(19) United States
(12) Patent Application Publication
(10) Pub. No.: US 2026/0367515 A1
(43) Pub. Date: Nov. 19, 2026

(54) MONOMER, POLYMER, CHEMICALLY AMPLIFIED RESIST COMPOSITION, AND PATTERN FORMING PROCESS

(71) Applicant: Shin-Etsu Chemical Co., Ltd., Tokyo (JP)

(72) Inventor: Masahiro Fukushima, Joetsu-shi (JP)

(73) Assignee: Shin-Etsu Chemical Co., Ltd., Tokyo (JP)

(21) Appl. No.: 19/641,613

(22) Filed: Apr. 8, 2026

(30) Foreign Application Priority Data
Apr. 25, 2025 (JP) 2025-072883

(51) Int. Cl. G03F 7/039; C08F 128/00; G03F 7/20

(52) U.S. Cl. CPC G03F 7/0397; C08F 128/00; G03F 7/2004

(57) ABSTRACT

A polymer obtained from a monomer having a specific structure has excellent solvent solubility. A chemically amplified resist composition comprising the polymer exhibits a high sensitivity and contrast and forms a pattern of satisfactory profile having improved lithography properties such as LWR, CDU, EL and DOF. The monomer has the formula (A):

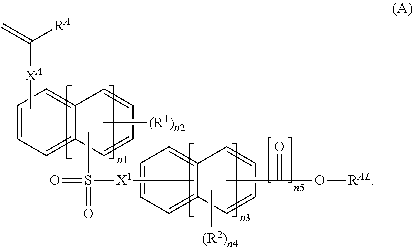

### CROSS-REFERENCE TO RELATED APPLICATION

This non-provisional application claims priority under 35 U.S.C. § 119(a) on Patent Application No. 2025-072883 filed in Japan on Apr. 25, 2025, the entire contents of which are hereby incorporated by reference.

### TECHNICAL FIELD

This invention relates to a monomer, polymer, chemically amplified resist composition, and pattern forming process.

### BACKGROUND ART

To meet the demand for higher integration density and operating speed of LSIs, the effort to reduce the pattern rule is in rapid progress. As the use of 5G high-speed communications and artificial intelligence (AI) is widely spreading, high-performance devices are needed for their processing. As the advanced miniaturization technology, manufacturing of microelectronic devices at the 5-nm node by the lithography using EUV of wavelength 13.5 nm has been implemented in a mass scale. Studies are made on the application of EUV lithography to 3-nm node devices of the next generation and 2-nm node devices of the next-but-one generation.

As the feature size reduces, image blurs due to acid diffusion become a problem. To insure resolution for fine patterns of sub-45-nm size, not only an improvement in dissolution contrast is important as previously reported, but the control of acid diffusion is also important as reported in Non-Patent Document 1. Since chemically amplified resist compositions are designed such that sensitivity and contrast are enhanced by acid diffusion, an attempt to minimize acid diffusion by reducing the temperature and/or time of post-exposure bake (PEB) fails, resulting in drastic reductions of sensitivity and contrast.

A triangular tradeoff relationship among sensitivity, resolution, and edge roughness (LER or LWR) has been pointed out. Specifically, a resolution improvement requires to suppress acid diffusion whereas a short acid diffusion distance leads to a decline of sensitivity.

The addition of an acid generator capable of generating a bulky acid is an effective means for suppressing acid diffusion. It was then proposed to incorporate repeat units derived from an onium salt having a polymerizable unsaturated bond in a polymer. Since this polymer functions as an acid generator, it is referred to as polymer-bound acid generator. Patent Document 1 discloses a sulfonium or iodonium salt having a polymerizable unsaturated bond, capable of generating a specific sulfonic acid. Patent Document 2 discloses a sulfonium salt having a sulfonic acid directly attached to the backbone.

The structure of an acid labile group on a base polymer is important as one component that contributes to the performance of positive resist material. Patent Documents 3 and 4 disclose an acid labile group of tertiary ester type bonded to a fluorinated aromatic group. Although the acid labile group of tertiary ester type bonded to an aromatic group is difficult to control acid diffusion because of a very high acid-catalyzed elimination reactivity, it becomes possible to moderate the elimination reactivity by introducing fluorine into the aromatic group.

For improving etching resistance in the EUV lithography, an acid labile monomer having a styrene structure is applied as the structure of polymerizable group on the monomer. Patent Document 5 discloses an acid labile monomer obtained from a styrene carboxylic acid and a cyclic tertiary alcohol. Patent Document 6 discloses an acid labile monomer of styrene type in which an aromatic linker structure containing iodine having a high absorptivity to EUV radiation is introduced. Since iodine is fully absorptive to EUV of wavelength 13.5 nm and enough to generate secondary electrons upon light exposure, iodine is considered attractive in the EUV lithography.

Patent Document 7 describes an acid labile monomer having methacrylamide as a polymerizable group and an iodized aromatic linker. Some improvements in resolution and sensitivity by this structure are attested, but still unsatisfactory. For further miniaturization, it is desired to have an acid labile monomer having moderate elimination reactivity relative to acid and capable of restraining swell in alkaline developer even after the elimination reaction.

### CITATION LIST

Patent Document 1: JP-A 2006-045311 (U.S. Pat. No. 7,482,108)
Patent Document 2: JP-A 2006-178317
Patent Document 3: JP 3832564
Patent Document 4: JP 5655754 (US 2013084527)
Patent Document 5: JP 7055070
Patent Document 6: JP-A 2025-005802
Patent Document 7: JP-A 2025-004966
Non-Patent Document 1: SPIE Vol. 6520 65203L-1 (2007)

### SUMMARY OF THE INVENTION

An object of the invention is to provide a monomer, a polymer obtained therefrom, and a chemically amplified resist composition comprising the polymer, the resist composition having a high solvent solubility, high sensitivity and high contrast, and forming a resist film with improved lithography properties such as LWR, CDU, EL, and DOF when processed by photolithography using high-energy radiation such as KrF or ArF excimer laser, EB or EUV; and a pattern forming process using the resist composition.

The inventor has found that a polymer obtained from a monomer of a specific structure has excellent solvent solubility, and that a chemically amplified resist composition comprising the polymer exhibits a high sensitivity and contrast and forms a pattern of satisfactory profile having improved lithography properties such as LWR, CDU, EL, and DOF and being resistant to collapse in forming small-size patterns.

In one aspect, the invention provides a monomer having the formula (A).

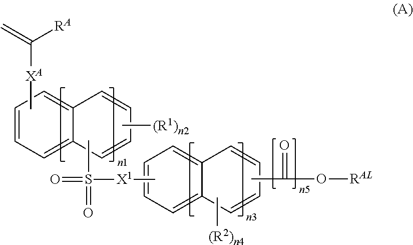

Herein n1 is 0 or 1, n2 is 0, 1, 2, 3 or 4, n3 is 0 or 1, n4 is 0, 1, 2, 3 or 4, n5 is 0 or 1,
R^{A} is hydrogen, fluorine, methyl or trifluoromethyl,
X^{A} is a single bond, —C(═O)—O—* or —C(═O)—N(H)—* wherein * designates a point of attachment to a carbon atom on the aromatic ring,
R¹ is halogen, nitro, cyano, hydroxy, carboxy, pentafluorosulfanyl, a C₁-C₂₀ hydrocarbyl group which may contain a heteroatom, C₁-C₂₀ hydrocarbyloxy group which may contain a heteroatom, C₁-C₂₀ hydrocarbylthio group which may contain a heteroatom; when n2 is 2, 3 or 4, a plurality of R¹ may be identical or different and two R¹ may bond together to form a ring with the carbon atoms to which they are attached,
R² is halogen, nitro, cyano, hydroxy, carboxy, pentafluorosulfanyl, a C₁-C₂₀ hydrocarbyl group which may contain a heteroatom, C₁-C₂₀ hydrocarbyloxy group which may contain a heteroatom, C₁-C₂₀ hydrocarbylthio group which may contain a heteroatom; when n4 is 2, 3 or 4, a plurality of R² may be identical or different and two R² may bond together to form a ring with the carbon atoms to which they are attached,
X¹ is —O— or —N(H)—, and
R^{AL} is an acid labile group.

The preferred monomer has the formula (A1):

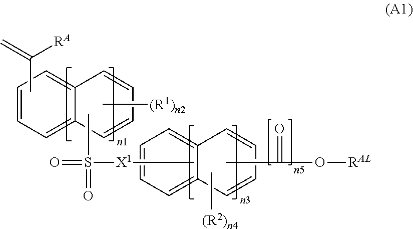

wherein n1 to n5, R^{A}, X¹, R¹, R² and R^{AL} are as defined above.

More preferably, the monomer has the formula (A2):

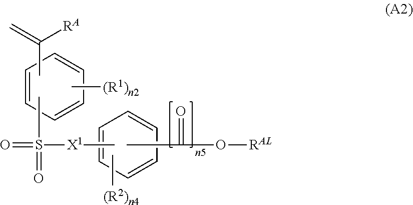

wherein n2, n4, n5, R^{A}, X¹, R¹, R² and R^{AL} are as defined above.

In a preferred embodiment, R^{AL} is a group having the formula (AL-1) or (AL-2).

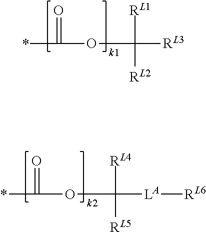

Herein k1 is 0 or 1, k2 is 0 or 1,
R^{L1} and R^{L2} are each independently a C₁-C₁₂ hydrocarbyl group, R^{L3} is hydrogen or a C₁-C₁₂ hydrocarbyl group, some —CH₂— in the hydrocarbyl group represented by R^{L1}, R^{L2} and R^{L3} may be replaced by —O— or —S—, and when the hydrocarbyl group contains an aromatic ring, some or all of the hydrogen atoms on the aromatic ring may be substituted by halogen, cyano, nitro, optionally halogenated C₁-C₄ alkyl moiety or optionally halogenated C₁-C₄ alkoxy moiety, R^{L1} and R^{L2} may bond together to form a ring with the carbon atom to which they are attached, some —CH₂— in the ring may be replaced by —O— or —S—, with the proviso that when R^{L3} is hydrogen, R^{L1} and R^{L2} bond together to form a multiple bond-containing alicyclic group with the carbon atom to which they are attached,
R^{L4} and R^{L5} are each independently hydrogen or a C₁-C₁₀ hydrocarbyl group, R^{L6} is a C₁-C₂₀ hydrocarbyl group, some —CH₂— in the hydrocarbyl group may be replaced by —O— or —S—, R^{L5} and R^{L6} may bond together to form a C₃-C₂₀ heterocyclic group with the carbon atom and L^{A} to which they are attached, some —CH₂— in the heterocyclic group may be replaced by —O— or —S—,
L^{A} is —O— or —S—, and
* designates a point of attachment to adjoining —O—.

In another aspect, the invention provides a polymer comprising repeat units derived from the monomer defined herein.

In a preferred embodiment, the polymer further comprises repeat units of at least one type selected from repeat units having the formula (a1), repeat units having the formula (a2), and repeat units having the formula (a3).

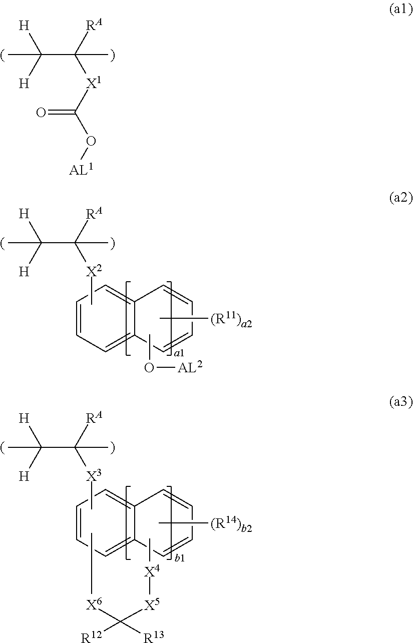

Herein a1 is 0 or 1, a2 is 0, 1, 2, 3 or 4,
b1 is 0 or 1, b2 is 0, 1, 2 or 3 when b1=0, b2 is 0, 1, 2, 3, 4 or 5 when b1=1,
R^{A} is each independently hydrogen, fluorine, methyl or trifluoromethyl,
X¹ is a single bond, phenylene, naphthylene, or *—C(═O)—O—X¹¹—, the phenylene or naphthylene group may be substituted with hydroxy, nitro, cyano, optionally fluorinated C₁-C₁₀ saturated hydrocarbyl moiety, optionally fluorinated C₁-C₁₀ saturated hydrocarbyloxy moiety, or halogen, X¹¹ is a C₁-C₁₀ saturated hydrocarbylene group, phenylene group or naphthylene group, the saturated hydrocarbylene group may contain hydroxy, ether bond, ester bond or lactone ring,
X² is a single bond, *—C(═O)—O— or *—C(═O)—N(H)—,
X³ is a single bond, *—C(═O)—O— or *—C(═O)—N(H)—,
* designates a point of attachment to the carbon atom in the backbone,
X⁴ is a single bond, a C₁-C₄ aliphatic hydrocarbylene group, carbonyl, sulfonyl, or a group obtained by combining the foregoing,
X⁵ and X⁶ are each independently oxygen or sulfur, X⁴ and X⁶ are attached to adjoining carbon atoms on the aromatic ring,
R¹¹ is halogen, cyano, hydroxy, nitro, pentafluorosulfanyl, a C₁-C₂₀ hydrocarbyl group which may contain a heteroatom, C₁-C₂₀ hydrocarbyloxy group which may contain a heteroatom, C₂-C₂₀ hydrocarbylcarbonyl group which may contain a heteroatom, C₂-C₂₀ hydrocarbylcarbonyloxy group which may contain a heteroatom, or C₂-C₂₀ hydrocarbyloxycarbonyl group which may contain a heteroatom; when a2 is 2, 3 or 4, a plurality of R¹¹ may be identical or different,
R¹² and R¹³ are each independently hydrogen or a C₁-C₂₀ hydrocarbyl group which may contain a heteroatom, R¹² and R¹³ may bond together to form a ring with the carbon atom to which they are attached,
R¹⁴ is halogen, hydroxy, cyano, nitro, pentafluorosulfanyl, a C₁-C₂₀ hydrocarbyl group which may contain a heteroatom, C₁-C₂₀ hydrocarbyloxy group which may contain a heteroatom, C₂-C₂₀ hydrocarbyloxycarbonyl group which may contain a heteroatom, C₂-C₂₀ hydrocarbylthio group which may contain a heteroatom, or —N(R^{14A})(R^{14B}), wherein R^{14A} and R^{14B} are each independently hydrogen or a C₁-C₆ hydrocarbyl group; when b2 is 2 or more, a plurality of R¹⁴ may be identical or different and a plurality of R¹⁴ may bond together to form a ring with carbon atoms on the aromatic ring to which they are attached,
AL¹ and AL² are each independently an acid labile group.

In a preferred embodiment, the polymer further comprises repeat units having the formula (b1).

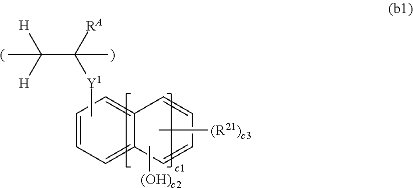

Herein R^{A} is each independently hydrogen, fluorine, methyl or trifluoromethyl,
Y¹ is a single bond, *—C(═O)—O— or *—C(═O)—N(H)—, wherein * designates a point of attachment to the carbon atom in the backbone,
R²¹ is halogen, carboxy, nitro, cyano, pentafluorosulfanyl, a C₁-C₂₀ hydrocarbyl group which may contain a heteroatom, C₁-C₂₀ hydrocarbyloxy group which may contain a heteroatom, C₂-C₂₀ hydrocarbylcarbonyl group which may contain a heteroatom, C₂-C₂₀ hydrocarbylcarbonyloxy group which may contain a heteroatom, C₂-C₂₀ hydrocarbyloxycarbonyl group which may contain a heteroatom; when c3 is 2, 3 or 4, a plurality of R²¹ may be identical or different,
c1 is 0 or 1, c2 is 1, 2, 3 or 4, c3 is 0, 1, 2, 3 or 4, meeting 1≤c2+c3≤5.

In a preferred embodiment, the polymer further comprises repeat units having the formula (b2).

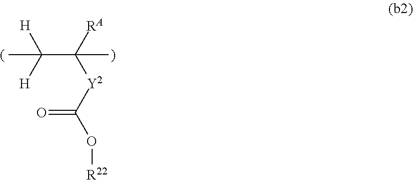

Herein R^{A} is each independently hydrogen, fluorine, methyl or trifluoromethyl,
Y² is a single bond, phenylene, naphthylene, *—C(═O)—O—Y²¹— or *—C(═O)—NH—Y²¹—, the phenylene or naphthylene group may be substituted with hydroxy, nitro, cyano, optionally fluorinated C₁-C₁₀ saturated hydrocarbyl moiety, optionally fluorinated C₁-C₁₀ saturated hydrocarbyloxy moiety, or halogen, * designates a point of attachment to the carbon atom in the backbone, Y²¹ is a C₁-C₁₀ saturated hydrocarbylene group, phenylene group or naphthylene group, the saturated hydrocarbylene group may contain hydroxy, ether bond, ester bond or lactone ring,
R²² is hydrogen, or a C₁-C₂₀ group containing at least one structure selected from hydroxy other than phenolic hydroxy, cyano, nitro, carbonyl, carboxy, ether bond, ester bond, sulfonate ester bond, carbonate bond, lactone ring, sultone ring, lactam ring, sultam ring, and carboxylic anhydride (—C(═O)—O—C(═O)—).

In a preferred embodiment, the polymer further comprises repeat units of at least one type selected from repeat units having the formula (c1), repeat units having the formula (c2), repeat units having the formula (c3), repeat units having the formula (c4), and repeat units having the formula (c5).

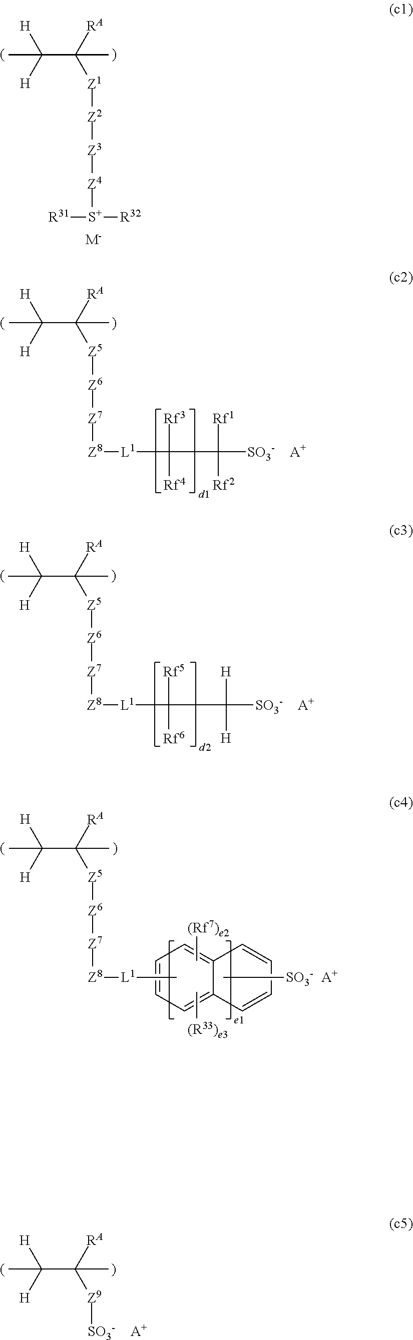

Herein d1 and d2 are each independently 0, 1, 2 or 3,
e1 is 0 or 1, e2 is 0, 1, 2, 3 or 4, e3 is 0, 1, 2, 3 or 4, meeting 0≤e2+e3≤4 when e1=0, and 0≤e2+e3≤6 when e1=1,
R^{A} is each independently hydrogen, fluorine, methyl or trifluoromethyl,
Z¹ is a single bond or optionally substituted phenylene group,
Z² is a single bond, **—C(═O)—O—Z²¹—, **—C(═O)—N(H)—Z²¹—, or **—O—Z²¹—, Z²¹ is a C₁-C₆ aliphatic hydrocarbylene group, phenylene group or a divalent group obtained by combining the foregoing, which may contain halogen, carbonyl moiety, ester bond, ether bond or hydroxy moiety,
Z³ is a single bond, ether bond, ester bond, sulfonate ester bond, amide bond, sulfonamide bond, carbonate bond or carbamate bond,
Z⁴ is a single bond or a C₁-C₆ aliphatic hydrocarbylene group, phenylene group or a divalent group obtained by combining the foregoing, which may contain halogen, carbonyl moiety, ester bond, ether bond or hydroxy moiety,
Z⁵ is each independently a single bond, optionally substituted phenylene group, naphthylene group or *—C(═O)—O—Z⁵¹—, Z⁵¹ is a C₁-C₁₀ aliphatic hydrocarbylene group, phenylene group or naphthylene group, the aliphatic hydrocarbylene group may contain halogen, hydroxy, ether bond, ester bond or lactone ring,
Z⁶ is a single bond, ether bond, ester bond, sulfonate ester bond, amide bond, sulfonamide bond, carbonate bond or carbamate bond,
Z⁷ is each independently a single bond, ***—Z⁷¹—C(═O)—O—, ***—C(═O)—N(H)—Z⁷¹— or ***—O—Z⁷¹—, Z⁷¹ is a C₁-C₂₀ hydrocarbylene group which may contain a heteroatom,
Z⁸ is each independently a single bond, ****—Z⁸¹—C(═O)—O—, ****—C(═O)—N(H)—Z⁸¹— or ****—O—Z⁸¹—, Z⁸¹ is a C₁-C₂₀ hydrocarbylene group which may contain a heteroatom,
Z⁹ is a single bond, methylene, ethylene, phenylene, fluorinated phenylene, trifluoromethyl-substituted phenylene, *—C(═O)—O—Z⁹¹—, *—C(═O)—N(H)—Z⁹¹— or *—O—Z⁹¹—, Z⁹¹ is a C₁-C₆ aliphatic hydrocarbylene group, phenylene group, fluorinated phenylene group, or trifluoromethyl-substituted phenylene group, which may contain carbonyl, ester bond, ether bond or hydroxy,
* designates a point of attachment to the carbon atom in the backbone, ** designates a point of attachment to Z¹, *** designates a point of attachment to Z⁶, **** designates a point of attachment to Z⁷,
L¹ is a single bond, ether bond, ester bond, carbonyl group, sulfonate ester bond, sulfonamide bond, carbonate bond or carbamate bond,
Rf¹ and Rf² are each independently fluorine or a C₁-C₆ fluorinated saturated hydrocarbyl group,
Rf³ and Rf⁴ are each independently hydrogen, fluorine or a C₁-C₆ fluorinated saturated hydrocarbyl group,
Rf⁵ and Rf⁶ are each independently hydrogen, fluorine or a C₁-C₆ fluorinated saturated hydrocarbyl group, excluding that all Rf⁵ and Rf⁶ are hydrogen at the same time,
Rf⁷ is fluorine, a C₁-C₆ fluorinated alkyl group, C₁-C₆ fluorinated alkoxy group, C₁-C₆ fluorinated alkylthio group, or pentafluorosulfanyl group,
R³¹ and R³² are each independently a C₁-C₂₀ hydrocarbyl group which may contain a heteroatom, R³¹ and R³² may bond together to form a ring with the sulfur atom to which they are attached,
R³³ is halogen exclusive of fluorine, or a C₁-C₂₀ hydrocarbyl group which may contain a heteroatom; when e3 is 2, 3 or 4, a plurality of R⁴³ may be identical or different and a plurality of R⁴³ may bond together to form a ring with the carbon atoms to which they are attached,
M⁻ is a non-nucleophilic counter ion, and
A⁺ is an onium cation.

In a further aspect, the invention provides a chemically amplified resist composition comprising a base polymer containing the polymer defined herein, and an organic solvent.

The resist composition may further comprise a quencher, a photoacid generator other than a polymer-bound photoacid generator, and/or a surfactant.

In a still further aspect, the invention provides a pattern forming process comprising the steps of applying the chemically amplified resist composition defined herein onto a substrate to form a resist film thereon, exposing the resist film to high-energy radiation, and developing the exposed resist film in a developer.

Typically, the high-energy radiation is KrF excimer laser, ArF excimer laser, EB or EUV of wavelength 3 to 15 nm.

### Advantageous Effects of the Invention

When a chemically amplified resist composition comprising a polymer obtained from polymerization of the inventive monomer is processed by lithography, resist patterns having a high sensitivity, high contrast, and improved properties including LWR, CDU, EL, and DOF can be formed. The risk of pattern collapse during formation of small-size patterns is minimized.

### DESCRIPTION OF THE PREFERRED EMBODIMENT

As used herein, the singular forms “a,” “an” and “the” include plural referents unless the context clearly dictates otherwise. “Optional” or “optionally” means that the subsequently described event or circumstances may or may not occur, and that description includes instances where the event or circumstance occurs and instances where it does not.

The notation (Cn-Cm) means a group containing from n to m carbon atoms per group. In chemical formulae, Me stands for methyl, and Ac for acetyl. The broken line (---) and the asterisk (*) designate a valence bond or point of attachment. As used herein, the term “halogenated” refers to a halogen-substituted or halogen-containing compound or group.

The terms “group” and “moiety” are interchangeable.

The abbreviations and acronyms have the following meaning.
EB: electron beam
EUV: extreme ultraviolet
Mw: weight average molecular weight
Mn: number average molecular weight
Mw/Mn: molecular weight dispersity
GPC: gel permeation chromatography
PEB: post-exposure bake
PAG: photoacid generator
EL: exposure latitude
LWR: line width roughness
CDU: critical dimension uniformity
DOF: depth of focus

It is understood that for some structures represented by chemical formulae, there can exist enantiomers and diastereomers because of the presence of asymmetric carbon atoms. In such a case, a single formula collectively represents all such isomers. The isomers may be used alone or in admixture.

### [Monomer]

The invention provides a monomer having the formula (A).

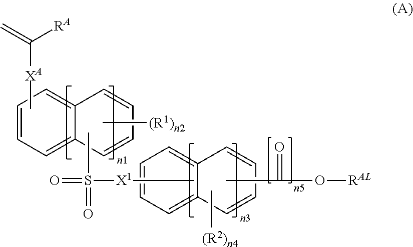

In formula (A), n1 is 0 or 1. The relevant structure is a benzene ring when n1=0, and a naphthalene ring when n1=1. The benzene ring corresponding to n1=0 is preferred from the aspect of solvent solubility. The subscript n2 is 0, 1, 2, 3 or 4. It is preferred for reactant availability that n2 be 0, 1 or 2. The subscript n3 is 0 or 1. The relevant structure is a benzene ring when n3=0, and a naphthalene ring when n3=1. The benzene ring corresponding to n3=0 is preferred from the aspect of solvent solubility. The subscript n4 is 0, 1, 2, 3 or 4. It is preferred for reactant availability that n4 be 0, 1 or 2. The subscript n5 is 0 or 1.

In formula (A), R^{A} is hydrogen, fluorine, methyl or trifluoromethyl. Of these, hydrogen and methyl are preferred.

In formula (A), X^{A} is a single bond, —C(═O)—O—* or —C(═O)—N(H)—*, wherein * designates a point of attachment to a carbon atom on the aromatic ring. X^{A} is preferably a single bond or —C(═O)—O—*, more preferably a single bond.

In formula (A), R¹ is halogen, nitro, cyano, hydroxy, carboxy, pentafluorosulfanyl, a C₁-C₂₀ hydrocarbyl group which may contain a heteroatom, C₁-C₂₀ hydrocarbyloxy group which may contain a heteroatom or C₁-C₂₀ hydrocarbylthio group which may contain a heteroatom. Suitable halogen atoms include fluorine, chlorine, bromine, and iodine, with fluorine and iodine being preferred. The hydrocarbyl group and hydrocarbyl moiety in the hydrocarbyloxy and hydrocarbylthio groups may be saturated or unsaturated and straight, branched or cyclic. Examples thereof include C₁-C₂₀ alkyl groups such as methyl, ethyl, n-propyl, isopropyl, n-butyl, isobutyl, sec-butyl, tert-butyl, n-pentyl, n-hexyl, n-octyl, n-nonyl, n-decyl, undecyl, dodecyl, tridecyl, tetradecyl, pentadecyl, heptadecyl, octadecyl, nonadecyl and icosyl; C₃-C₂₀ cyclic saturated hydrocarbyl groups such as cyclopropyl, cyclopentyl, cyclohexyl, cyclopropylmethyl, 4-methylcyclohexyl, cyclohexylmethyl, norbornyl, and adamantyl; C₂-C₂₀ alkenyl groups such as vinyl, 1-propenyl, 2-propenyl, butenyl, and hexenyl; C₃-C₂₀ cyclic unsaturated hydrocarbyl groups such as cyclohexenyl; C₆-C₂₀ aryl groups such as phenyl and naphthyl; C₇-C₂₀ aralkyl groups such as benzyl, 1-phenylethyl, and 2-phenylethyl, and combinations thereof. Inter alia, aryl groups are preferred. In the hydrocarbyl group, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy, cyano, fluorine, chlorine, bromine, iodine, carbonyl, ether bond, ester bond, sulfonate ester bond, carbonate bond, lactone ring, sultone ring, carboxylic anhydride (—C(═O)—O—C(═O)—) or haloalkyl moiety.

In formula (A), R² is halogen, nitro, cyano, hydroxy, carboxy, pentafluorosulfanyl, a C₁-C₂₀ hydrocarbyl group which may contain a heteroatom, C₁-C₂₀ hydrocarbyloxy group which may contain a heteroatom, C₁-C₂₀ hydrocarbylthio group which may contain a heteroatom. Suitable halogen atoms include fluorine, chlorine, bromine, and iodine, with fluorine and iodine being preferred. The hydrocarbyl group and hydrocarbyl moiety in the hydrocarbyloxy and hydrocarbylthio groups may be saturated or unsaturated and straight, branched or cyclic. Examples thereof are as exemplified above for the hydrocarbyl group R¹, but not limited thereto.

When n2 is 2, 3 or 4, a plurality of R¹ may be identical or different. When n2 is 2, 3 or 4, two R¹ may bond together to form a ring with the carbon atoms to which they are attached. The ring is preferably 5- to 8-membered. When n4 is 2, 3 or 4, a plurality of R² may be identical or different. When n4 is 2, 3 or 4, two R² may bond together to form a ring with the carbon atoms to which they are attached. The ring is preferably 5- to 8-membered.

In formula (A), X¹ is —O— or —N(H)—.

In formula (A), R^{AL} is an acid labile group. Typical of the acid labile group are groups of the following formulae (AL-1) and (AL-2).

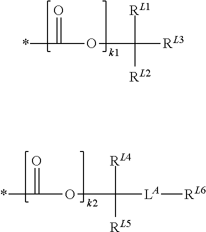

Herein, * designates a point of attachment to —O—.

In formulae (AL-1) and (AL-2), k1 is 0 or 1 and k2 is 0 or 1.

In formula (AL-1), R^{L1} and R^{L2} are each independently a C₁-C₁₂ hydrocarbyl group. R^{L3} is hydrogen or a C₁-C₁₂ hydrocarbyl group. Some —CH₂— in the hydrocarbyl group represented by R^{L1}, R^{L2} and R^{L3} may be replaced by —O— or —S—. When the hydrocarbyl group contains an aromatic ring, some or all of the hydrogen atoms on the aromatic ring may be substituted by halogen, cyano, nitro, optionally halogenated C₁-C₄ alkyl moiety or optionally halogenated C₁-C₄ alkoxy moiety. The C₁-C₁₂ hydrocarbyl group represented by R^{L1}, R^{L2} and R^{L3} may be saturated or unsaturated and straight, branched or cyclic. Examples thereof are as exemplified above for the hydrocarbyl group R¹, but of 1 to 12 carbon atoms. R^{L1} and R^{L2} may bond together to form a ring with the carbon atom to which they are attached, and some —CH₂— in the ring may be replaced by —O— or —S—. When R^{L3} is hydrogen, R^{L1} and R^{L2} bond together to form a multiple bond-containing alicyclic group with the carbon atom to which they are attached.

In formula (AL-2), R^{L4} and R^{L5} are each independently hydrogen or a C₁-C₁₀ hydrocarbyl group. The C₁-C₁₀ hydrocarbyl group R^{L4} and R^{L5} may be saturated or unsaturated and straight, branched or cyclic, and examples thereof are as exemplified for the hydrocarbyl group R¹, but of 1 to 10 carbon atoms. R^{L6} is a C₁-C₂₀ hydrocarbyl group. Some —CH₂— in the hydrocarbyl group may be replaced by —O— or —S—. R^{L5} and R^{L6} may bond together to form a C₃-C₂₀ heterocyclic group with the carbon atom and L^{A} to which they are attached. Some —CH₂— in the heterocyclic group may be replaced by —O— or —S—. The C₁-C₂₀ hydrocarbyl group R^{L6} may be saturated or unsaturated and straight, branched or cyclic, and examples thereof are as exemplified for the hydrocarbyl group R¹.

In formula (AL-2), L^{A} is —O— or —S—.

Examples of the acid labile group having formula (AL-1) are shown below, but not limited thereto. Herein, * designates a point of attachment to adjoining —O—.

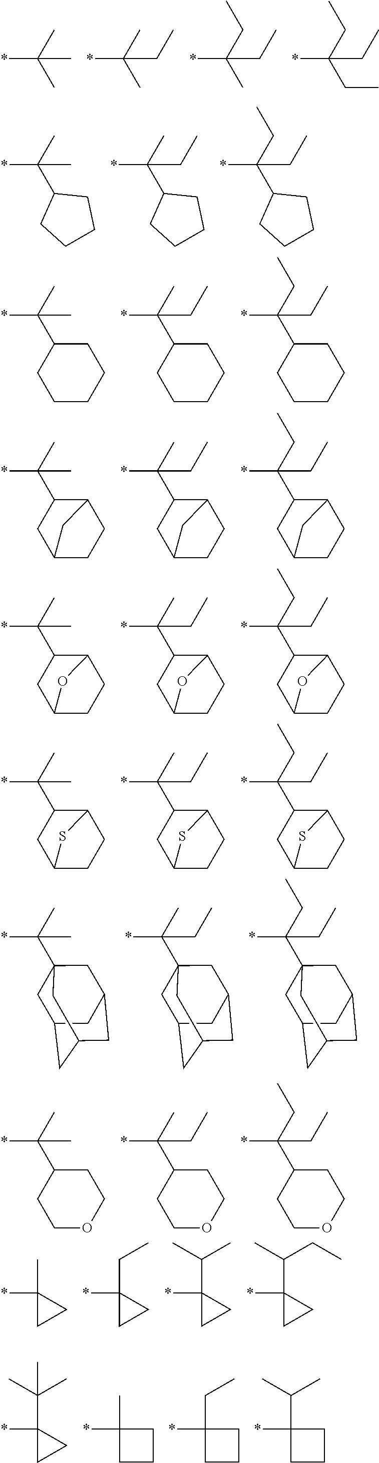

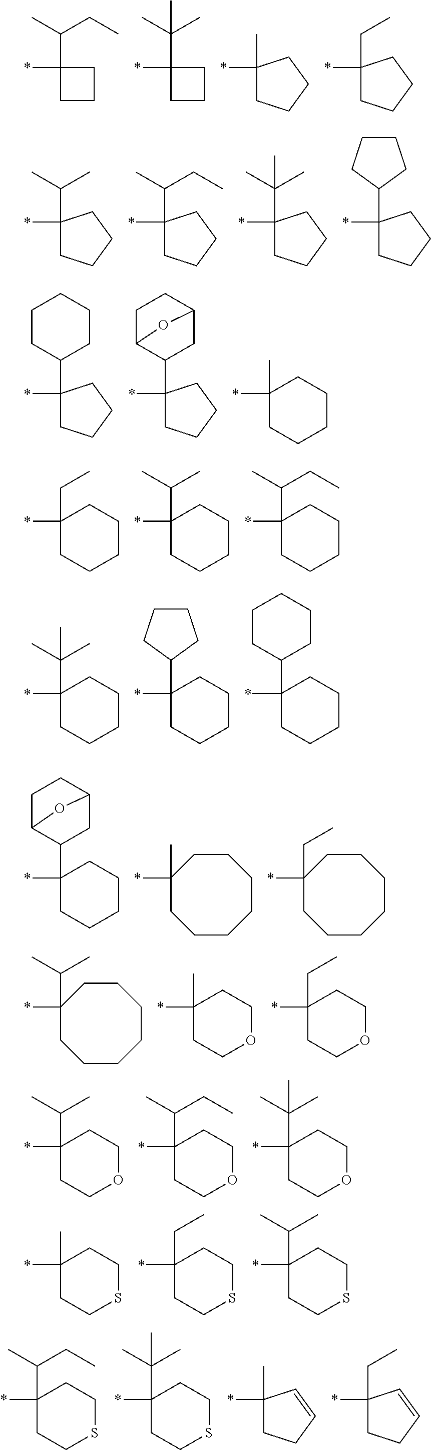

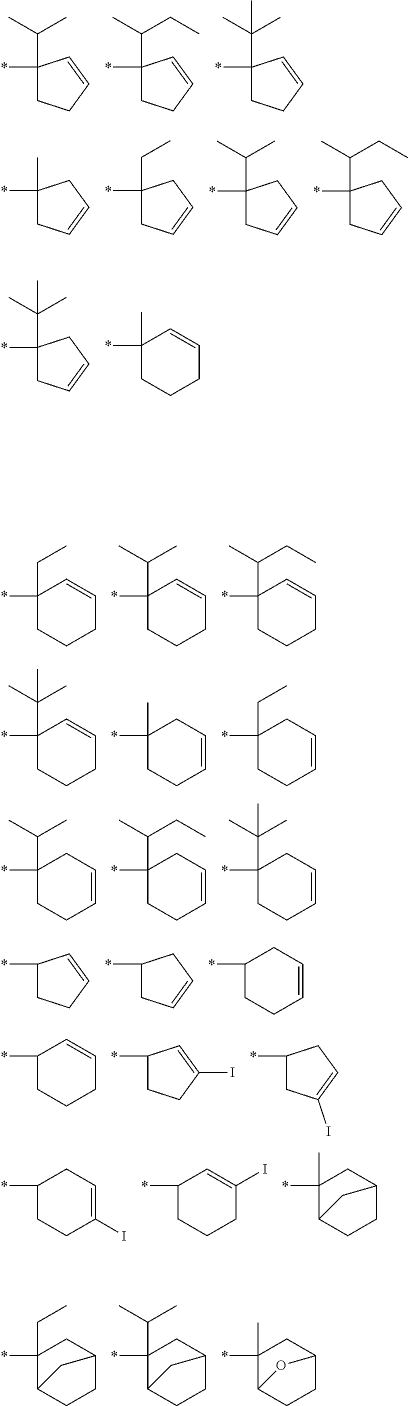

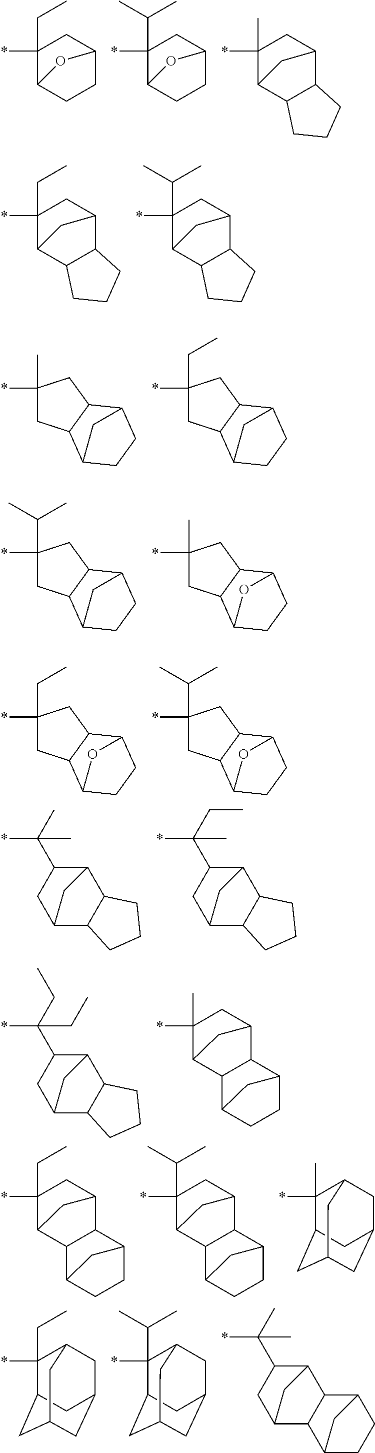

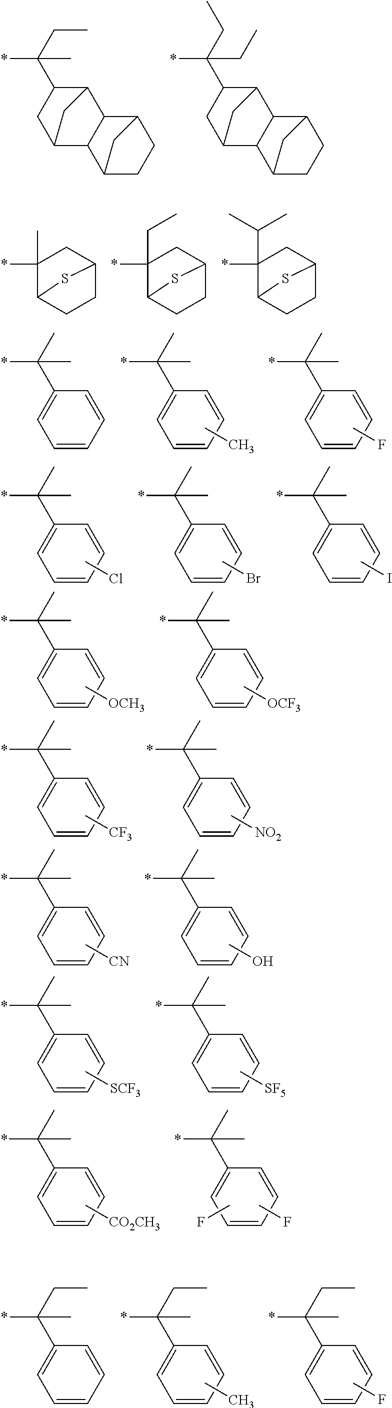

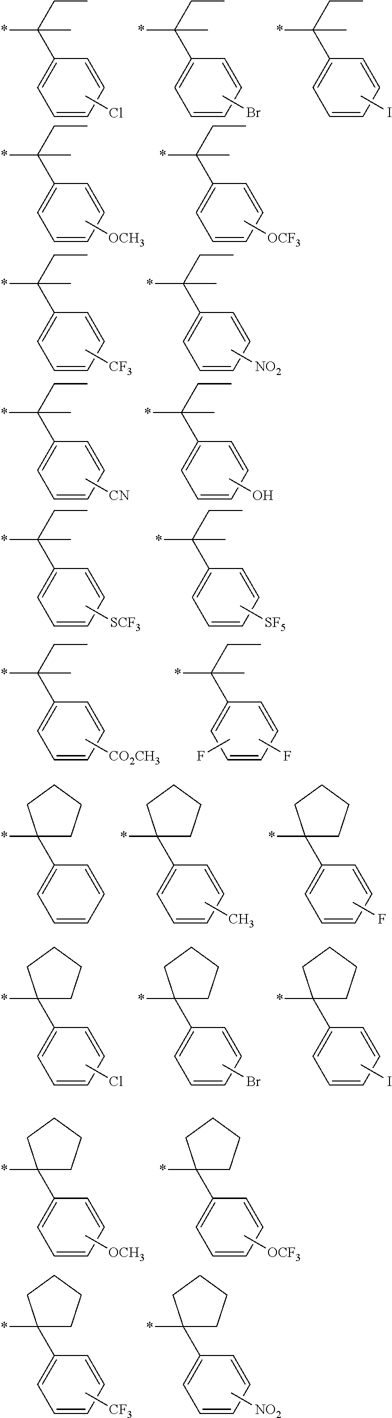

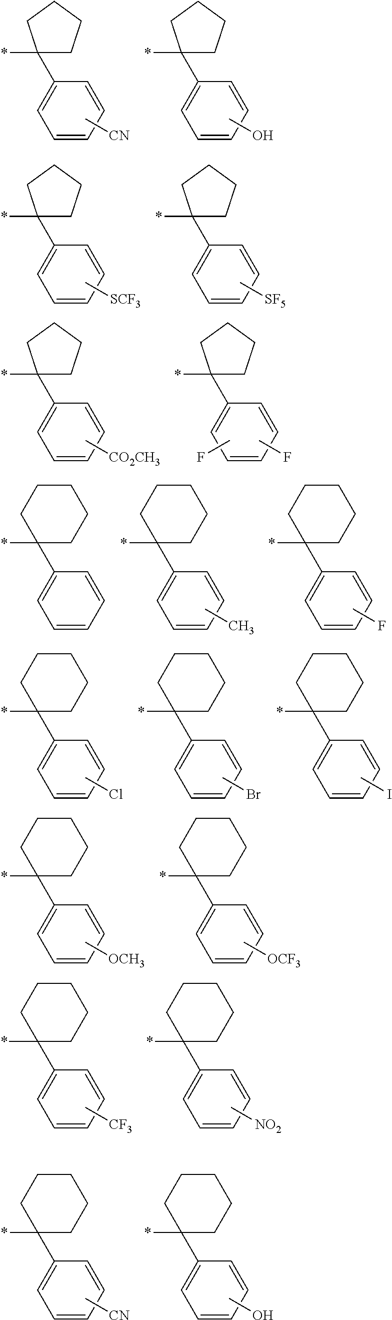

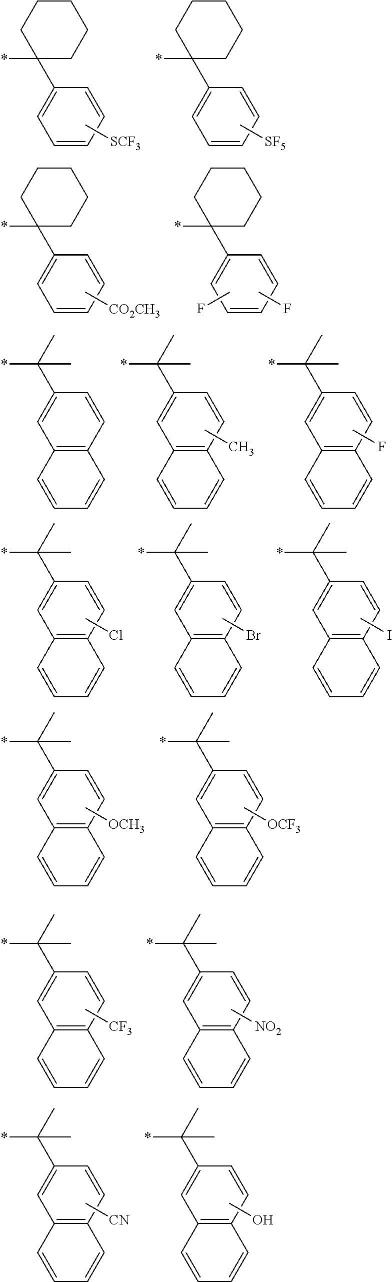

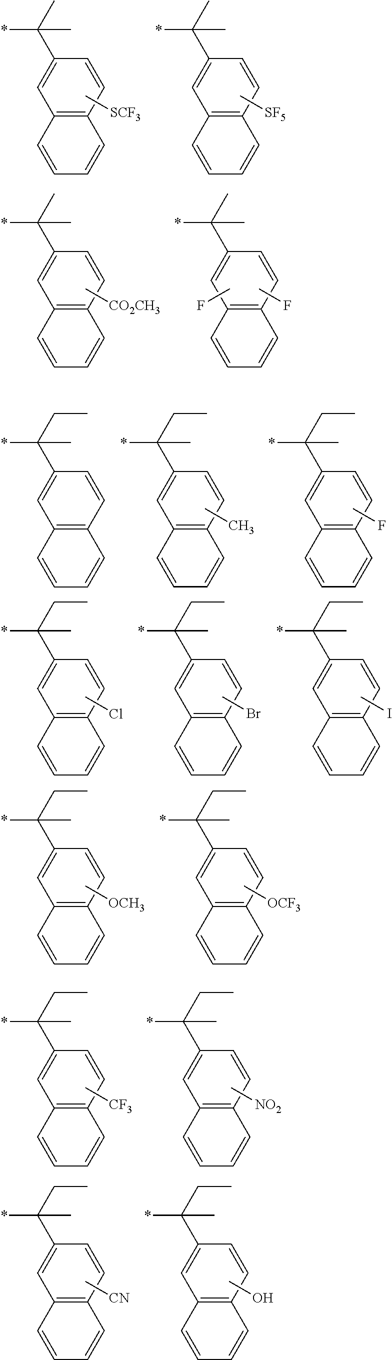

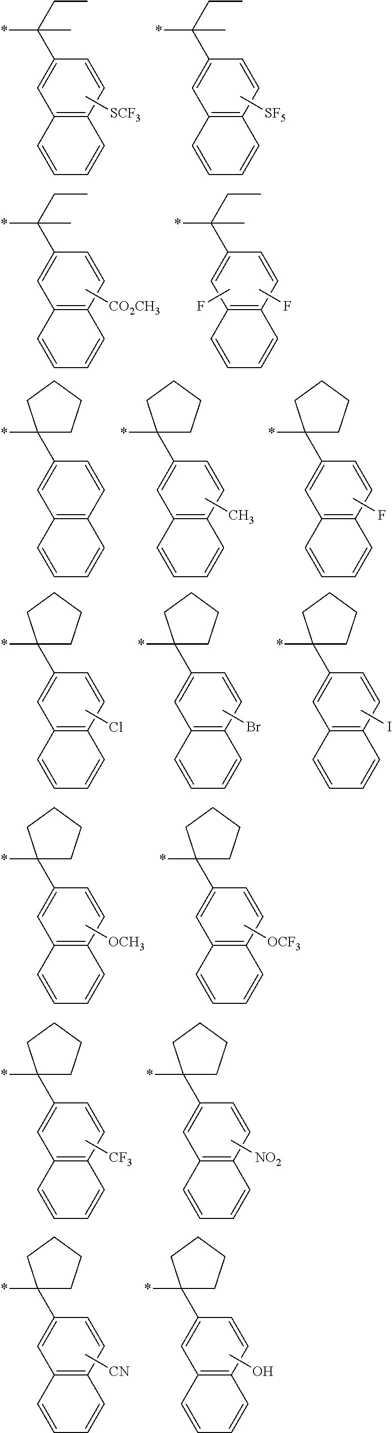

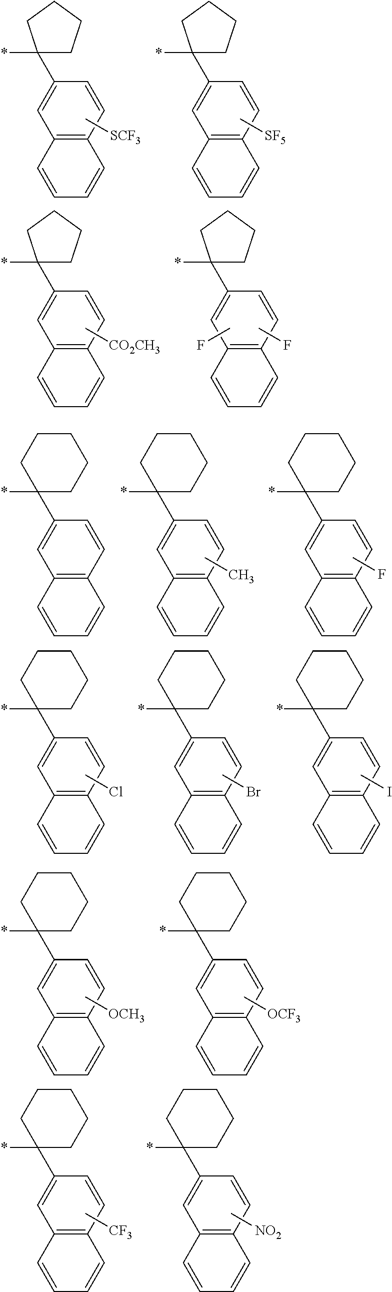

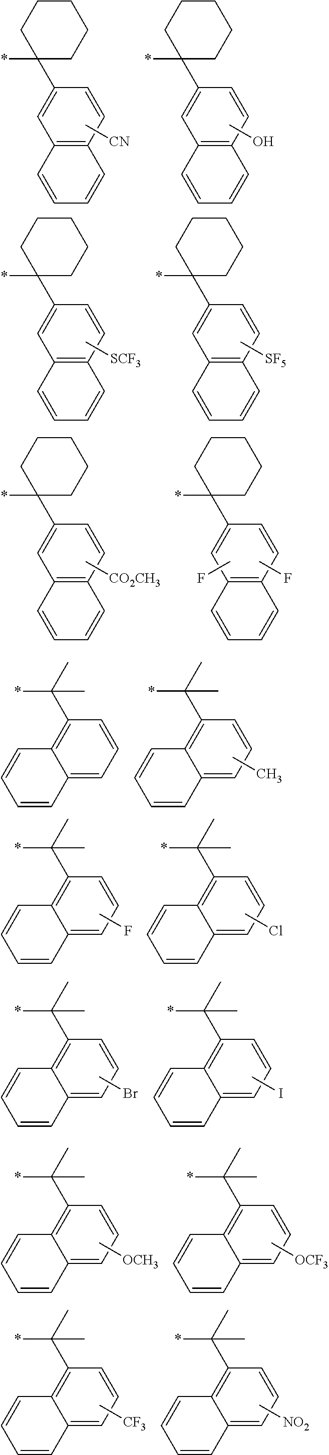

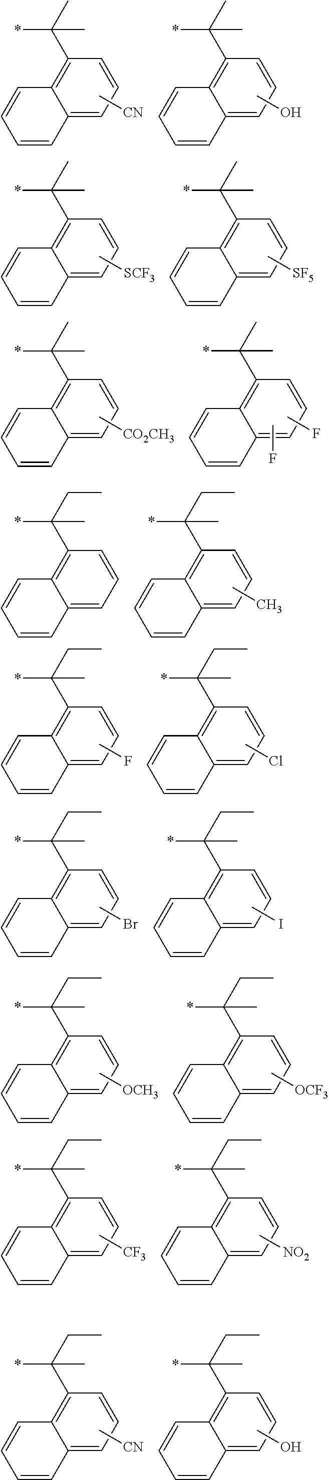

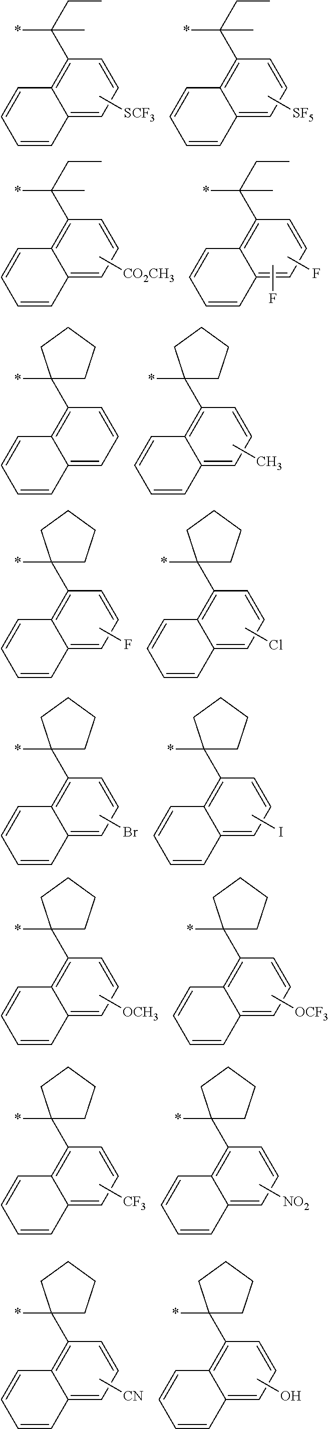

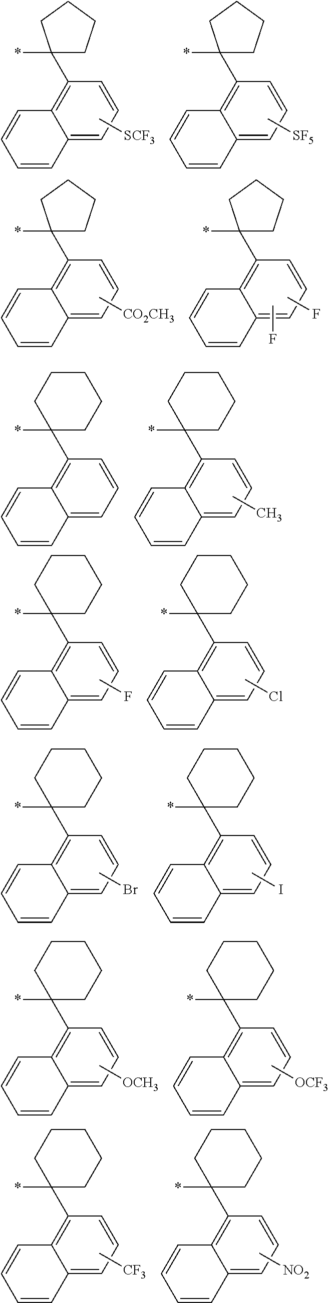

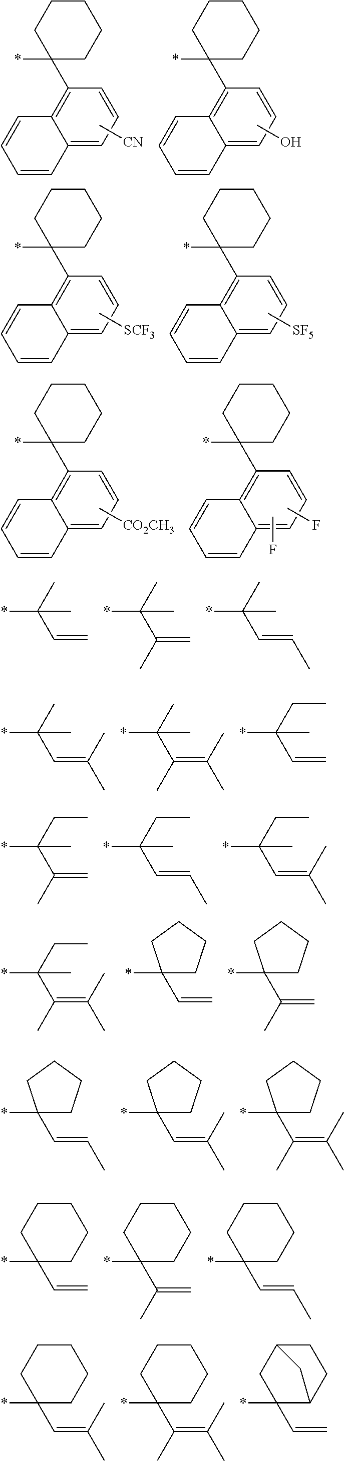

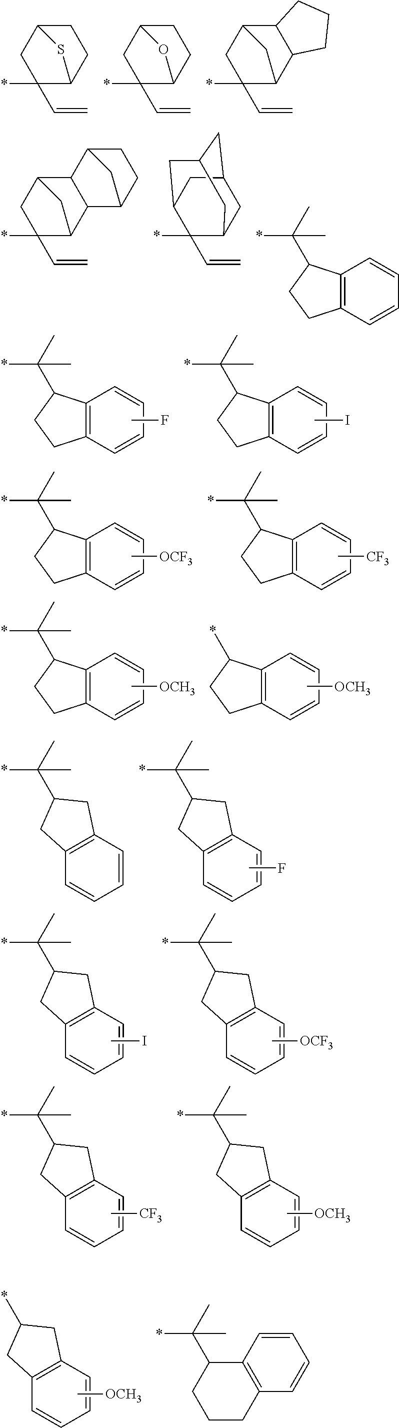

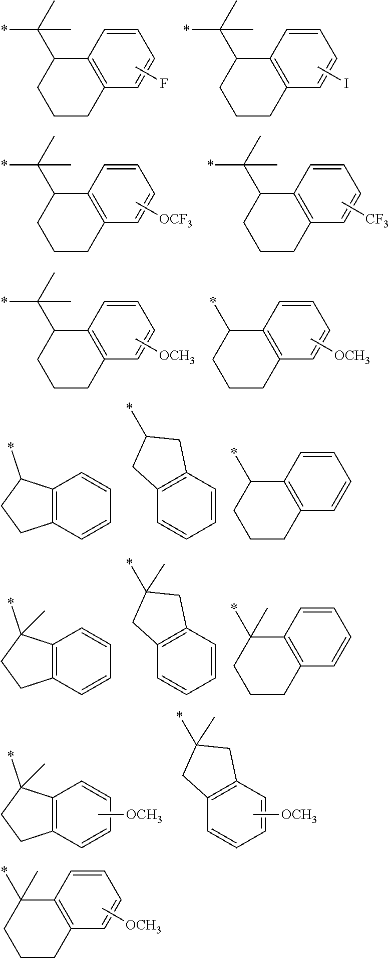

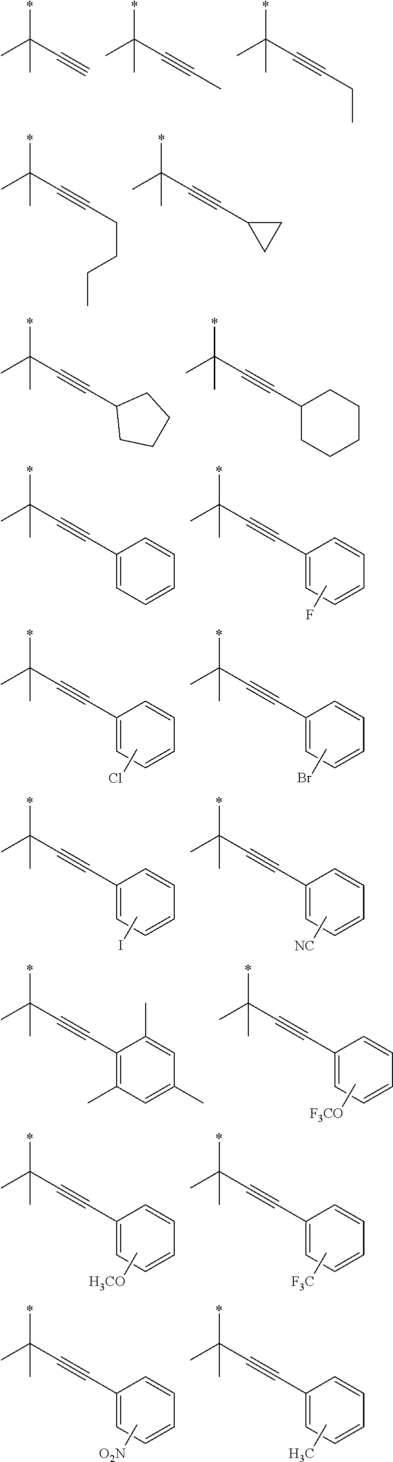

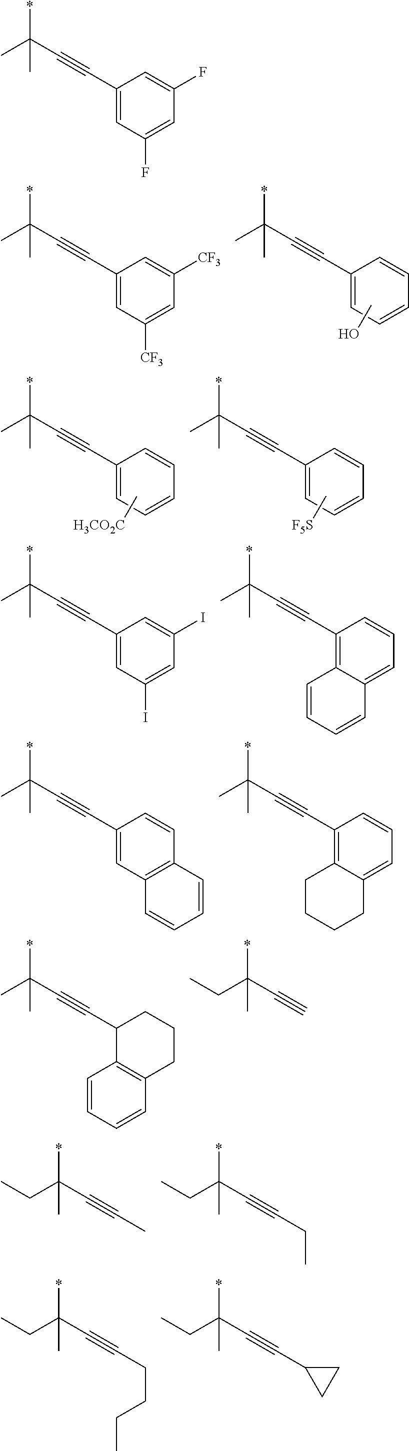

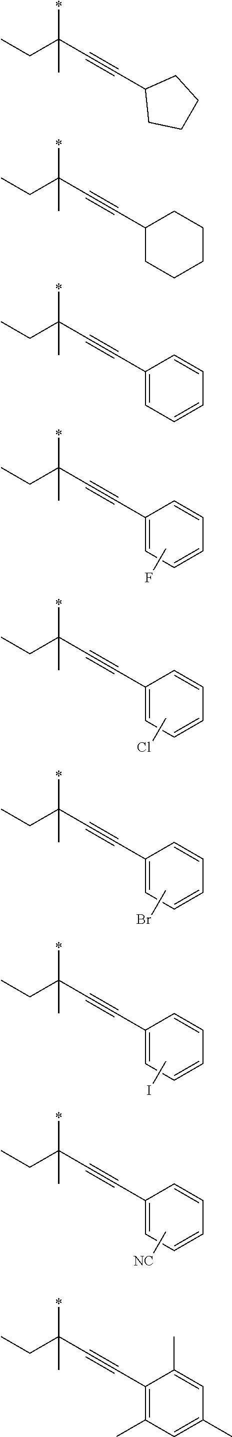

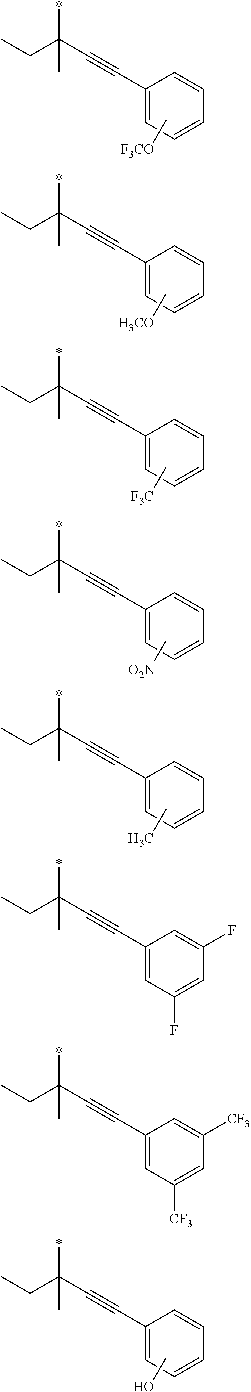

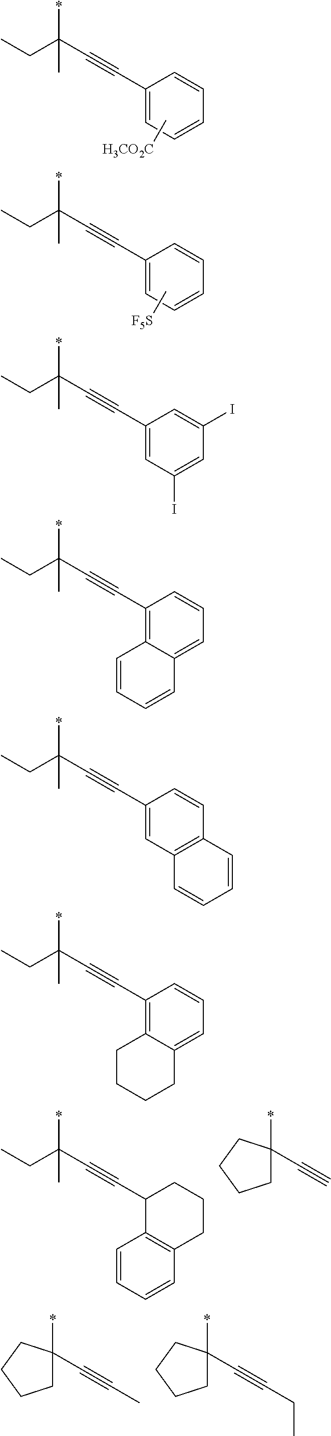

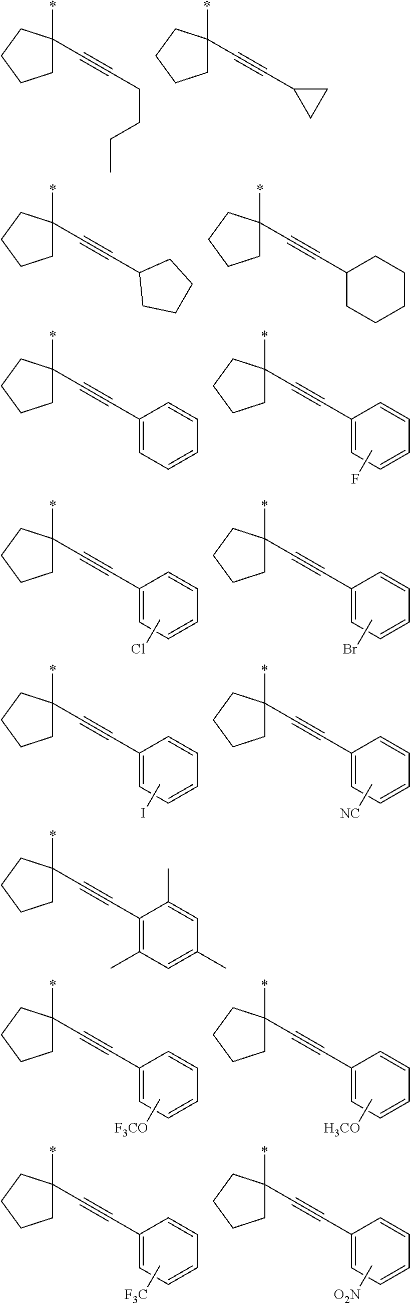

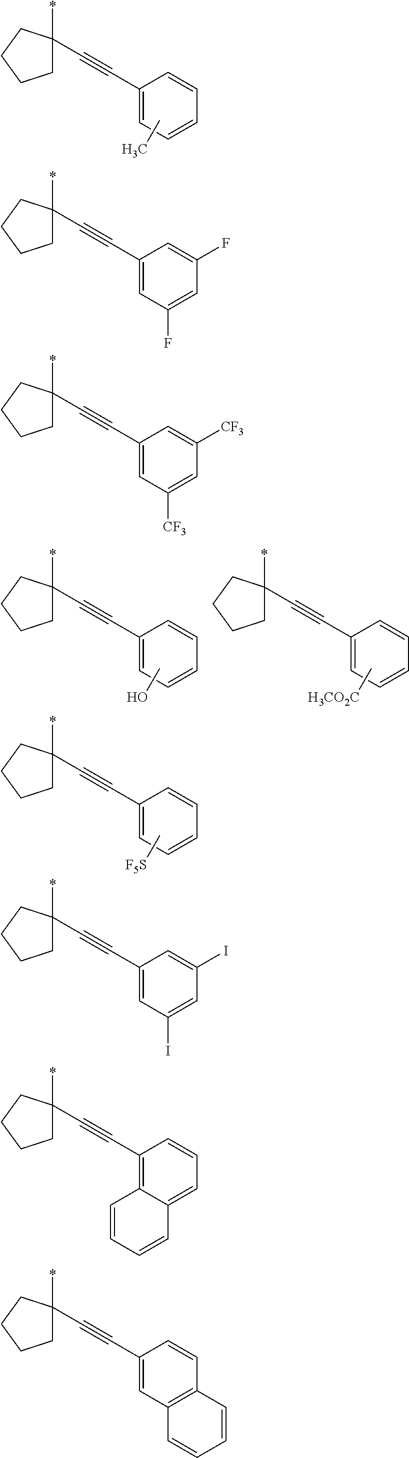

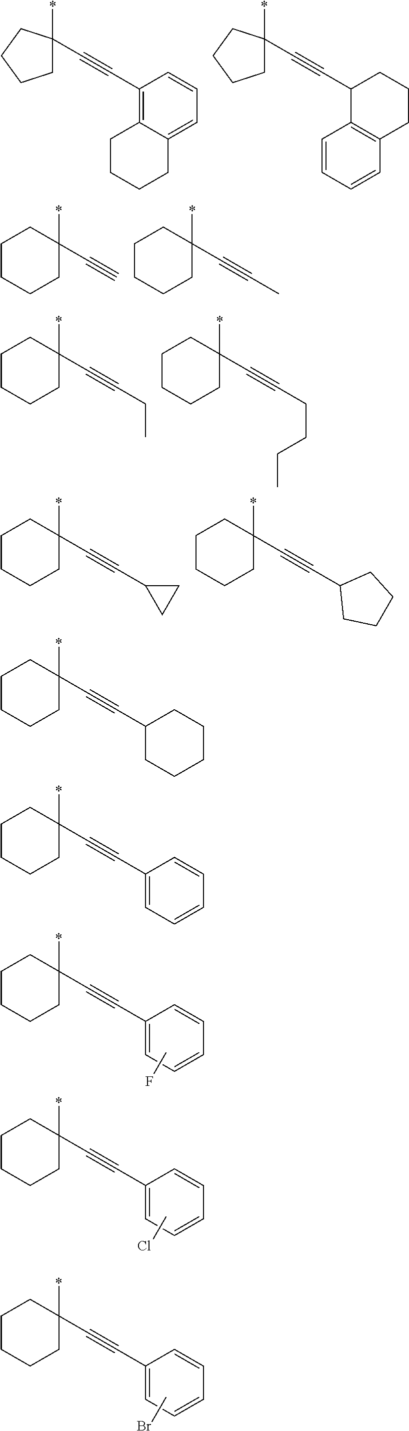

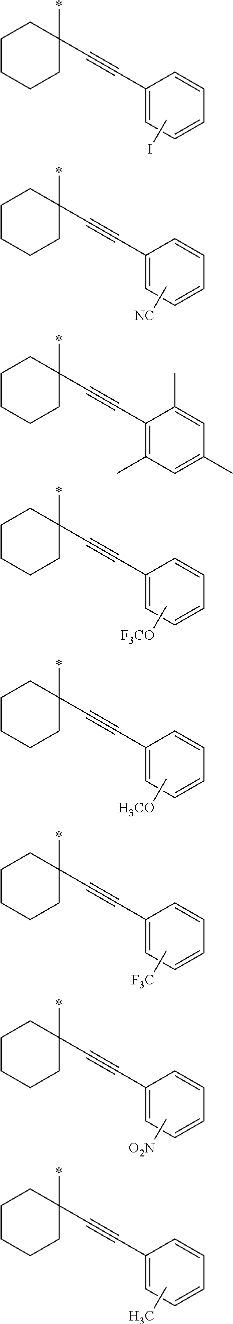

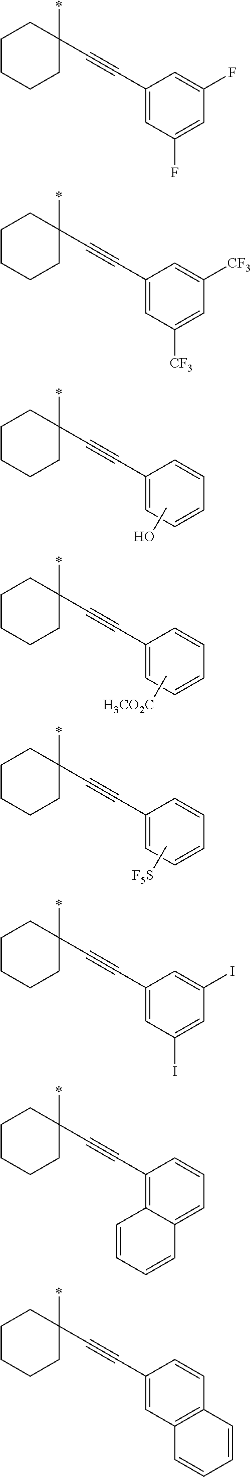

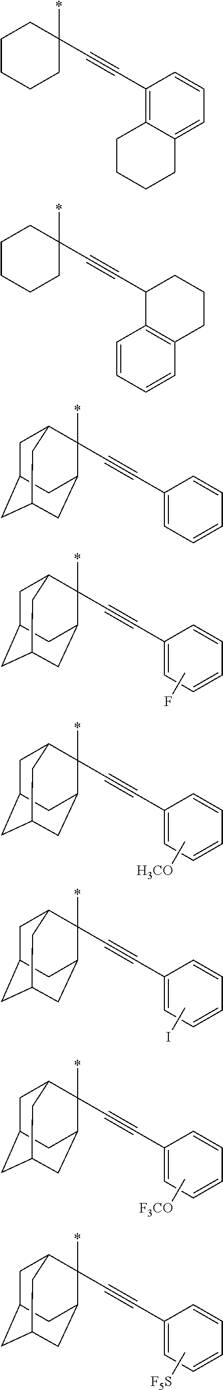

Examples of the acid labile group having formula (AL-2) are shown below, but not limited thereto. Herein, * designates a point of attachment to adjoining —O—.

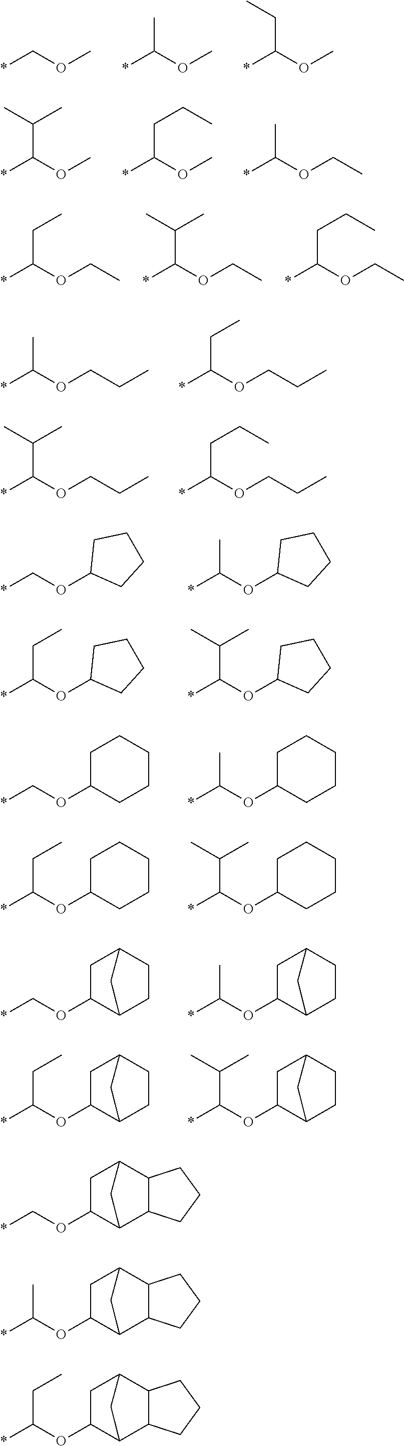

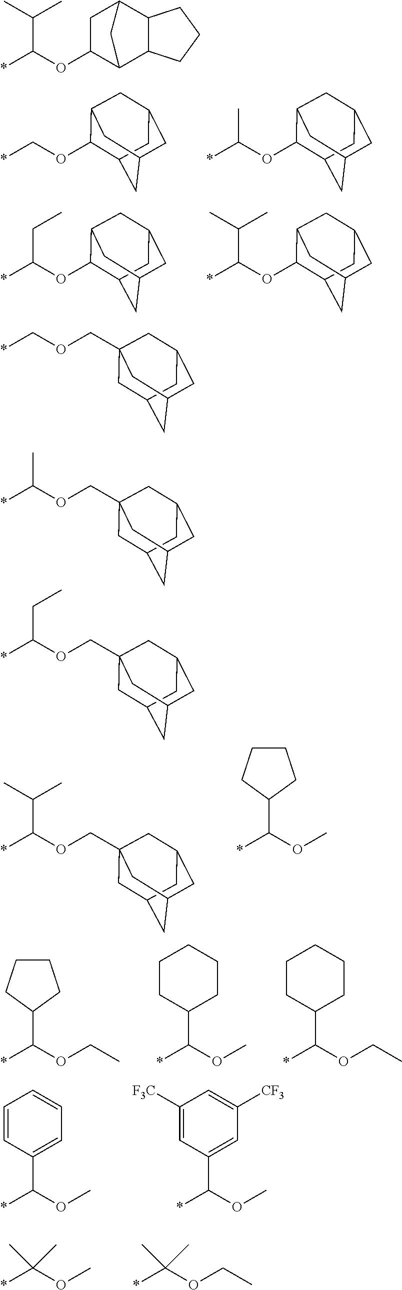

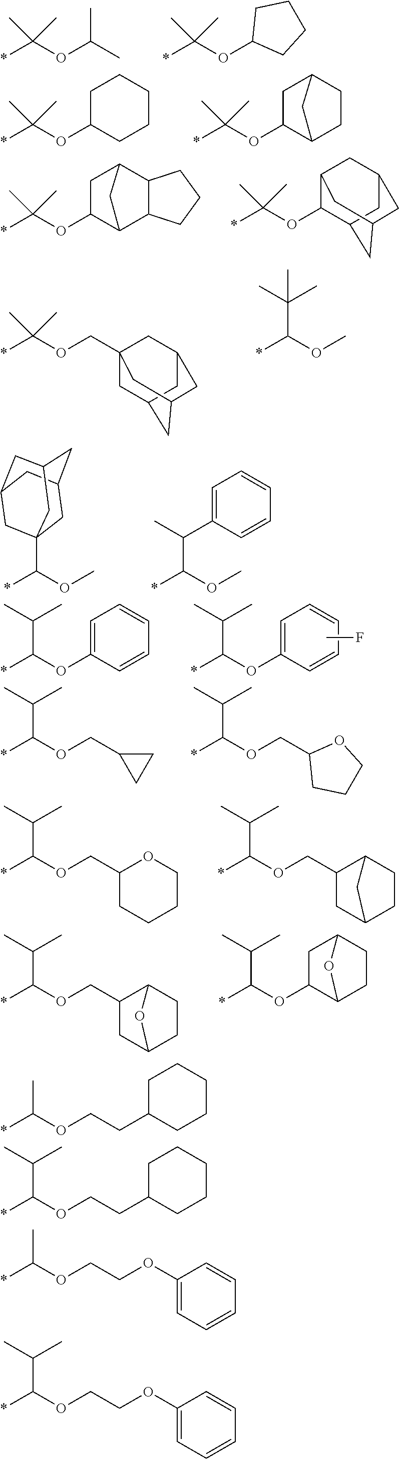

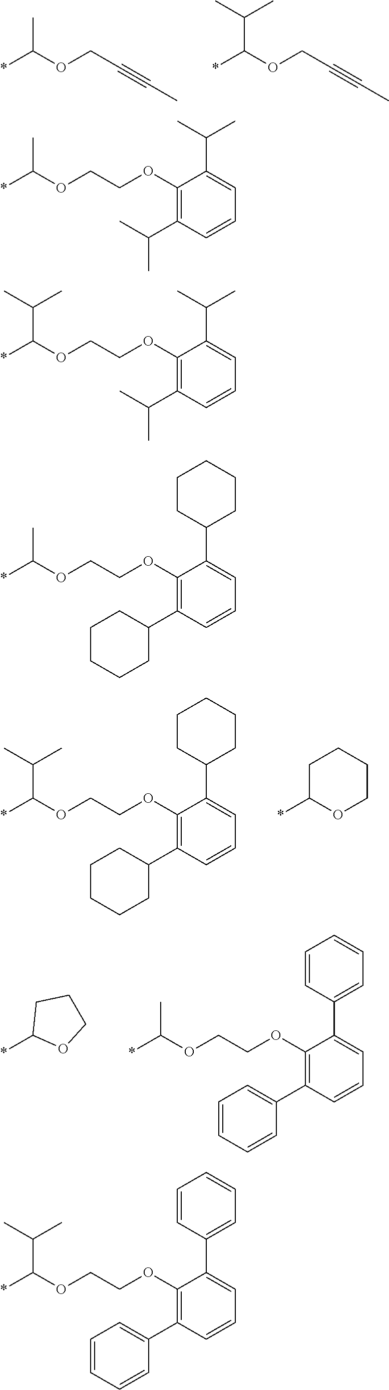

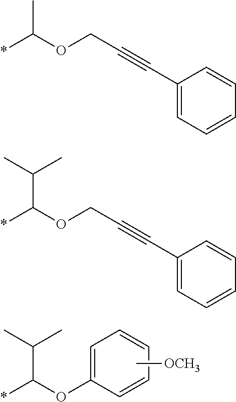

Of the monomers of formula (A), those having the formula (A1) are preferred.

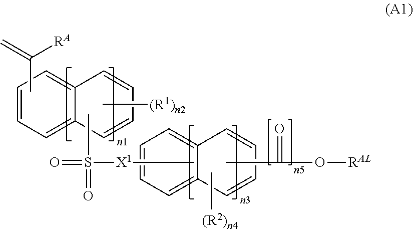

Herein n1 to n5, R^{A}, X¹, R¹, R², and R^{AL} are as defined above.

Of the monomers of formula (A1), those having the formula (A2) are preferred.

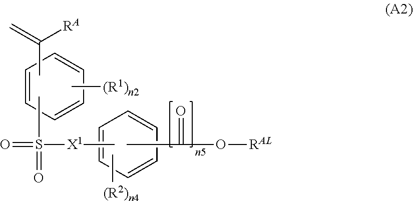

Herein n2, n4, n5, R^{A}, X¹, R¹, R², and R^{AL} are as defined above.

Examples of the monomer having formula (A) are shown below, but not limited thereto. The position of attachment of substituent groups on the aromatic ring is not limited to the illustrated one.

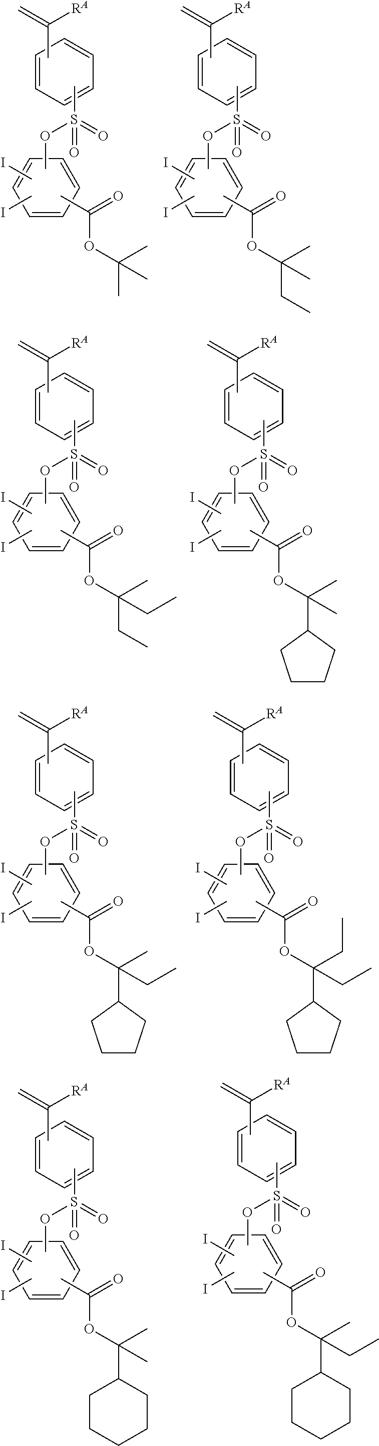

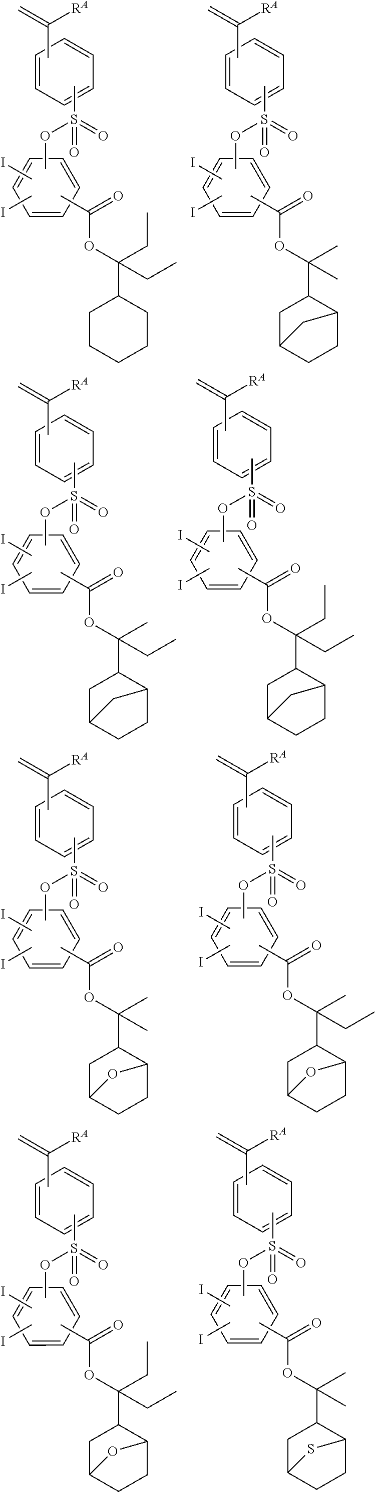

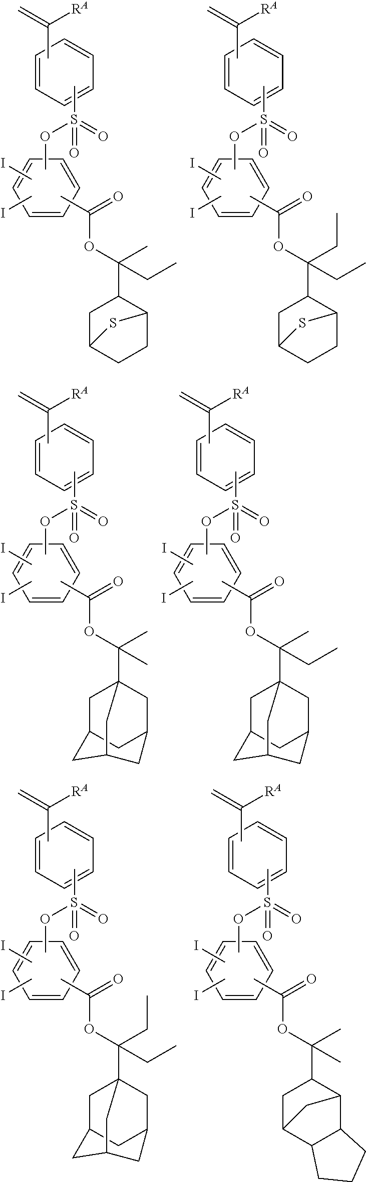

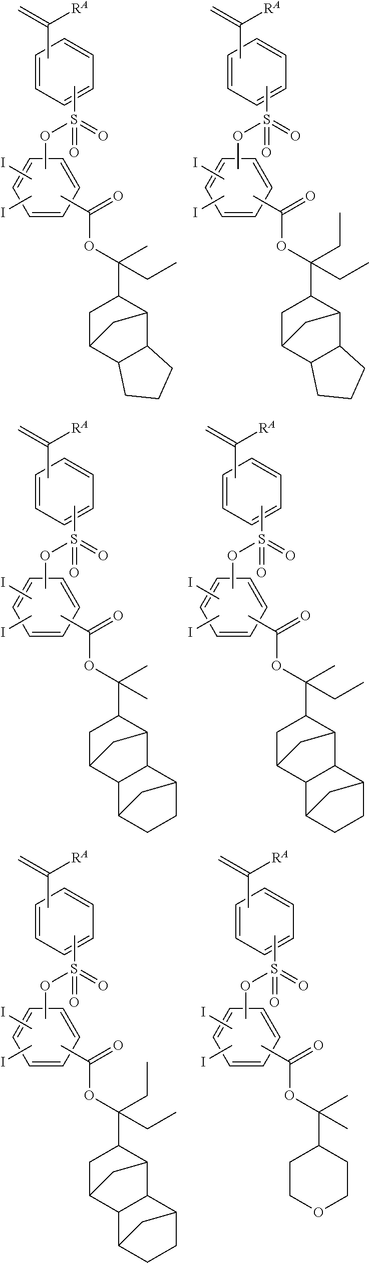

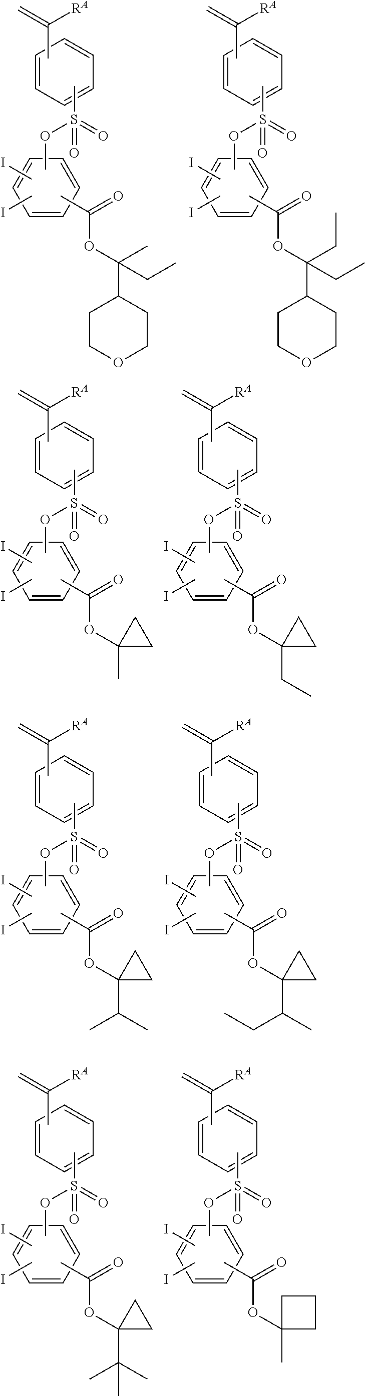

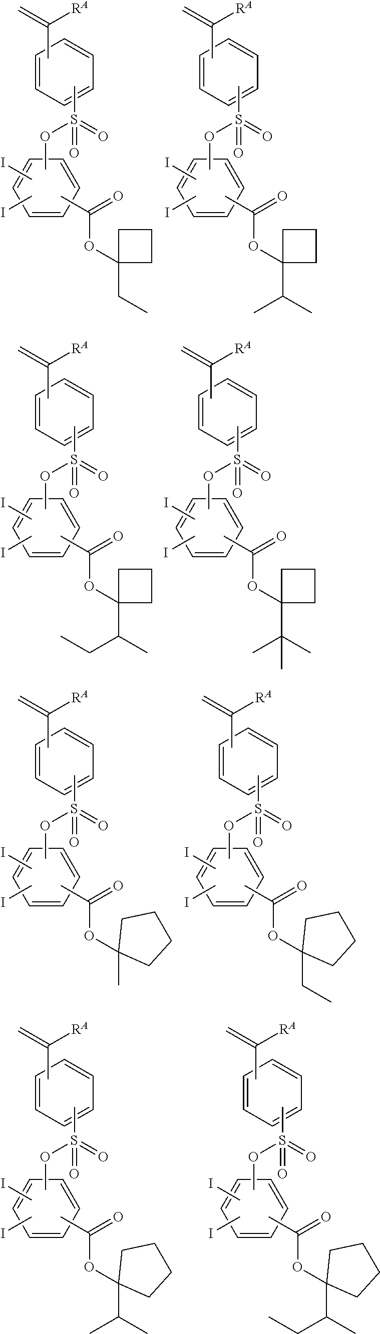

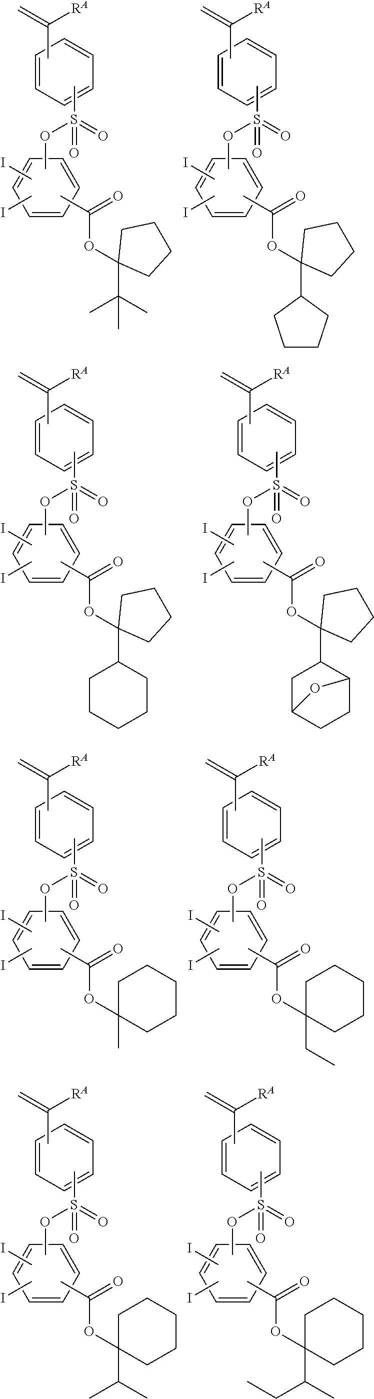

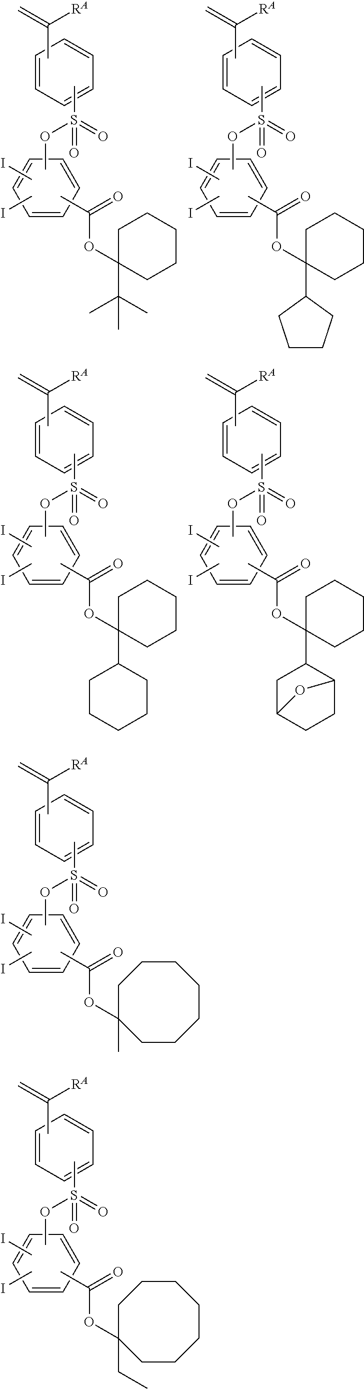

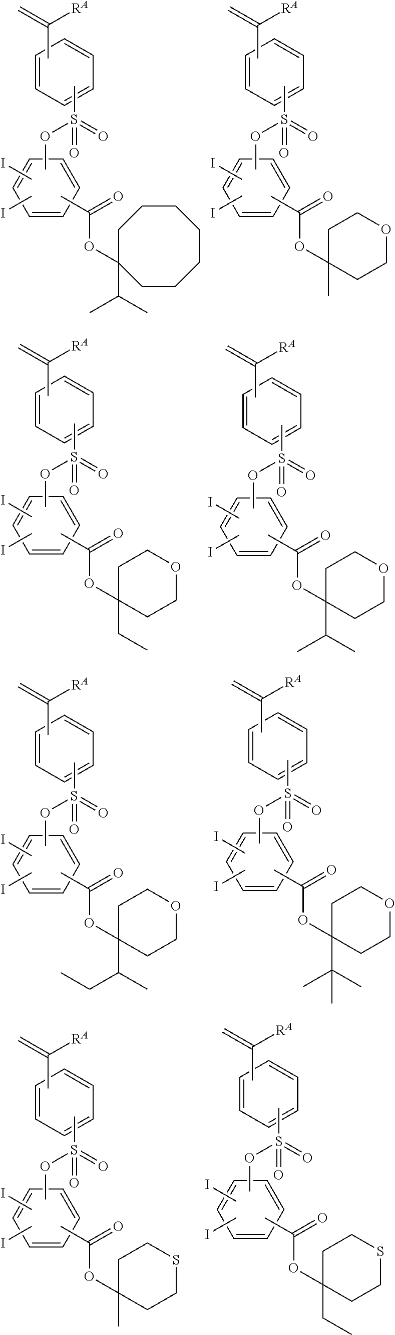

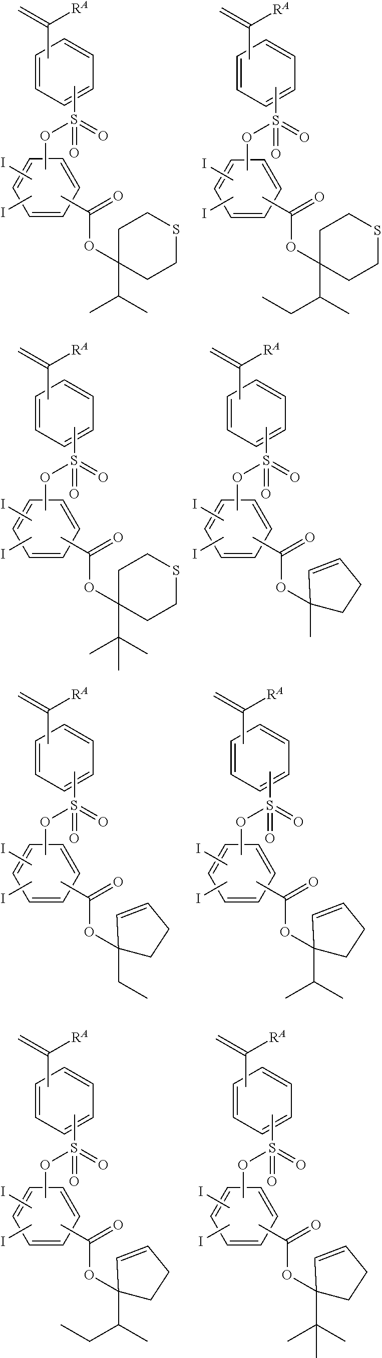

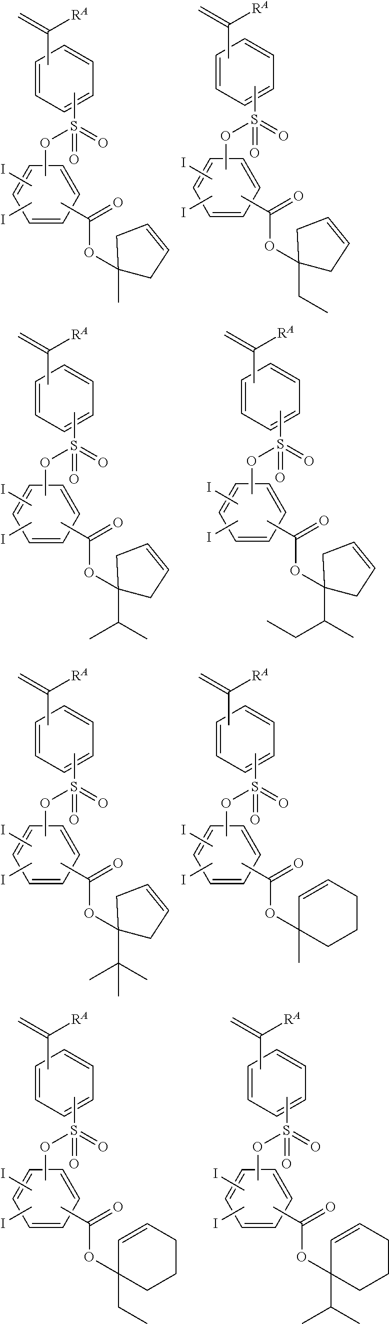

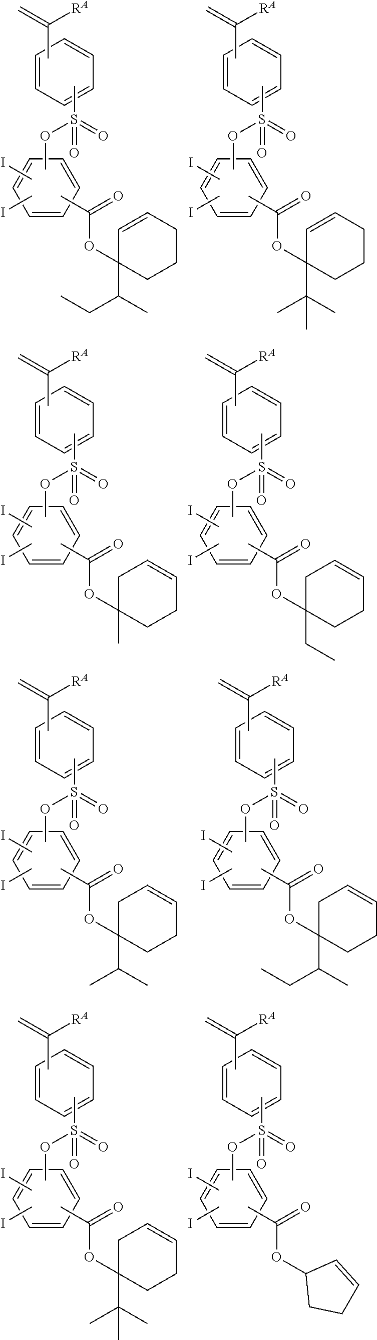

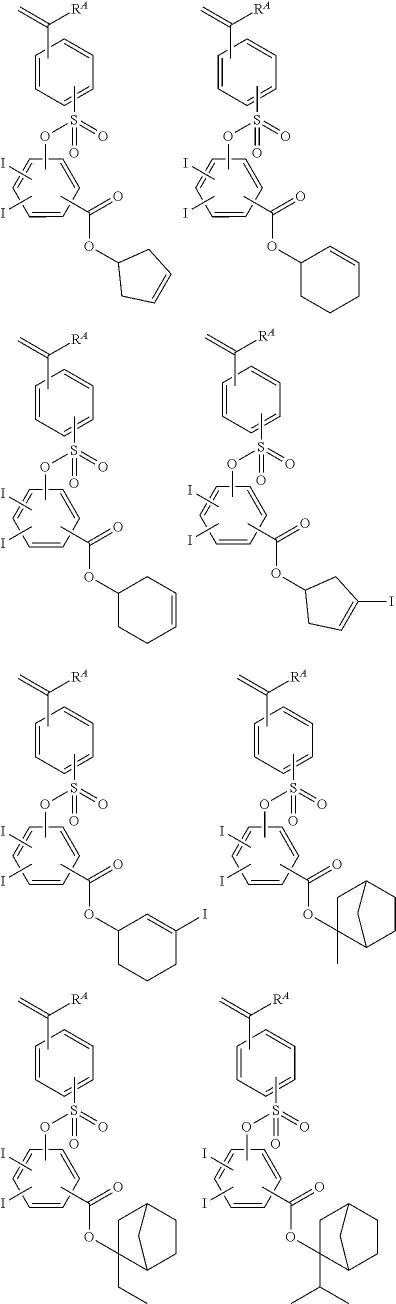

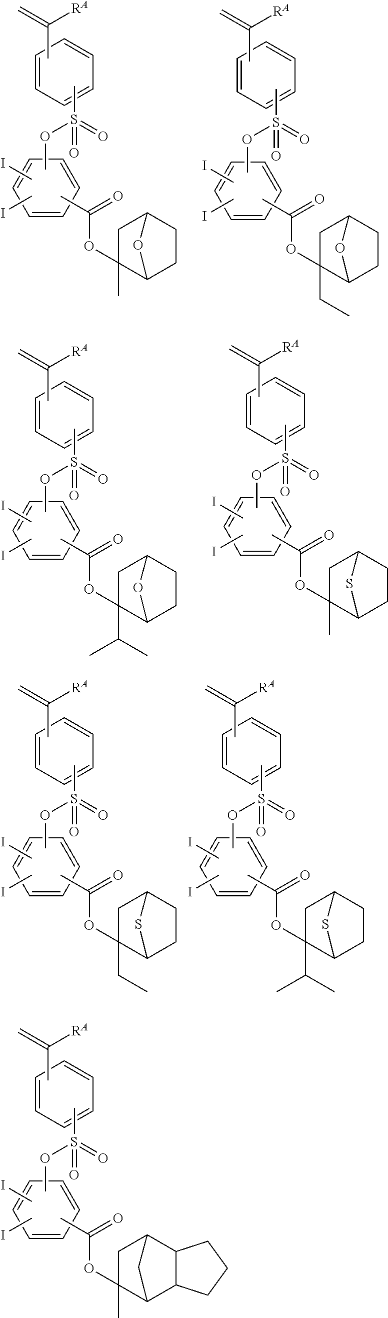

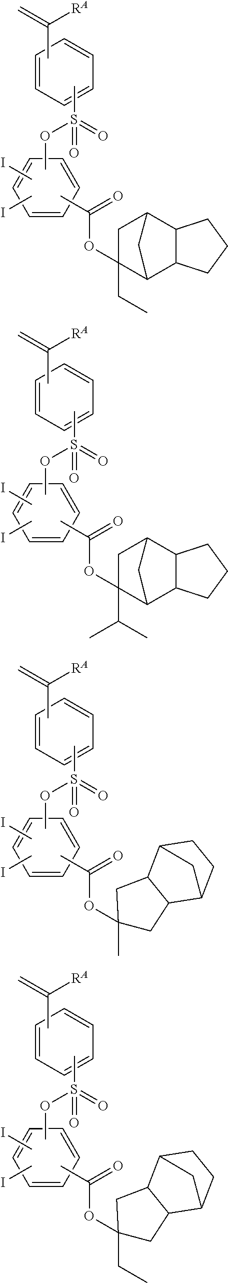

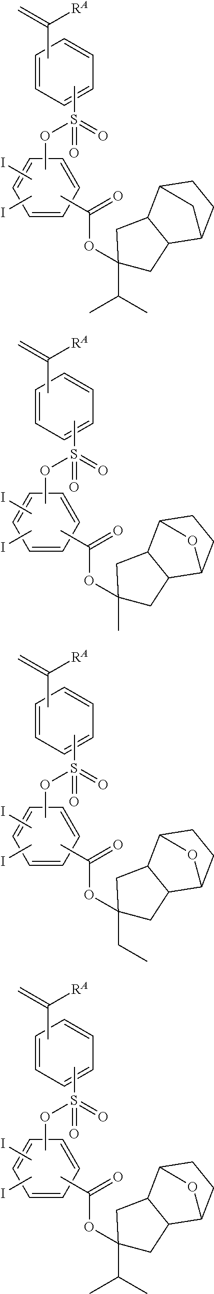

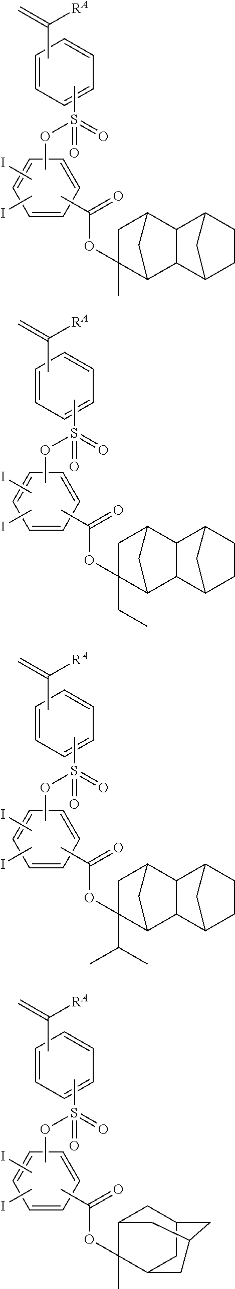

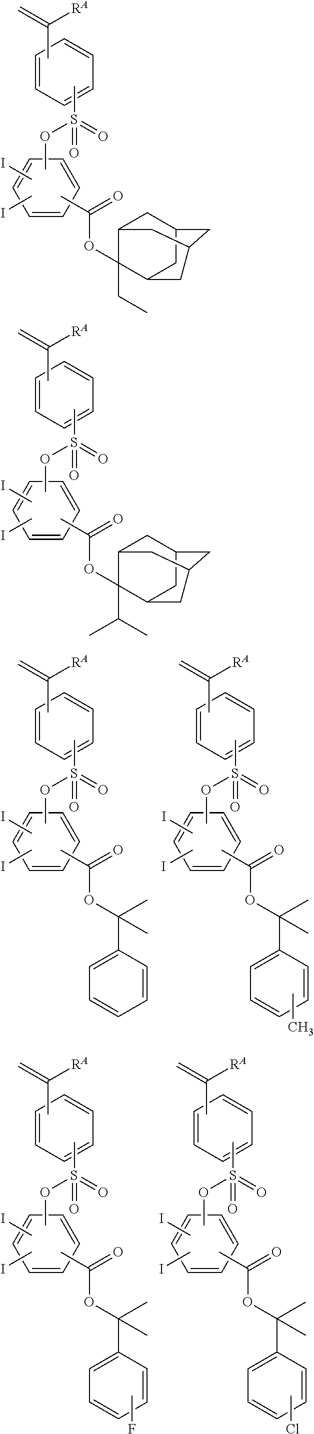

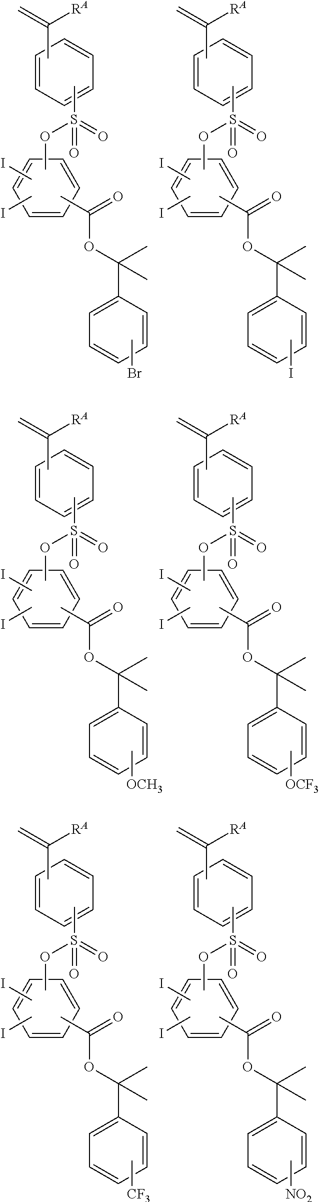

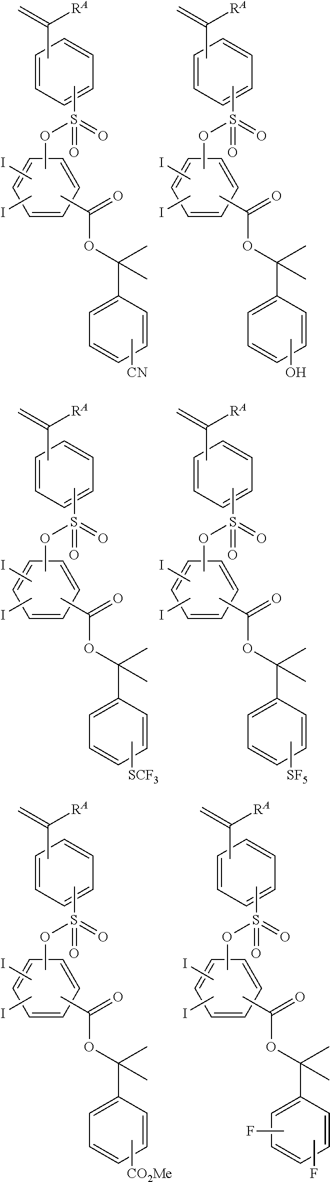

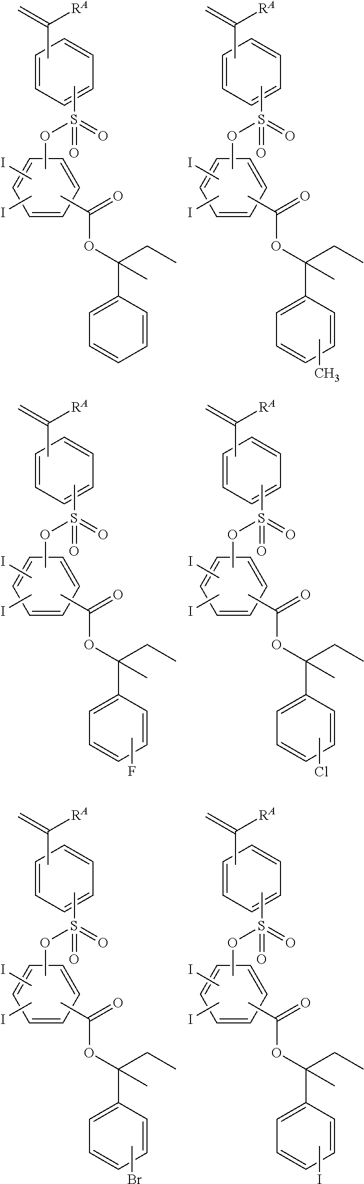

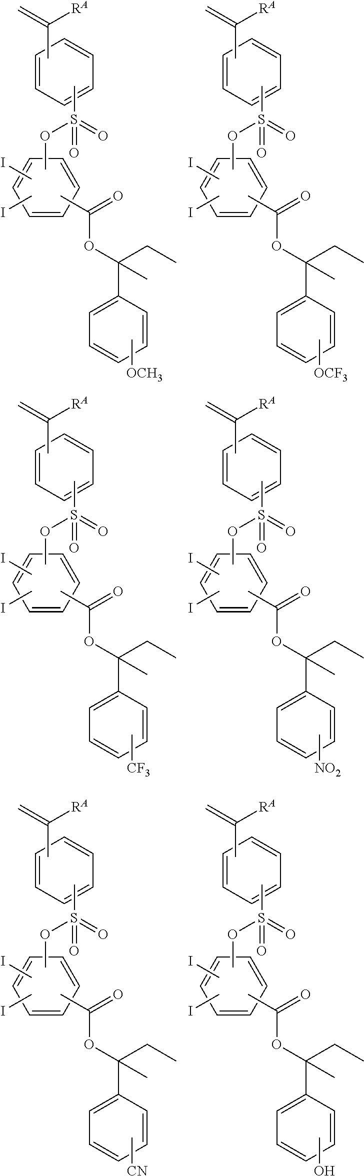

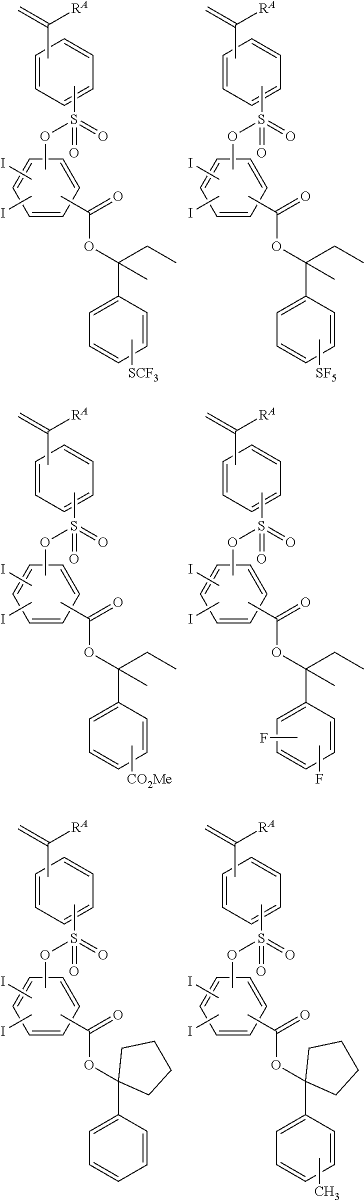

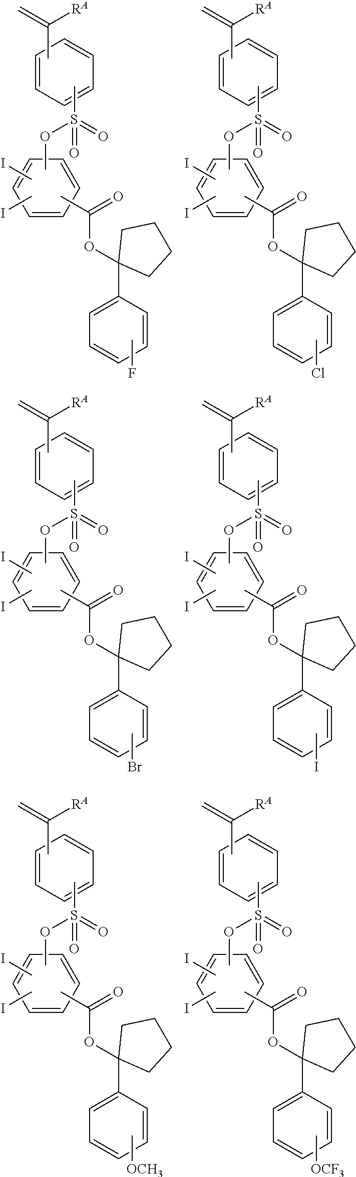

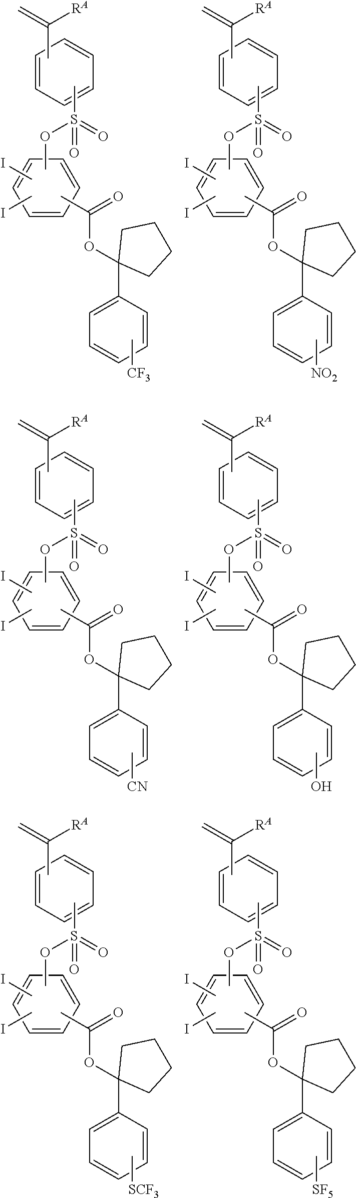

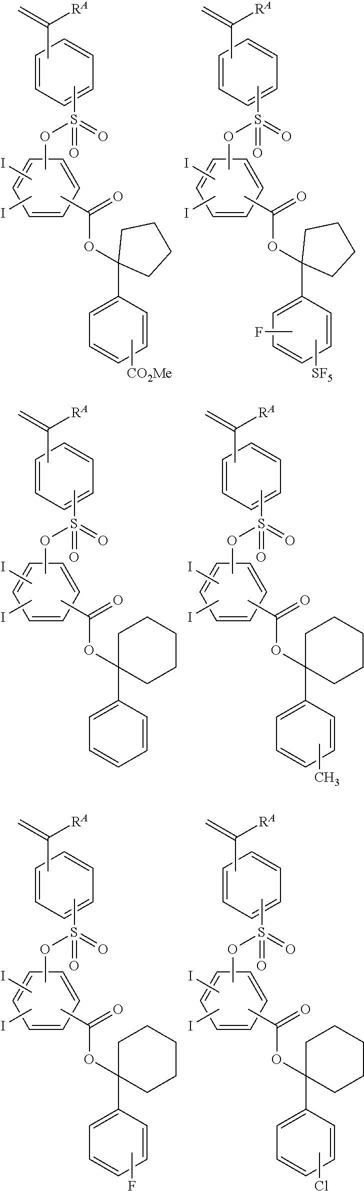

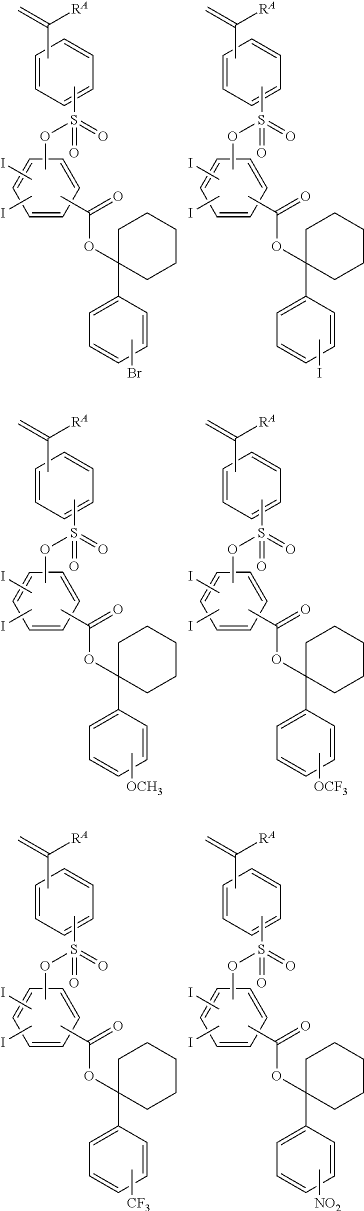

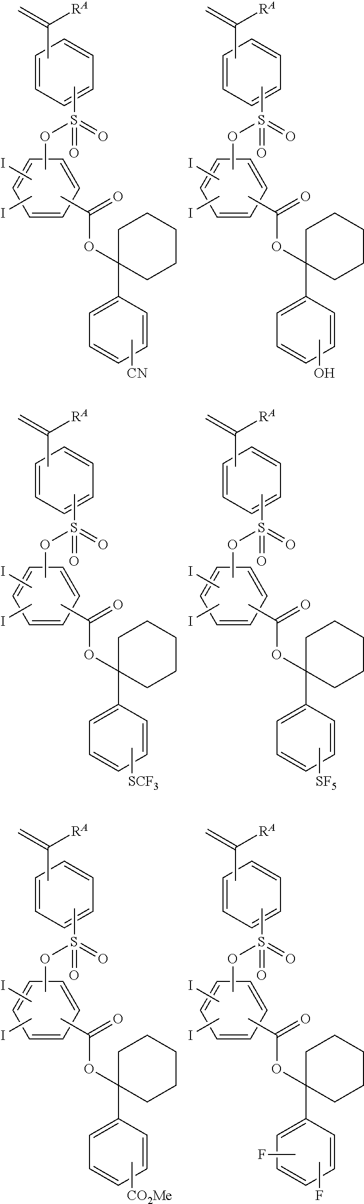

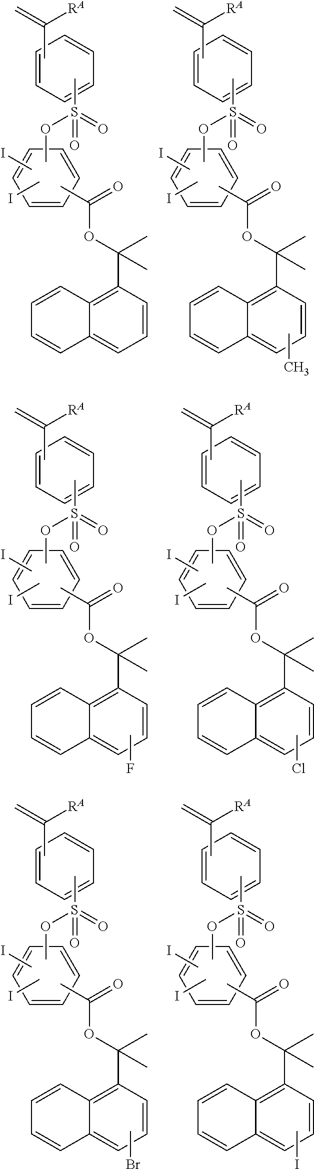

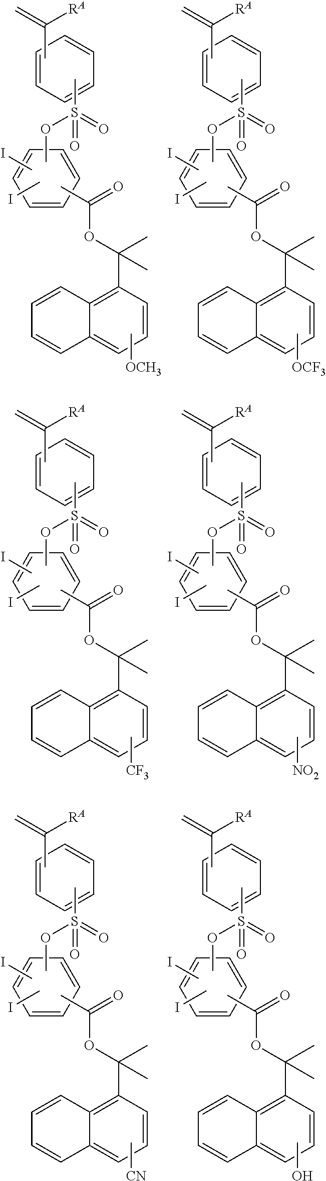

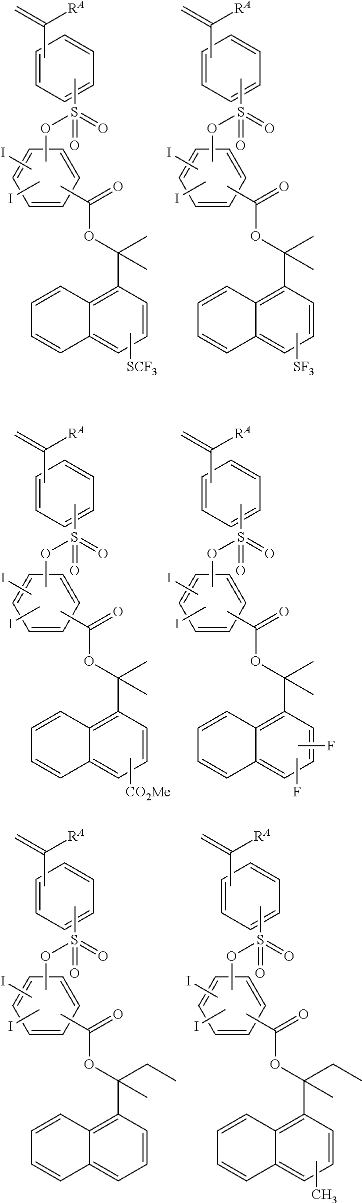

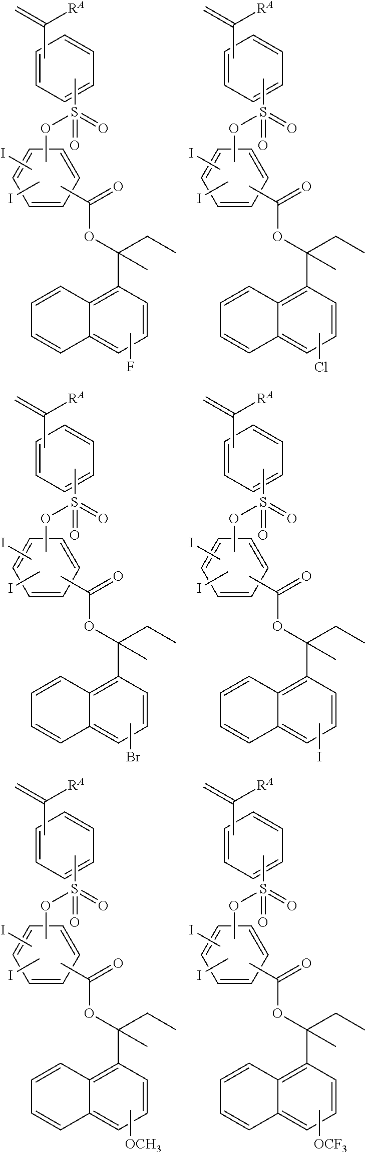

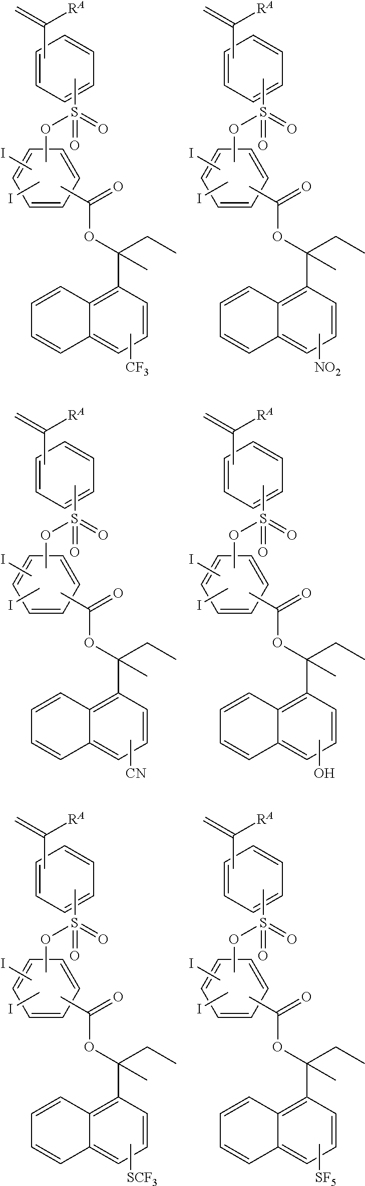

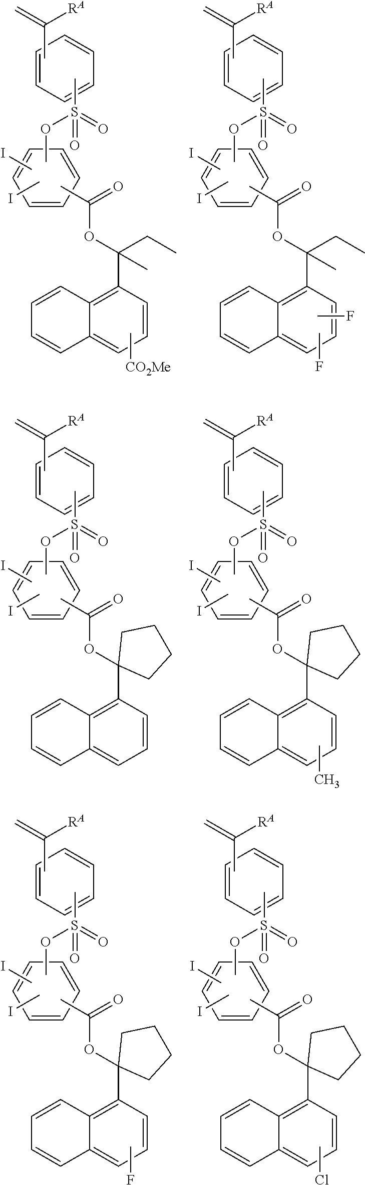

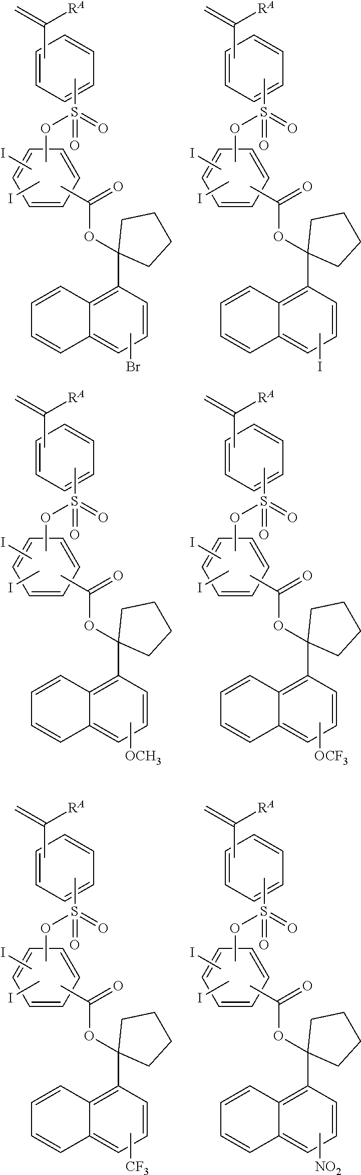

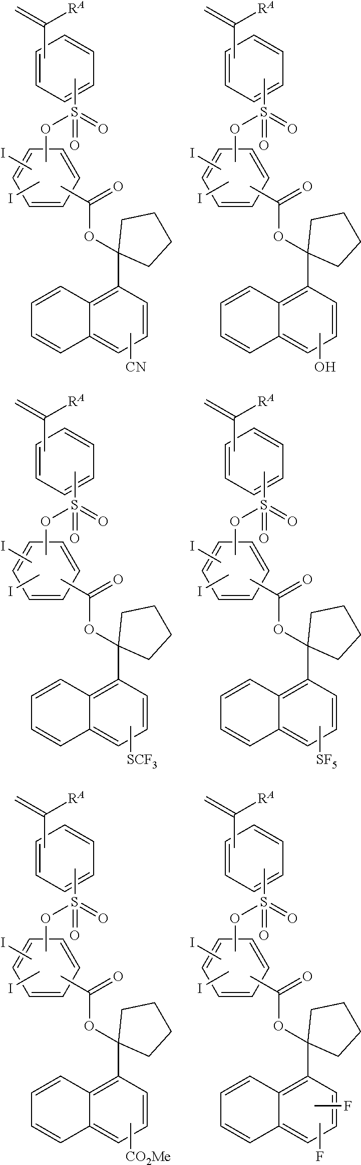

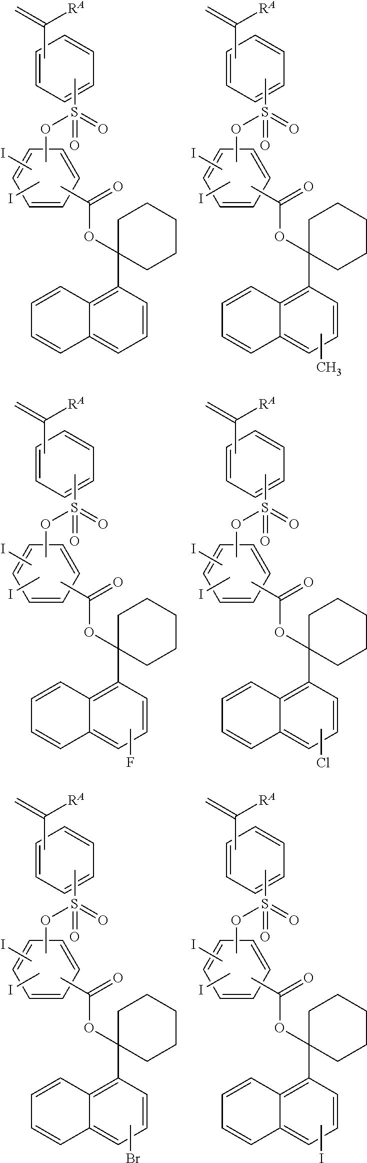

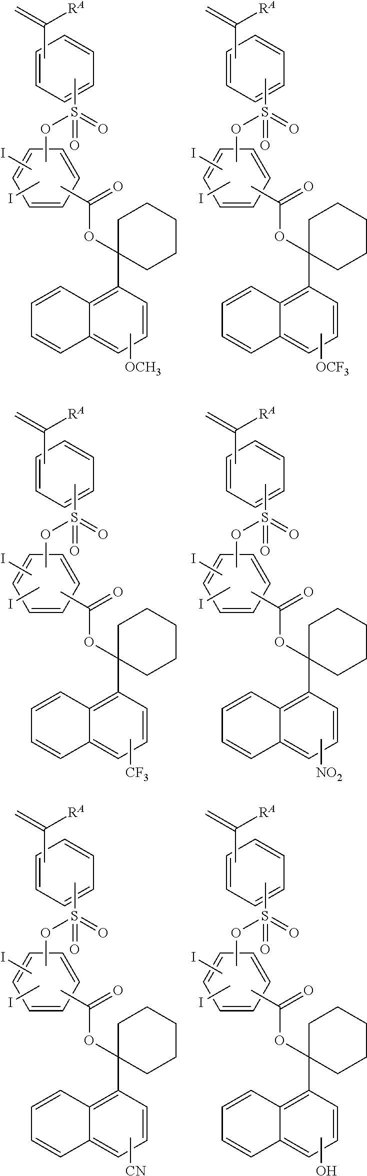

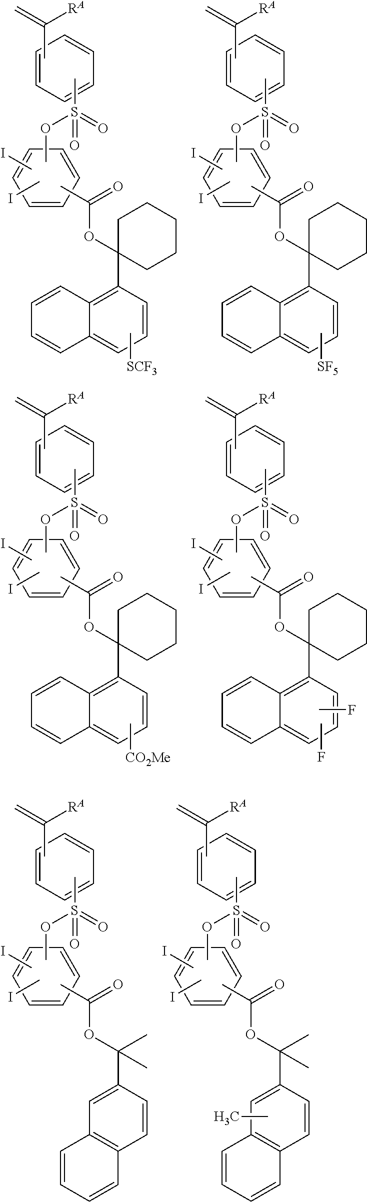

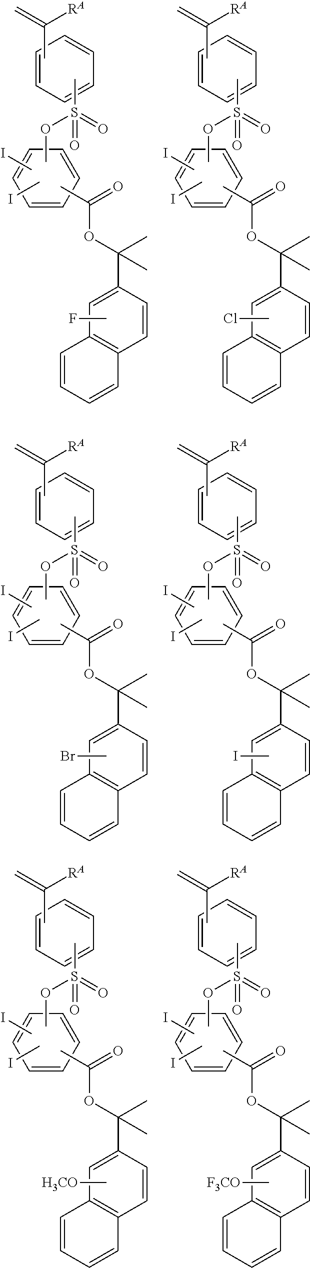

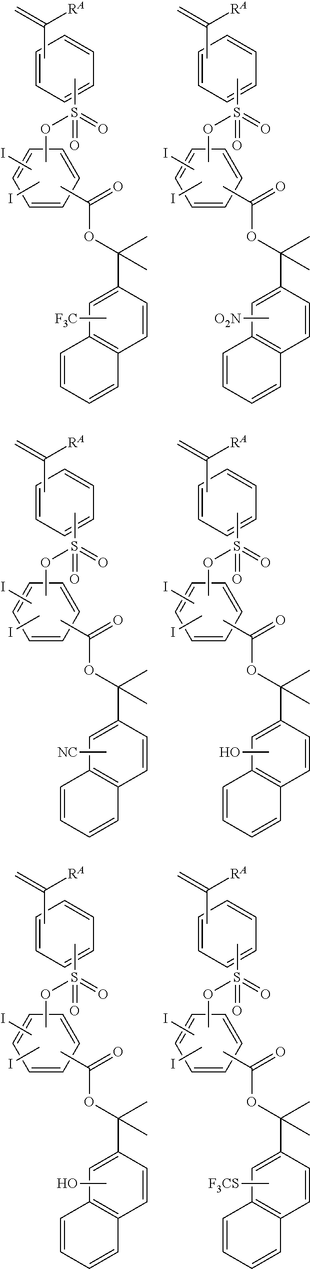

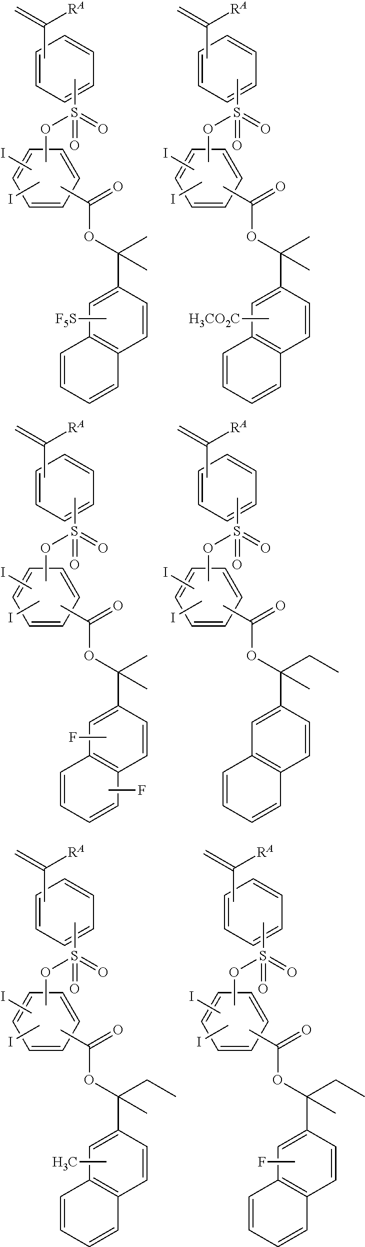

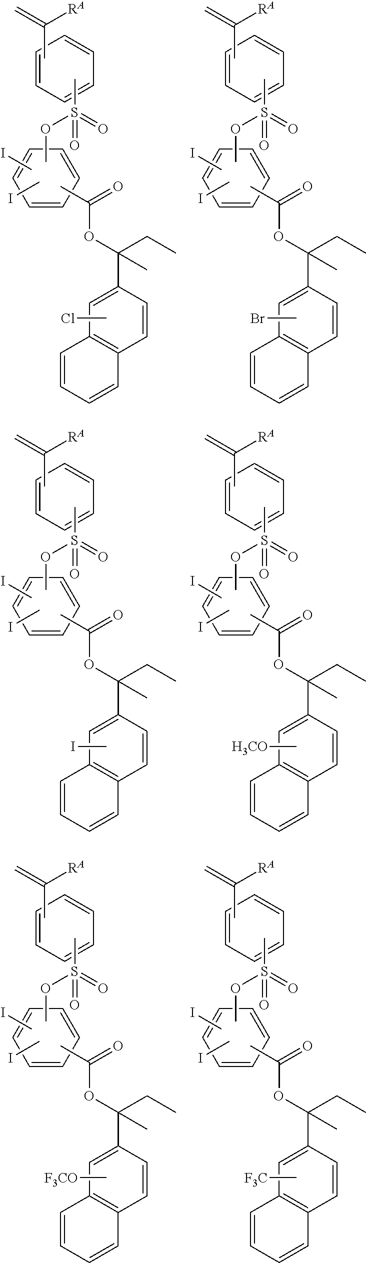

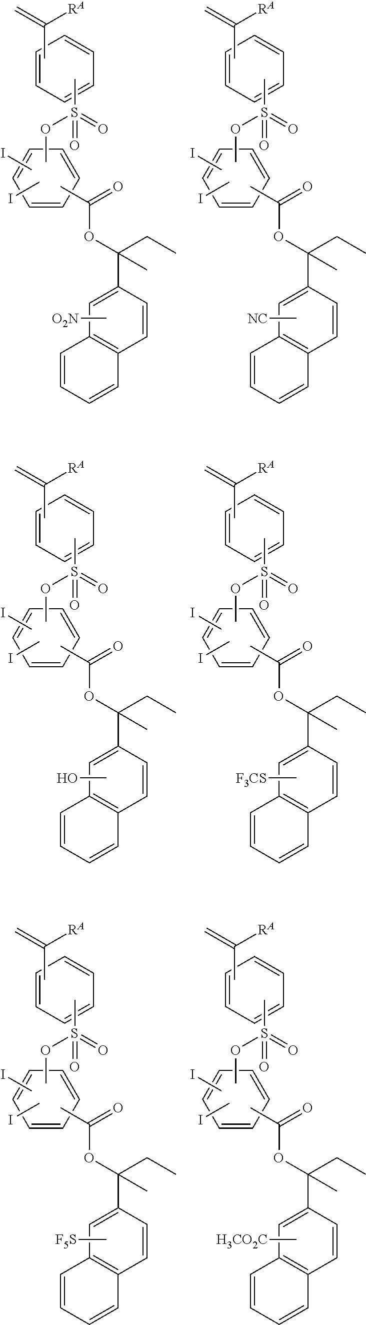

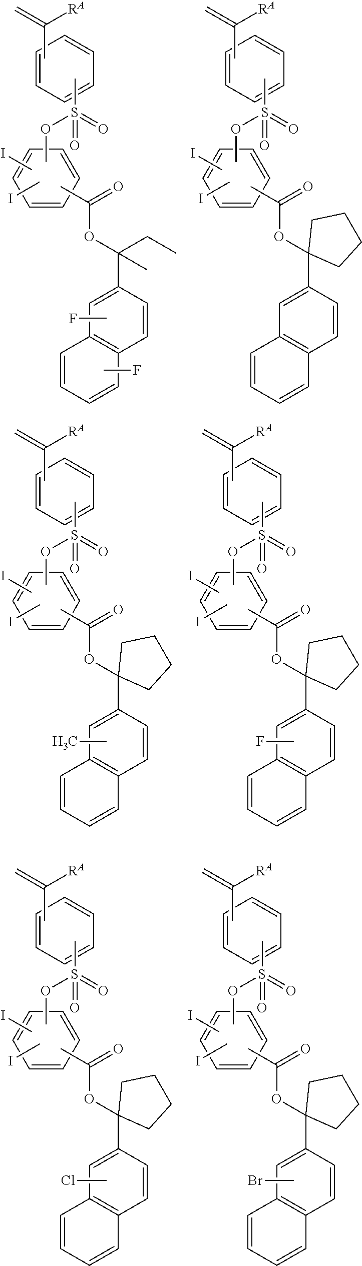

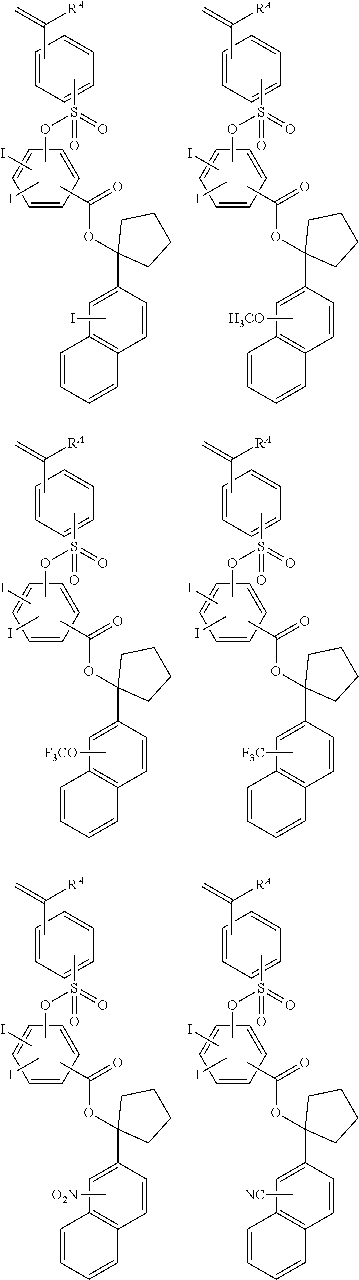

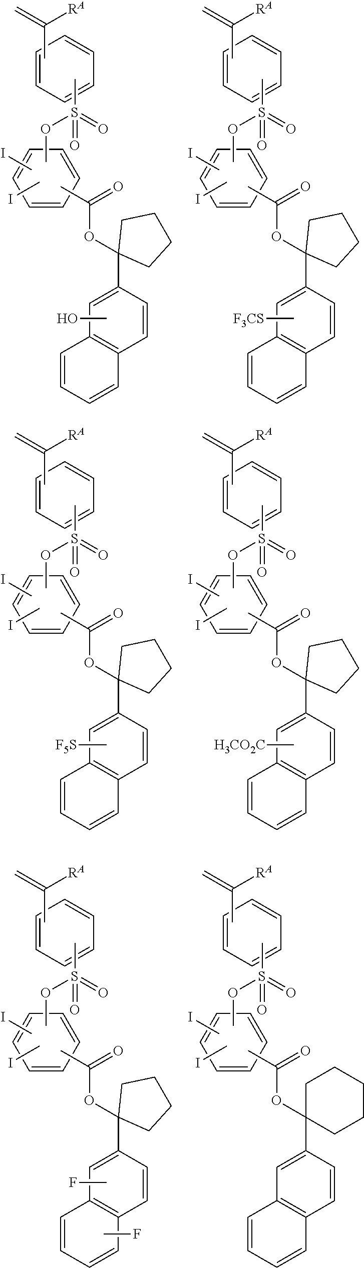

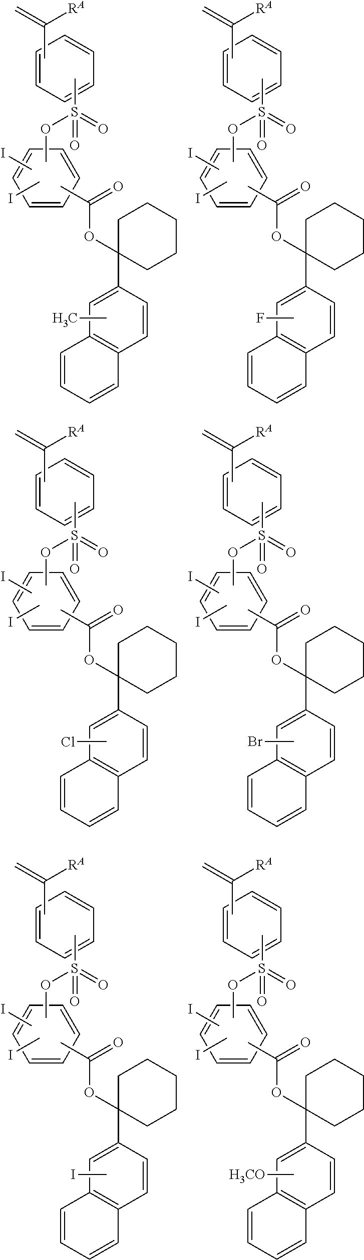

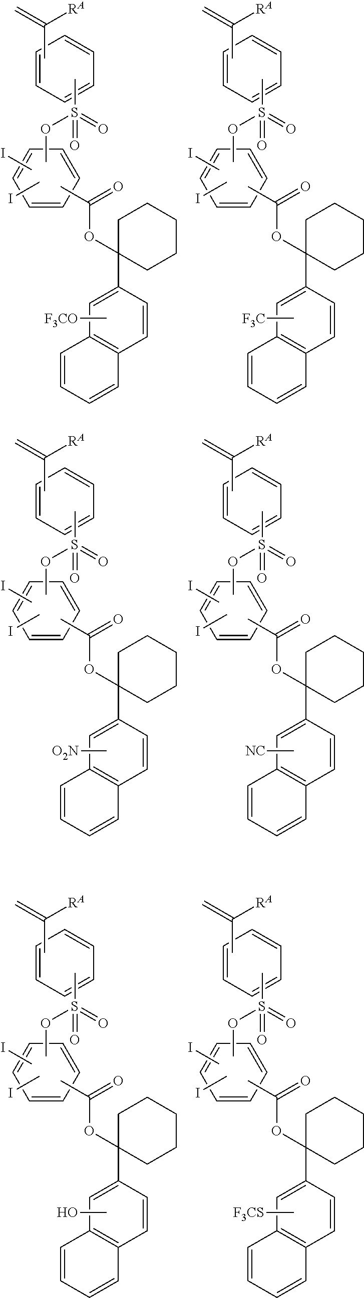

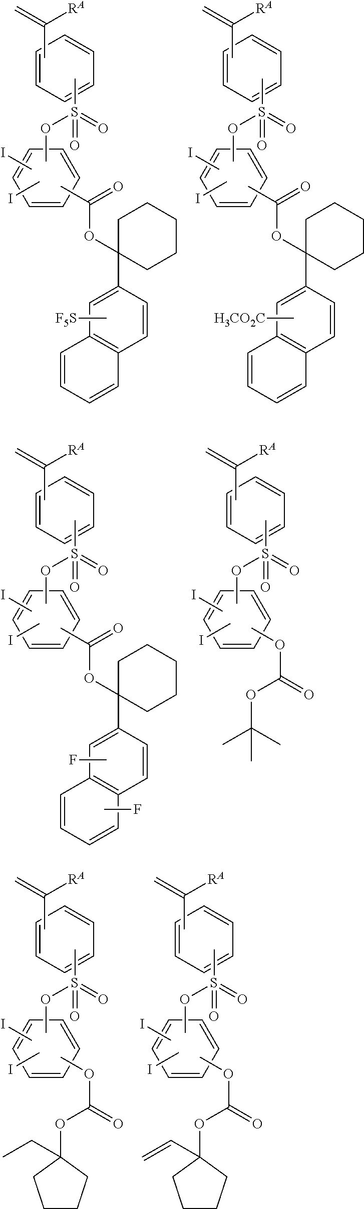

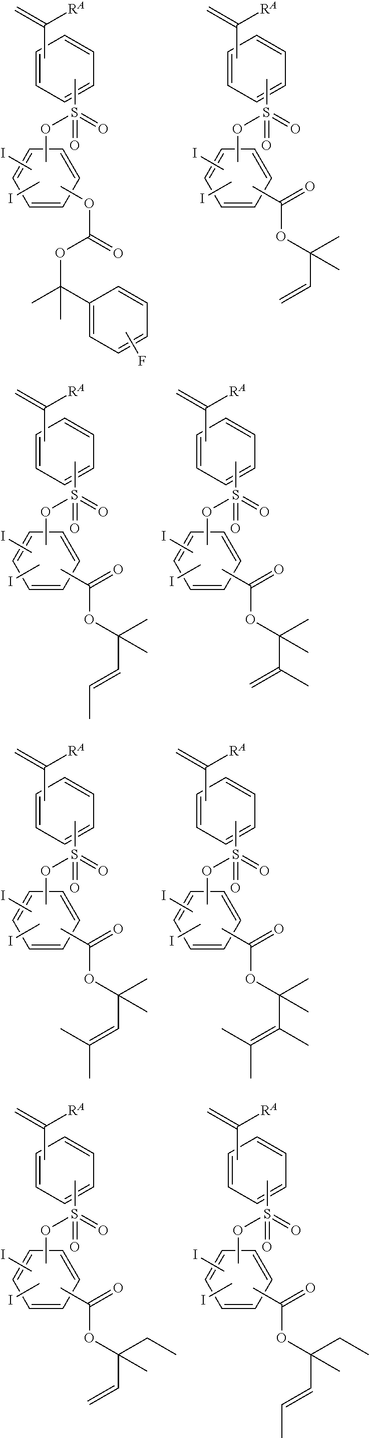

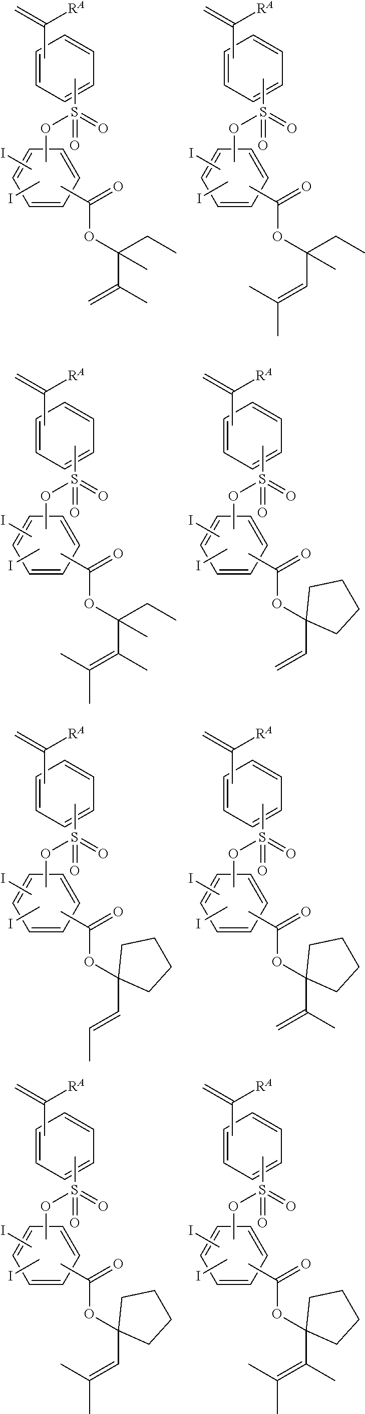

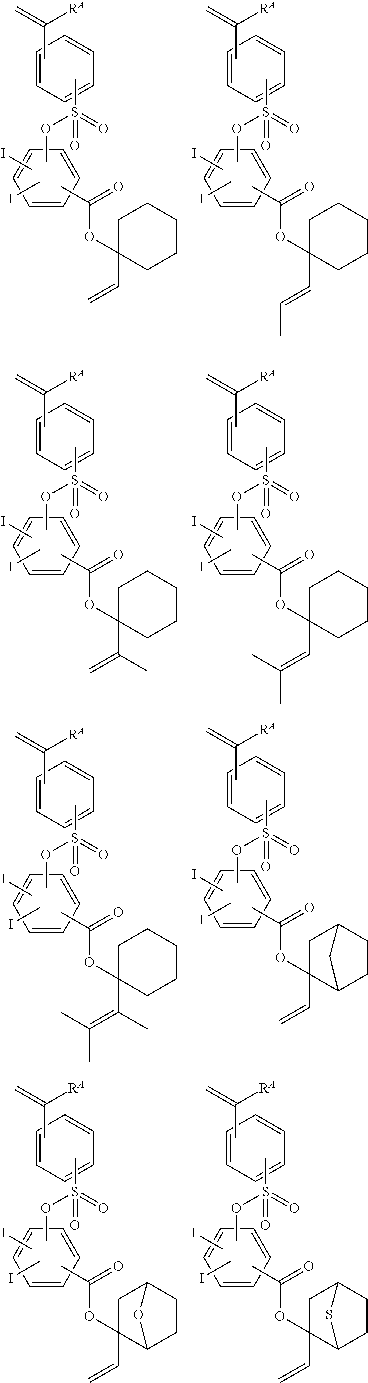

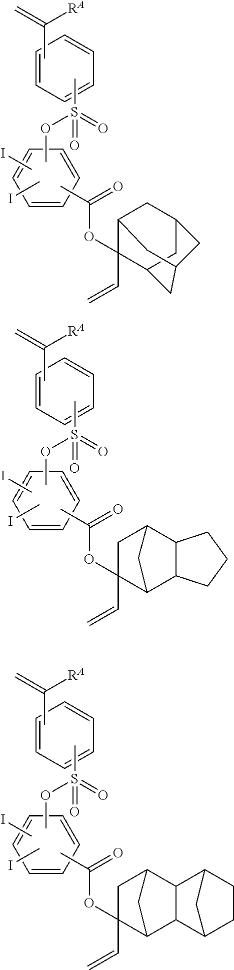

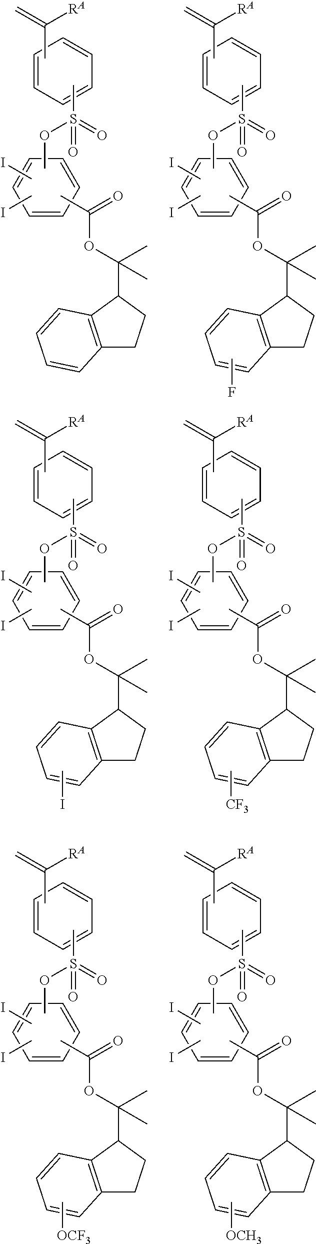

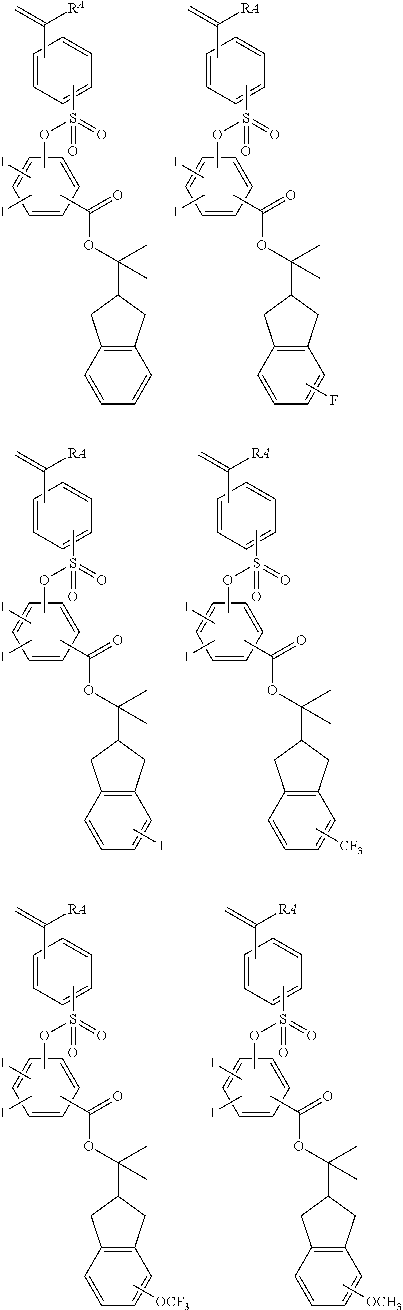

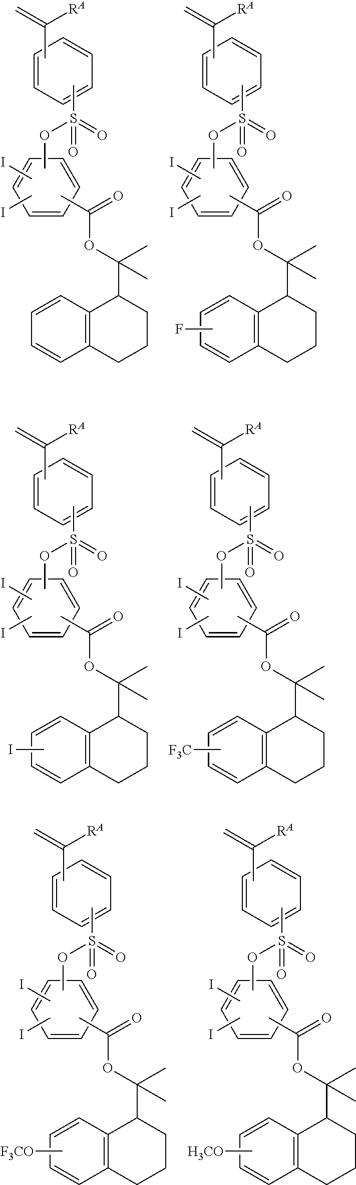

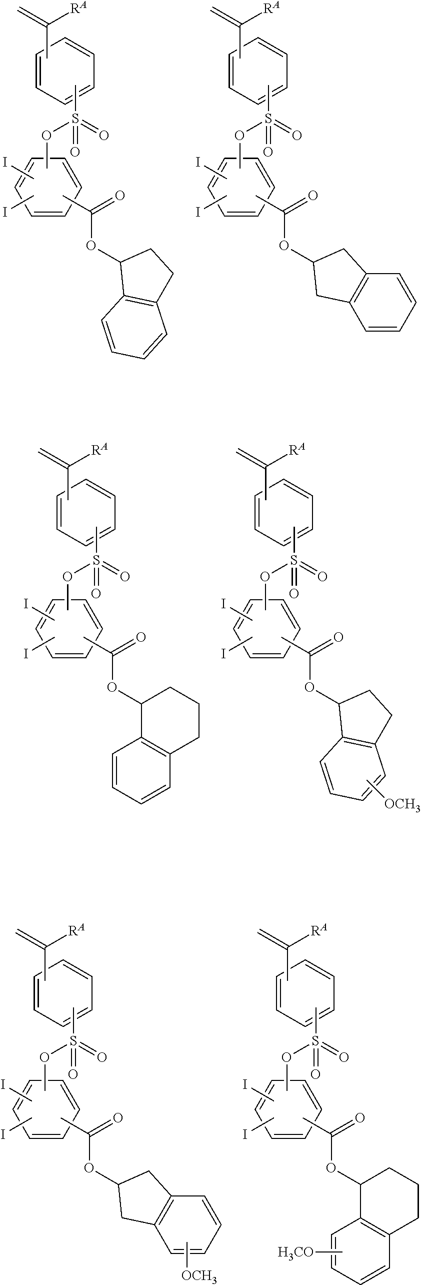

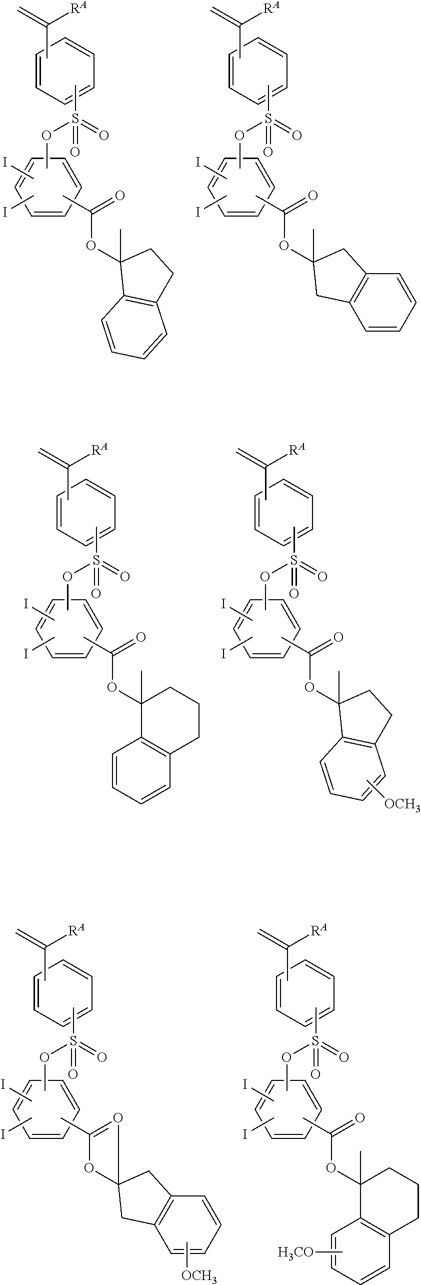

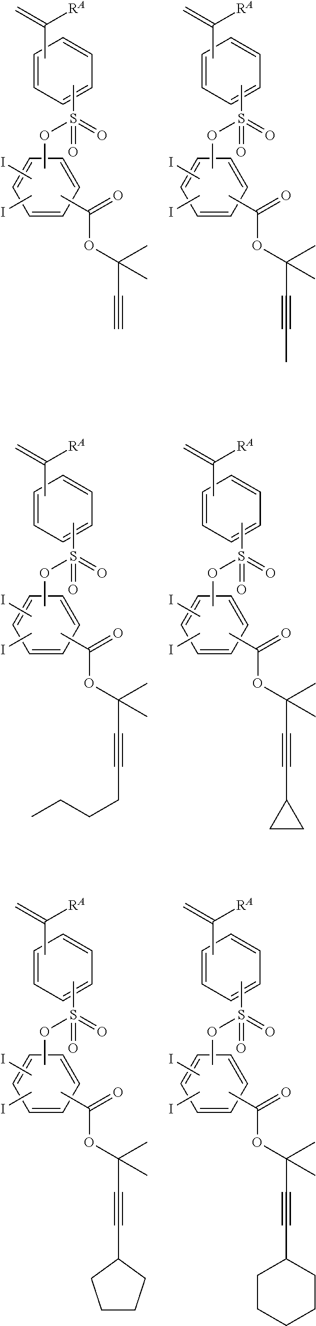

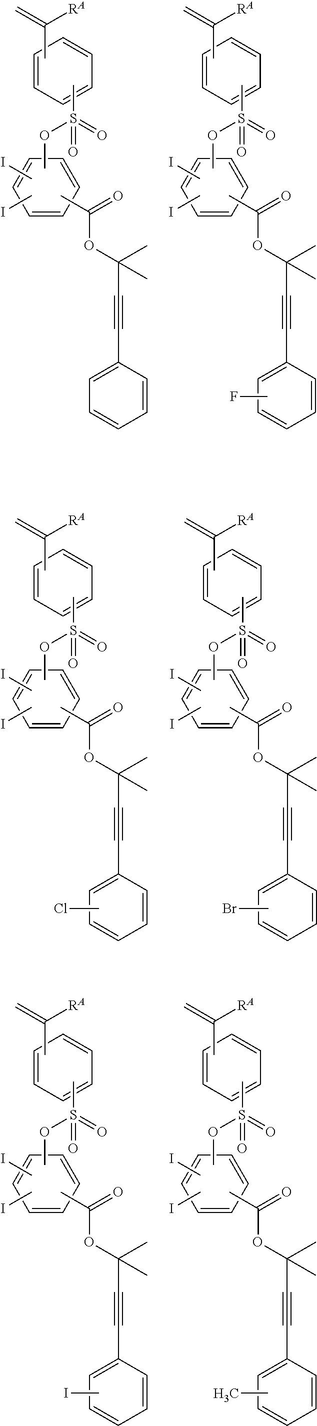

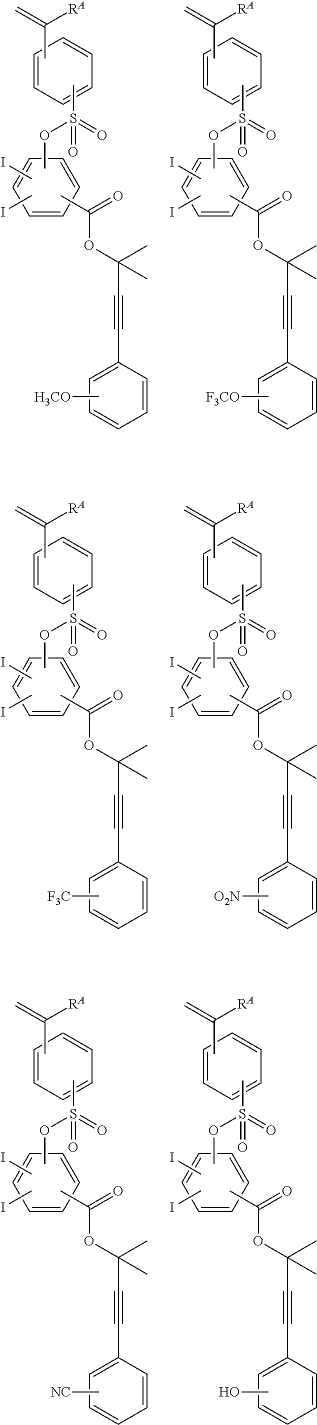

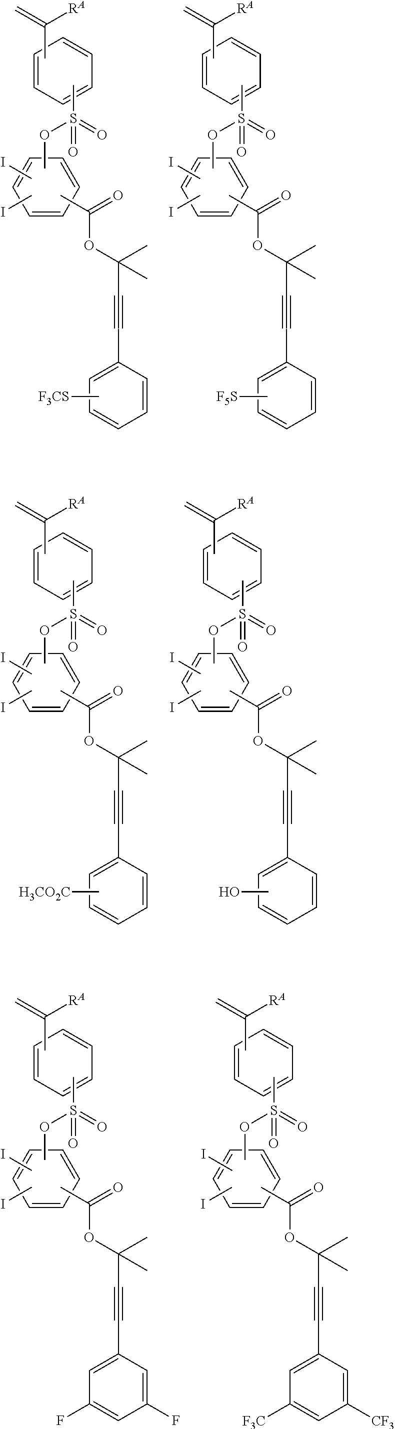

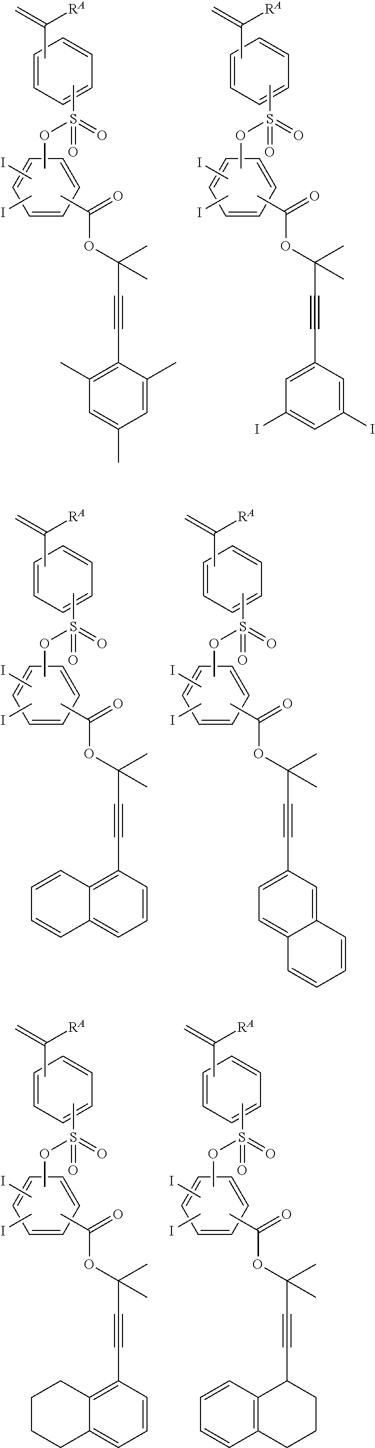

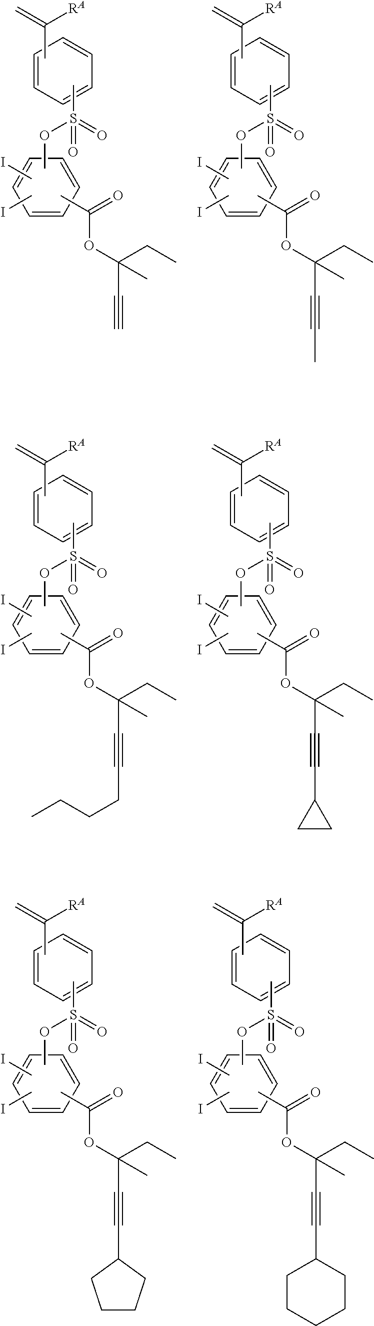

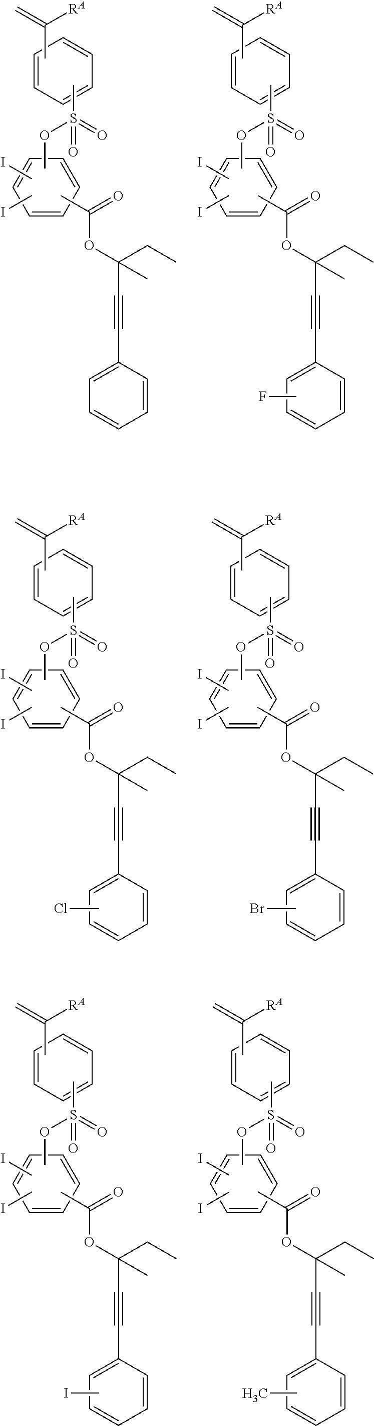

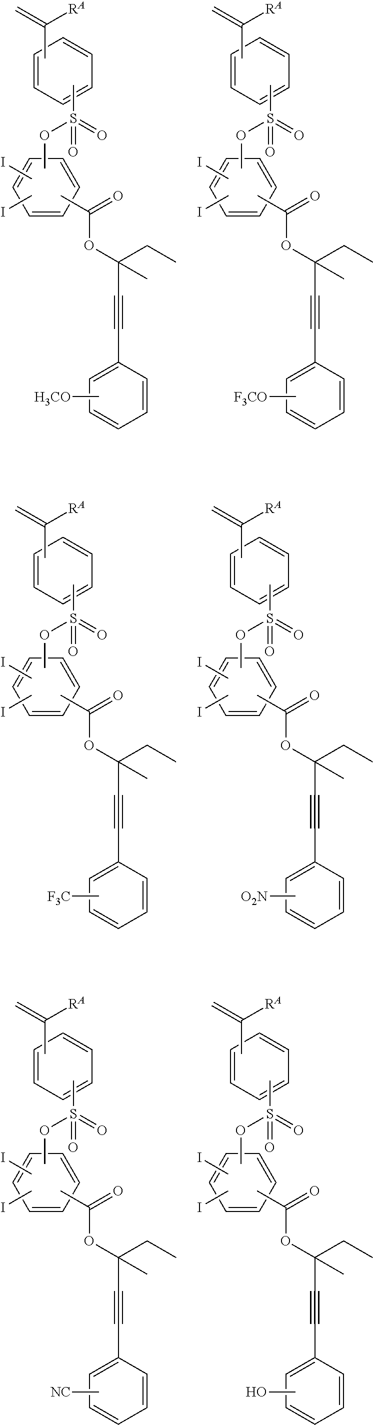

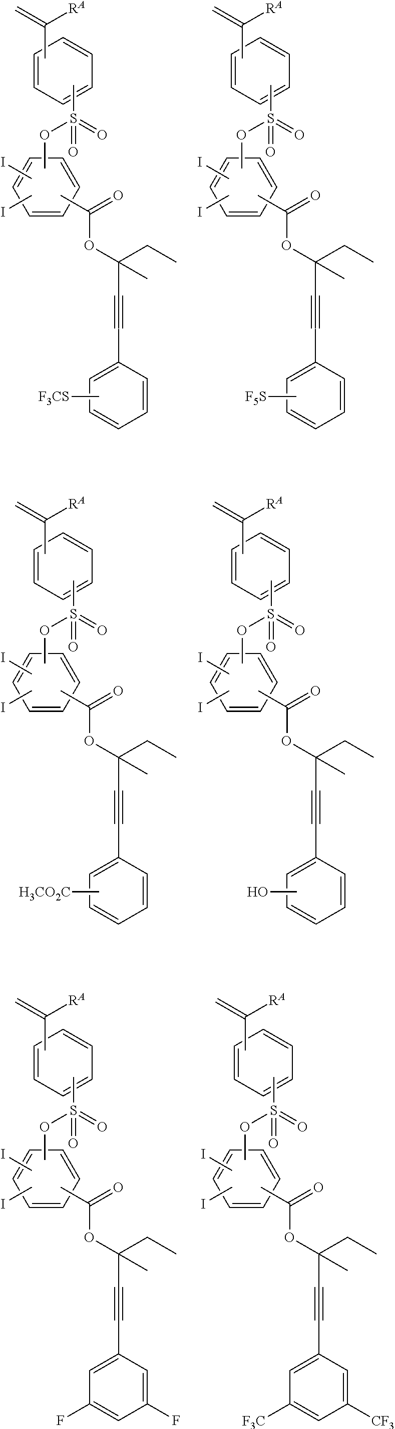

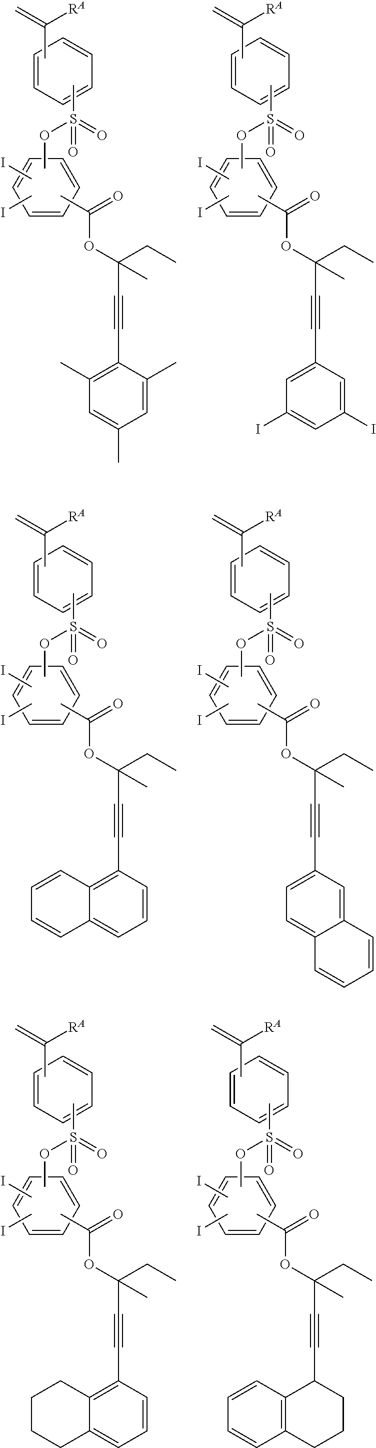

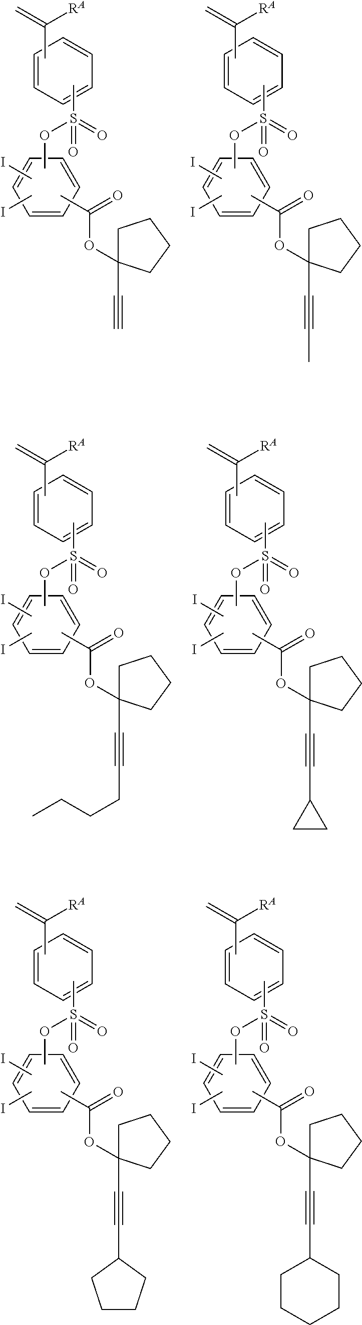

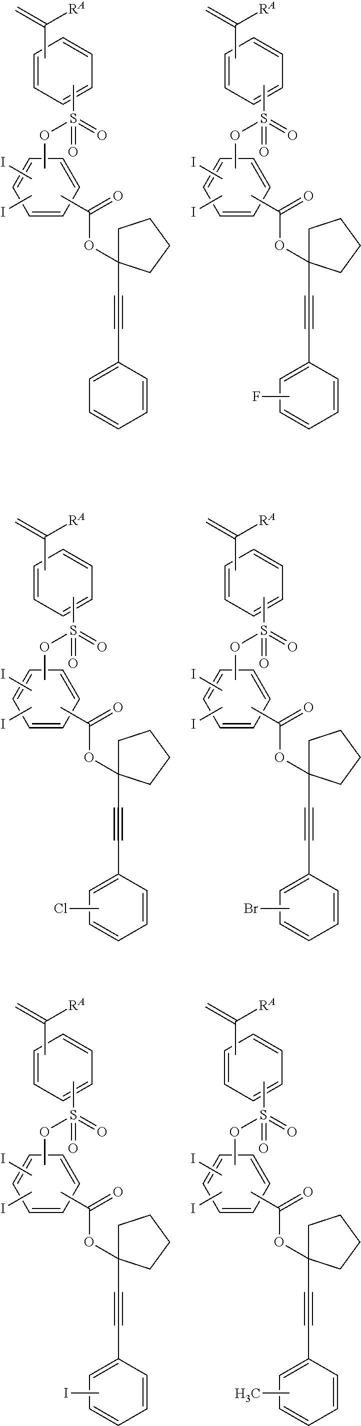

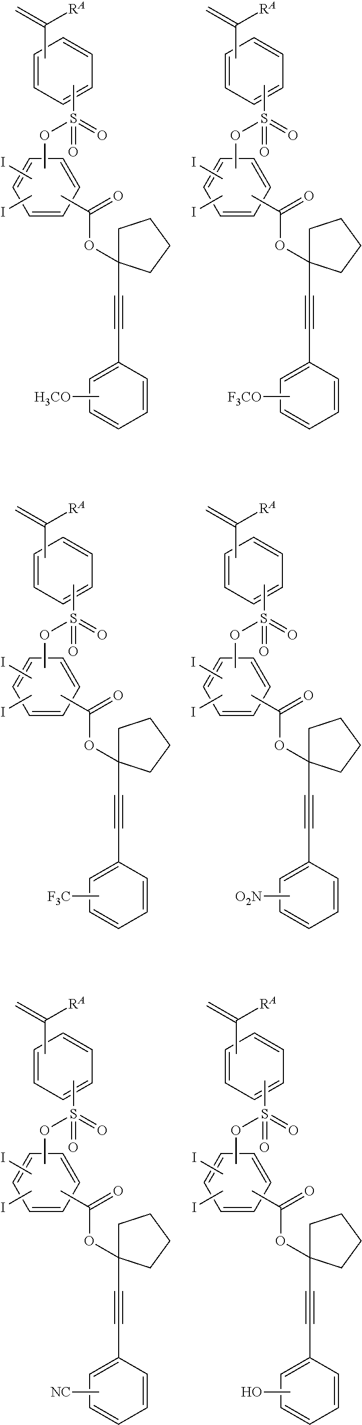

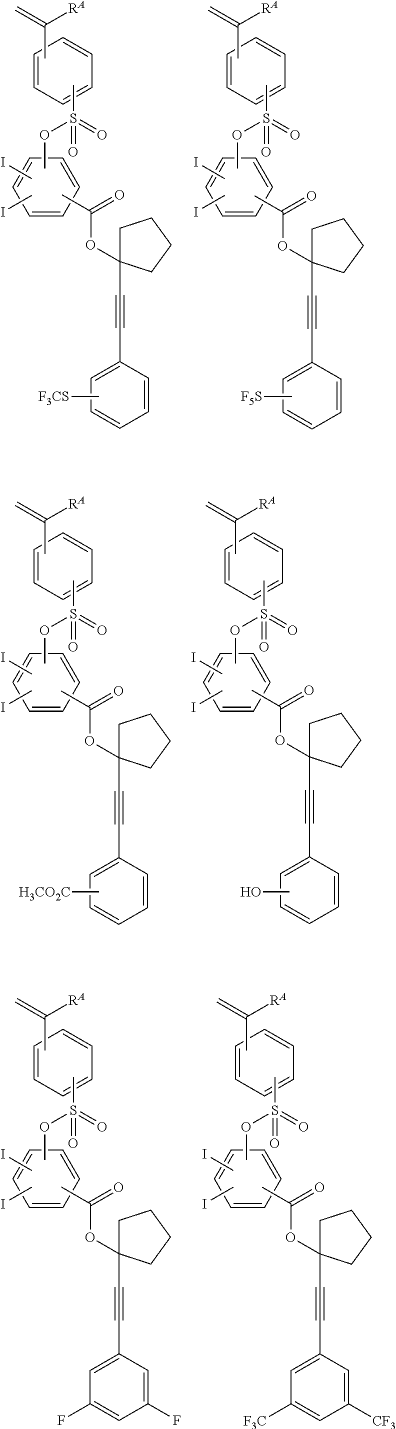

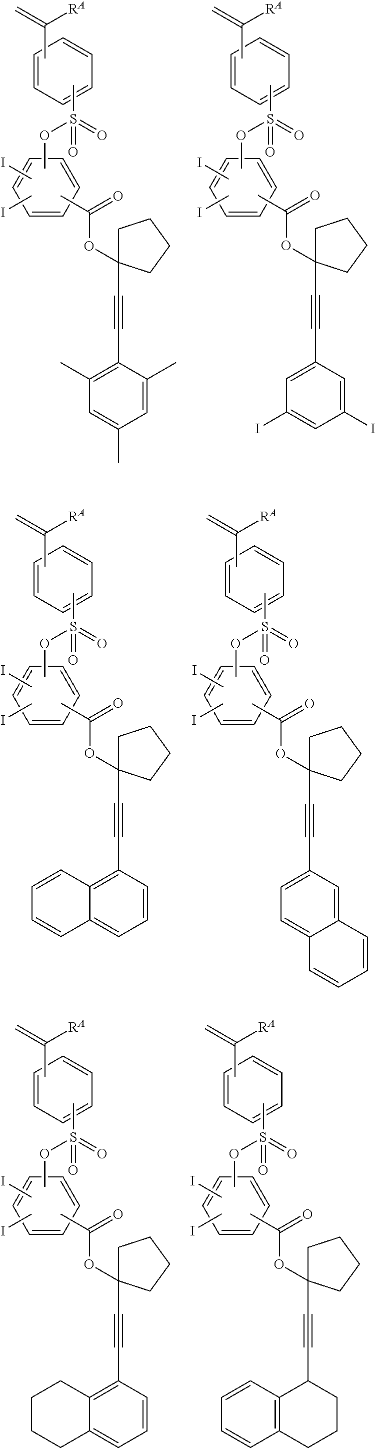

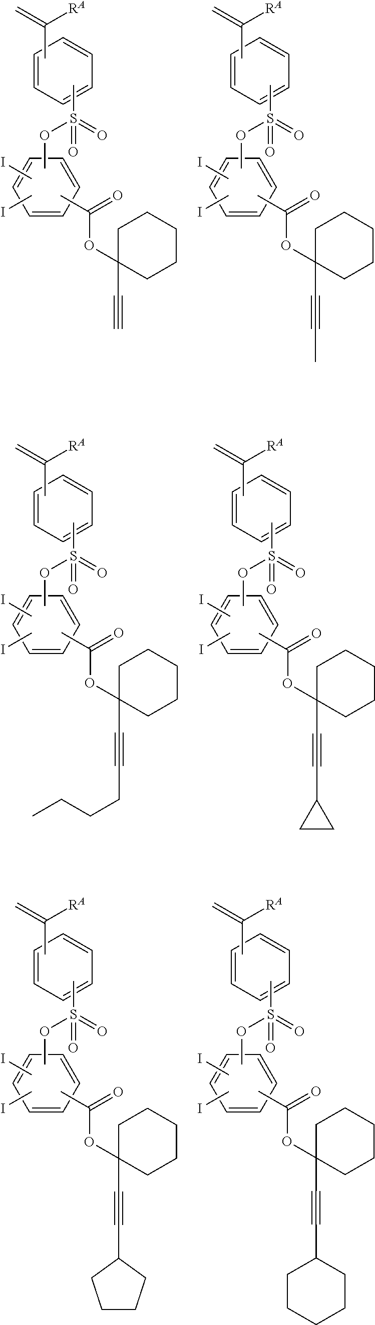

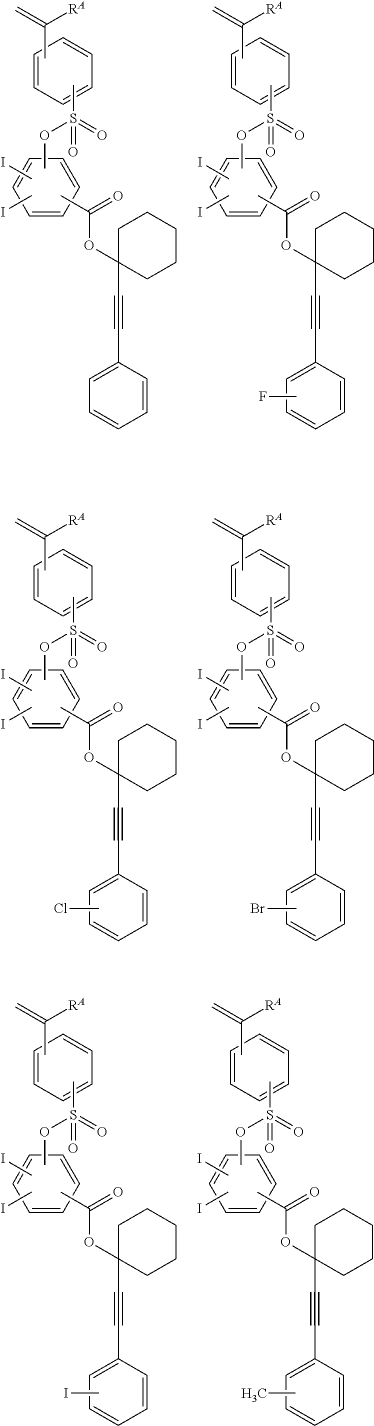

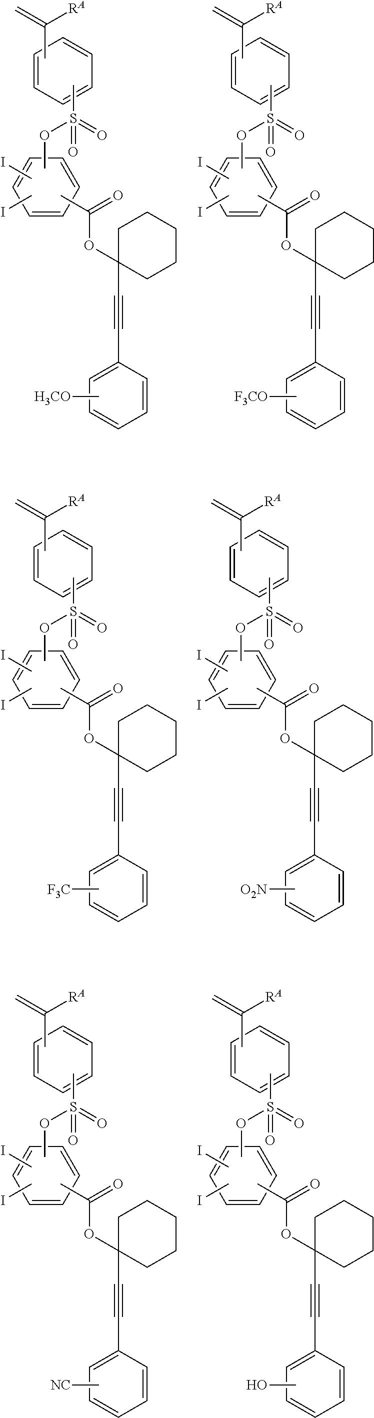

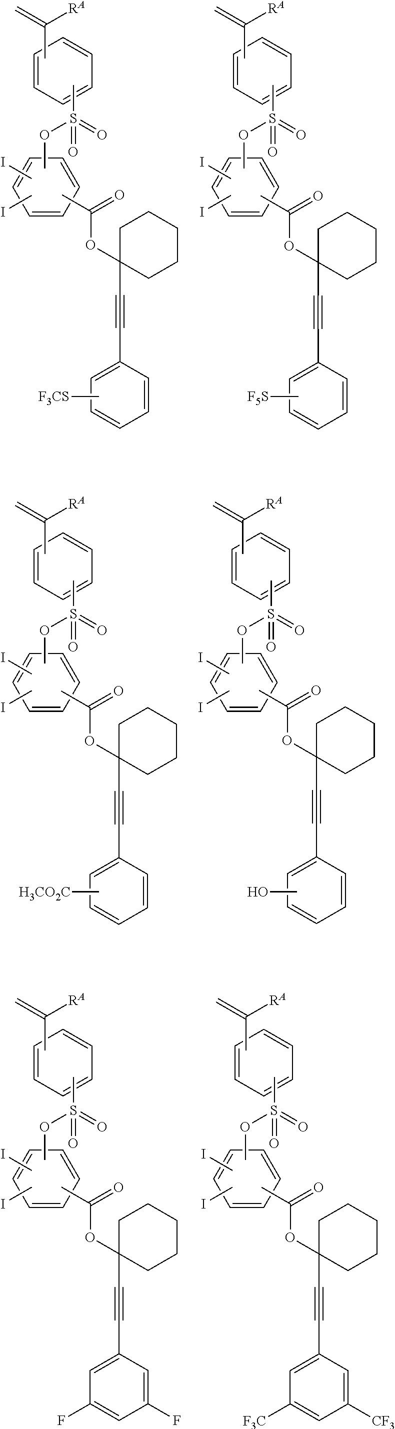

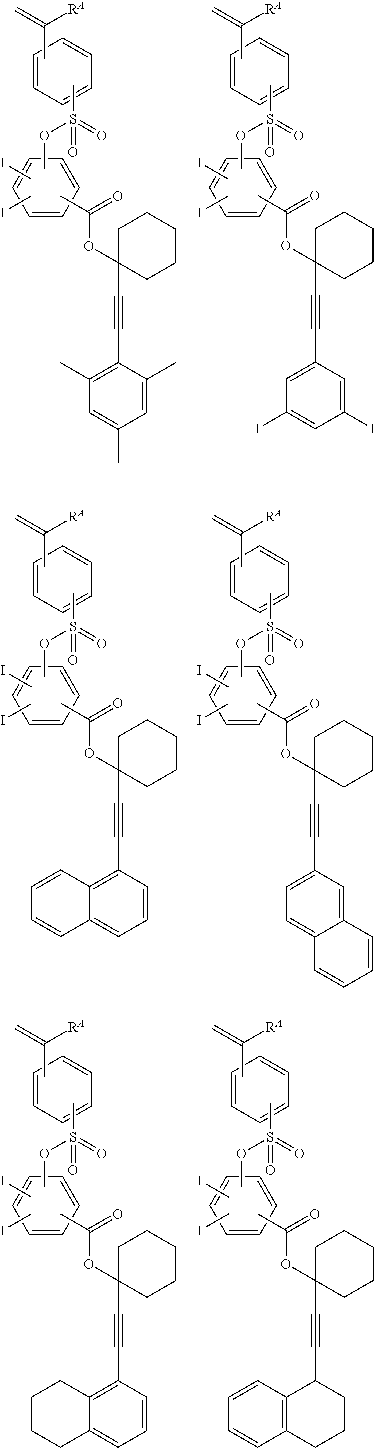

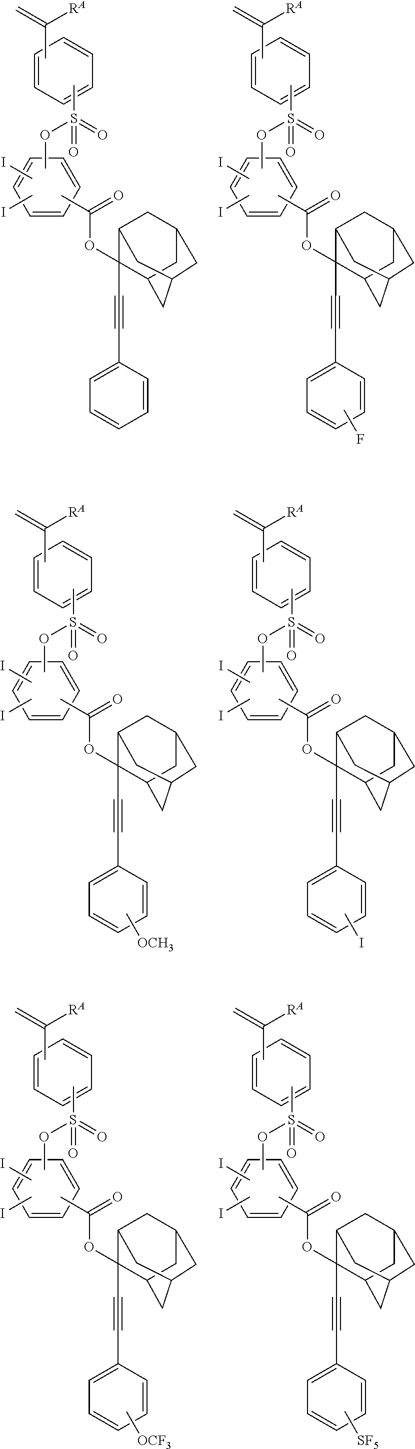

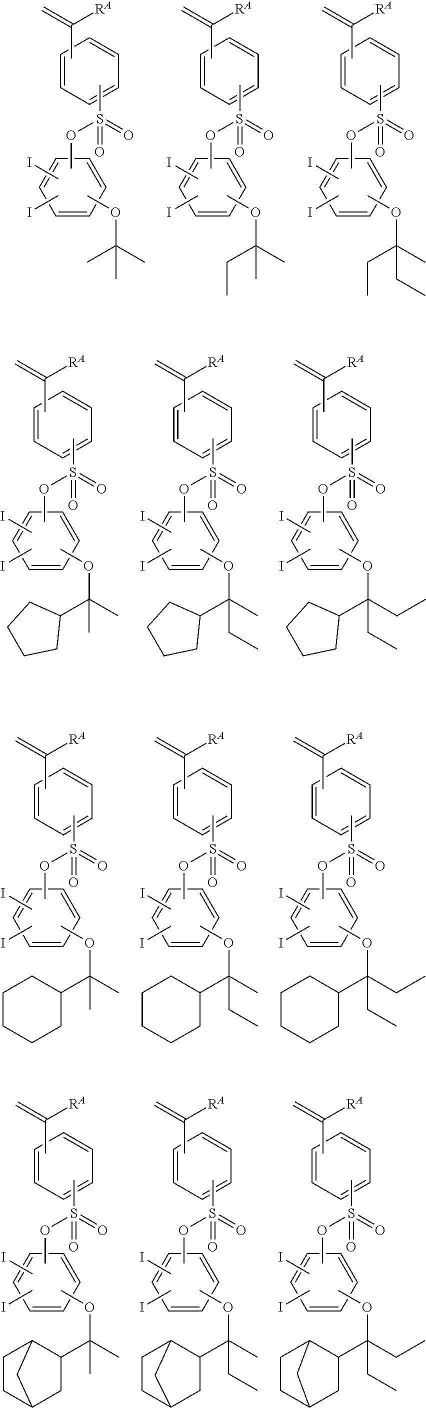

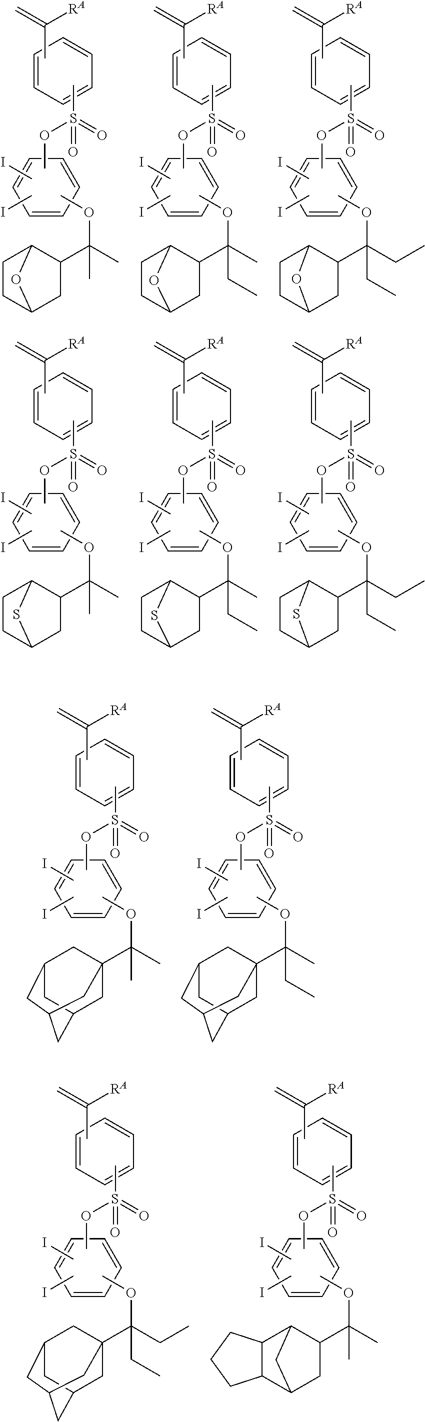

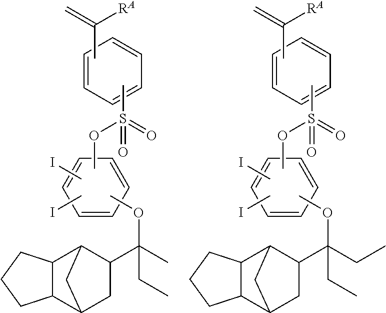

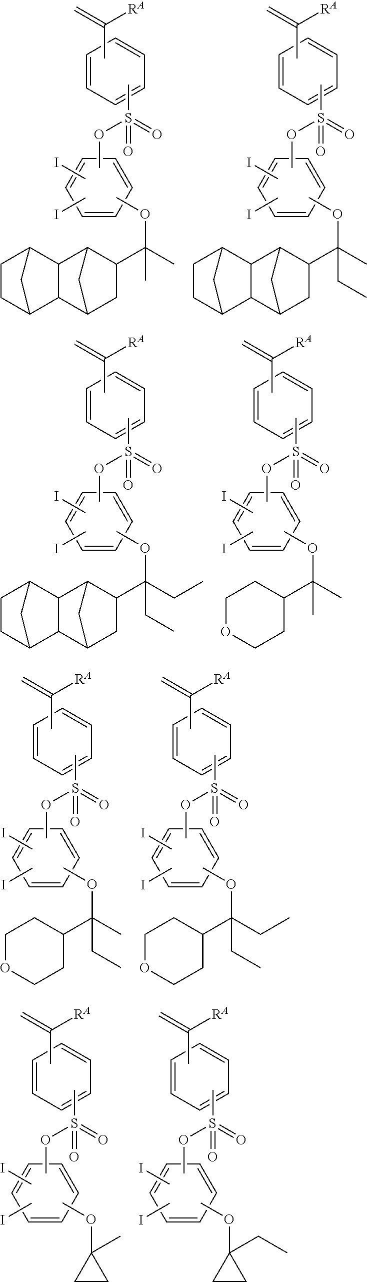

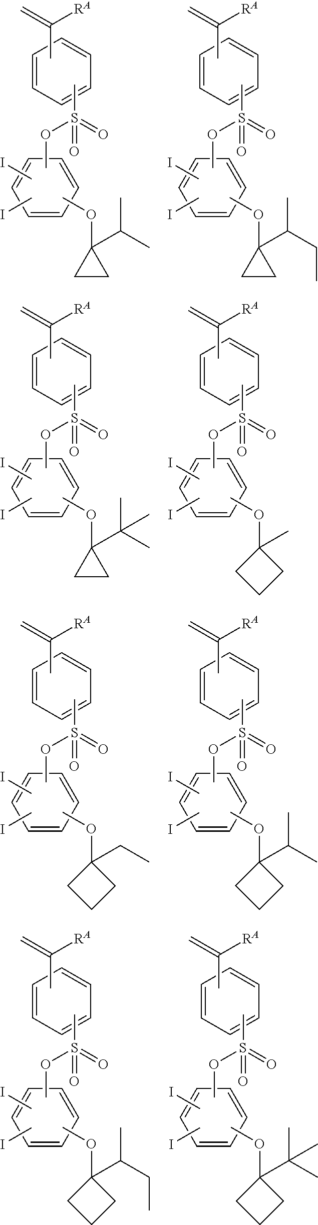

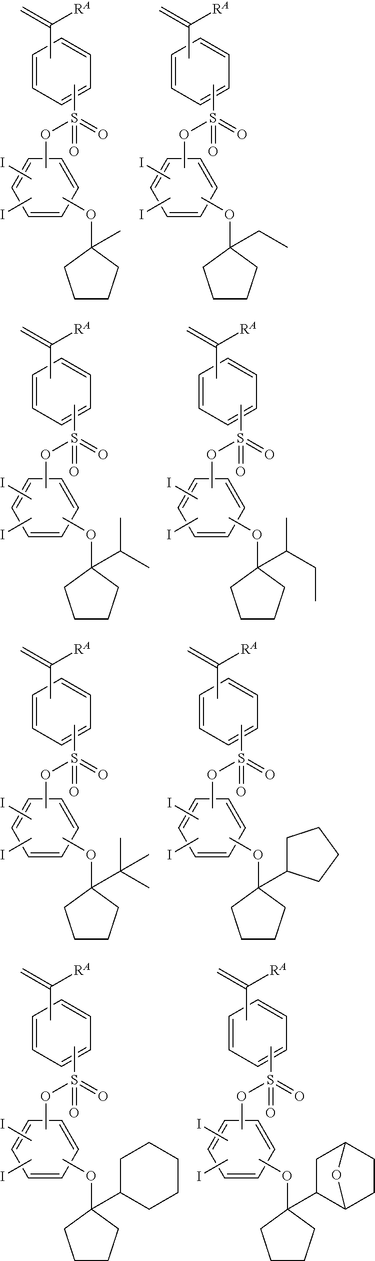

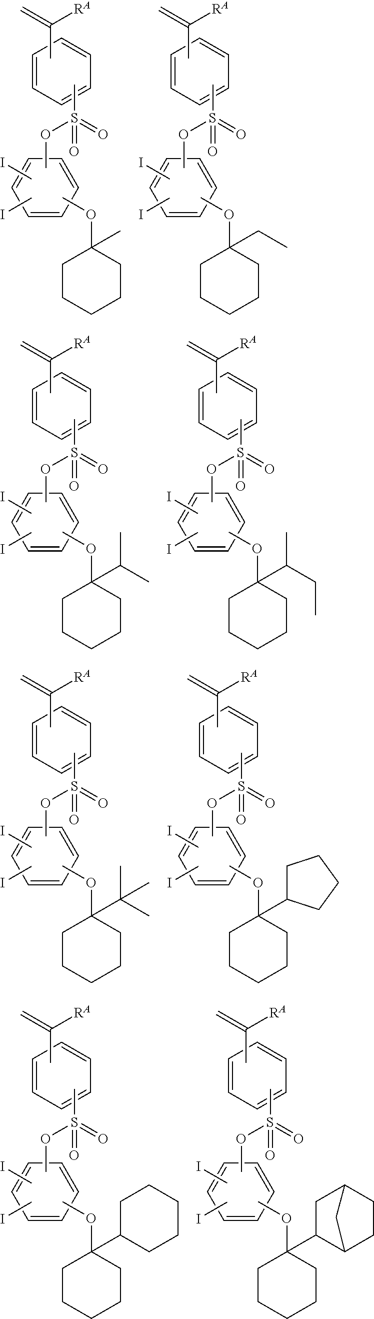

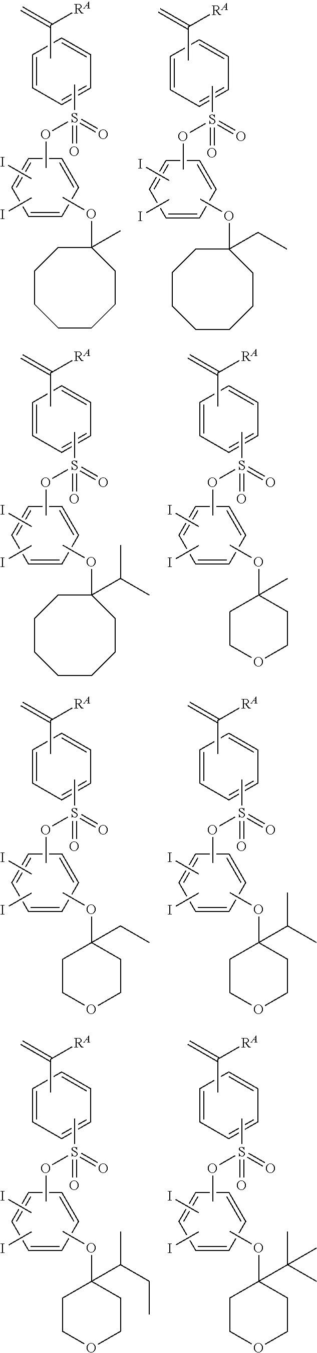

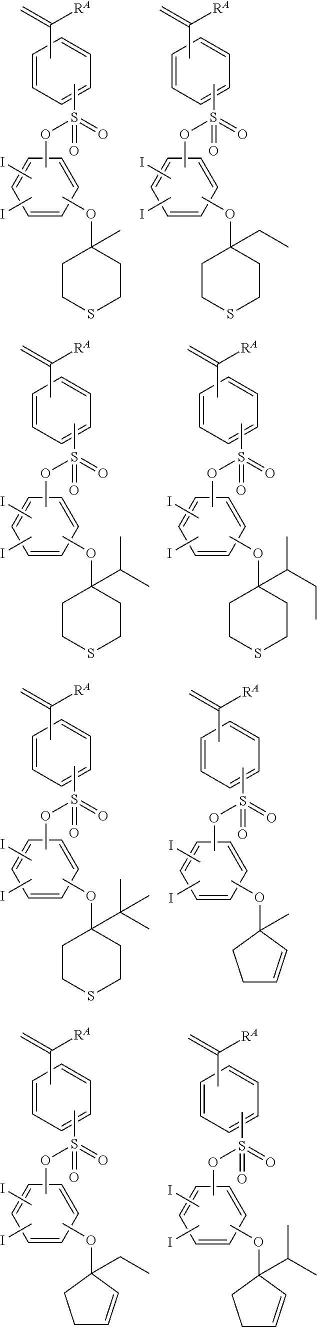

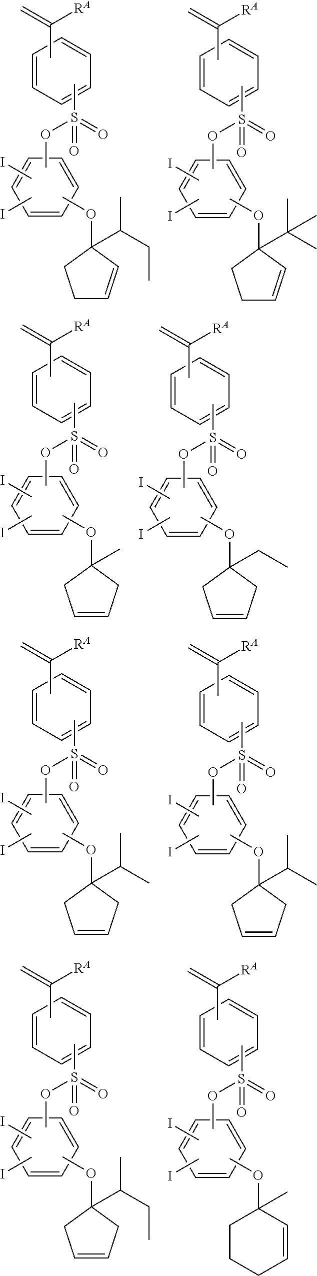

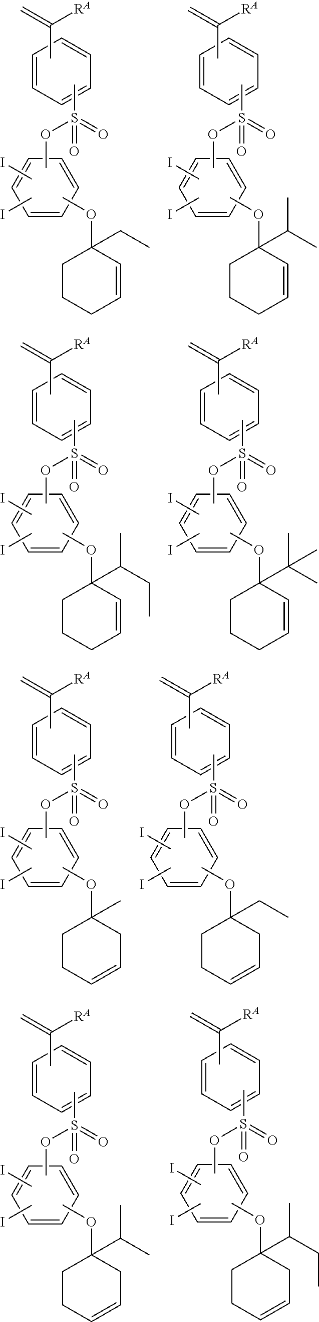

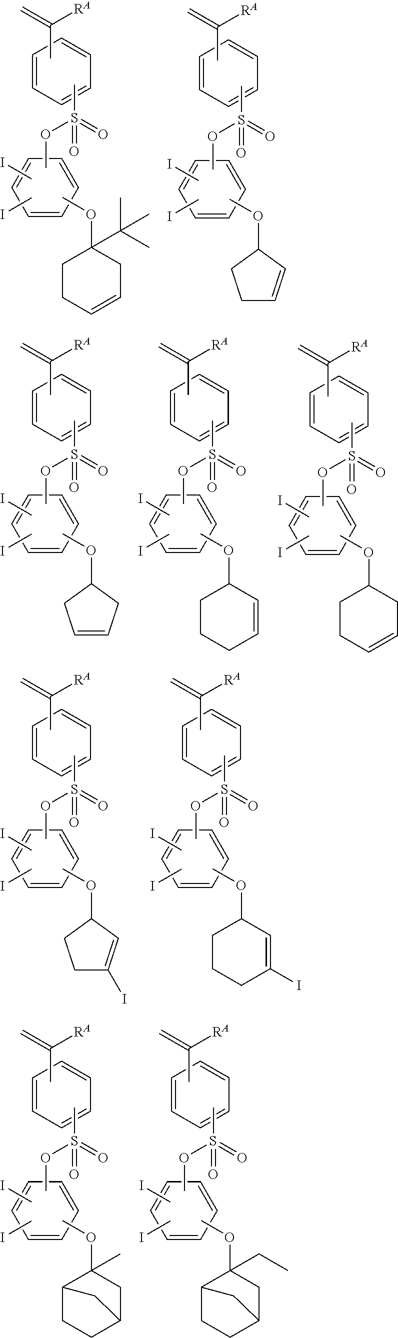

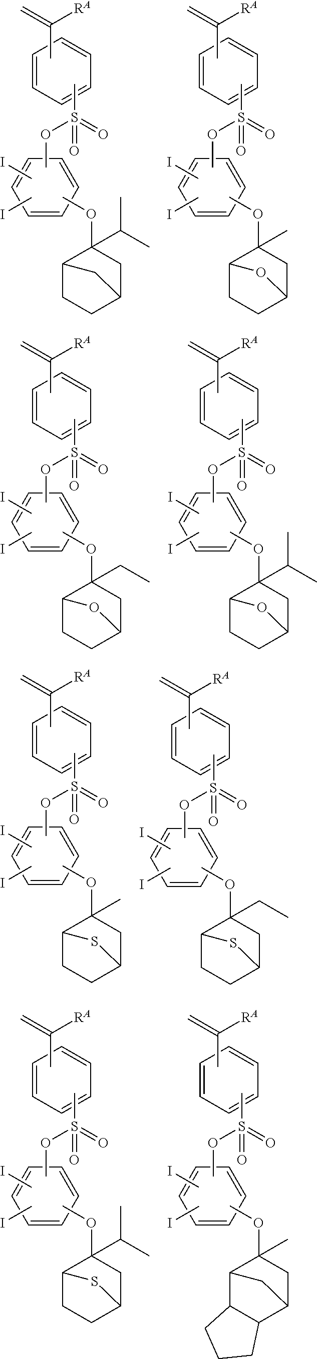

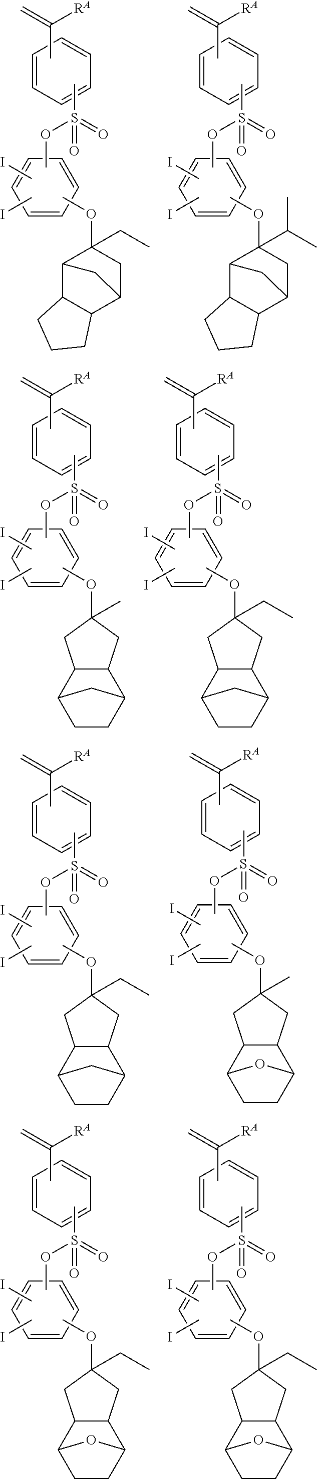

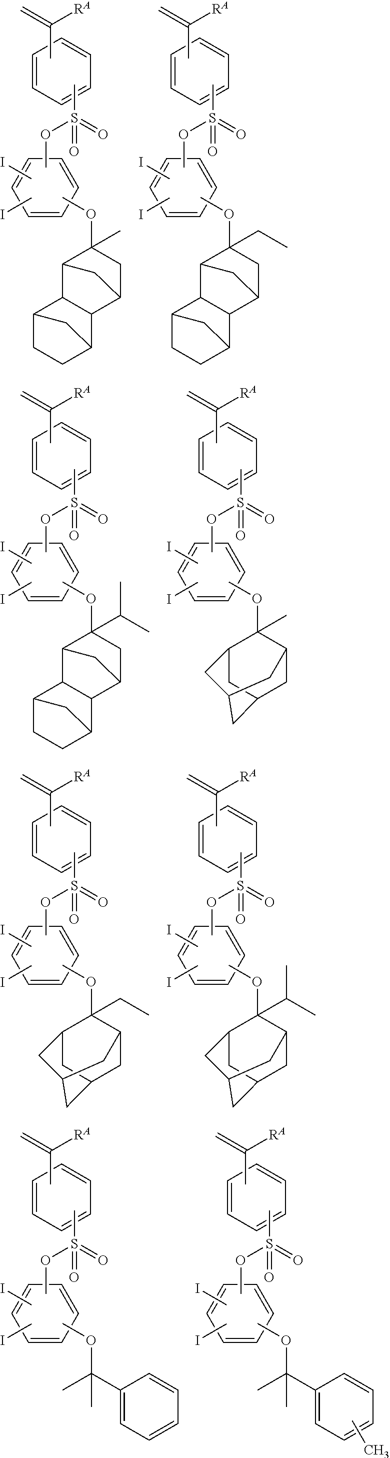

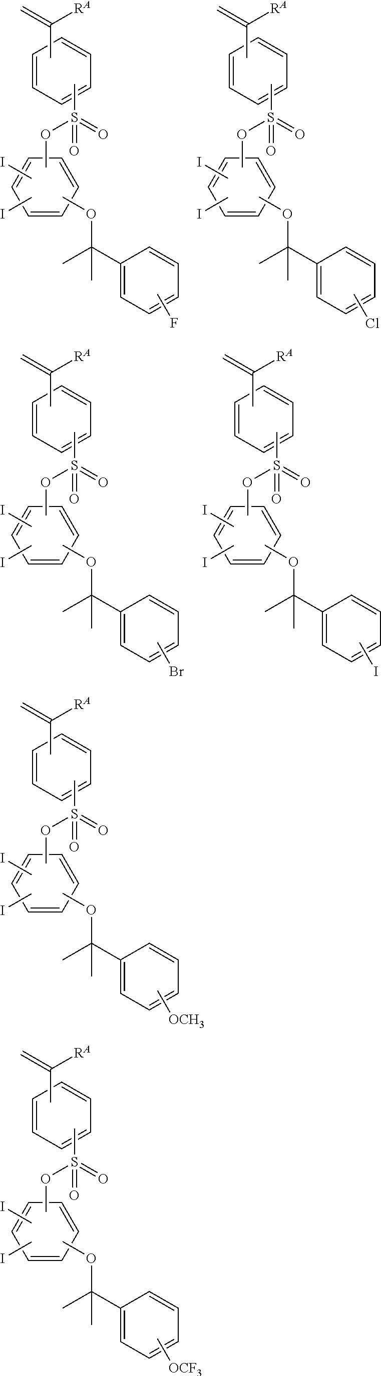

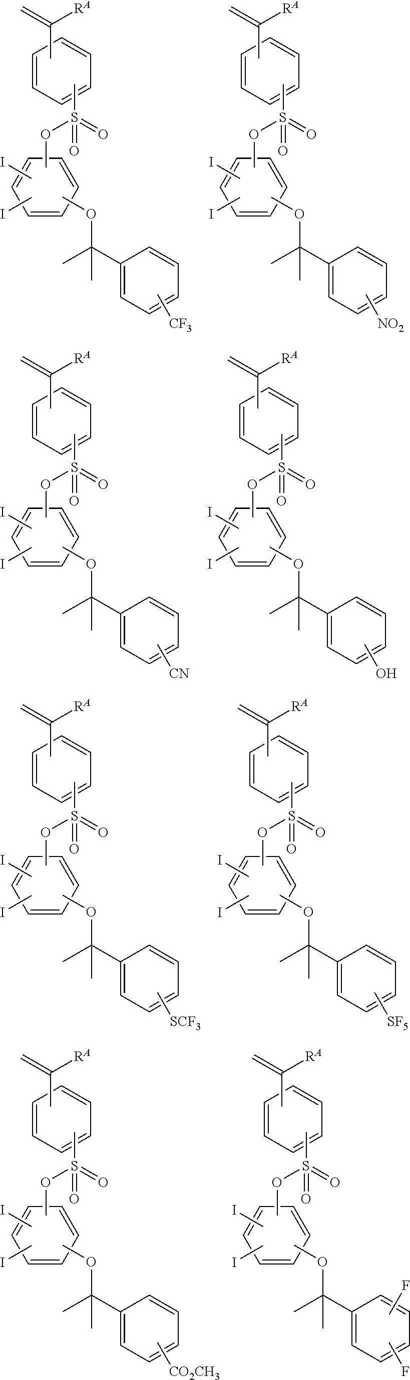

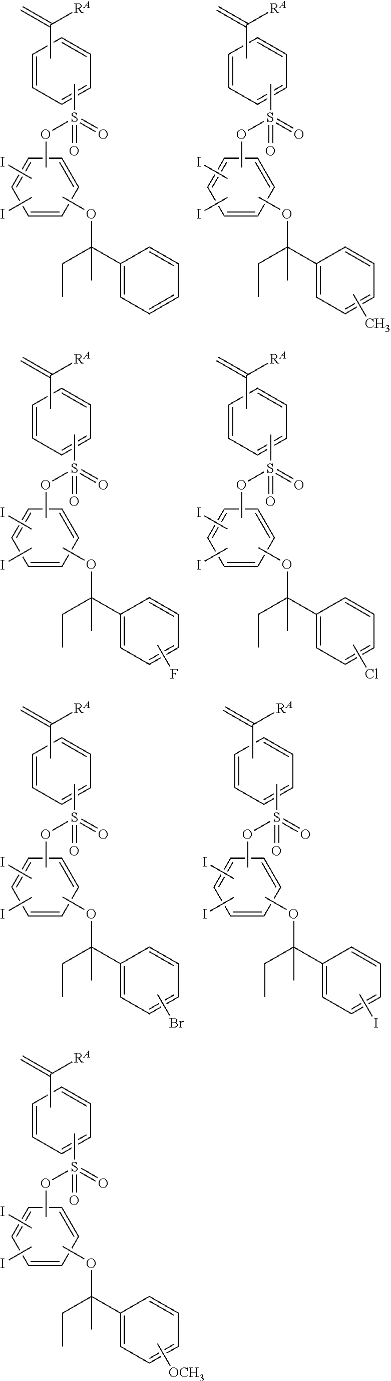

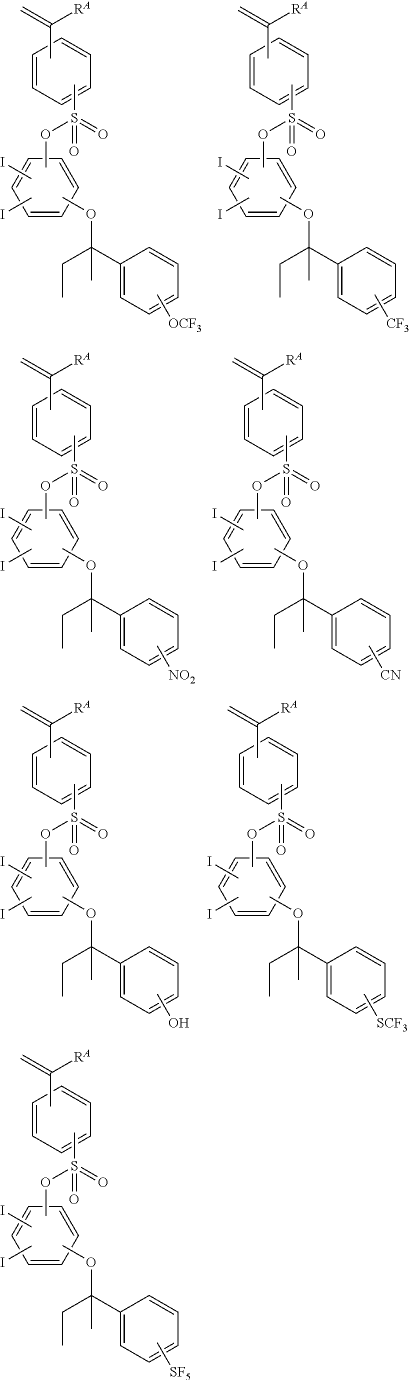

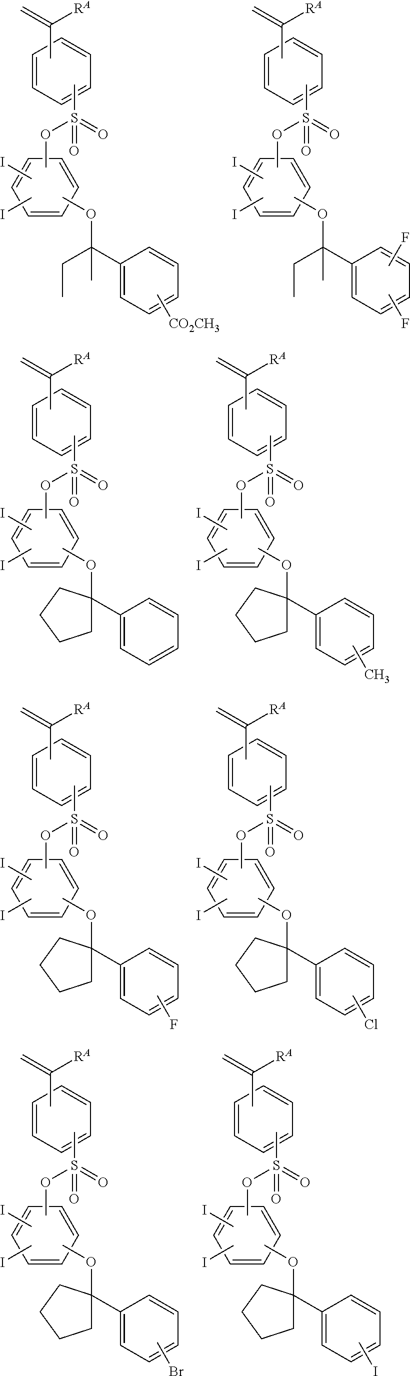

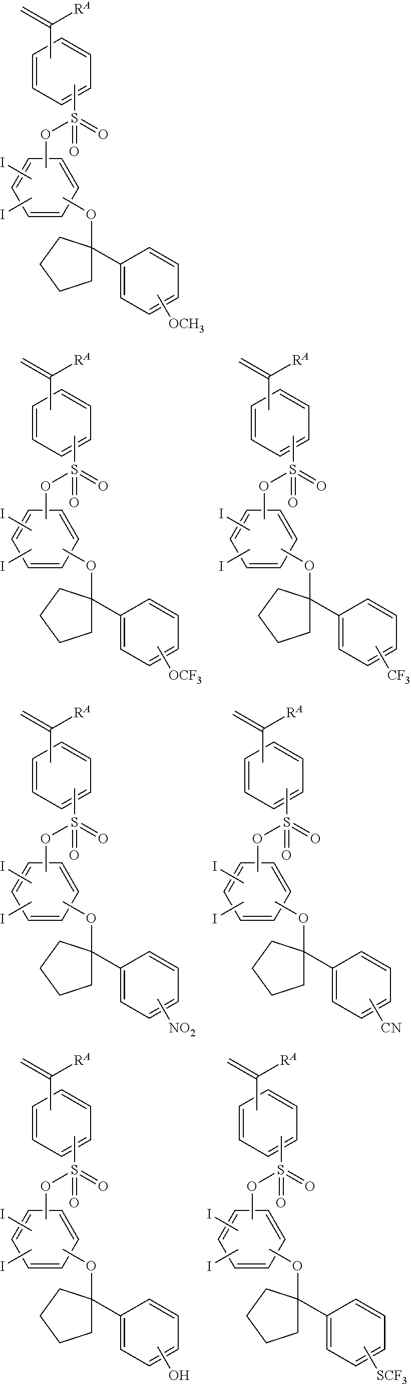

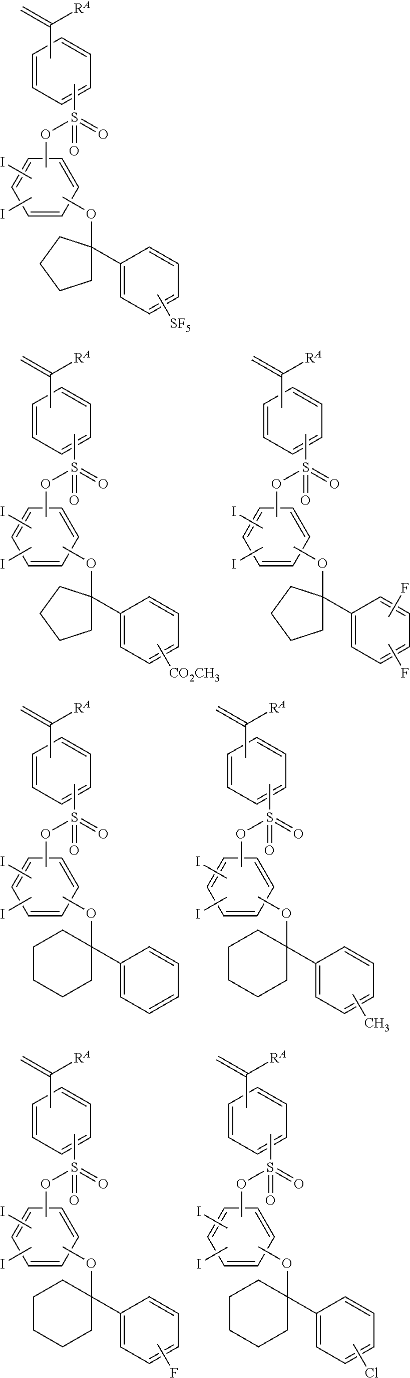

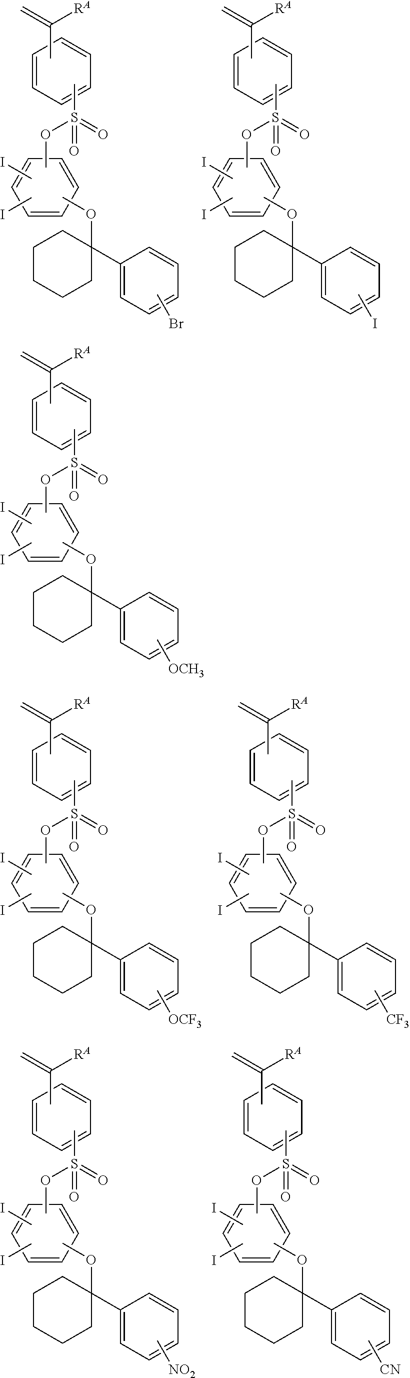

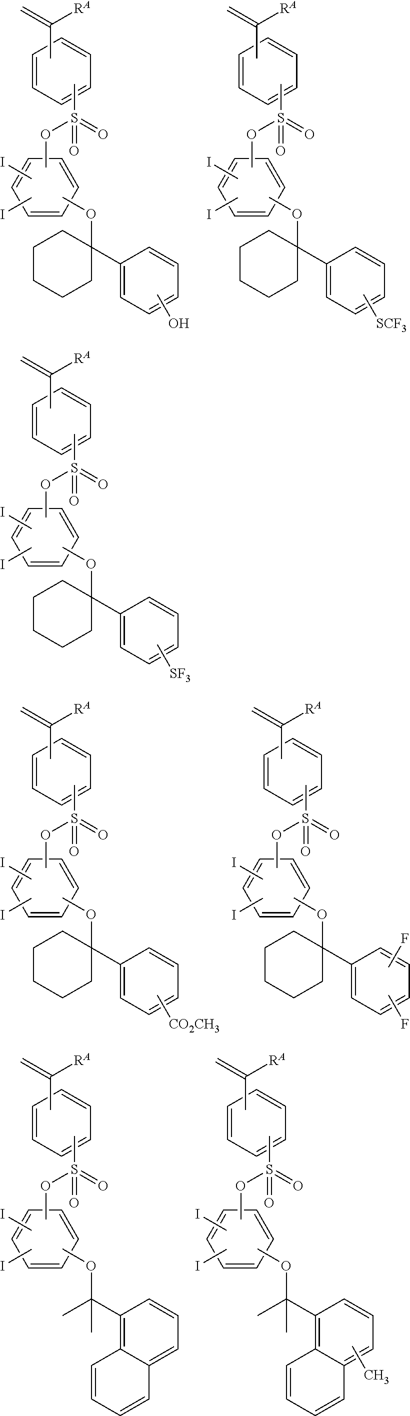

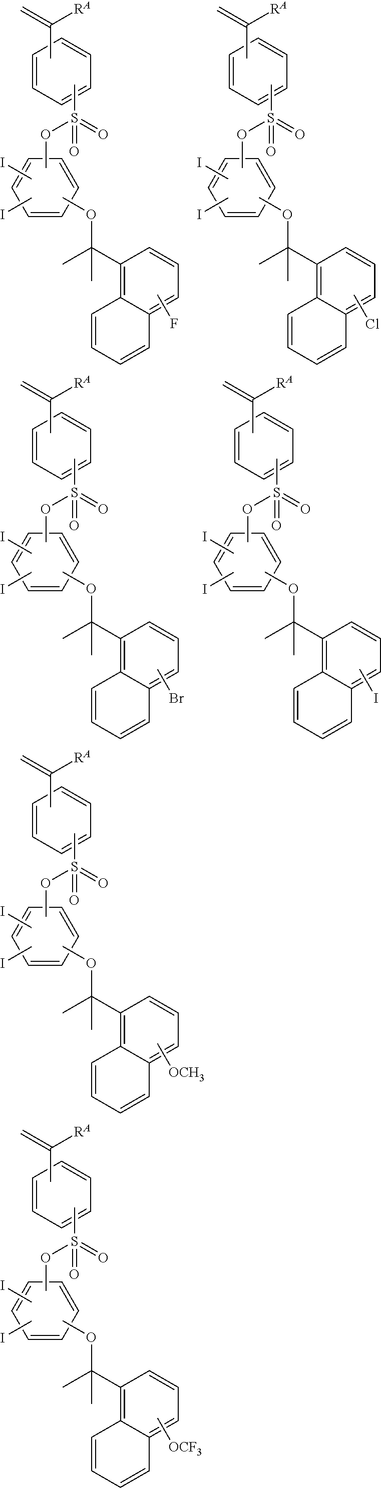

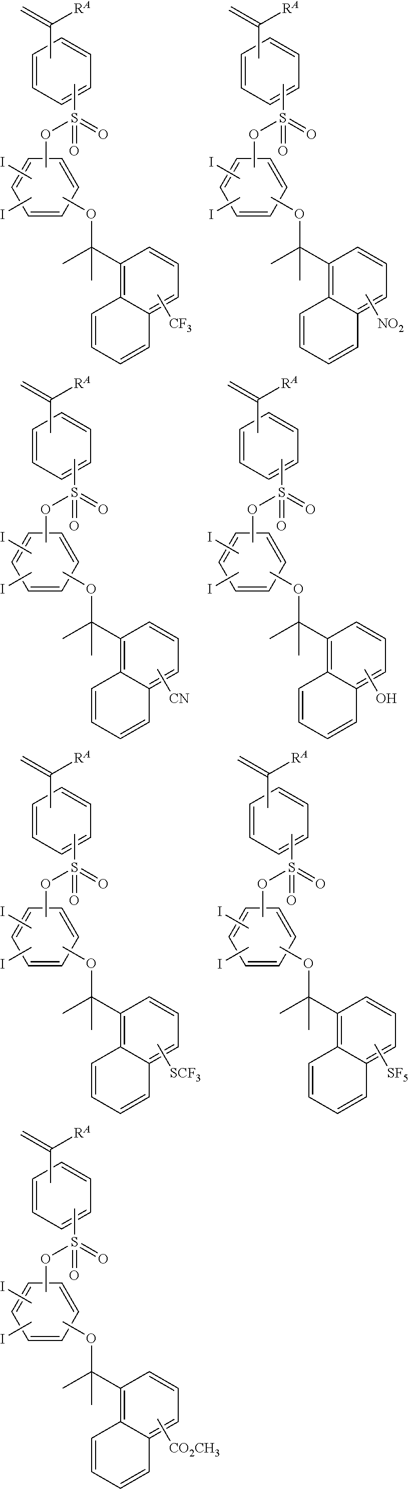

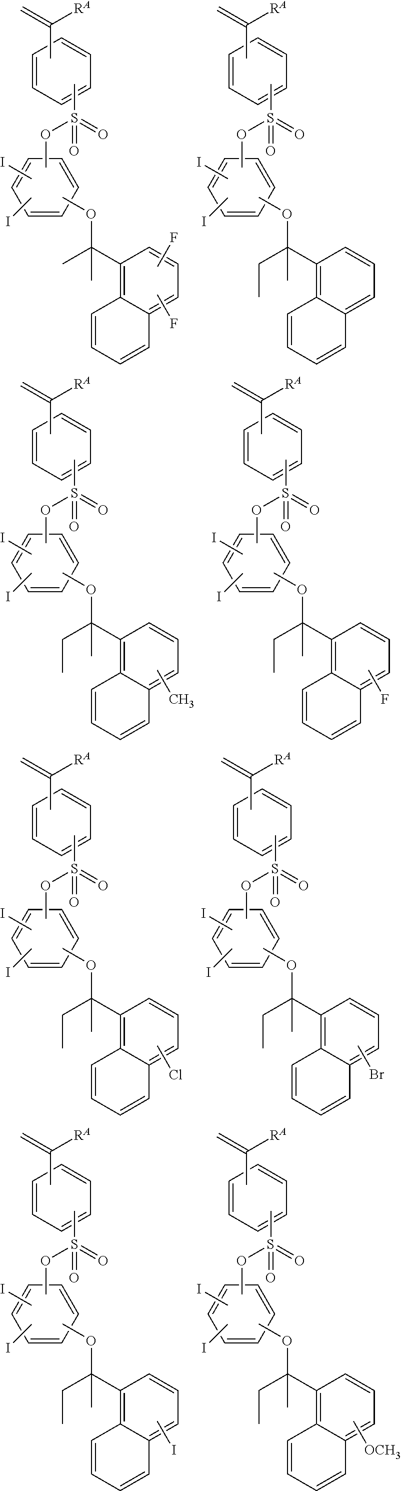

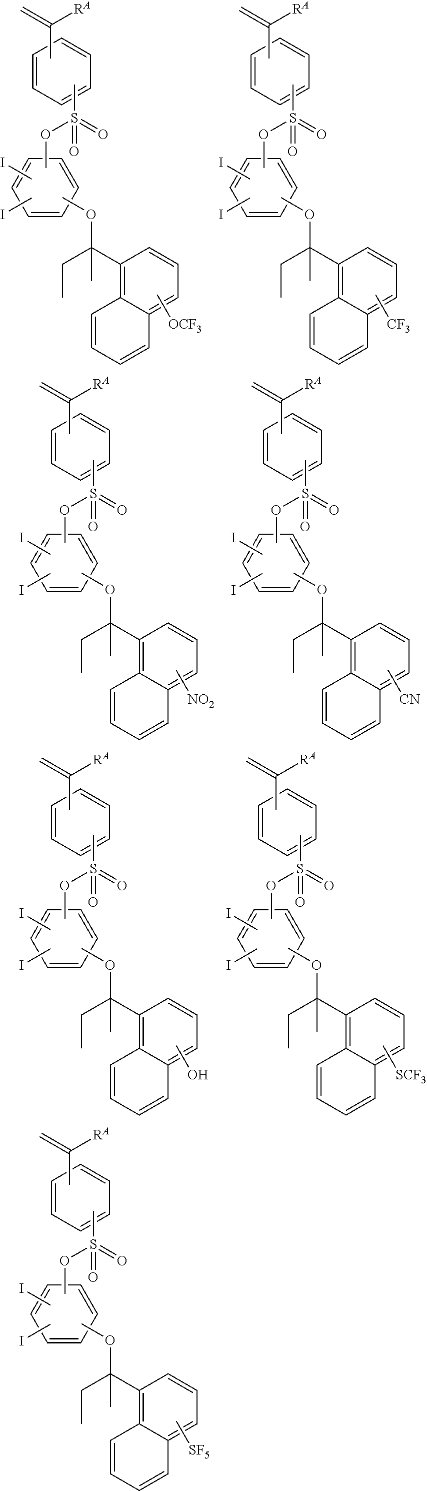

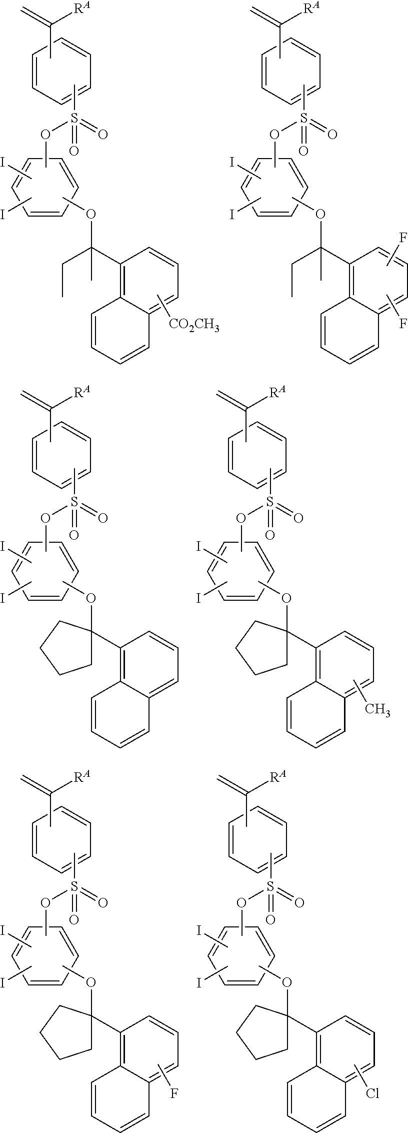

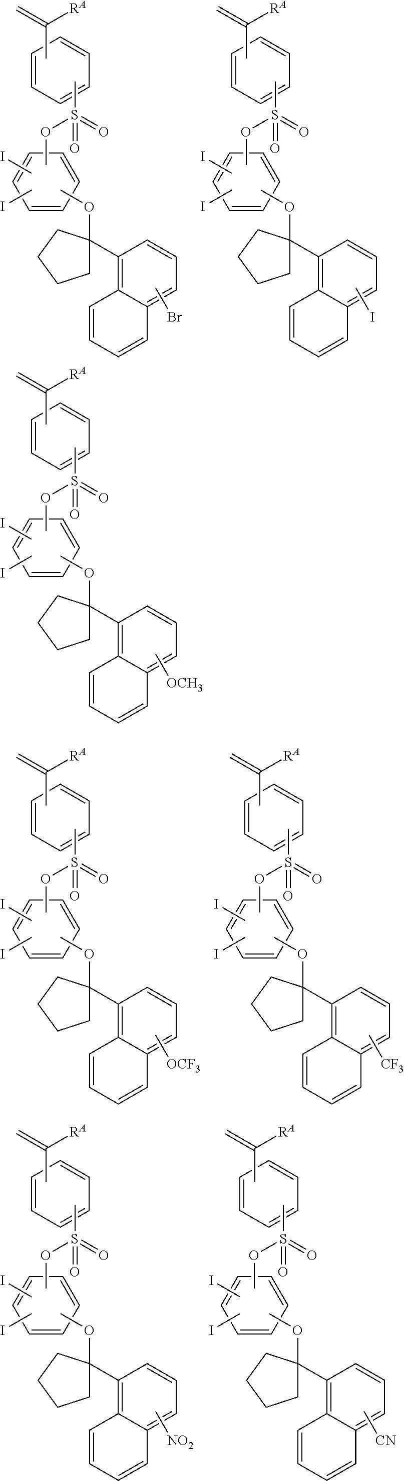

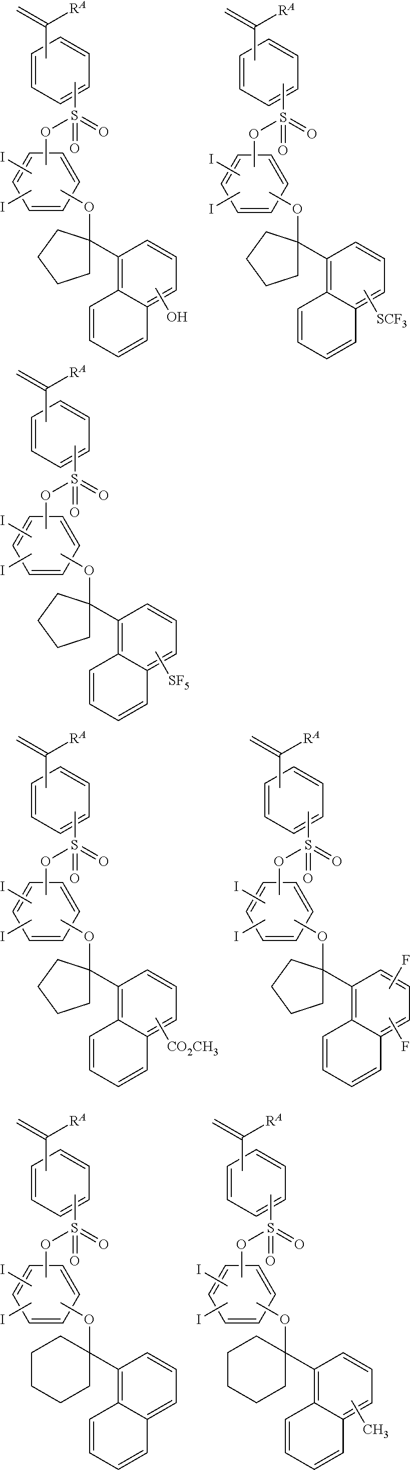

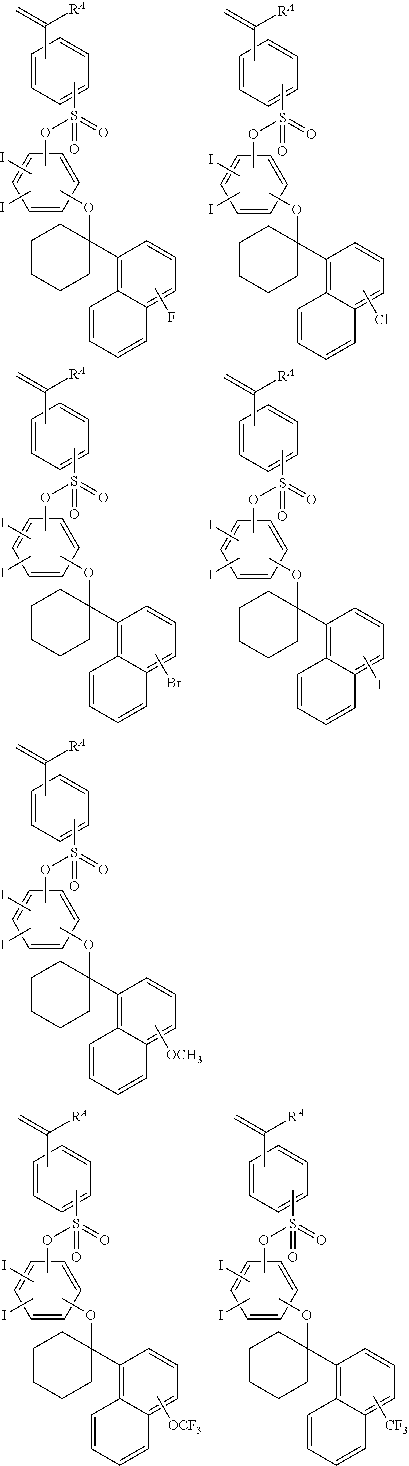

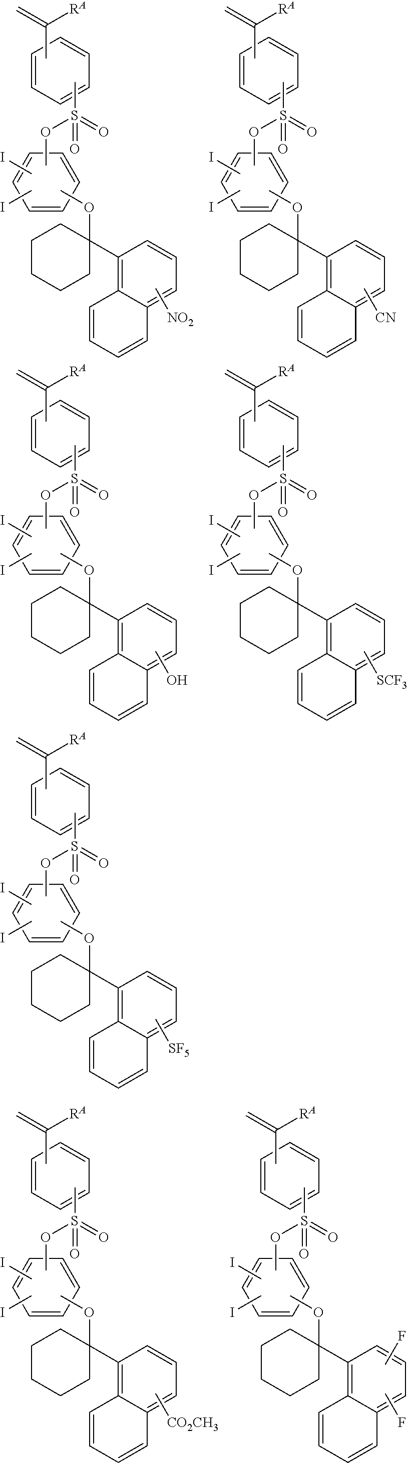

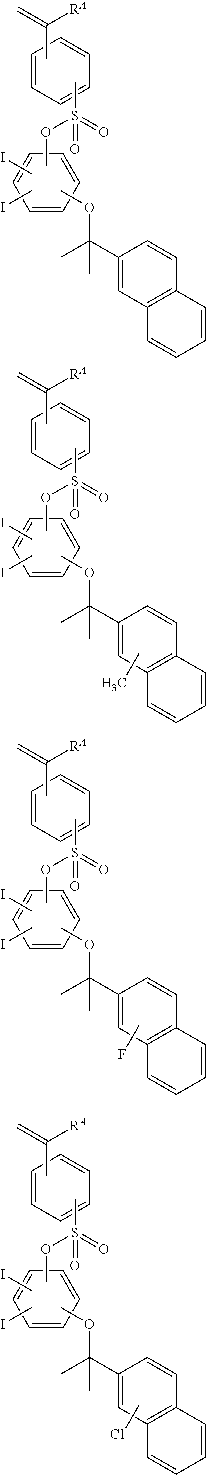

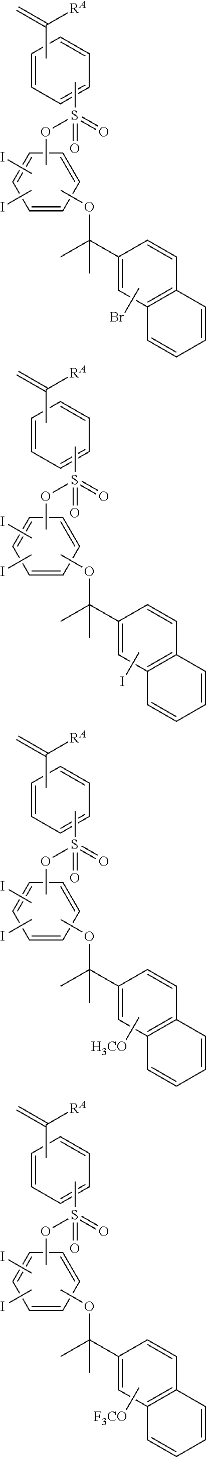

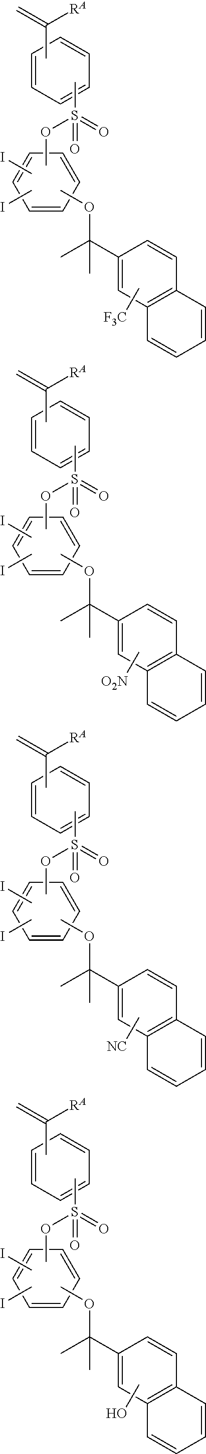

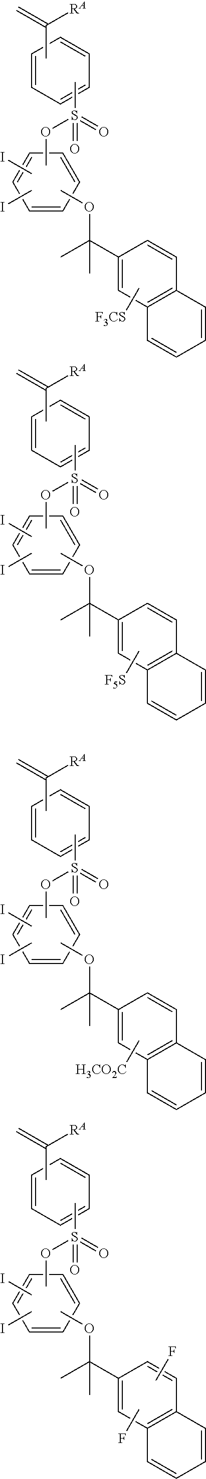

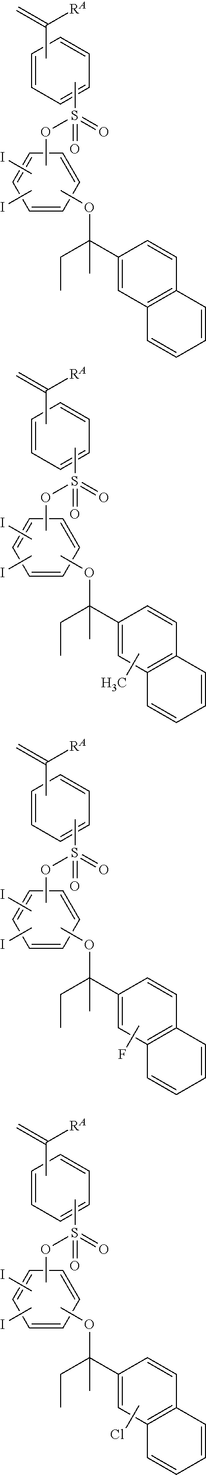

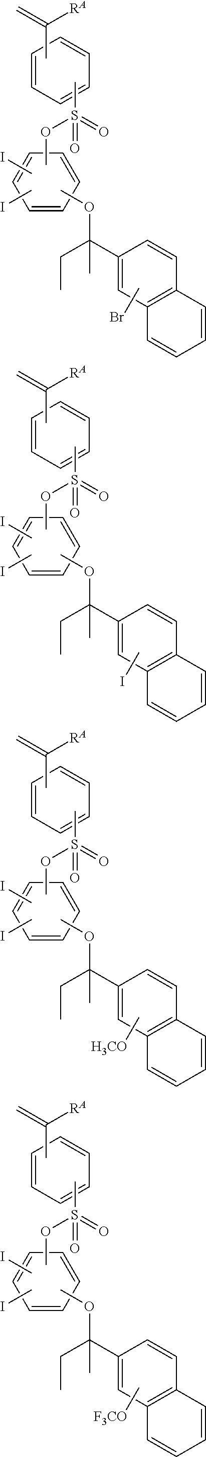

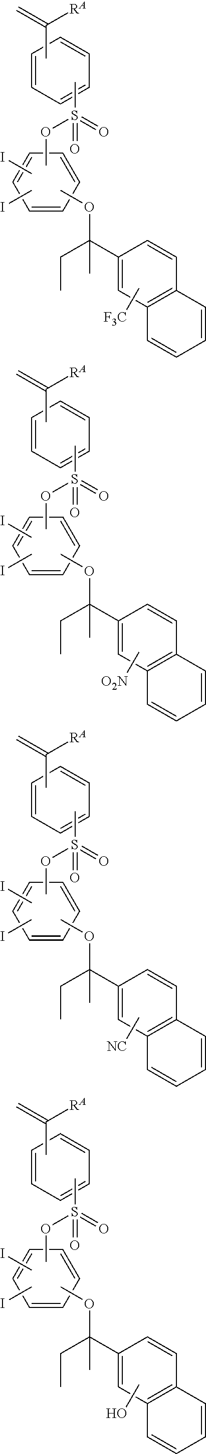

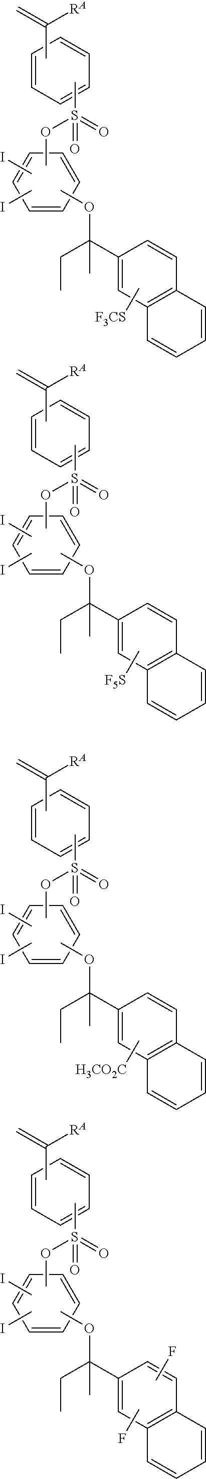

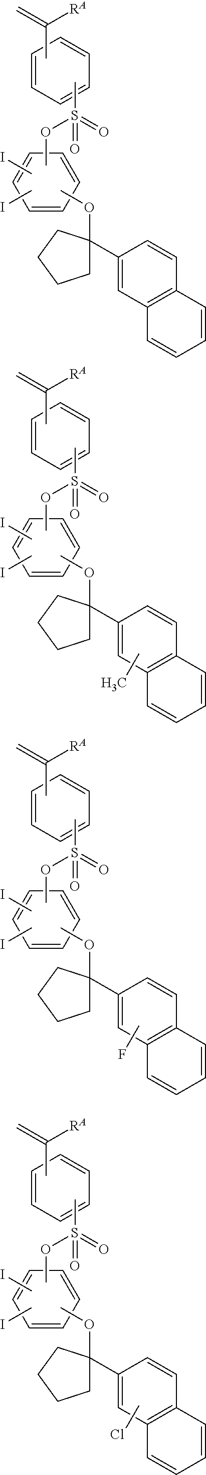

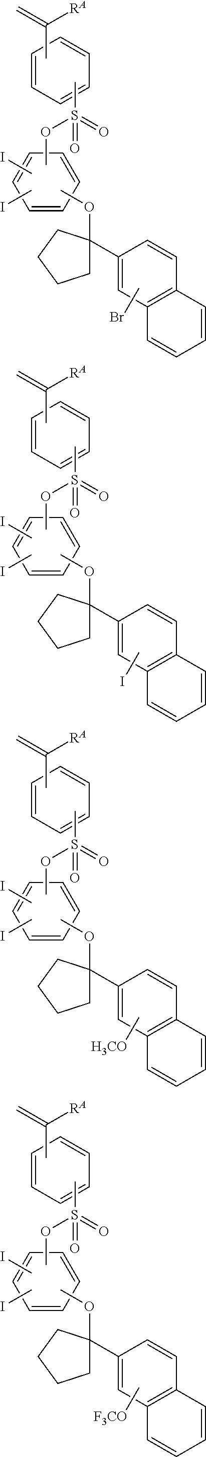

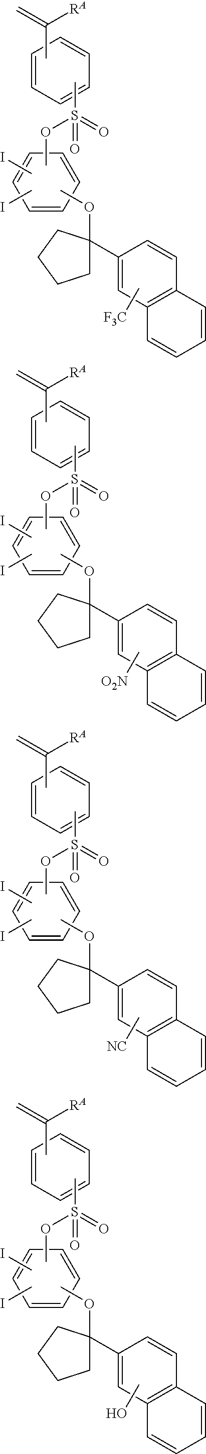

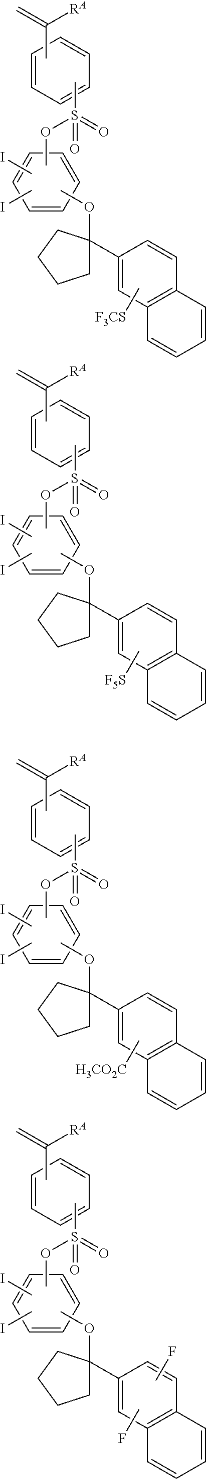

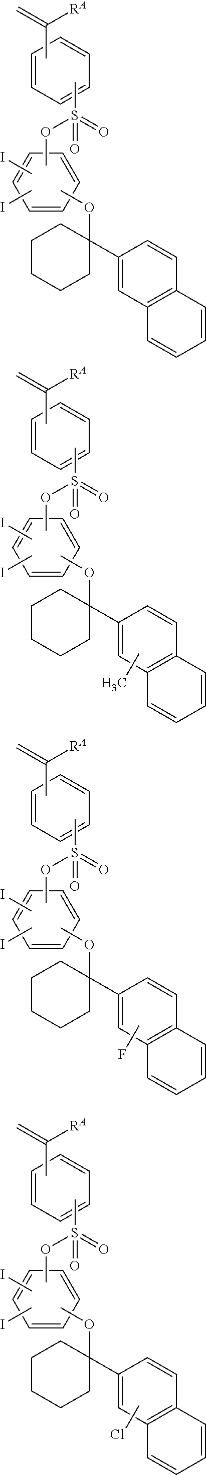

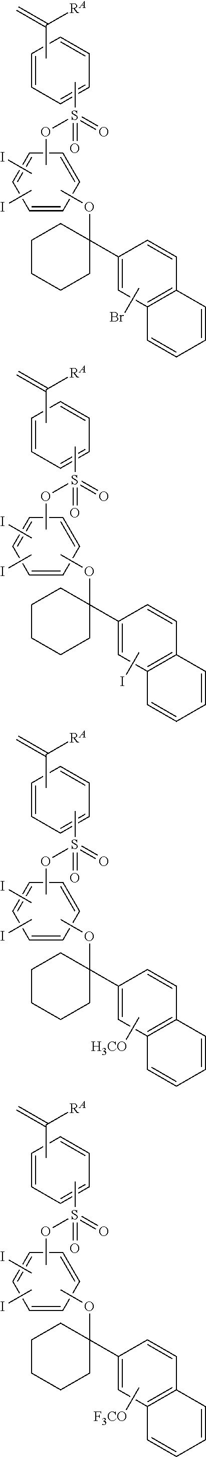

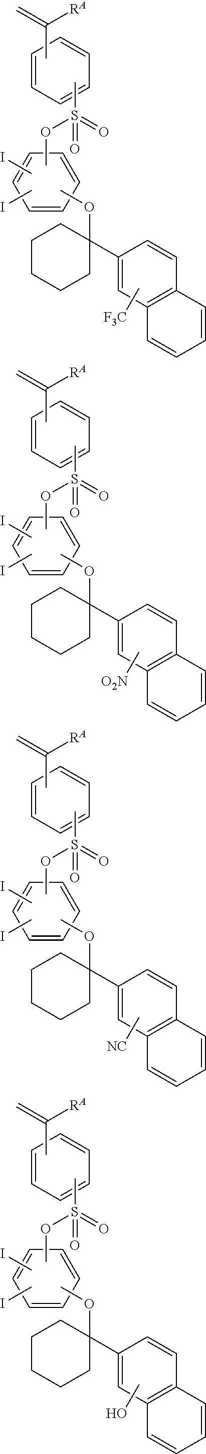

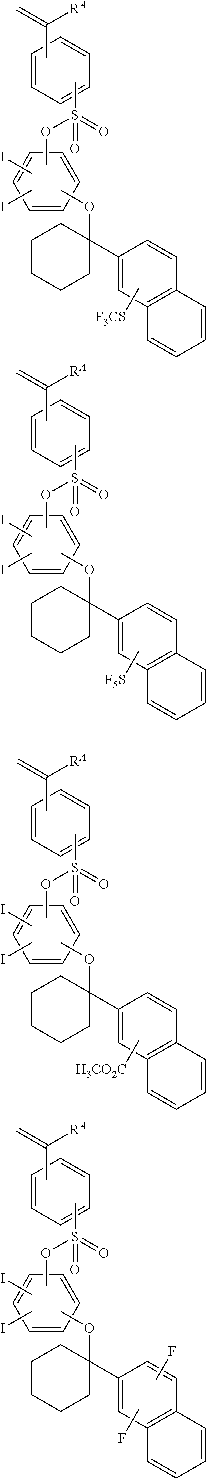

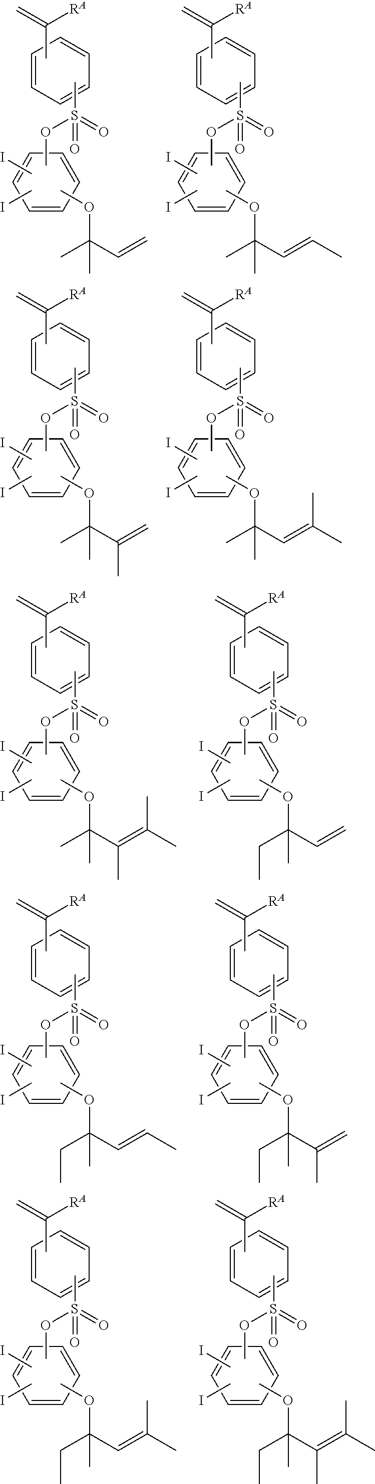

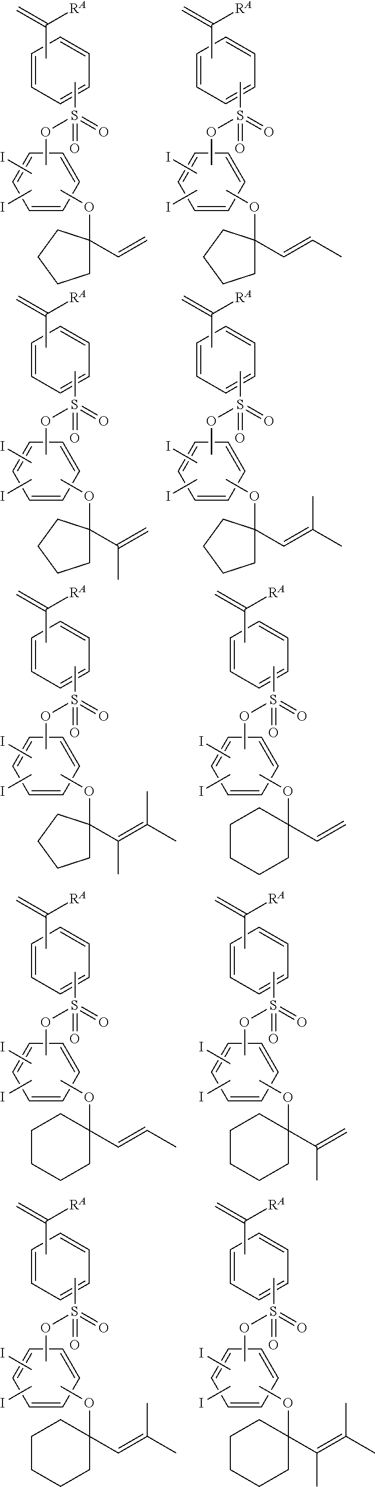

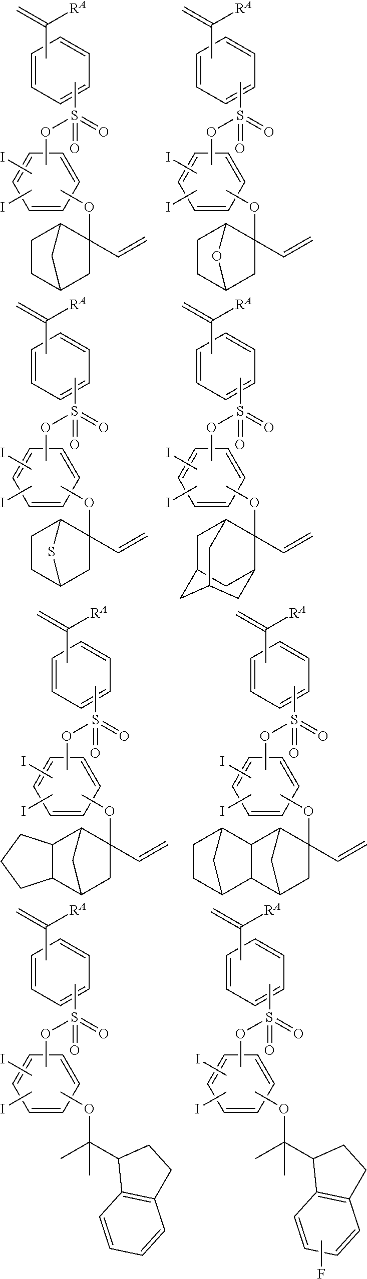

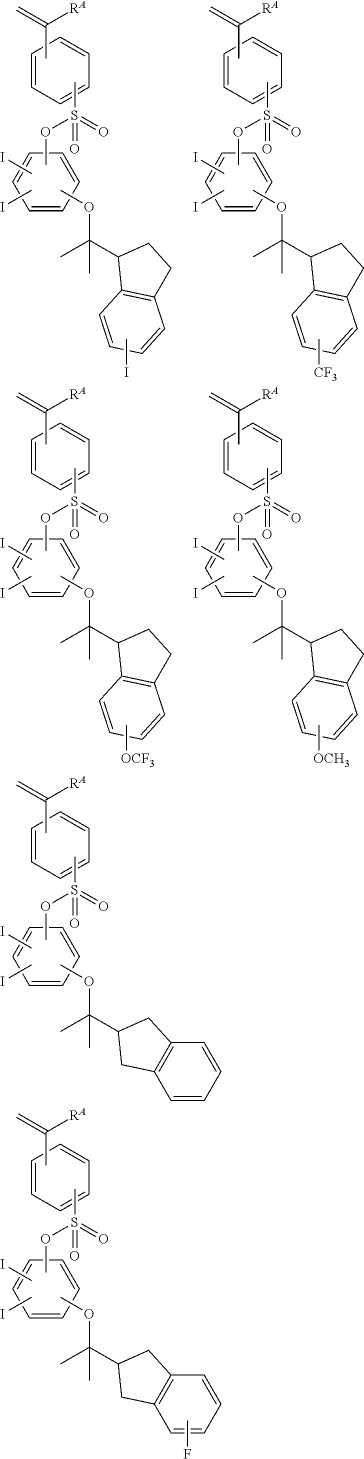

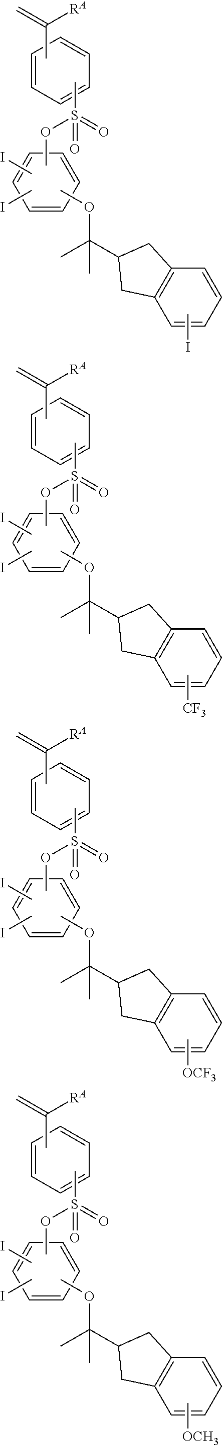

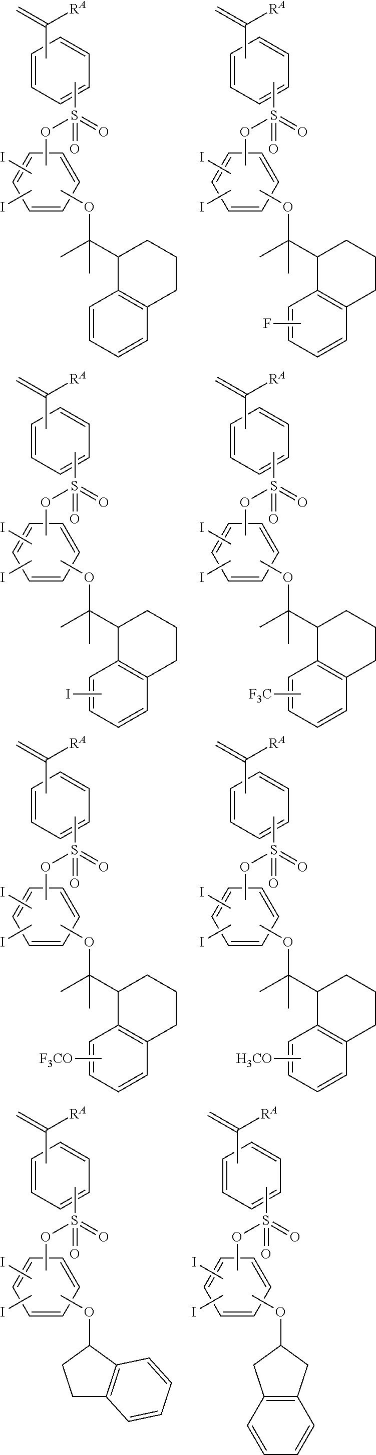

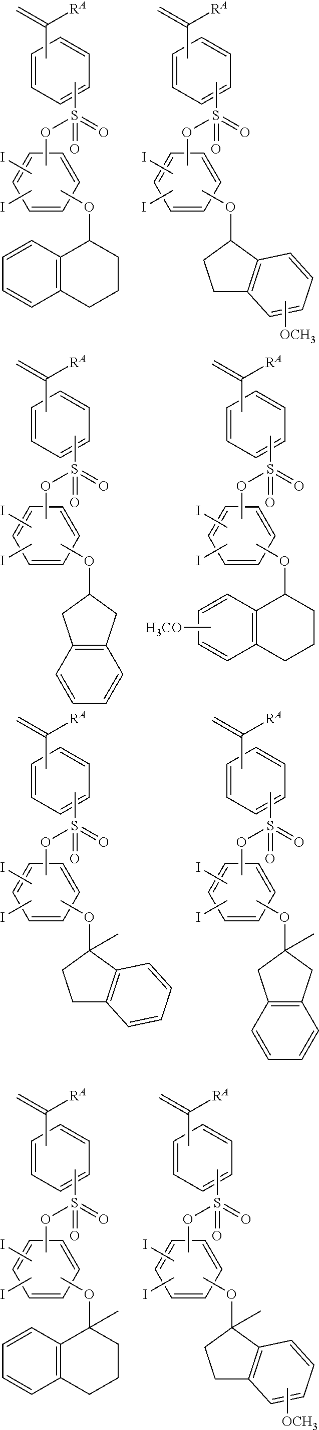

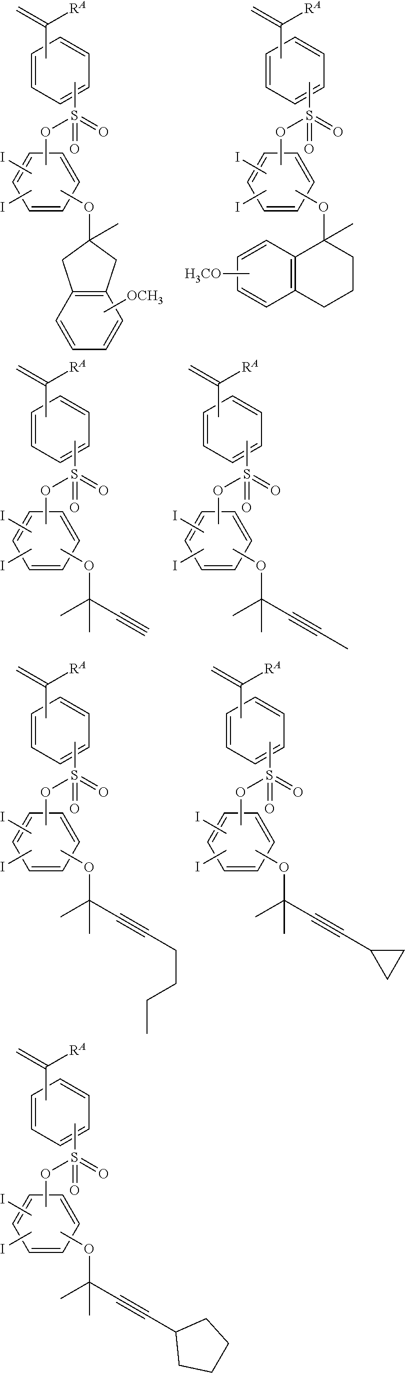

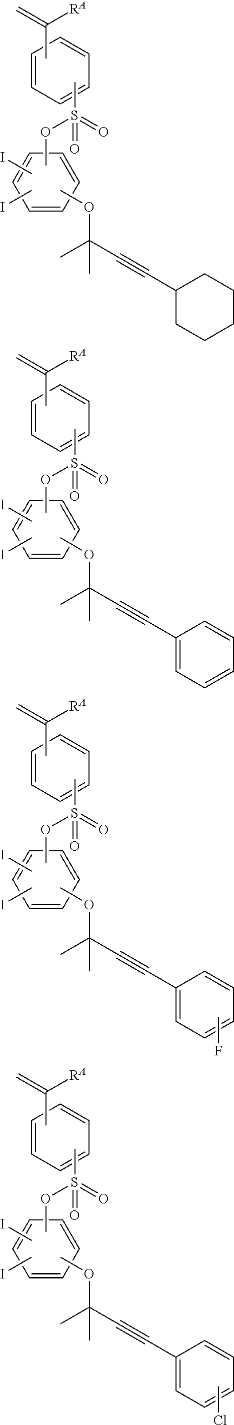

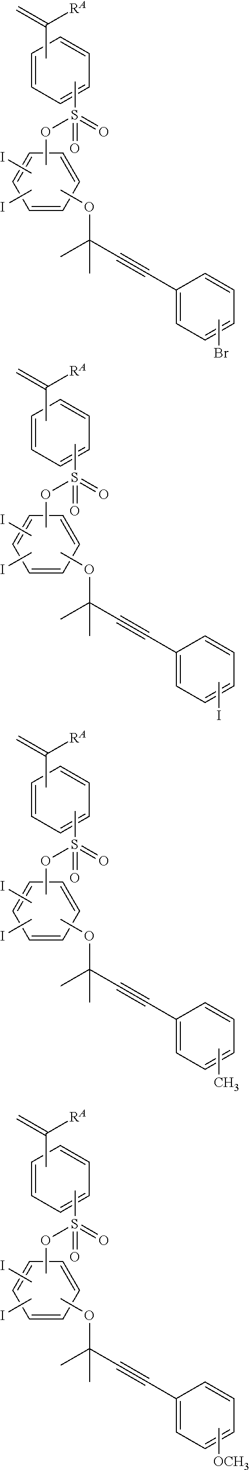

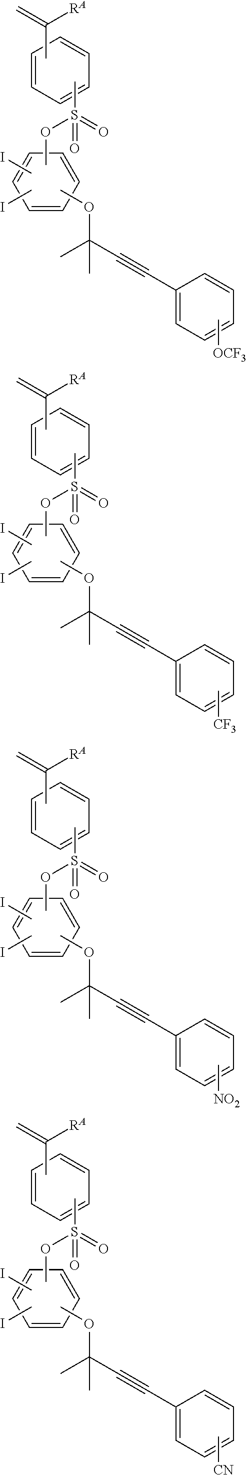

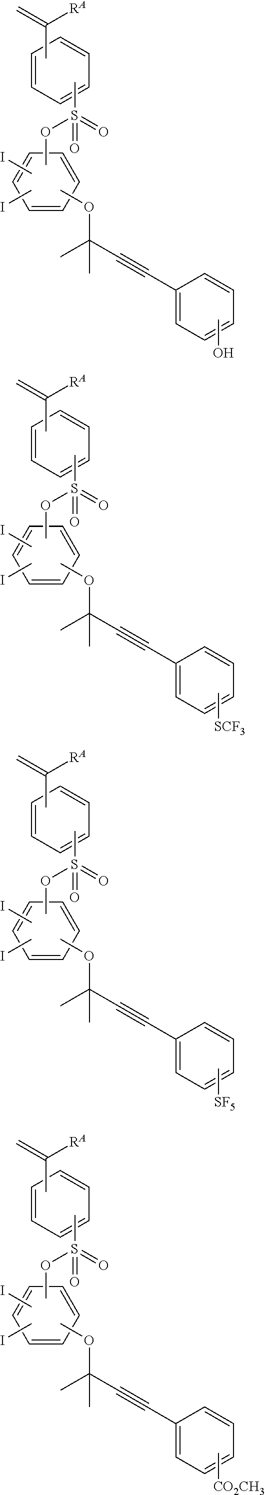

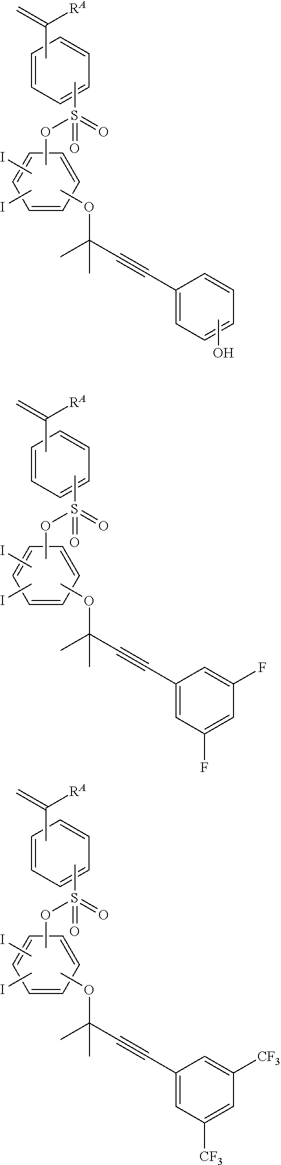

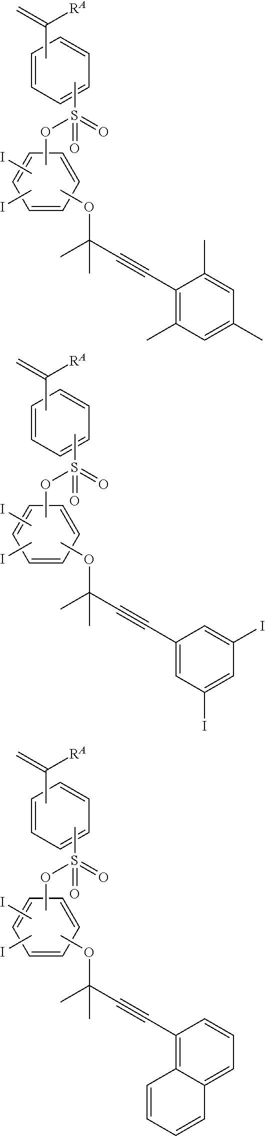

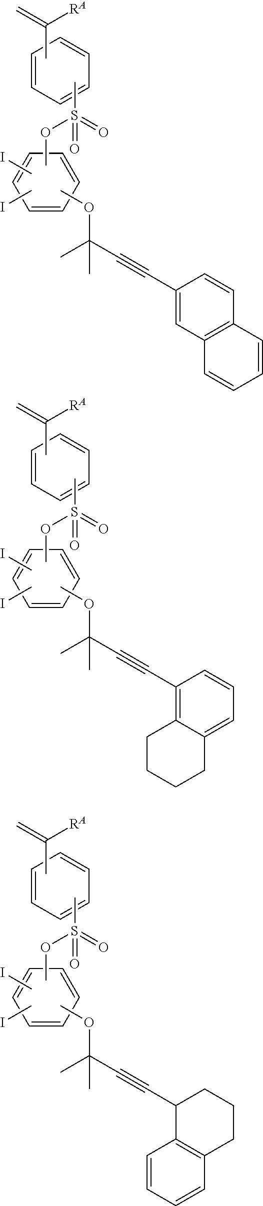

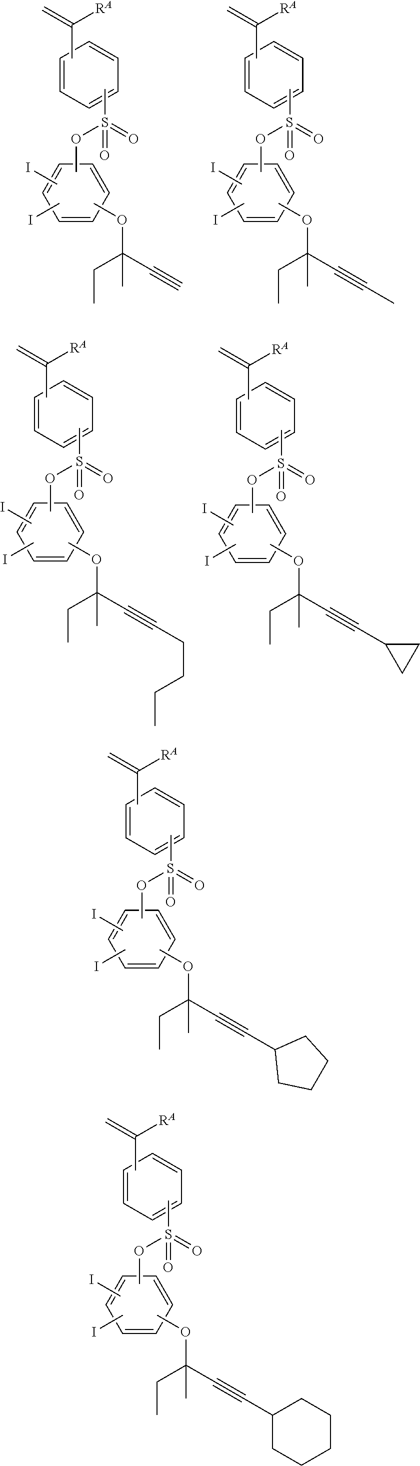

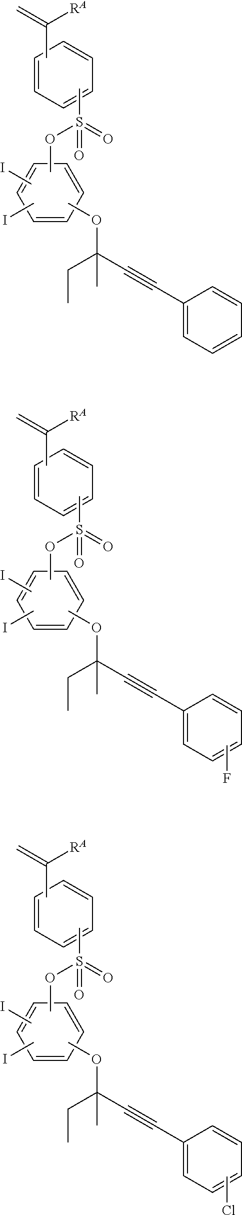

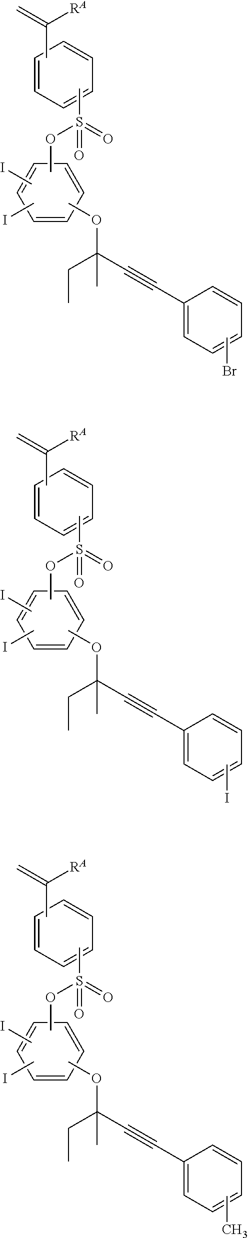

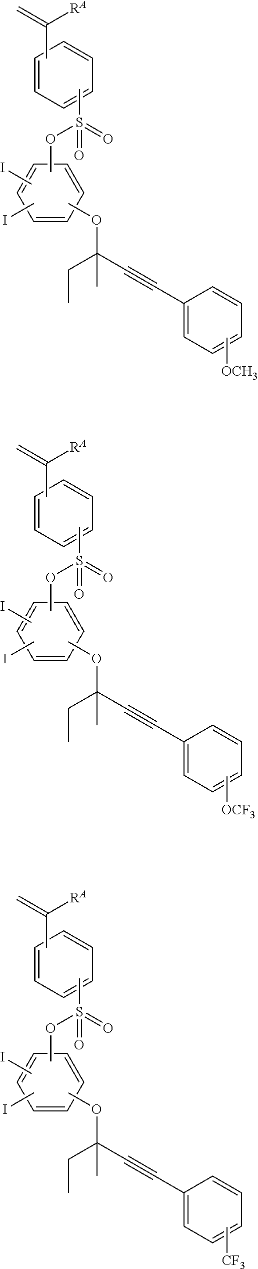

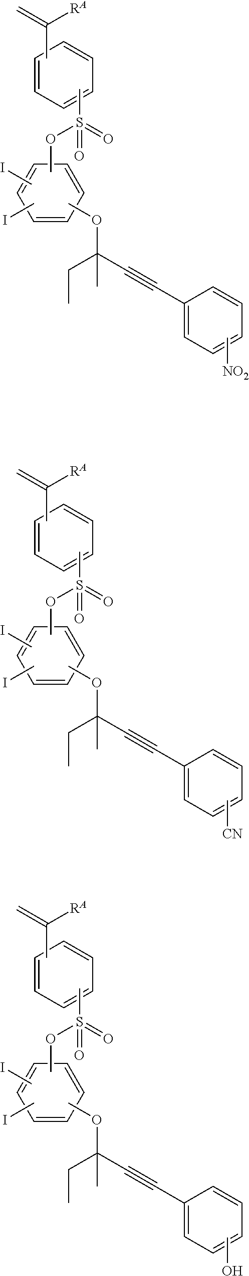

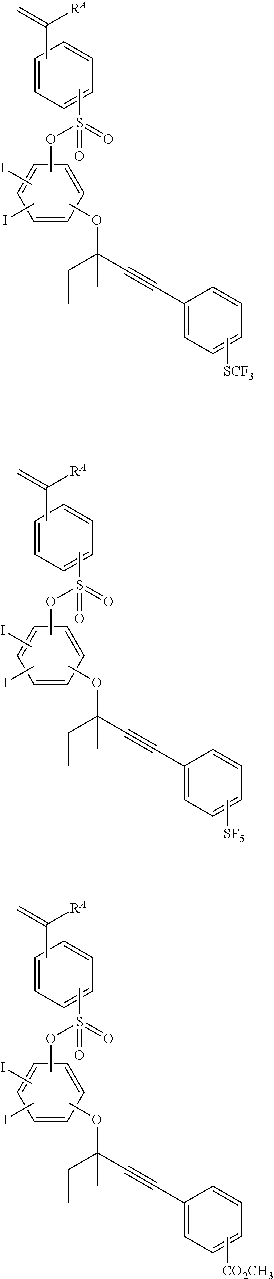

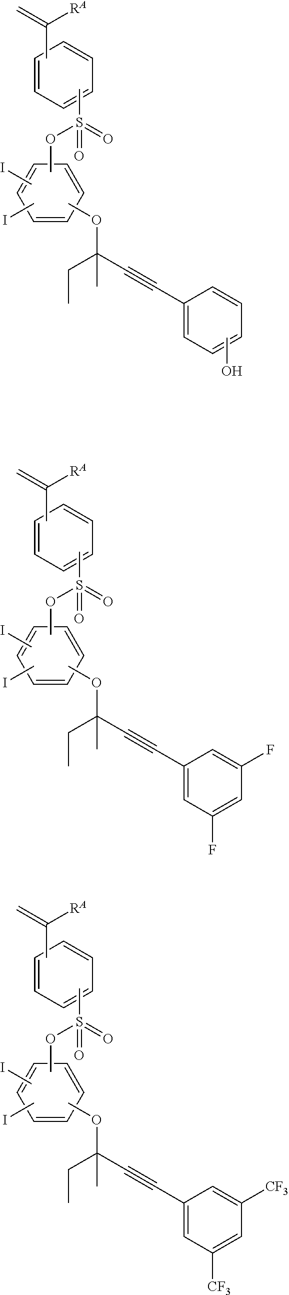

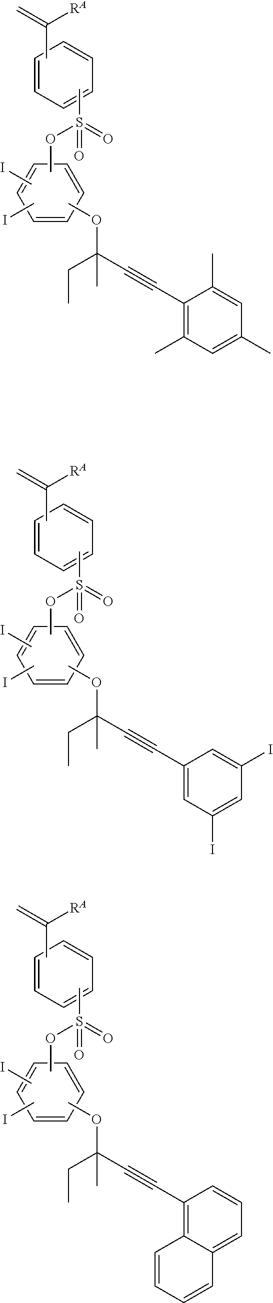

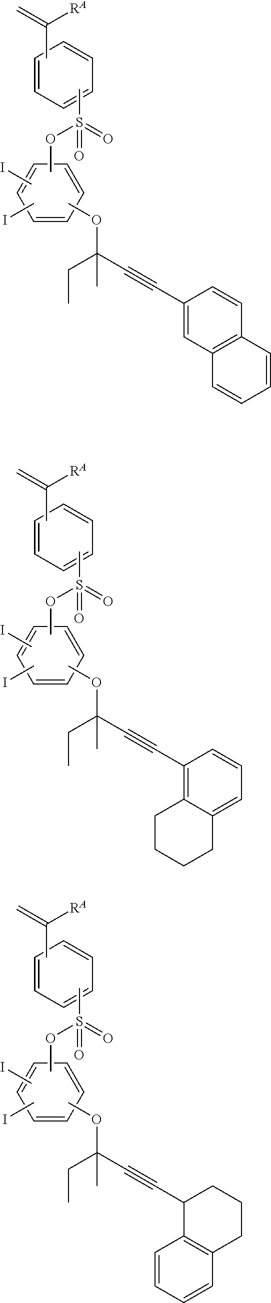

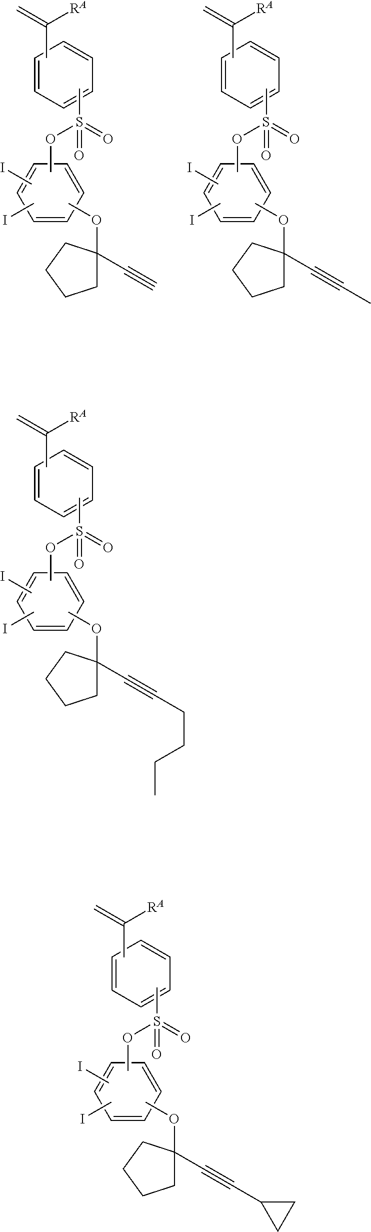

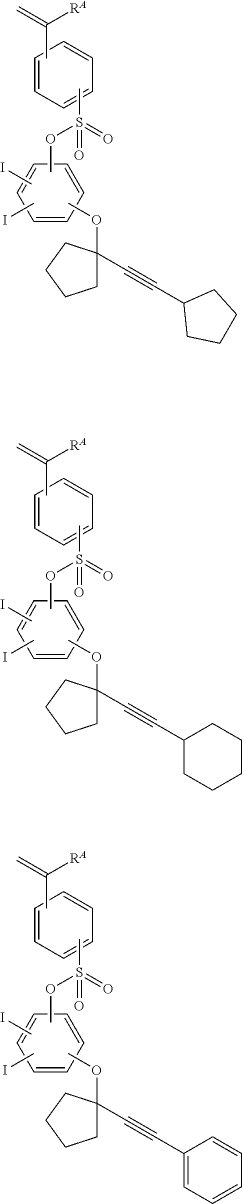

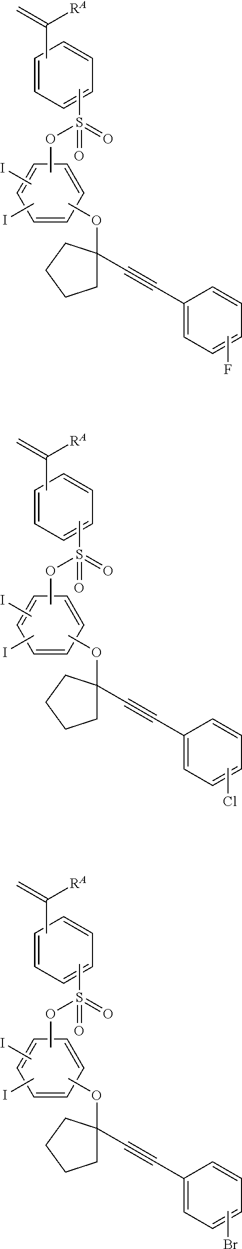

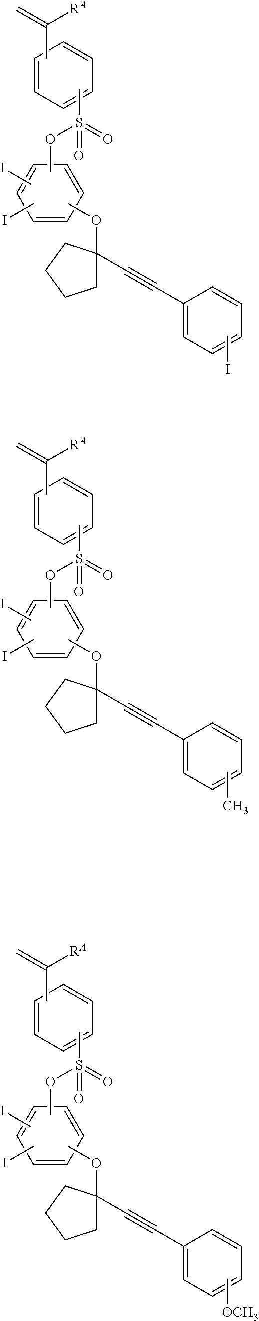

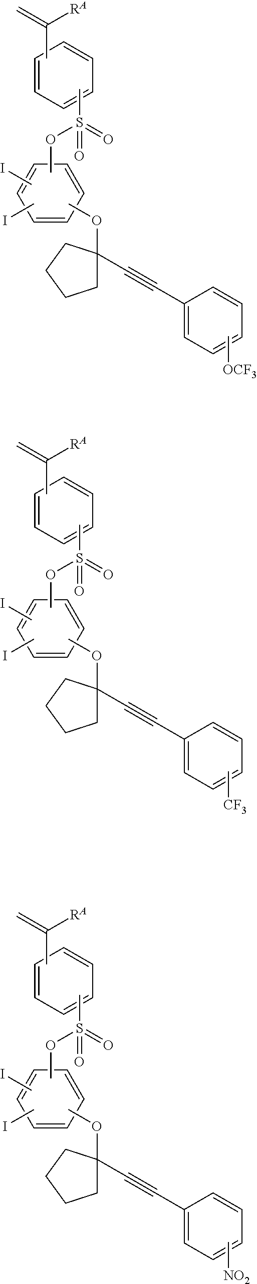

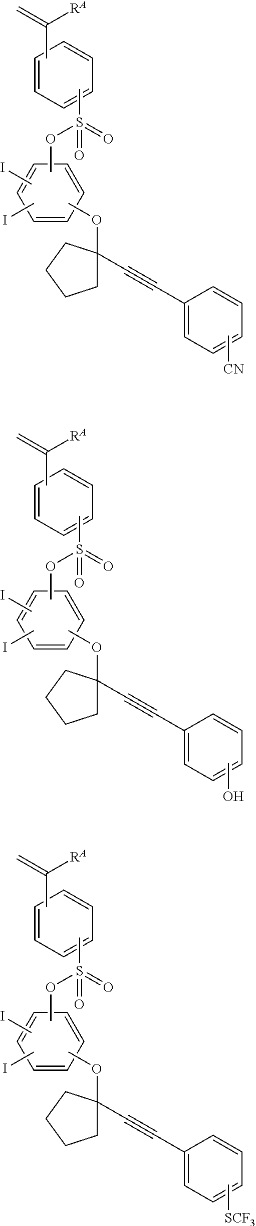

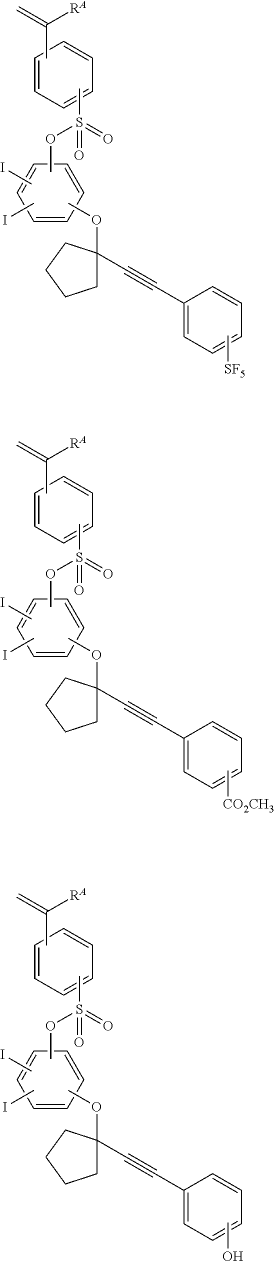

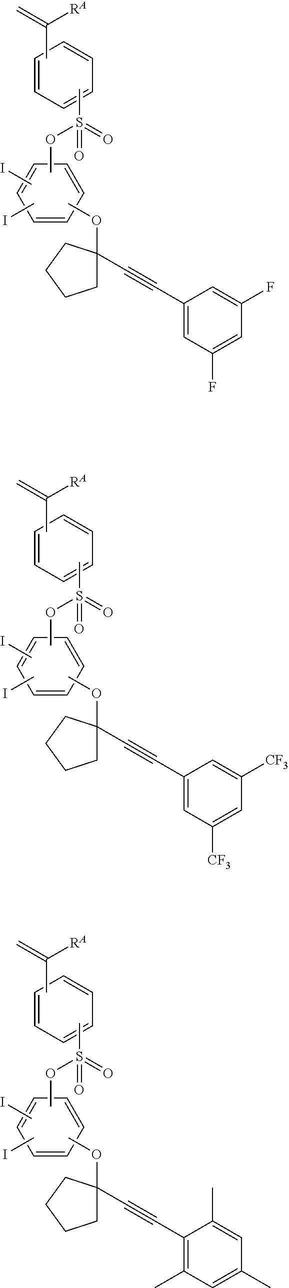

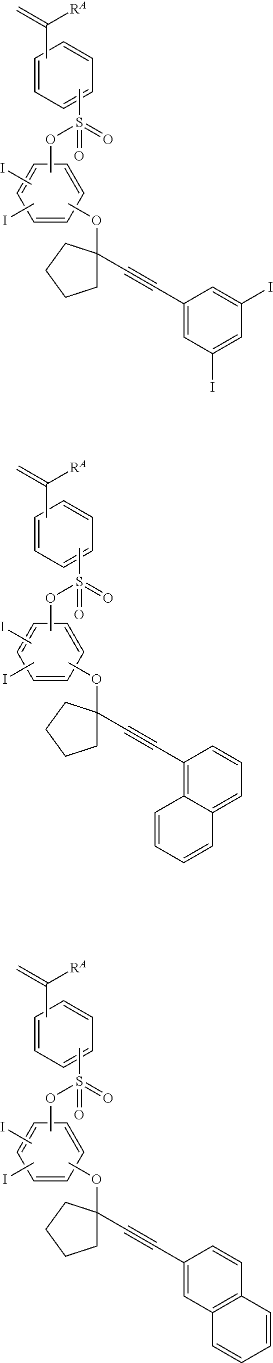

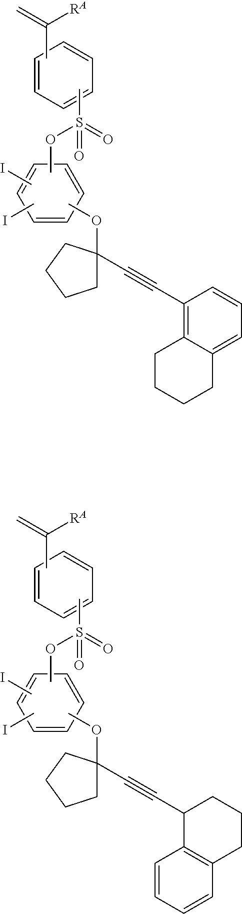

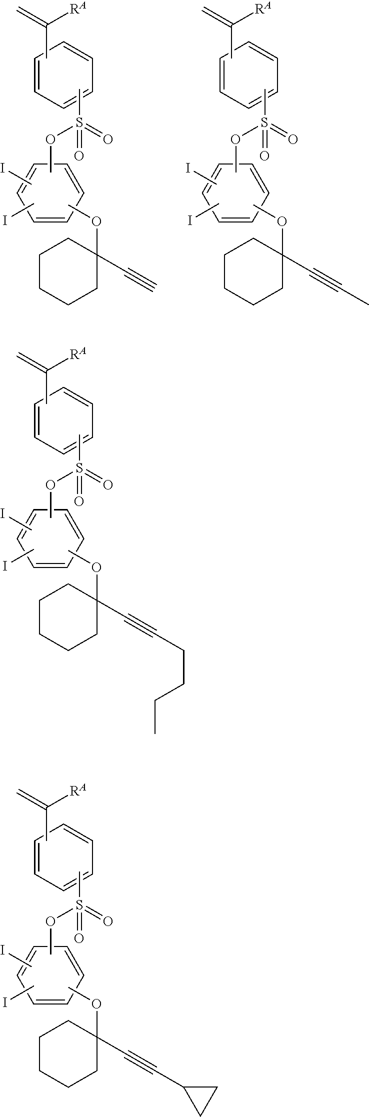

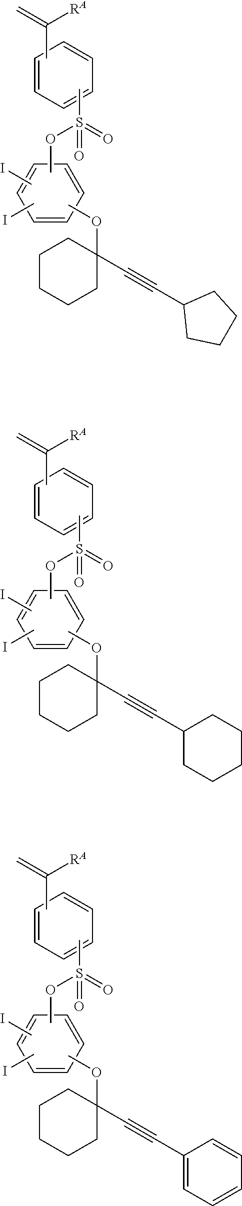

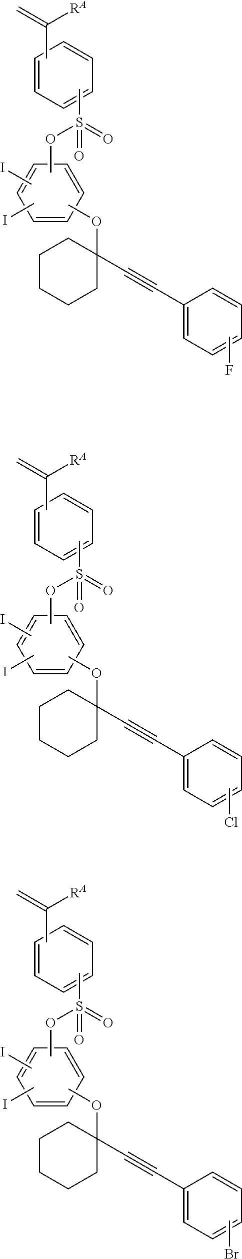

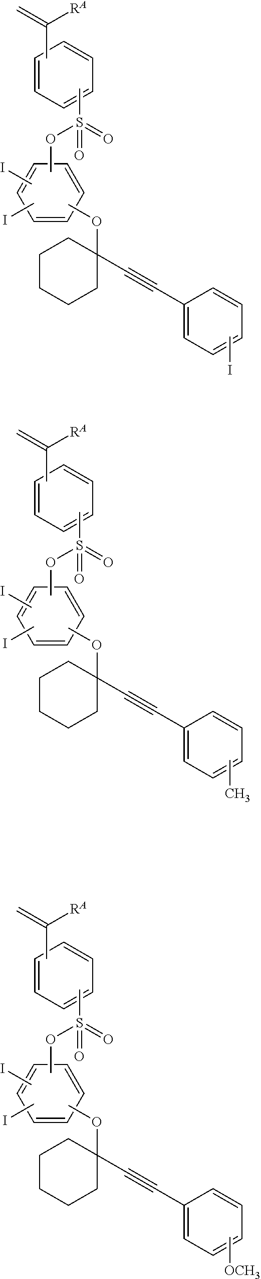

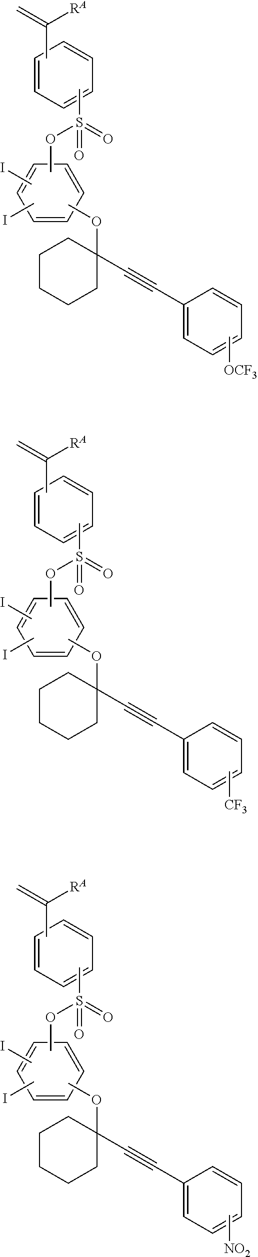

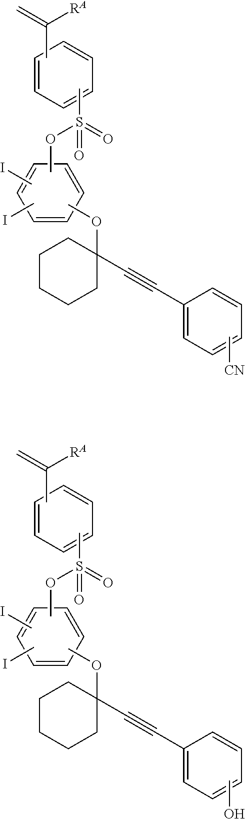

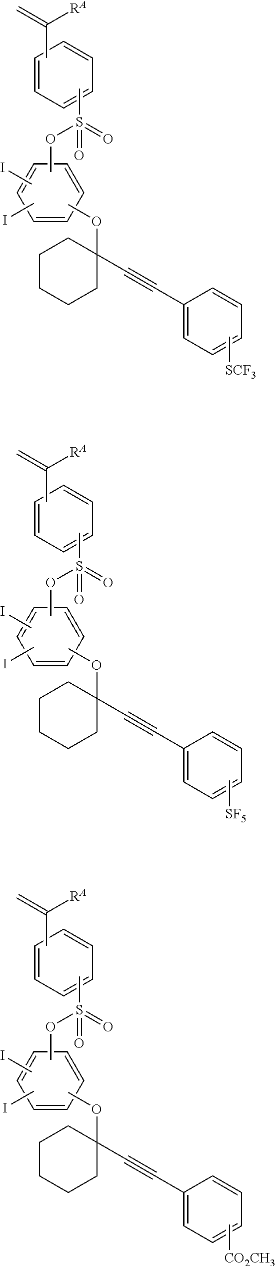

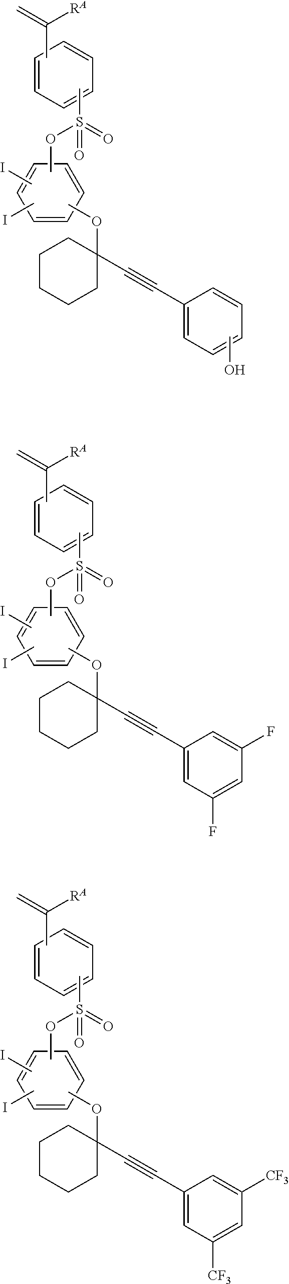

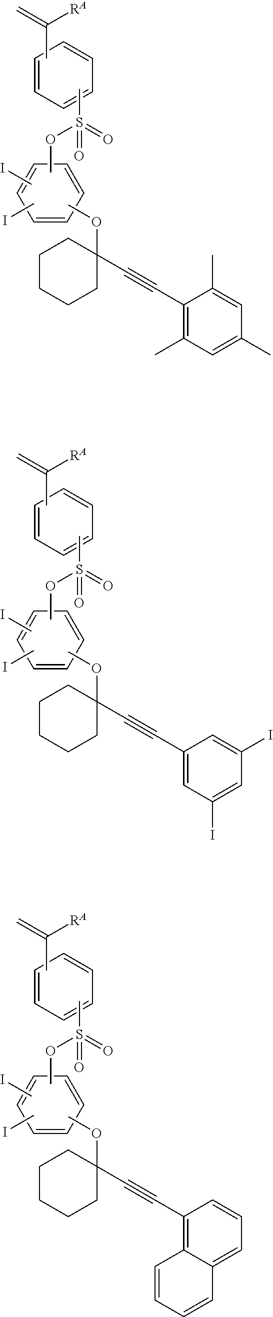

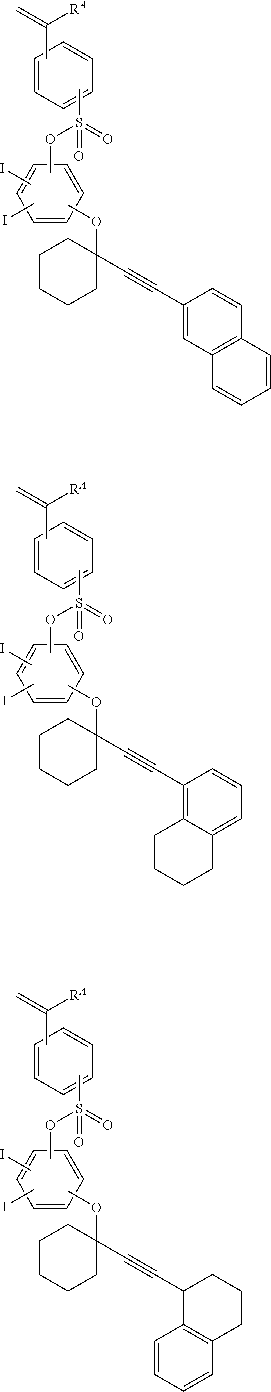

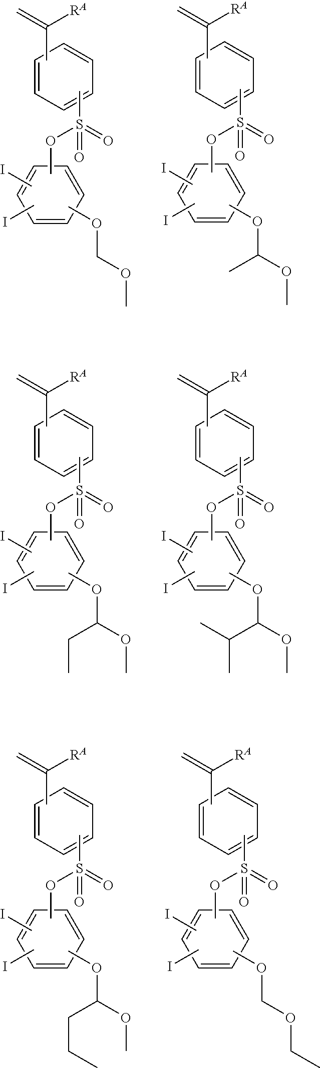

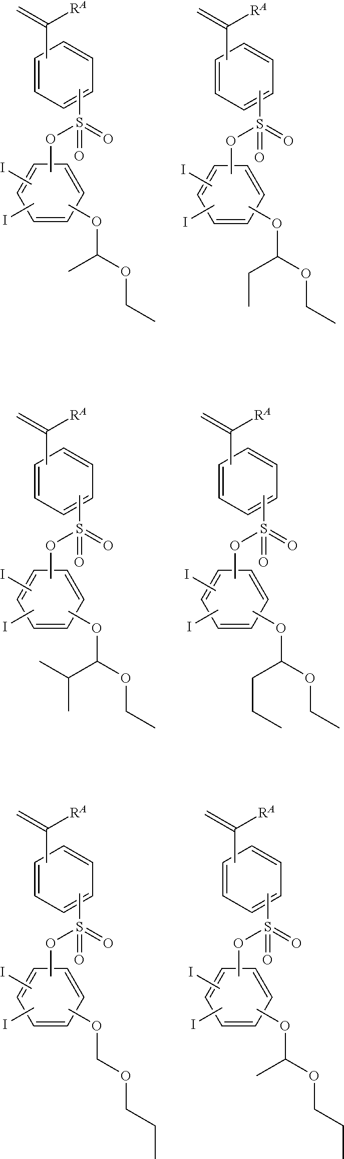

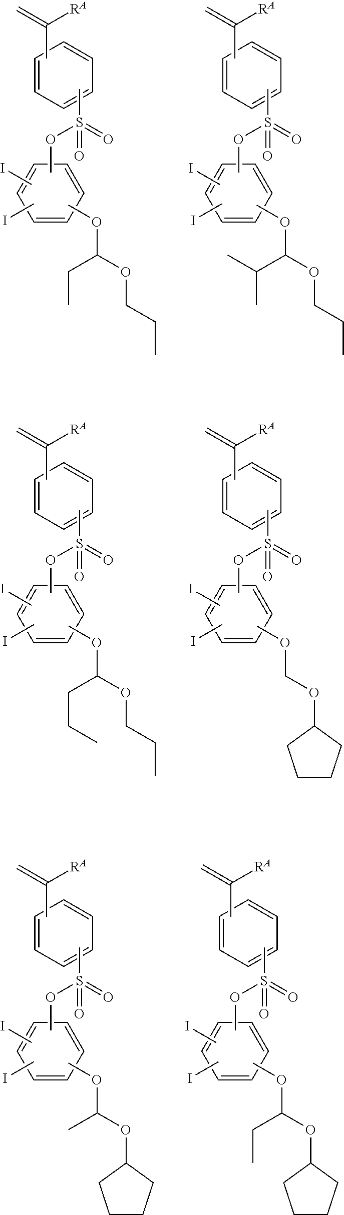

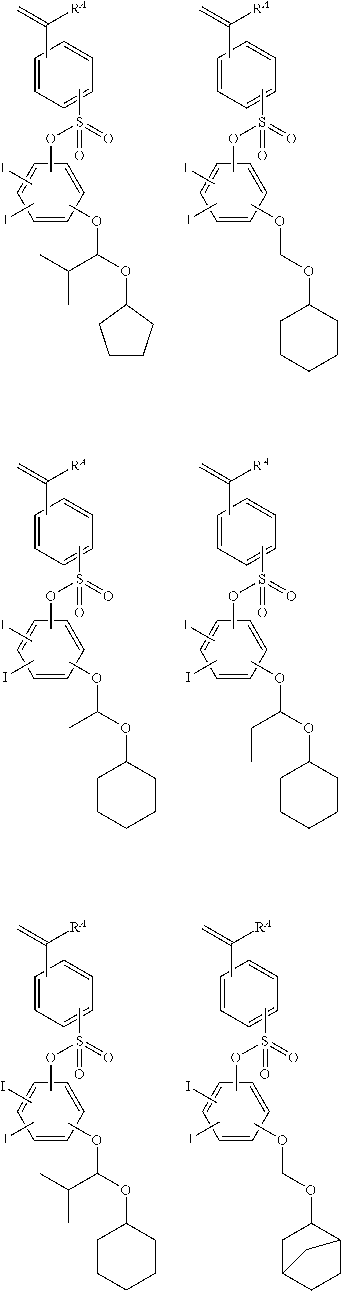

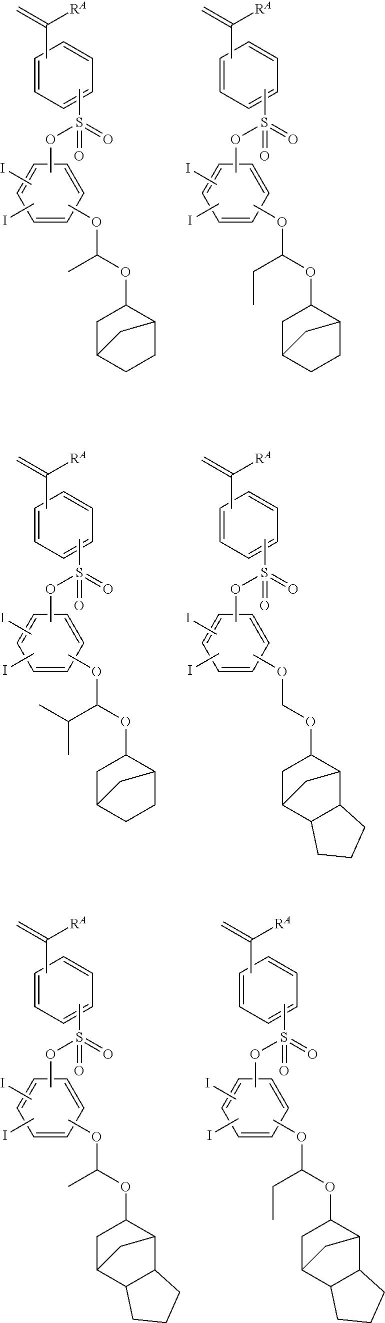

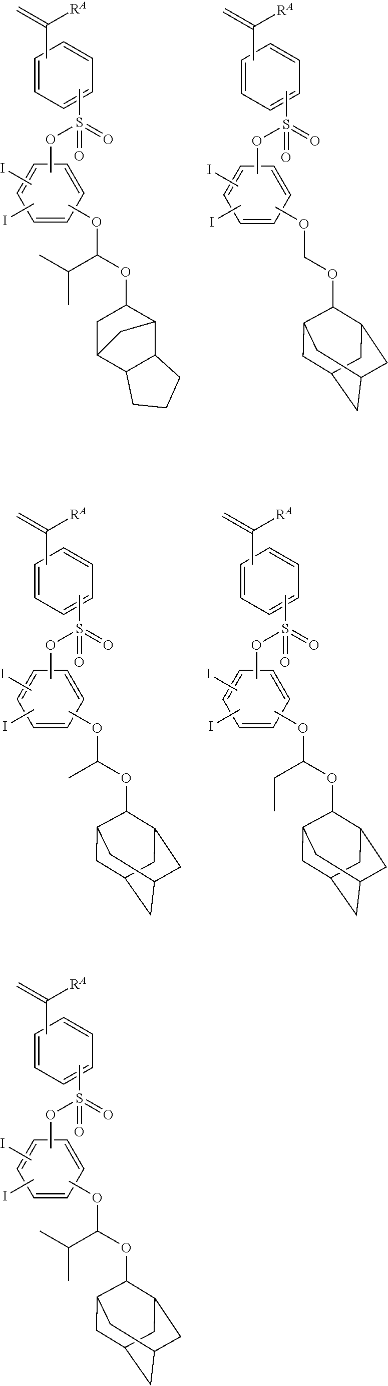

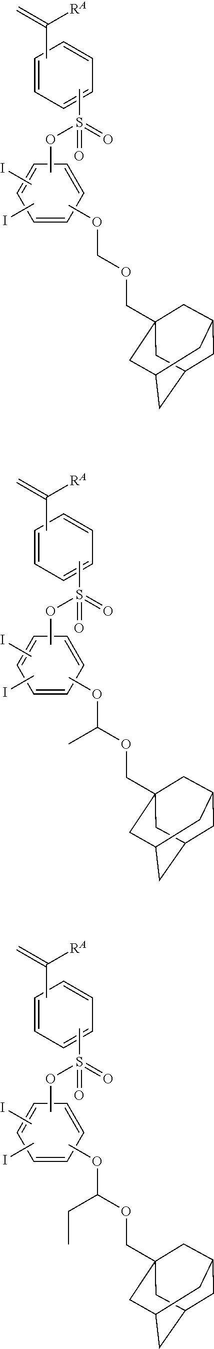

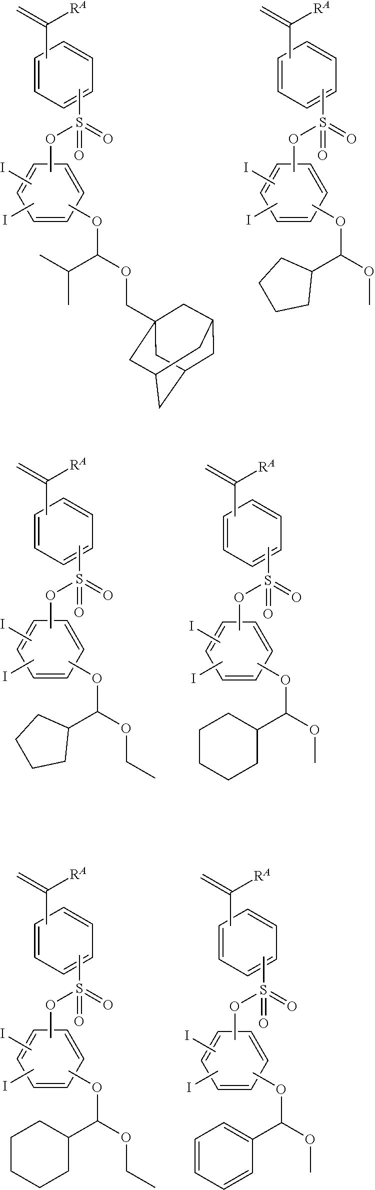

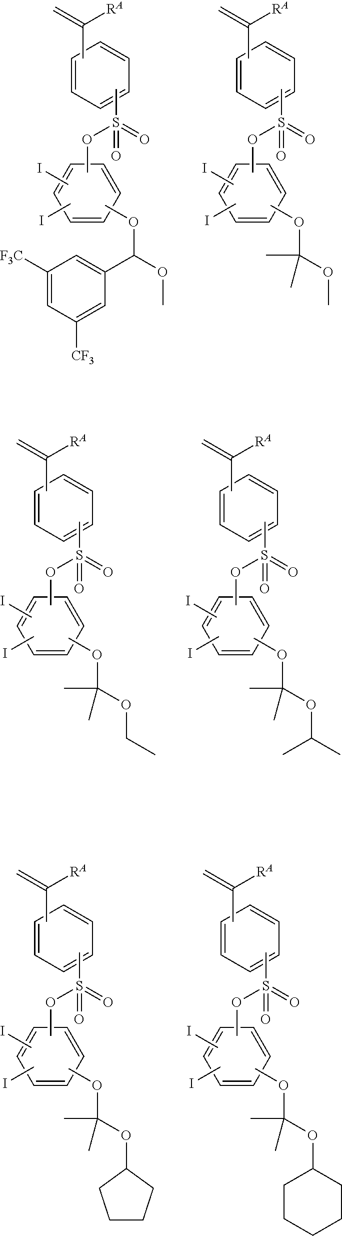

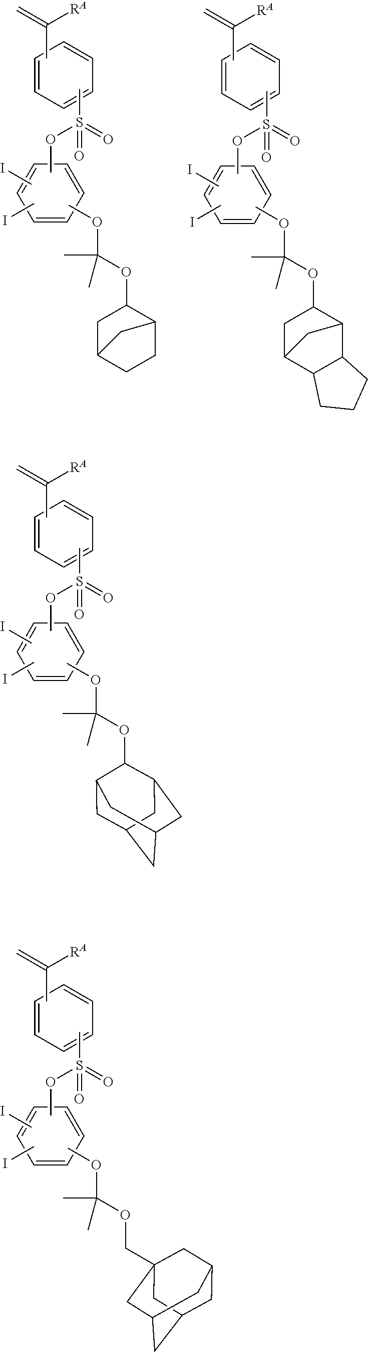

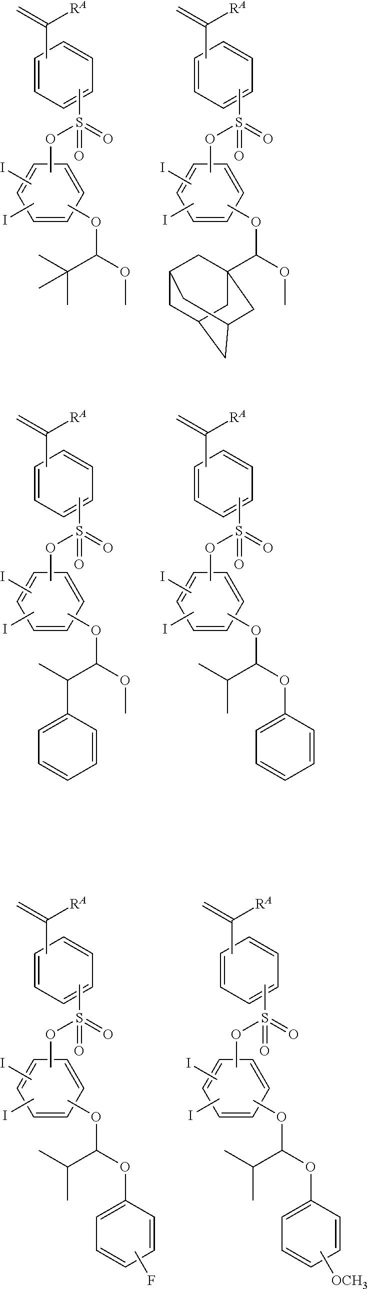

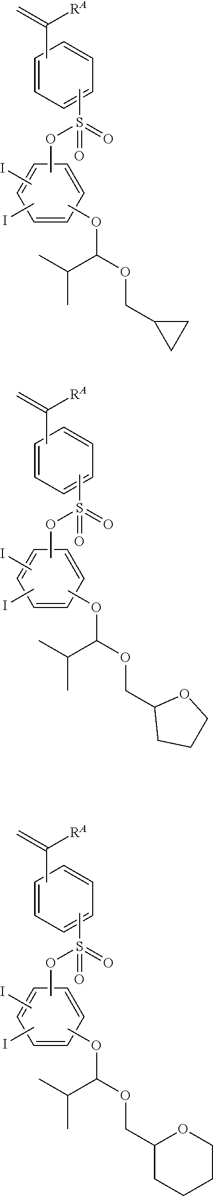

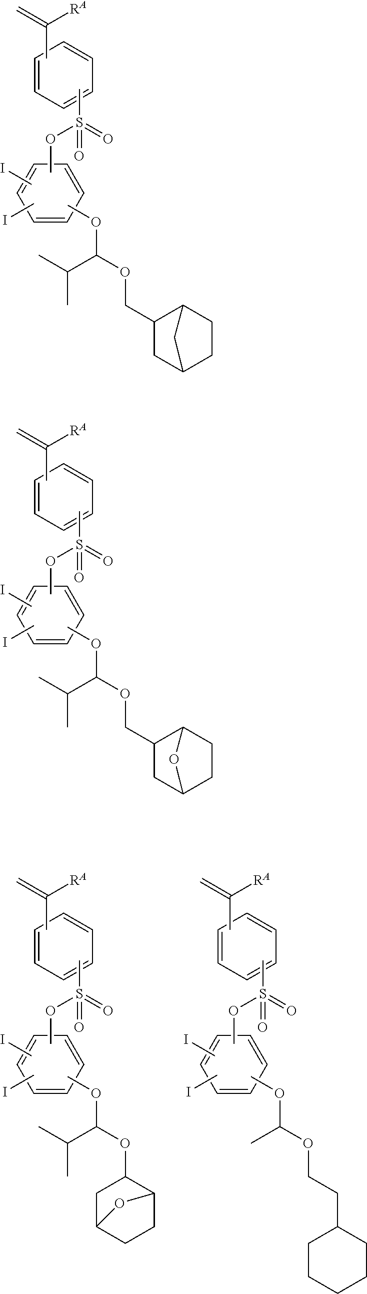

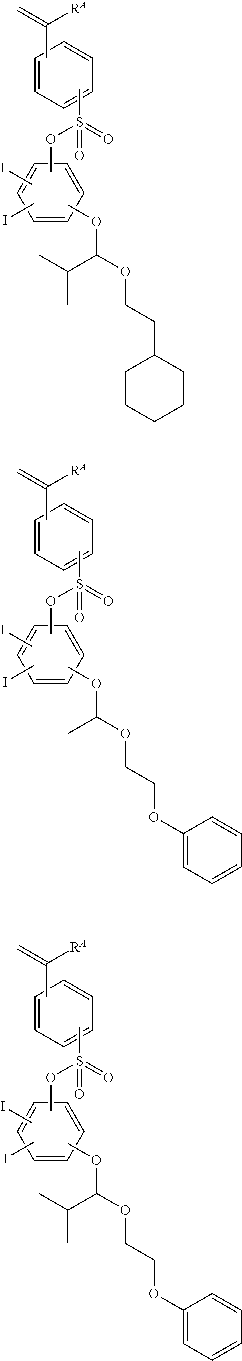

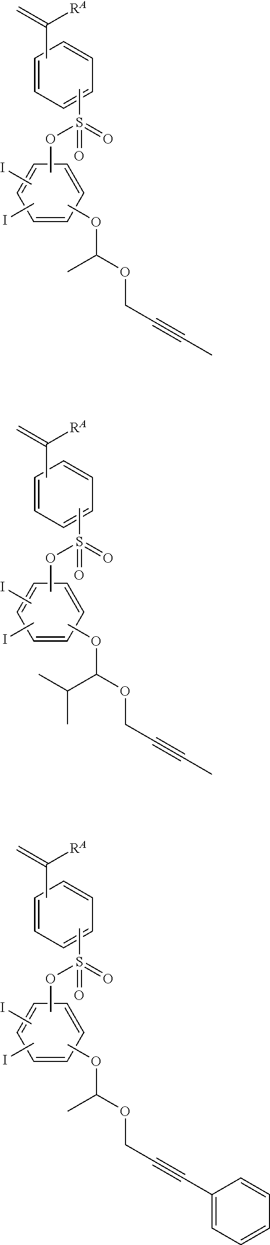

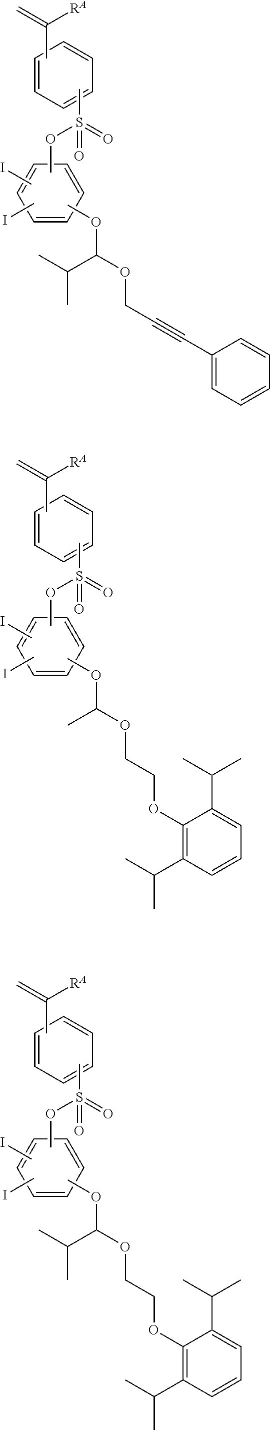

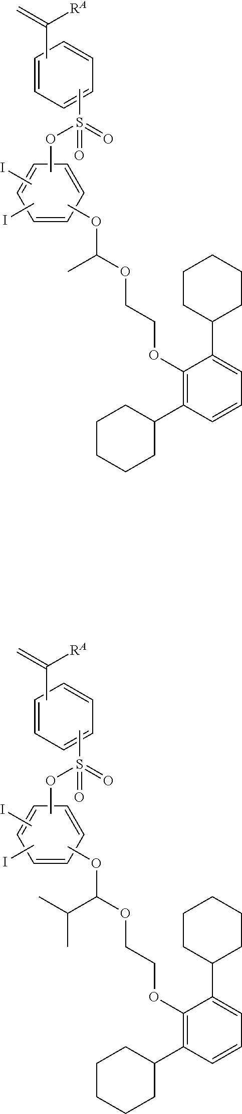

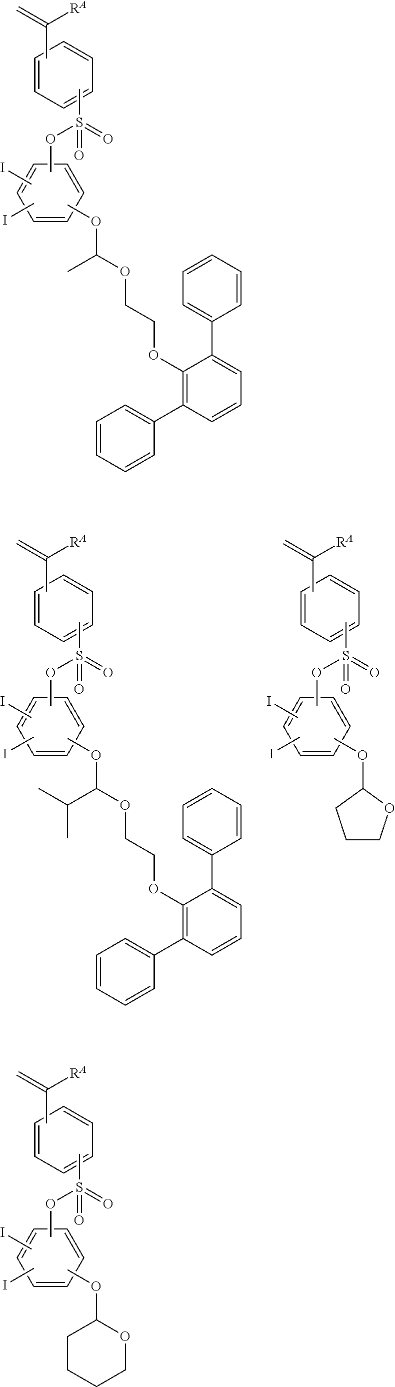

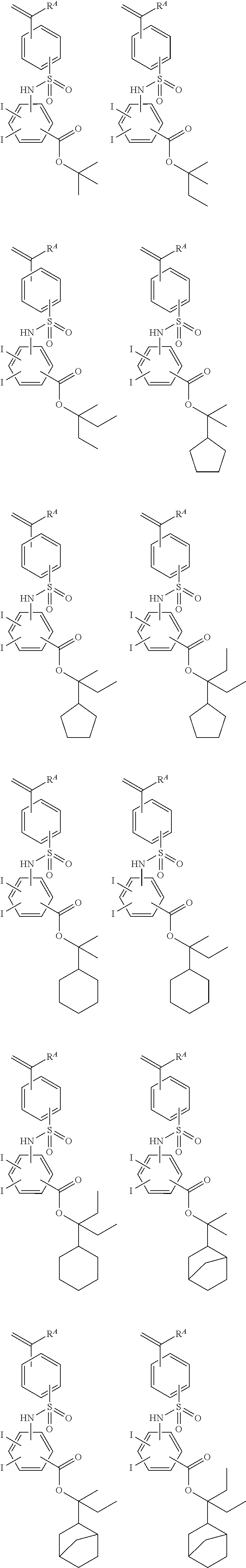

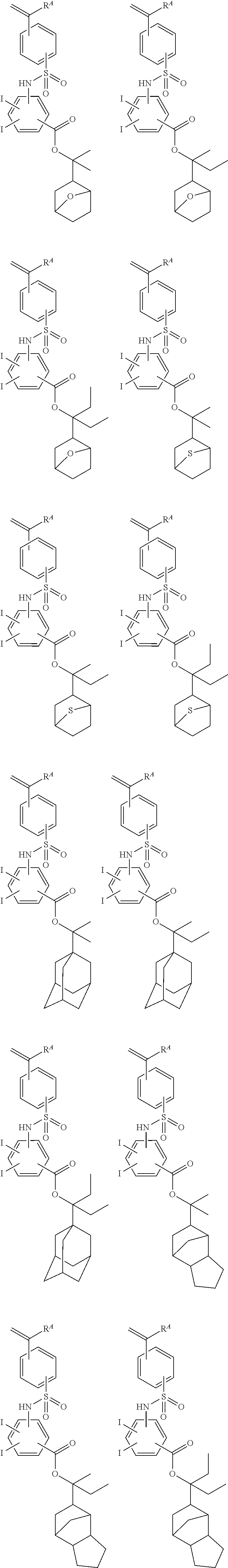

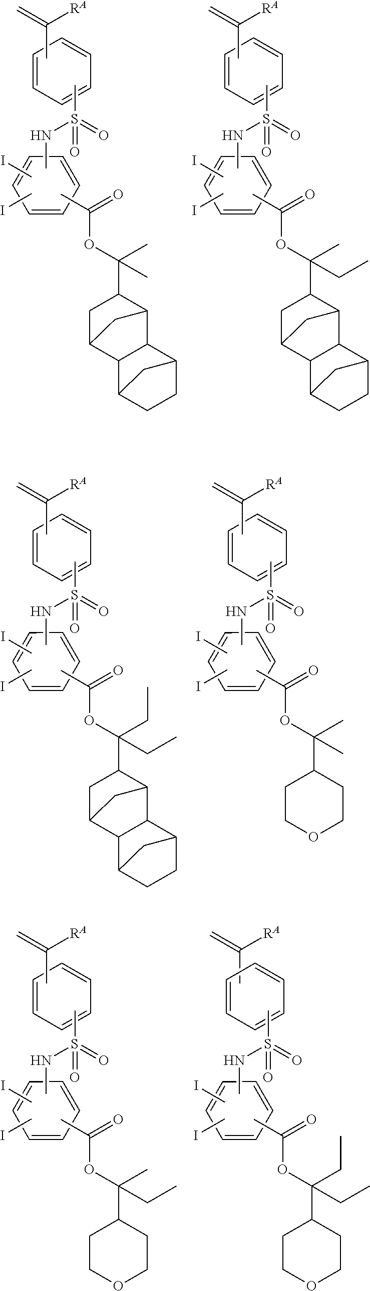

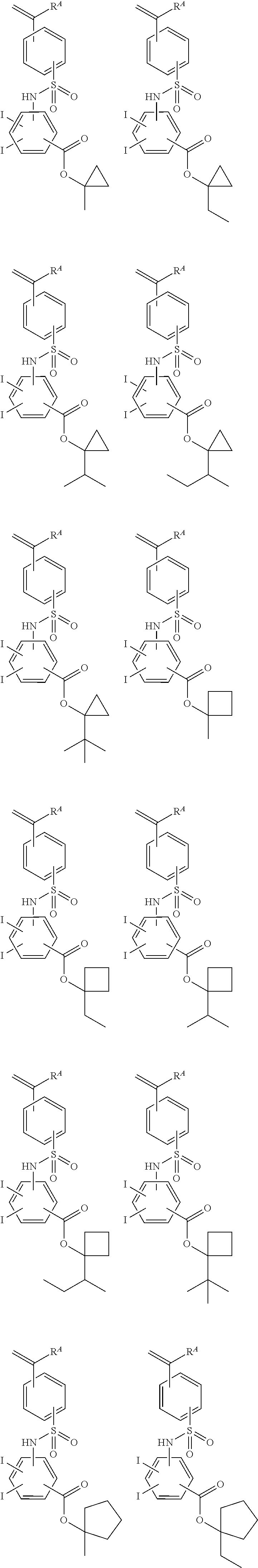

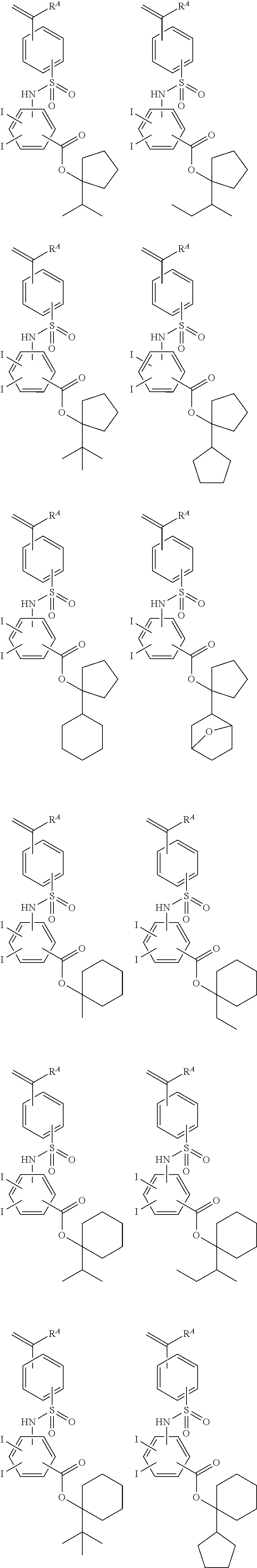

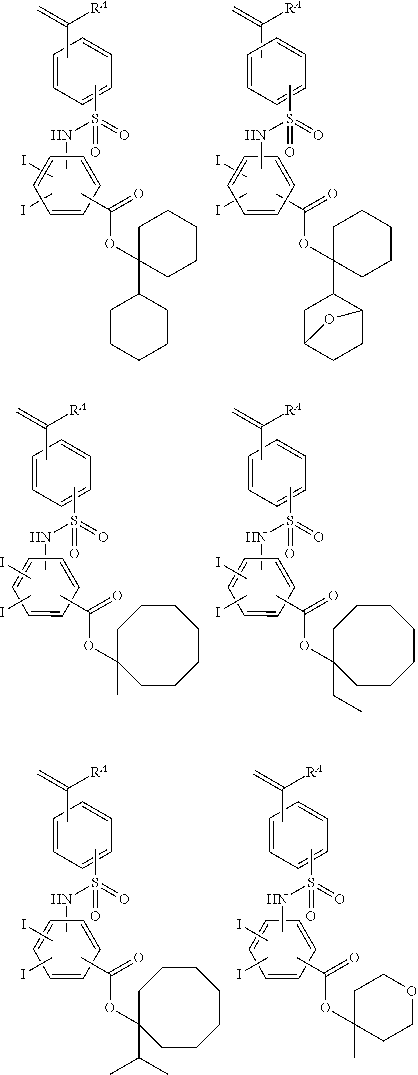

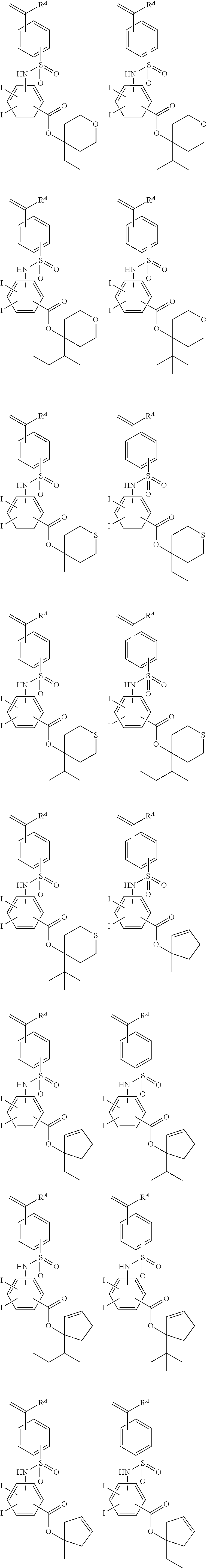

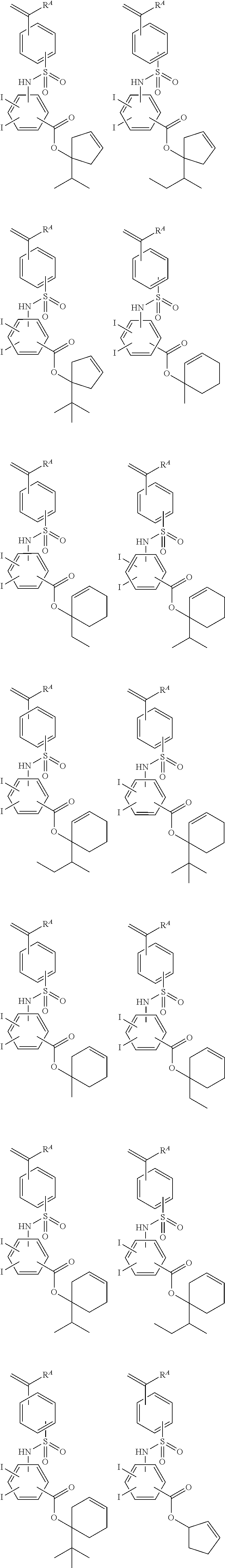

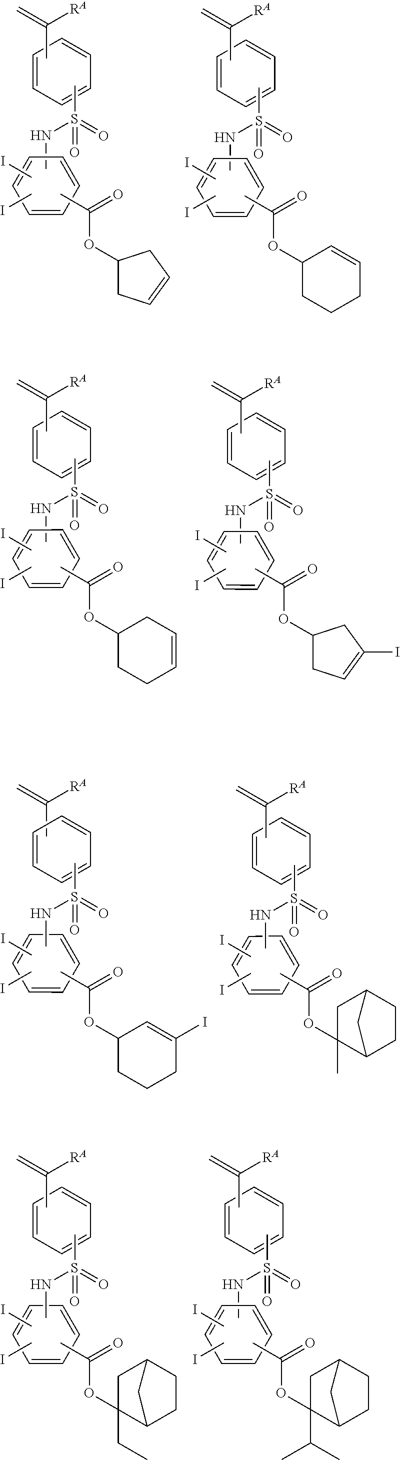

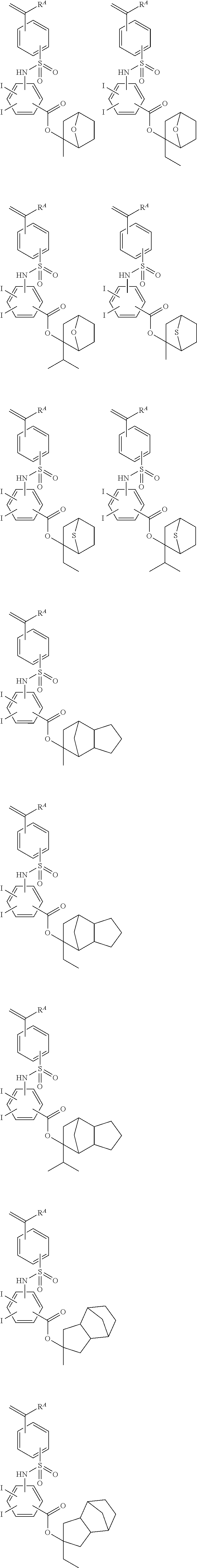

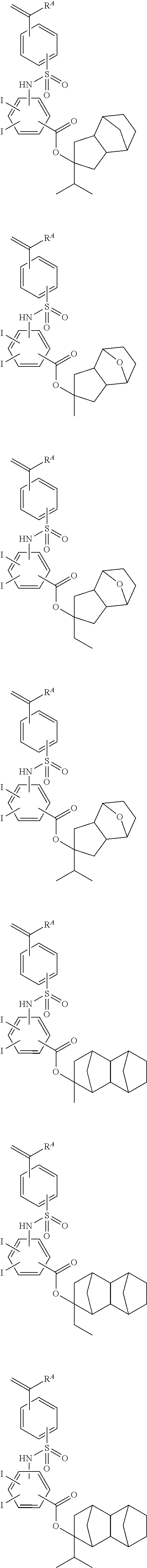

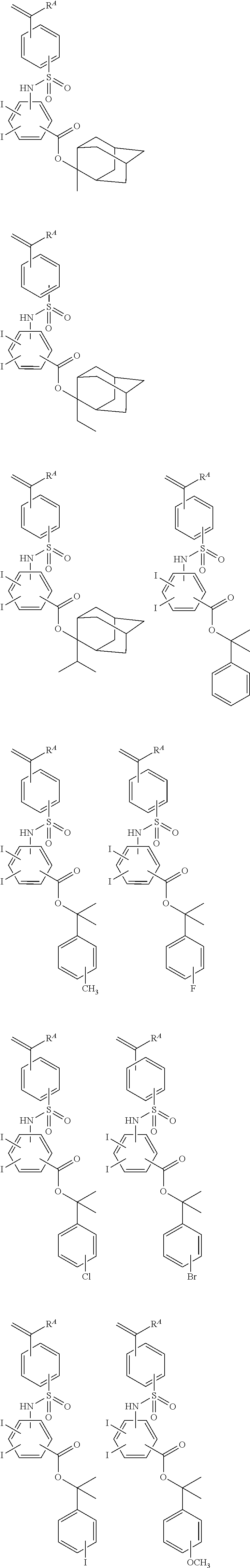

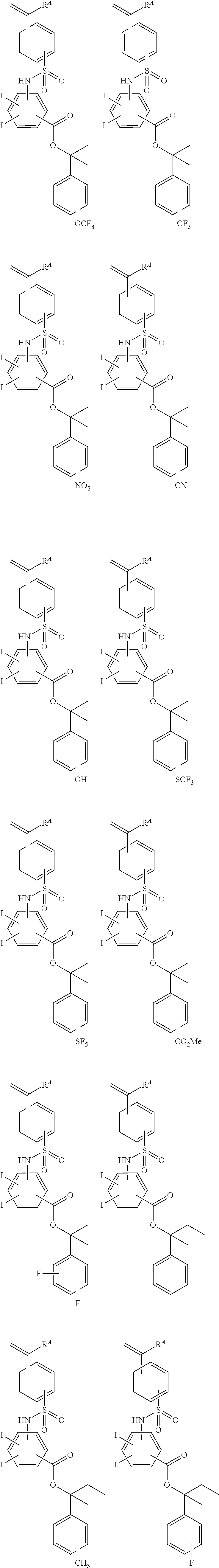

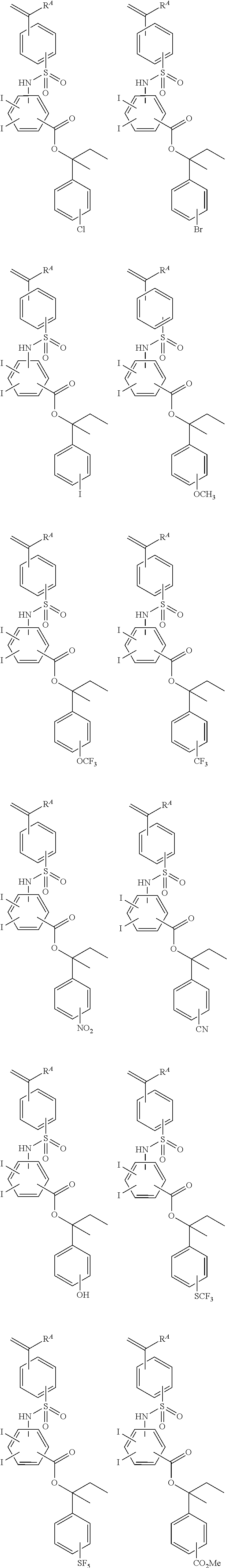

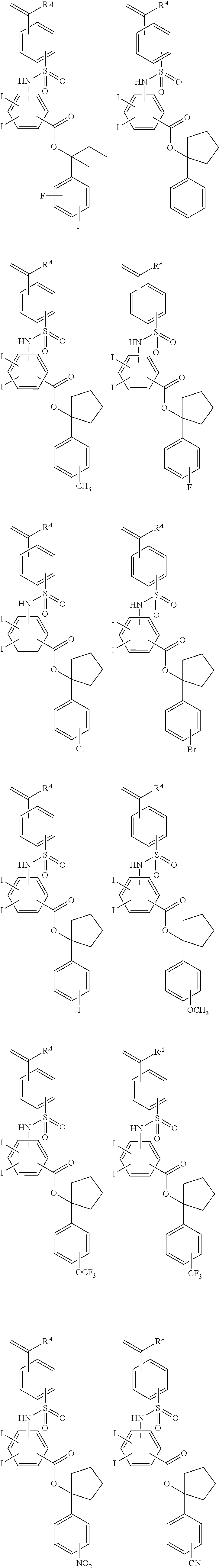

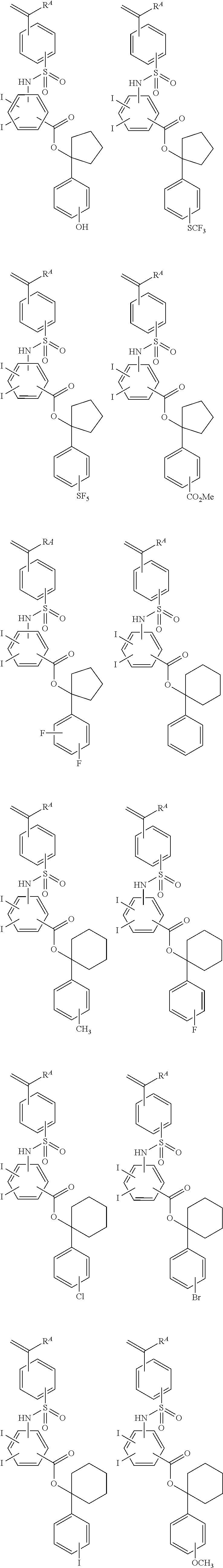

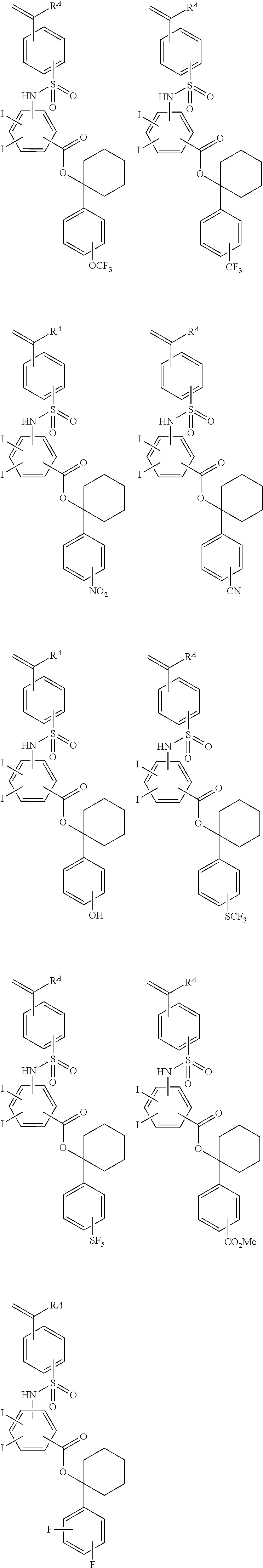

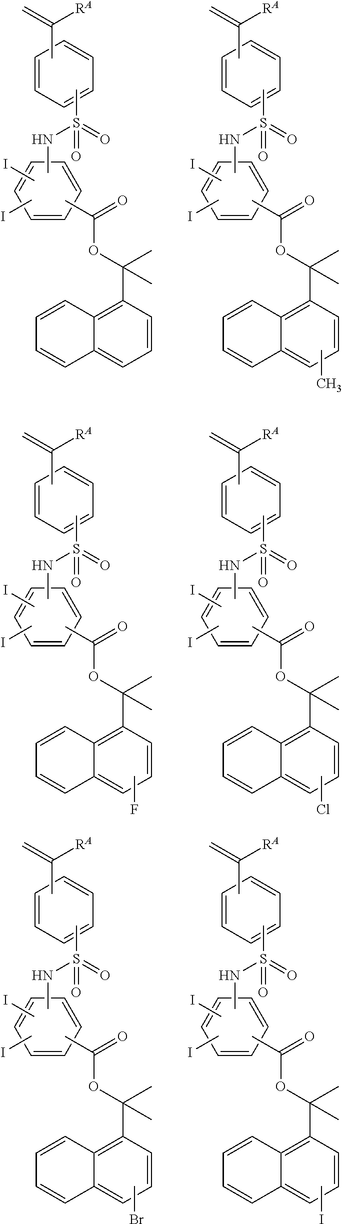

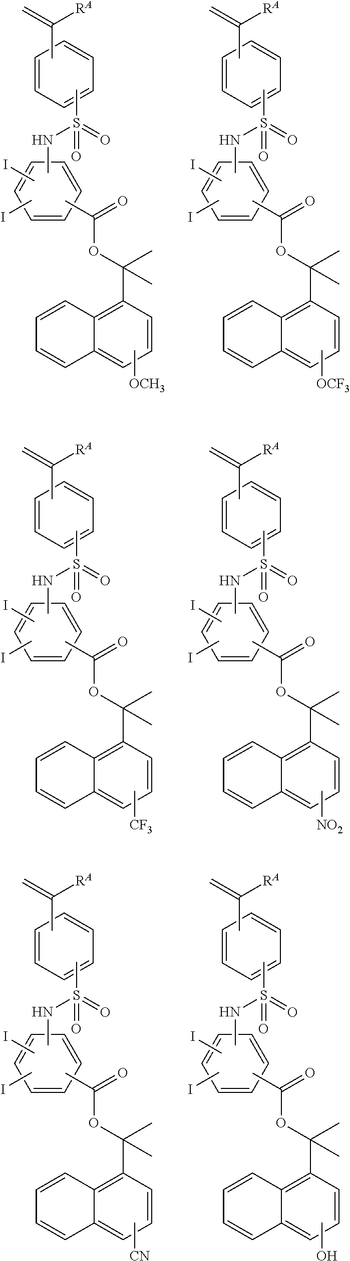

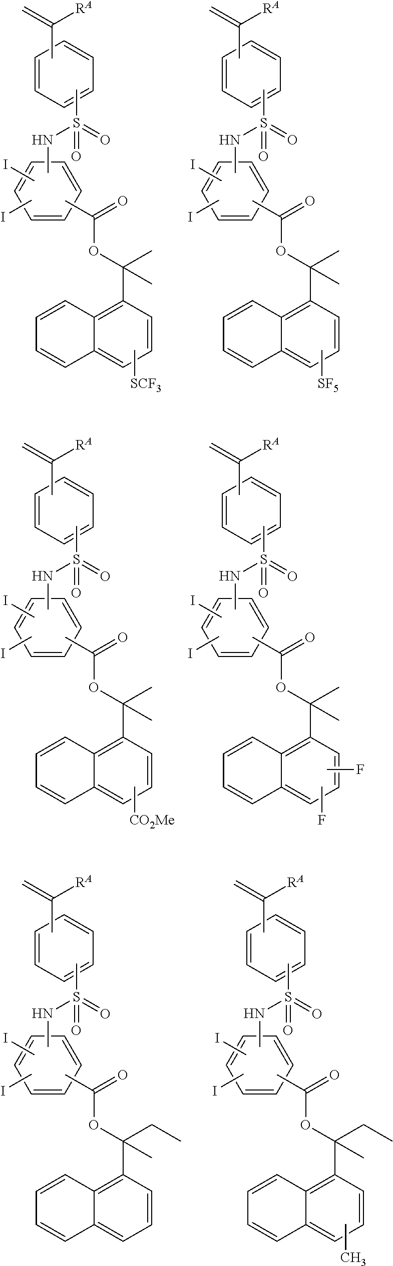

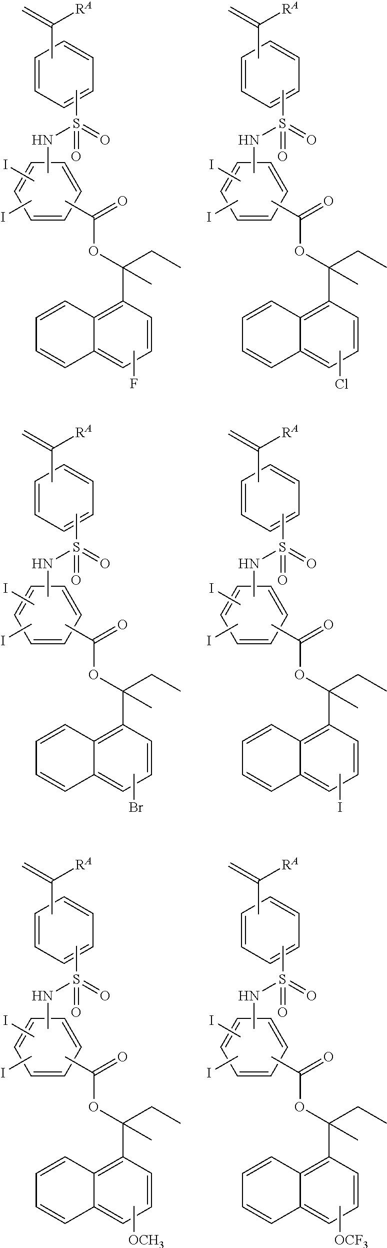

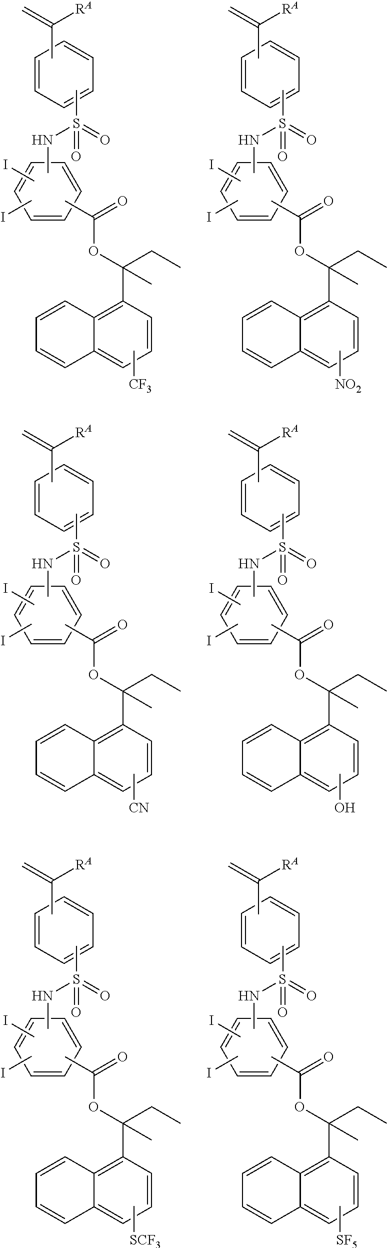

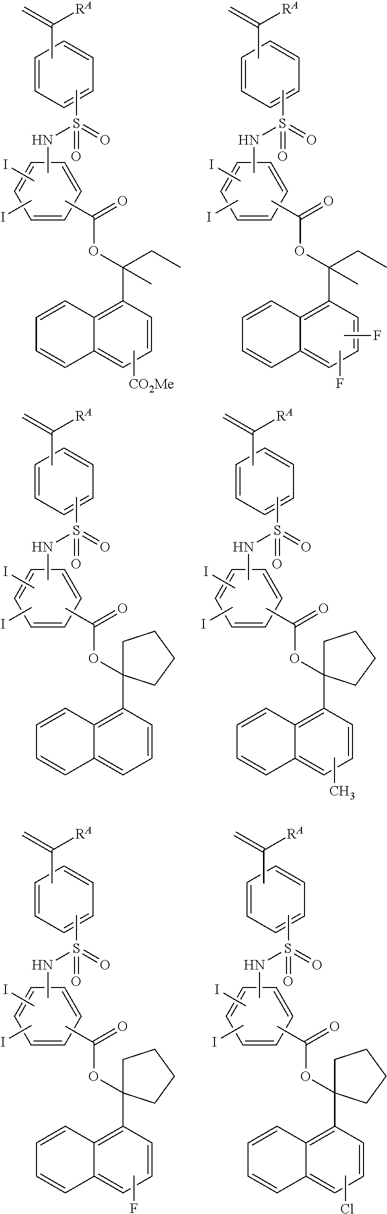

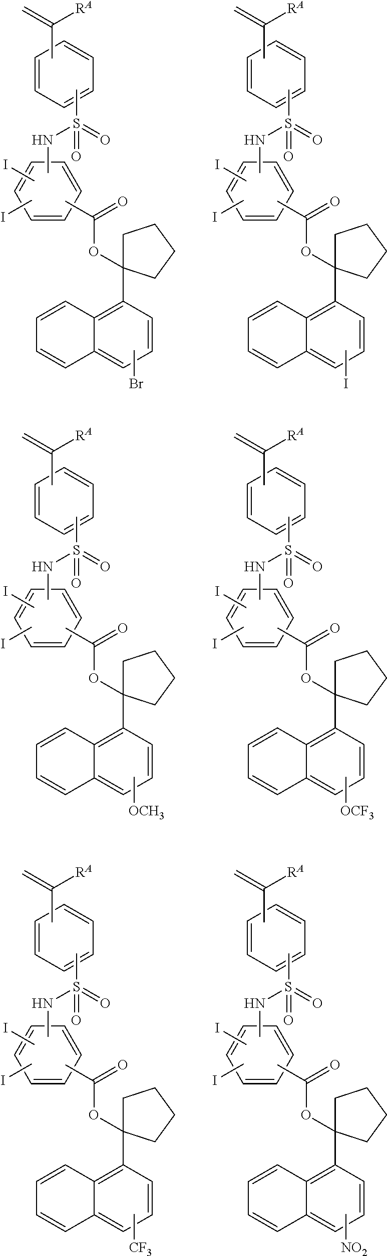

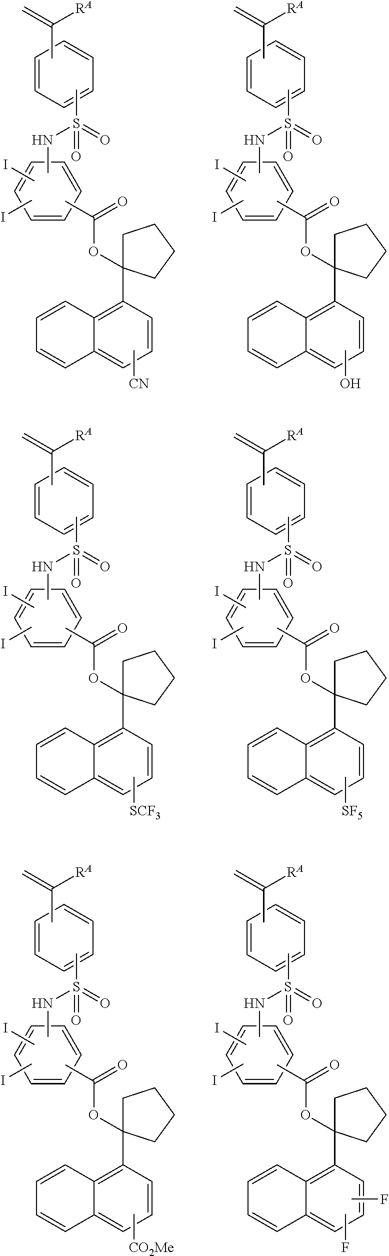

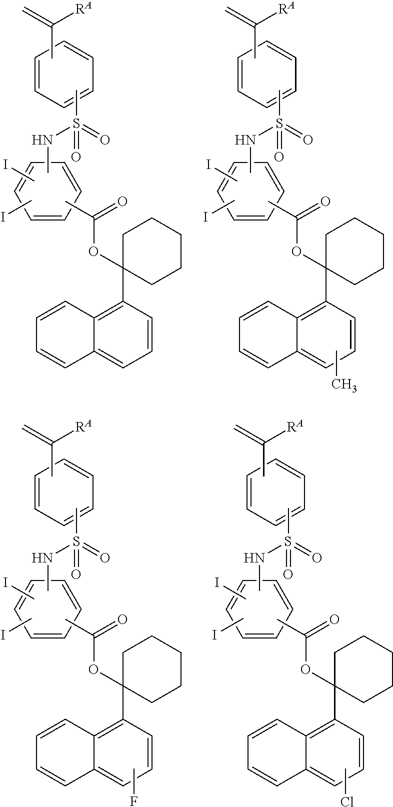

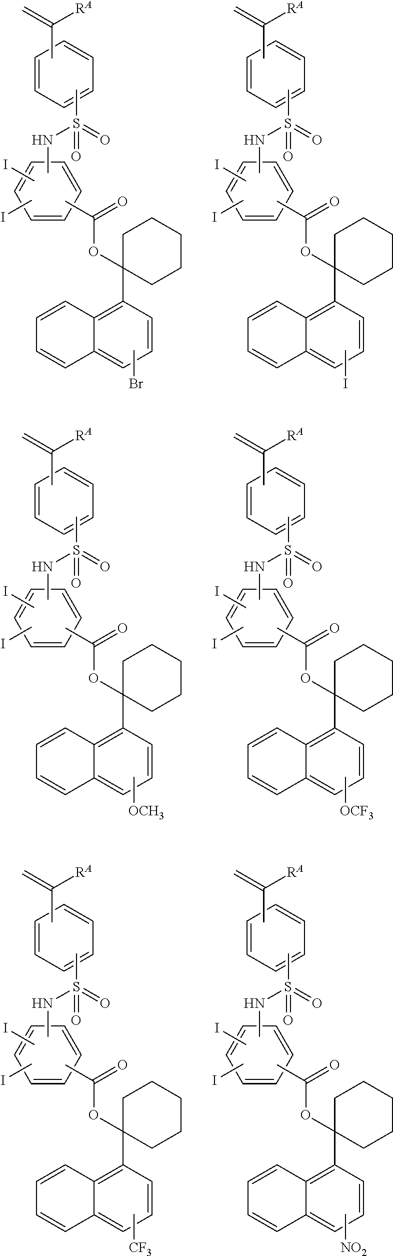

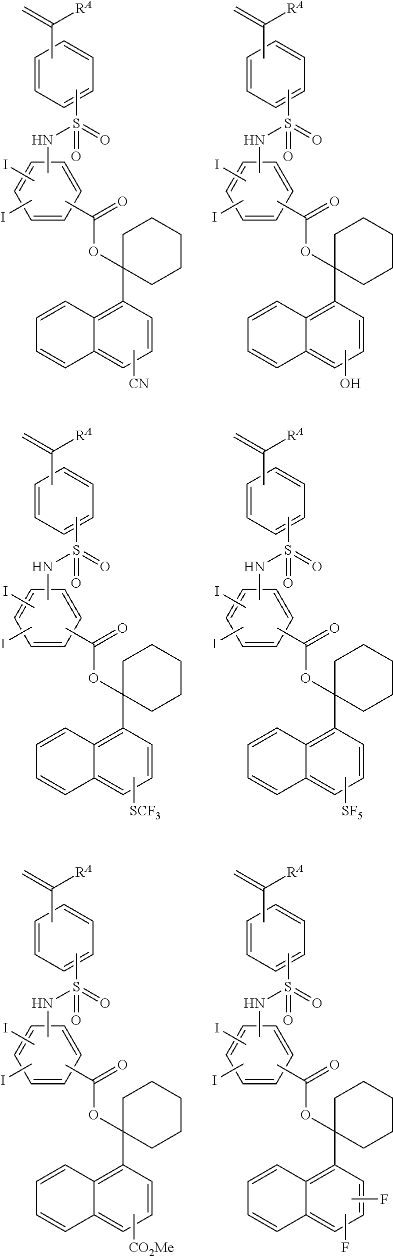

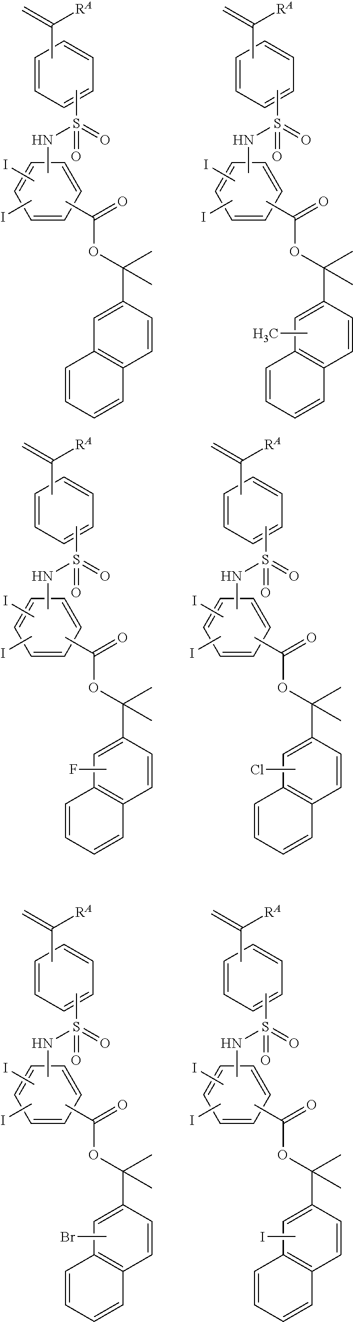

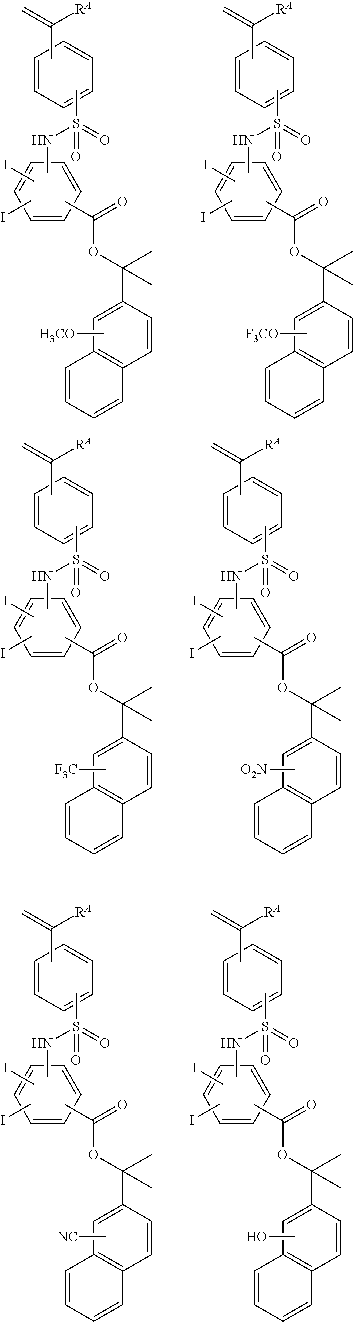

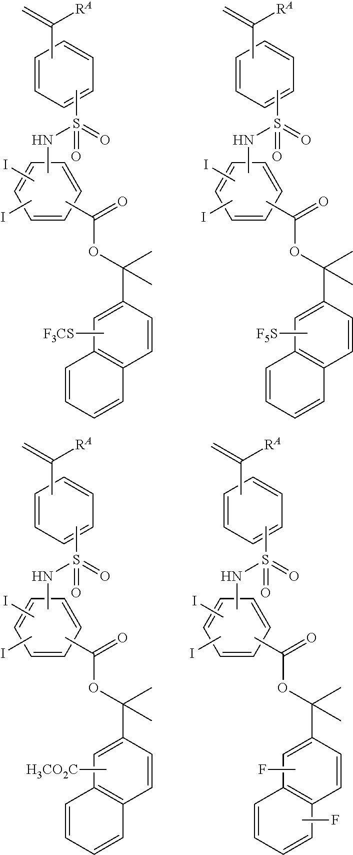

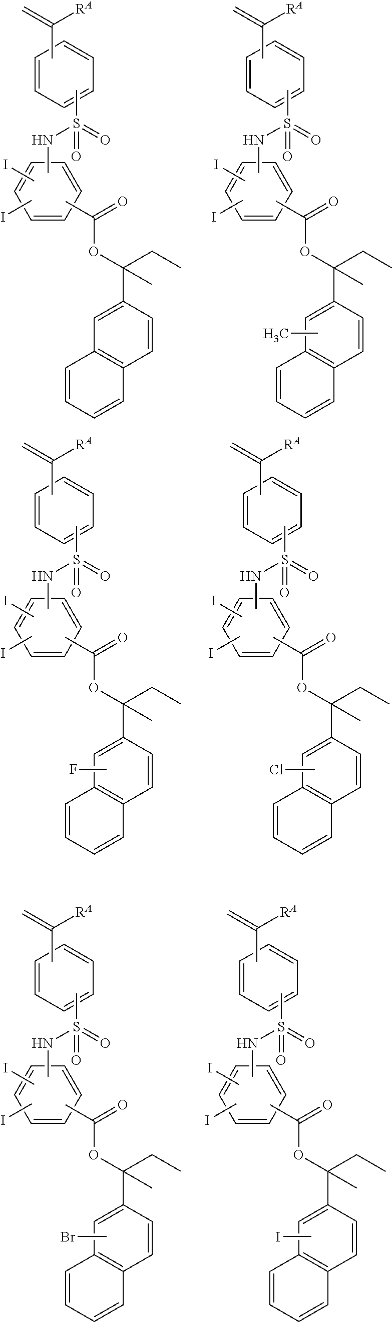

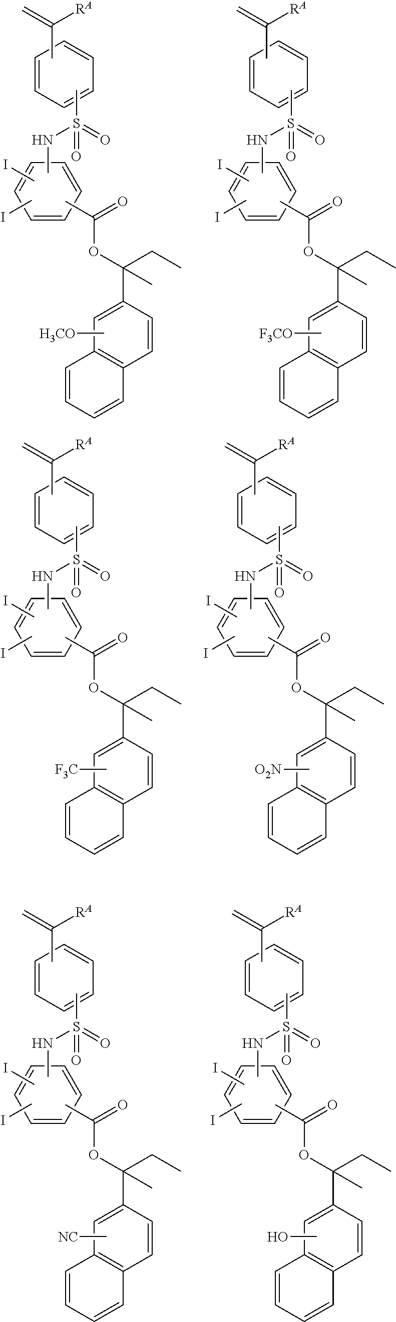

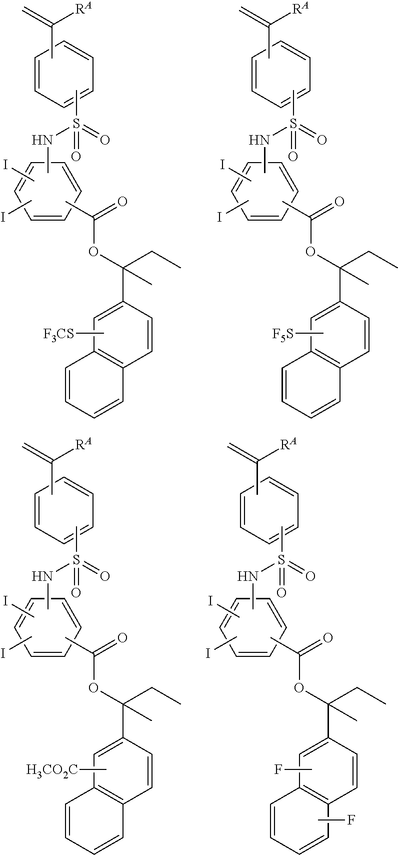

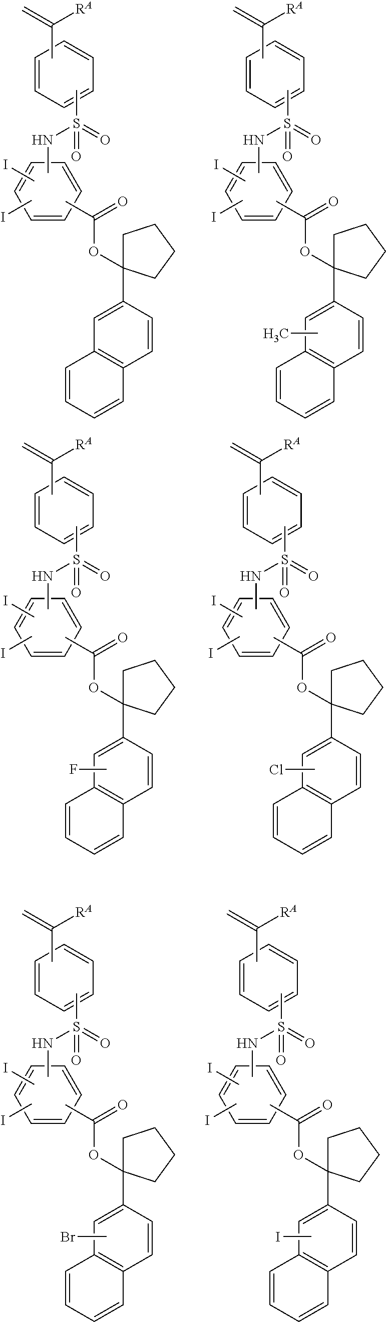

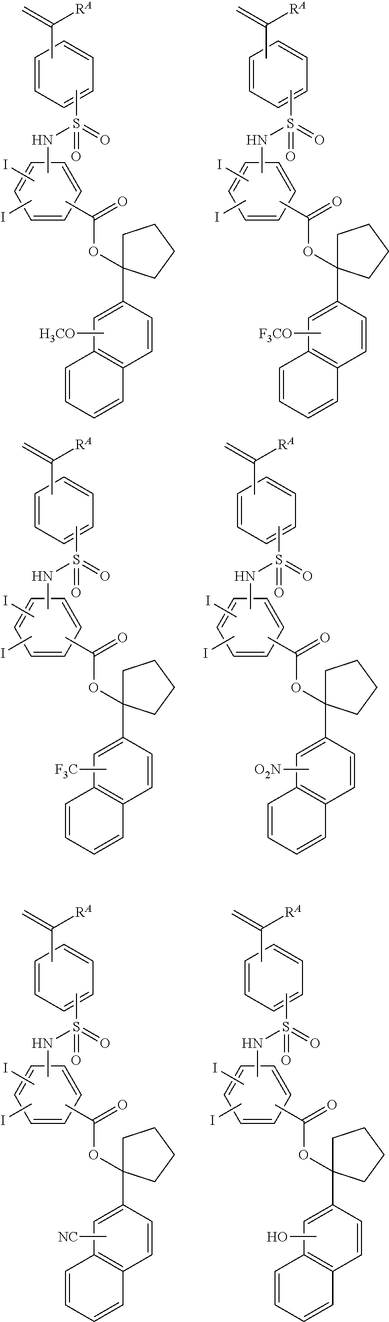

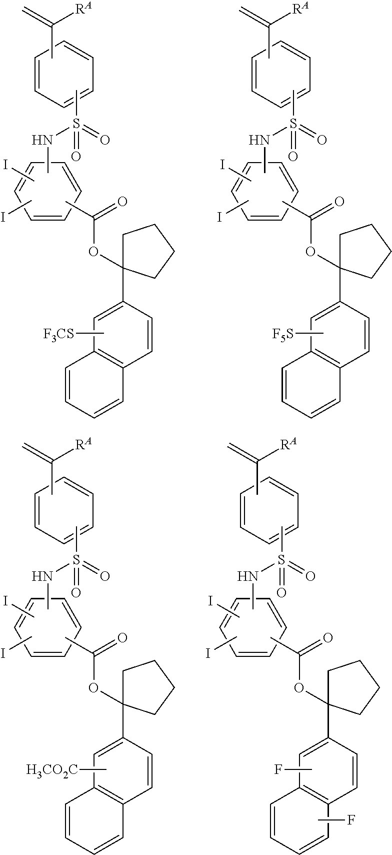

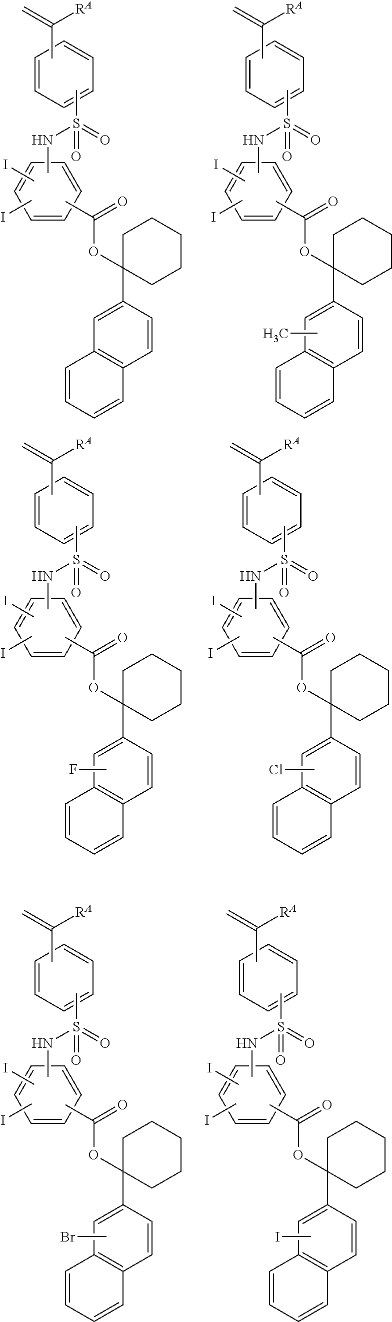

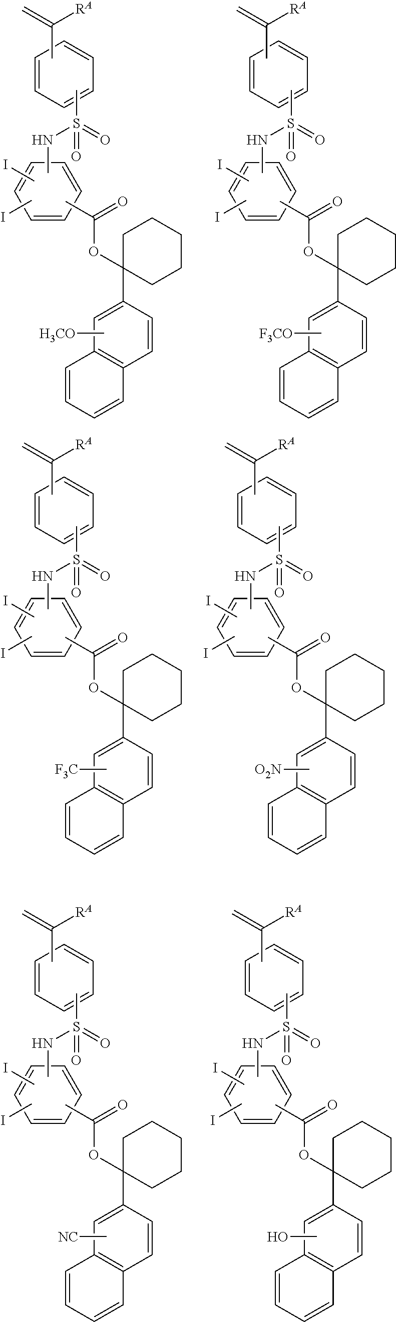

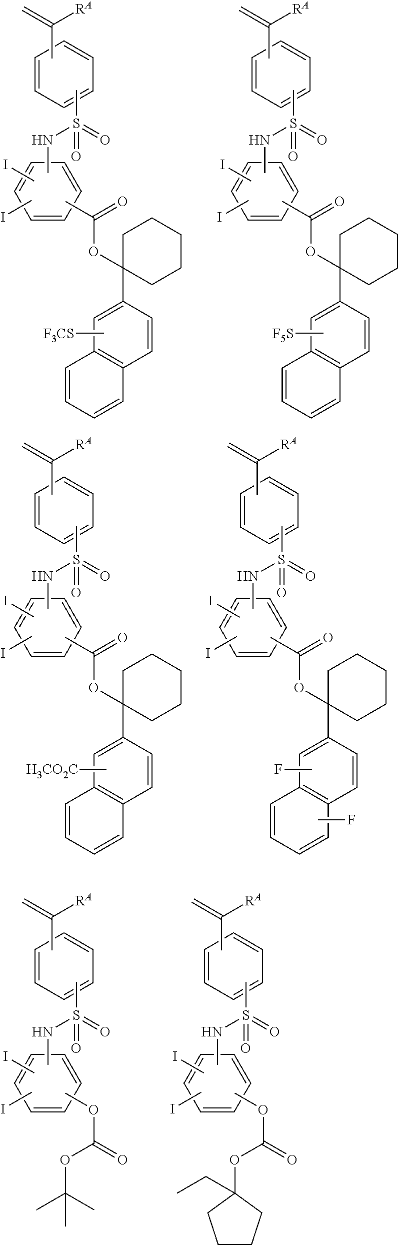

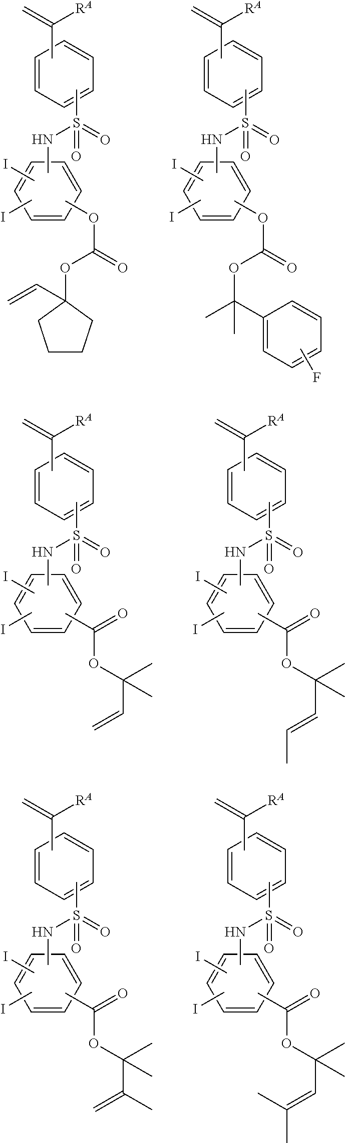

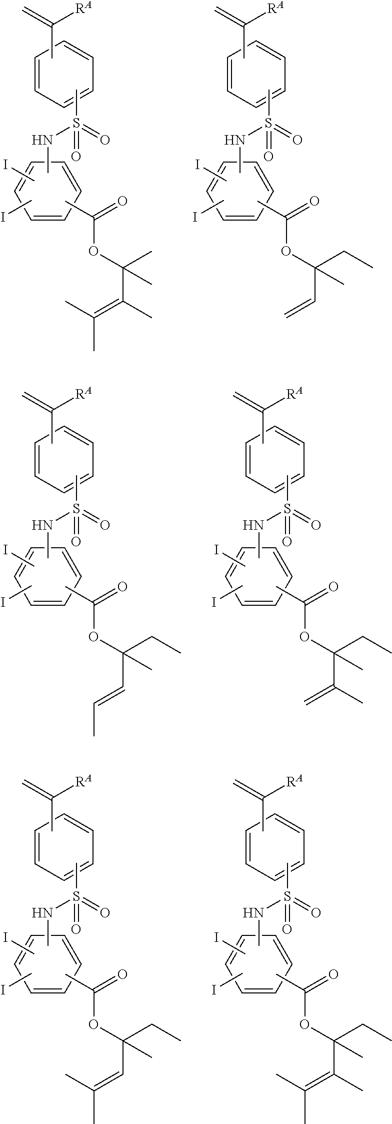

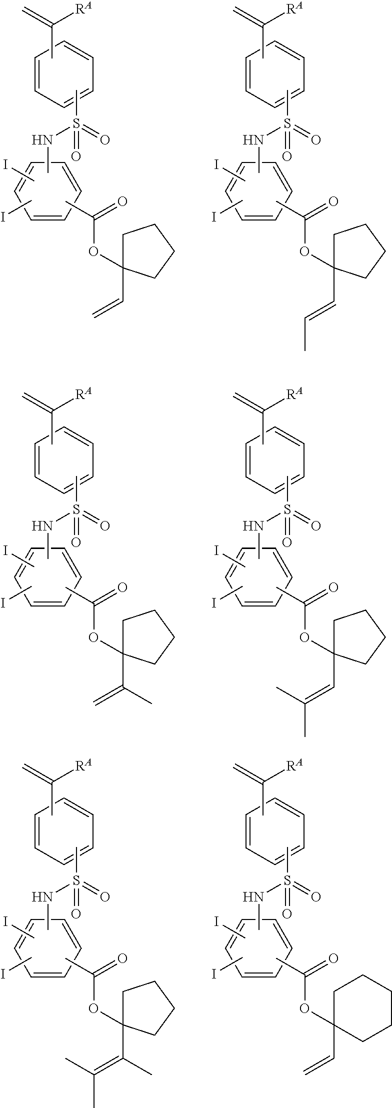

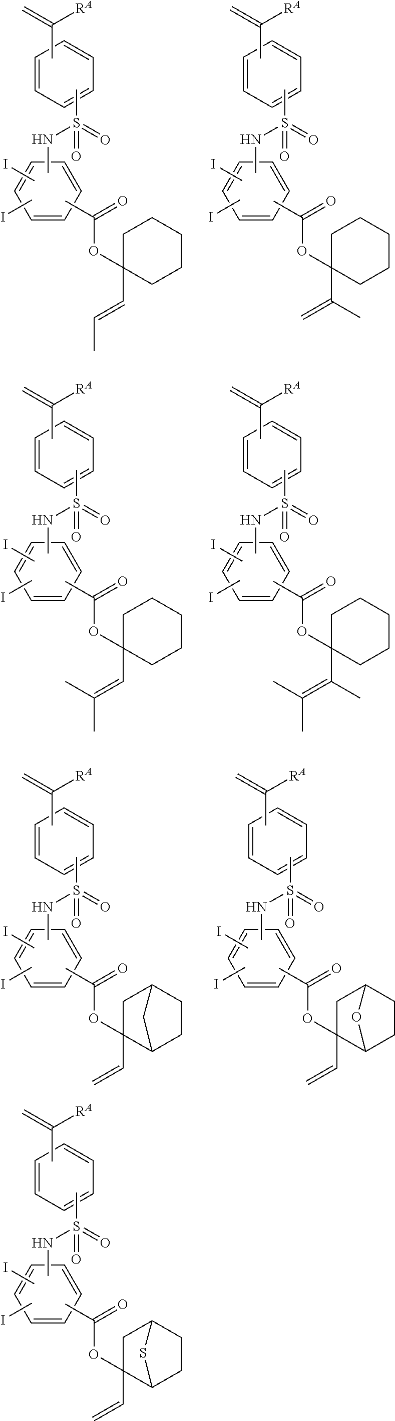

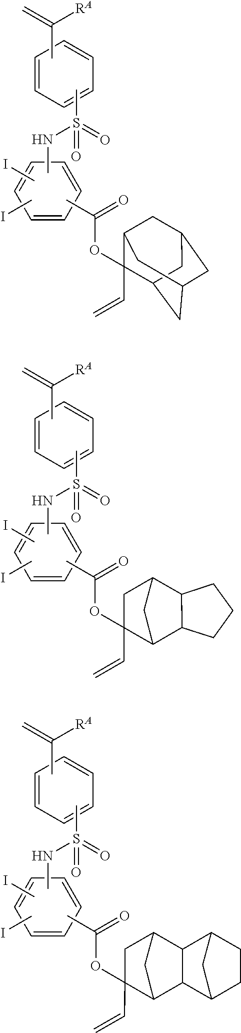

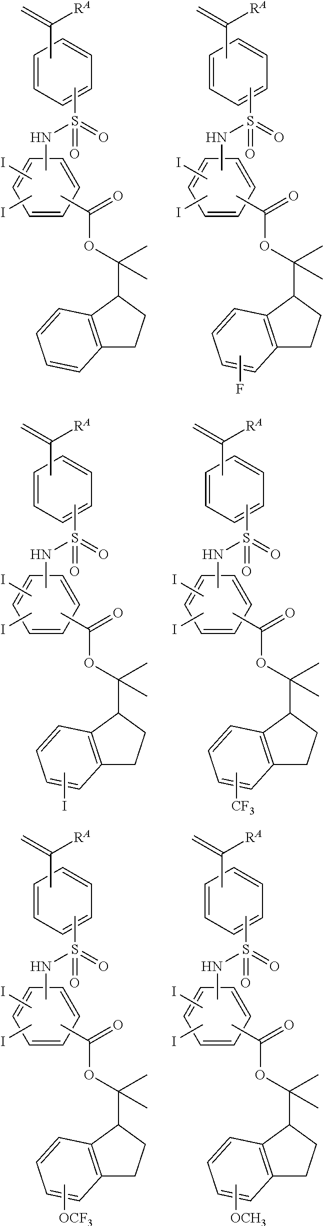

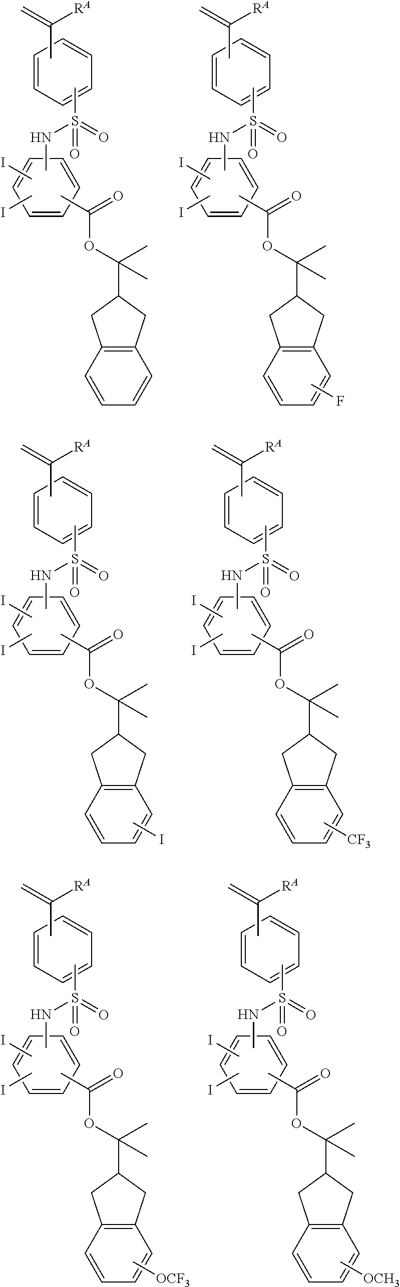

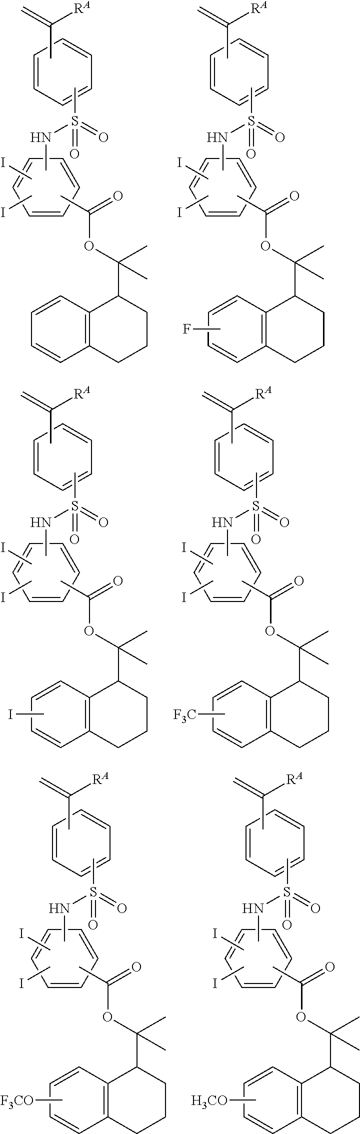

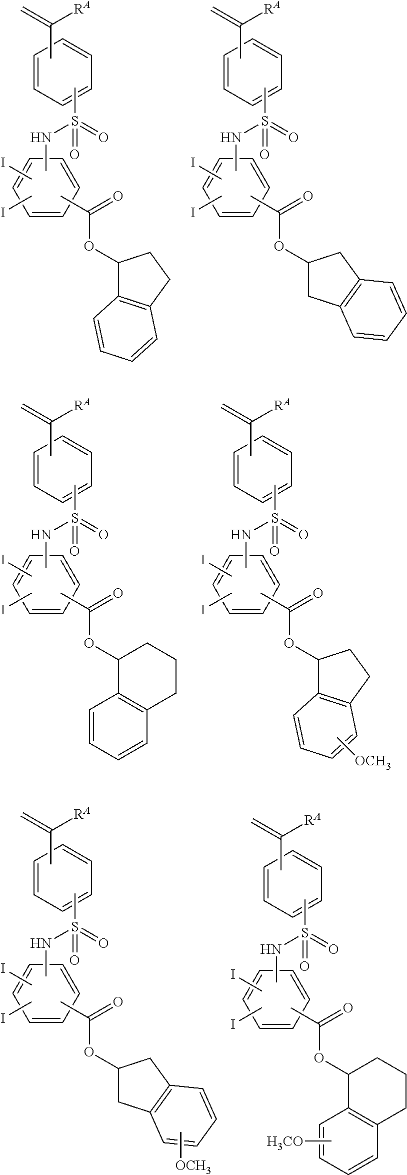

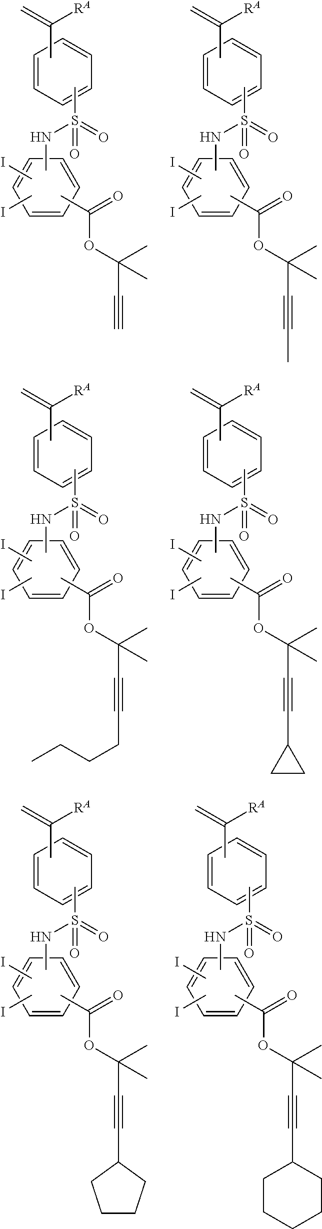

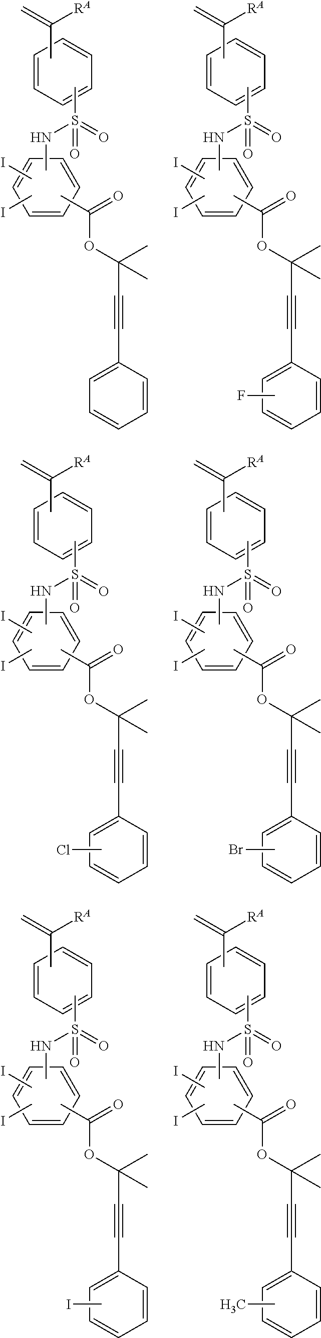

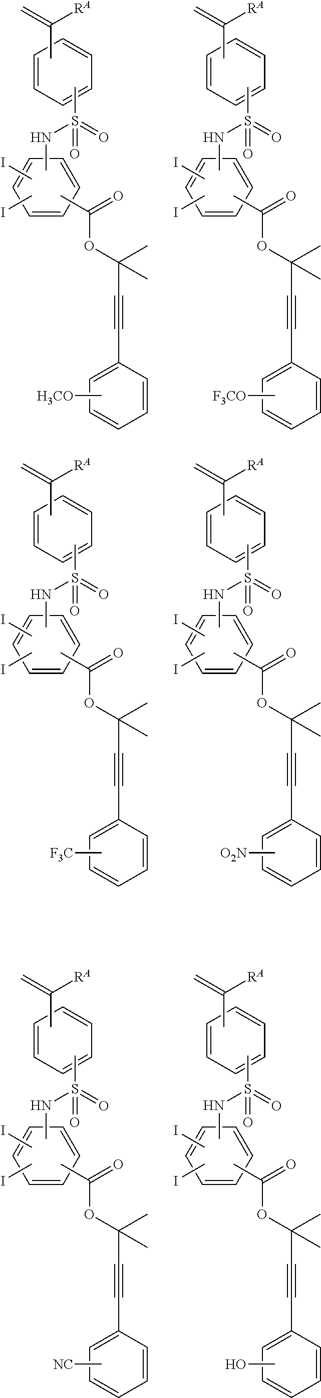

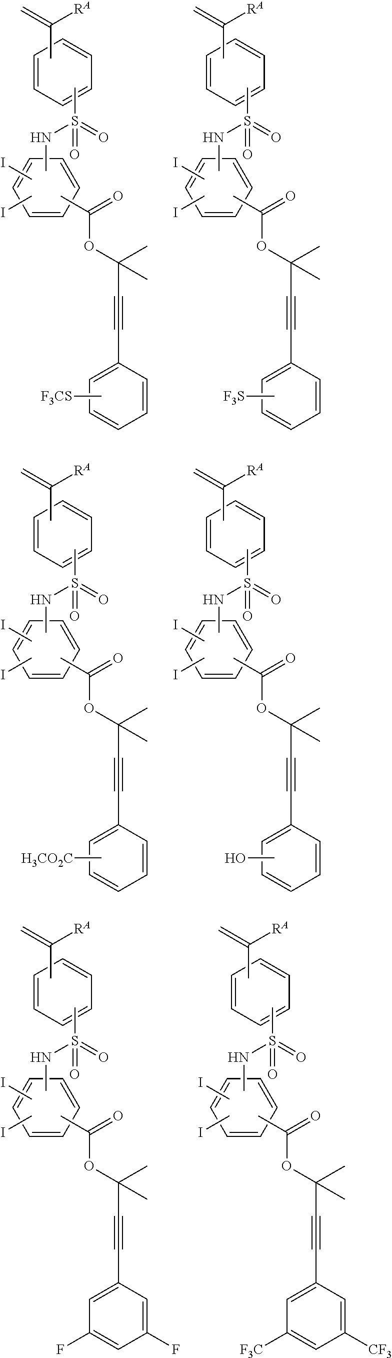

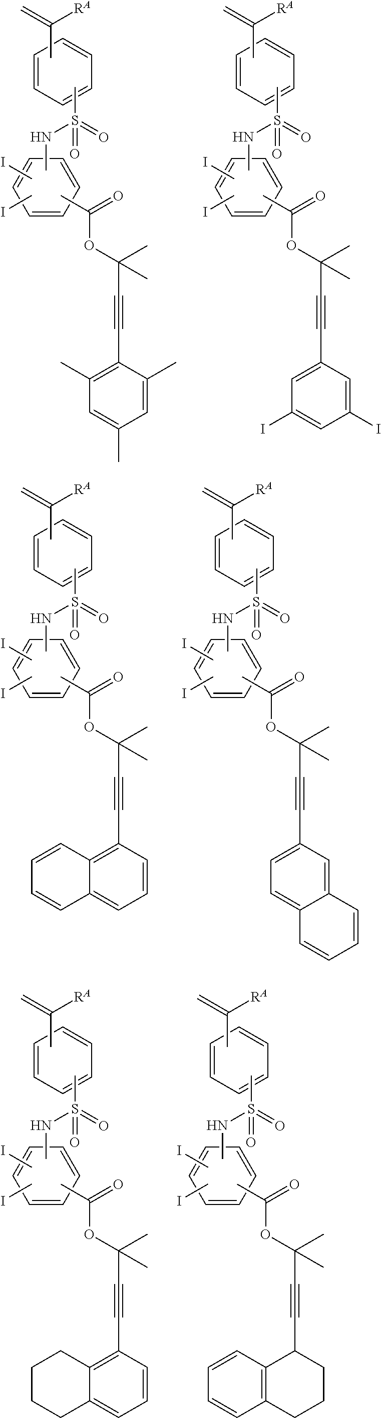

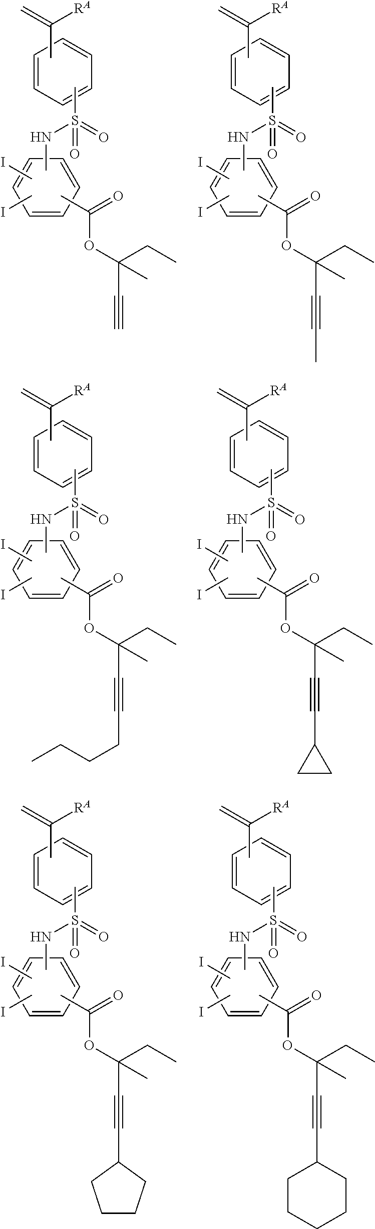

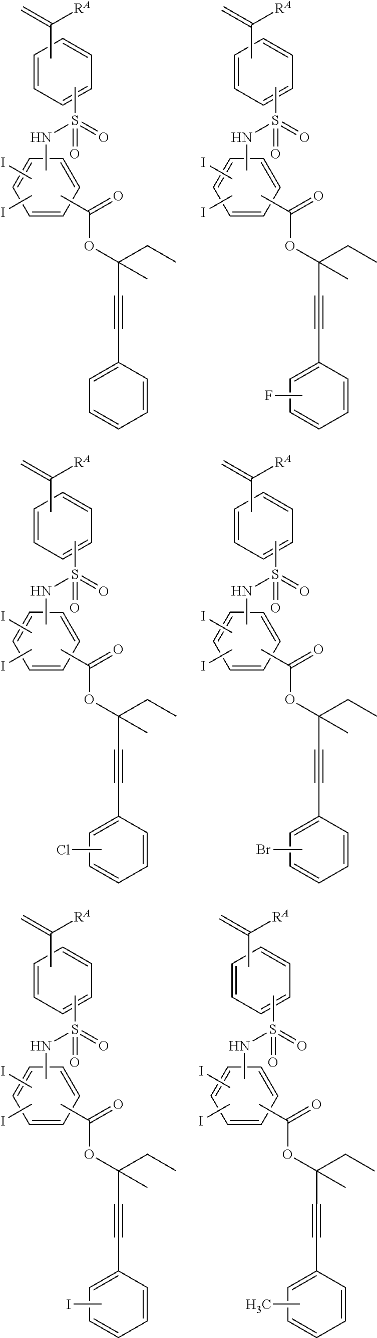

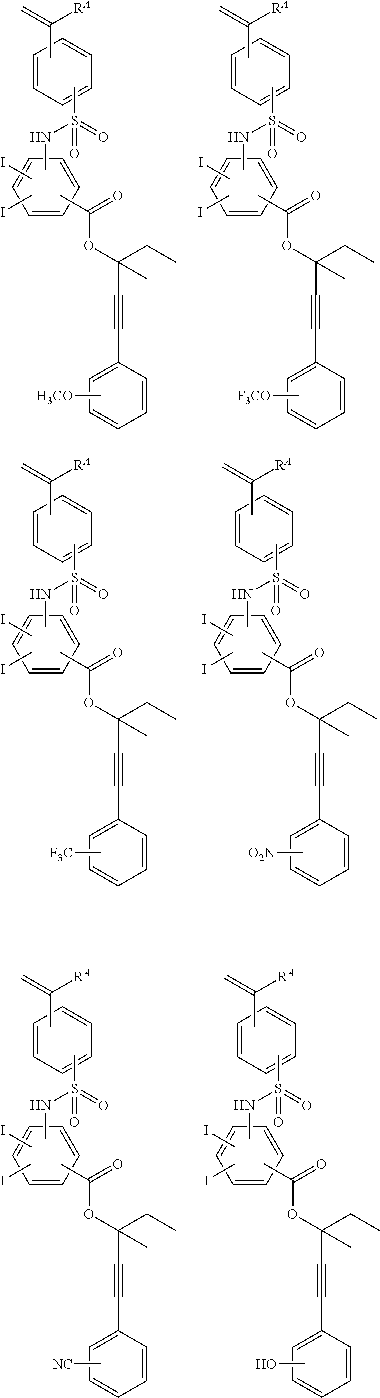

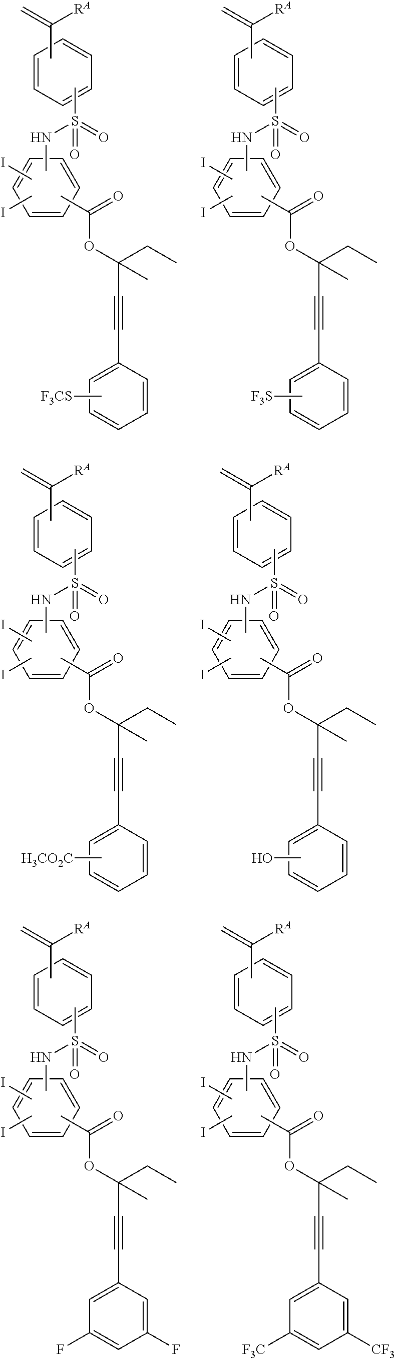

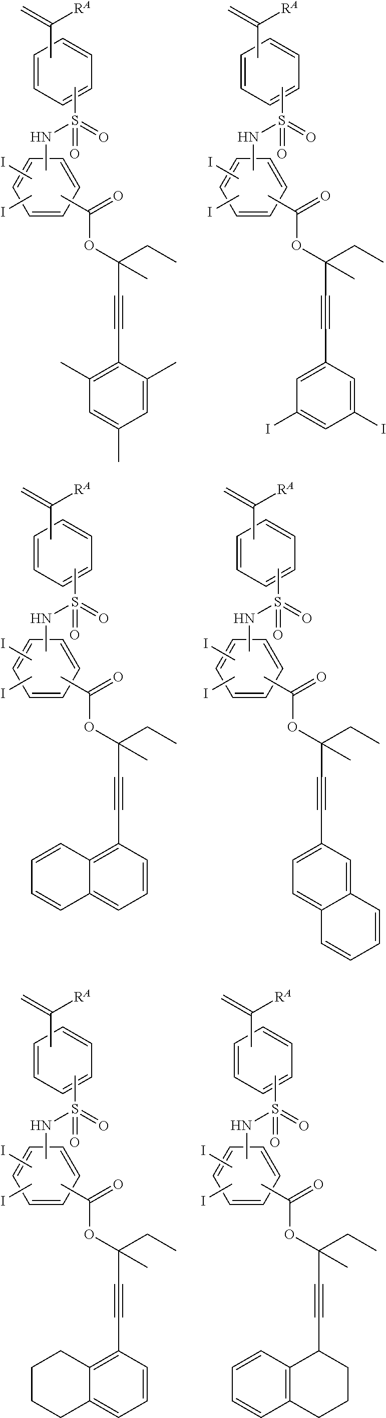

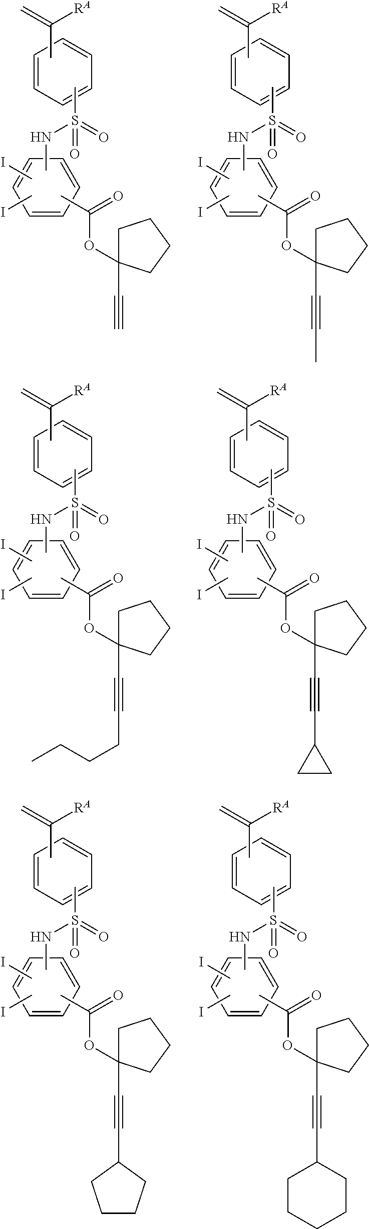

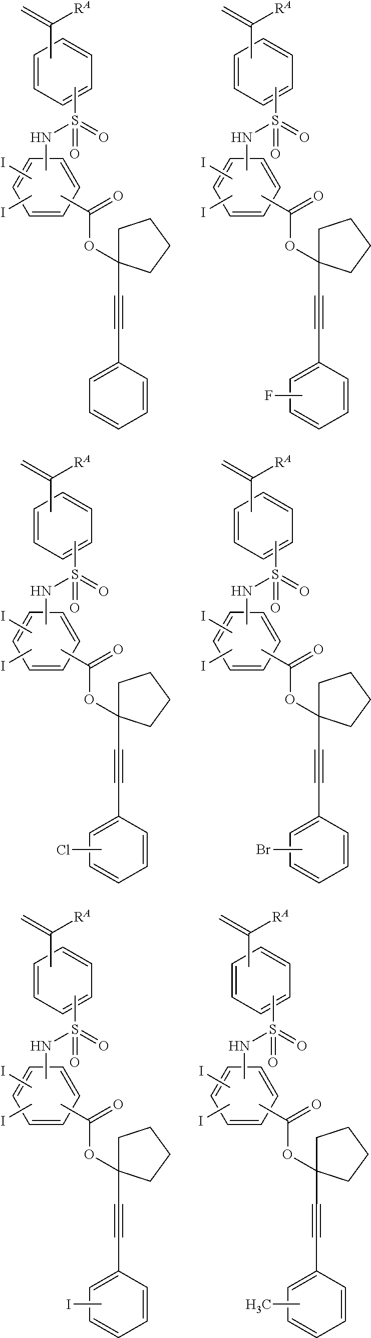

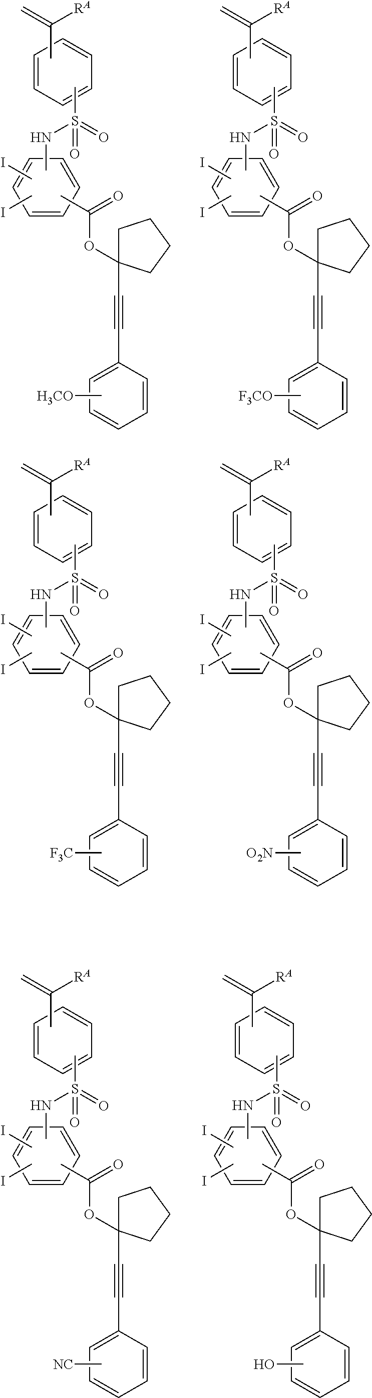

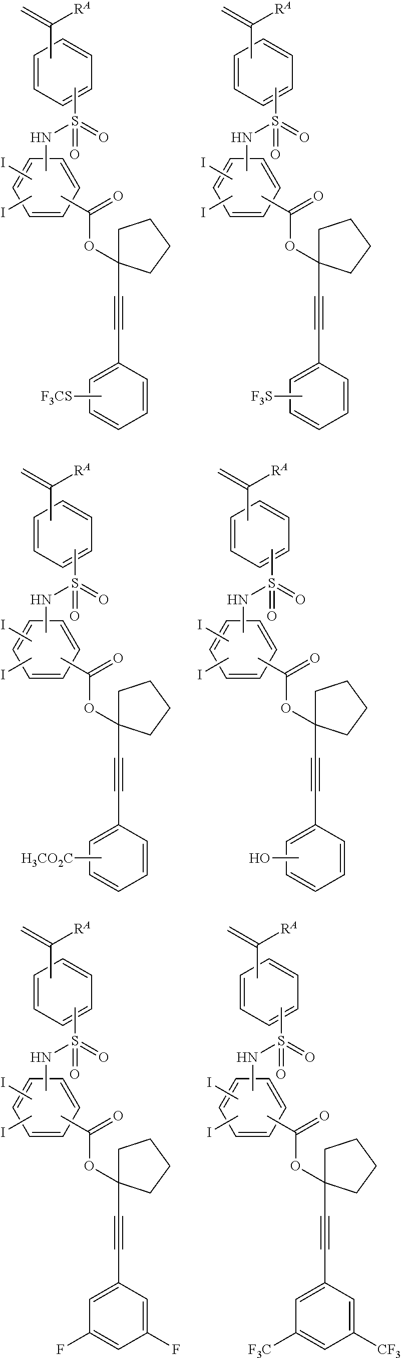

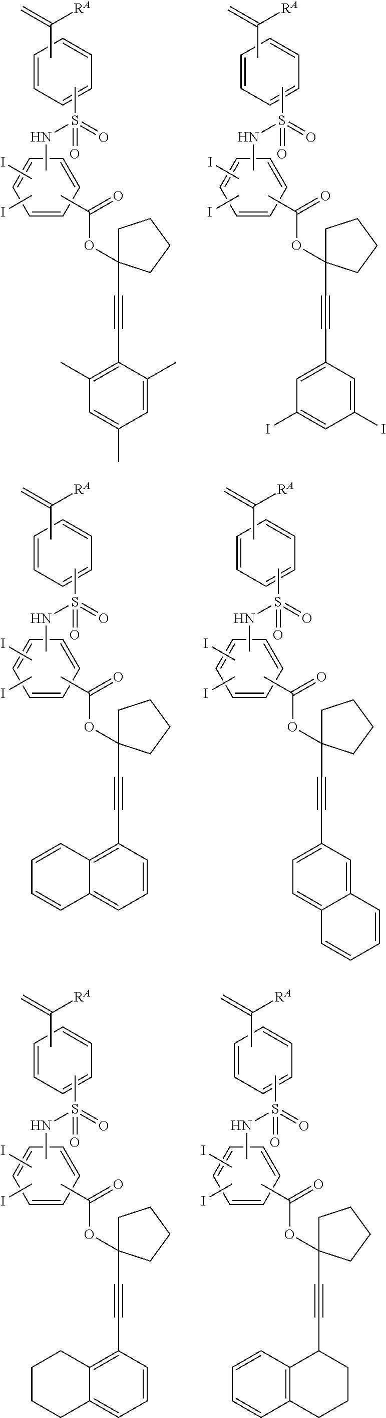

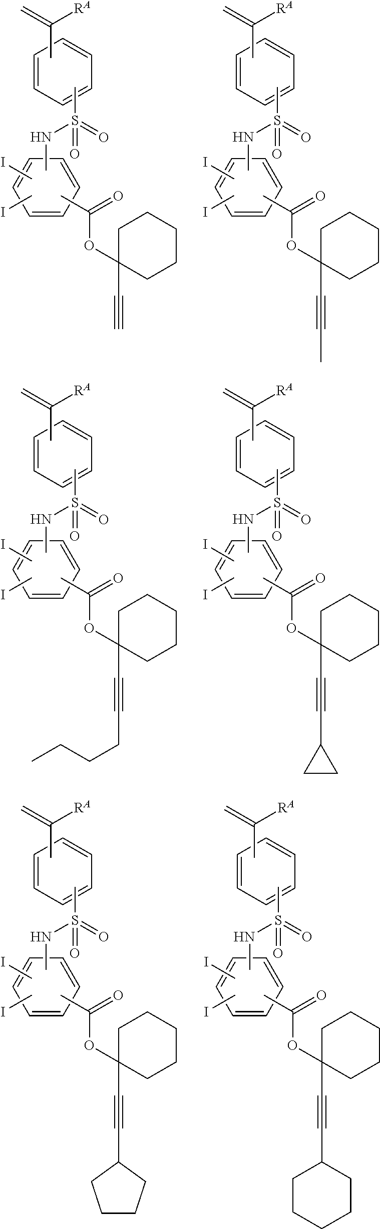

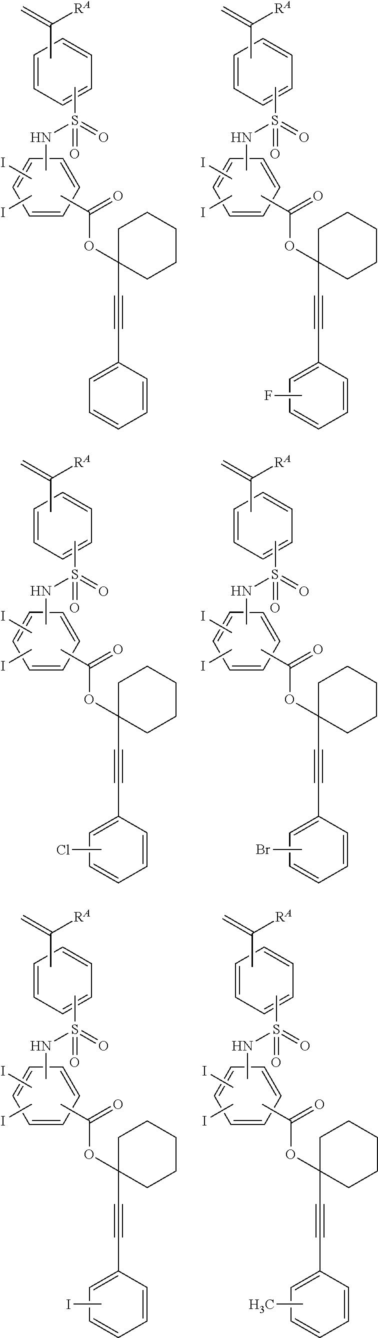

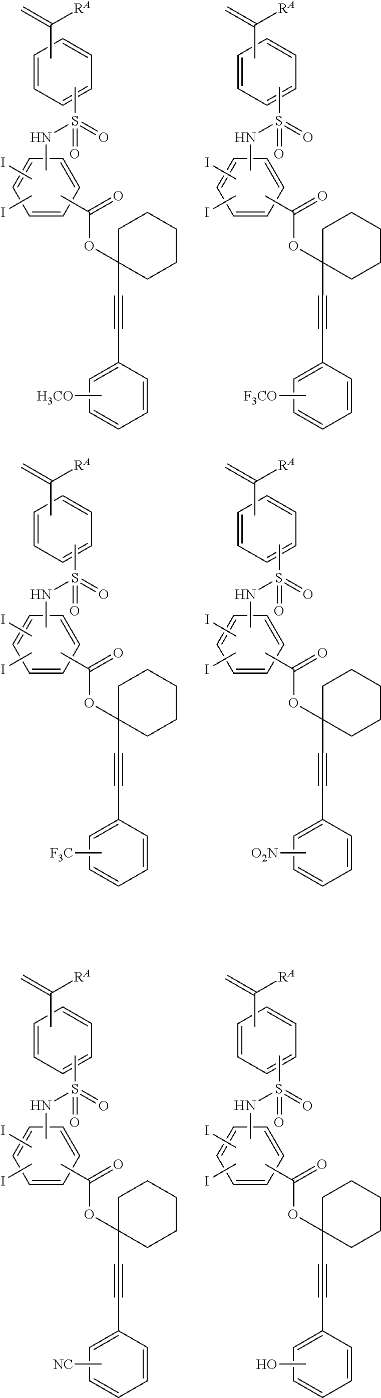

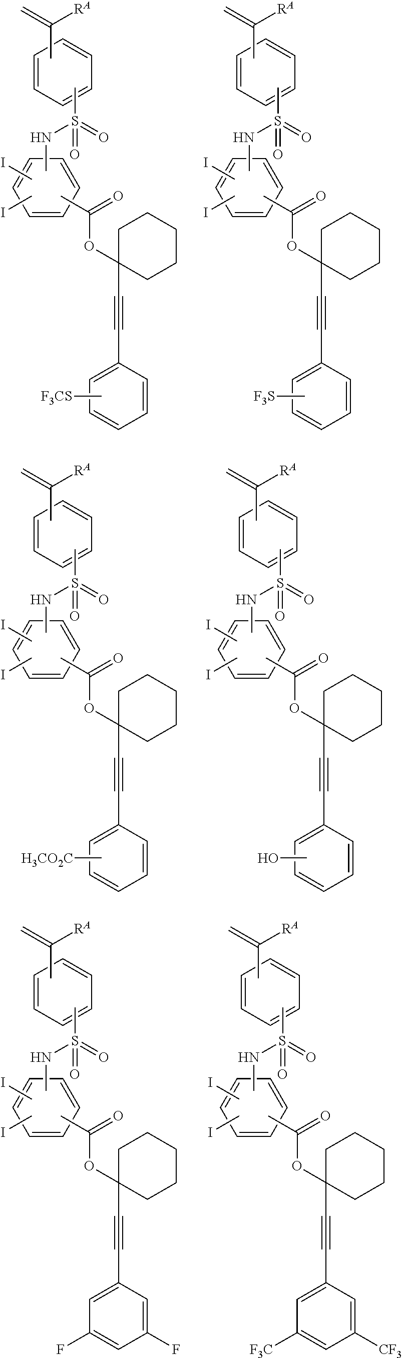

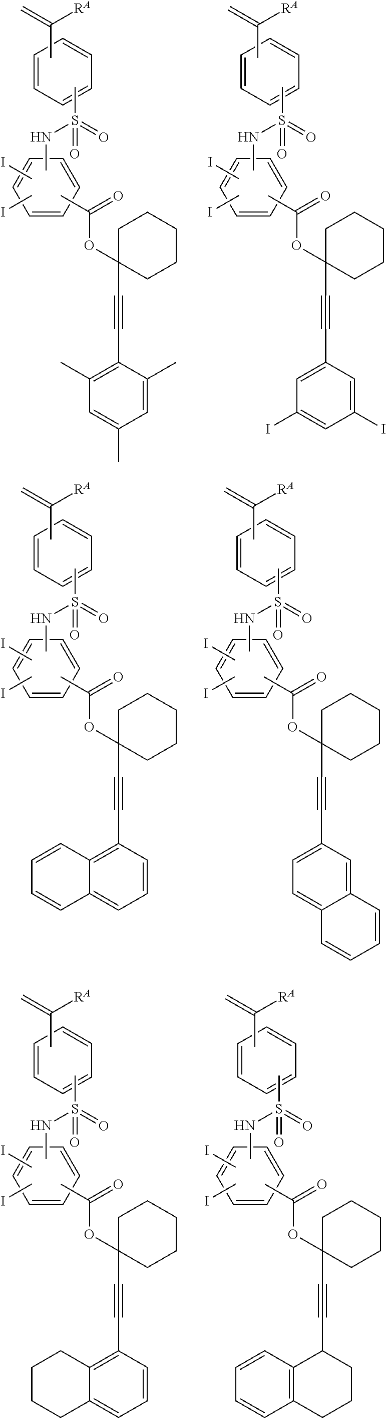

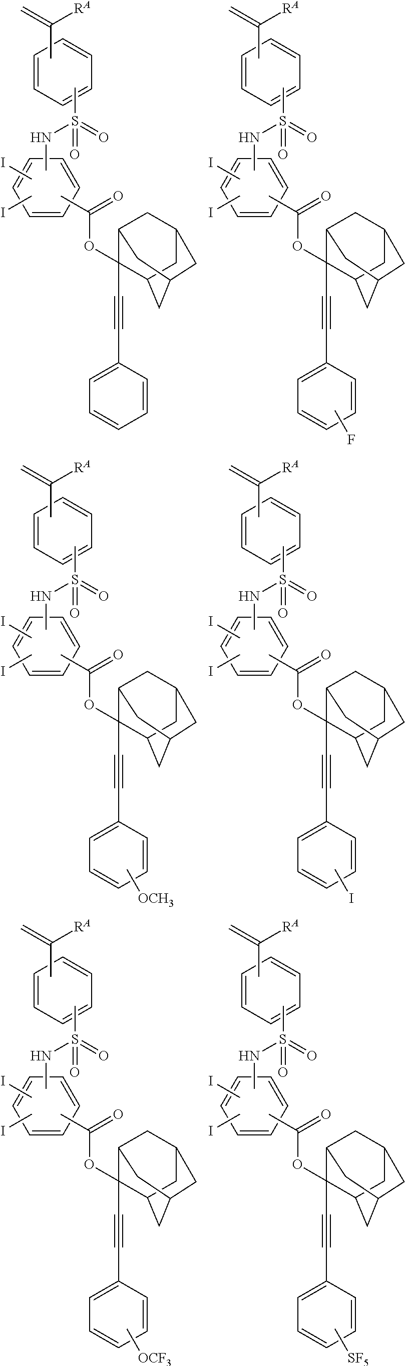

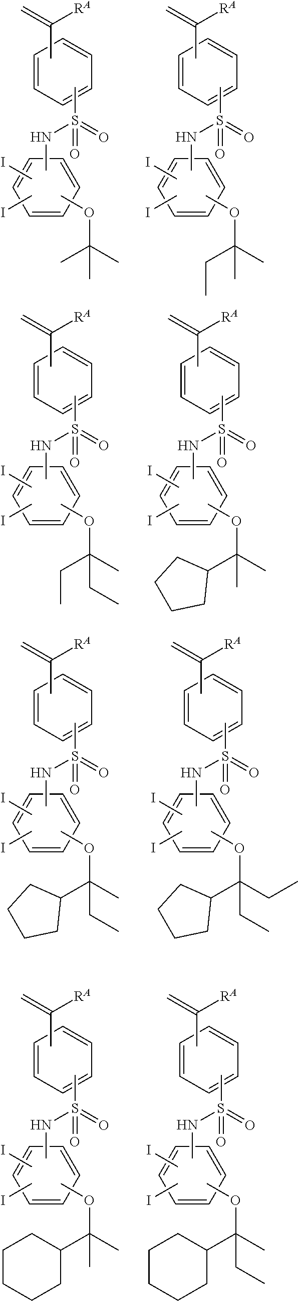

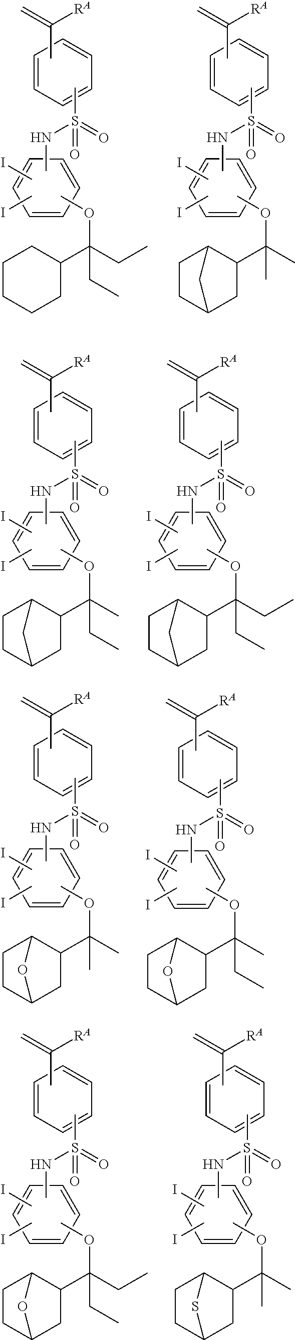

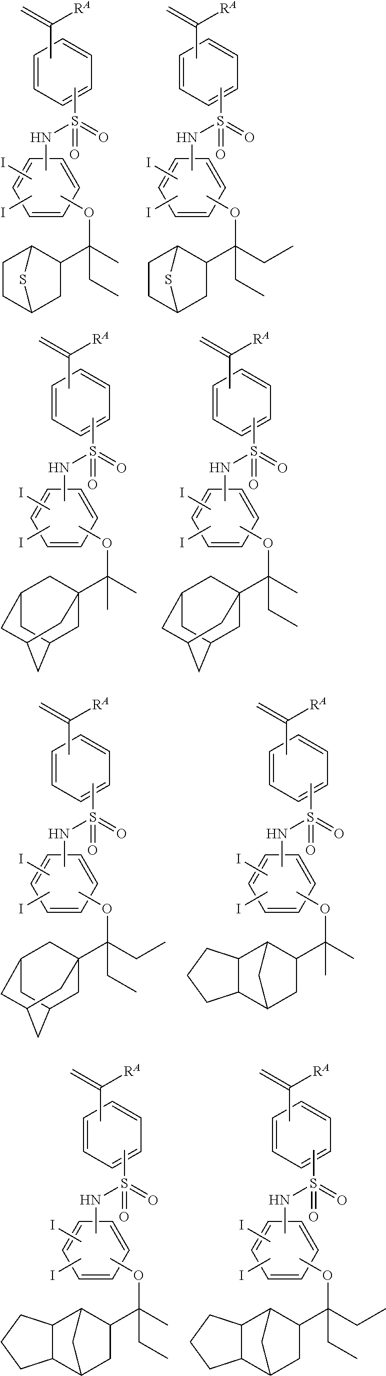

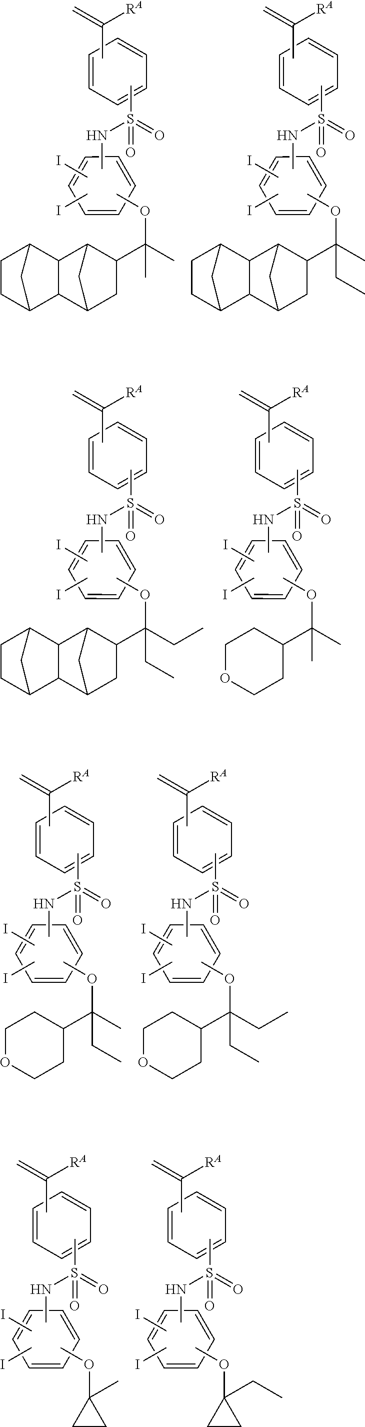

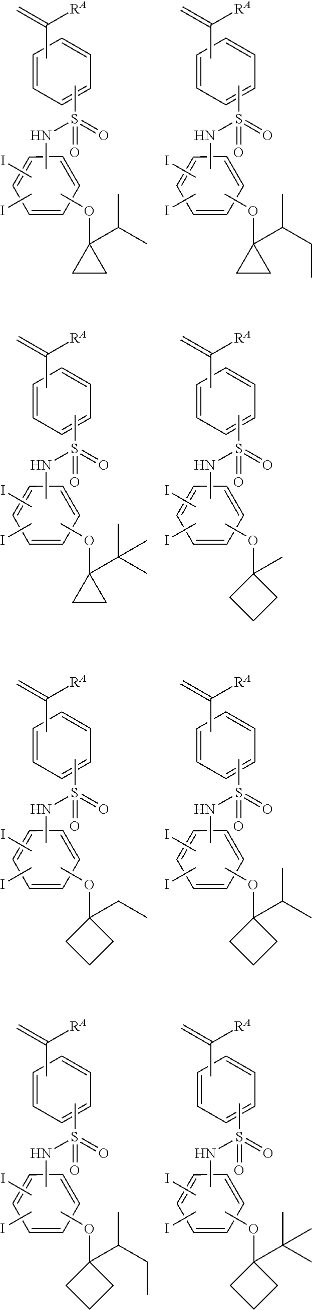

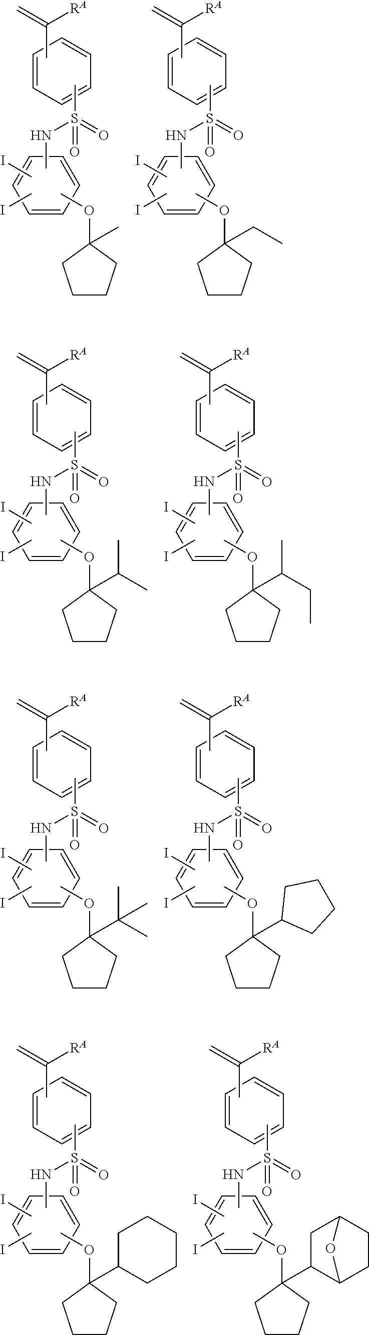

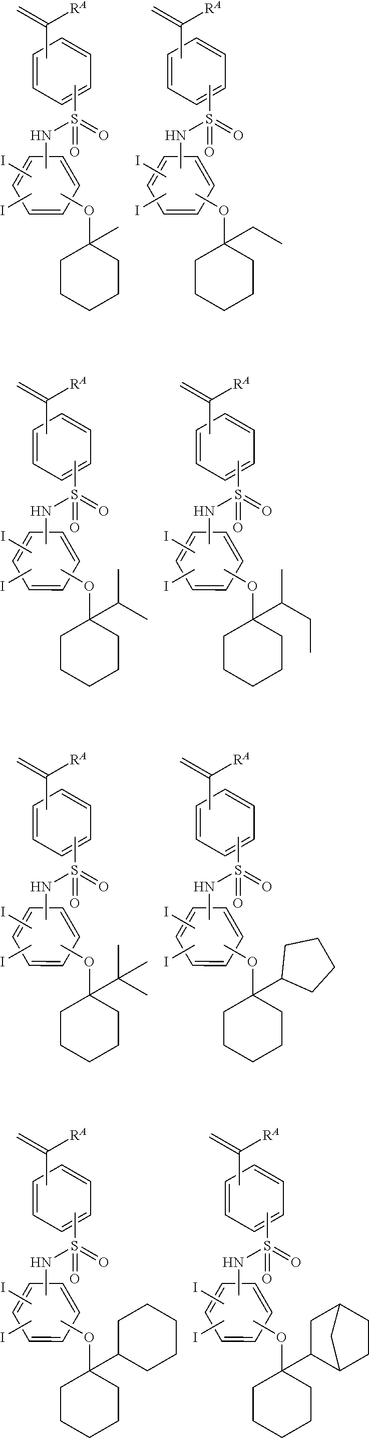

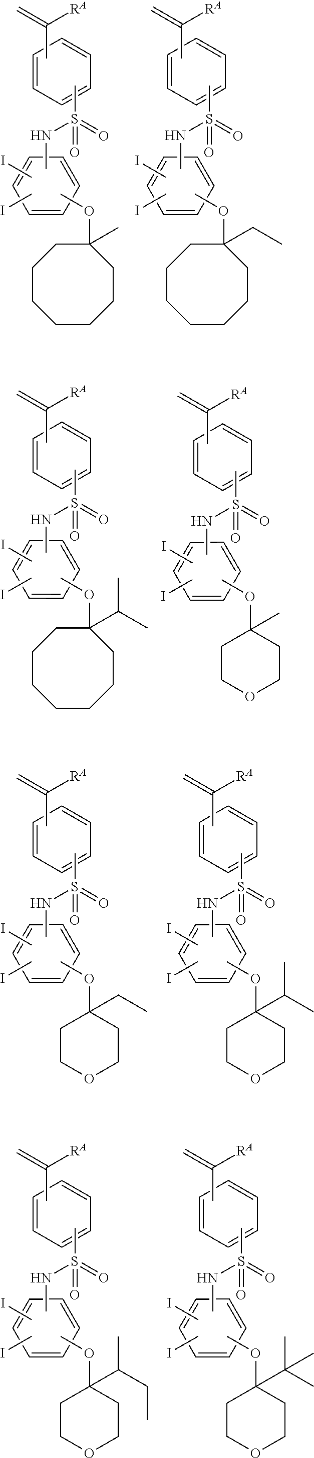

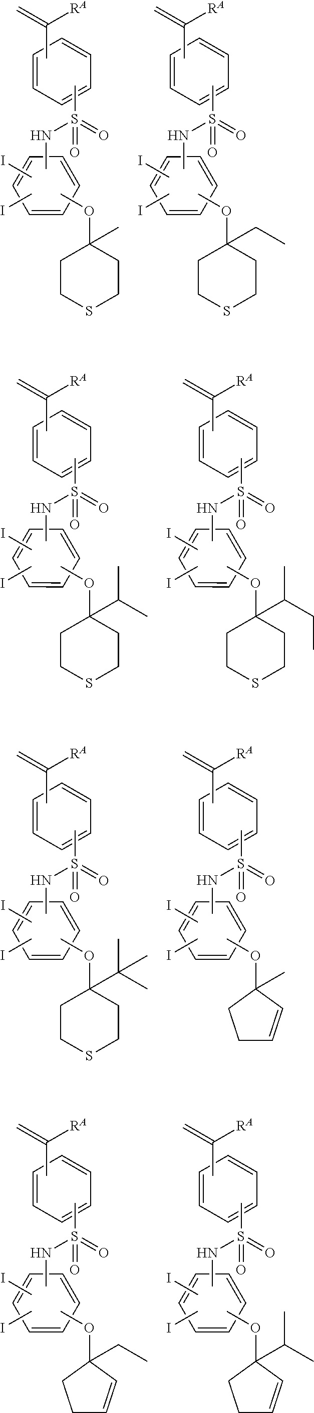

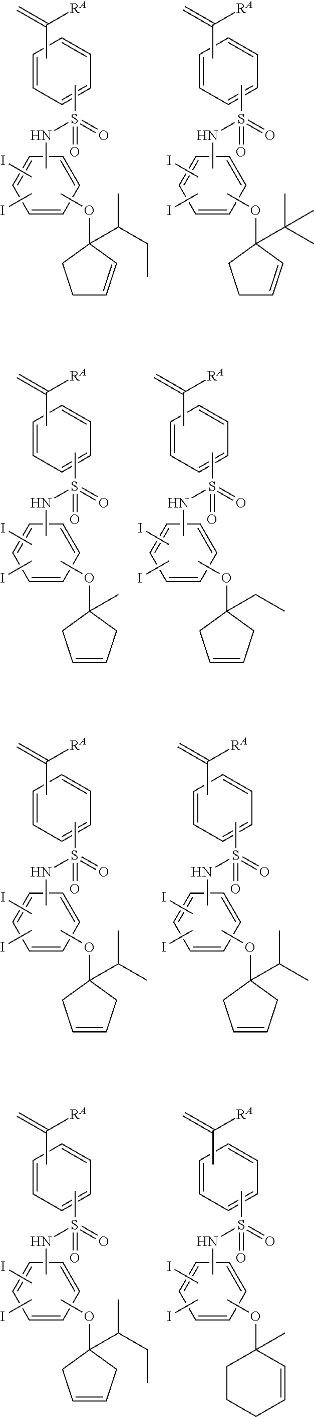

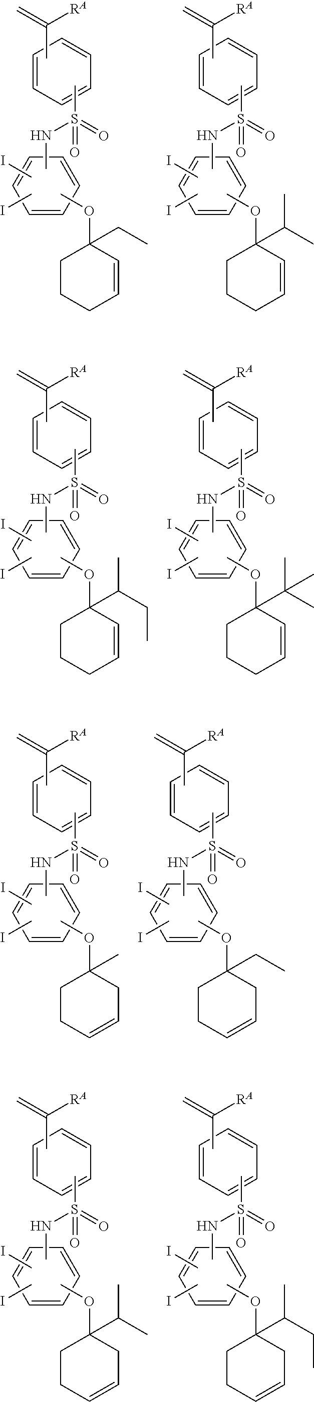

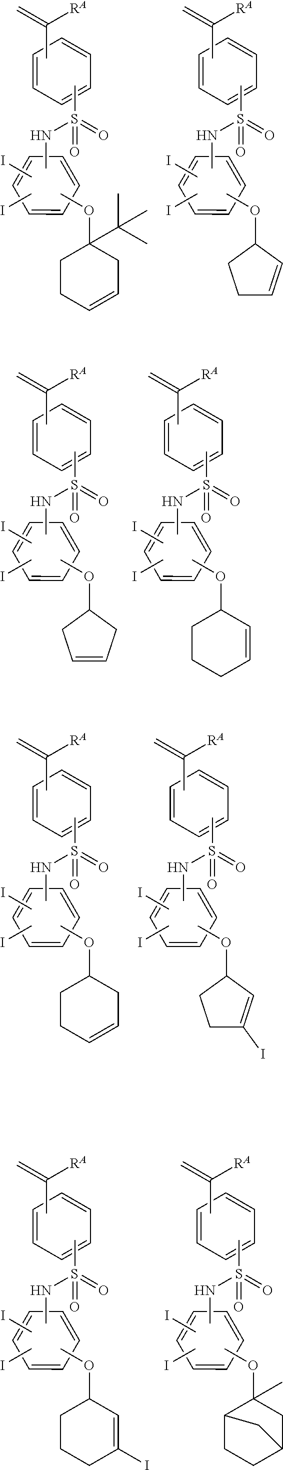

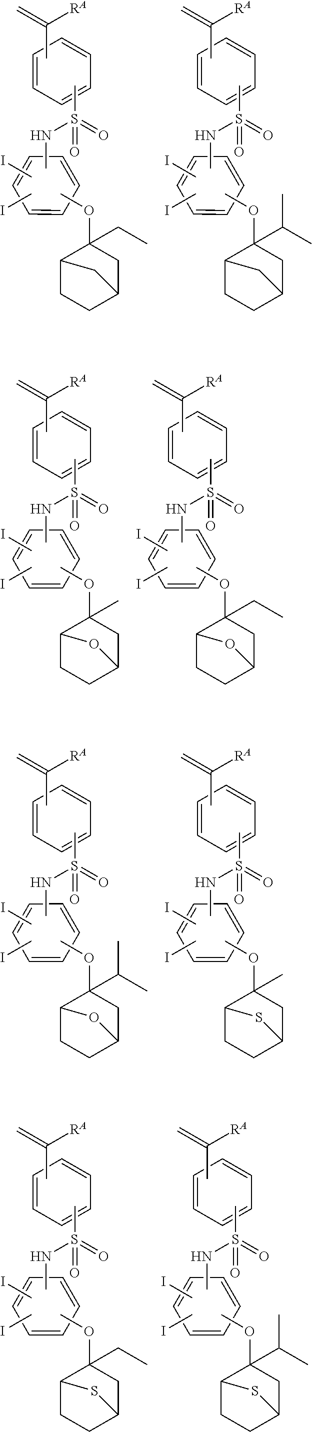

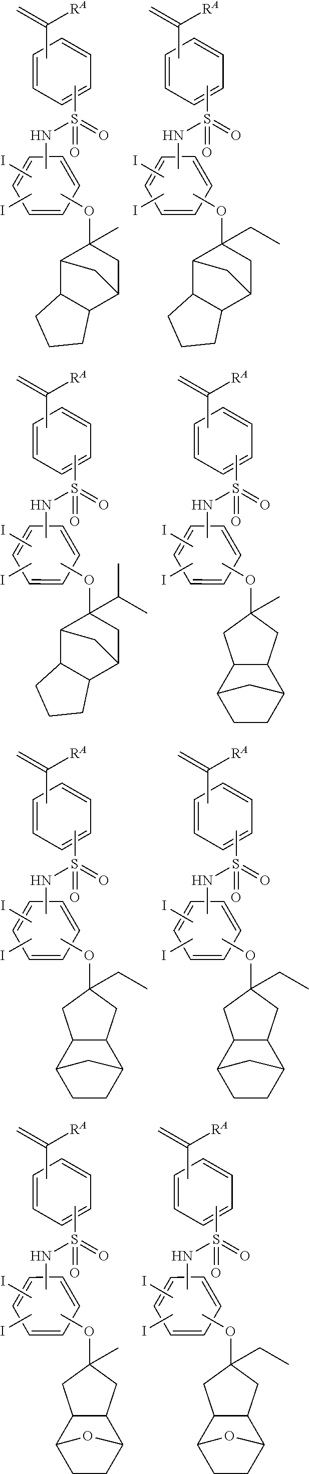

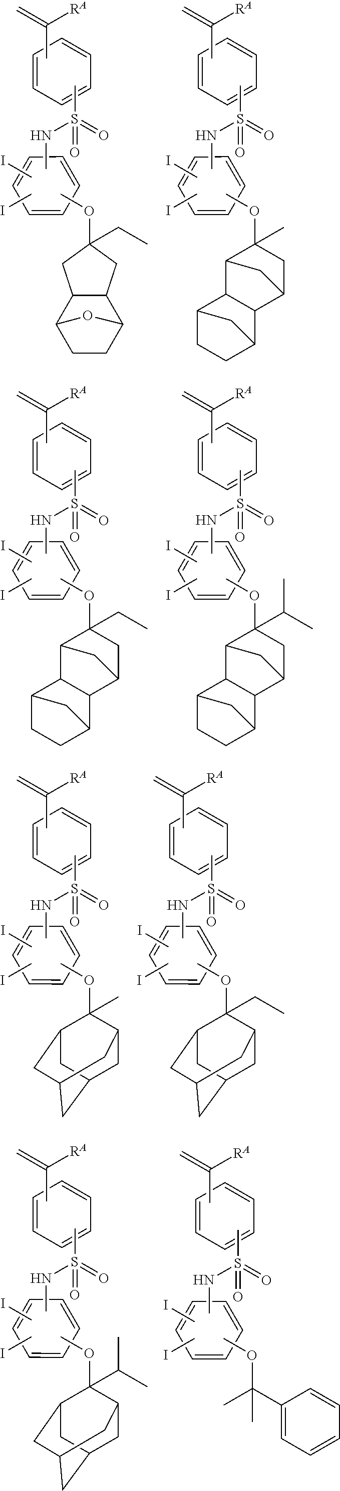

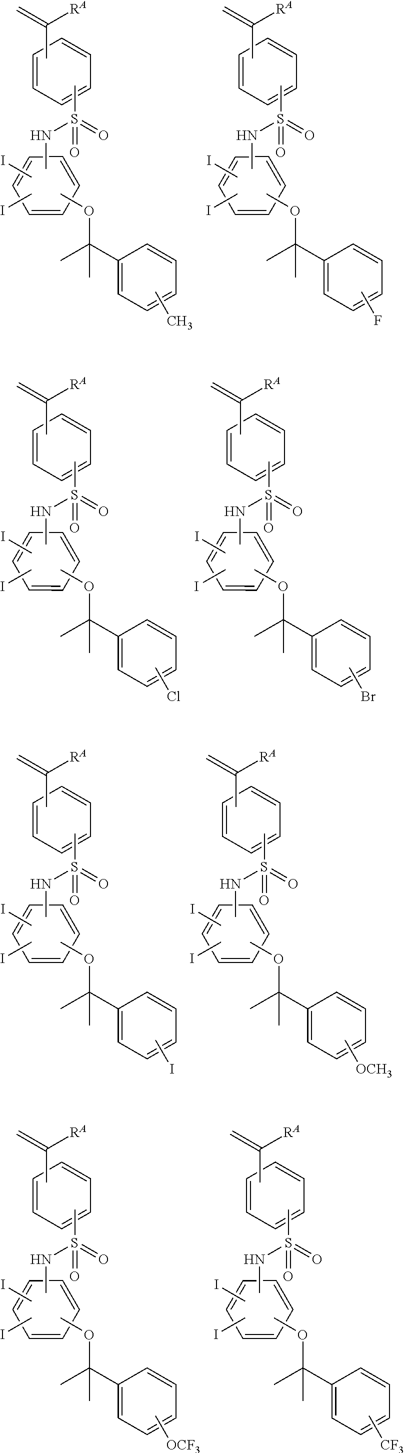

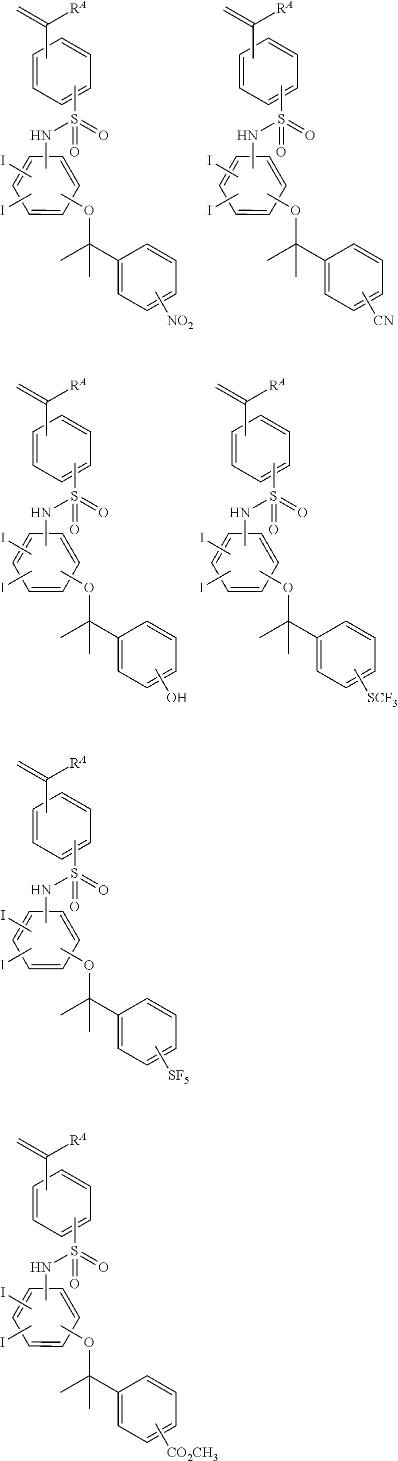

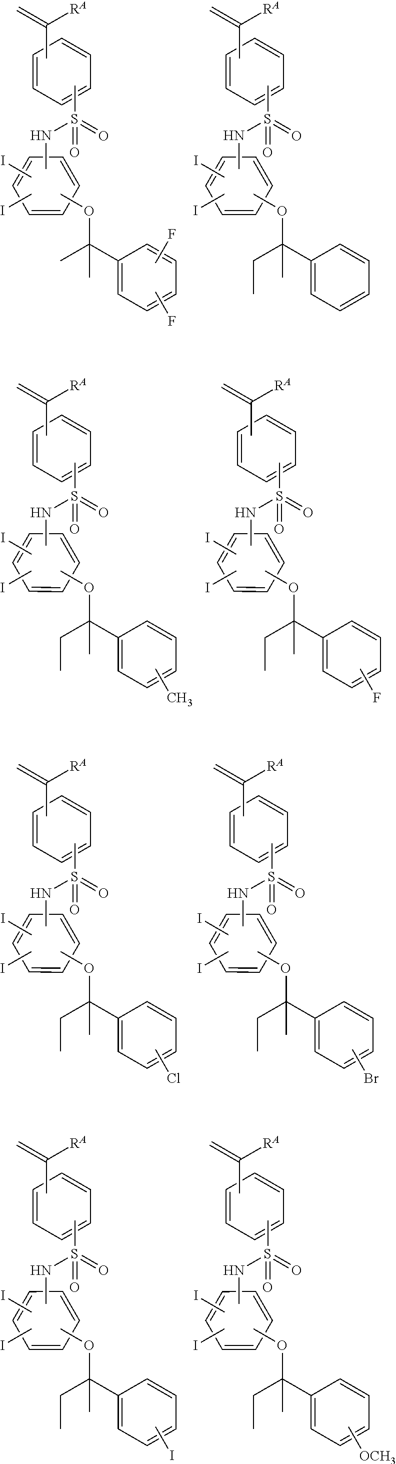

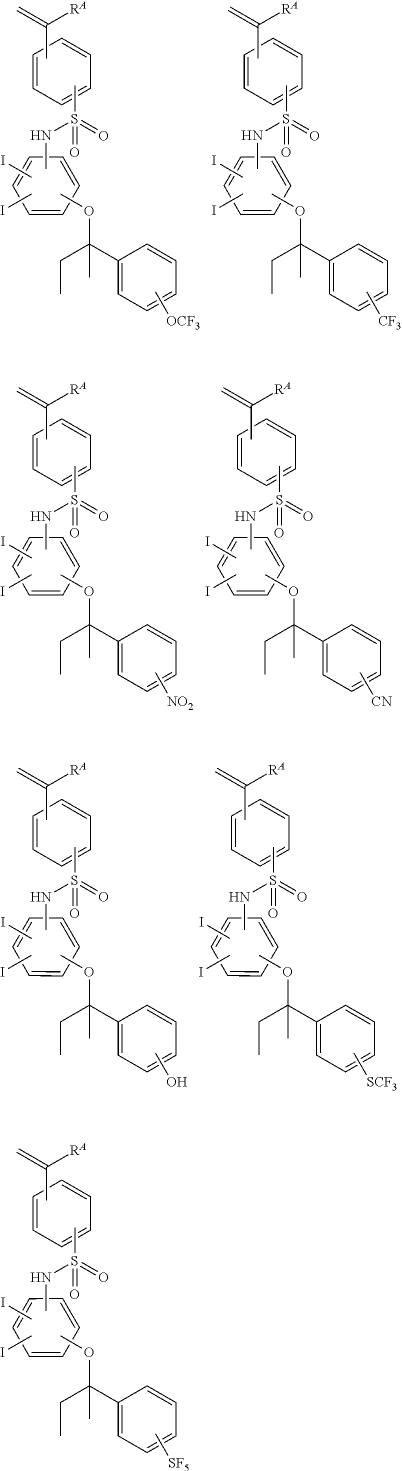

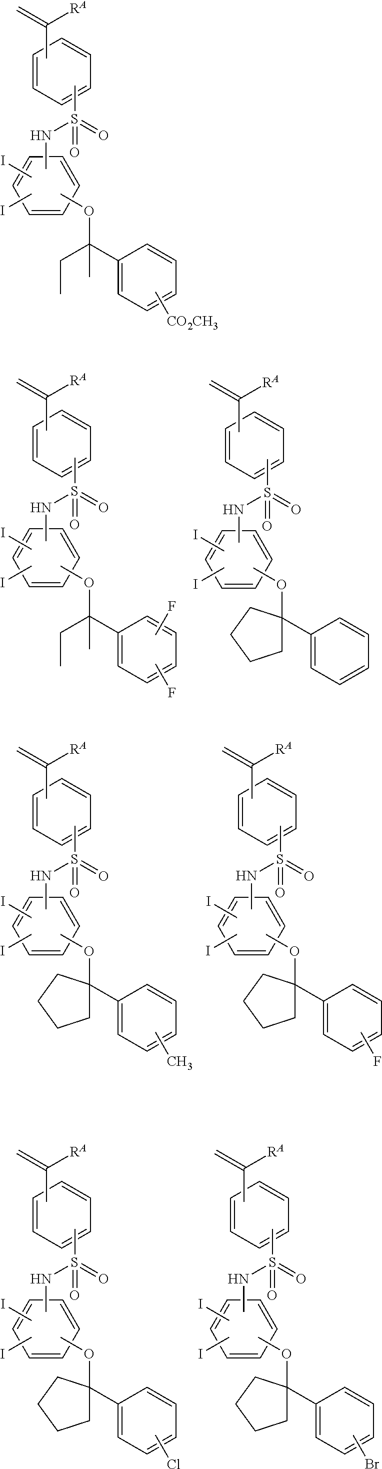

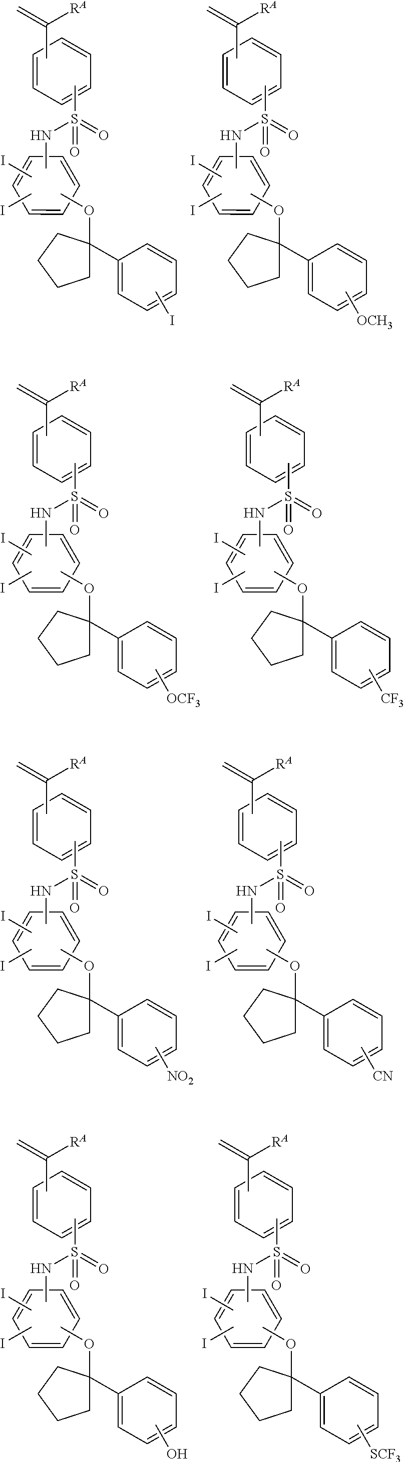

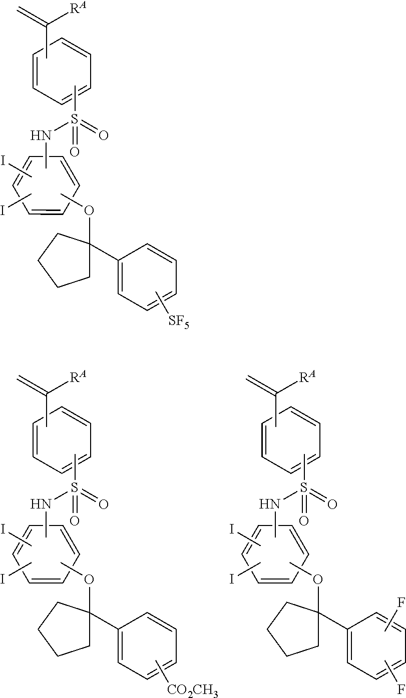

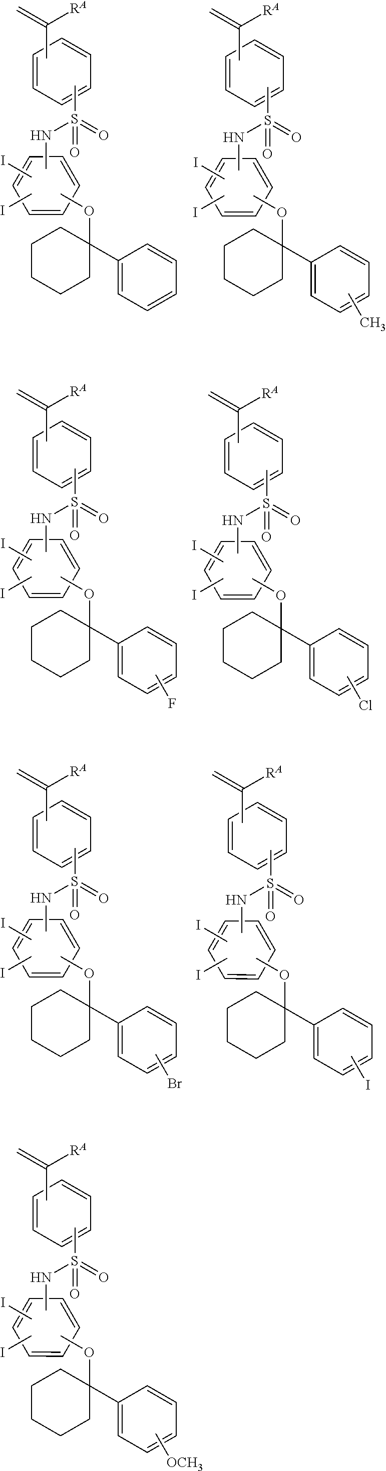

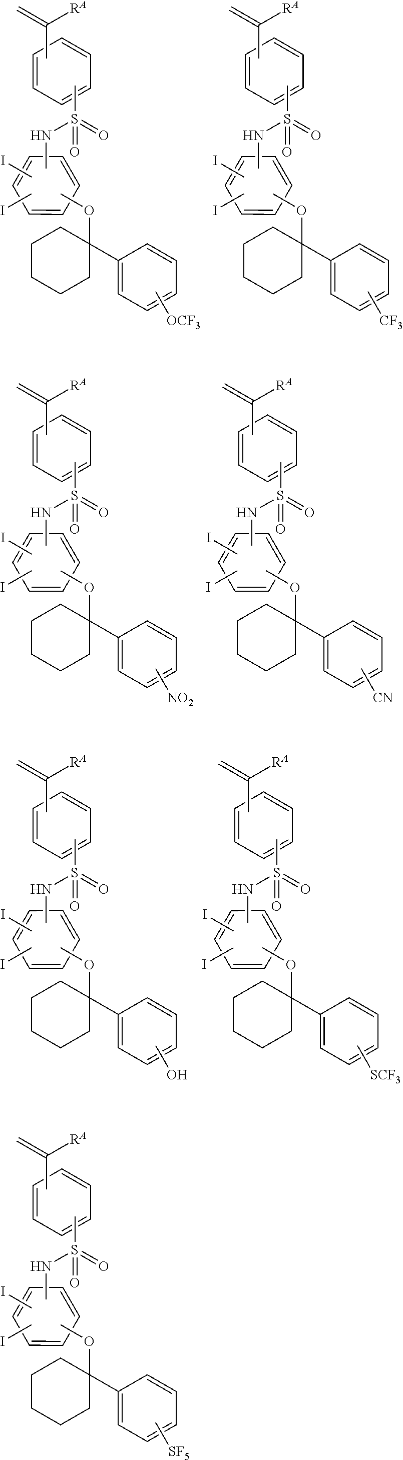

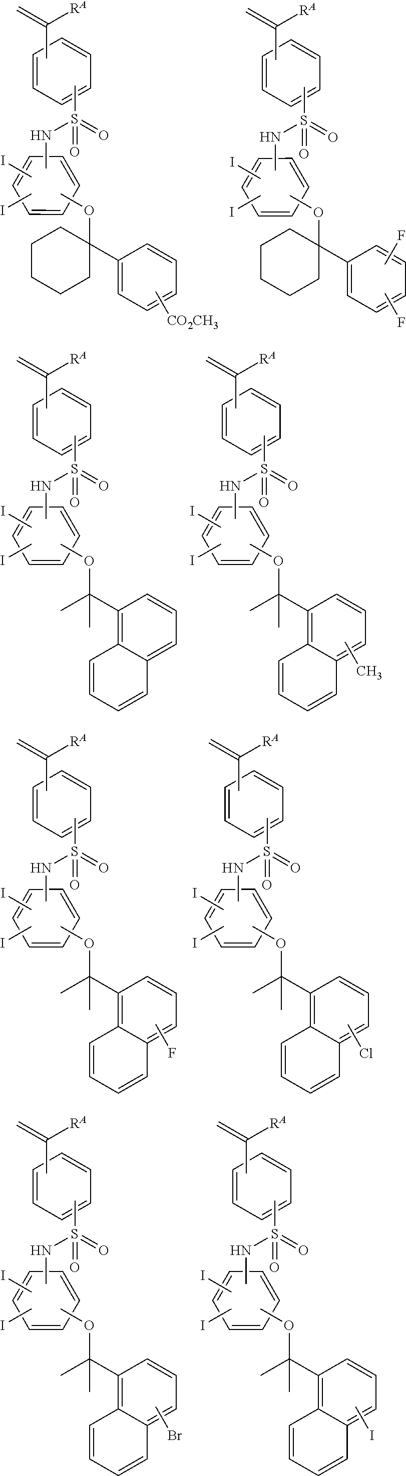

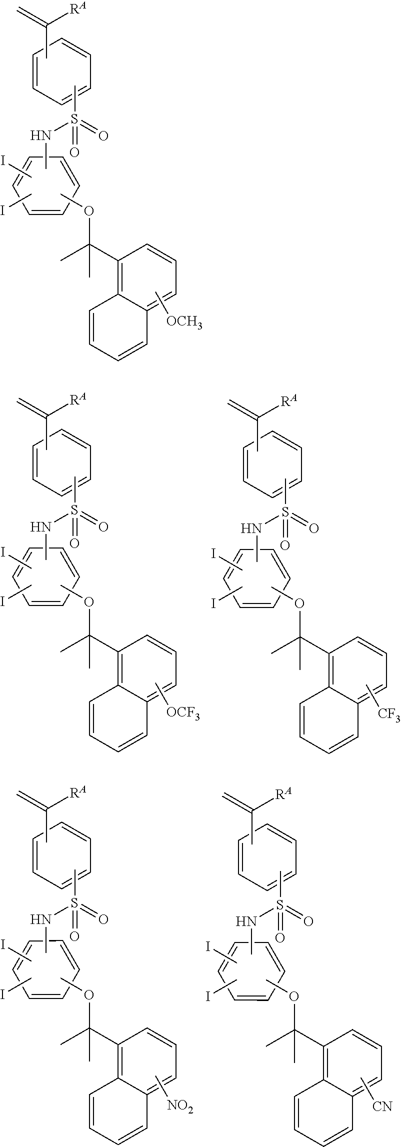

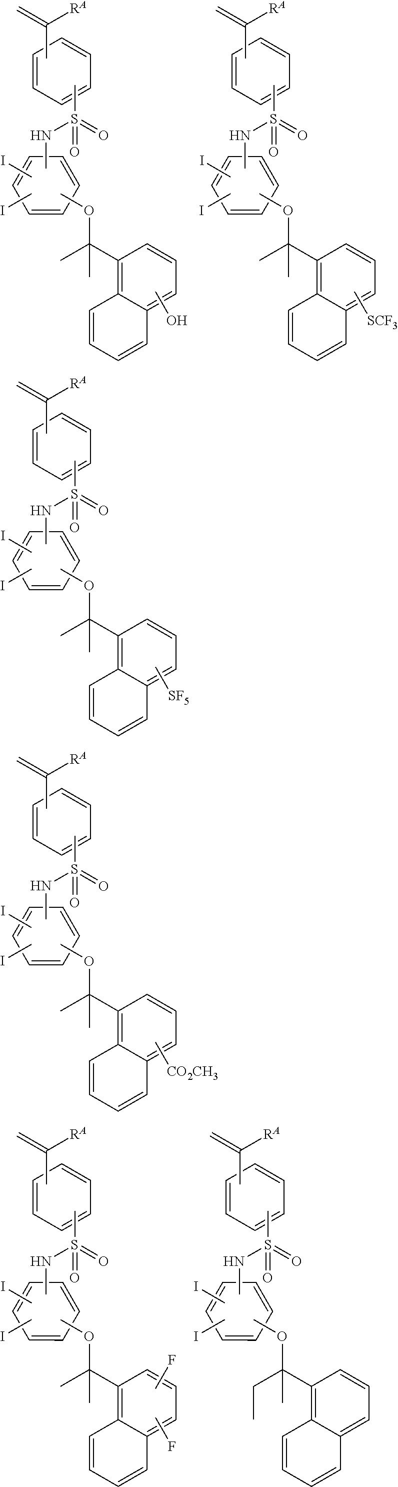

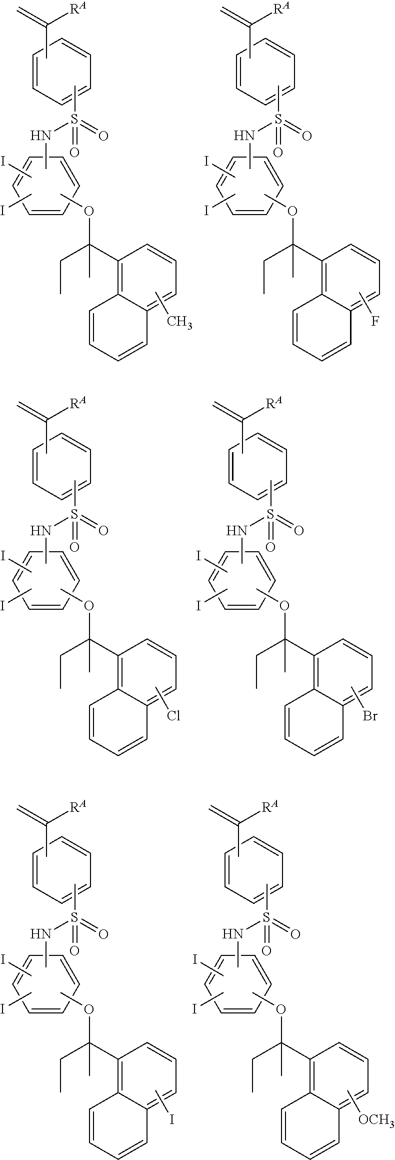

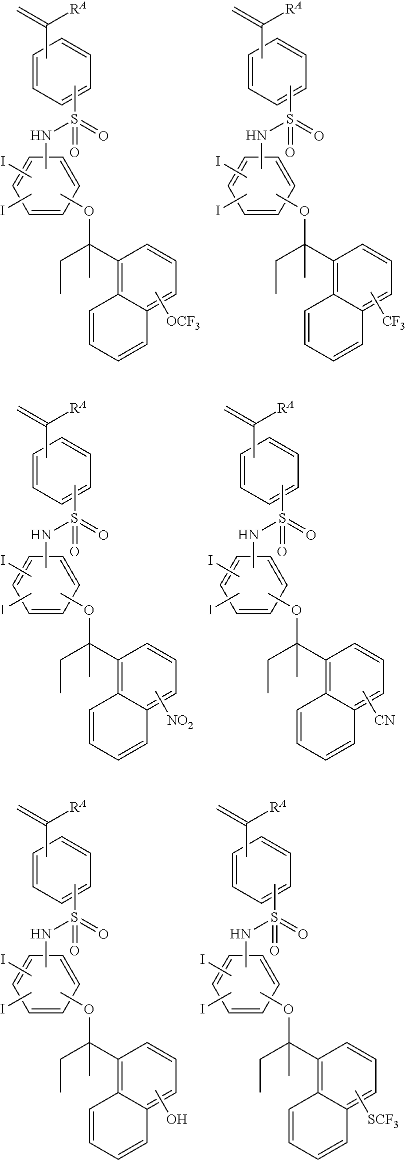

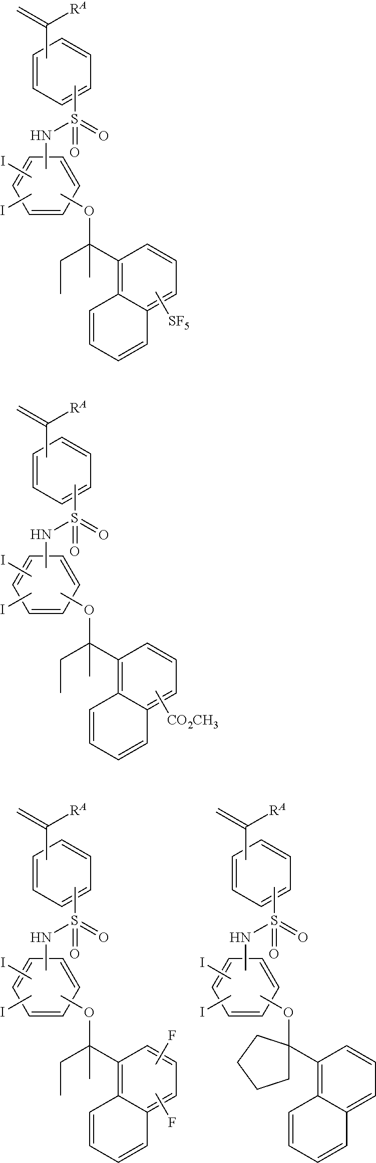

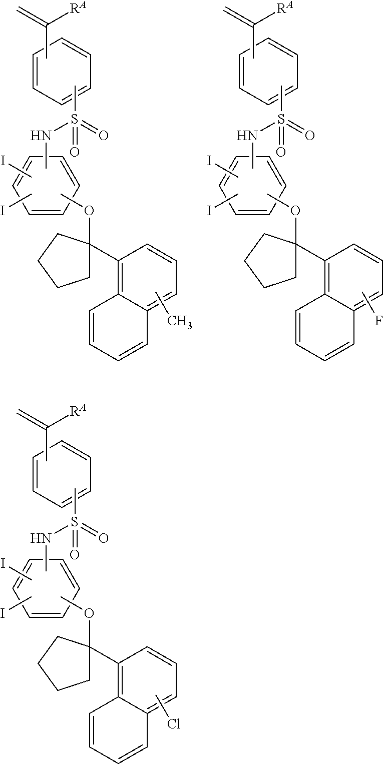

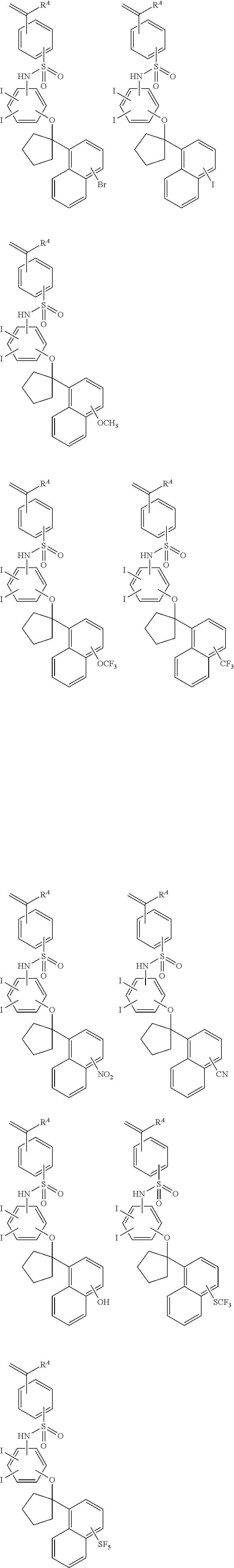

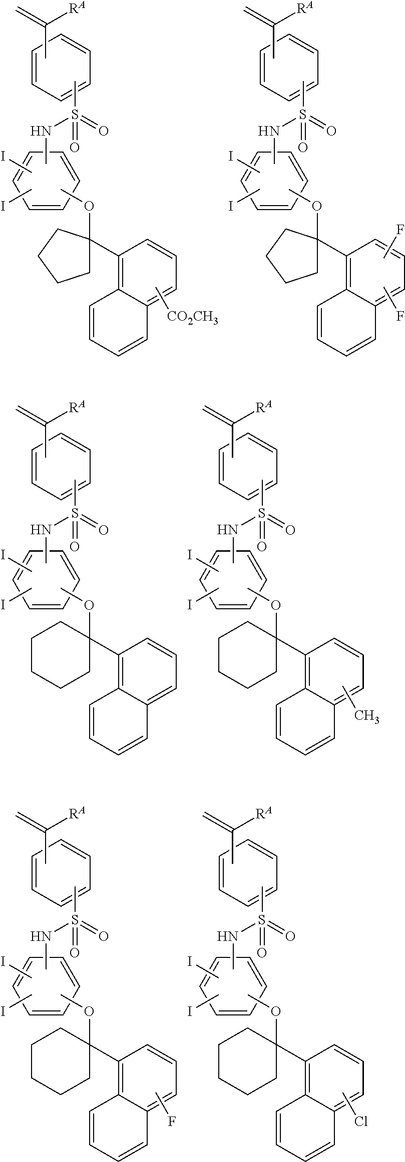

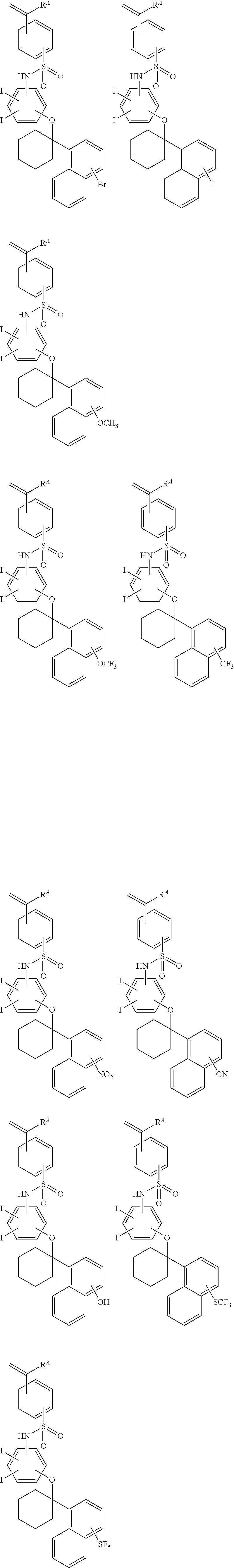

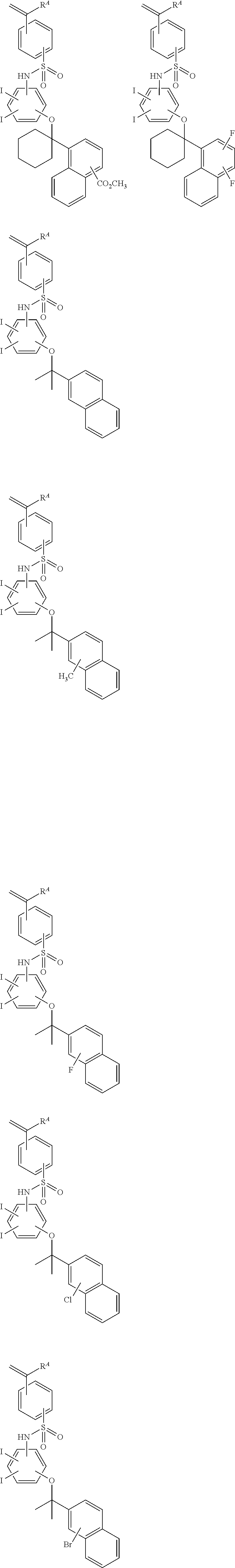

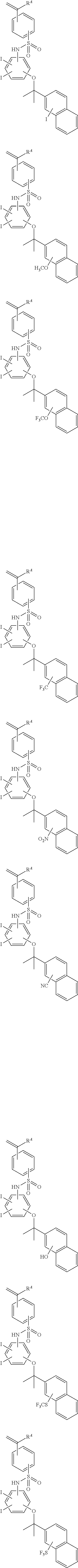

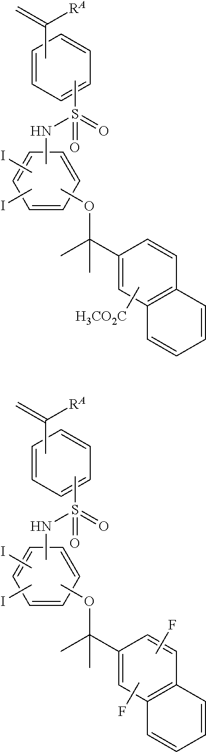

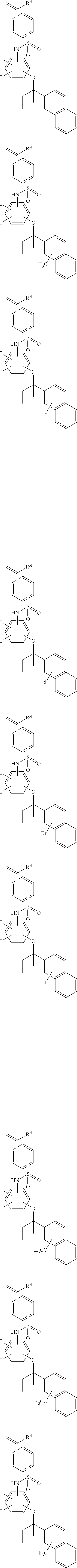

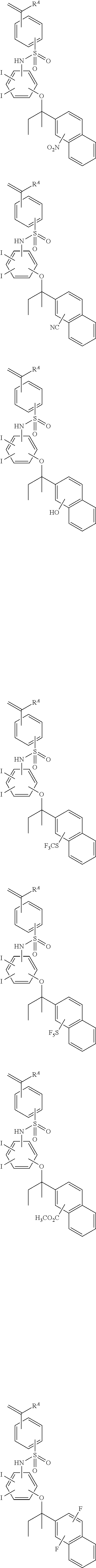

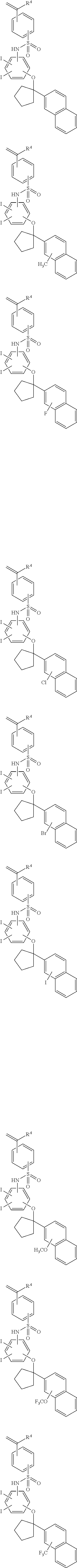

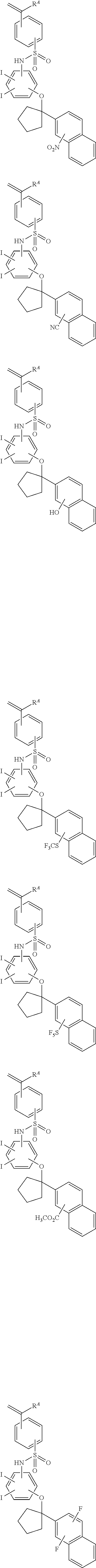

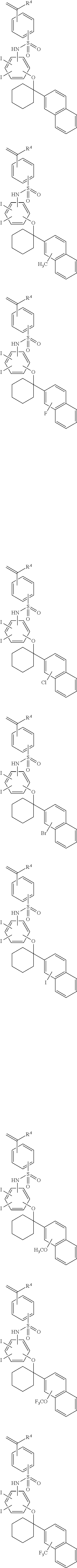

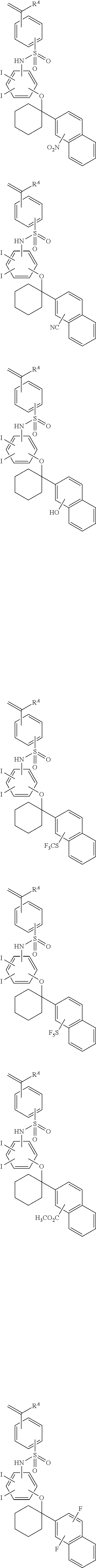

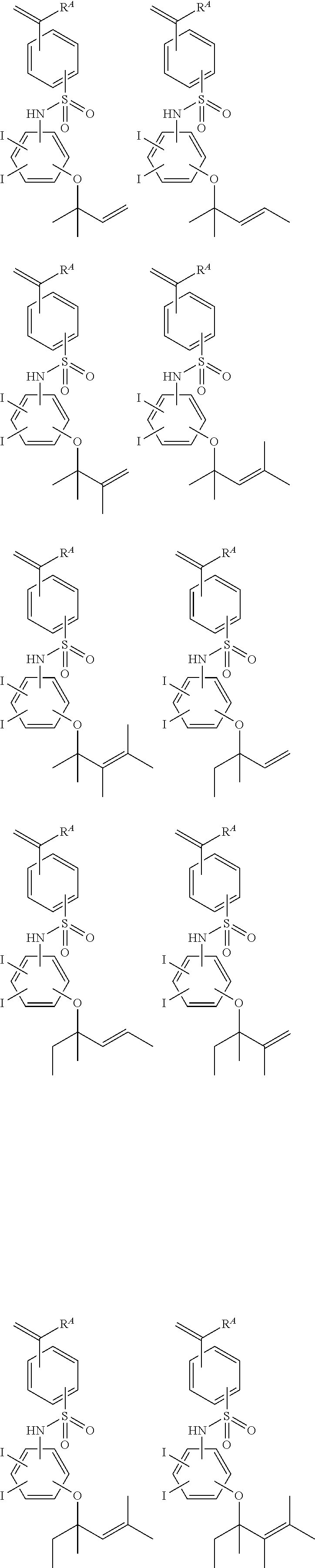

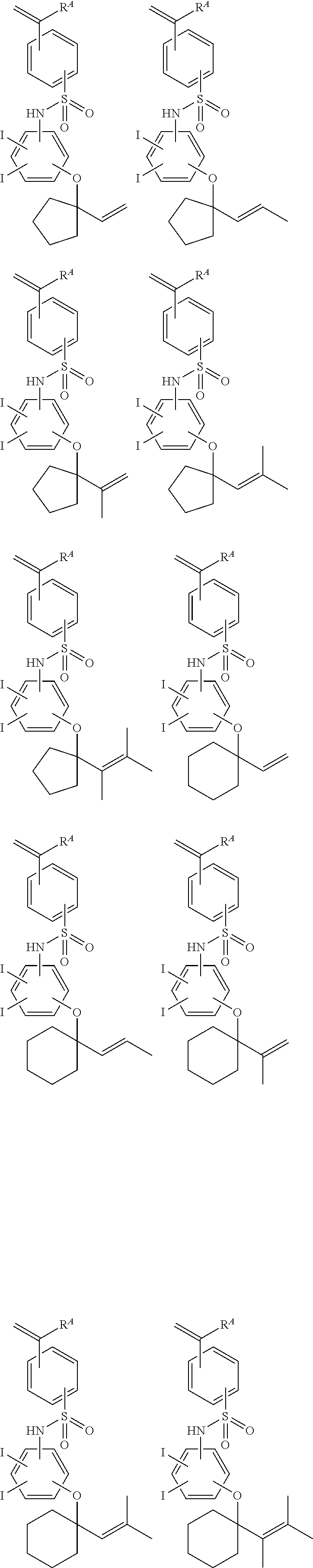

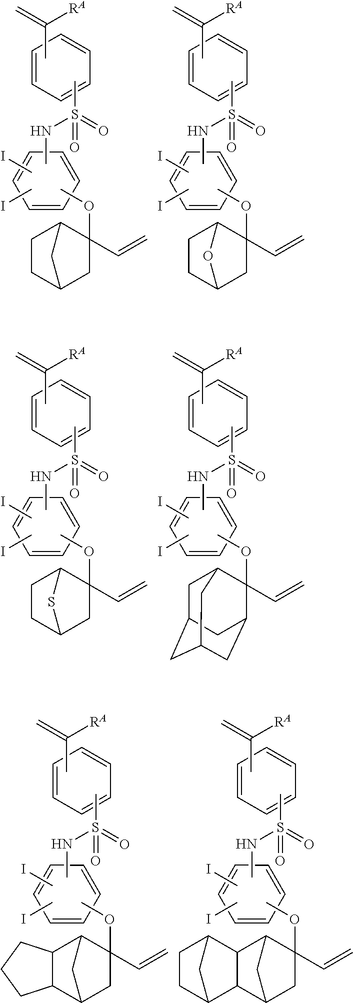

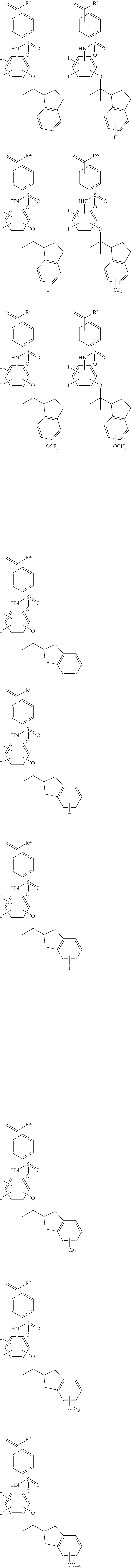

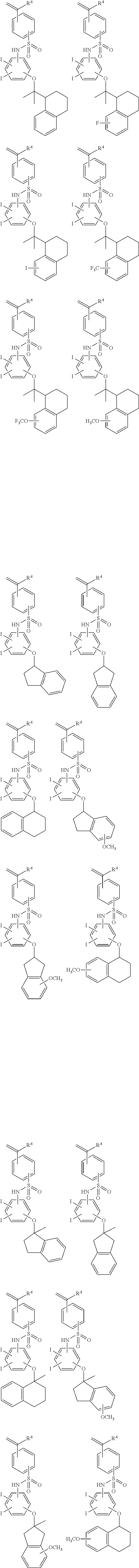

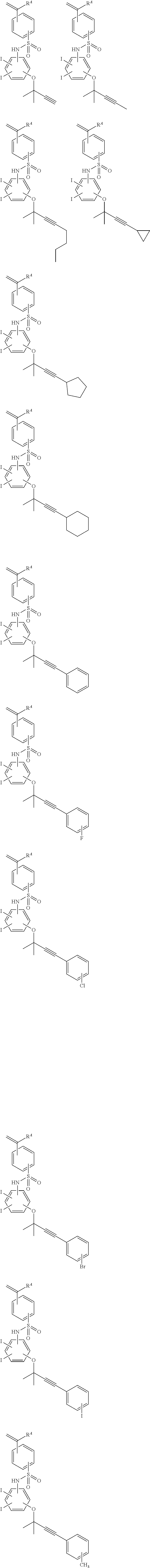

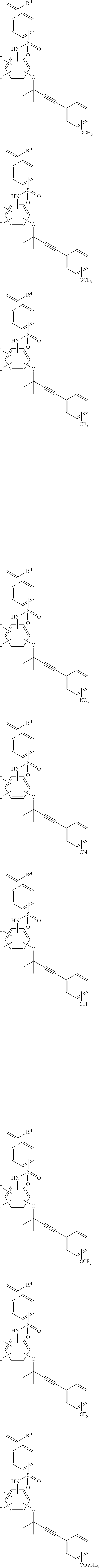

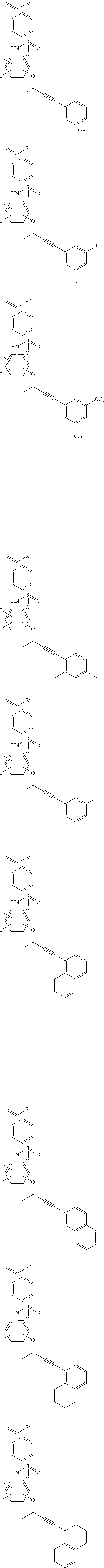

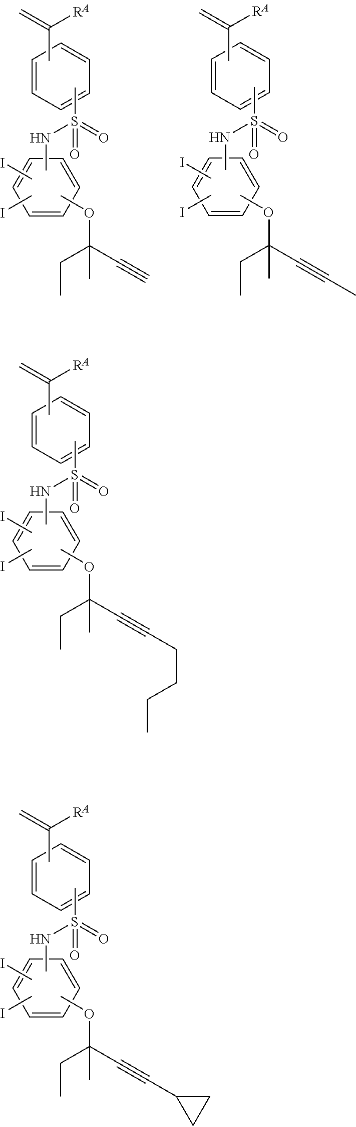

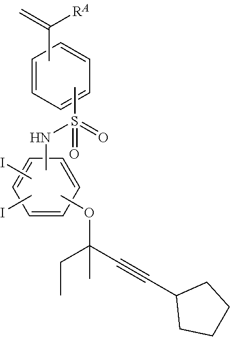

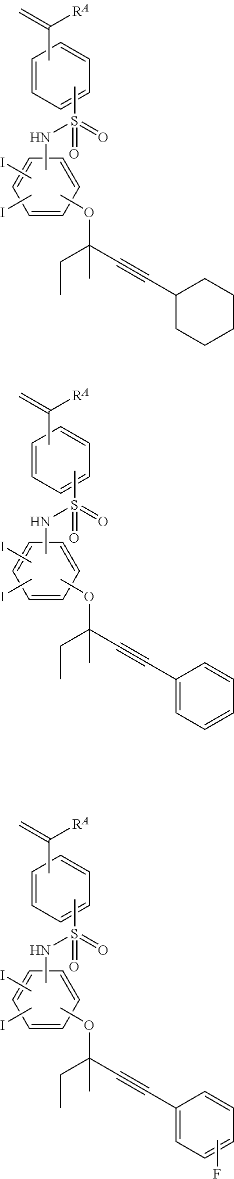

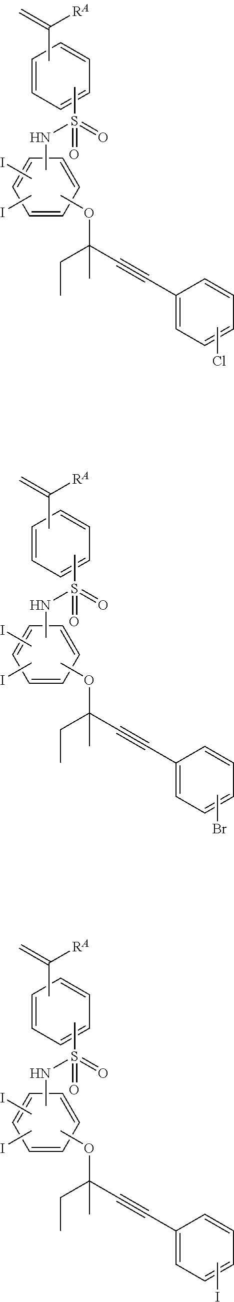

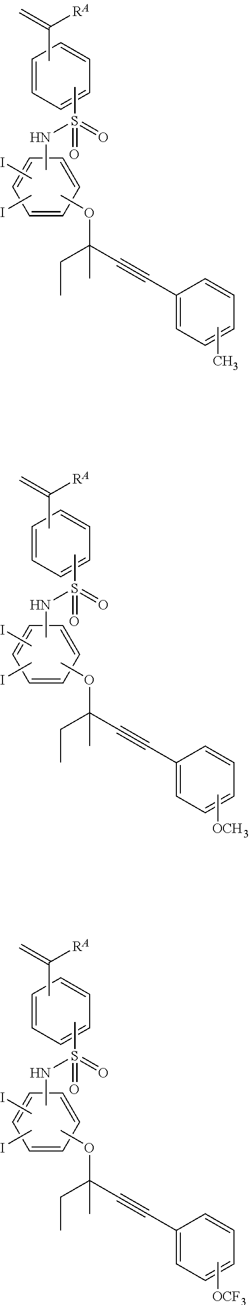

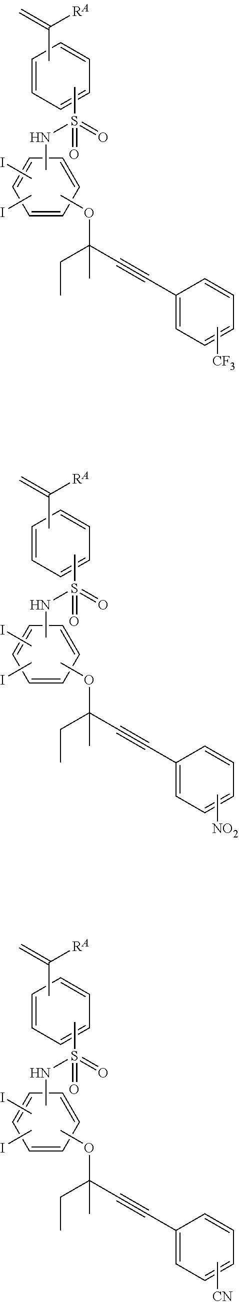

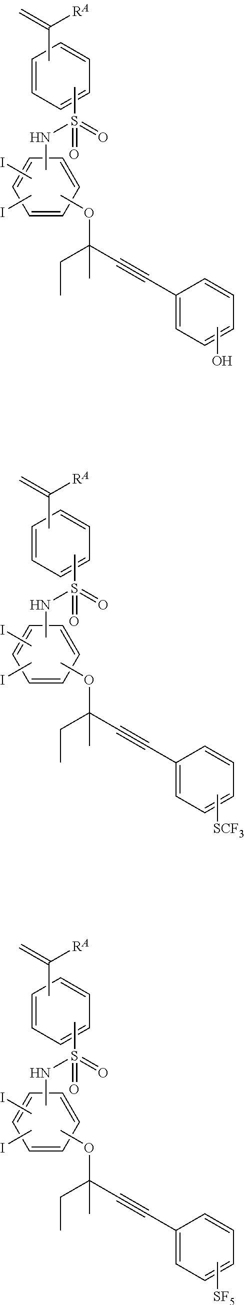

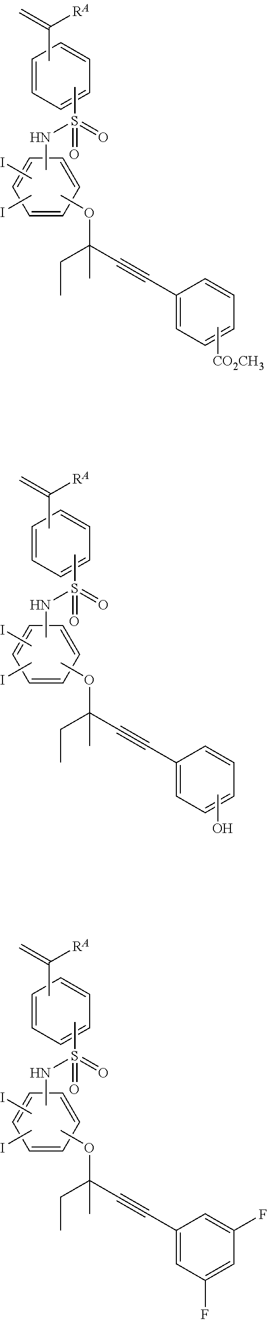

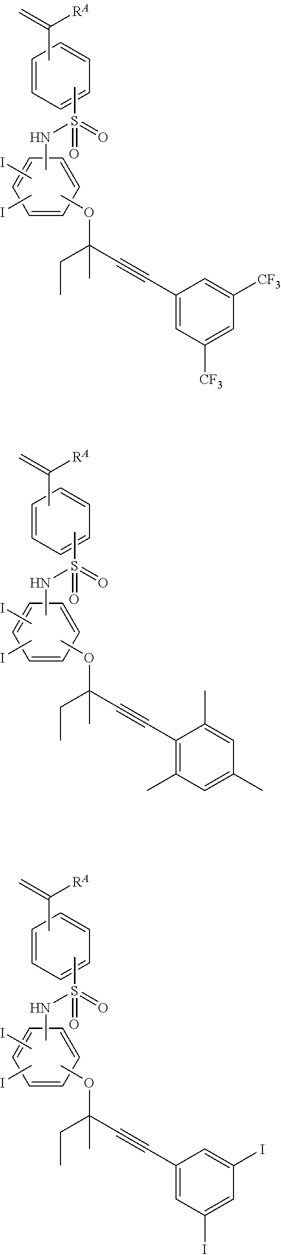

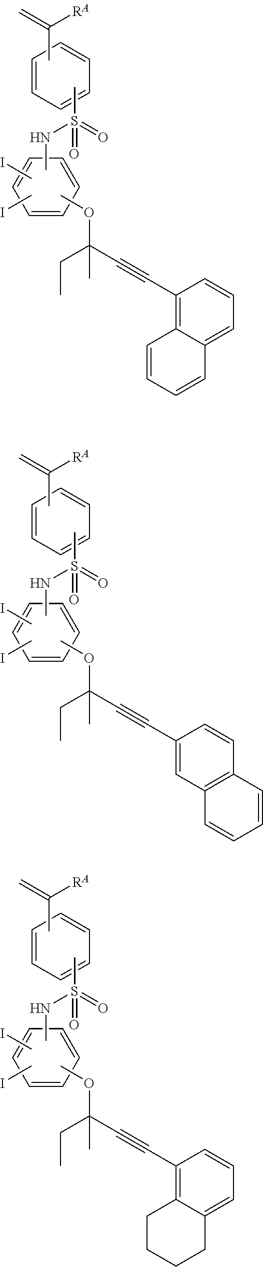

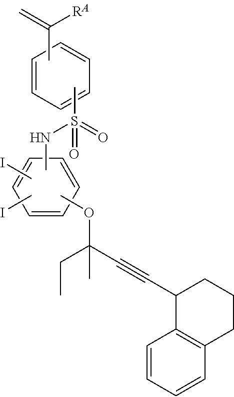

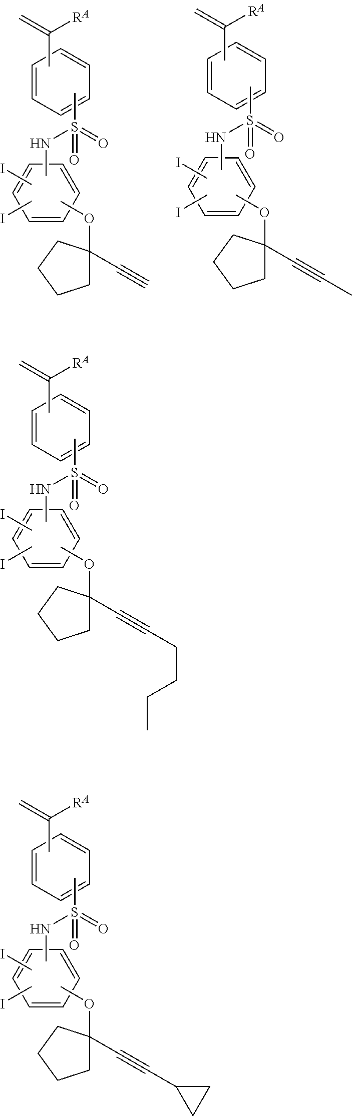

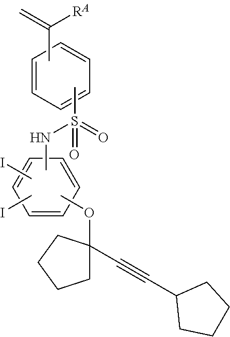

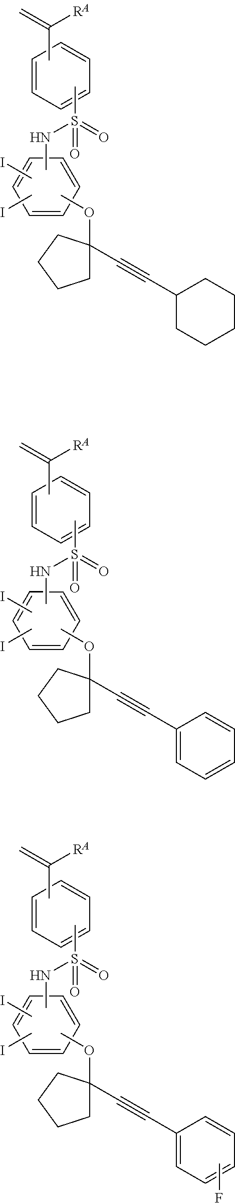

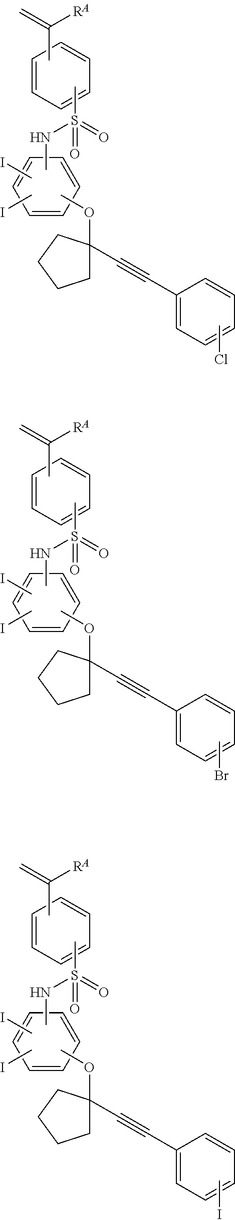

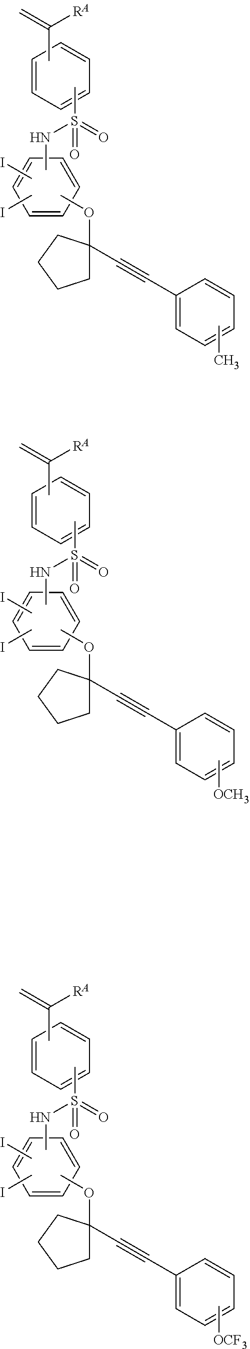

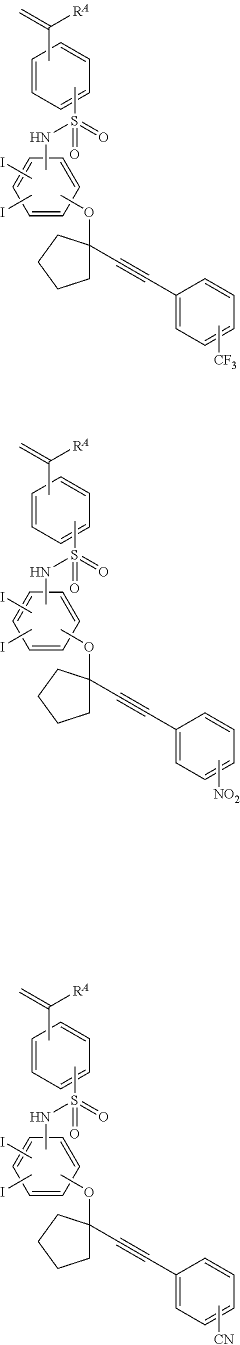

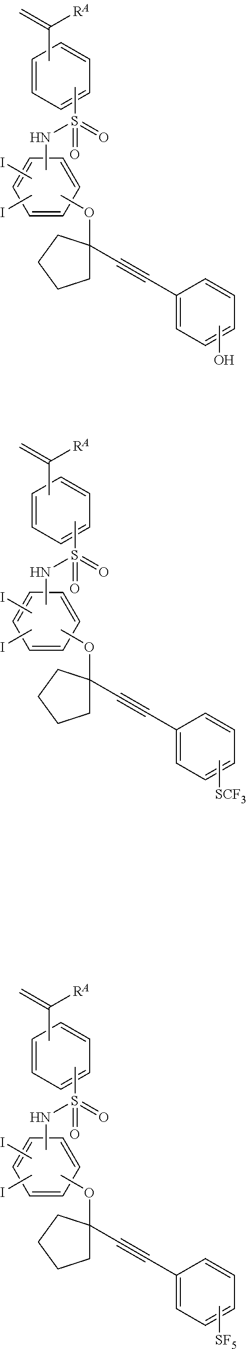

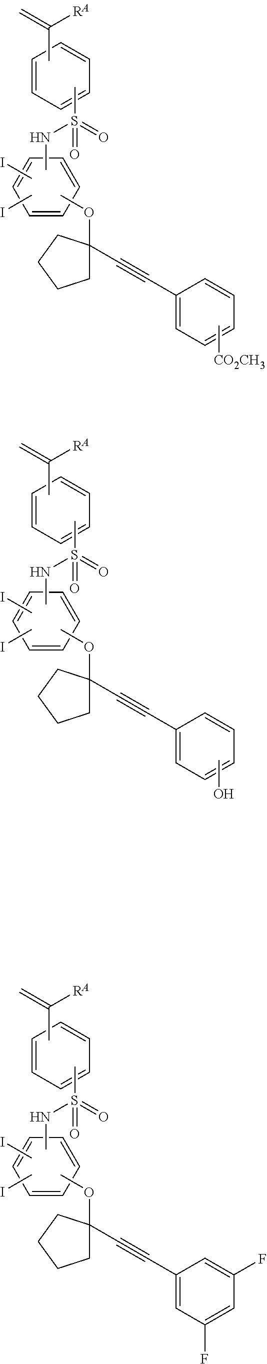

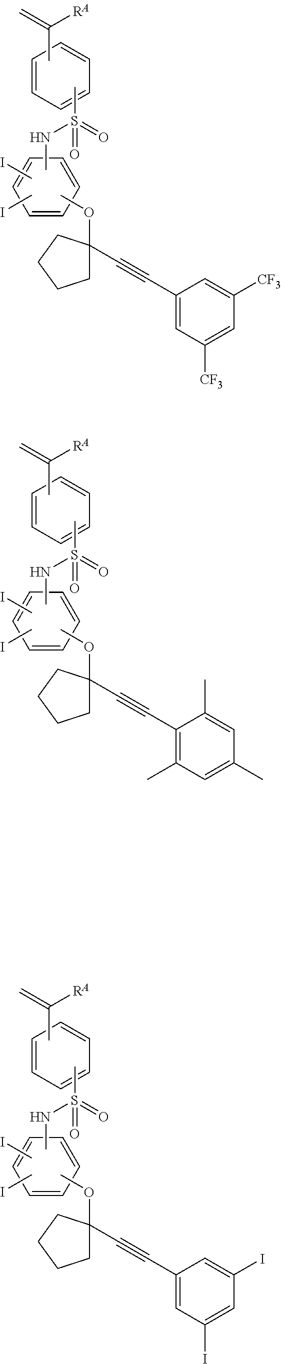

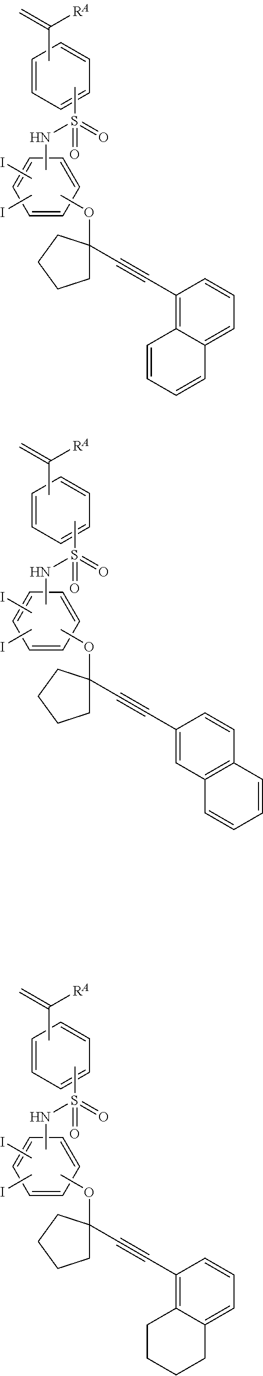

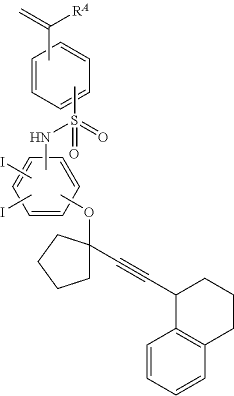

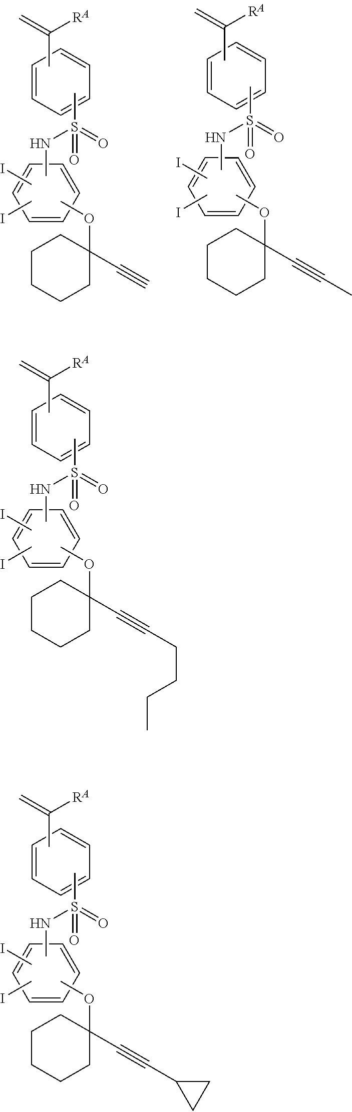

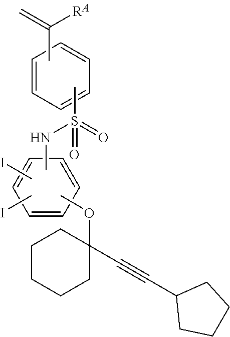

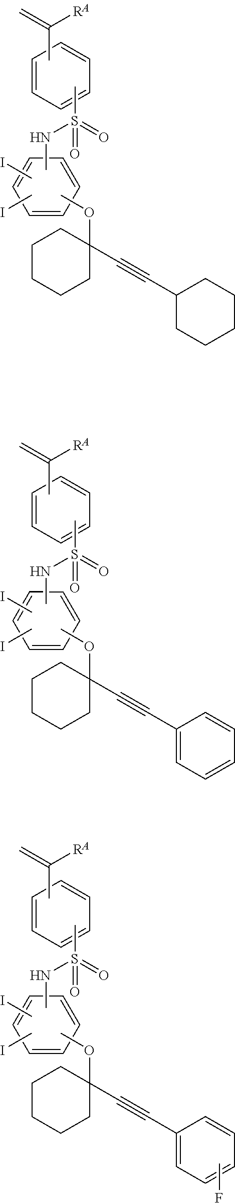

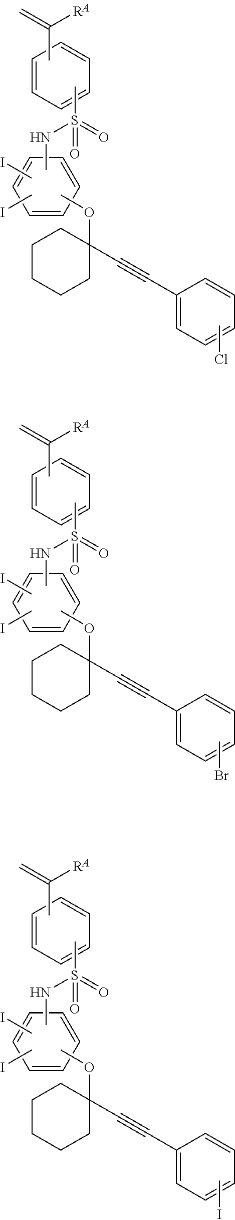

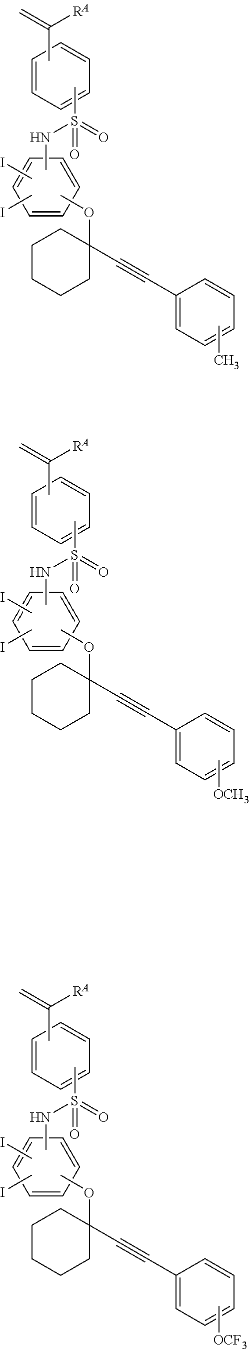

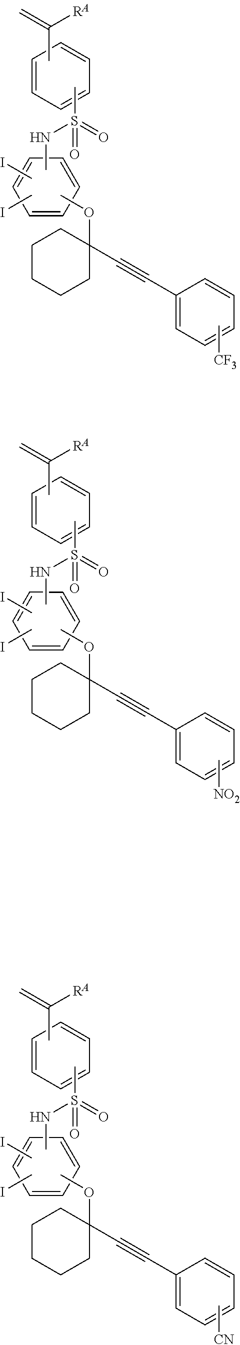

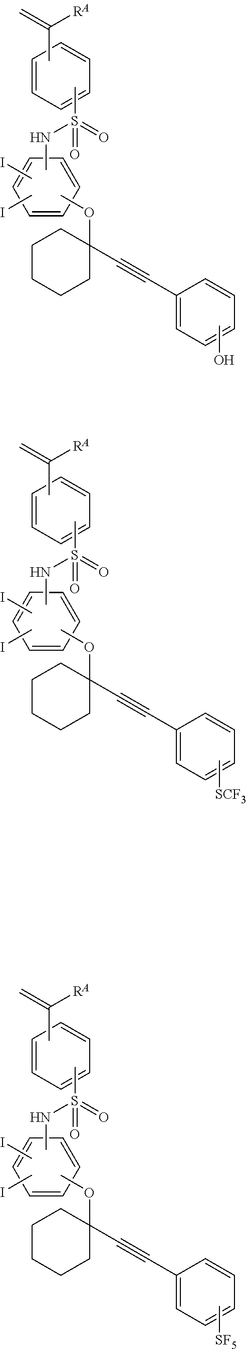

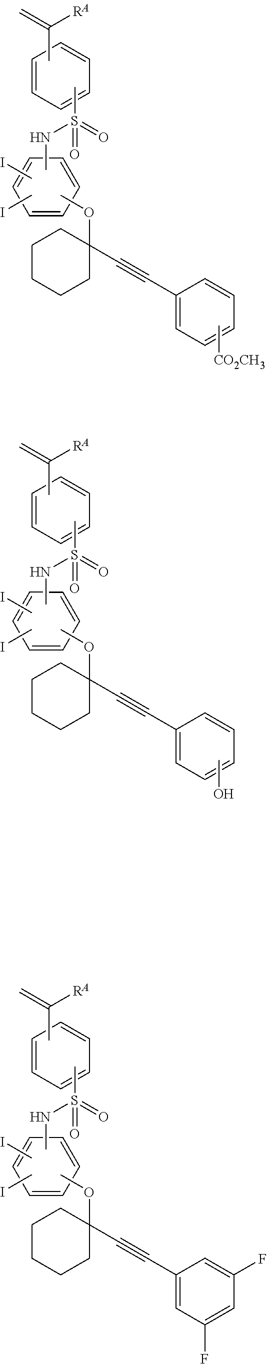

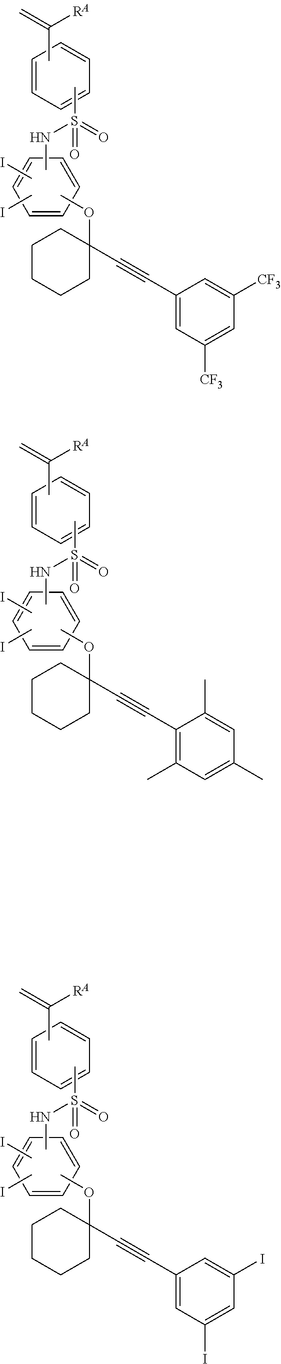

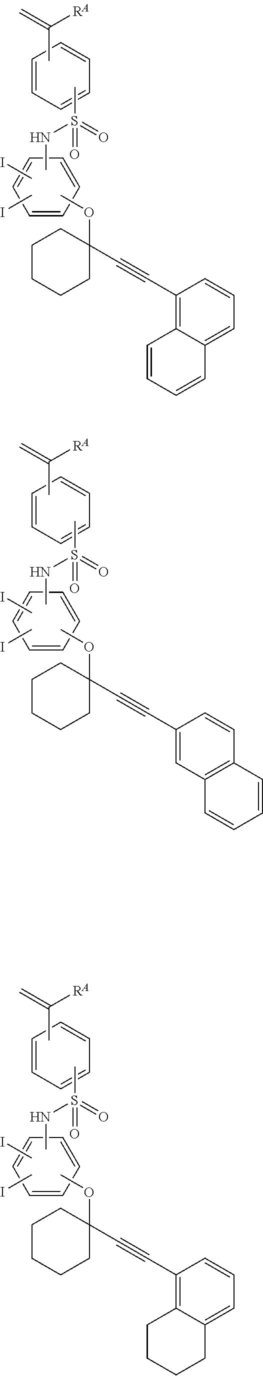

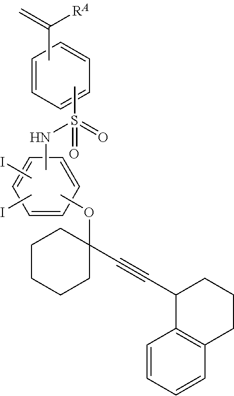

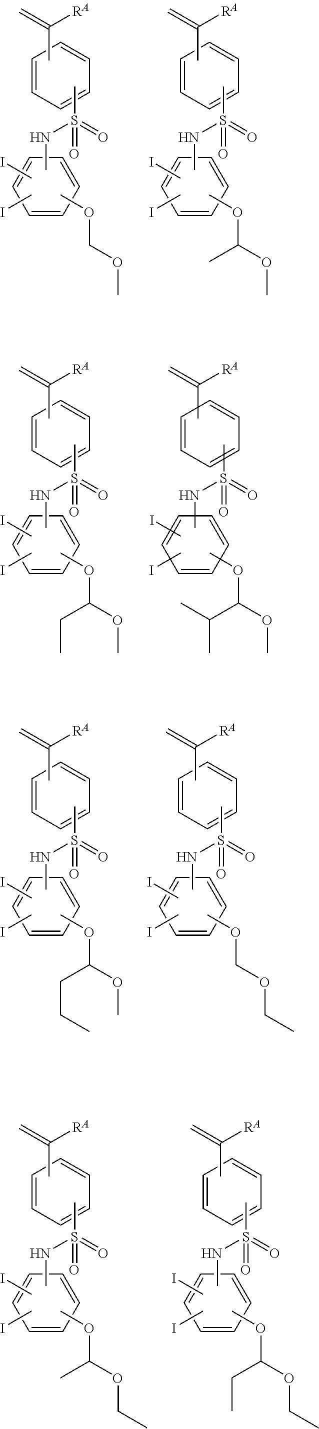

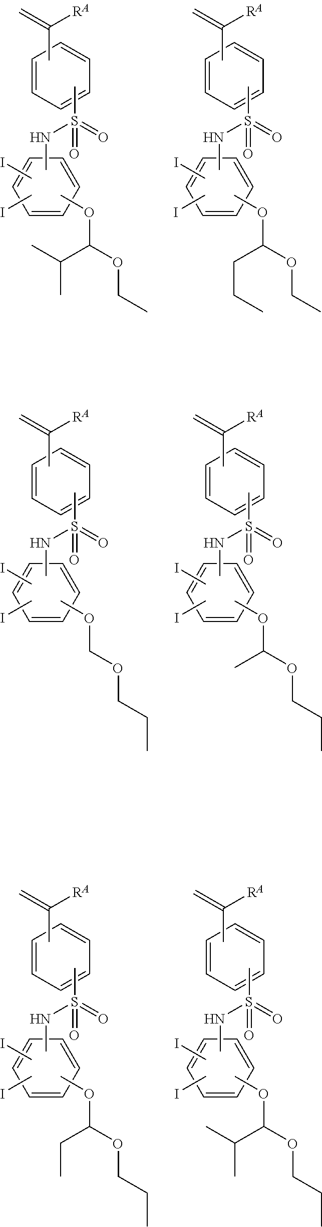

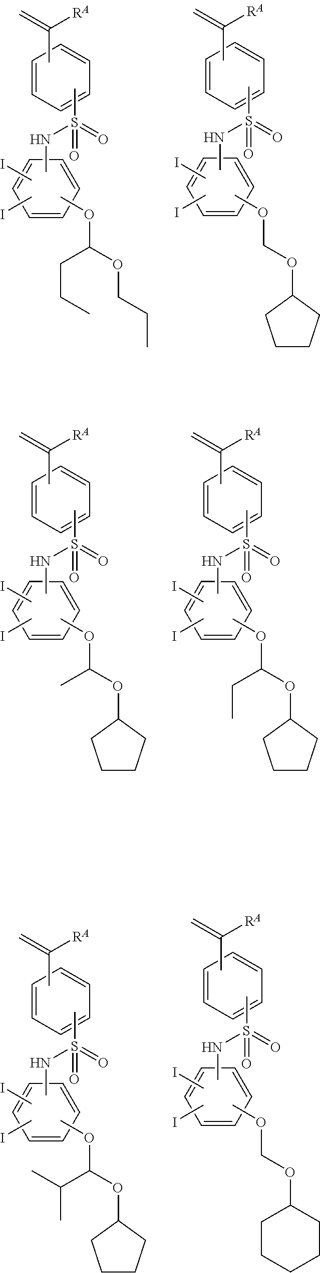

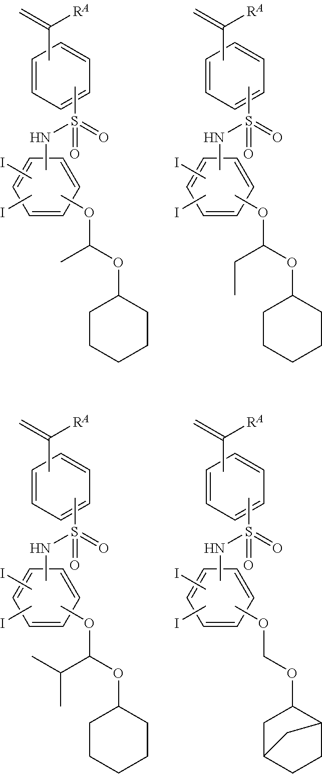

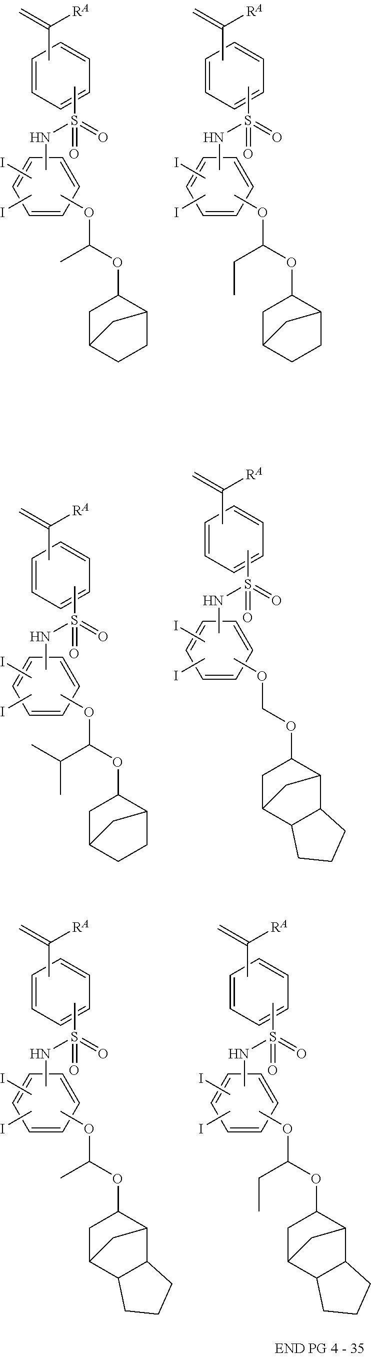

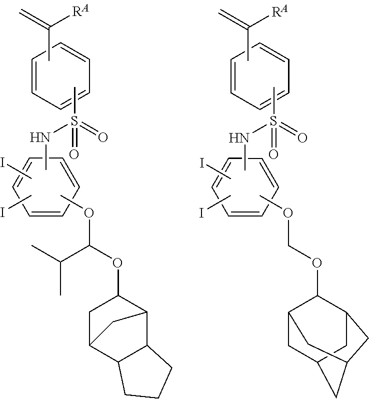

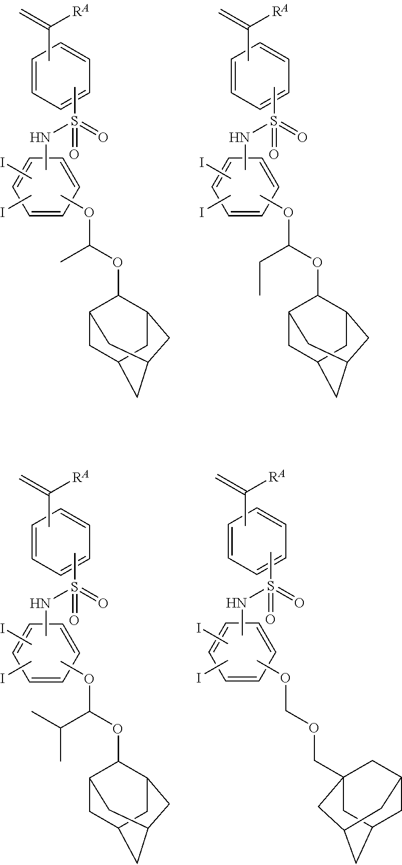

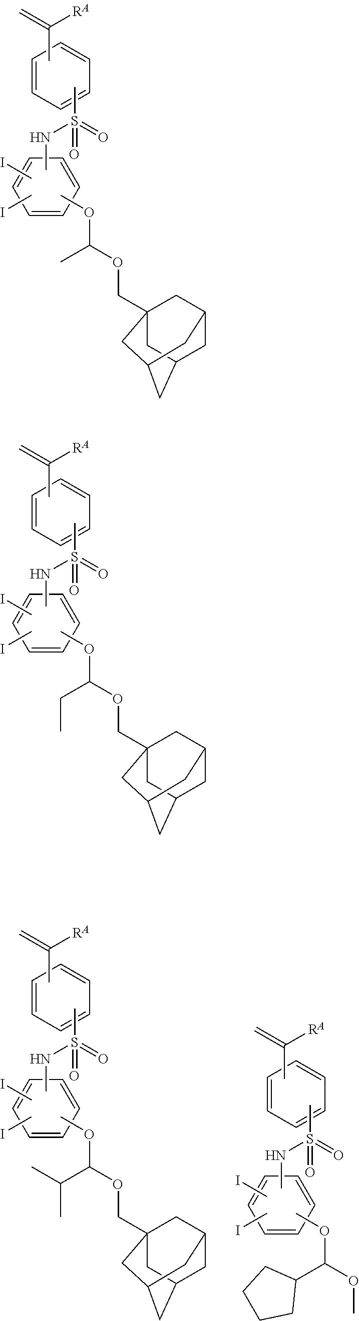

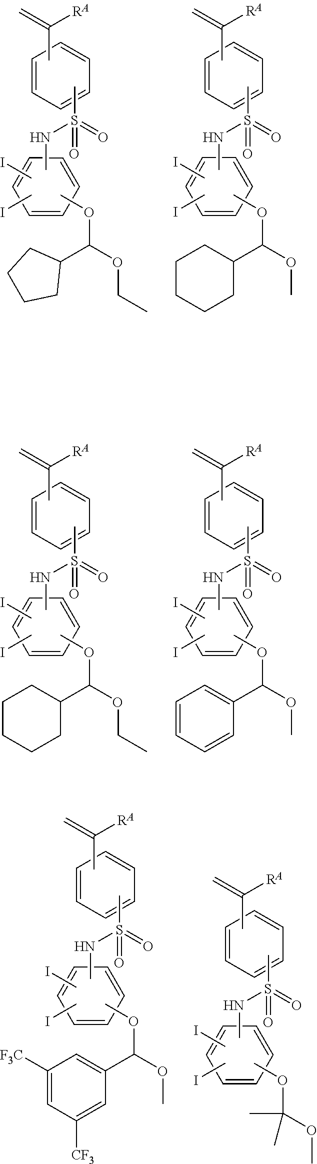

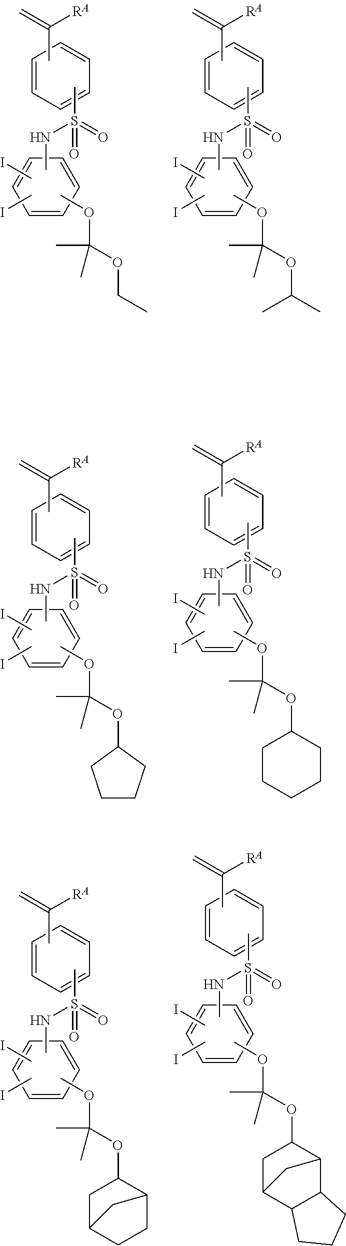

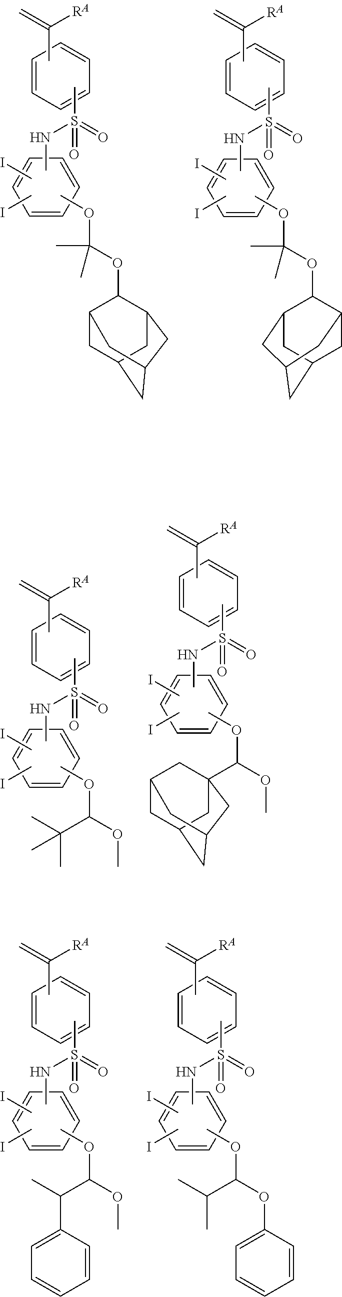

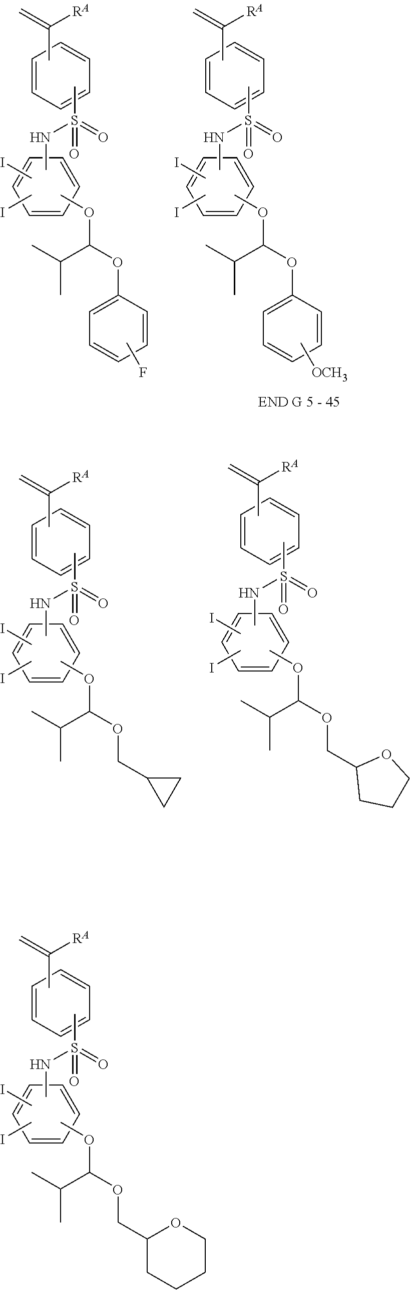

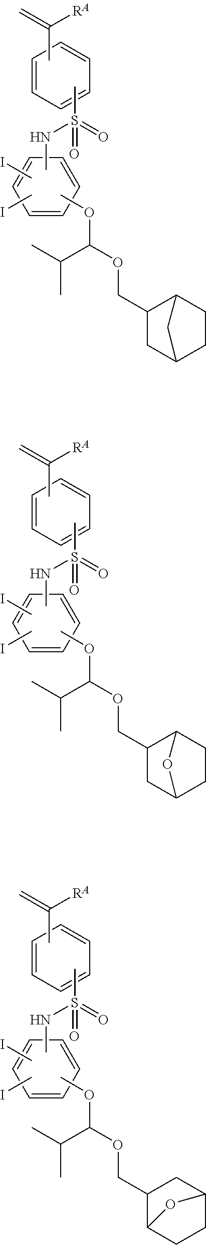

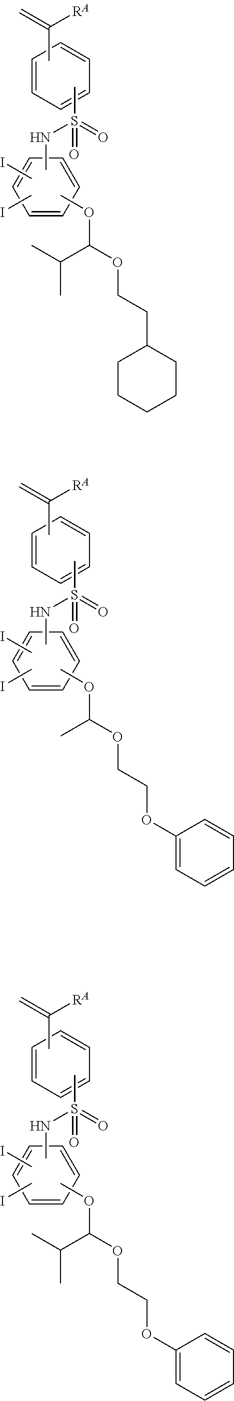

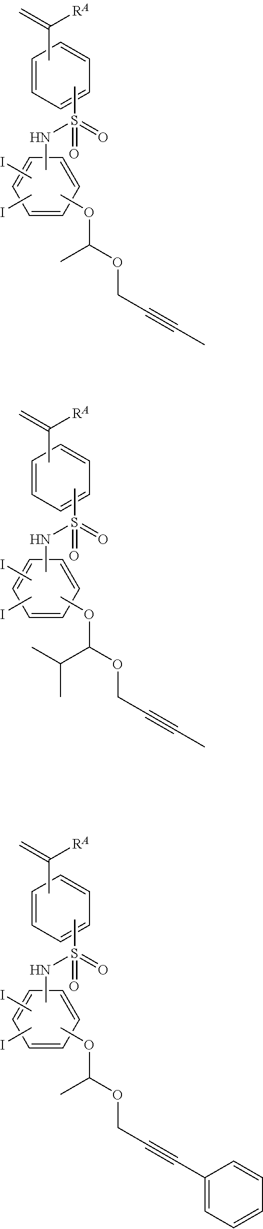

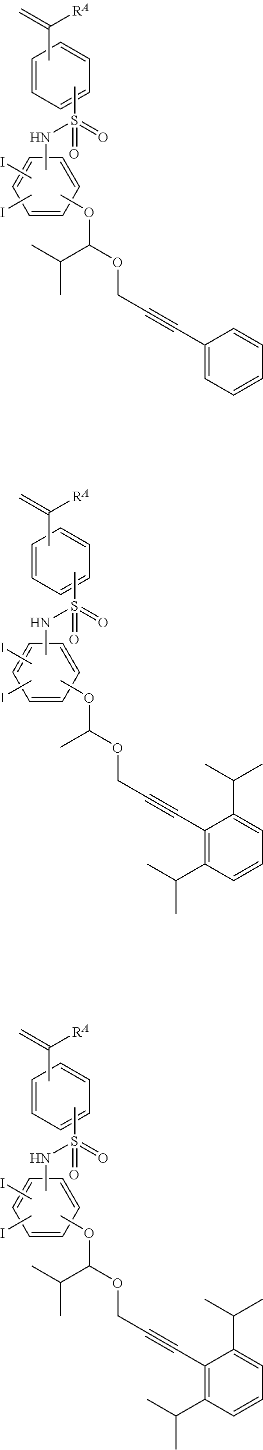

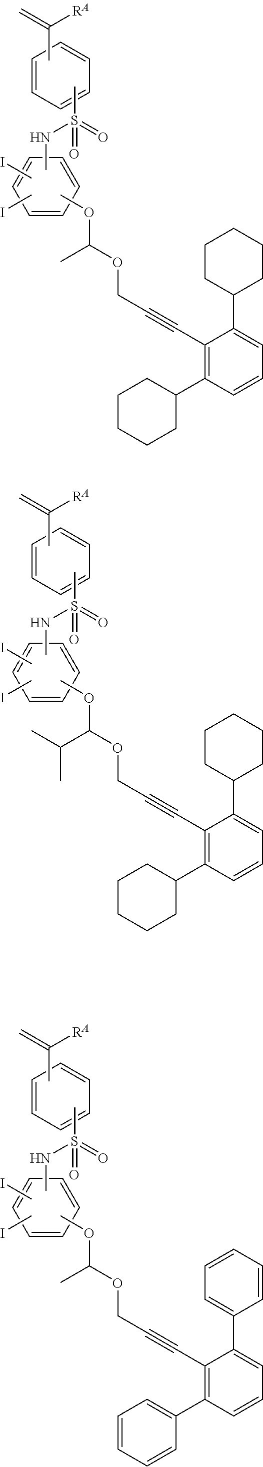

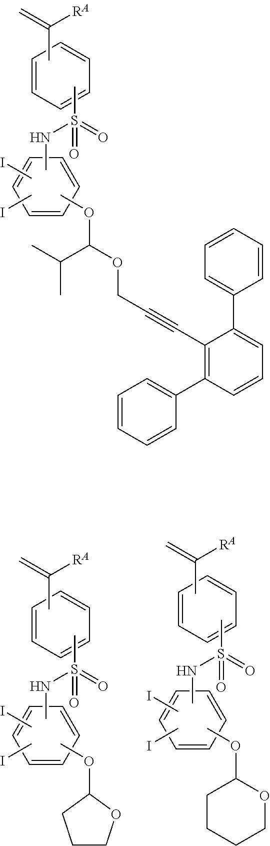

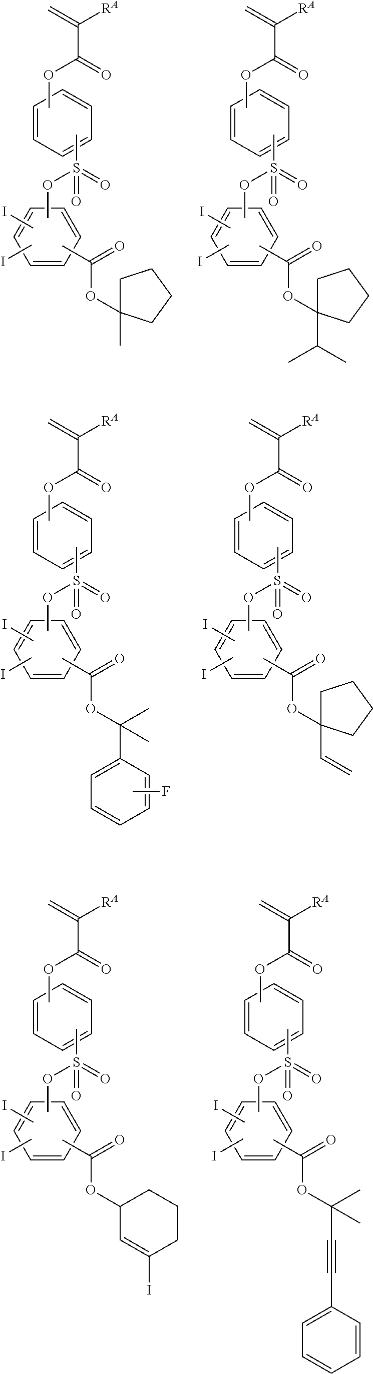

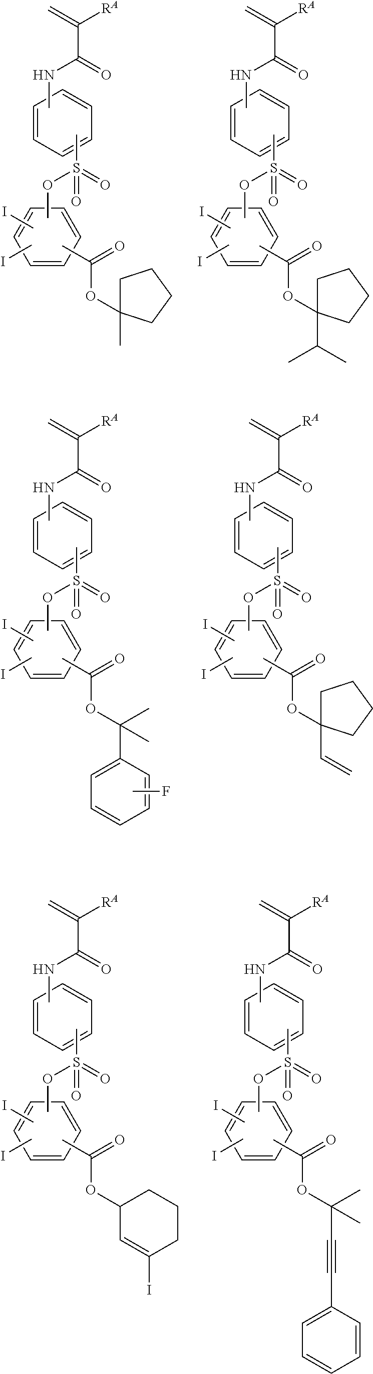

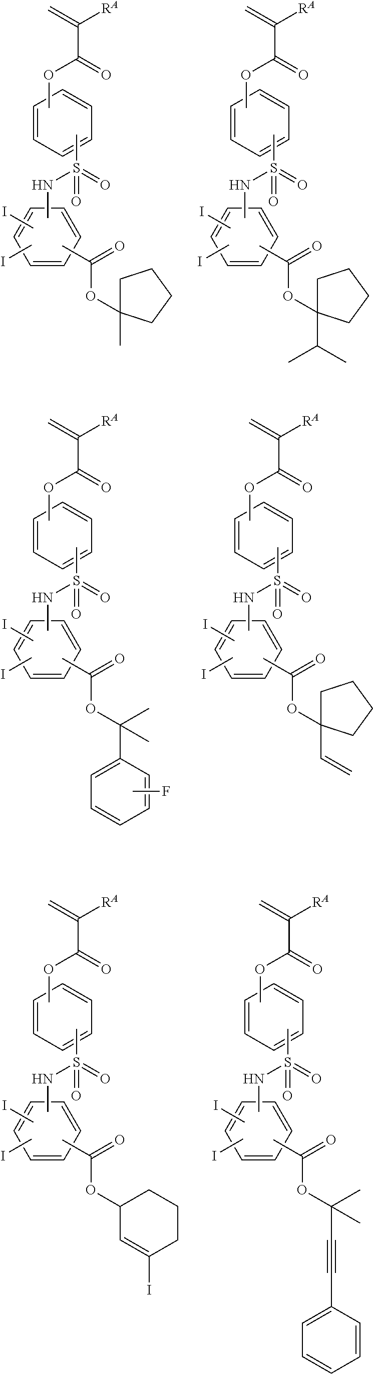

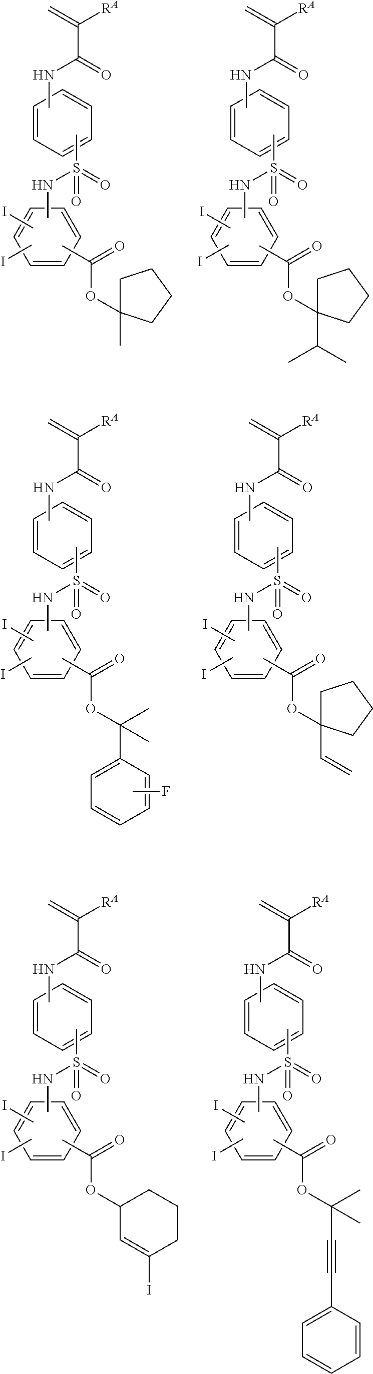

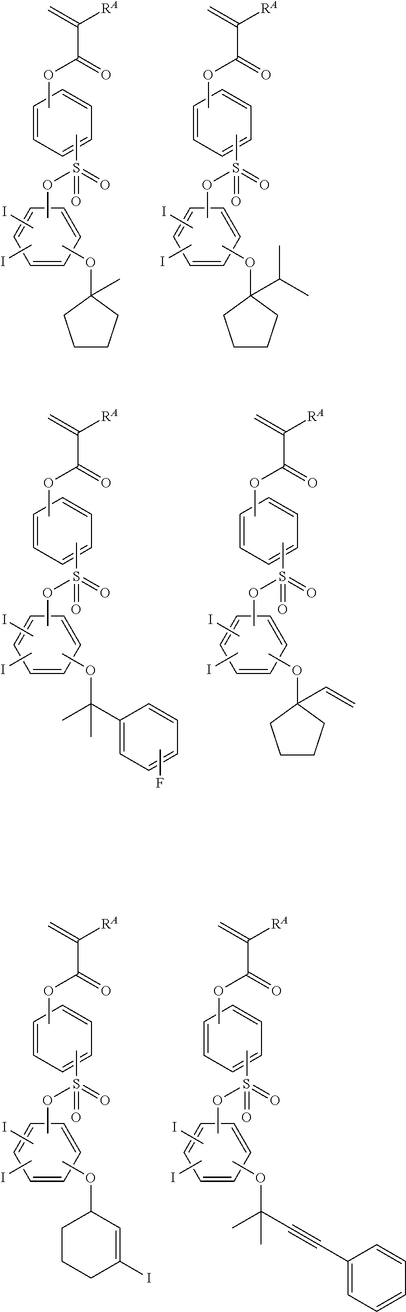

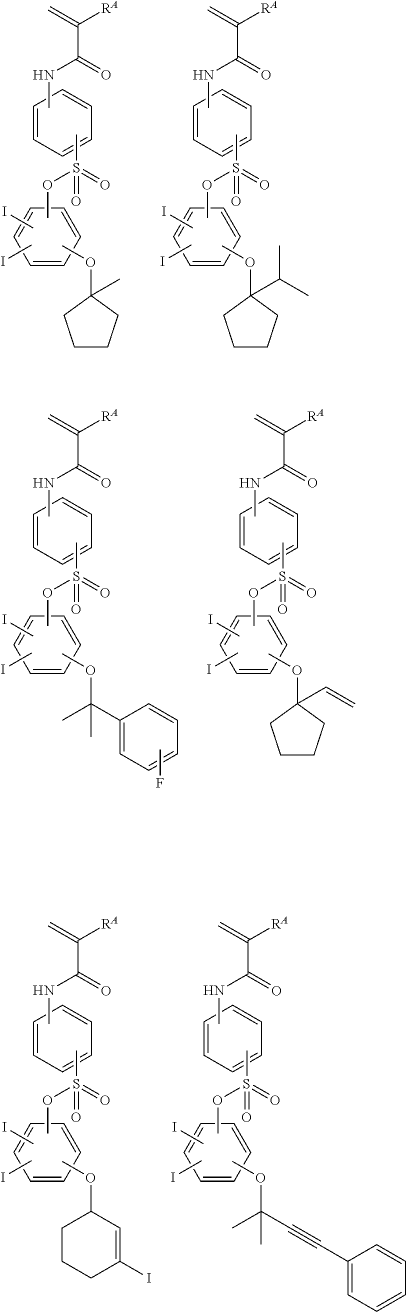

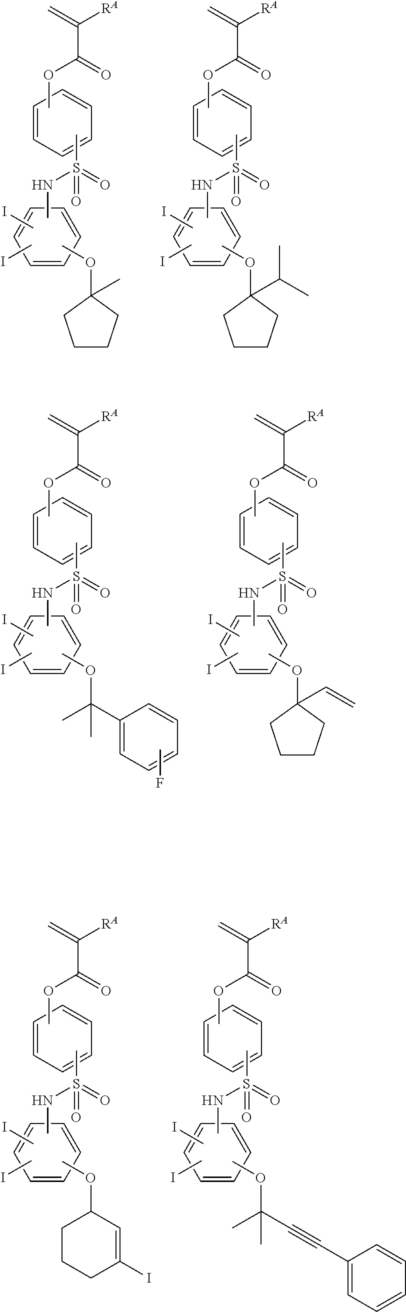

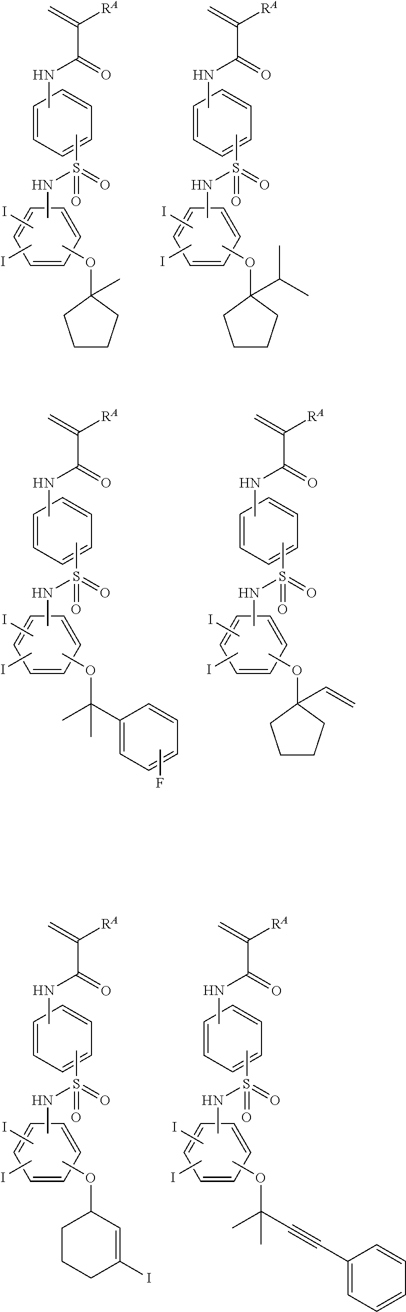

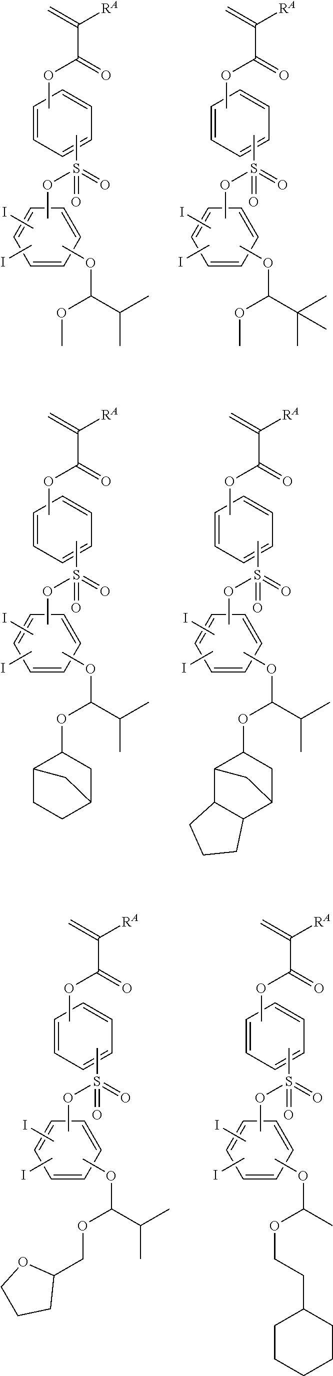

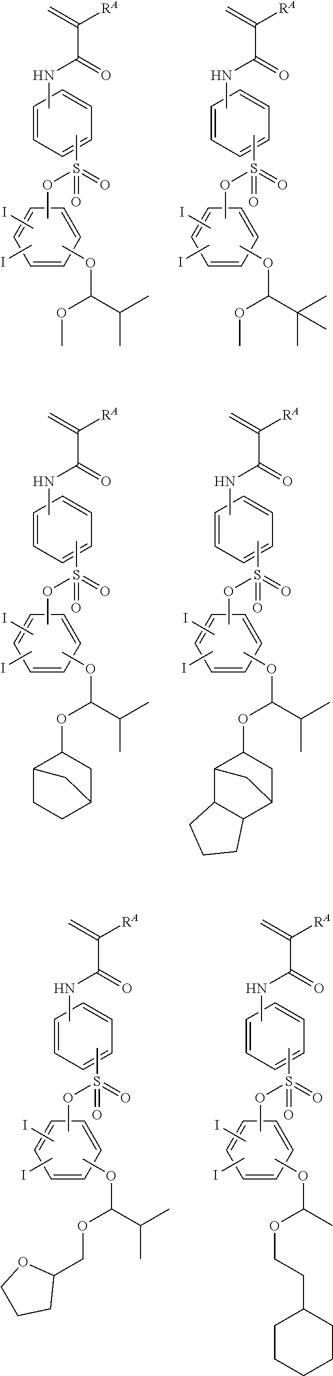

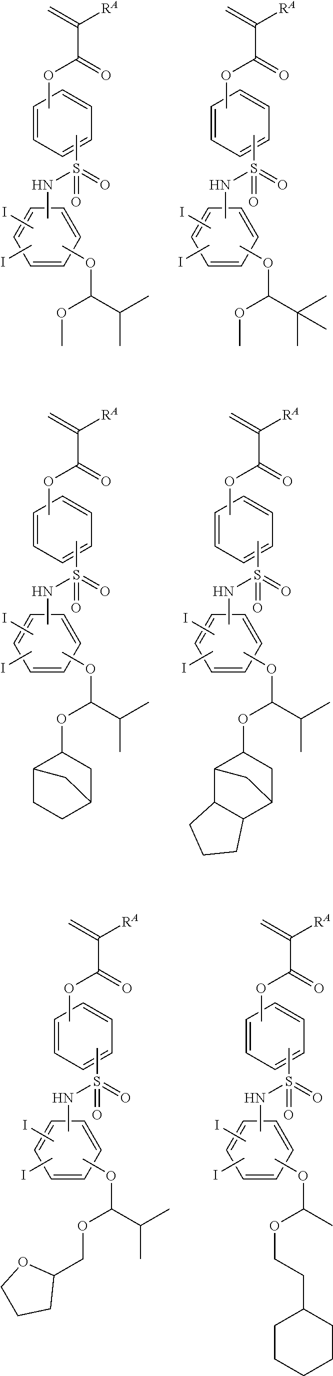

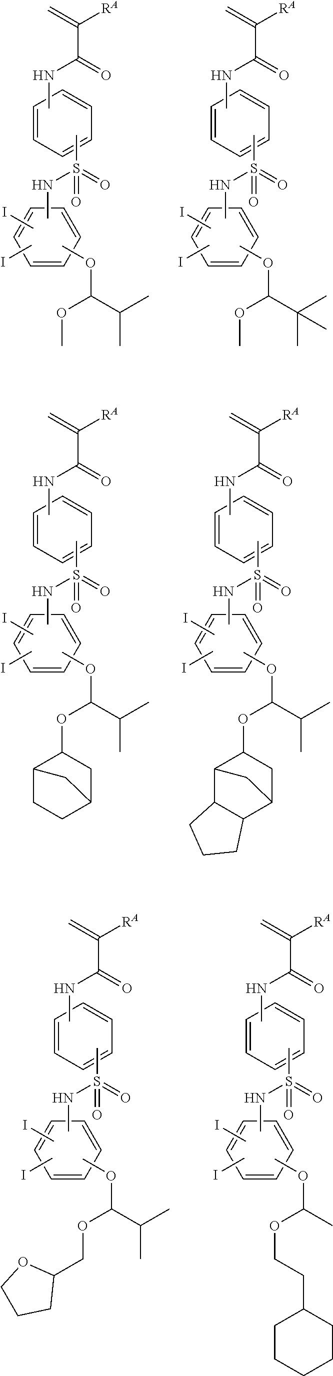

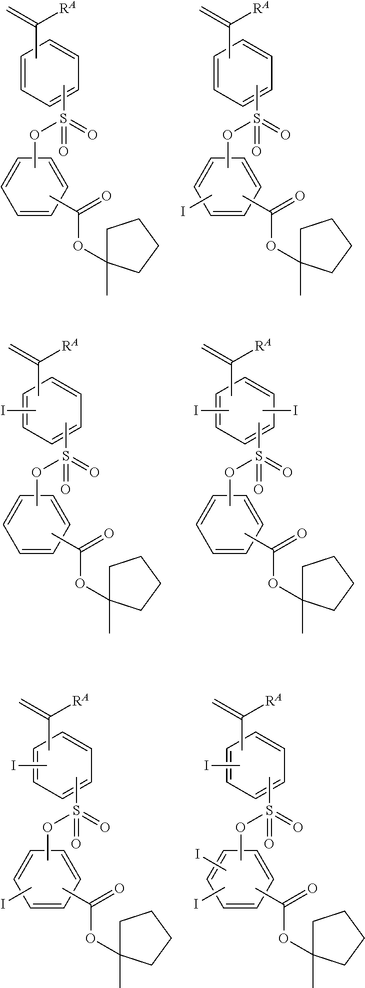

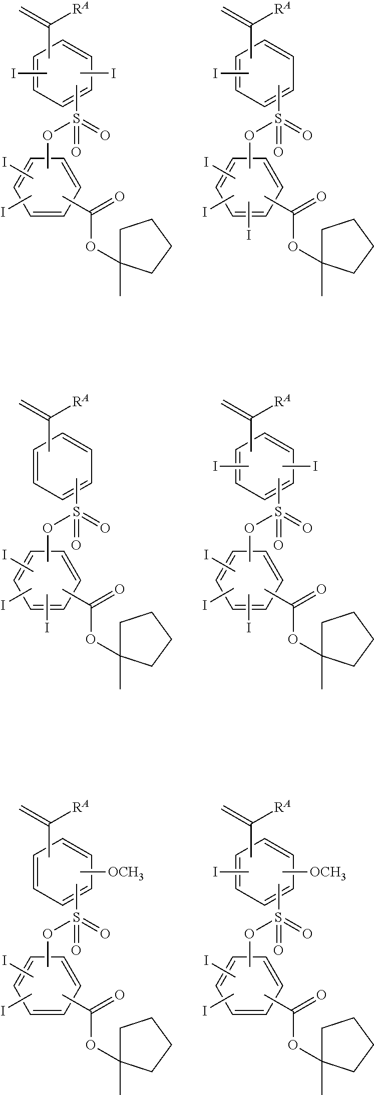

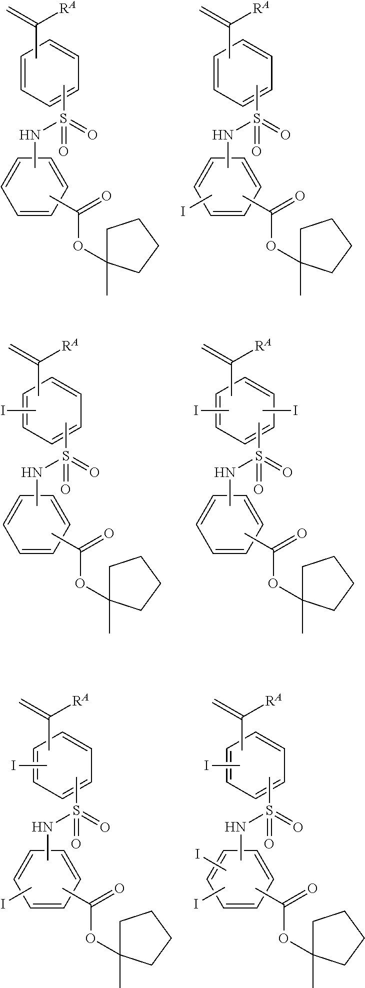

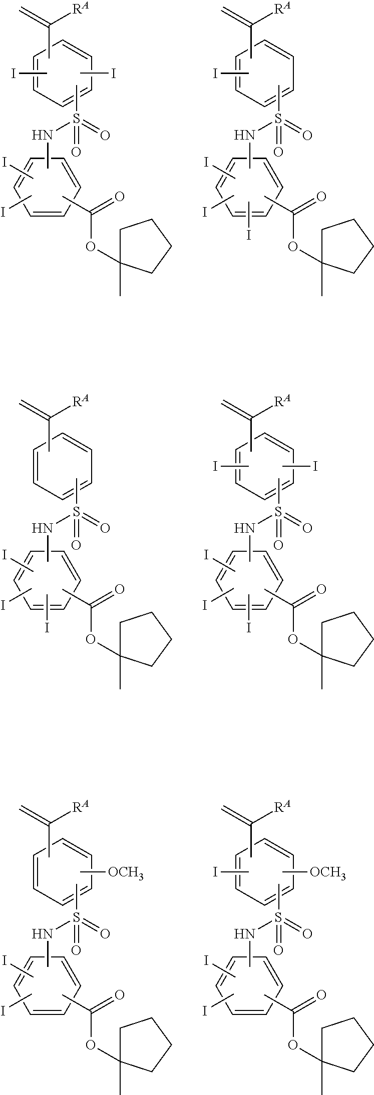

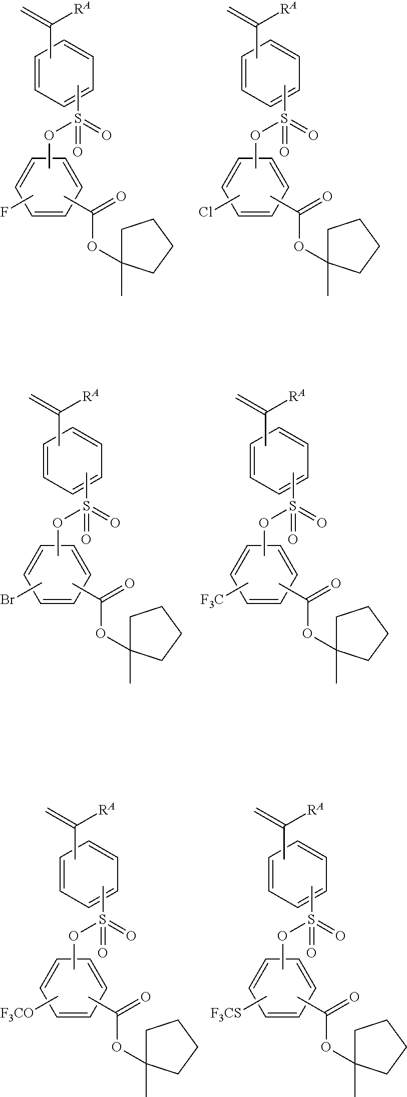

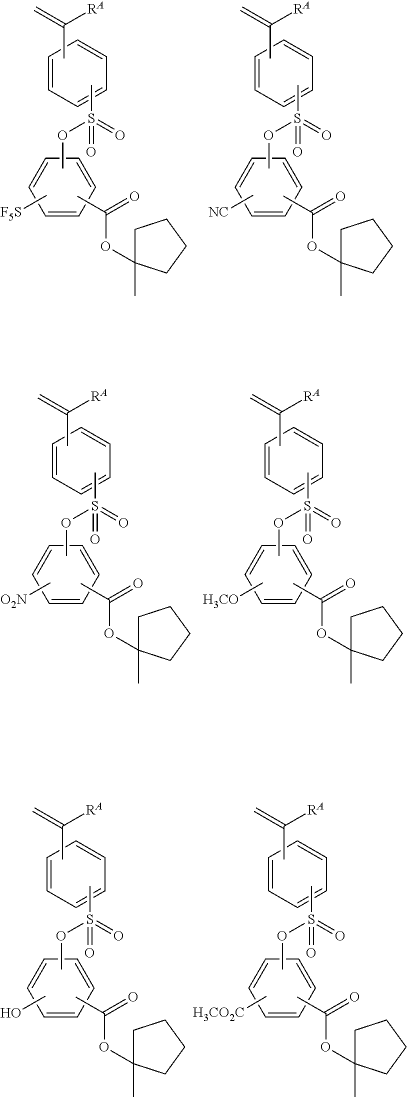

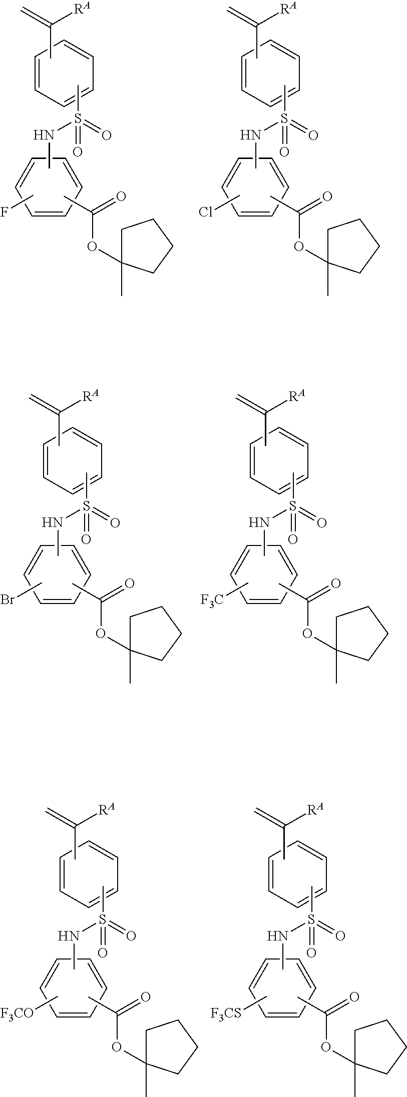

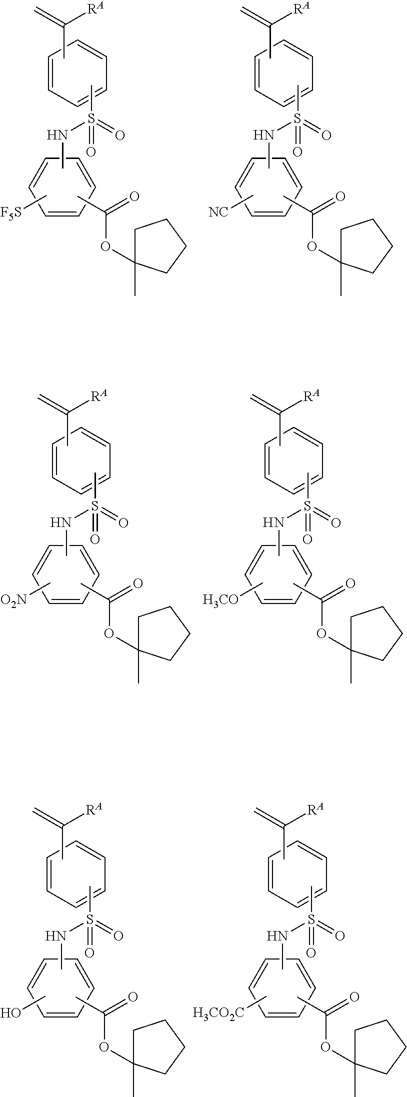

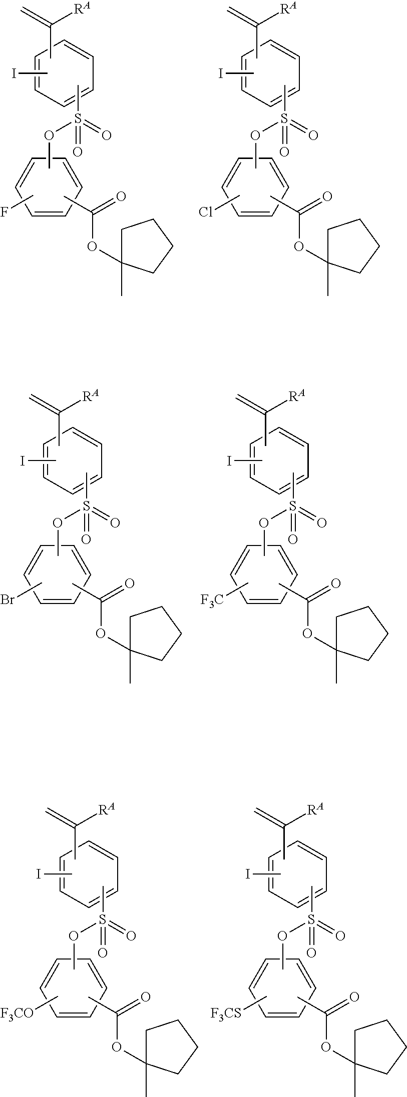

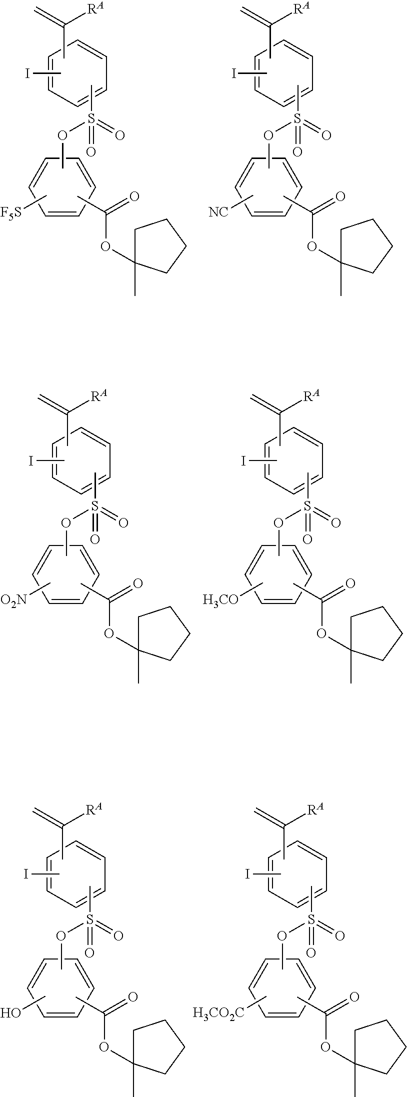

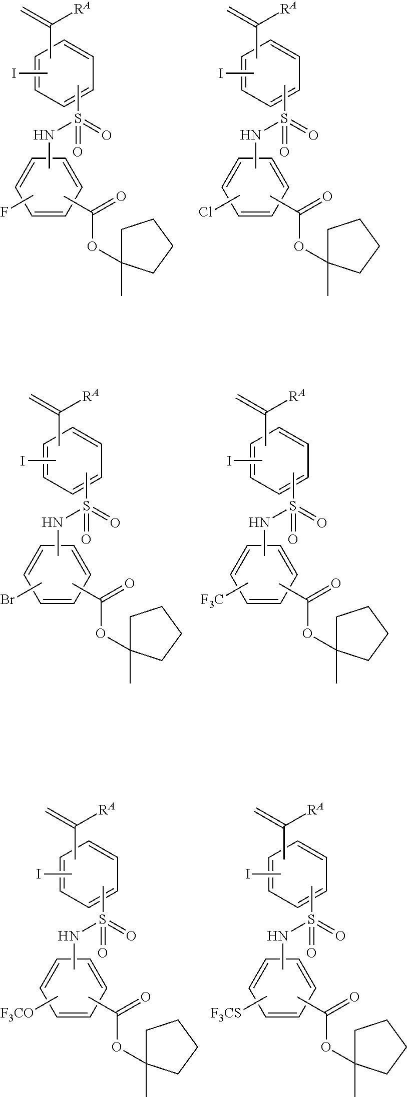

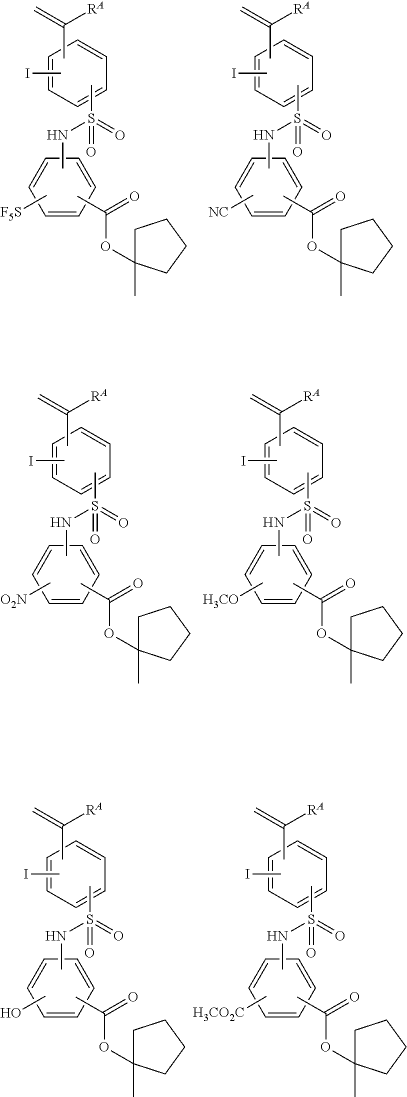

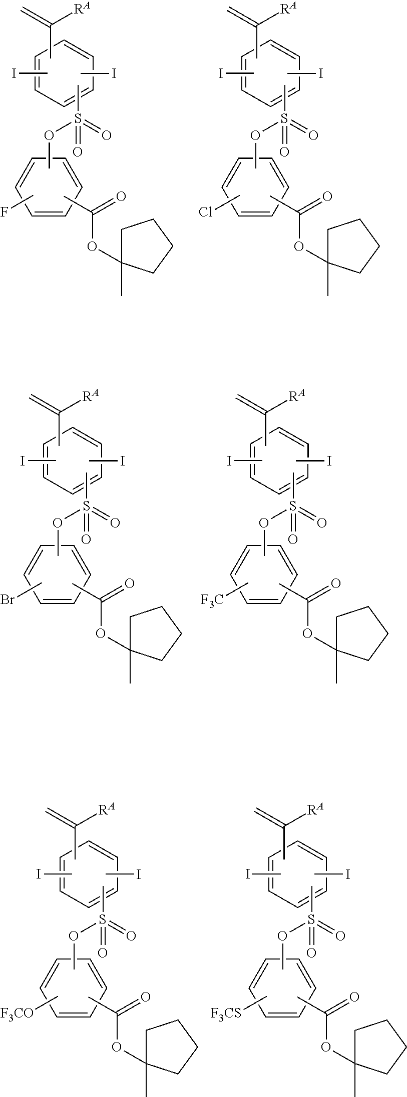

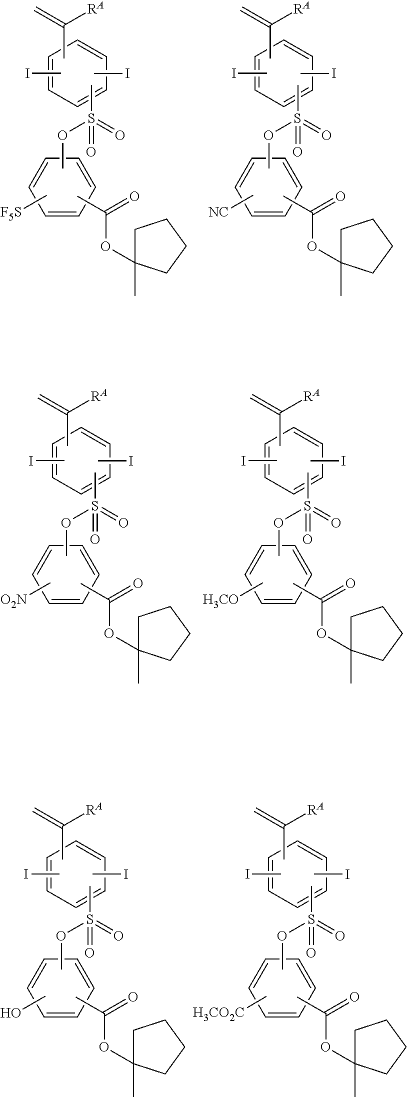

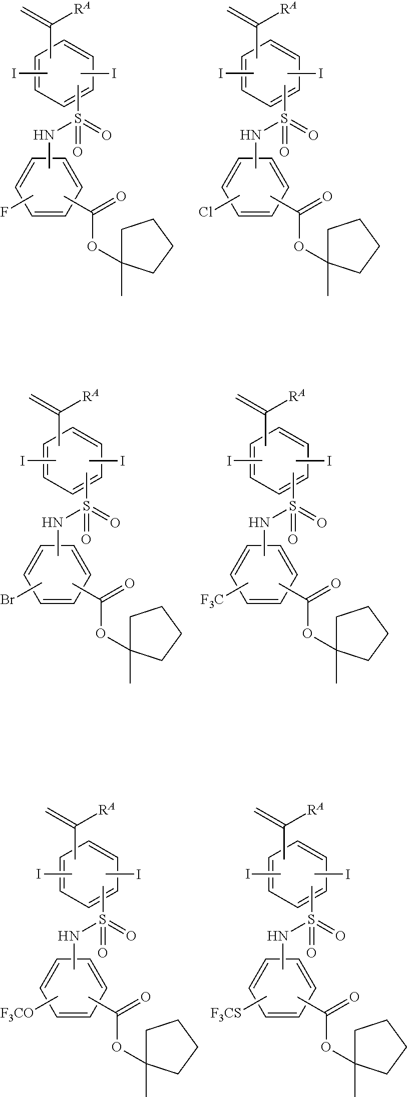

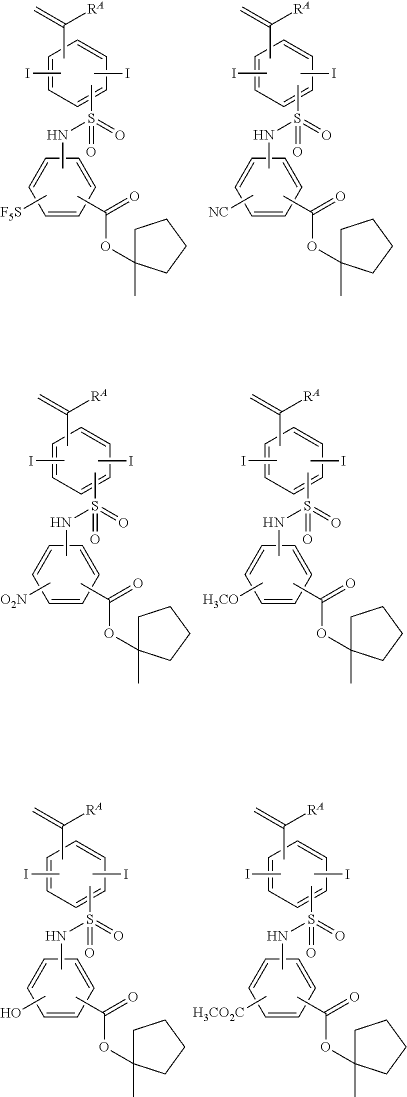

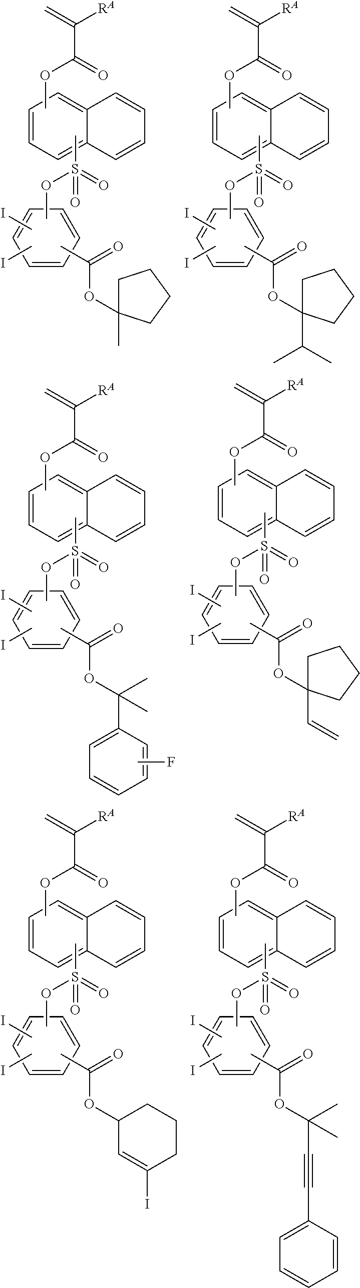

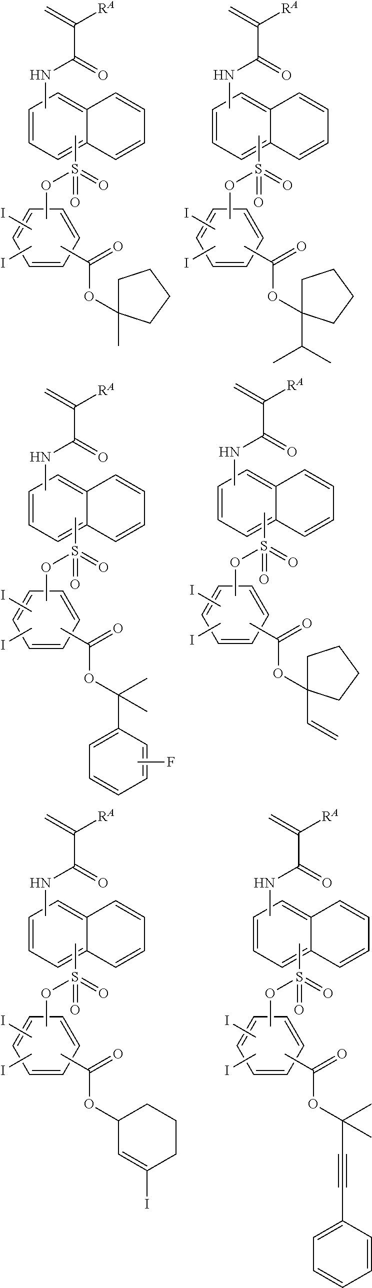

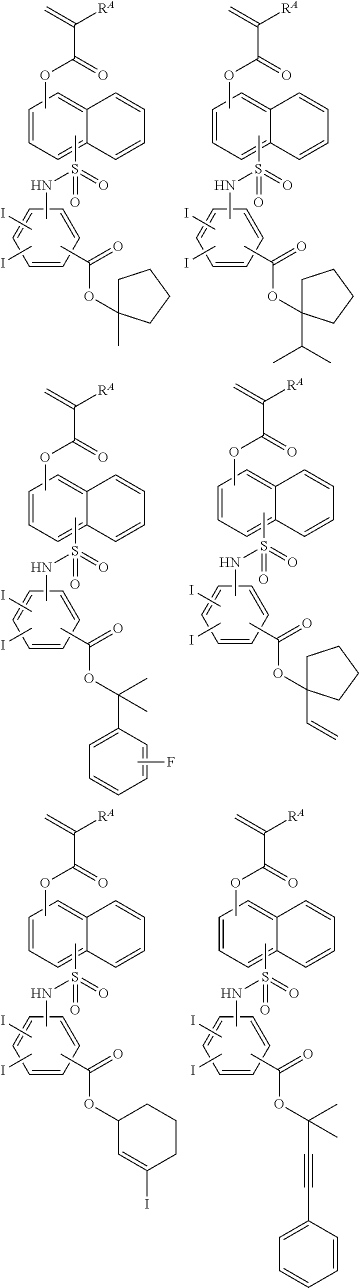

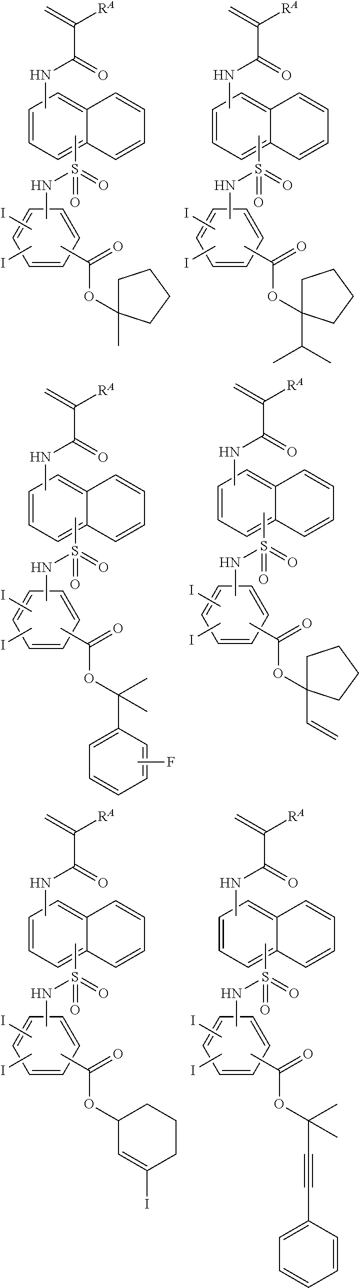

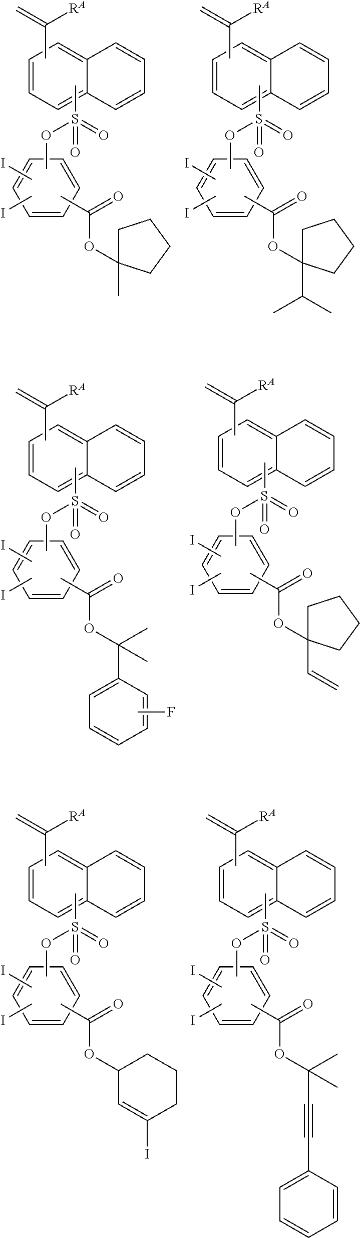

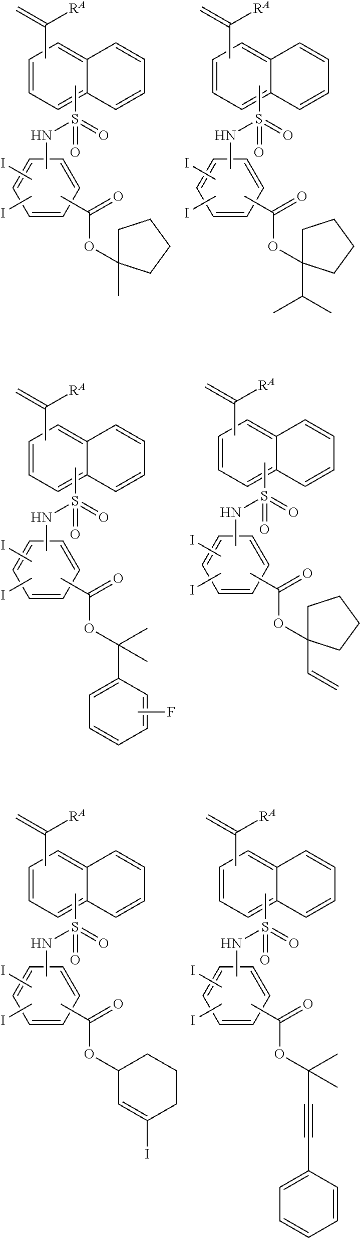

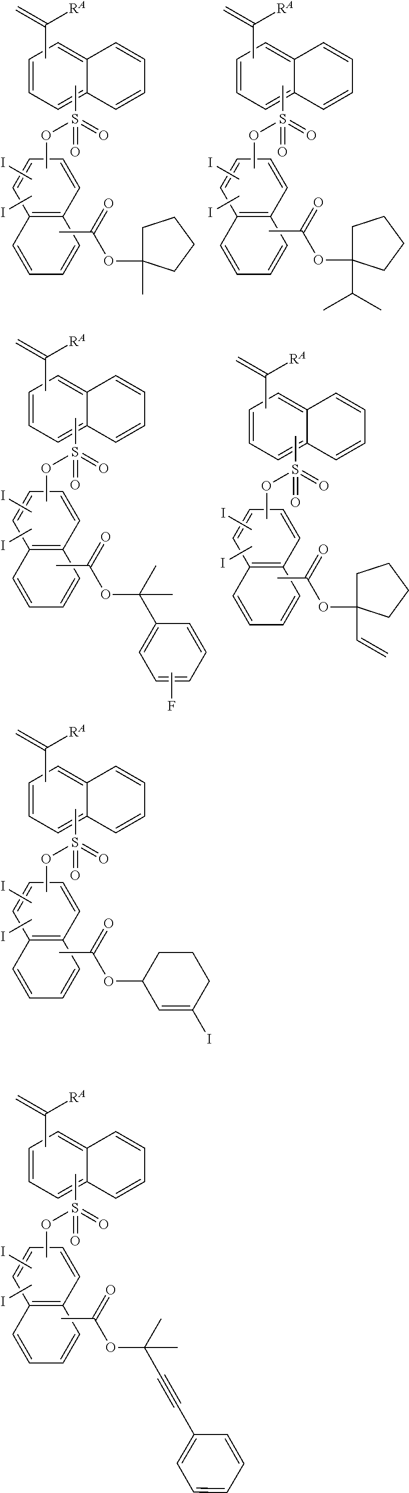

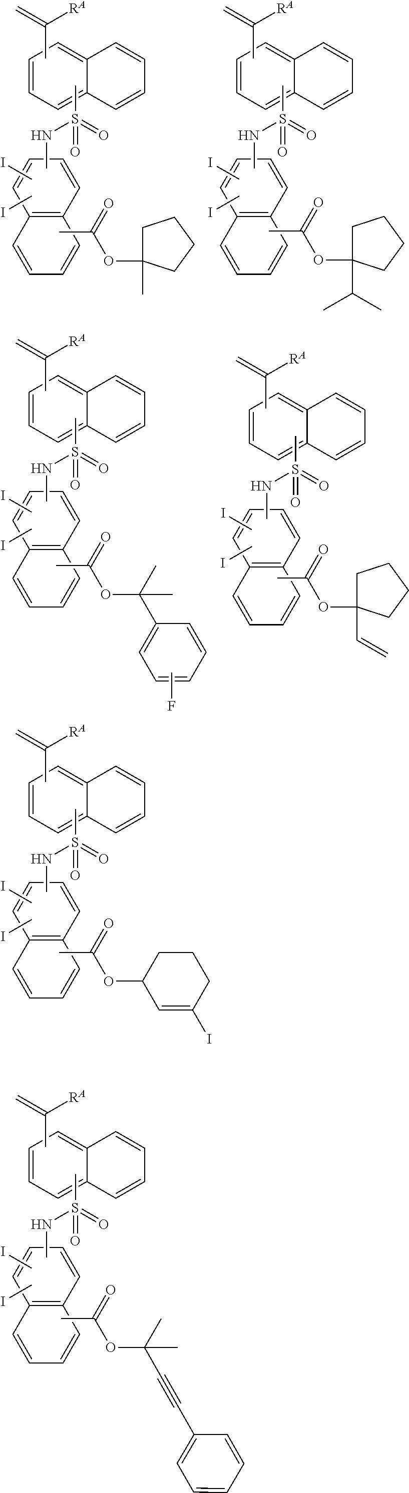

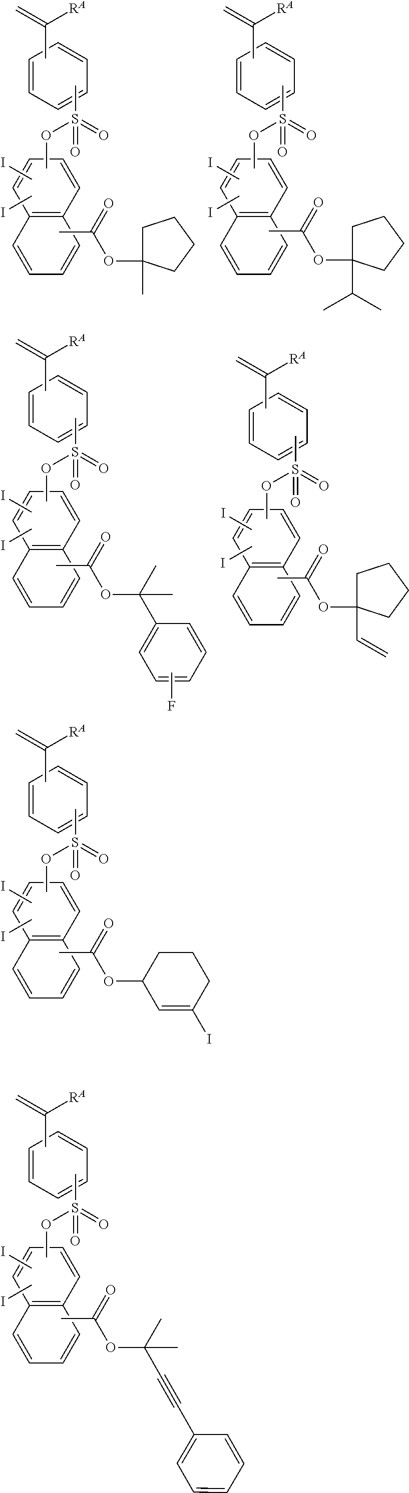

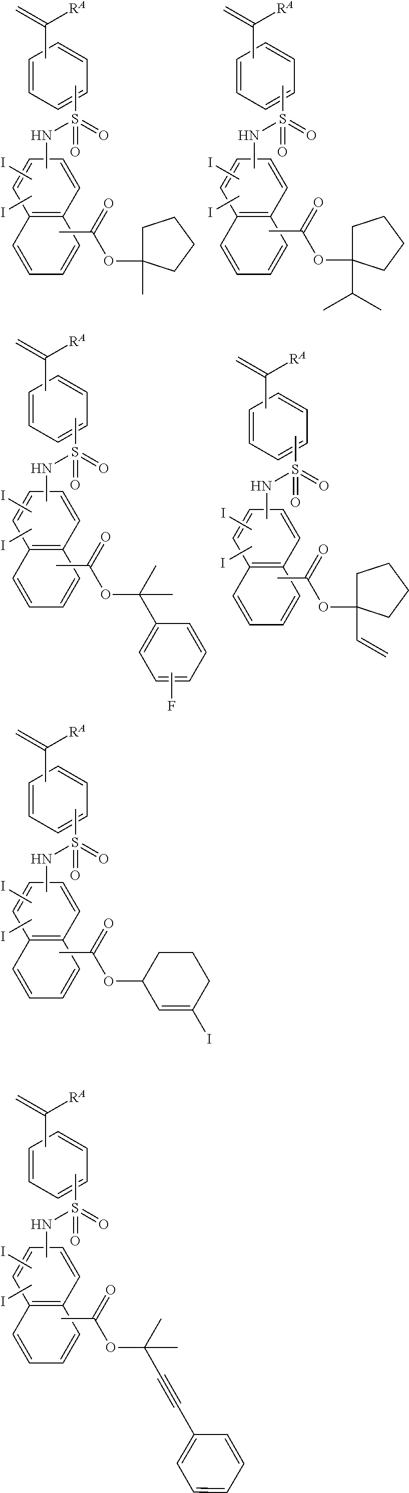

The monomer may be synthesized by any well-known methods. Reference is now made to the synthesis of a monomer having formula (A) wherein X¹ is oxygen, i.e., monomer (A′), for example.

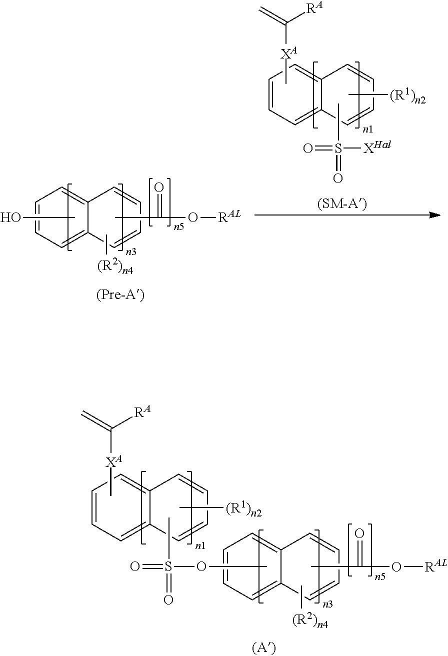

Herein n1 to n5, R^{A}, R¹, R² and R^{AL} are as defined above, and X^{Hal} is fluorine, chlorine, bromine or iodine.

The target compound having a sulfonate ester bond, i.e., monomer (A′) is obtained by reacting a reactant (Pre-A′) with a reactant (SM-A′), specifically the hydroxy group of reactant (Pre-A′) with the sulfonyl halide of reactant (SM-A′).

The reactants (Pre-A′) and (SM-A′) may be synthesized by well-known methods, or commercially available compounds may be used. The reaction may be performed by a well-known organic synthesis method. Specifically, reactant (Pre-A′) is dissolved in a solvent such as toluene, hexane, TIF, acetonitrile, or methylene chloride in the presence of an organic base such as triethylamine or pyridine, after which reactant (SM-A′) as such is added dropwise thereto or if reactant (SM-A′) is solid, it is diluted with a solvent similar to the reaction solvent and then added dropwise. For accelerating the reaction rate, 4-dimethylaminopyridine may be added. The reaction temperature is preferably 5 °C to nearly the boiling point of the solvent. While it is desirable in view of yield that the reaction time is determined by monitoring the progress of reaction by thin layer chromatography (TLC) or gas chromatography (GC) to drive the reaction to completion, the reaction time is typically about 1 to 24 hours. The monomer (A′) is recovered from the reaction mixture by ordinary aqueous workup. The monomer may be purified by conventional means such as distillation, chromatography or recrystallization, if necessary.

The above-mentioned preparation method is merely exemplary and the method of preparing the inventive monomer is not limited thereto.

The inventive monomer is structurally characterized in that it has an acid labile group attached to a hydroxy or carboxy group on aromatic ring and a polymerizable group which is introduced via a sulfonate ester or sulfonamide bond. In the exposed region, the acid labile group undergoes deprotection reaction with the aid of the generated acid, whereby an aromatic hydroxy or carboxy group is generated. In the EUV lithography of wavelength 13.5 nm, iodine generates secondary electrons upon EUV exposure because iodine is highly absorptive to EUV. This suggests that at least one iodine atom should preferably be on an aromatic ring in formula (A). That is, it is preferred in formula (A) that R¹ is iodine and n2 is 1, 2, 3 or 4, and/or R² is iodine and n3 is 1, 2, 3 or 4. Also, the polymerizable group which is introduced via a sulfonate ester or sulfonamide bond should preferably have a styrene or vinylnaphthalene structure. Since the polymerizable group of such structure is more robust than the polymerizable group of methacrylate ester, the polymer has a higher glass transition temperature (Tg). Owing to the interaction of aromatic rings within or between the polymer (π-π stacking effect), the polymer is arranged in order. This ensures that when a resist film is developed in a developer to form a small-size pattern, the resist pattern is resistant to collapse. The sulfonate ester or sulfonamide bond is highly resistant to alkaline hydrolysis, suggesting that in the case of positive resist using alkaline developer, when the resist film is patterned and developed in an alkaline developer, decomposition of the resist film in the unexposed region is suppressed, whereby pattern collapse is restrained. Patent Document 6 describes an analogous structure, a monomer having an aryl ester bond. Since the aryl ester is less resistant to hydrolysis than the alkyl ester, partial hydrolysis occurs during alkaline development, incurring pattern collapse. In the etching step following the small-size pattern formation, the direct bond of an aromatic ring to the backbone exerts superior etching resistance. Due to the synergy of these effects, a polymer obtained from the inventive monomer is useful as one component of a chemically amplified resist composition, especially of positive tone, which exhibits a high dissolution contrast and forms a pattern having reduced LWR (of line pattern), improved CDU (of hole pattern), collapse resistance, and etching resistance.

### [Polymer]

In another aspect, the invention provides a polymer comprising repeat units derived from the monomer having formula (A), also referred to as repeat units A. Repeat unit A is represented by the formula (Aa):

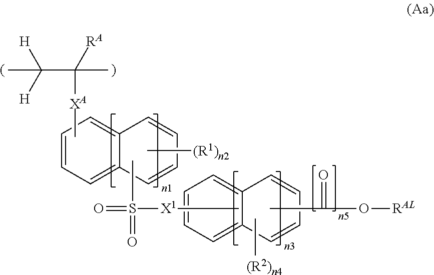

wherein n1 to n5, R^{A}, X^{A}, X¹, R¹, R² and R^{AL} are as defined above.

The polymer may contain repeat units A of one type or two or more types.

The polymer may further comprise repeat units of at least one type selected from repeat units having the formula (a1), repeat units having the formula (a2), and repeat units having the formula (a3), which are also referred to as repeat units (a1), (a2) and (a3).

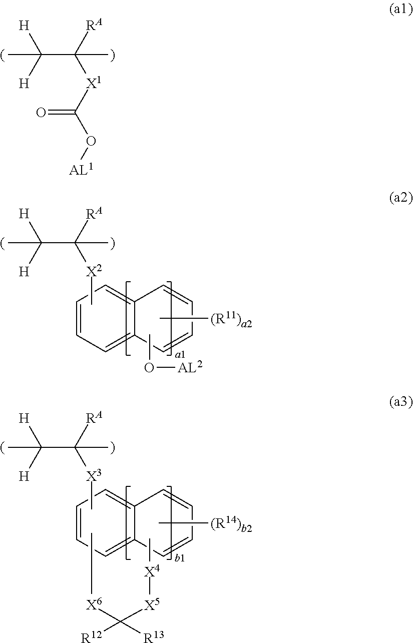

In formulae (a1) and (a2), R^{A} is each independently hydrogen, fluorine, methyl or trifluoromethyl.

In formula (a1), X¹ is a single bond, phenylene group, naphthylene group or *—C(═O)—O—X¹¹— wherein * designates a point of attachment to the carbon atom in the backbone. The phenylene and naphthylene groups may be substituted with hydroxy, nitro, cyano, a C₁-C₁₀ saturated hydrocarbyl moiety which may contain fluorine, C₁-C₁₀ saturated hydrocarbyloxy moiety which may contain fluorine, or halogen. X¹¹ is a C₁-C₁₀ saturated hydrocarbylene group, phenylene group or naphthylene group. The saturated hydrocarbylene group may contain hydroxy, ether bond, ester bond or lactone ring.

In formula (a2), X² is a single bond, *—C(═O)—O— or *—C(═O)—N(H)— wherein * designates a point of attachment to the carbon atom in the backbone. R¹¹ is halogen, cyano, hydroxy, nitro, pentafluorosulfanyl, a C₁-C₂₀ hydrocarbyl group which may contain a heteroatom, C₁-C₂₀ hydrocarbyloxy group which may contain a heteroatom, C₂-C₂₀ hydrocarbylcarbonyl group which may contain a heteroatom, C₂-C₂₀ hydrocarbylcarbonyloxy group which may contain a heteroatom, or C₂-C₂₀ hydrocarbyloxycarbonyl group which may contain a heteroatom, and a2 is 0, 1, 2, 3 or 4, preferably 0 or 1. The subscript a1 is 0 or 1. The relevant structure is a benzene ring when a1=0 and a naphthalene ring when a1=1. From the aspect of solvent solubility, the benzene ring corresponding to a1=0 is preferred. When a2 is 2, 3 or 4, a plurality of R¹¹ may be identical or different.

In formulae (a1) and (a2), AL¹ and AL² are each independently an acid labile group. The acid labile group may be selected from a variety of such groups, for example, those groups described in JP-A 2013-080033 (U.S. Pat. No. 8,574,817) and JP-A 2013-083821 (U.S. Pat. No. 8,846,303).

Typical of the acid labile group are groups of the following formulae (AL-3) to (AL-5).

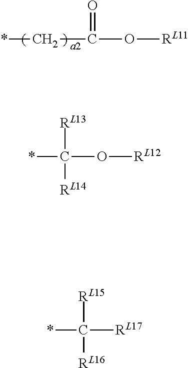

In formulae (AL-3) and (AL-4), R^{L11} and R^{L12} are each independently a C₁-C₄₀ hydrocarbyl group which may contain a heteroatom such as oxygen, sulfur, nitrogen or fluorine. The hydrocarbyl group may be saturated or unsaturated and straight, branched or cyclic. Inter alia, C₁-C₂₀ hydrocarbyl groups are preferred.

In formula (AL-3), a3 is an integer of 0 to 10, preferably 1, 2, 3, 4 or 5.

In formula (AL-4), R^{L13} and R^{L14} are each independently hydrogen or a C₁-C₂₀ hydrocarbyl group which may contain a heteroatom such as oxygen, sulfur, nitrogen or fluorine. The hydrocarbyl group may be saturated or unsaturated and straight, branched or cyclic. Any two of R^{L12}, R^{L13} and R^{L14} may bond together to form a C₃-C₂₀ ring with the carbon atom or carbon and oxygen atoms to which they are attached. The ring preferably contains 4 to 16 carbon atoms and is typically alicyclic.

In formula (AL-5), R^{L15}, R^{L16} and R^{L17} are each independently a C₁-C₂₀ hydrocarbyl group which may contain a heteroatom such as oxygen, sulfur, nitrogen or fluorine. The hydrocarbyl group may be saturated or unsaturated and straight, branched or cyclic. Any two of R^{L15}, R^{L16} and R^{L17} may bond together to form a C₃-C₂₀ ring with the carbon atom to which they are attached. The ring preferably contains 4 to 16 carbon atoms and is typically alicyclic.

Other examples of the acid labile group include those groups described in JP-A 2023-123222, paragraphs [0064]-[0068] (WO 2023/163008) and JP 7492842, paragraphs [0013]-[0014] (U.S. Pat. No. 11,548,961). After acid elimination reaction, they produce conjugated olefins or acrylate derivatives which serve as a driving force to run the reaction forward.

Examples of the repeat unit (a1) are shown below, but not limited thereto. Herein R^{A} and AL¹ are as defined above.

[chemical structure]

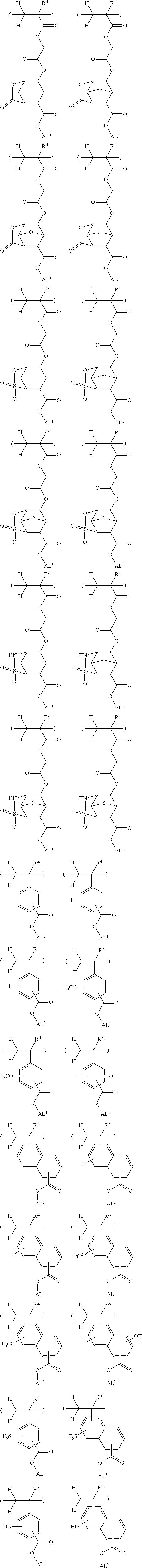

Examples of the repeat unit (a2) are shown below, but not limited thereto. Herein R^{A} and AL² are as defined above.

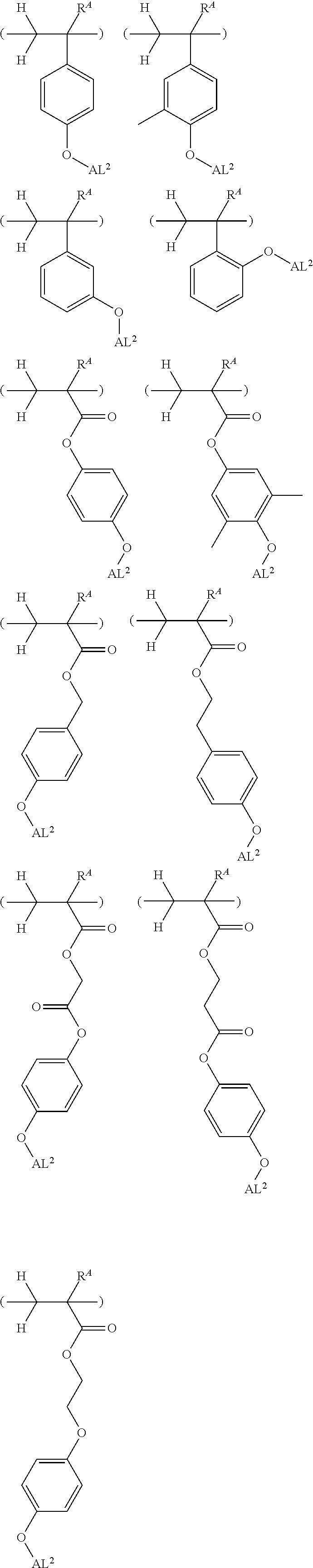

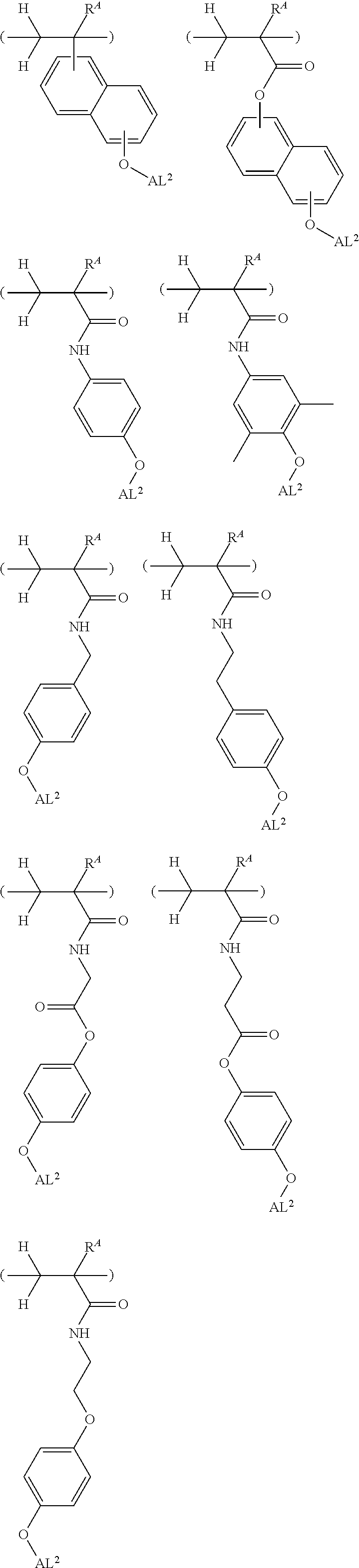

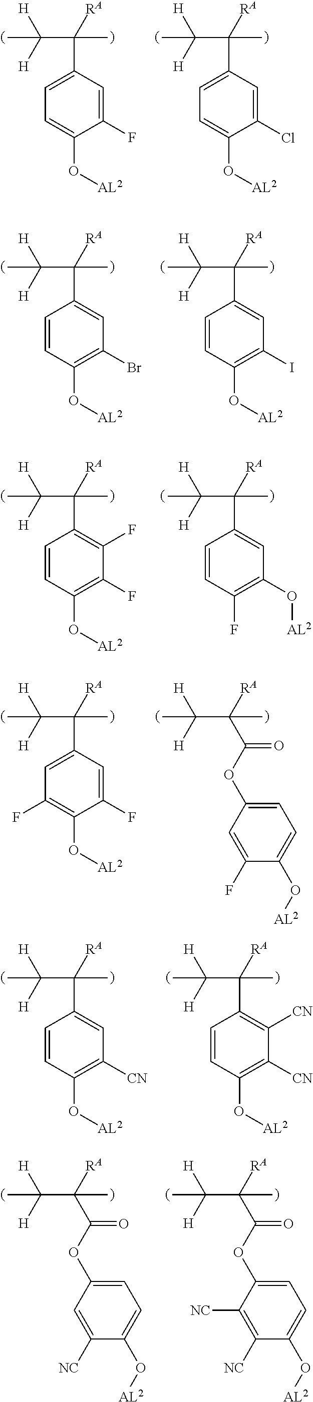

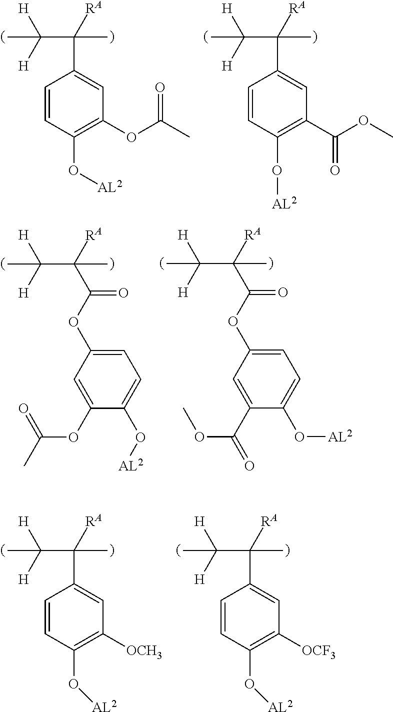

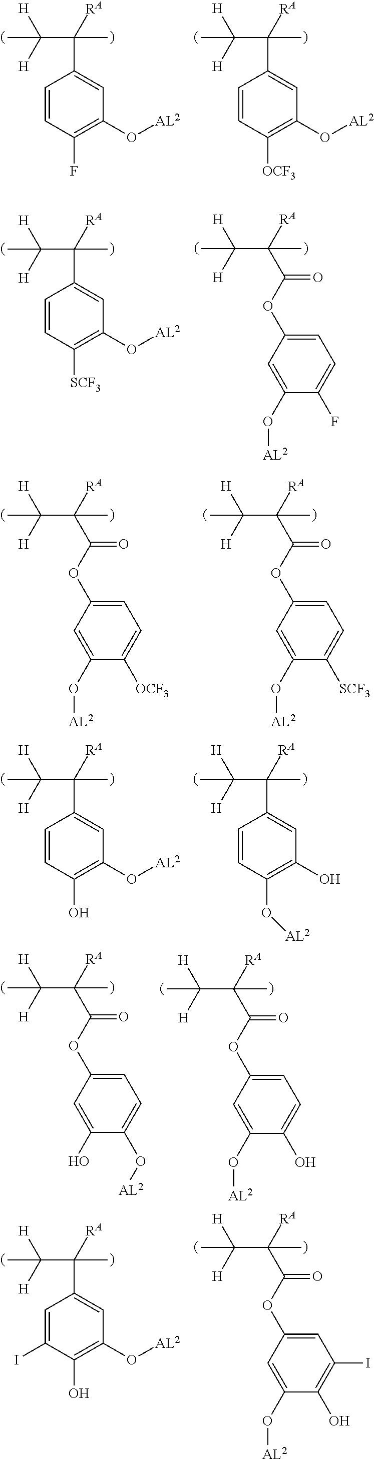

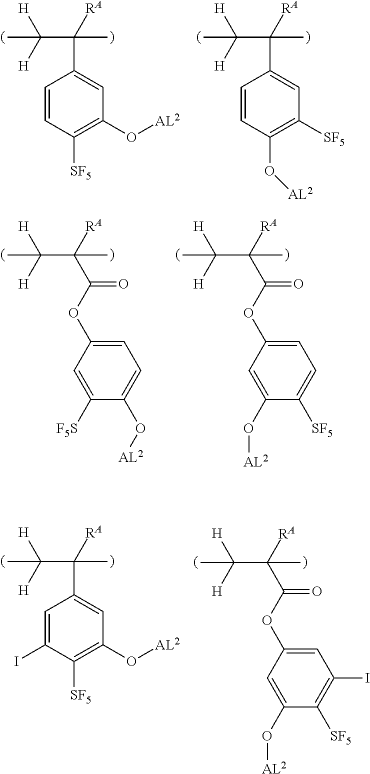

In formula (a3), b1 is 0 or 1. The relevant structure is a benzene ring when b1=0 and a naphthalene ring when b1=1. From the aspect of solvent solubility, the benzene ring corresponding to b1=0 is preferred. The subscript b2 is 0, 1, 2 or 3 when b1=0 and 0, 1, 2, 3, 4 or 5 when b1=1. It is preferred from the aspect of reactant availability that b2 be 0, 1, 2 or 3, more preferably 0, 1 or 2.

In formula (a3), R^{A} is hydrogen, fluorine, methyl or trifluoromethyl, preferably hydrogen or methyl, most preferably hydrogen.

In formula (a3), X³ is a single bond, *—C(═O)—O— or *—C(═O)—N(H)—, wherein * designates a point of attachment to the carbon atom in the backbone. X³ is preferably a single bond or *—C(═O)—O—, more preferably a single bond.

In formula (a3), X⁴ is a single bond, C₁-C₄ aliphatic hydrocarbylene group, carbonyl, sulfonyl or a group obtained by combining the foregoing. It is preferred from the aspect of reactant availability that X⁴ be a single bond, carbonyl or sulfonyl. It is more preferred from the aspect of a polar group created after reaction that X⁴ be a single bond or carbonyl.

In formula (a3), X⁵ and X⁶ are each independently oxygen or sulfur, with the proviso that X⁴ and X⁶ are attached to adjacent carbon atoms on the aromatic ring. X⁵ and X⁶ may be the same or different. It is preferred from the aspect of reactivity that both X⁵ and X⁶ be oxygen.

In formula (a3), R¹² and R¹³ are each independently hydrogen or a C₁-C₂₀ hydrocarbyl group which may contain a heteroatom. The hydrocarbyl group may be saturated or unsaturated and straight, branched or cyclic. Examples thereof include C₁-C₂₀ alkyl groups such as methyl, ethyl, n-propyl, isopropyl, n-butyl, isobutyl, sec-butyl, tert-butyl, n-pentyl, n-hexyl, n-octyl, n-nonyl, n-decyl, undecyl, dodecyl, tridecyl, tetradecyl, pentadecyl, heptadecyl, octadecyl, nonadecyl, and icosyl; C₃-C₂₀ cyclic saturated hydrocarbyl groups such as cyclopropyl, cyclopentyl, cyclohexyl, cylopropylmethyl, 4-methylcyclohexyl, cyclohexylmethyl, norbornyl, and adamantyl; C₂-C₂₀ alkenyl groups such as vinyl, 1-propenyl, 2-propenyl, butenyl, and hexenyl; C₃-C₂₀ cyclic unsaturated hydrocarbyl groups such as cyclohexenyl; C₆-C₂₀ aryl groups such as phenyl and naphthyl; C₇-C₂₀ aralkyl groups such as benzyl, 1-phenylethyl, and 2-phenylethyl, and combinations thereof. In the hydrocarbyl group, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy moiety, cyano moiety, fluorine, chlorine, bromine, iodine, carbonyl moiety, ether bond, ester bond, sulfonate ester bond, carbonate bond, lactone ring, sultone ring, carboxylic anhydride (—C(═O)—O—C(═O)—) or haloalkyl moiety.

R¹² and R¹³ may bond together to form a ring with the carbon atom to which they are attached. Examples of the ring include cyclopropane, cyclobutane, cyclopentane, cyclohexane, norbornane, and adamantane rings. In the ring, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the ring may contain a hydroxy moiety, fluorine, chlorine, bromine, iodine, cyano moiety, carbonyl moiety, ether bond, ester bond, sulfonate ester bond, carbonate bond, lactone ring, sultone ring, carboxylic anhydride (—C(═O)—O—C(═O)—) or haloalkyl moiety.

In formula (a3), R¹⁴ is halogen, hydroxy, cyano, nitro, pentafluorosulfanyl, a C₁-C₂₀ hydrocarbyl group which may contain a heteroatom, C₁-C₂₀ hydrocarbyloxy group which may contain a heteroatom, C₂-C₂₀ hydrocarbyloxycarbonyl group which may contain a heteroatom, C₁-C₂₀ hydrocarbylthio group which may contain a heteroatom, or —N(R^{14A})(R^{14B}). R^{14A} and R^{14B} are each independently hydrogen or a C₁-C₆ hydrocarbyl group. Suitable halogen atoms include fluorine, chlorine, bromine and iodine, with fluorine and iodine being preferred. The hydrocarbyl group and hydrocarbyl moiety in the hydrocarbyloxy, hydrocarbyloxycarbonyl, and hydrocarbylthio groups may be saturated or unsaturated and straight, branched or cyclic. Examples thereof are as exemplified above for the hydrocarbyl groups R¹² and R¹³. In the hydrocarbyl group, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy moiety, cyano moiety, fluorine, chlorine, bromine, iodine, carbonyl moiety, ether bond, ester bond, sulfonate ester bond, carbonate bond, lactone ring, sultone ring, carboxylic anhydride (—C(═O)—O—C(═O)—) or haloalkyl moiety. A plurality of R¹⁴ may be identical or different when b2 is 2 or more.

When b2 is 2 or more, a plurality of R¹⁴ may bond together to form a ring with carbon atoms in the aromatic ring to which they are attached. Examples of the ring include cyclopropane, cyclobutane, cyclopentane, cyclohexane, norbornane, and adamantane rings. In the ring, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the ring may contain a hydroxy moiety, fluorine, chlorine, bromine, iodine, cyano moiety, carbonyl moiety, ether bond, ester bond, sulfonic ester bond, carbonate bond, lactone ring, sultone ring, carboxylic anhydride (—C(═O)—O—C(═O)—) or haloalkyl moiety.

Examples of repeat unit (a3) are shown below, but not limited thereto. Herein R^{A} is as defined above. The positions of attachment of substituent groups on the aromatic ring are interchangeable.

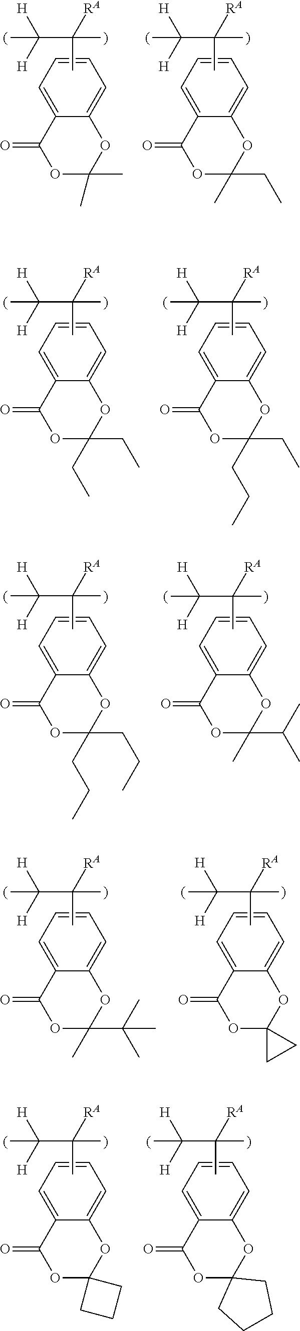

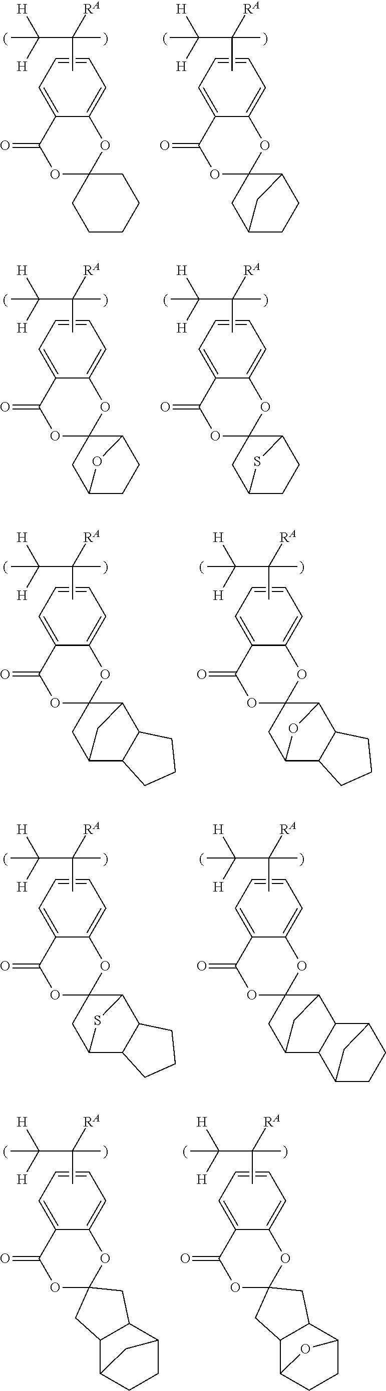

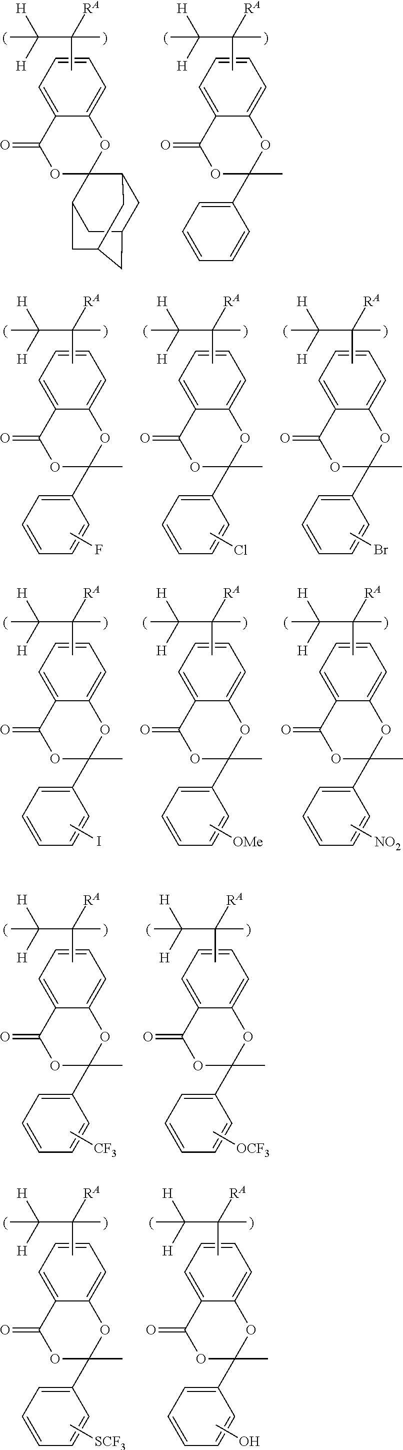

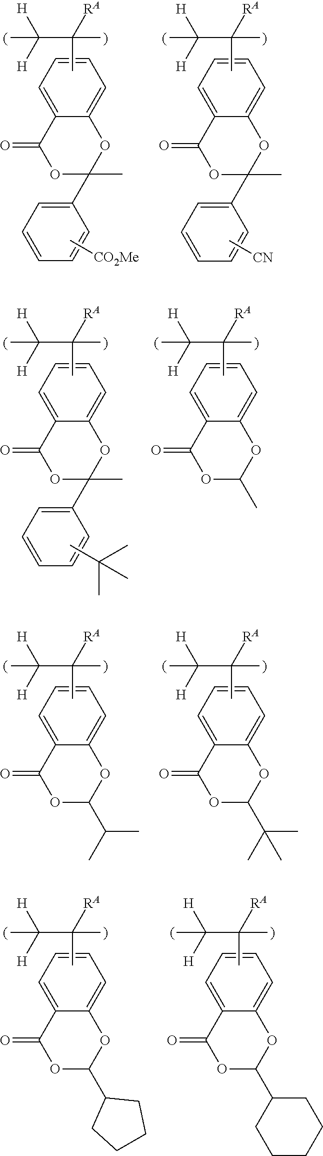

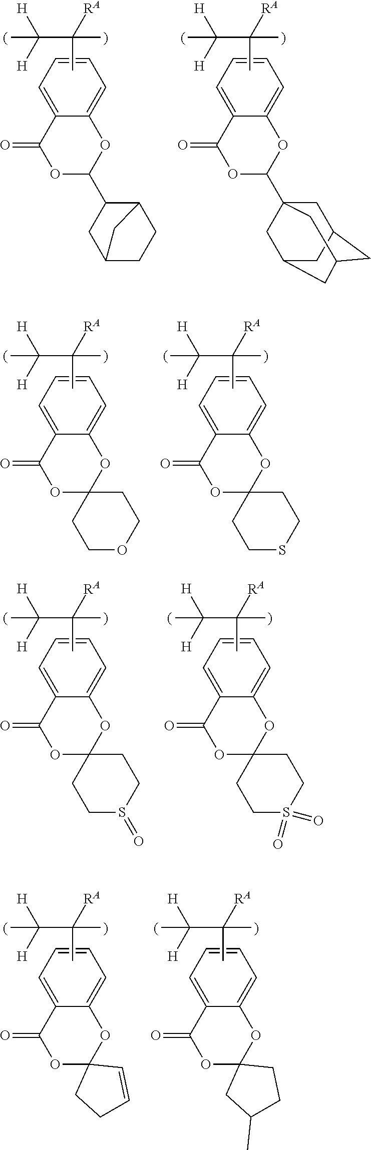

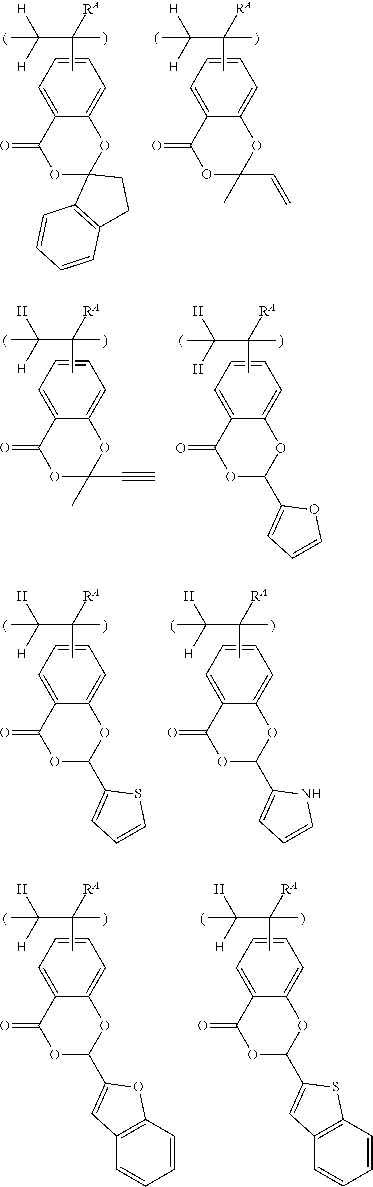

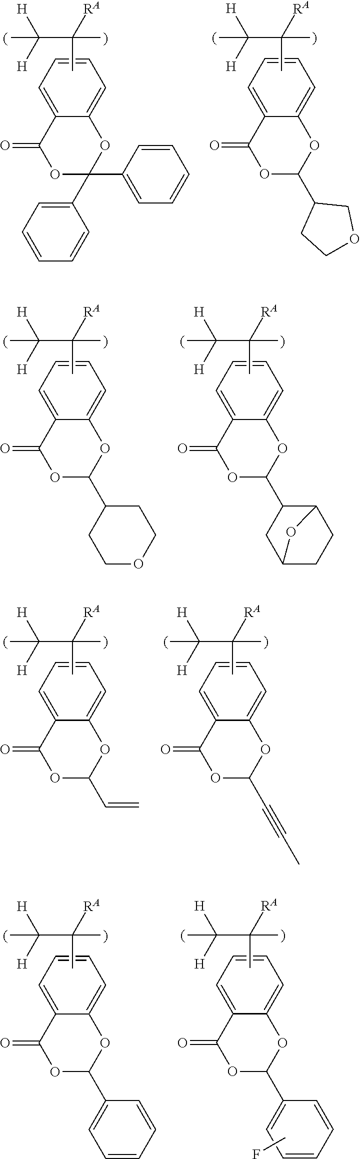

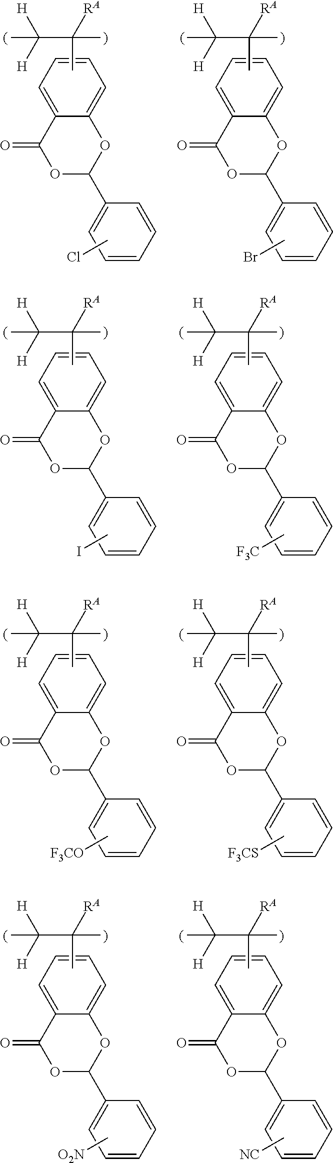

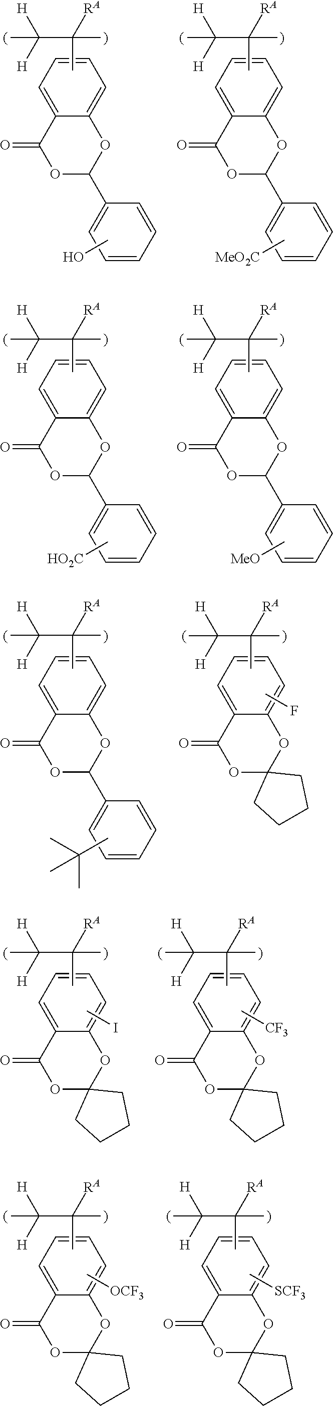

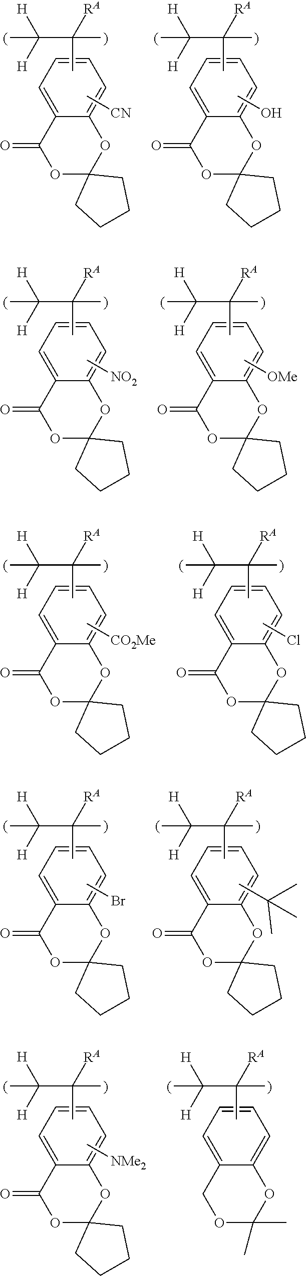

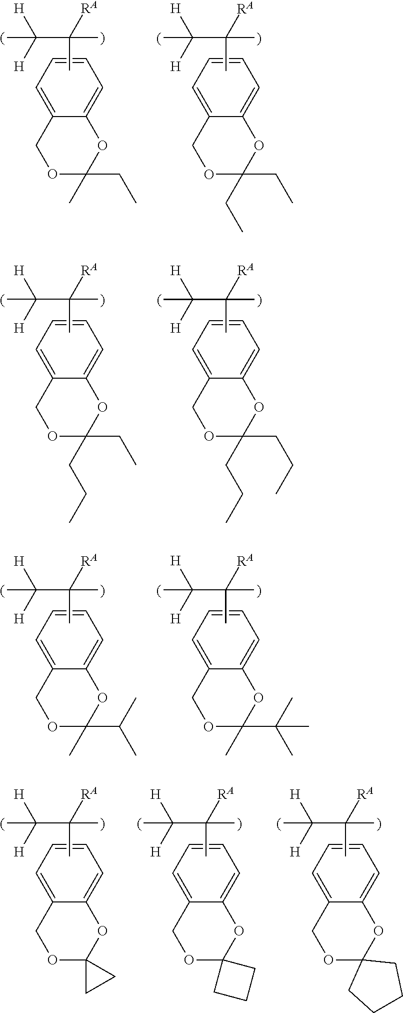

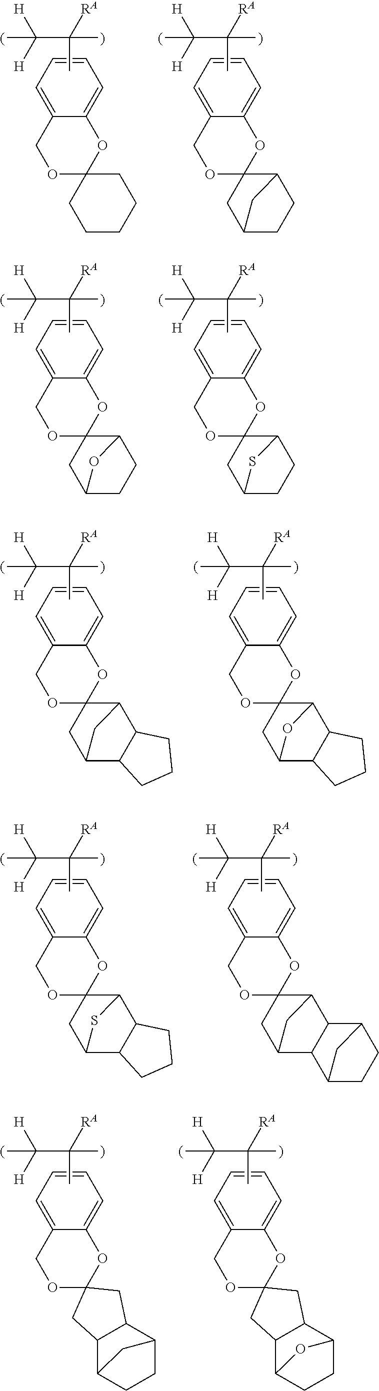

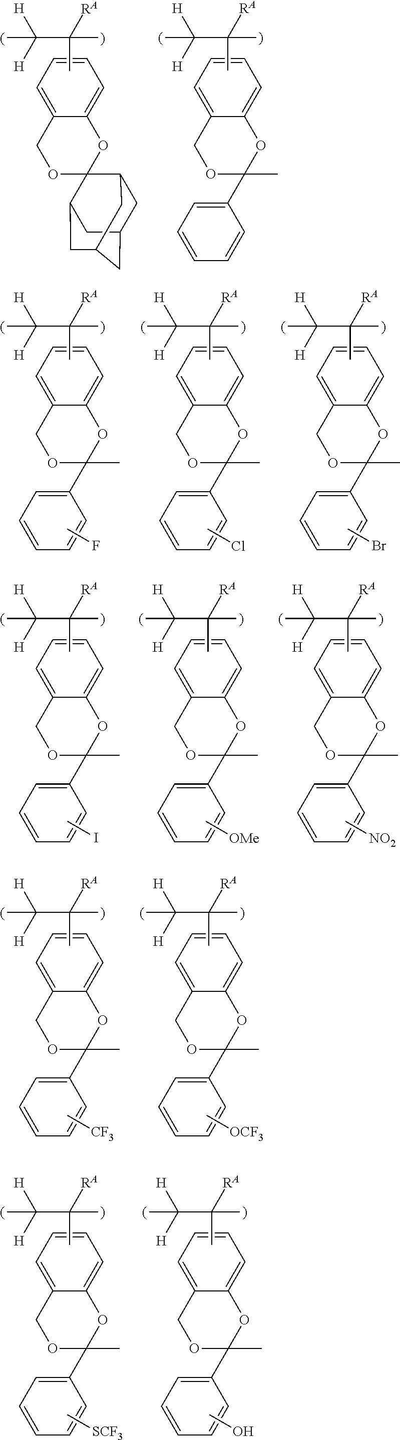

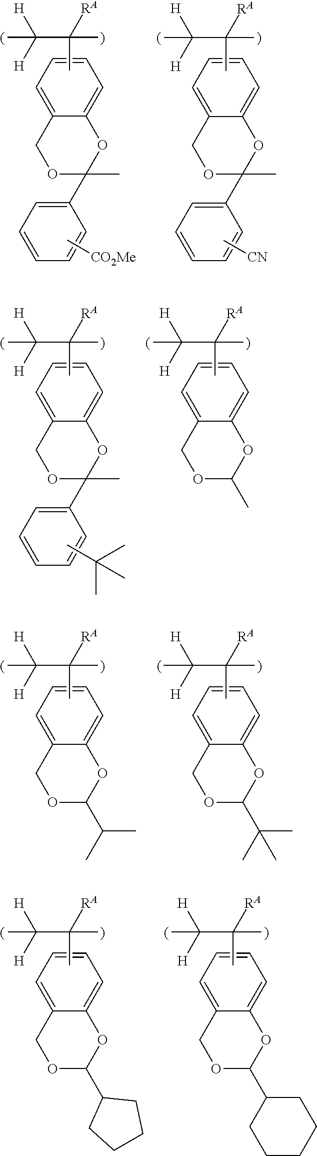

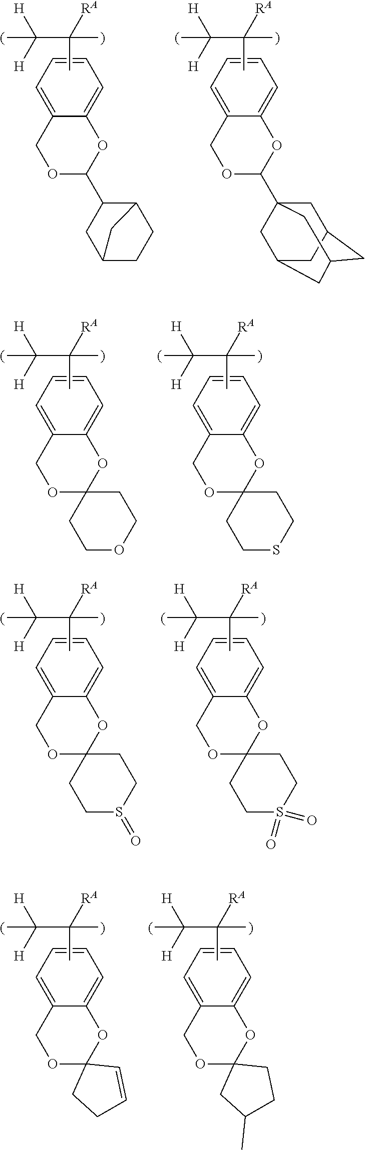

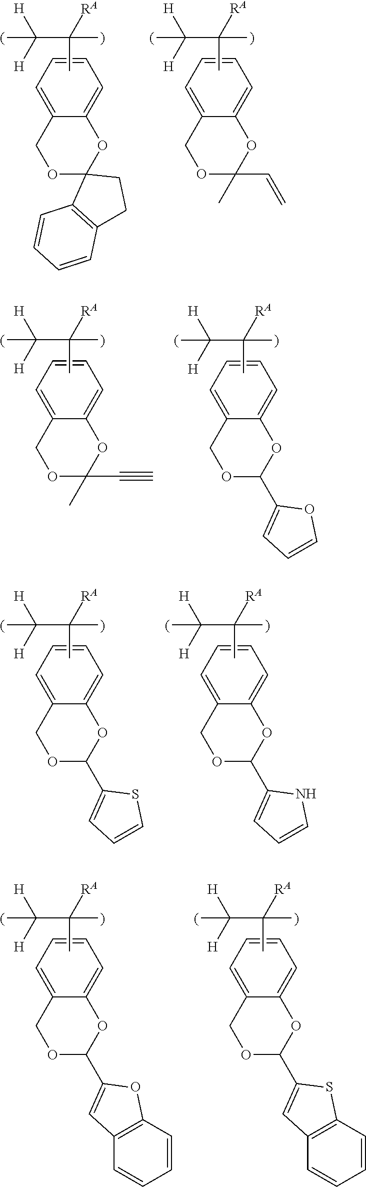

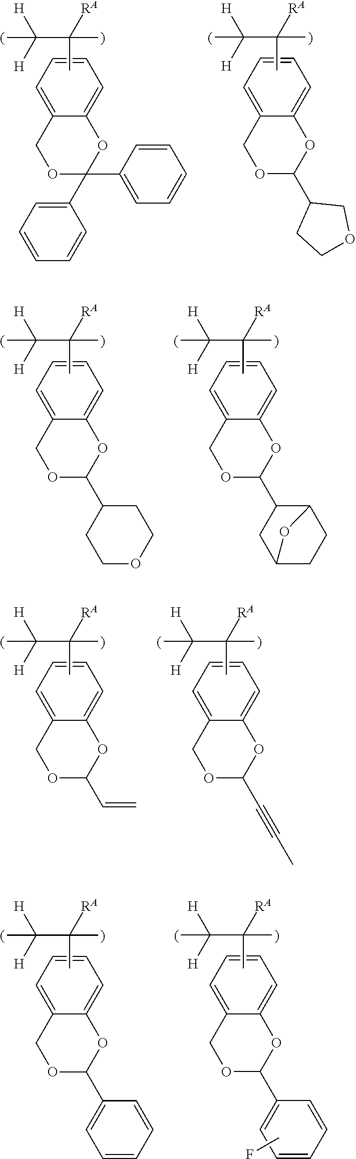

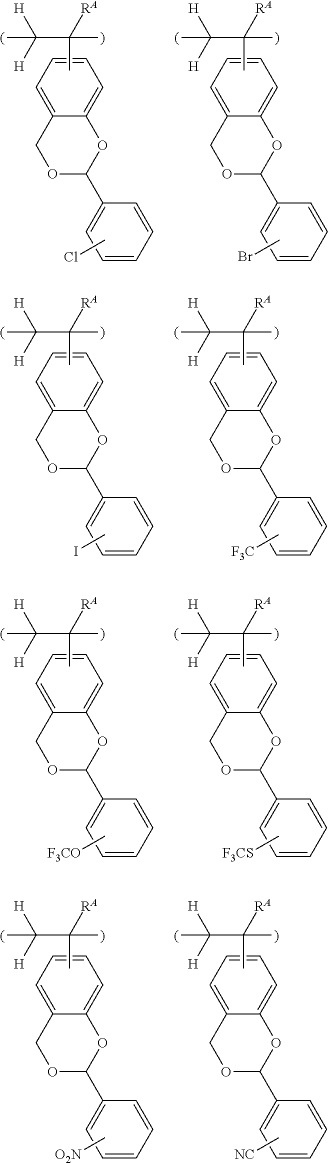

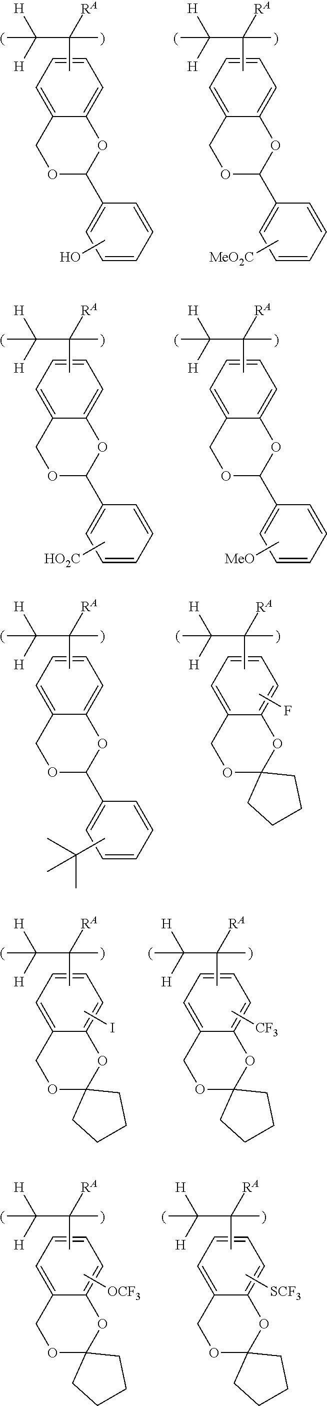

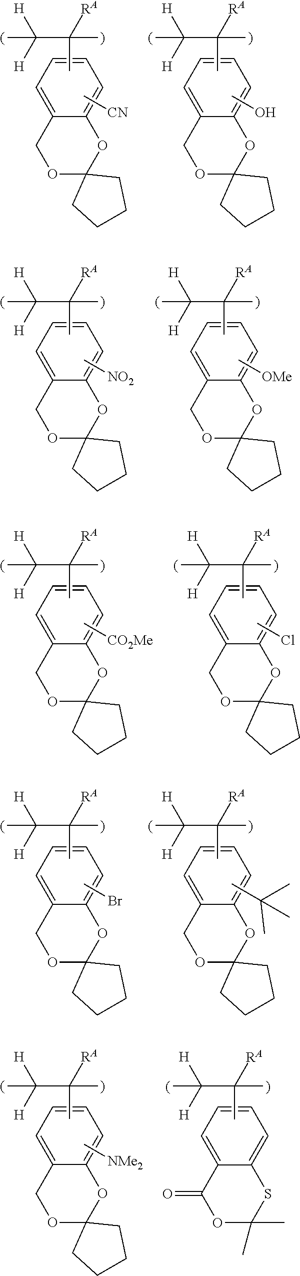

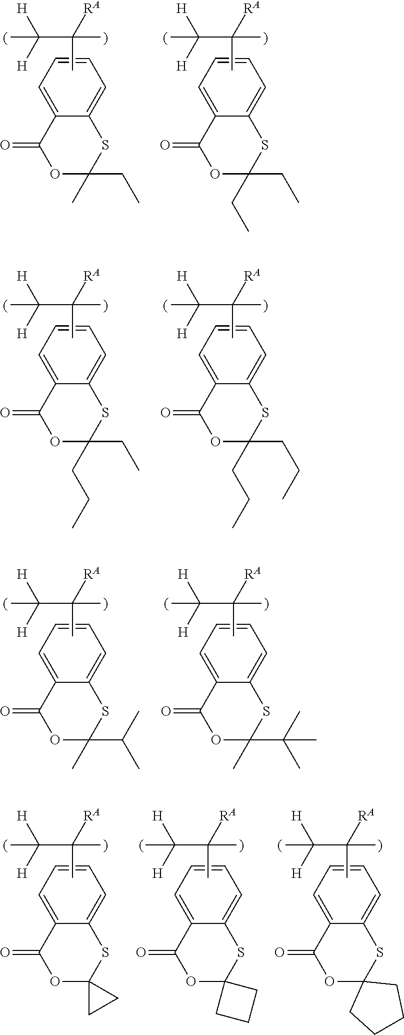

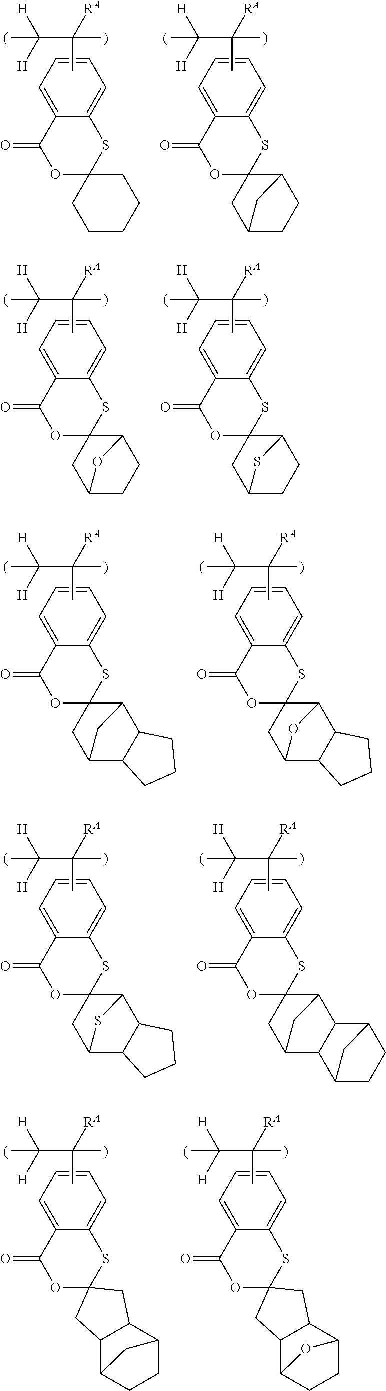

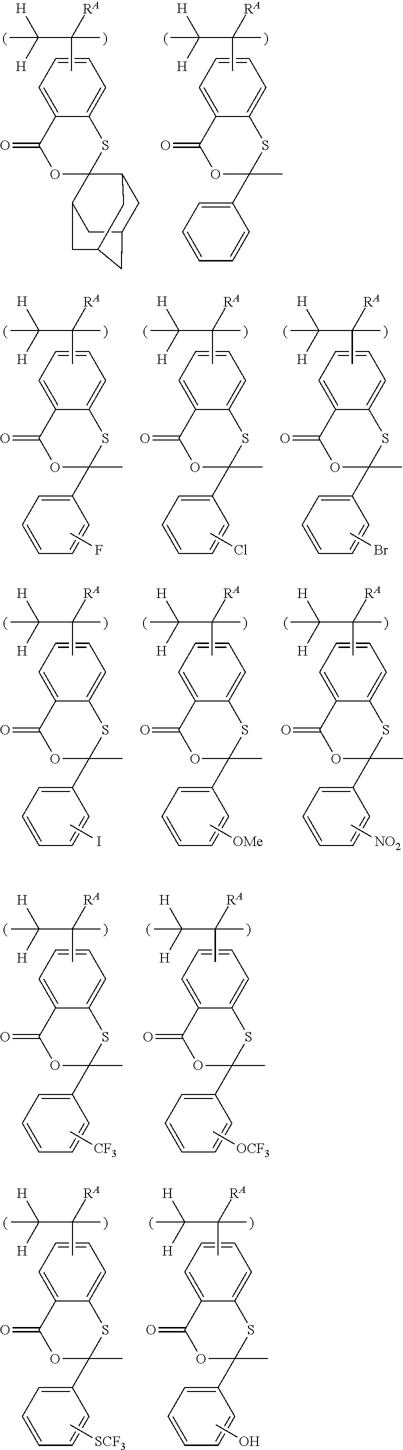

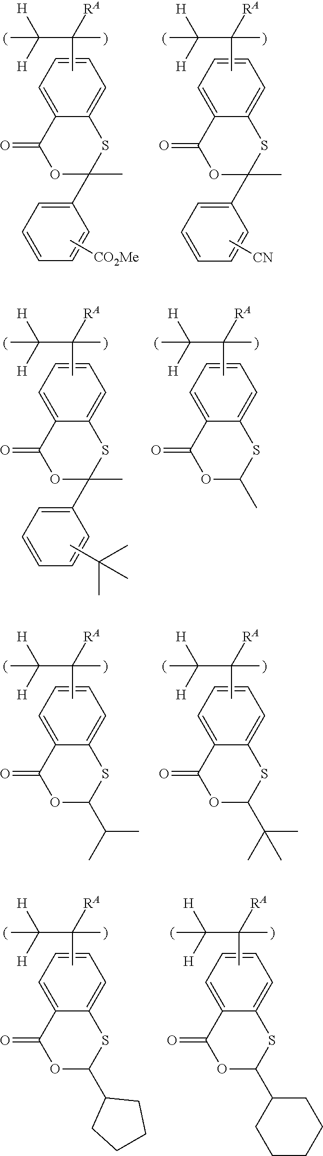

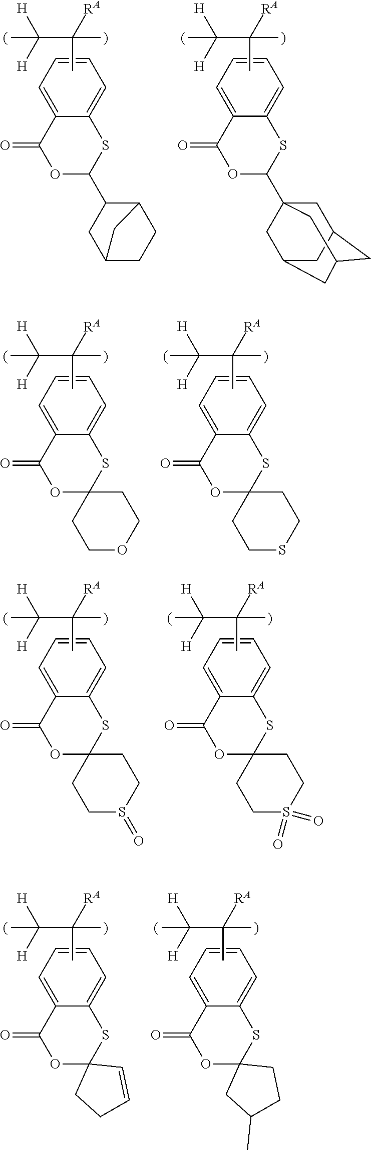

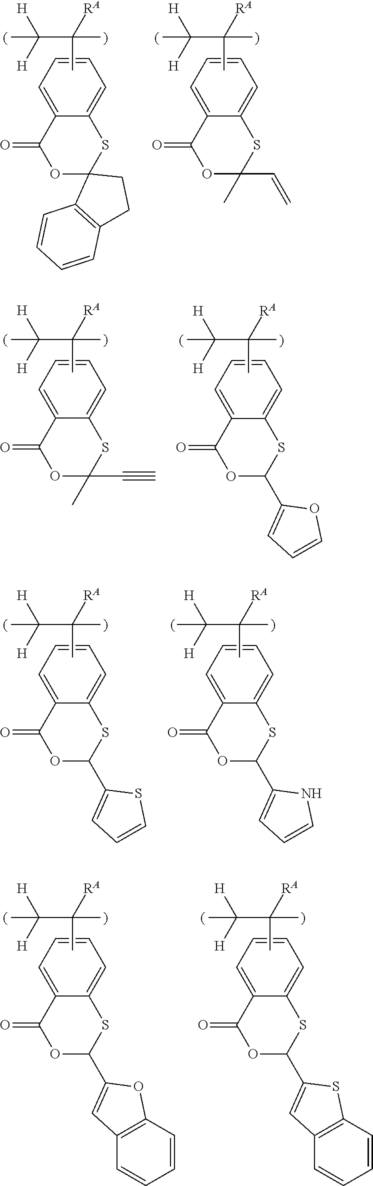

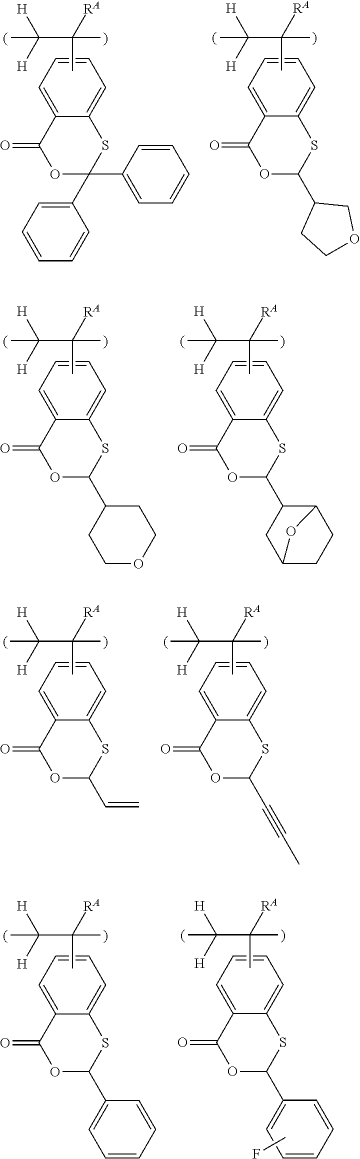

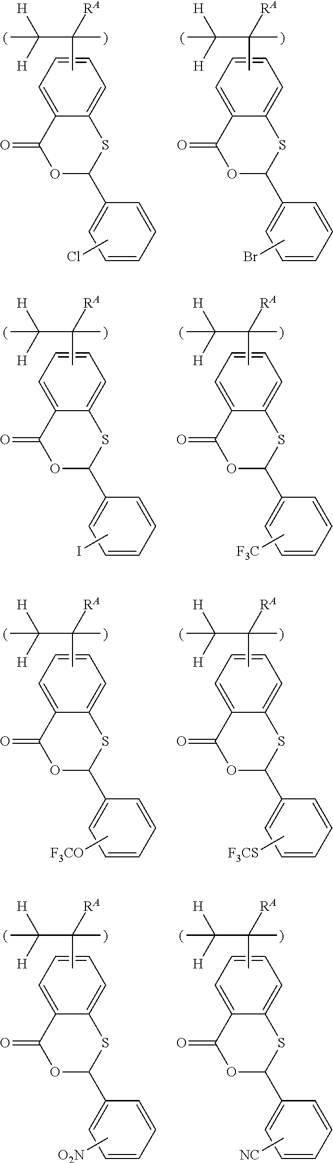

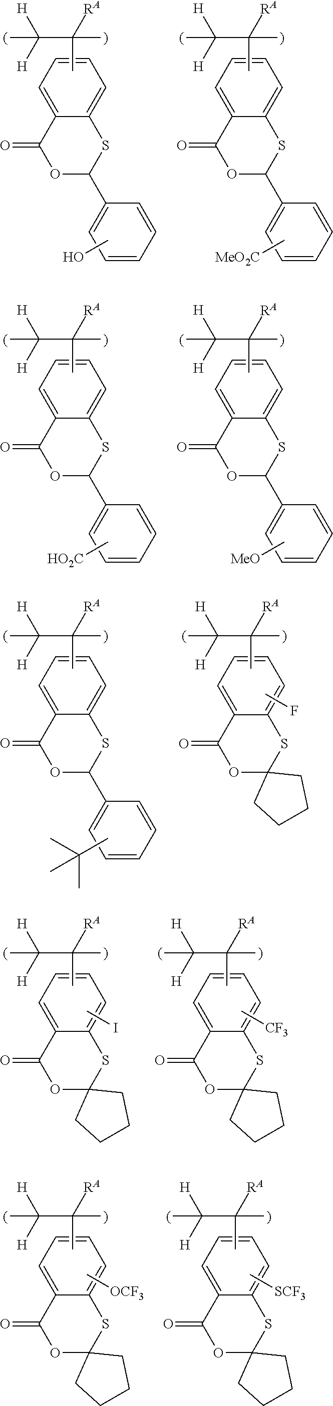

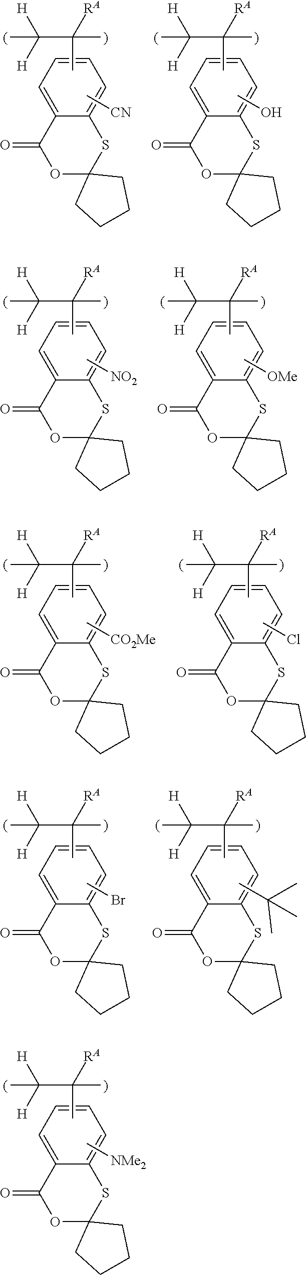

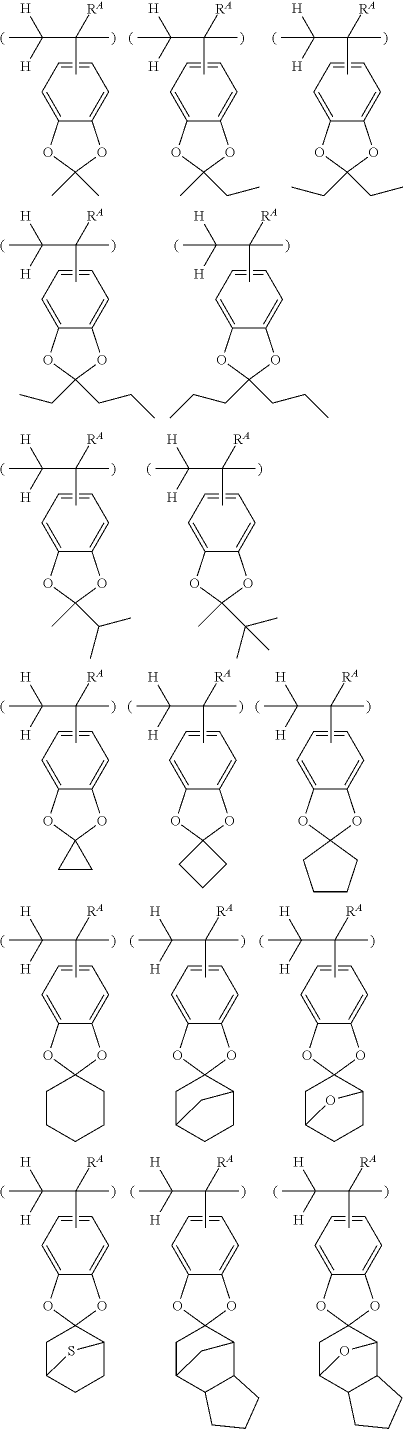

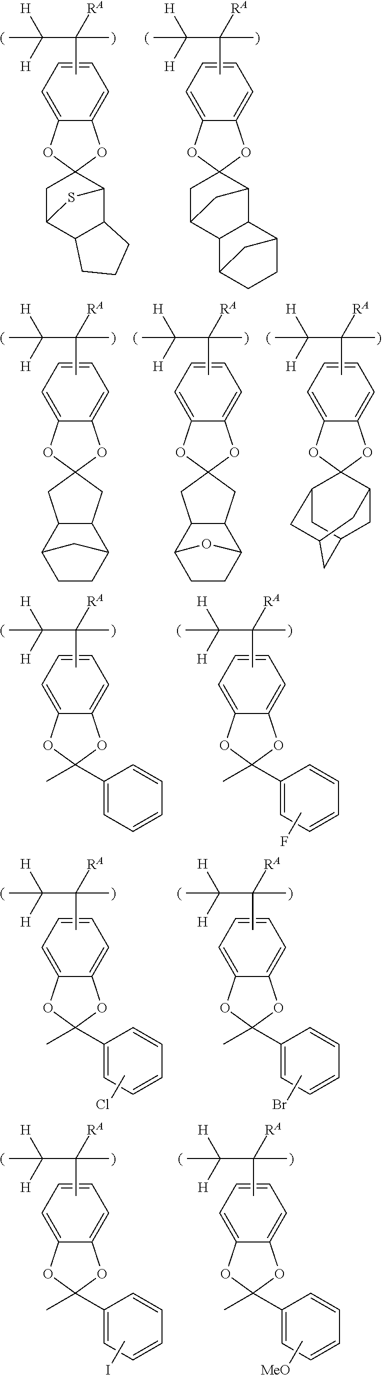

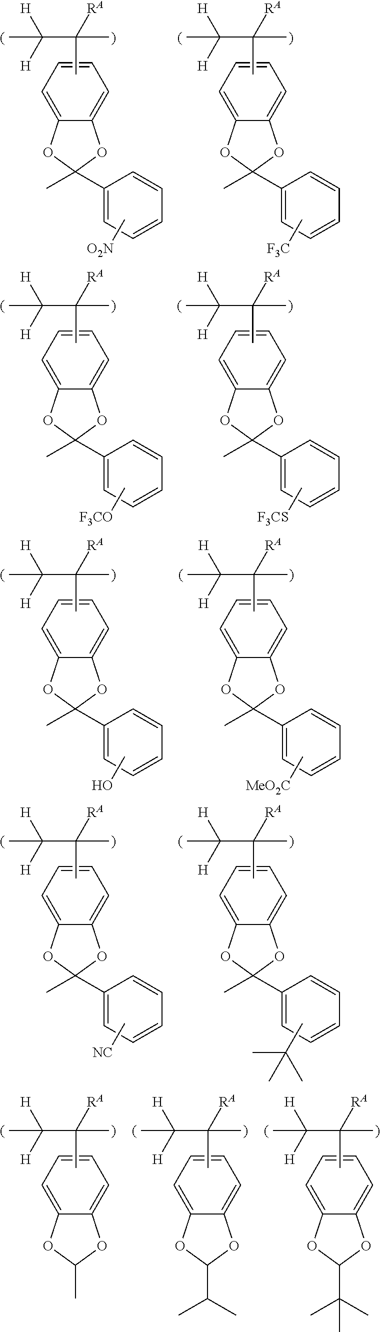

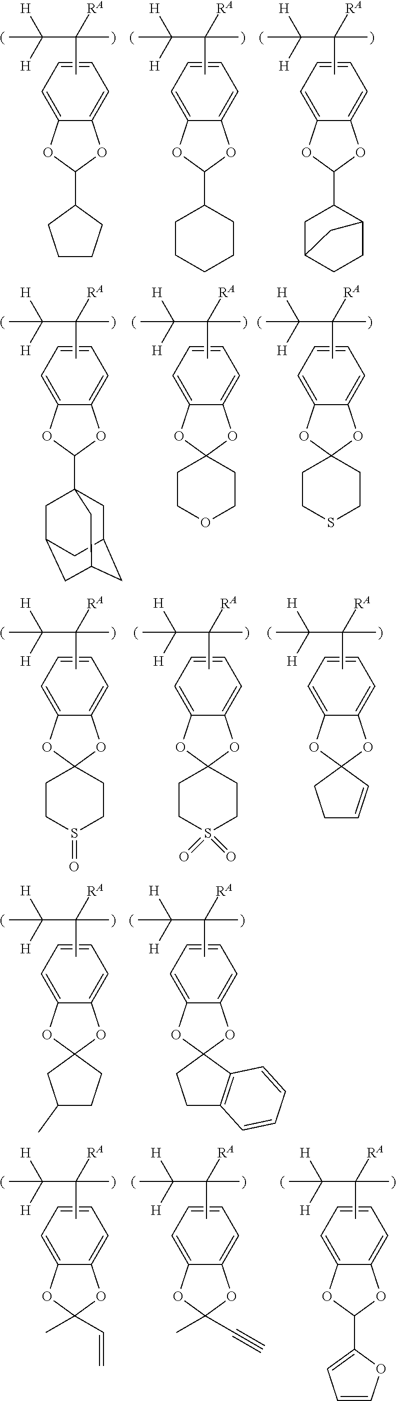

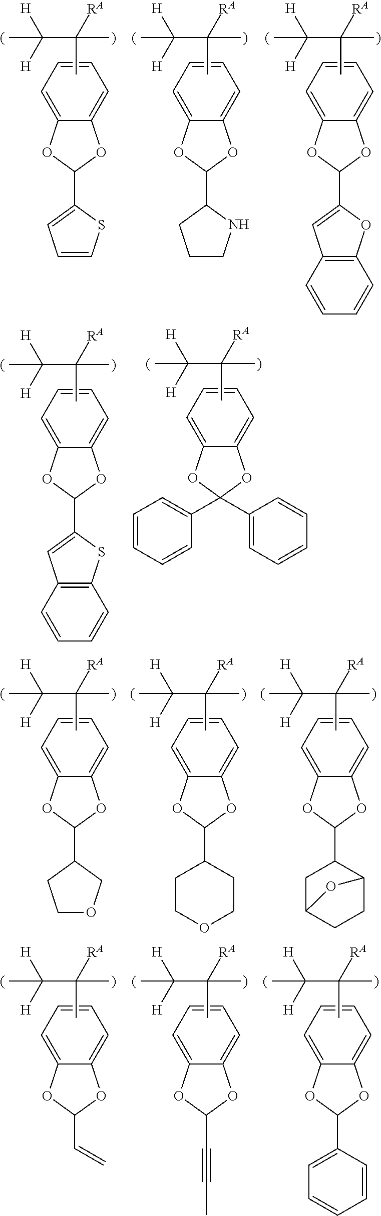

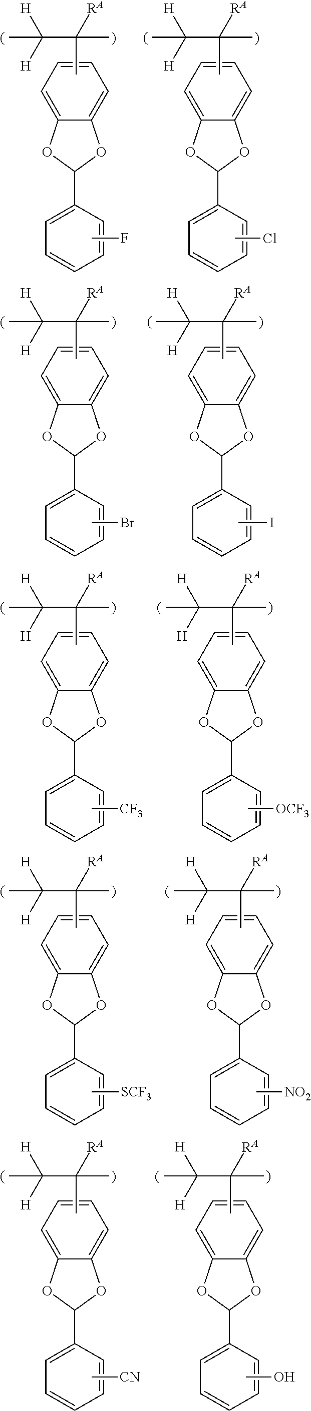

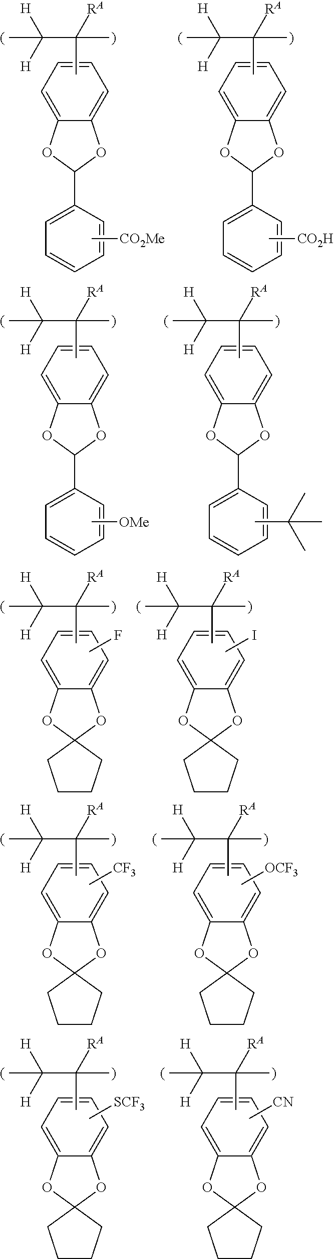

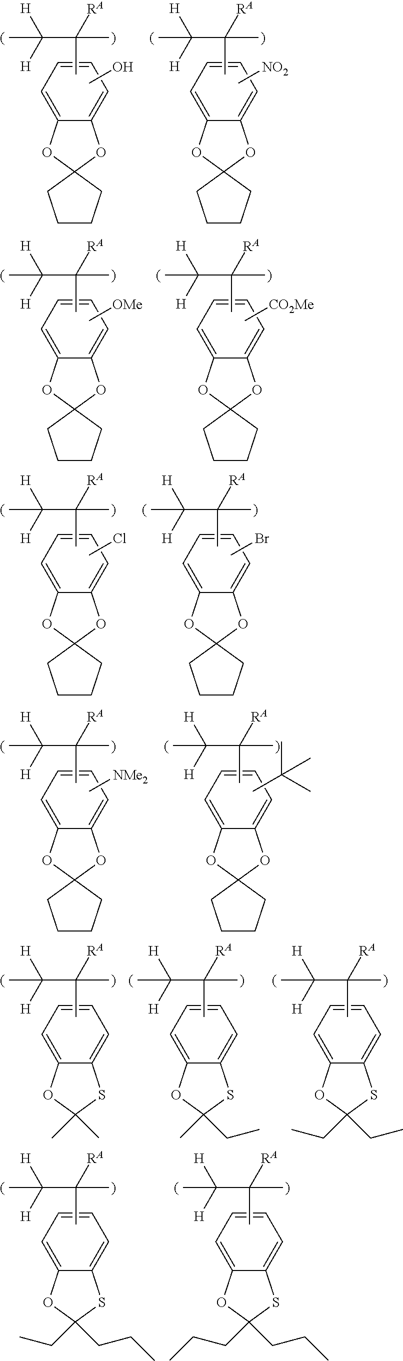

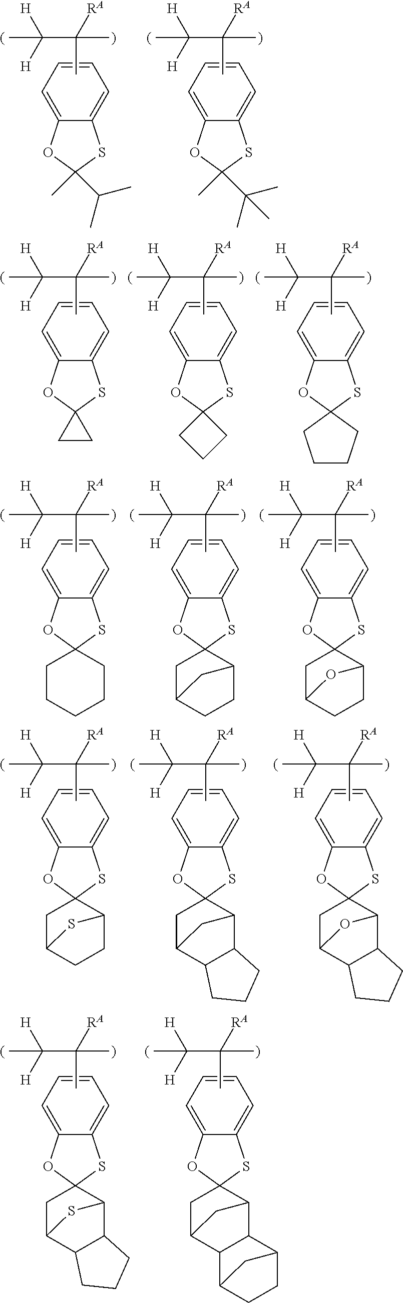

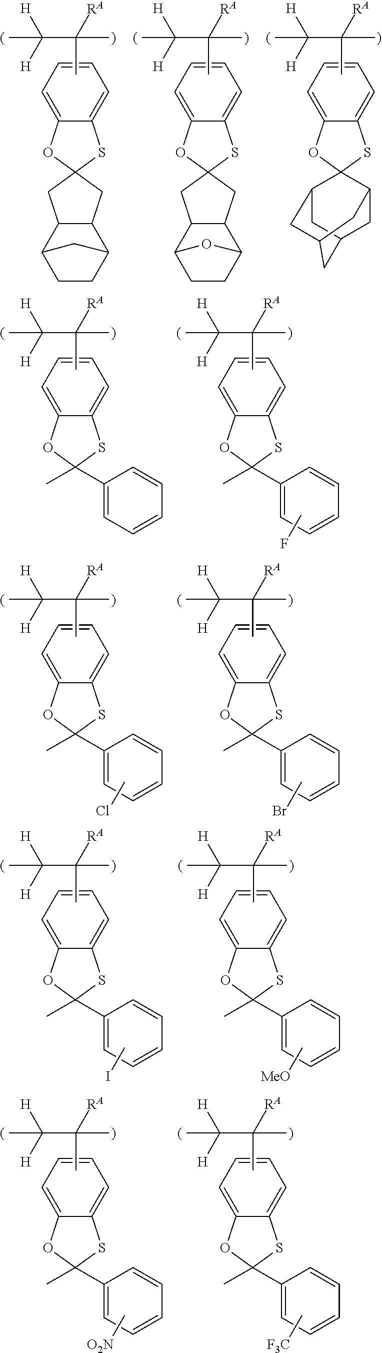

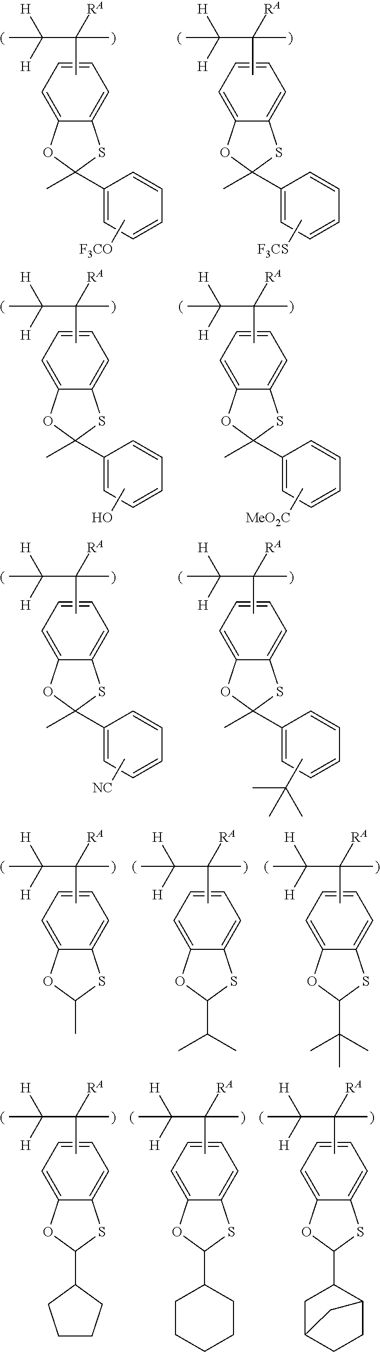

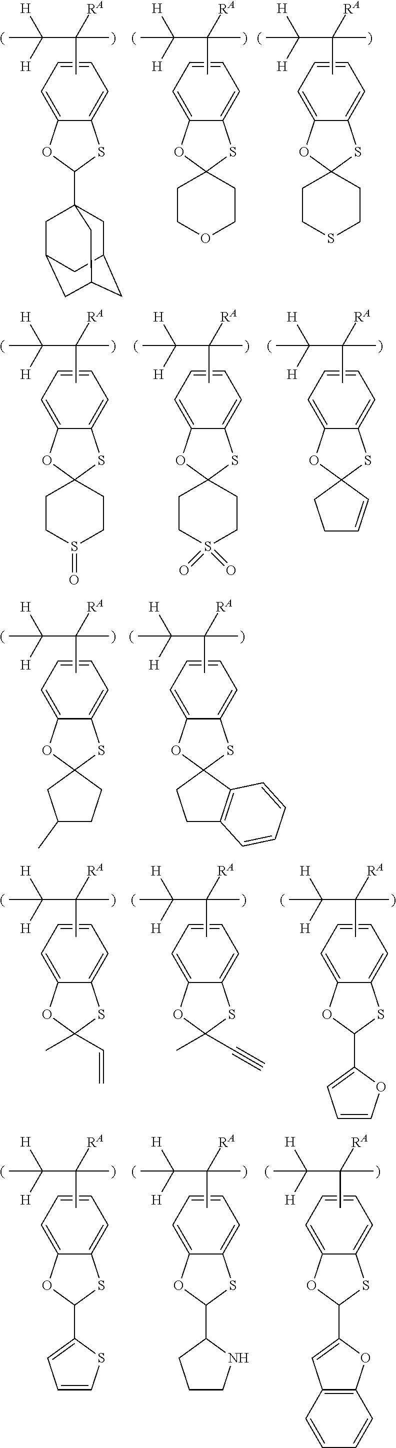

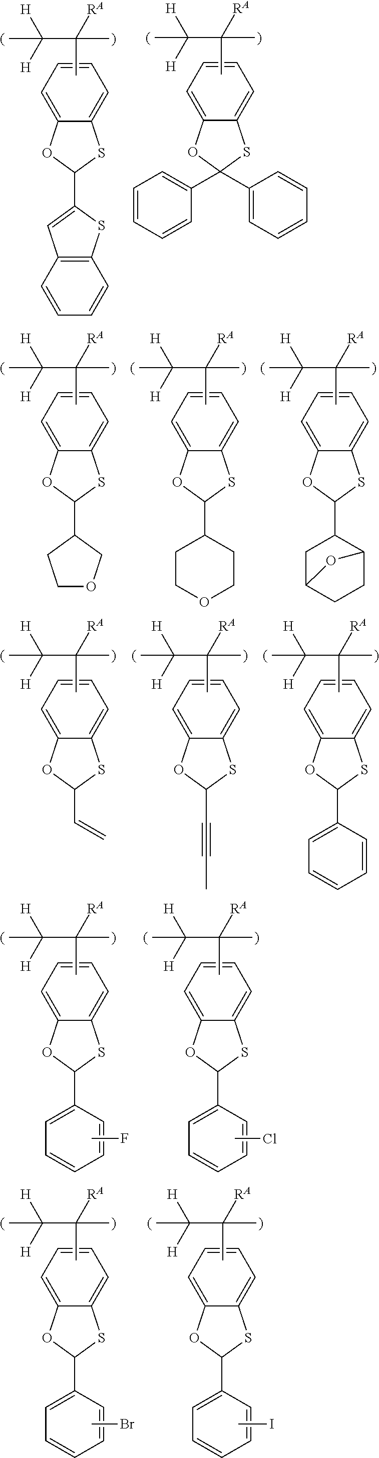

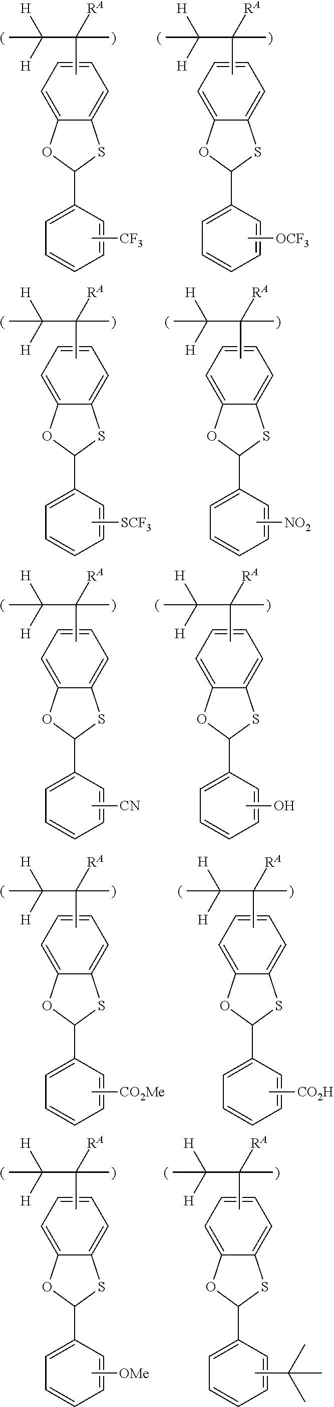

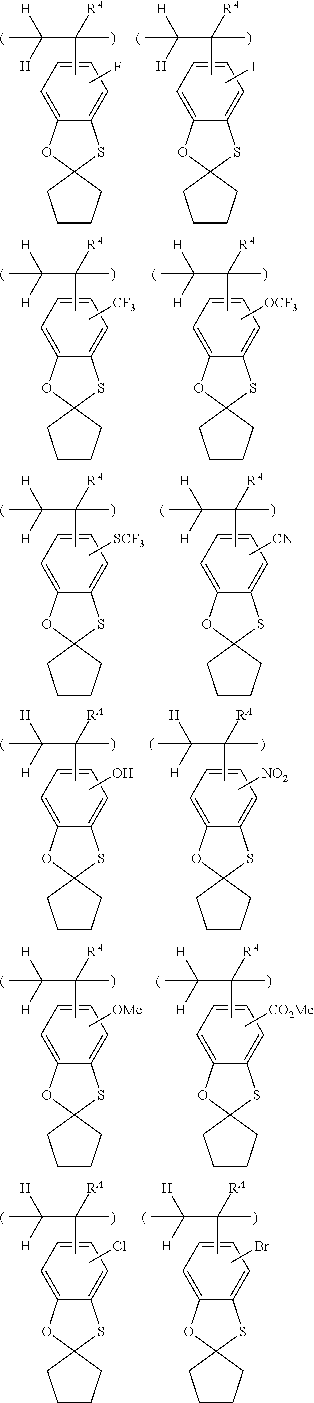

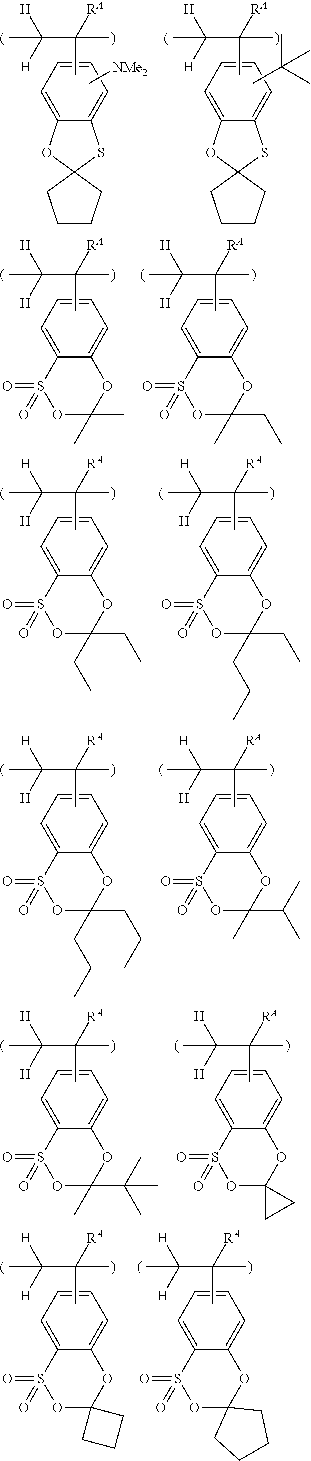

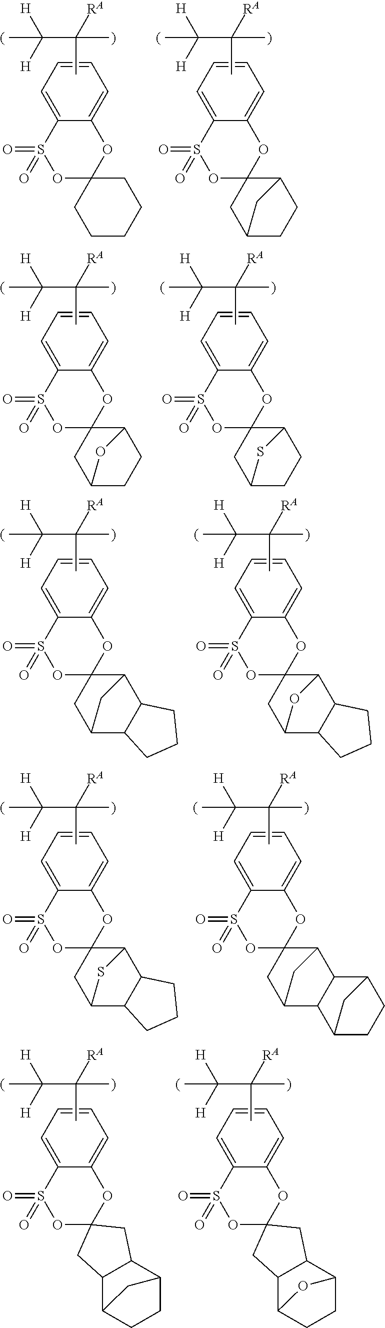

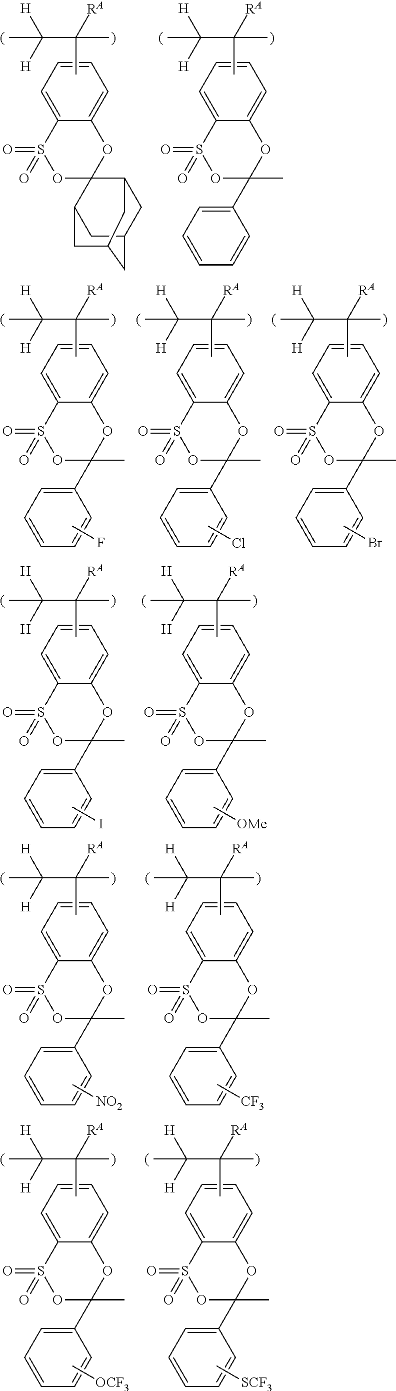

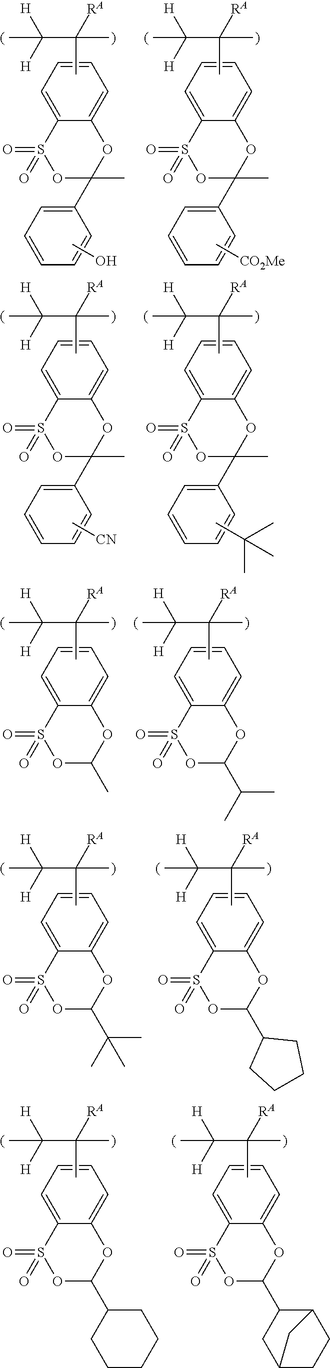

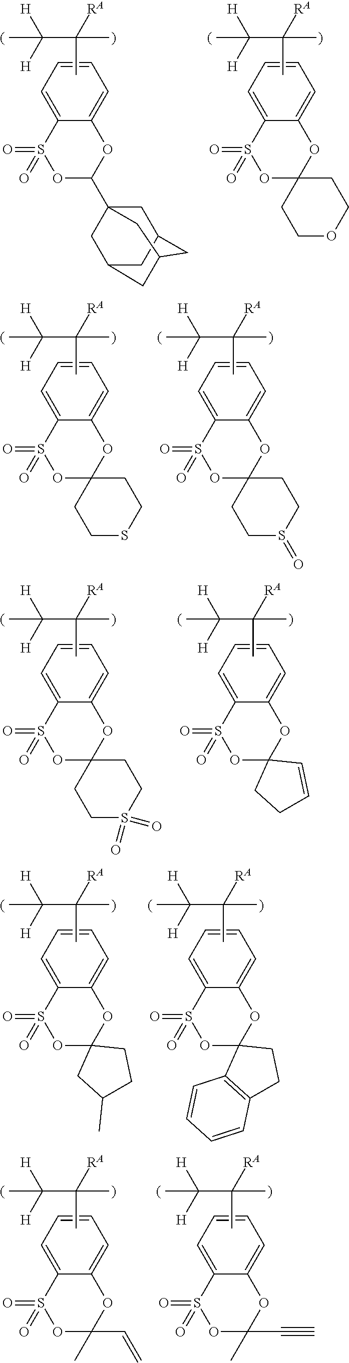

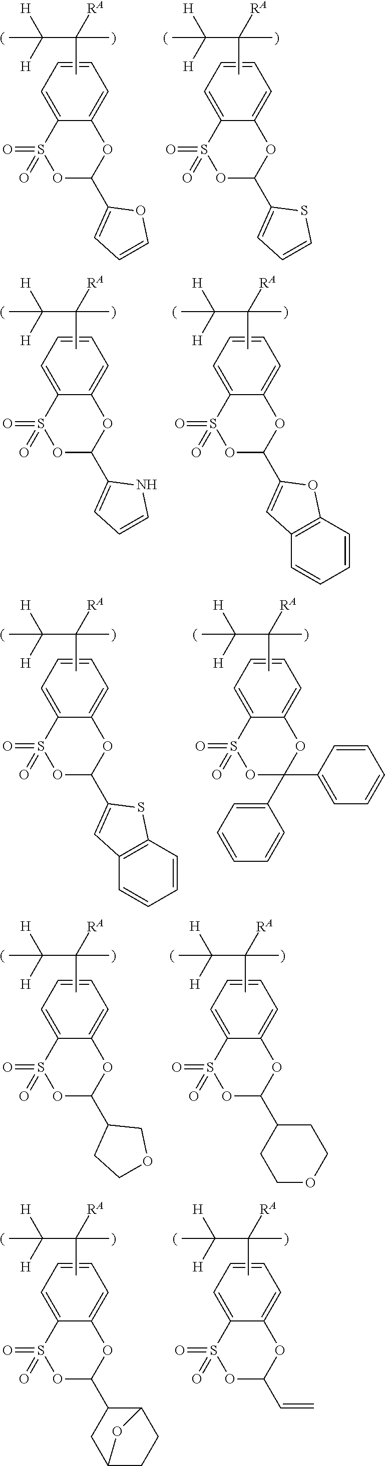

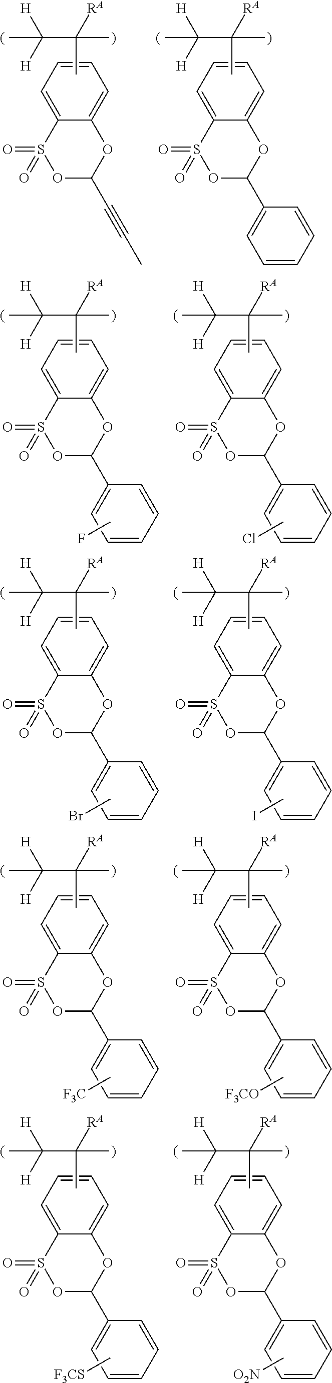

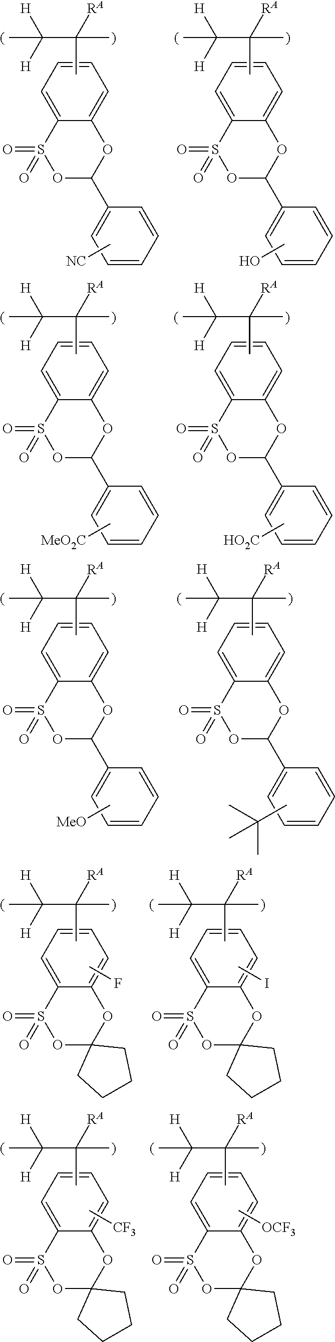

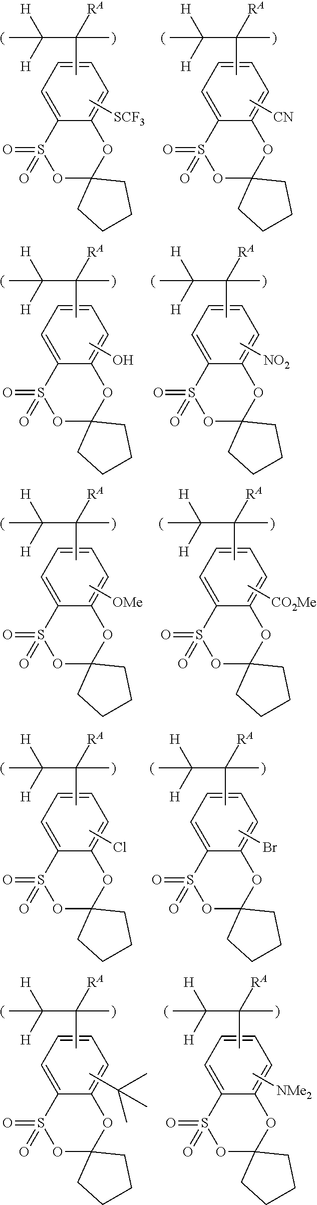

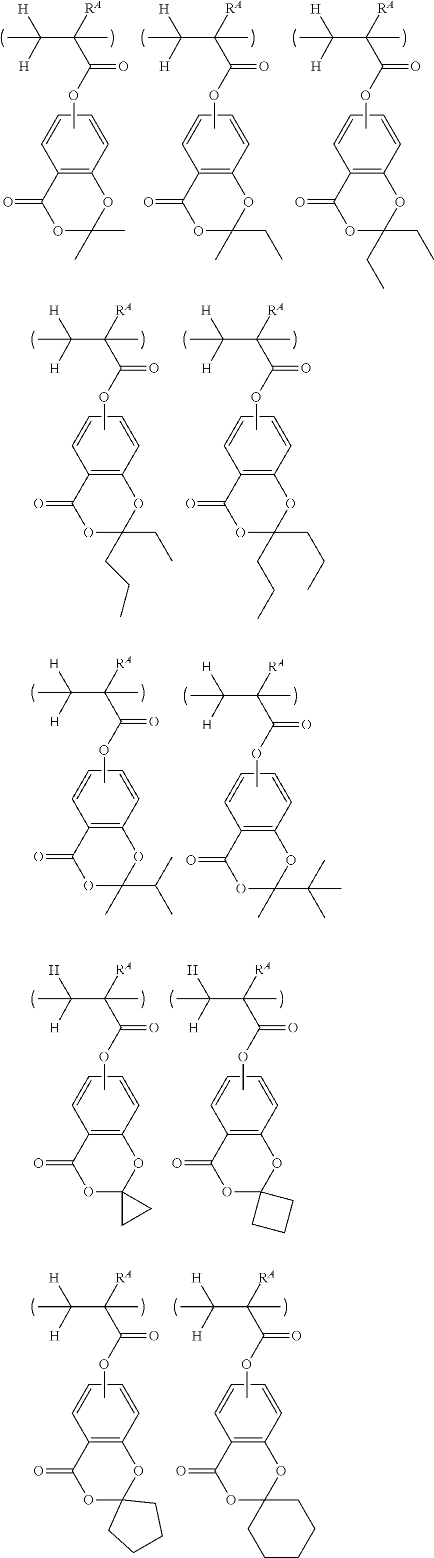

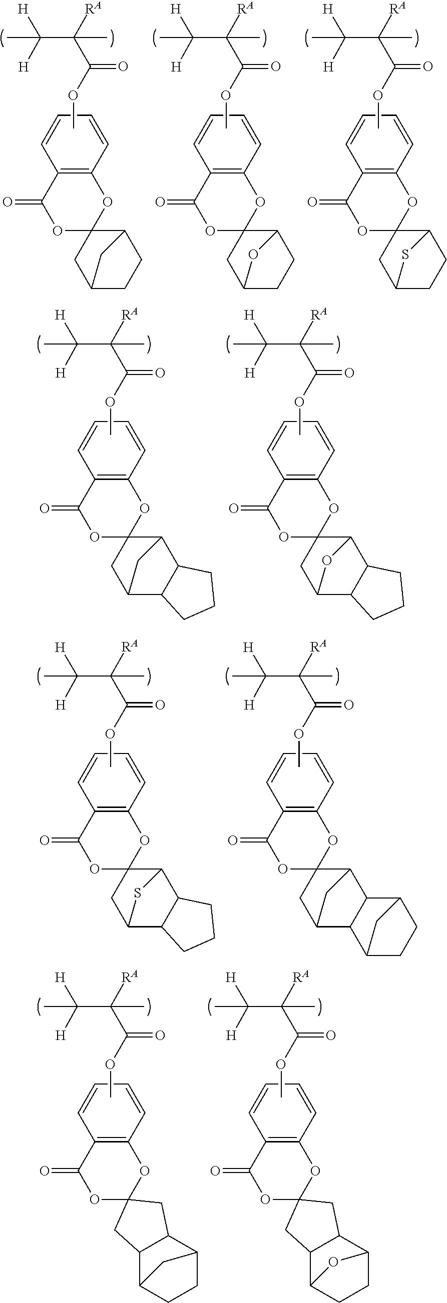

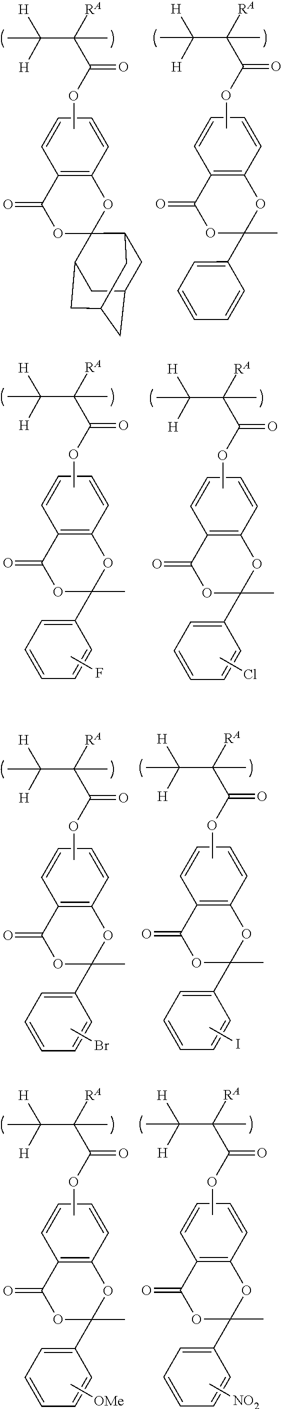

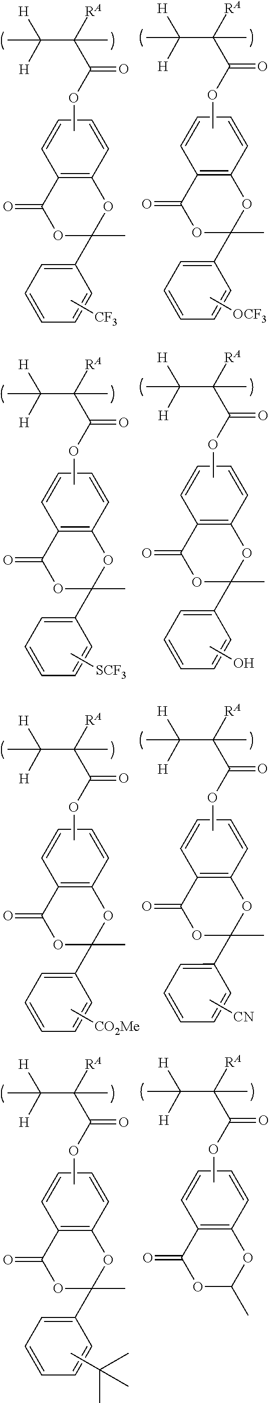

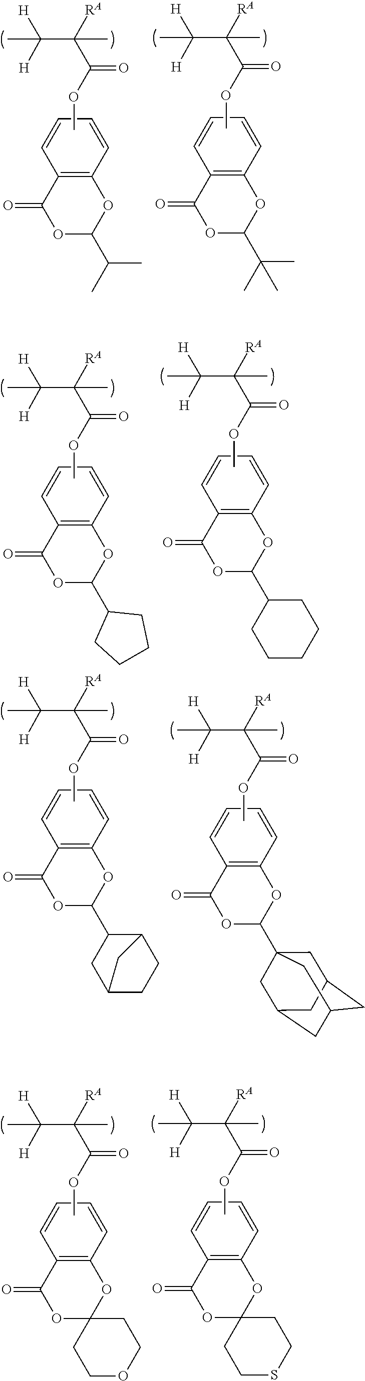

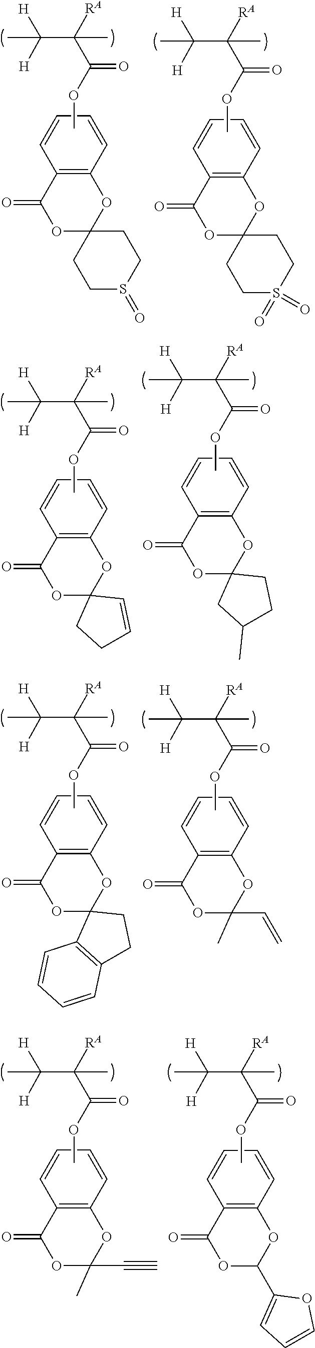

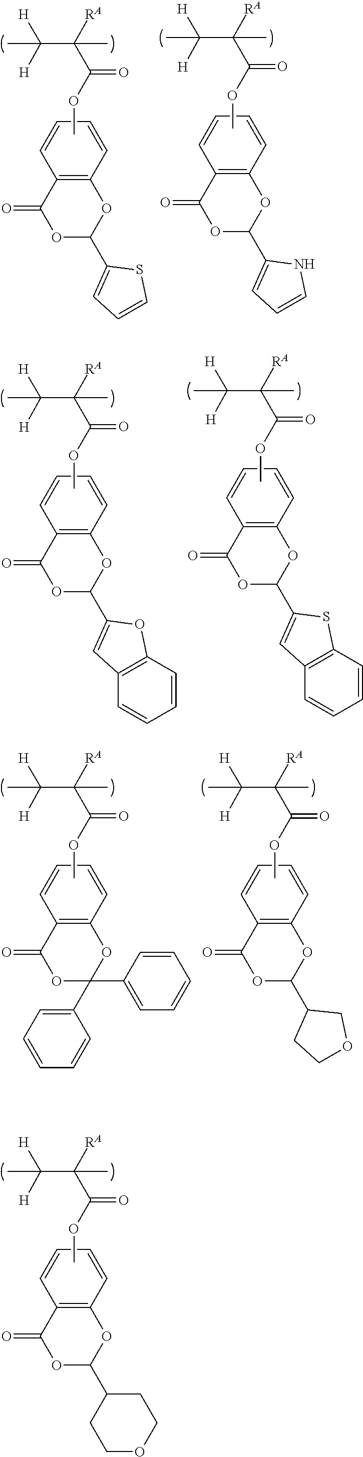

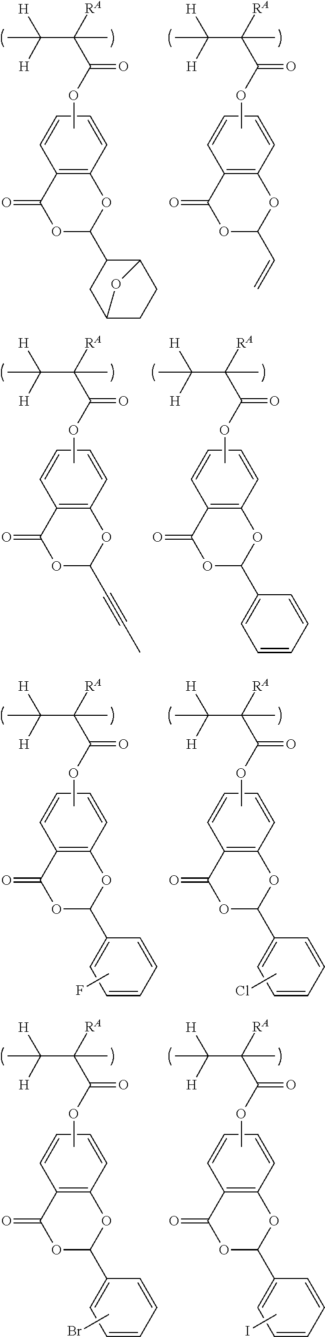

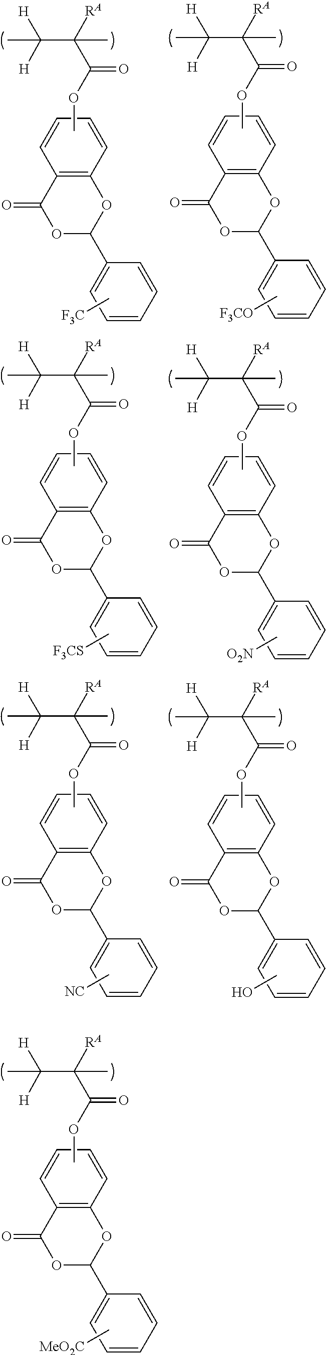

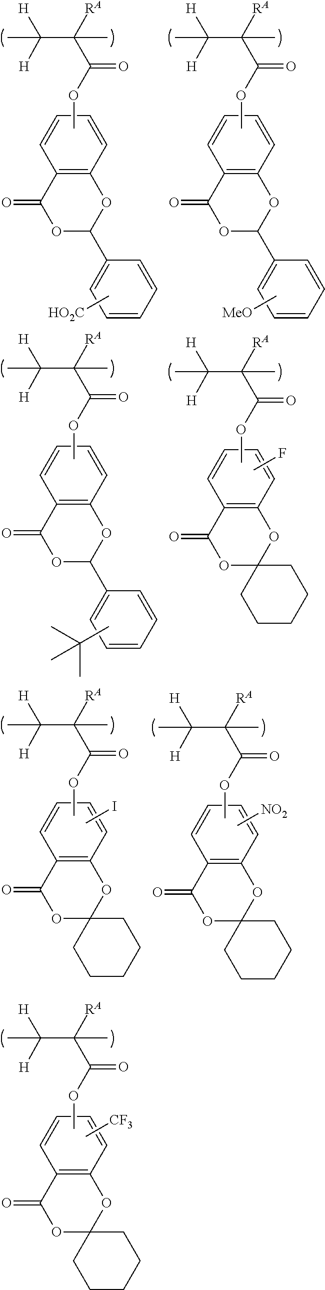

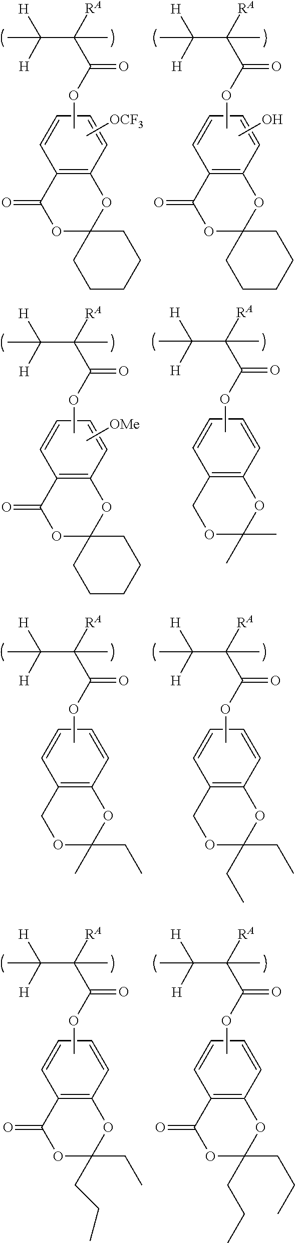

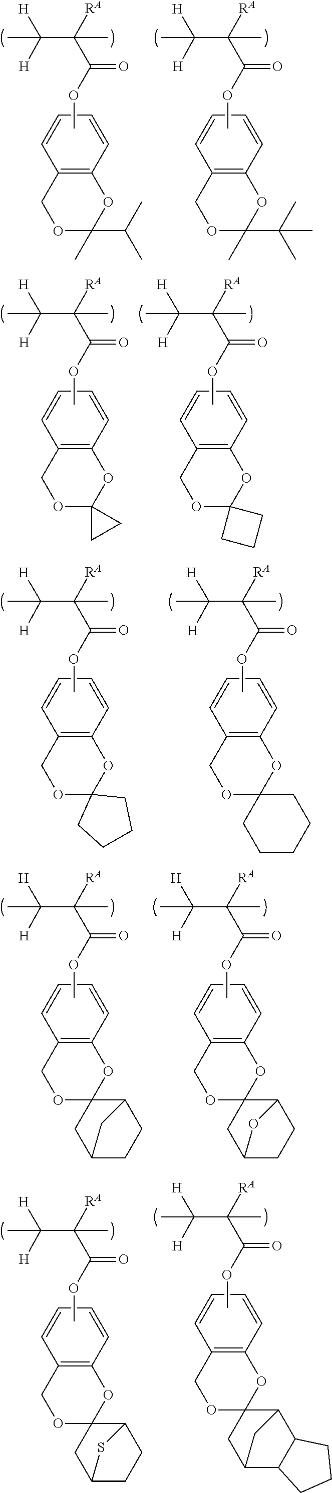

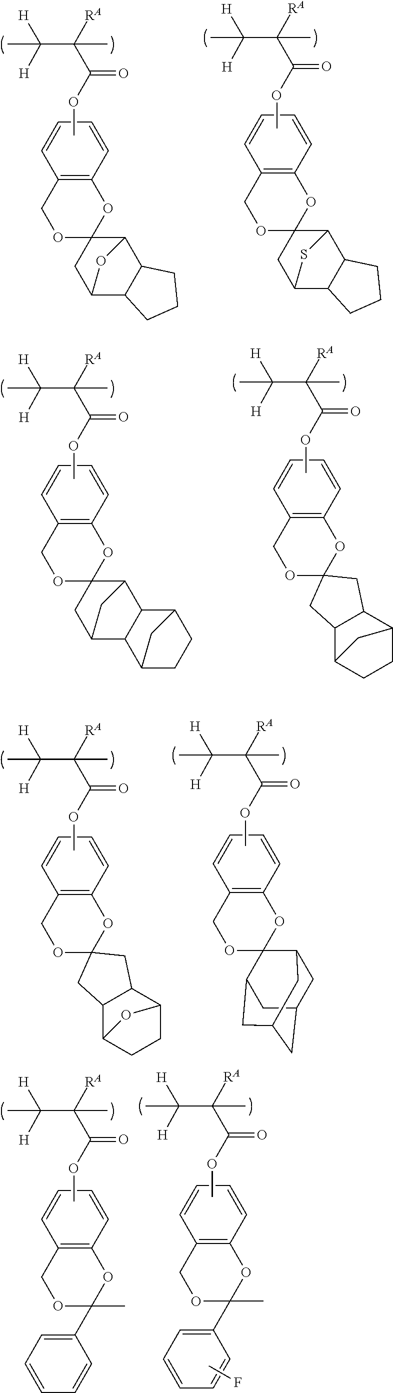

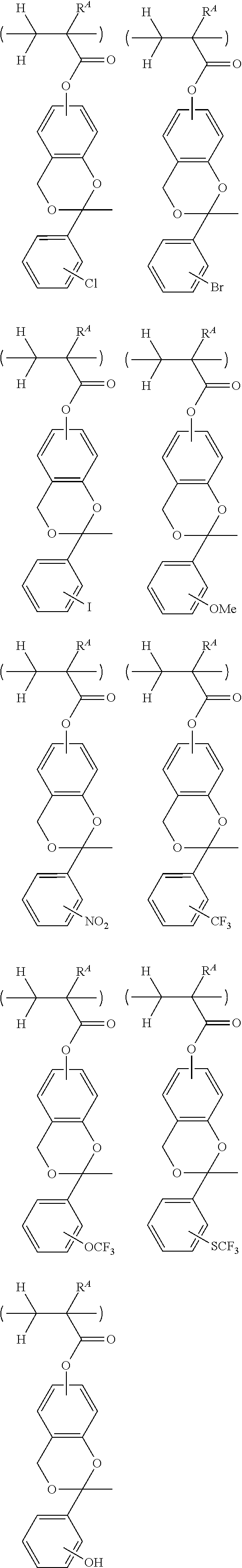

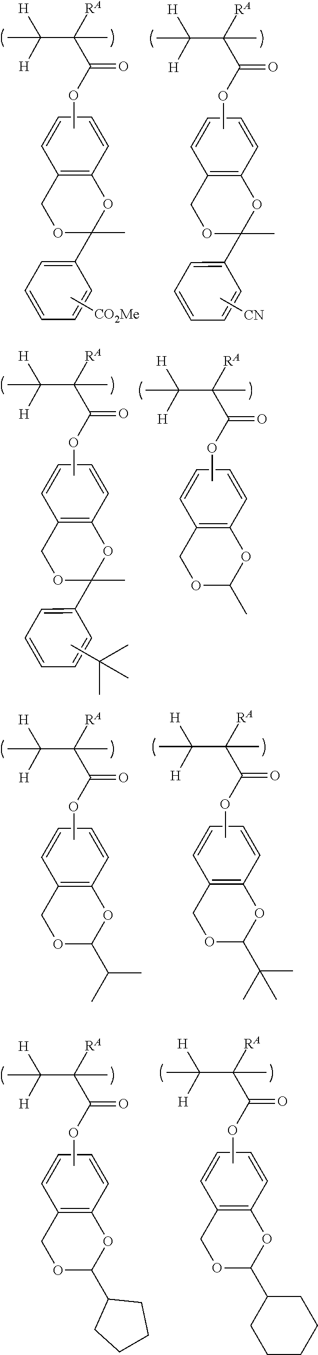

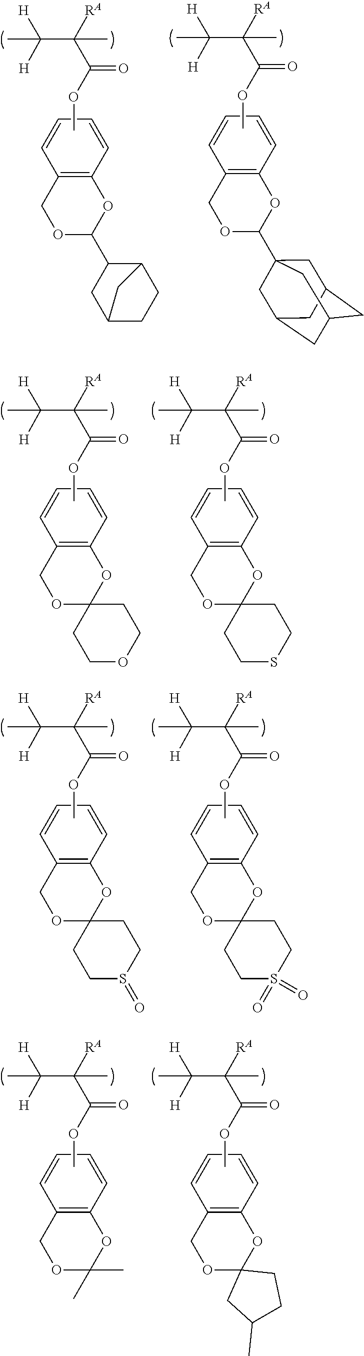

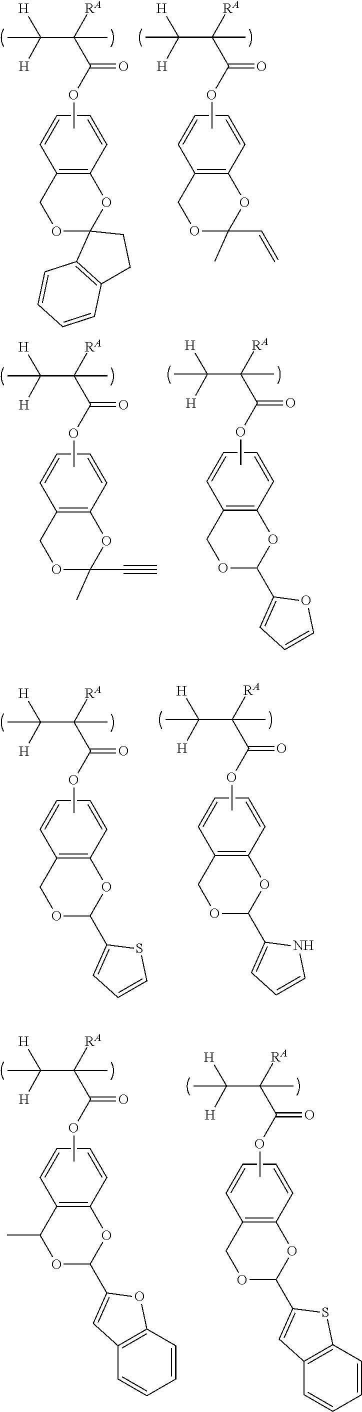

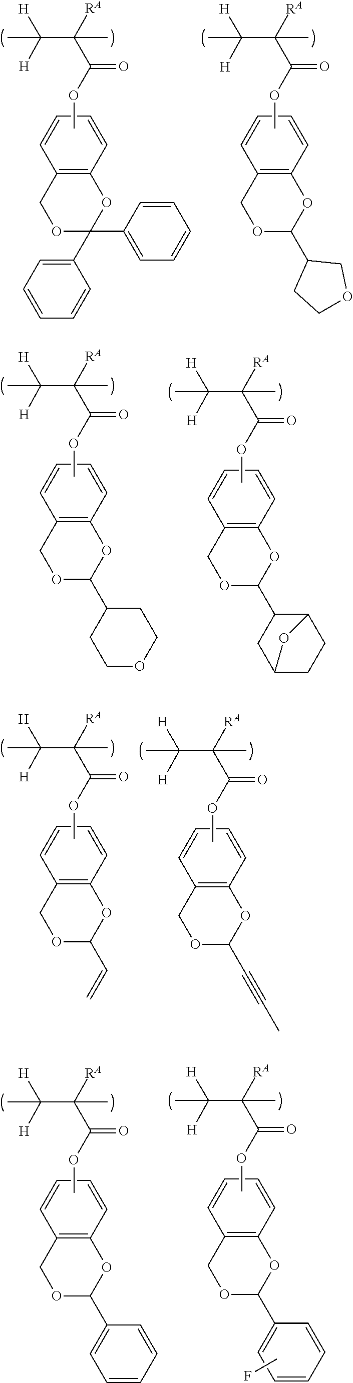

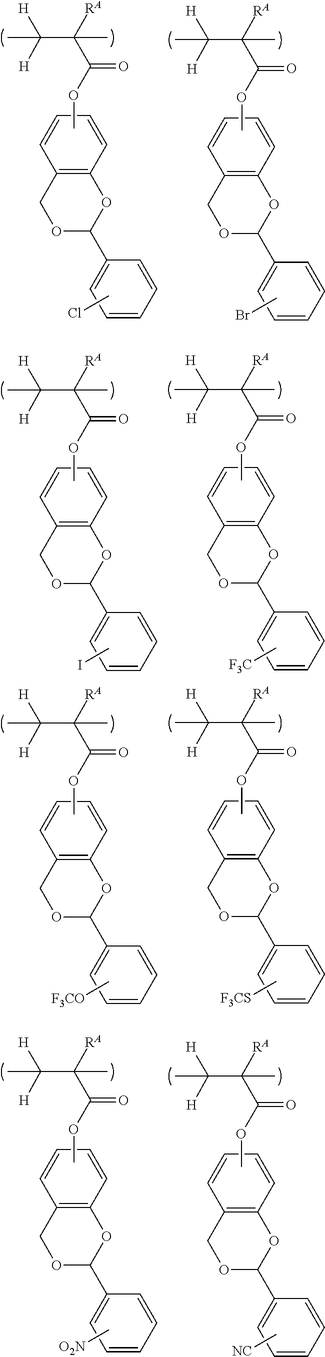

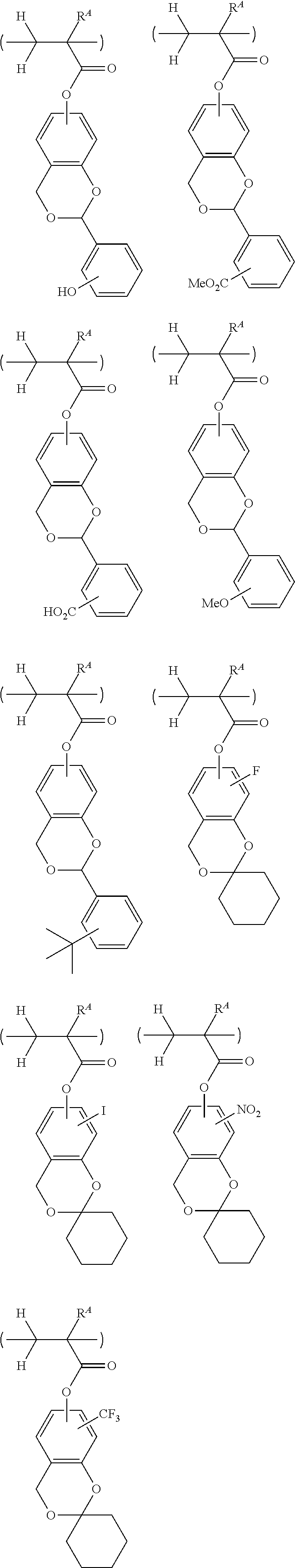

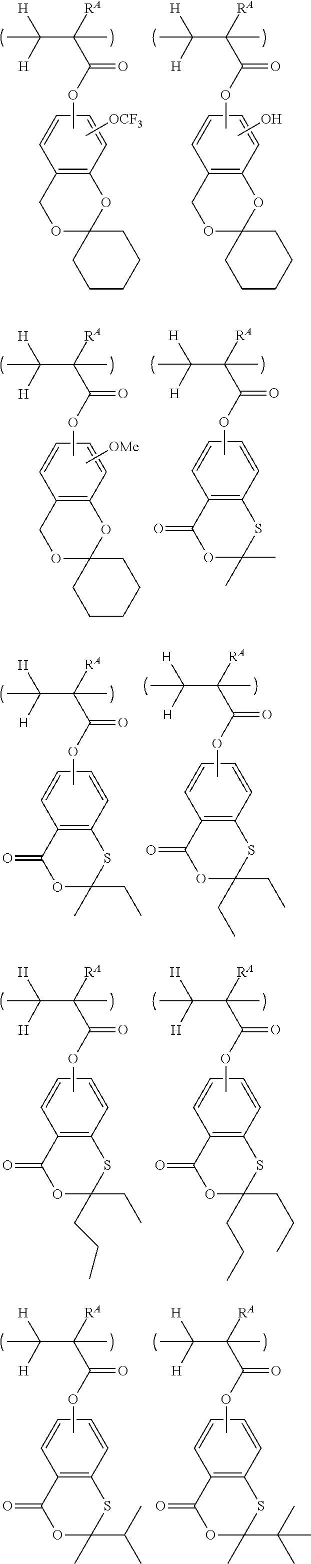

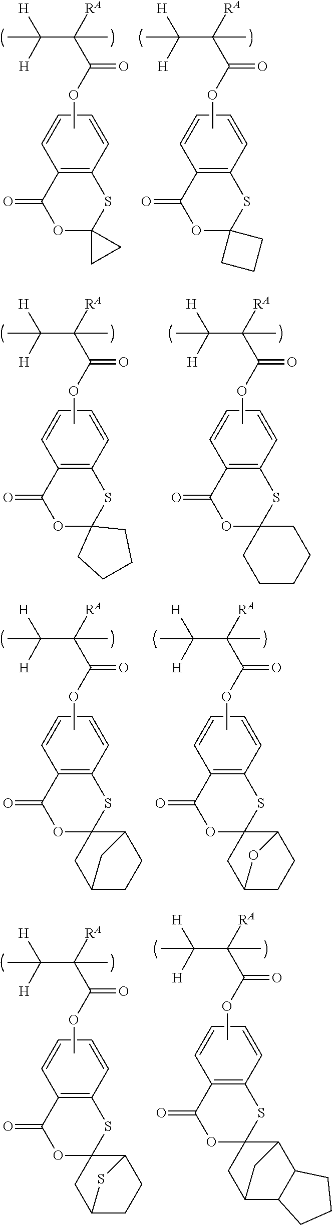

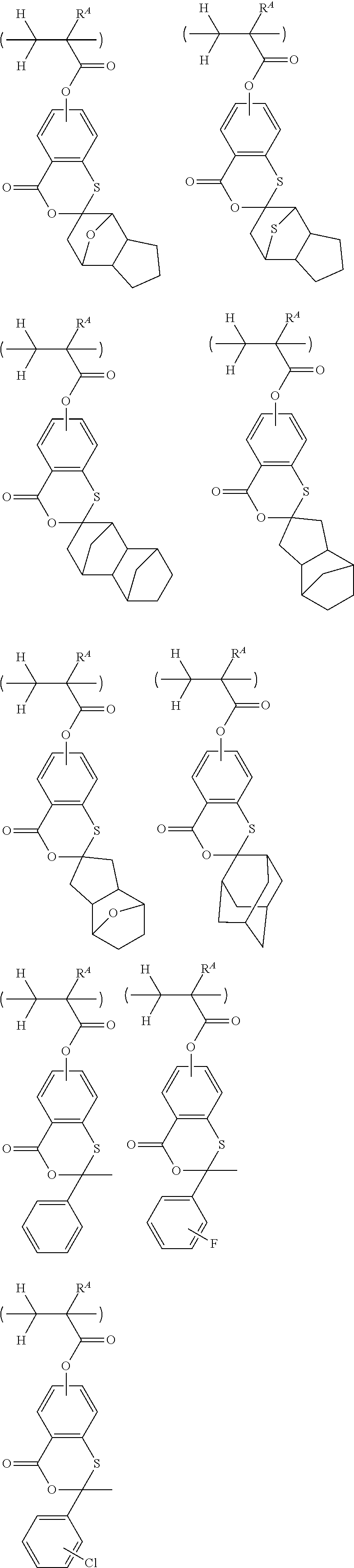

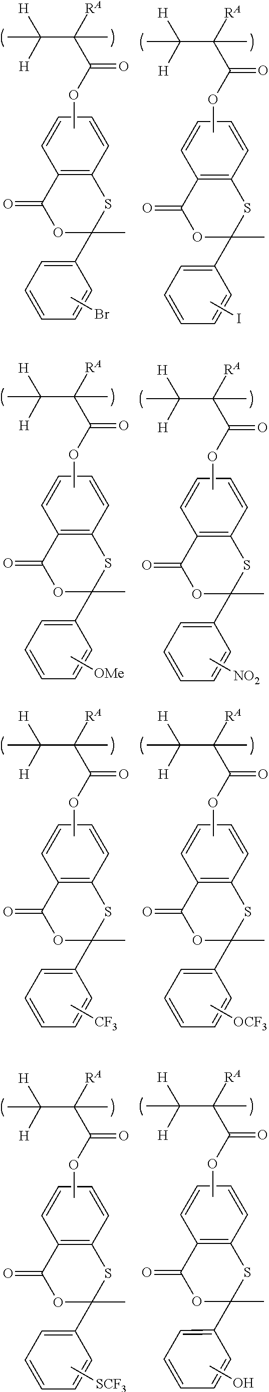

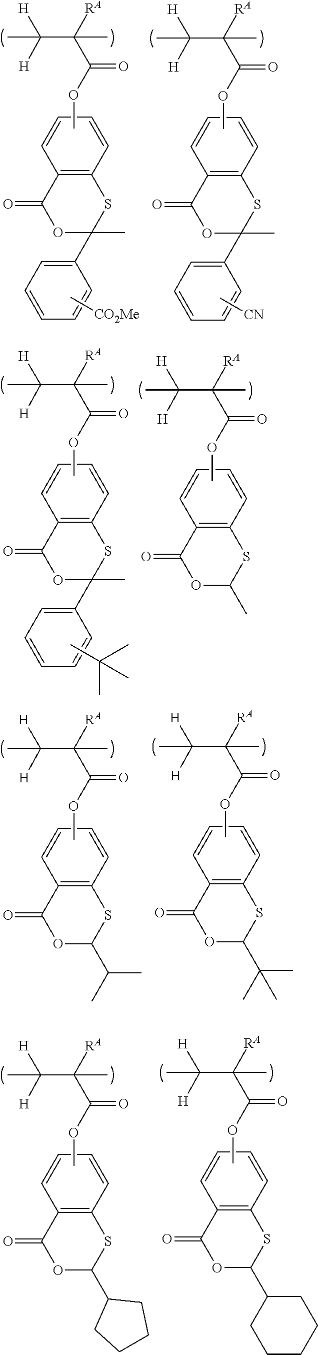

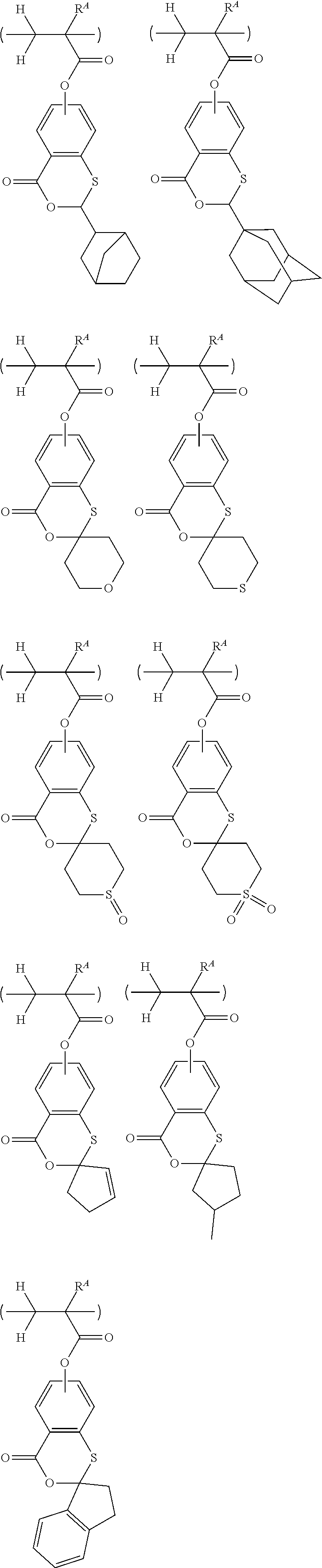

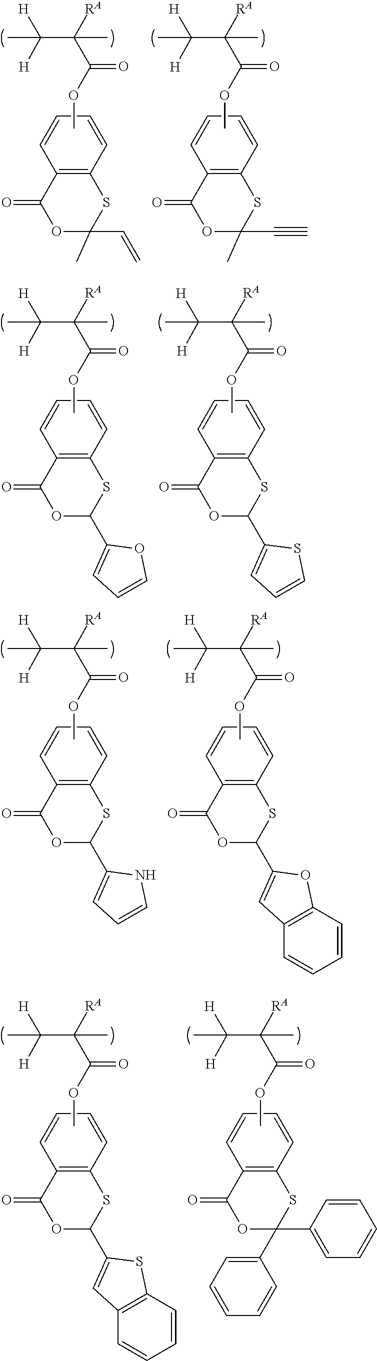

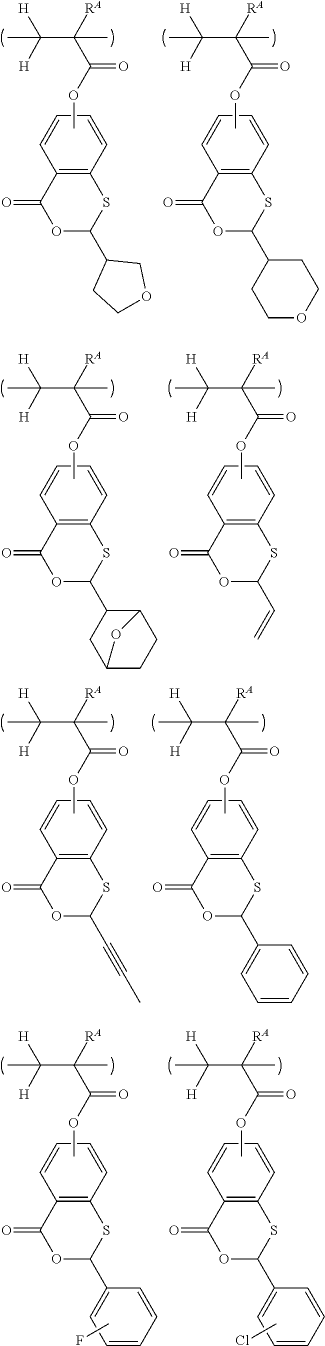

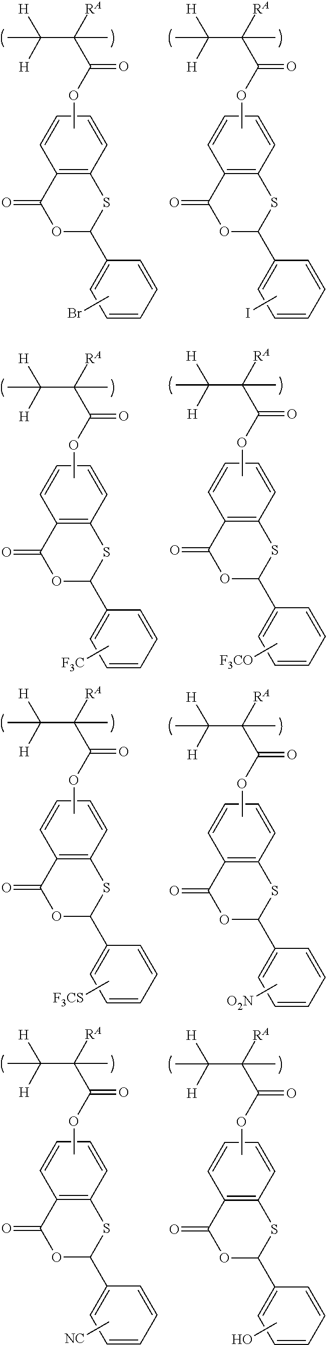

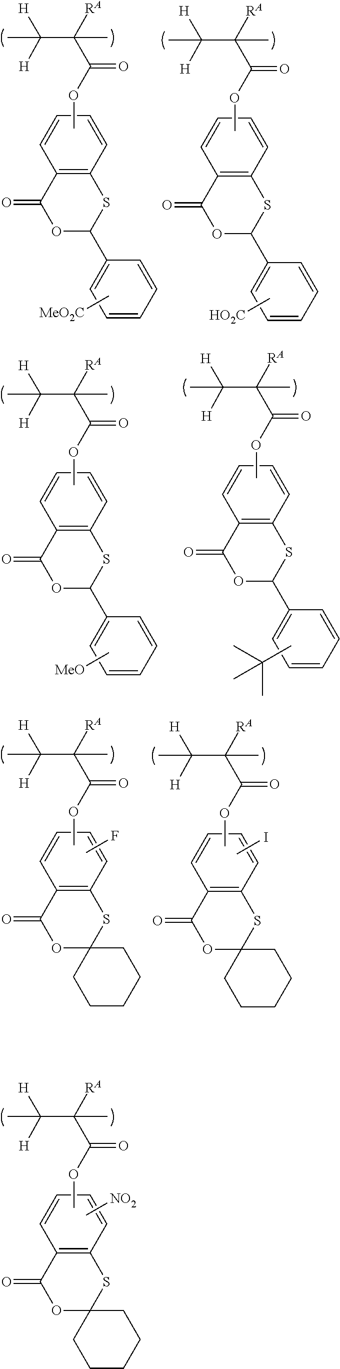

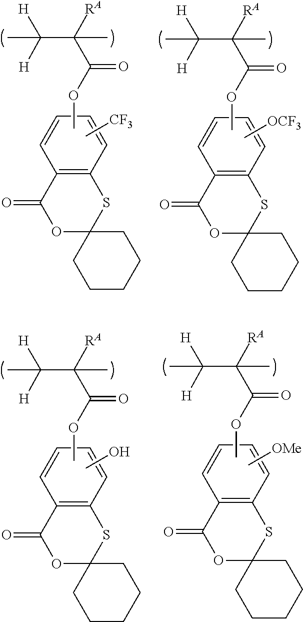

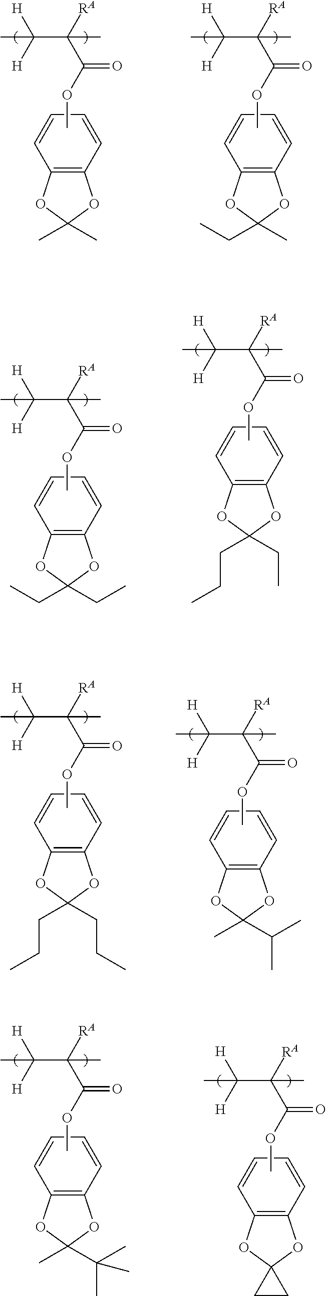

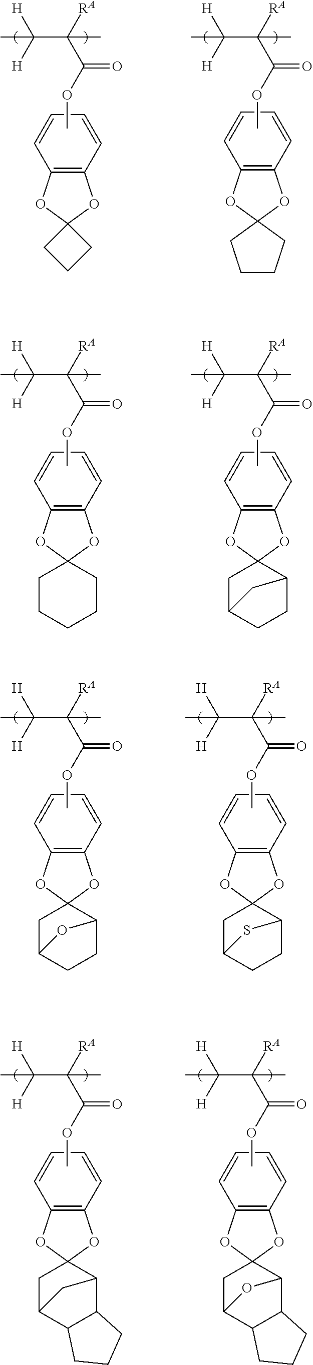

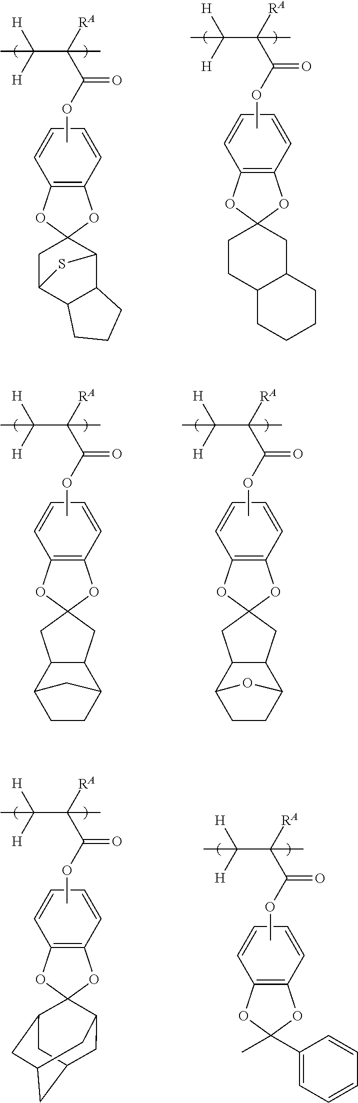

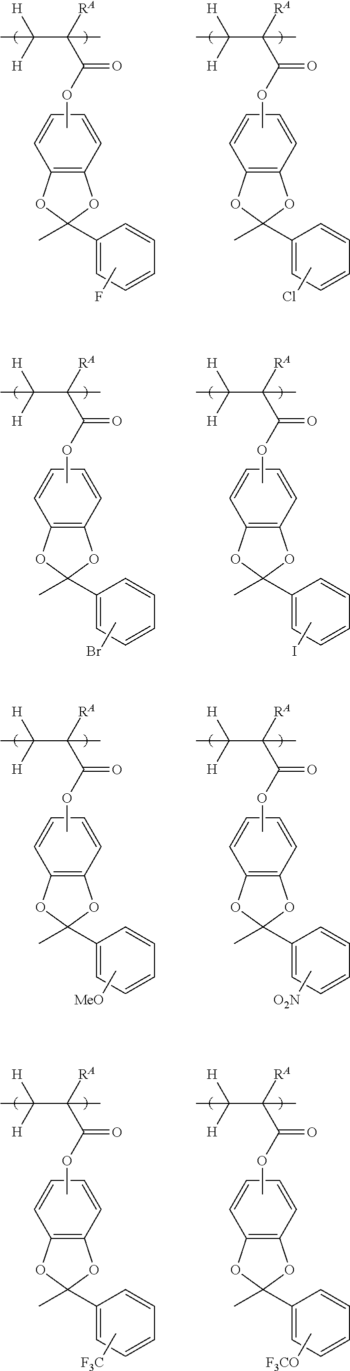

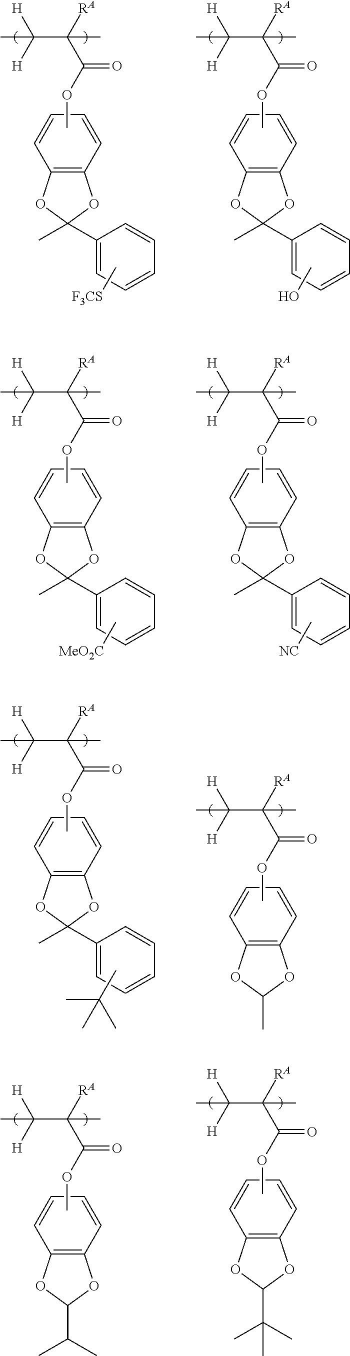

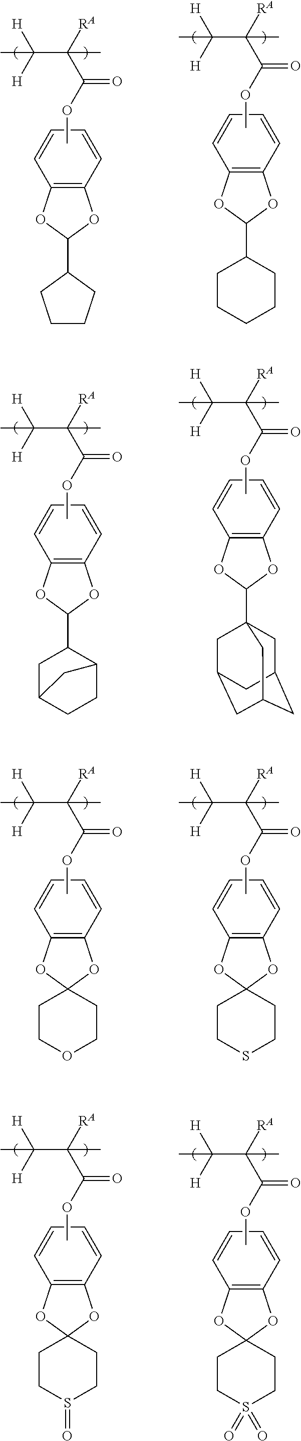

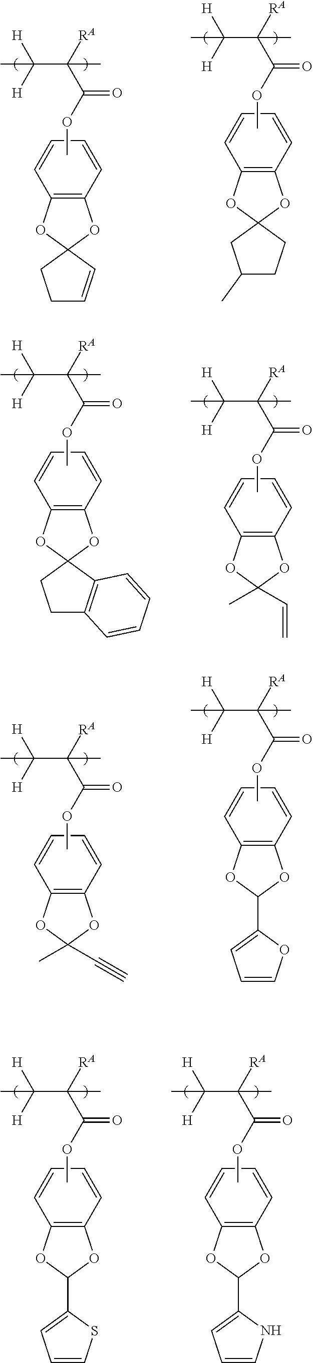

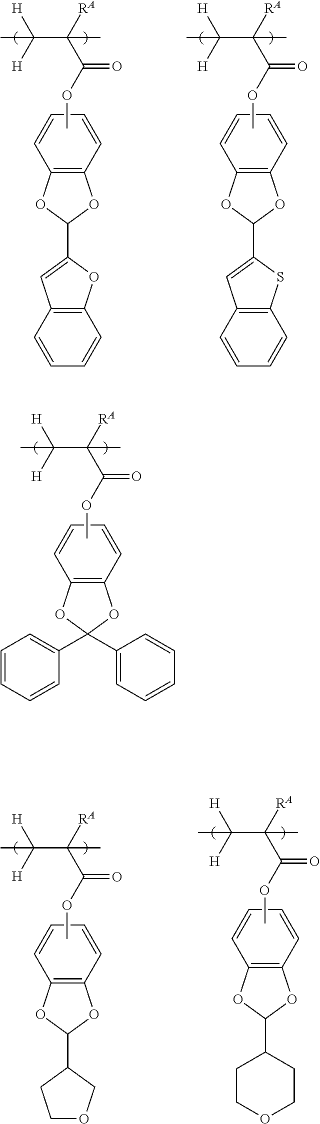

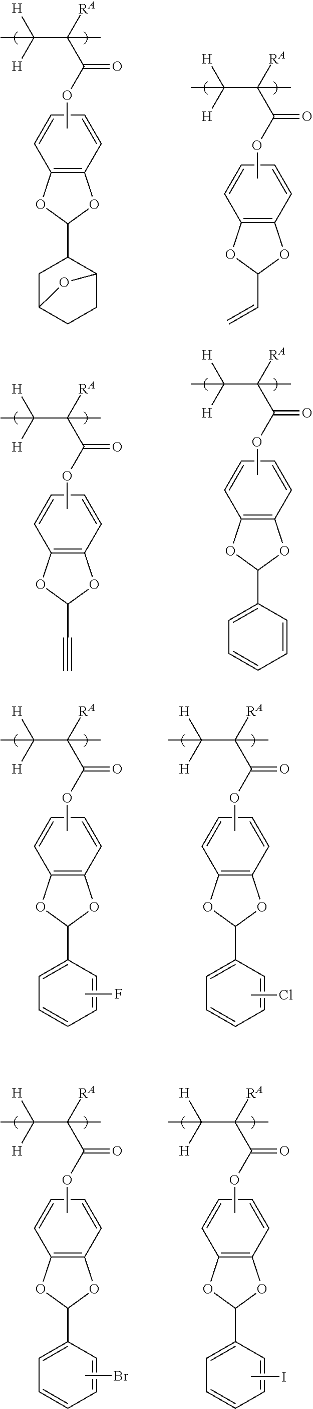

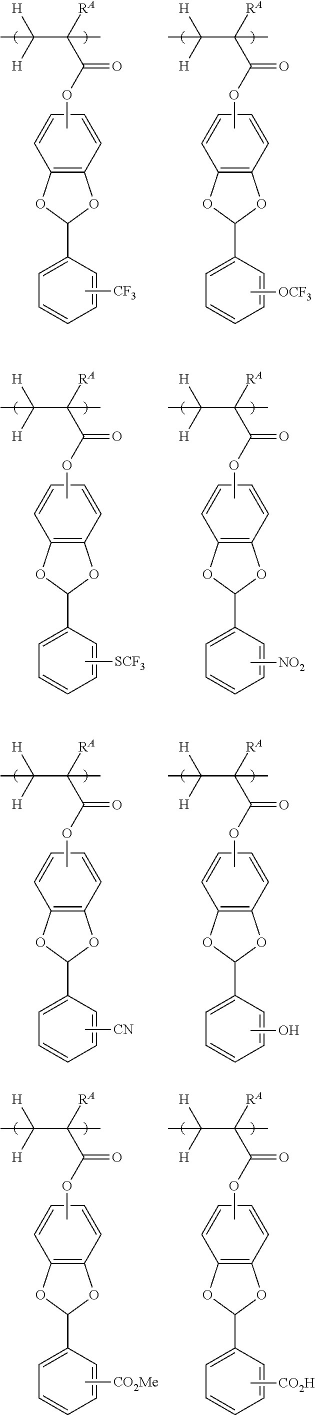

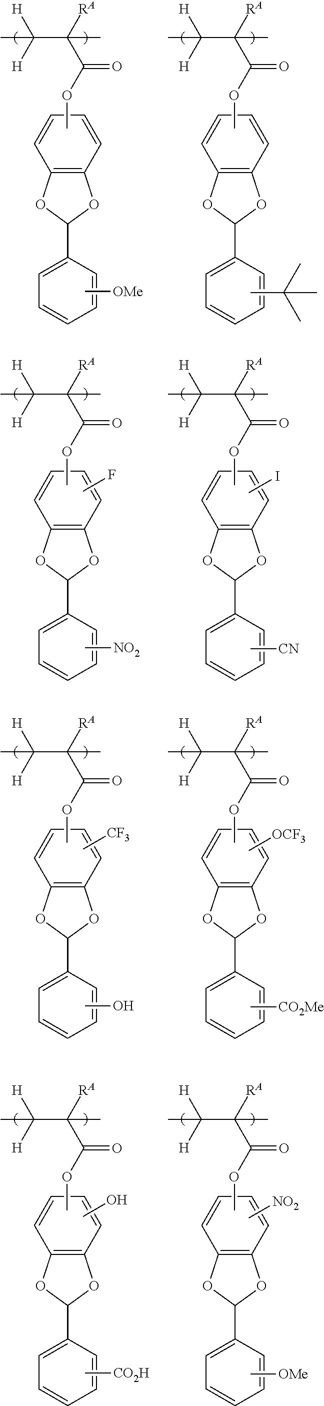

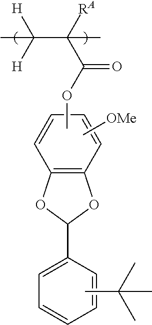

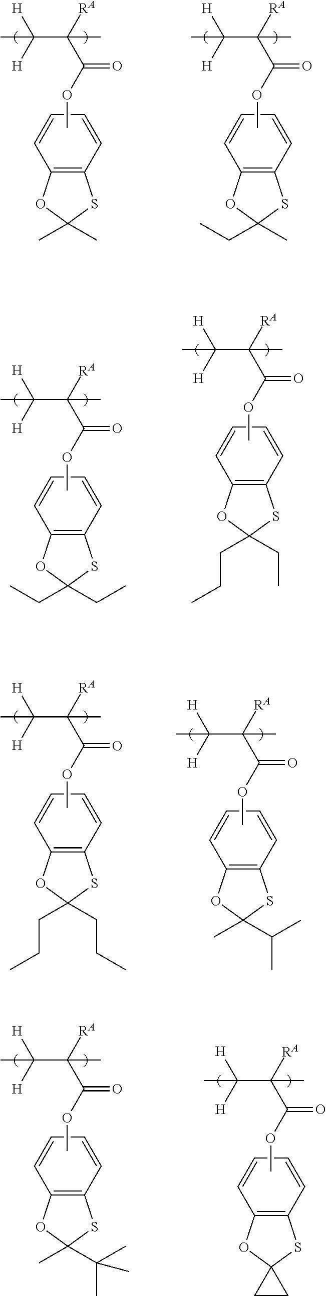

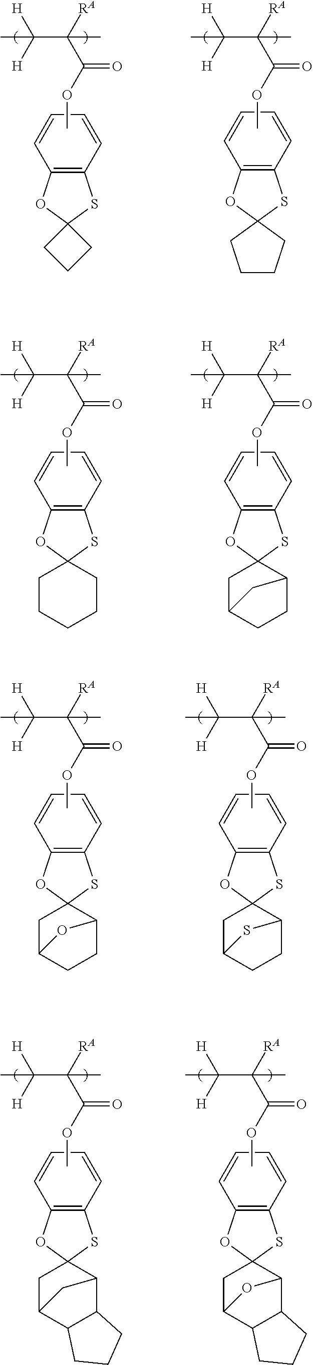

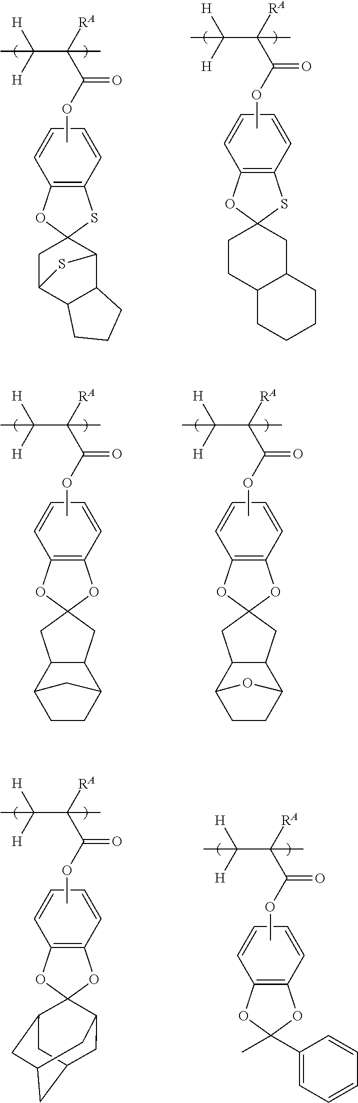

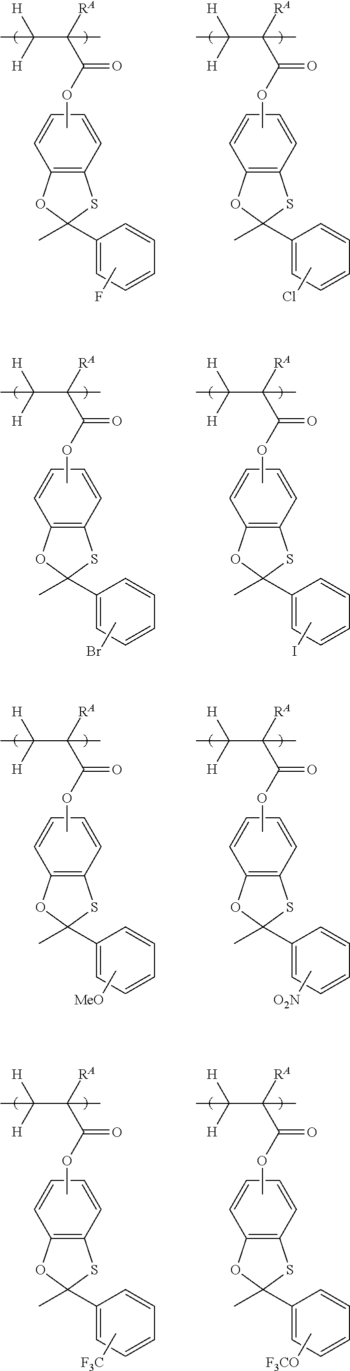

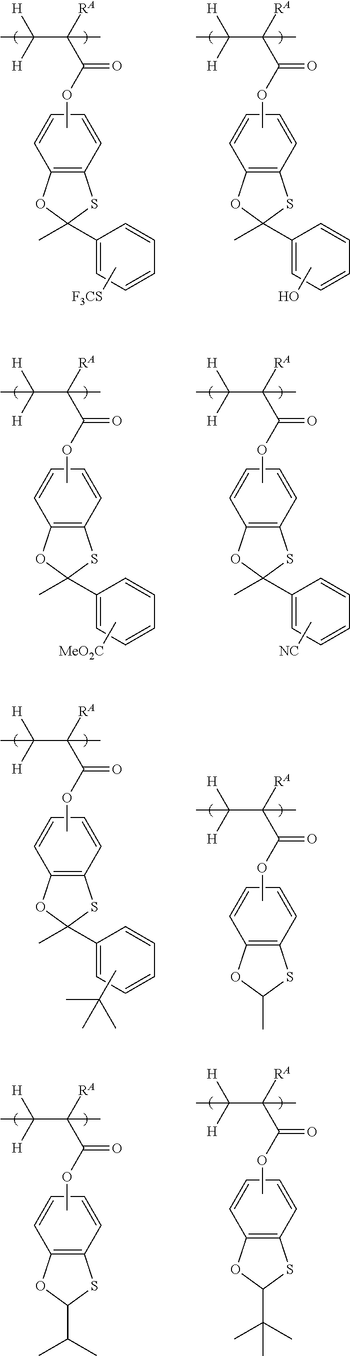

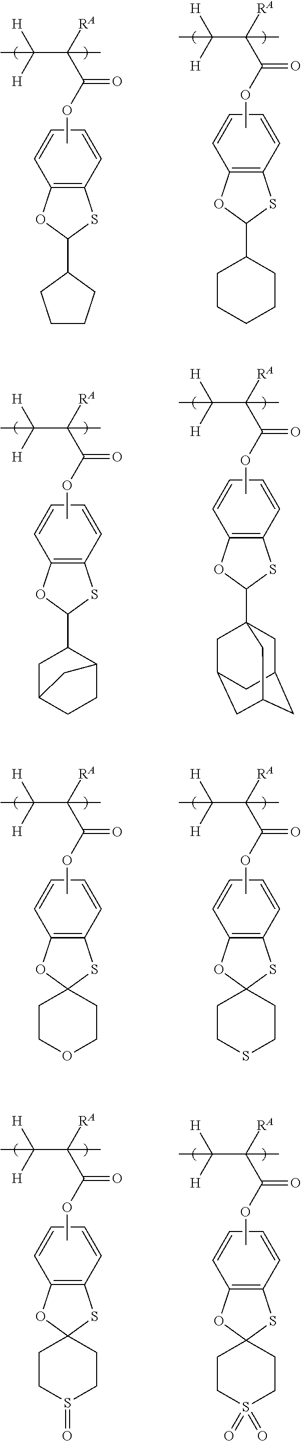

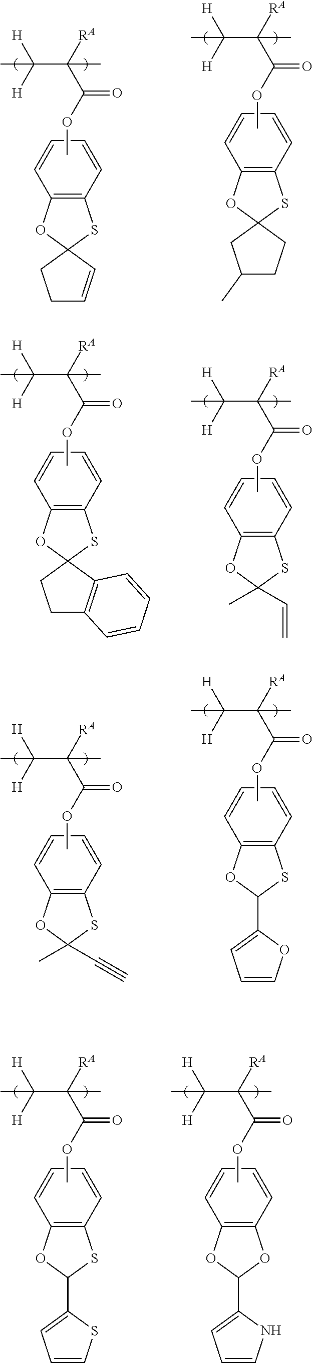

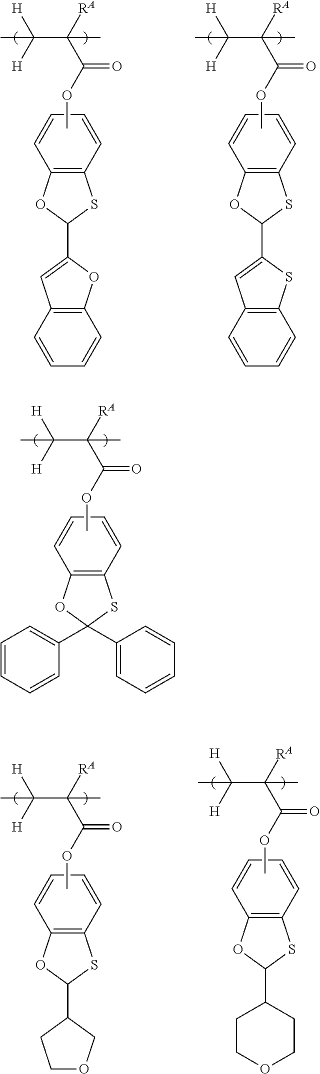

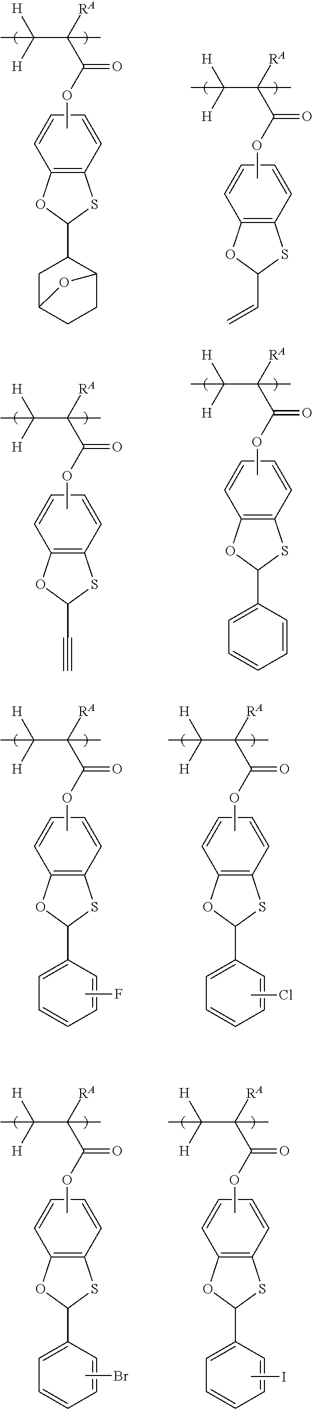

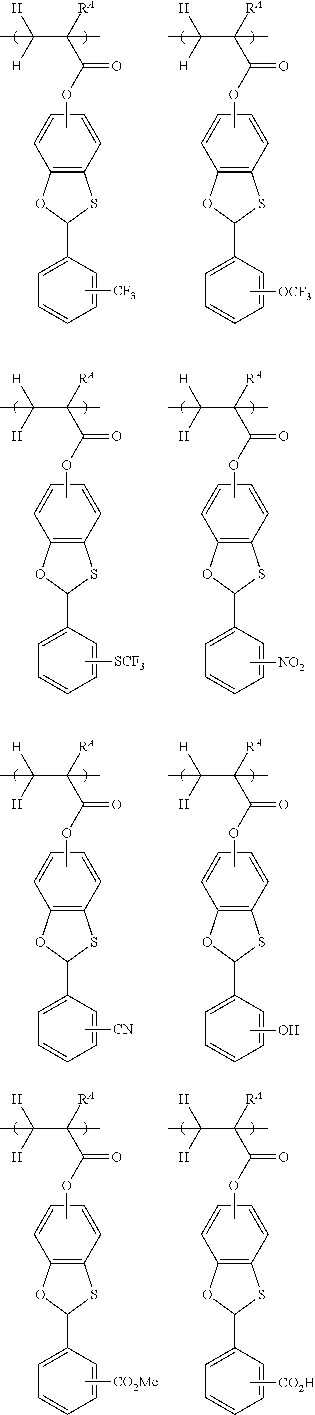

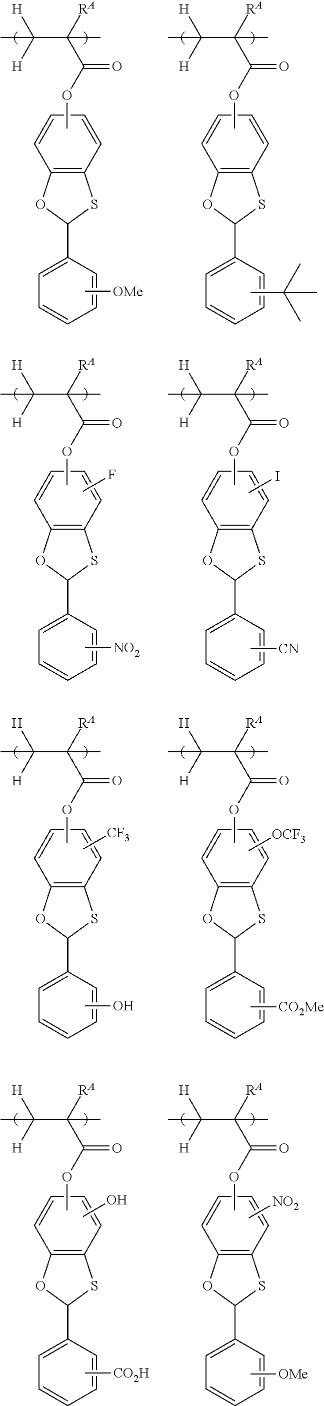

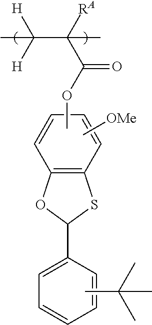

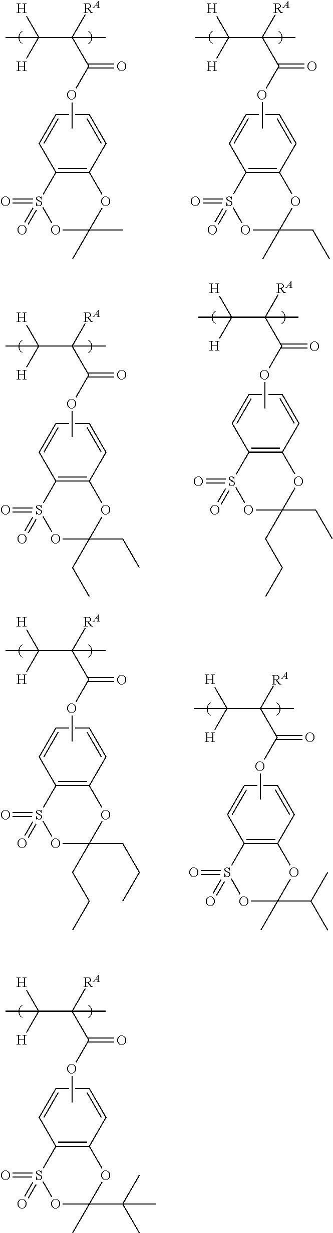

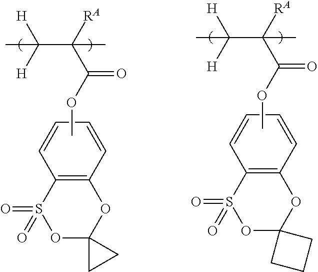

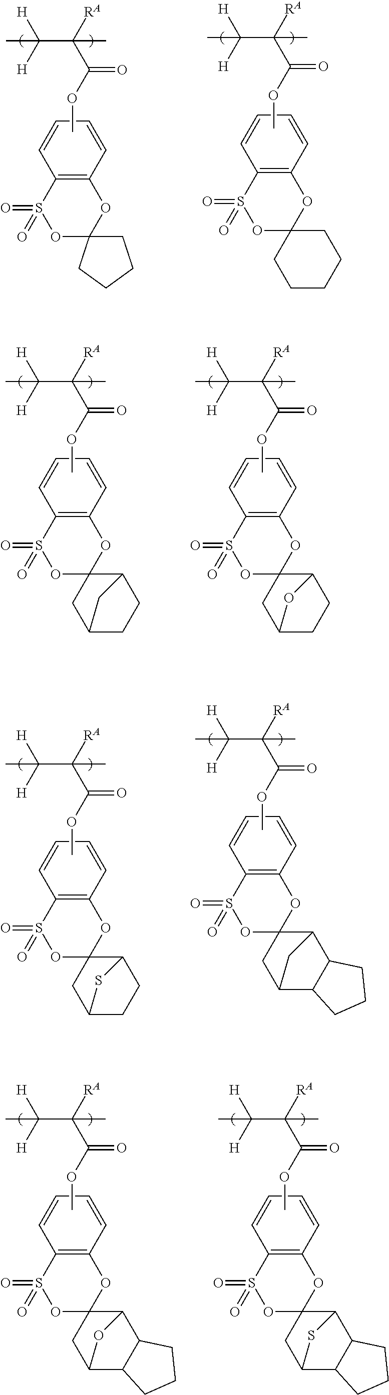

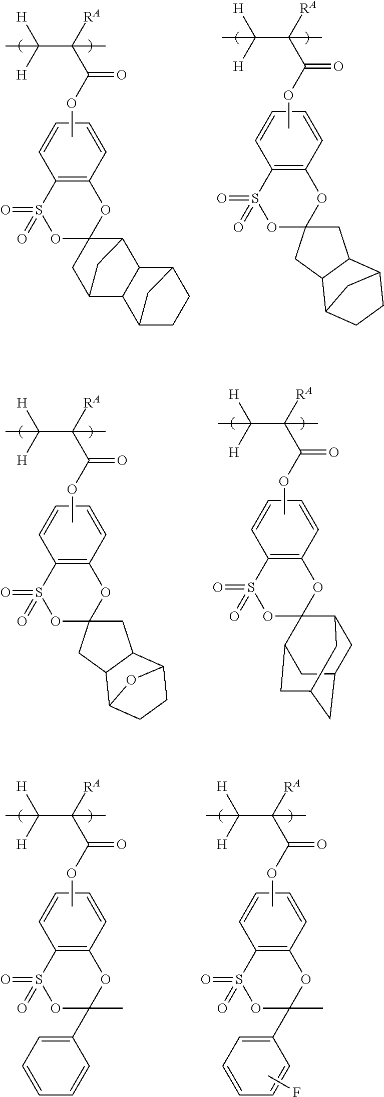

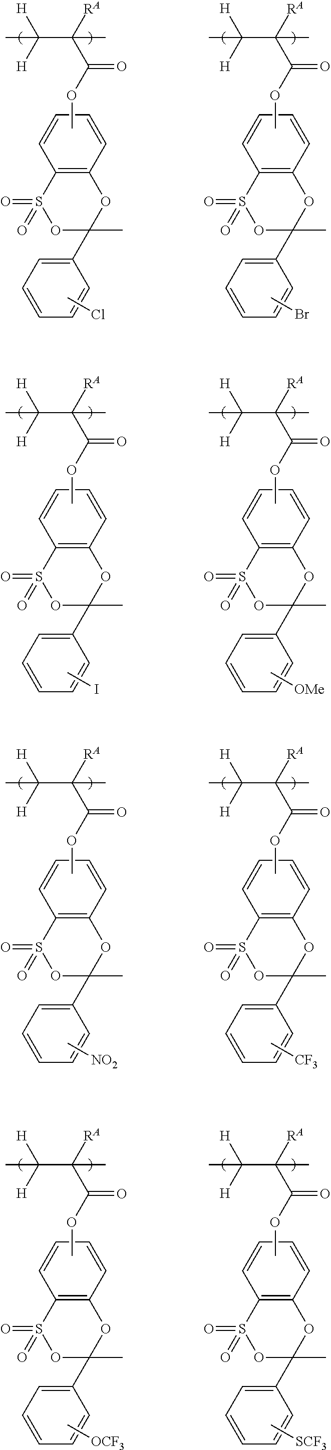

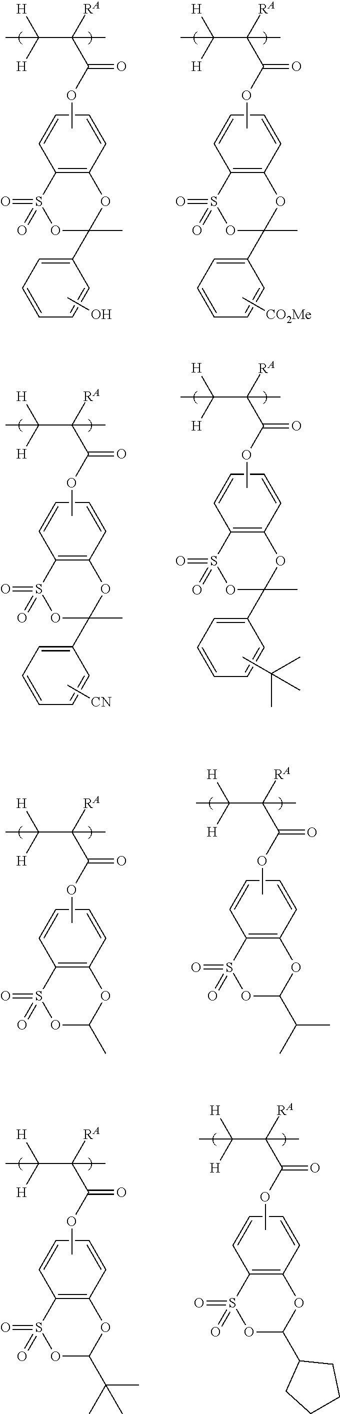

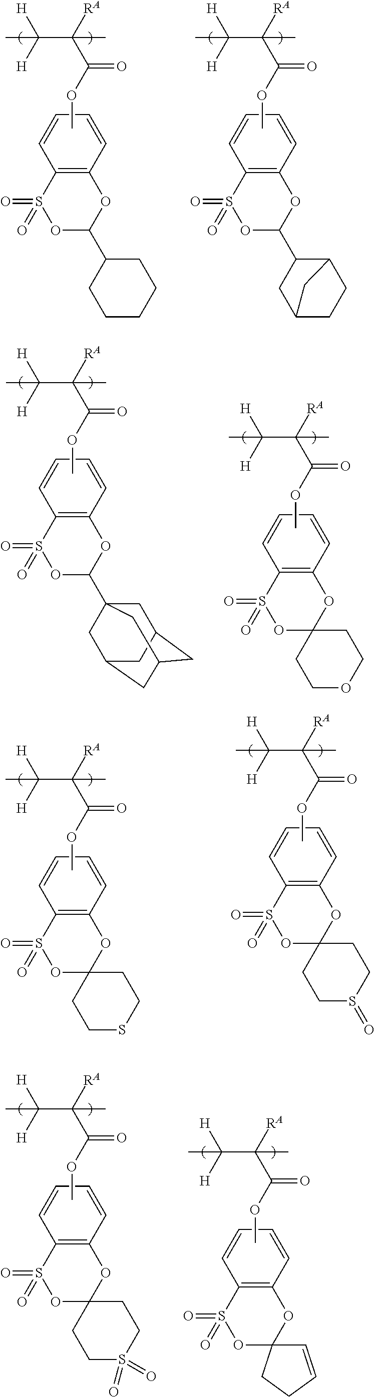

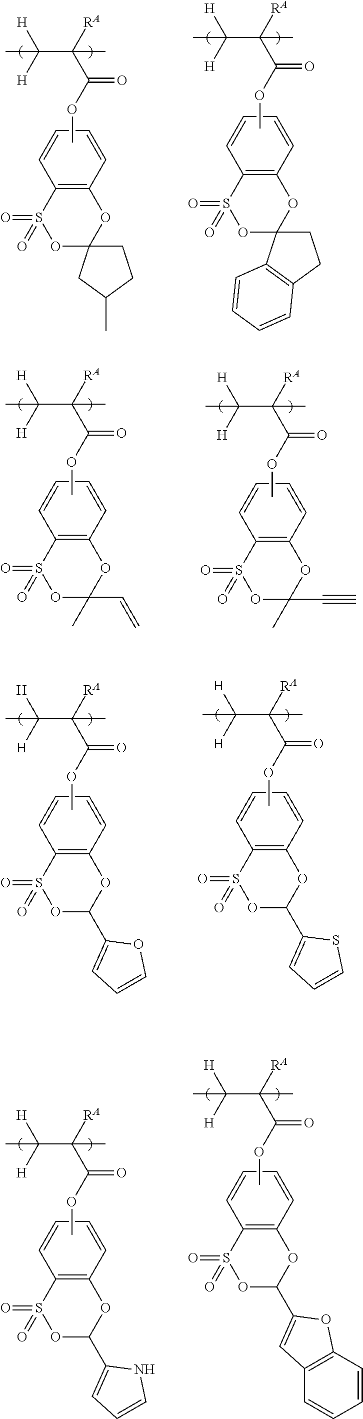

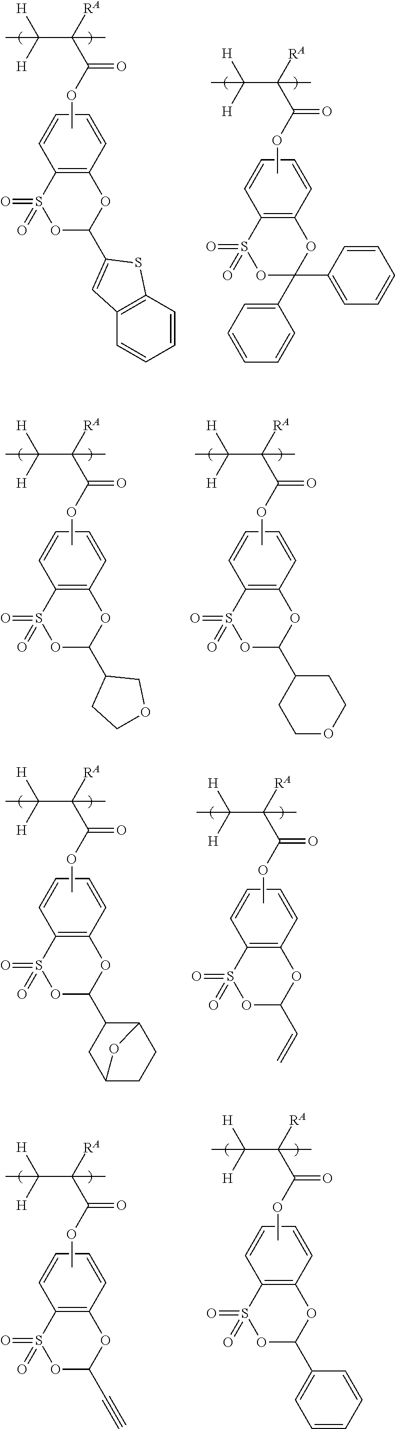

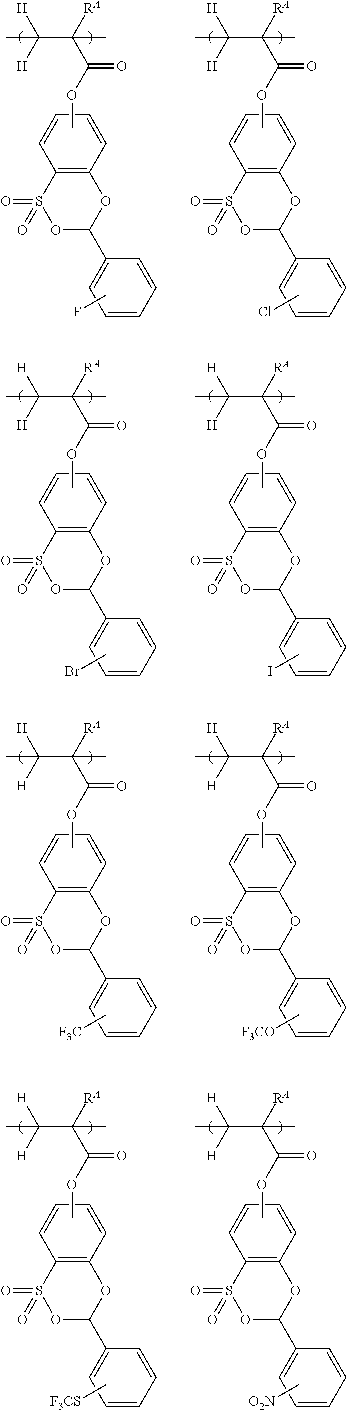

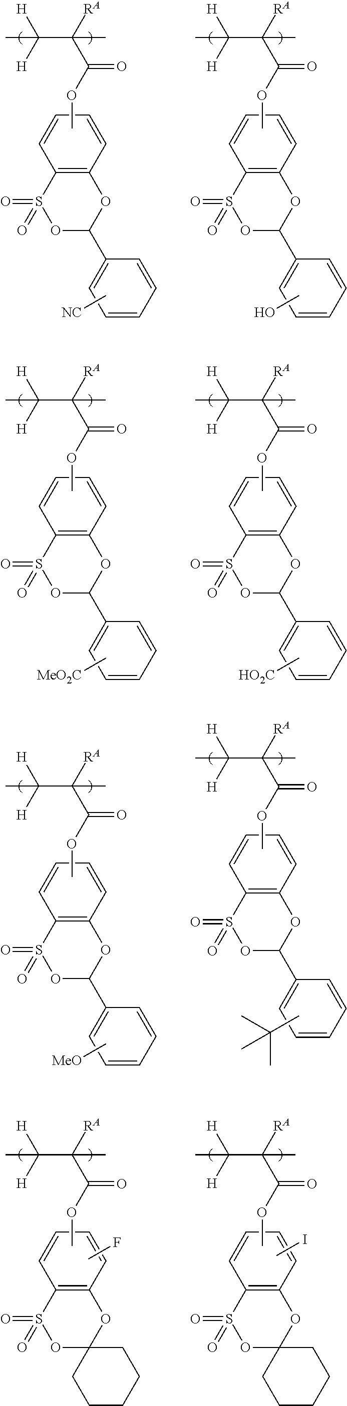

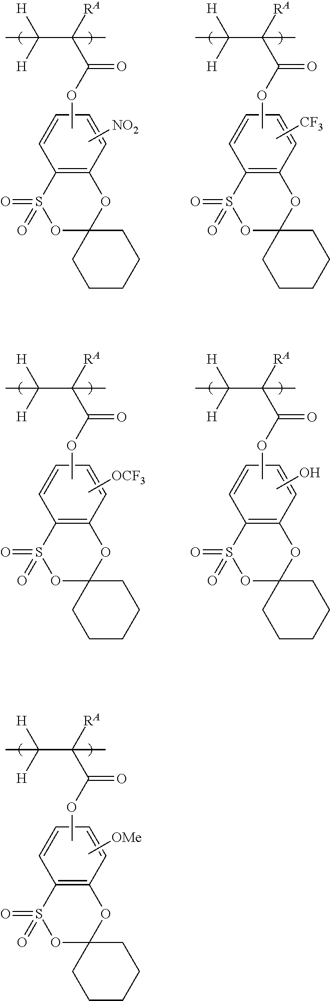

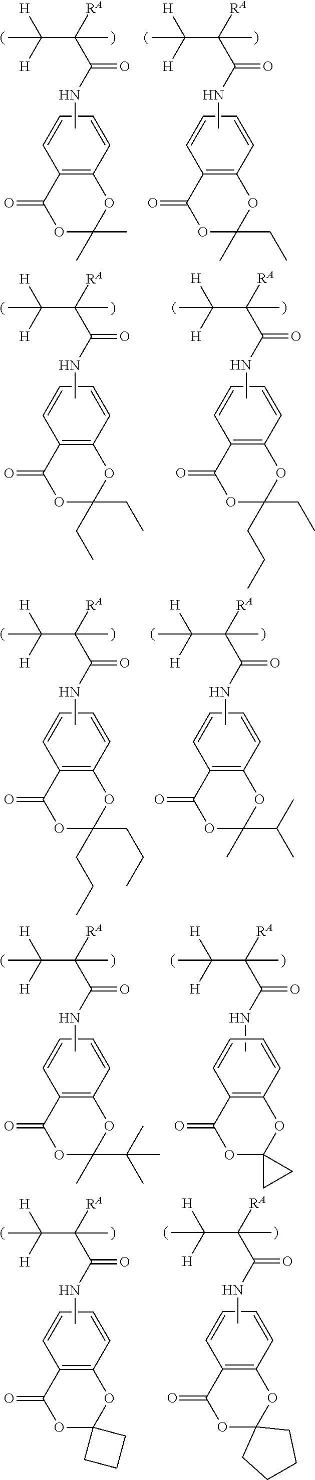

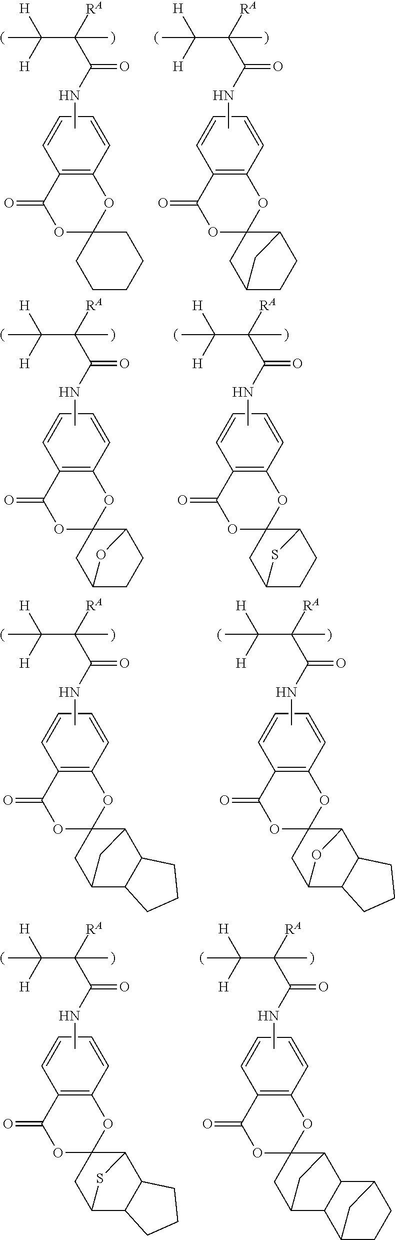

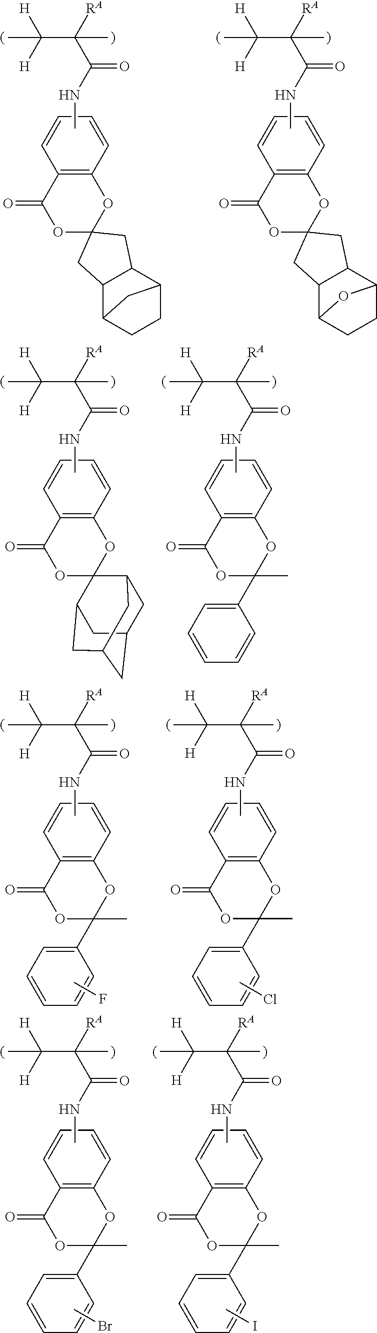

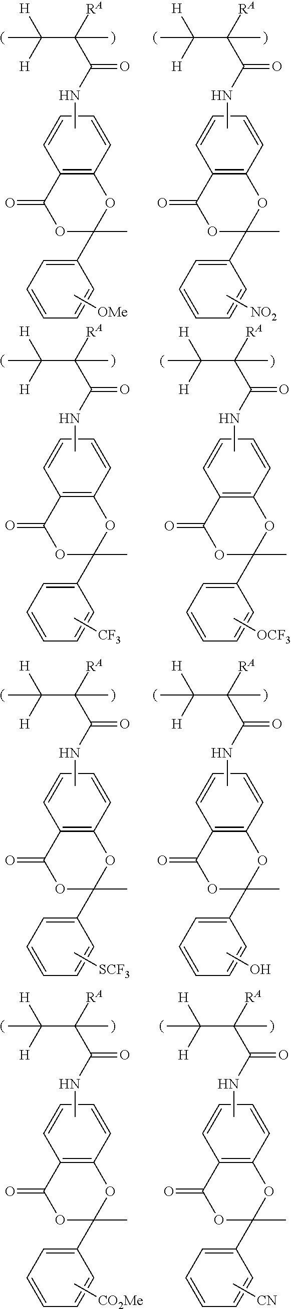

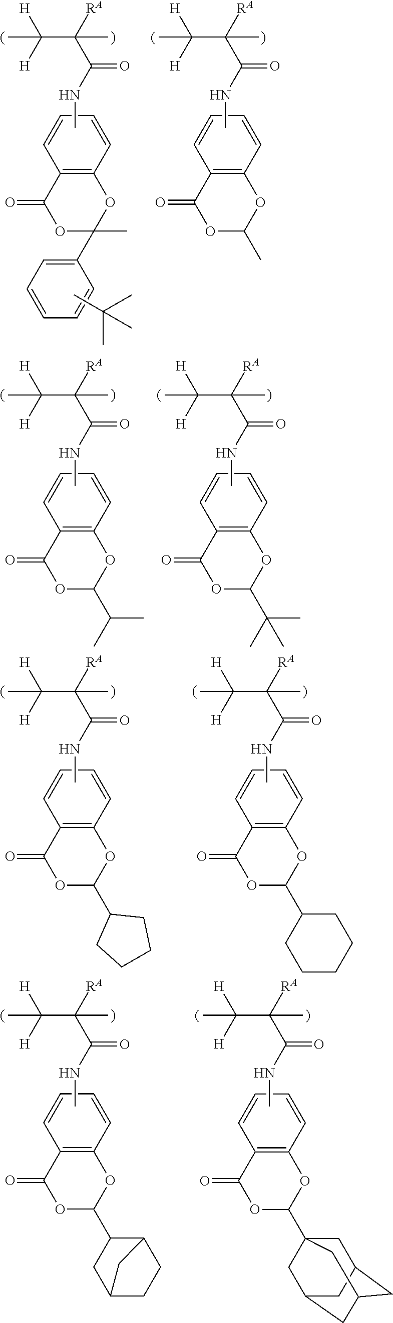

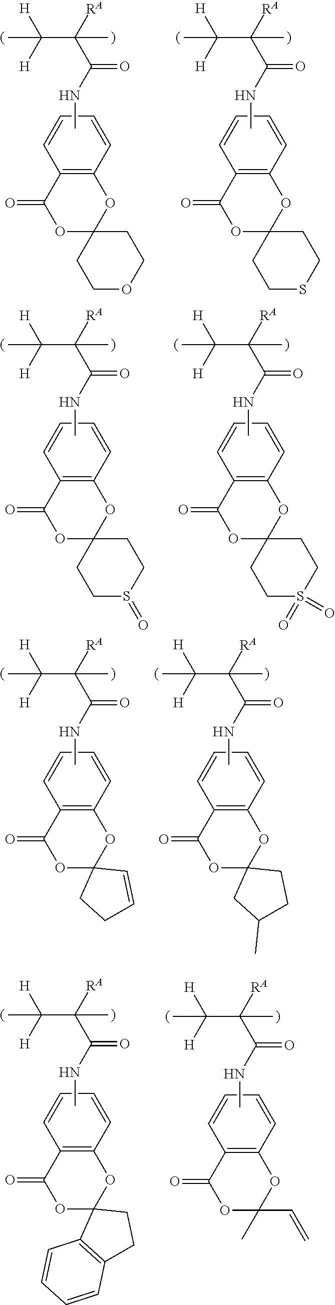

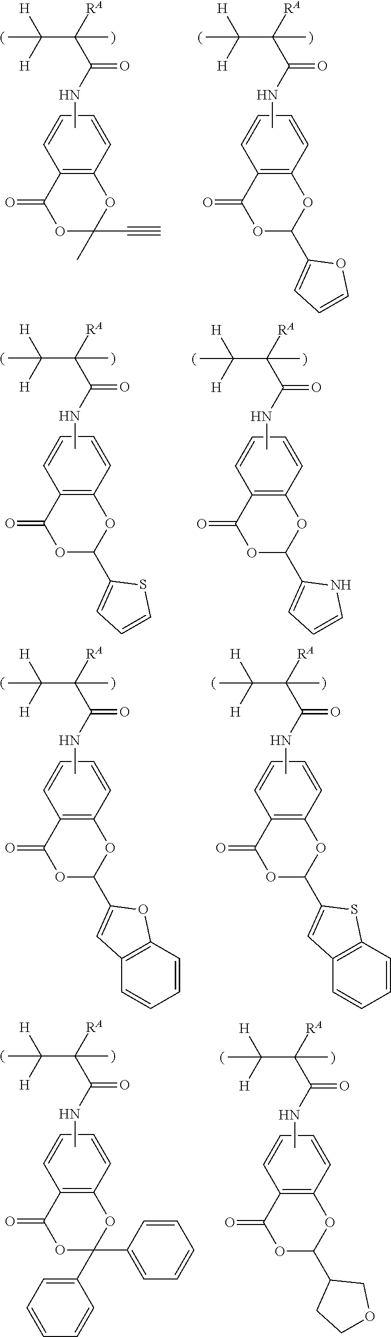

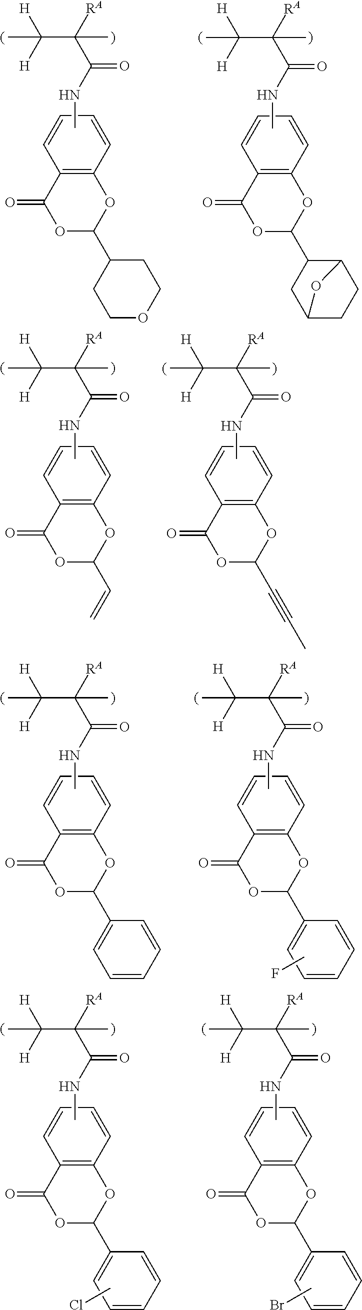

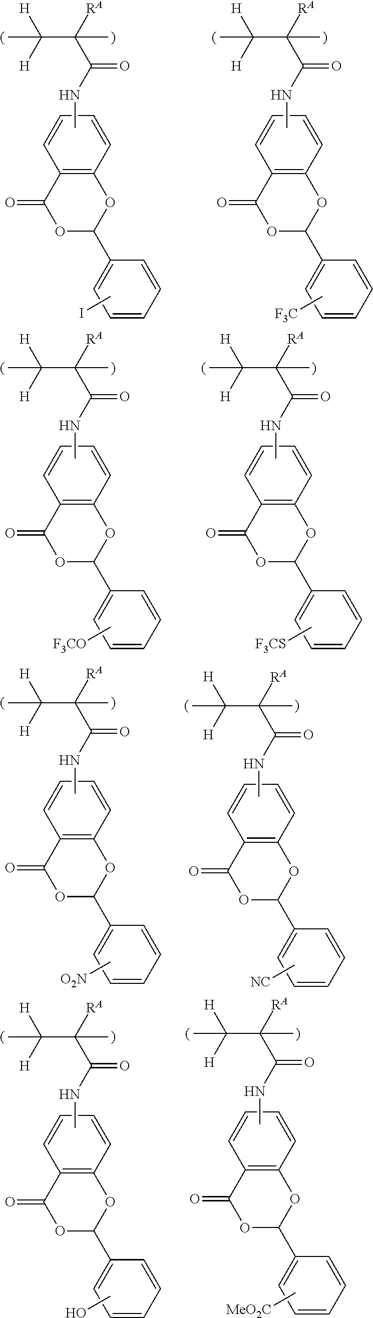

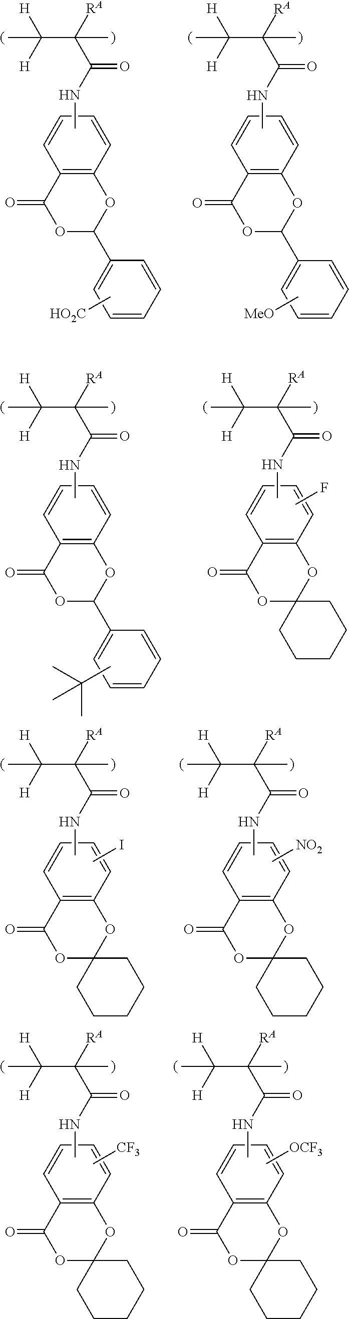

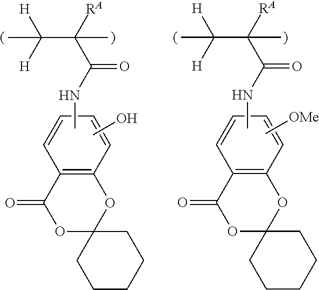

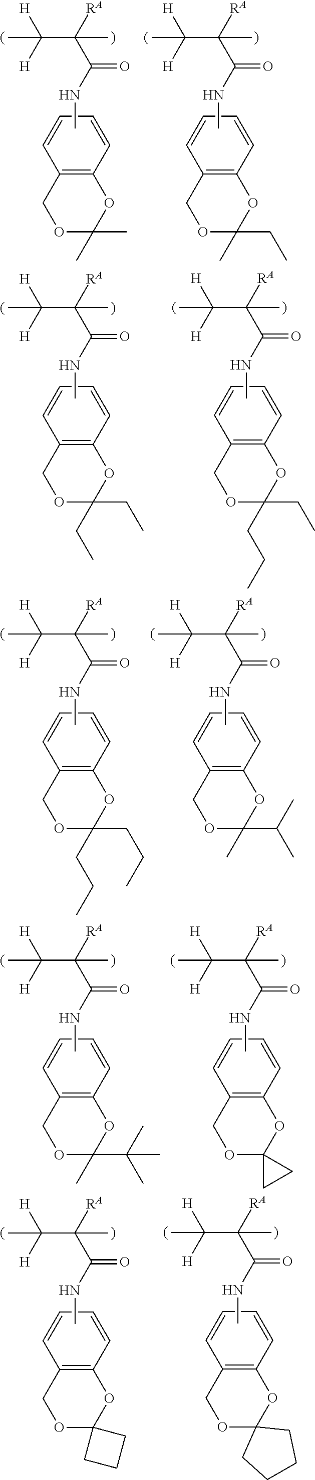

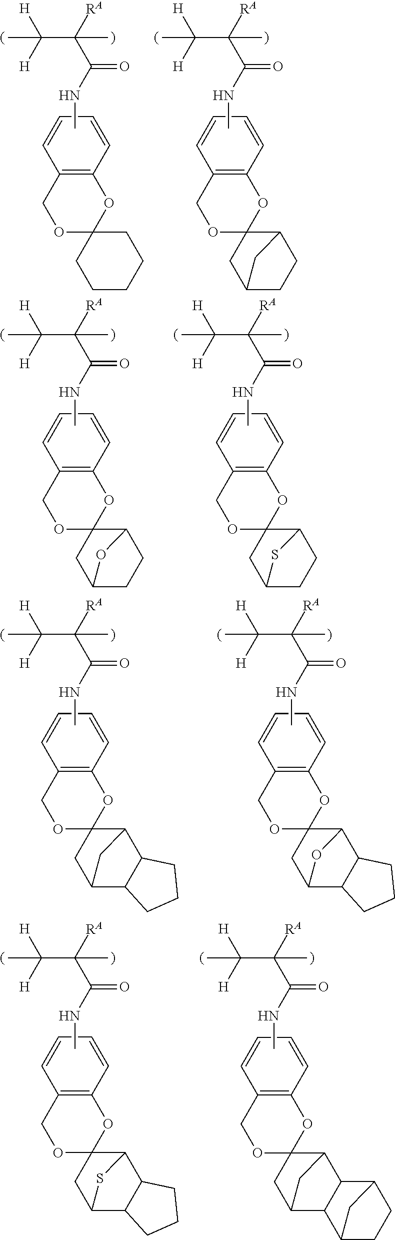

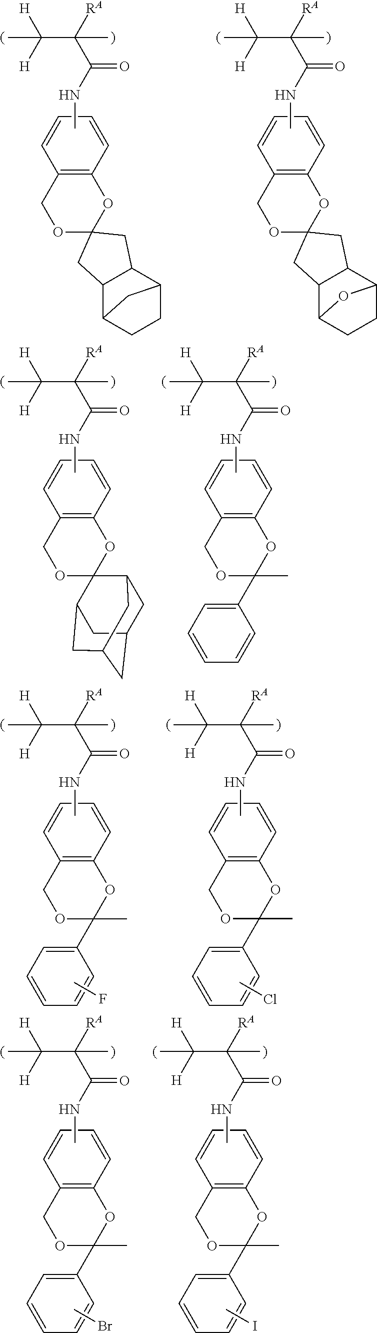

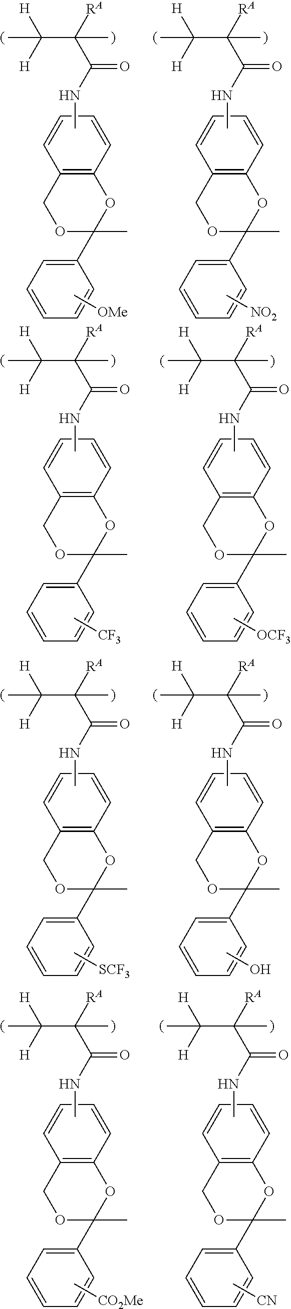

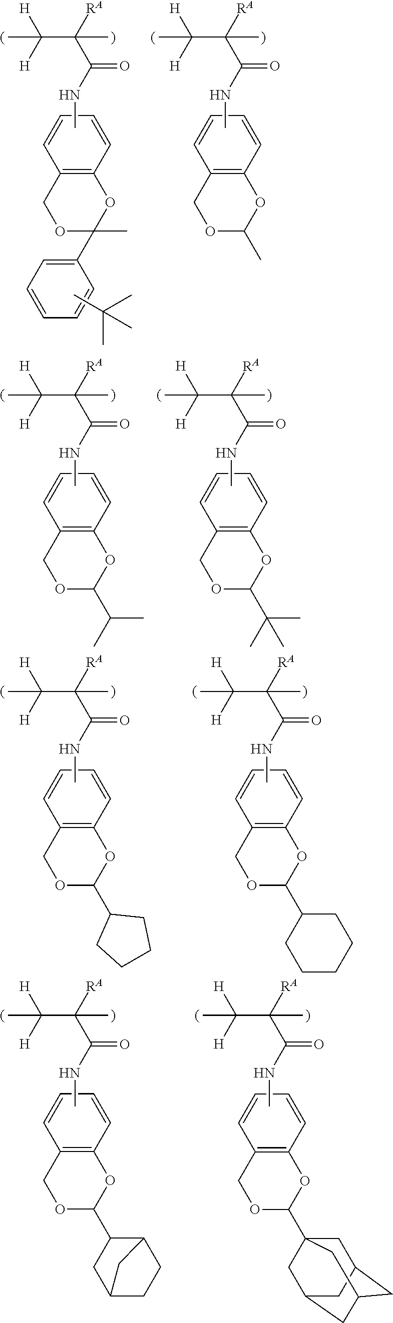

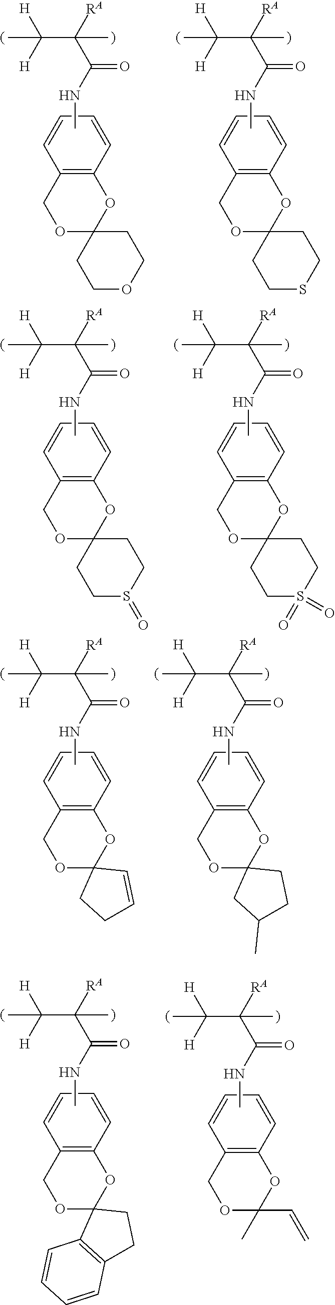

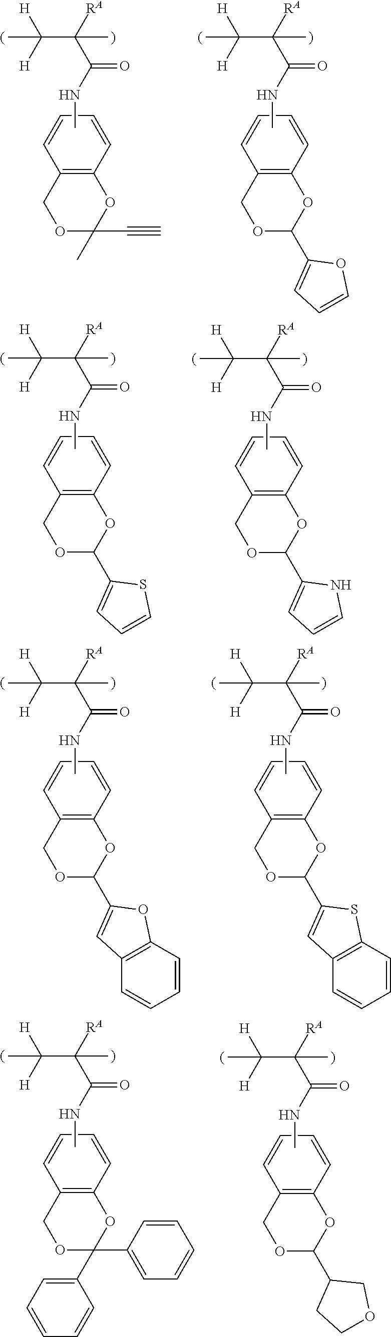

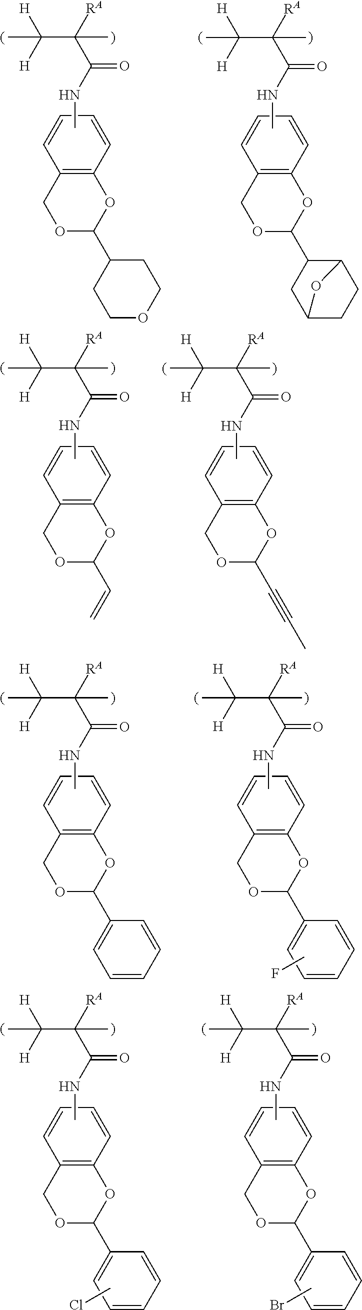

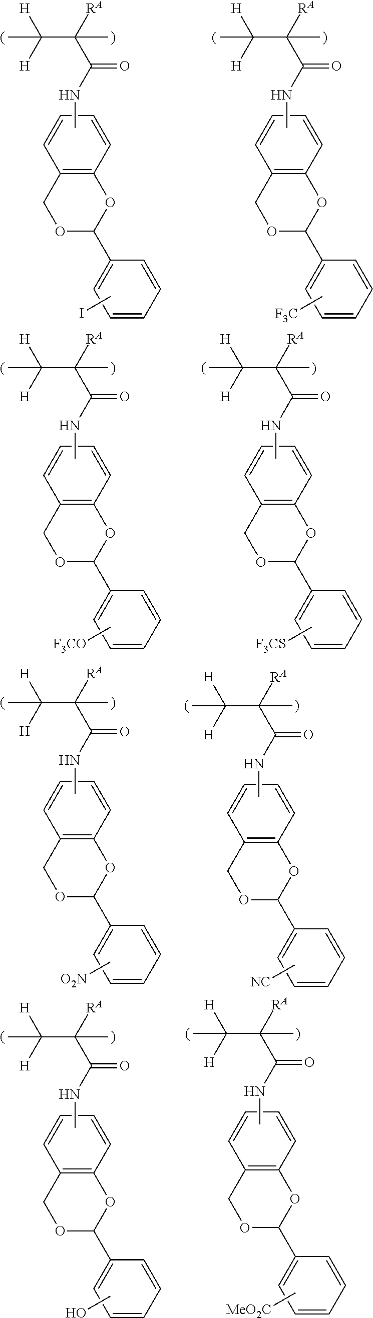

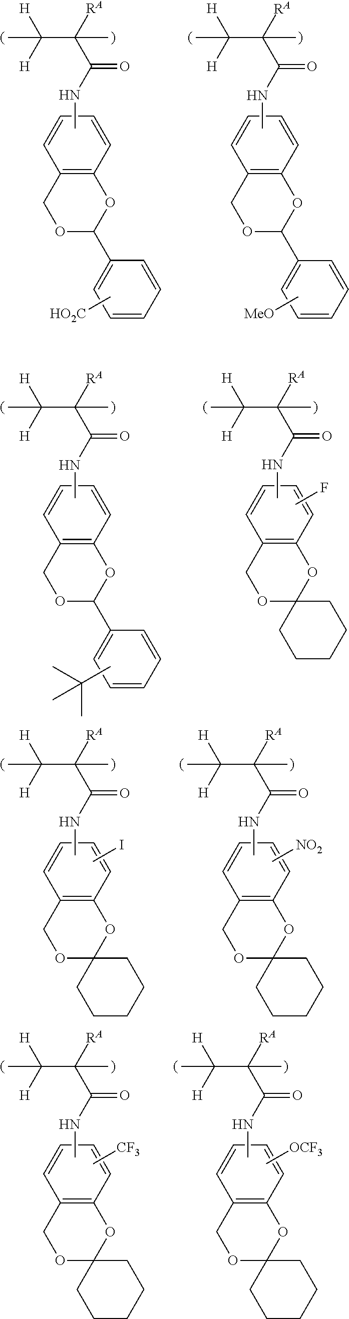

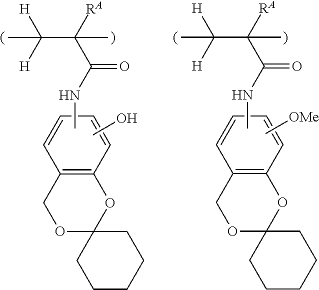

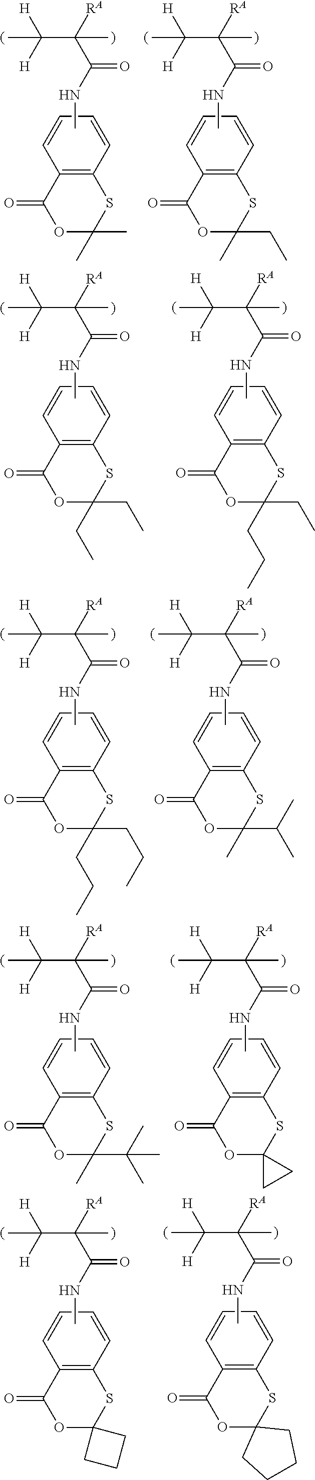

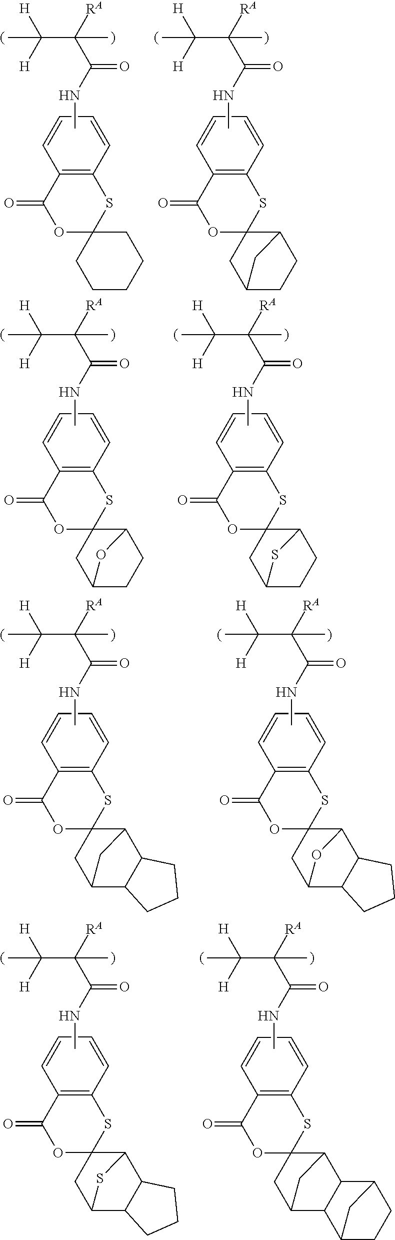

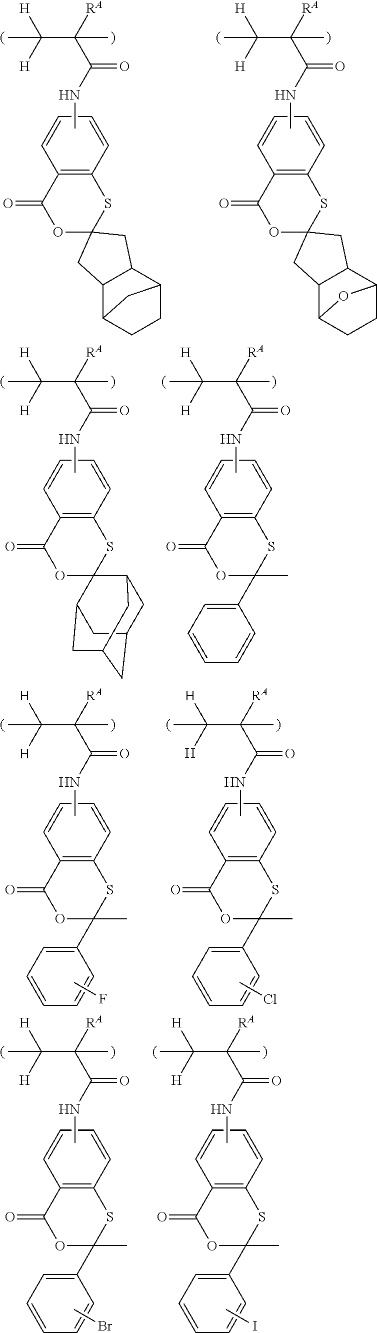

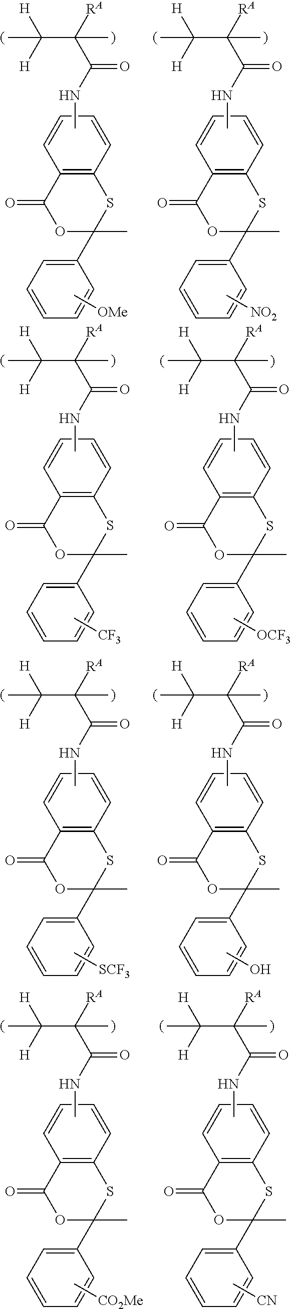

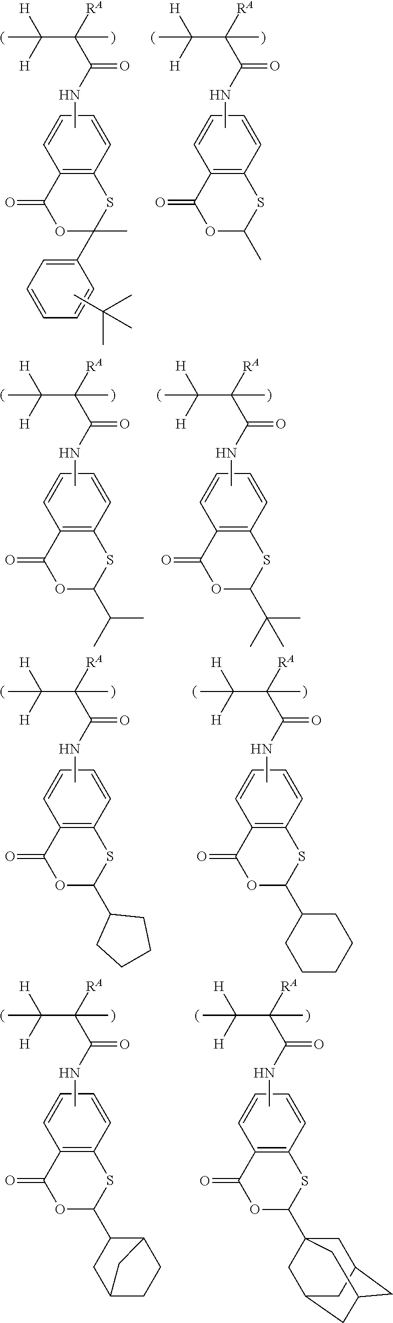

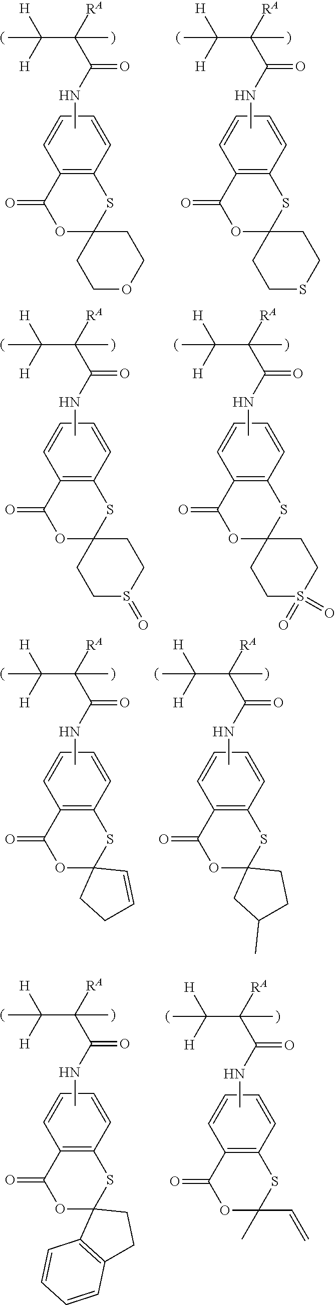

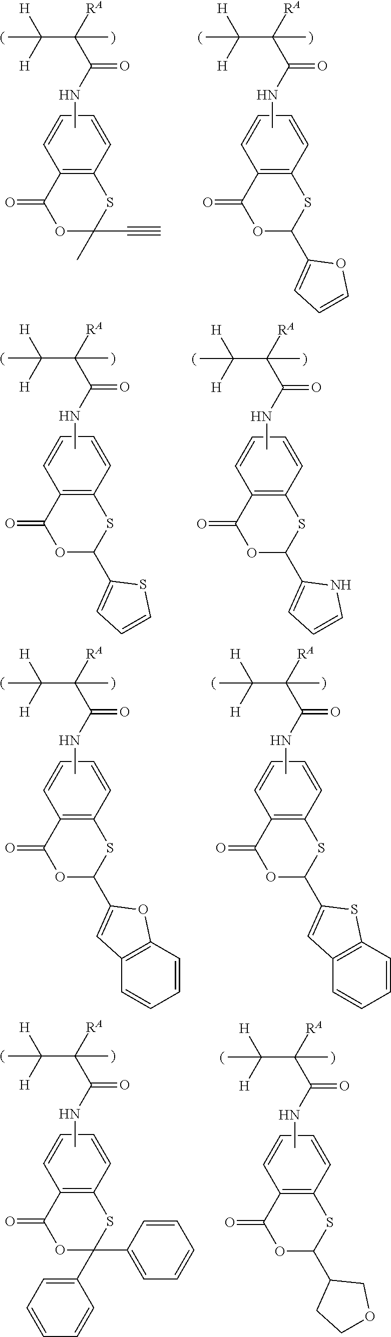

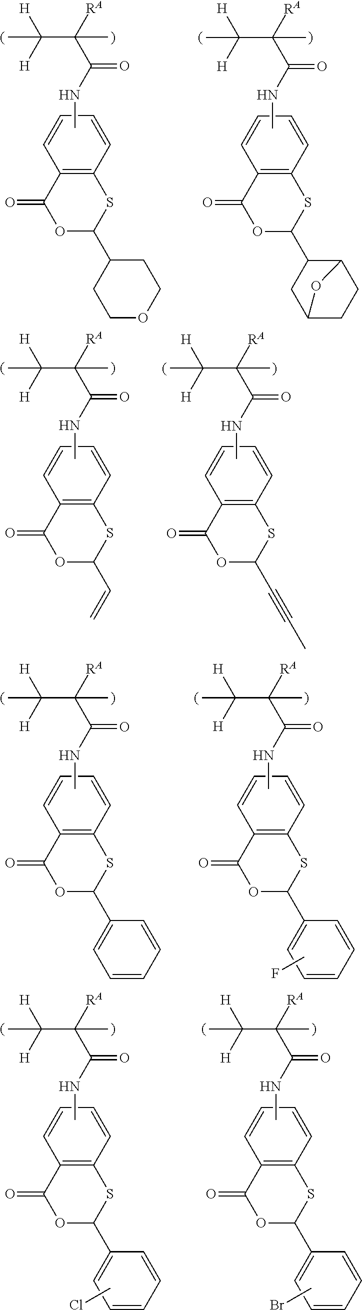

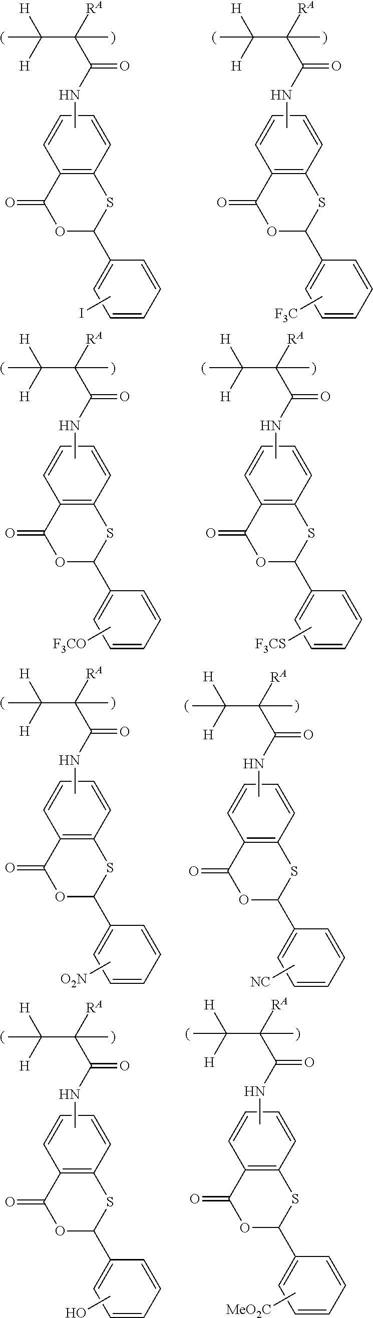

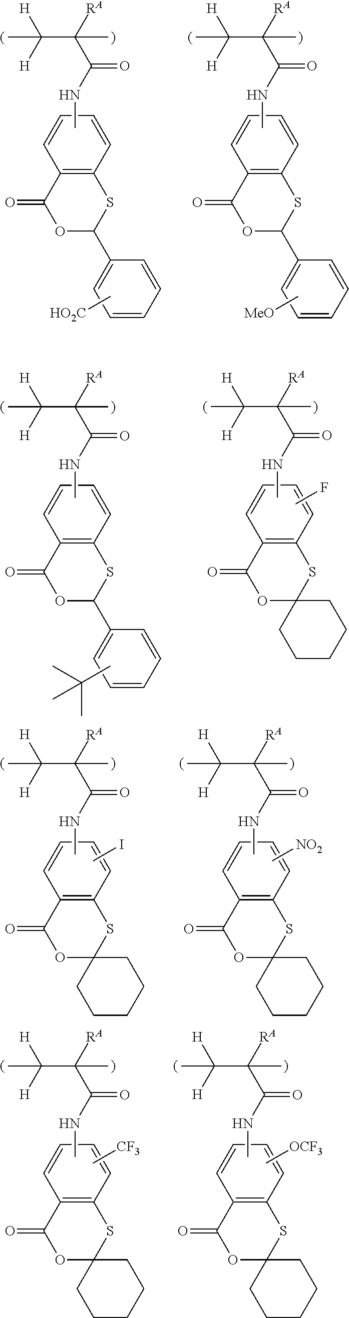

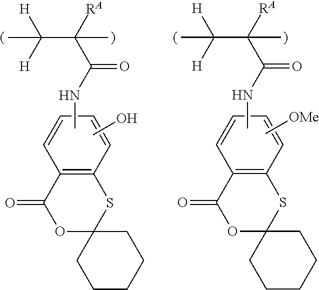

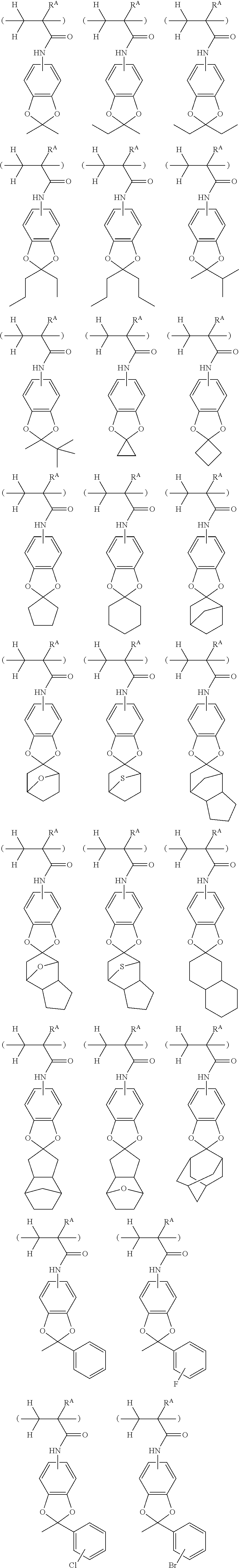

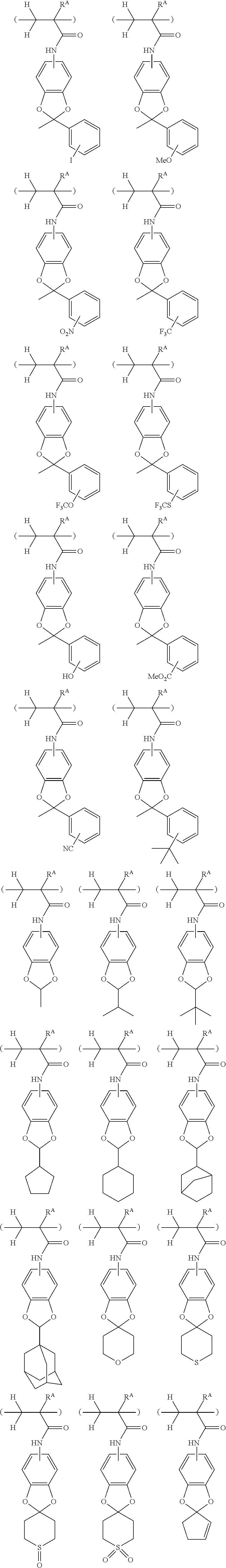

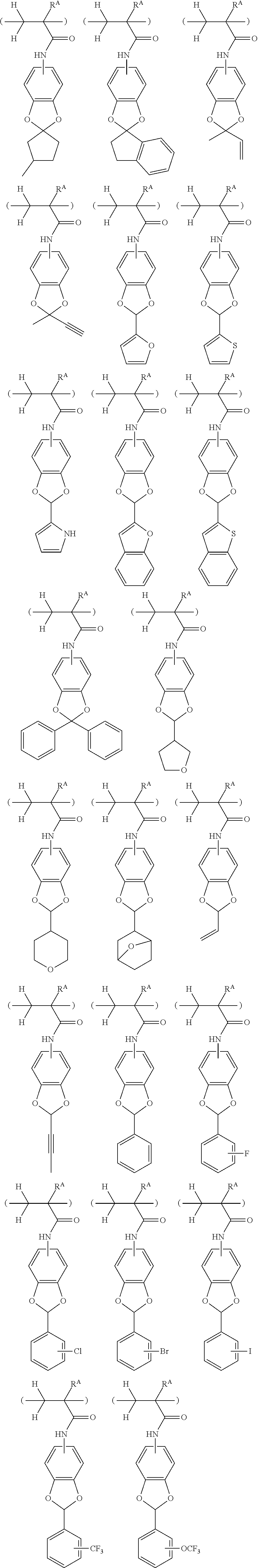

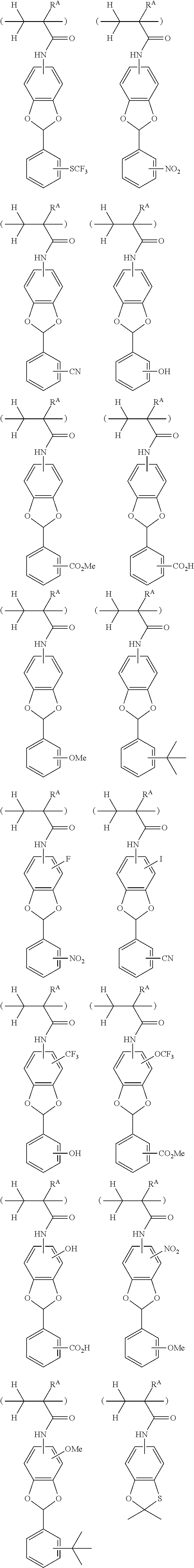

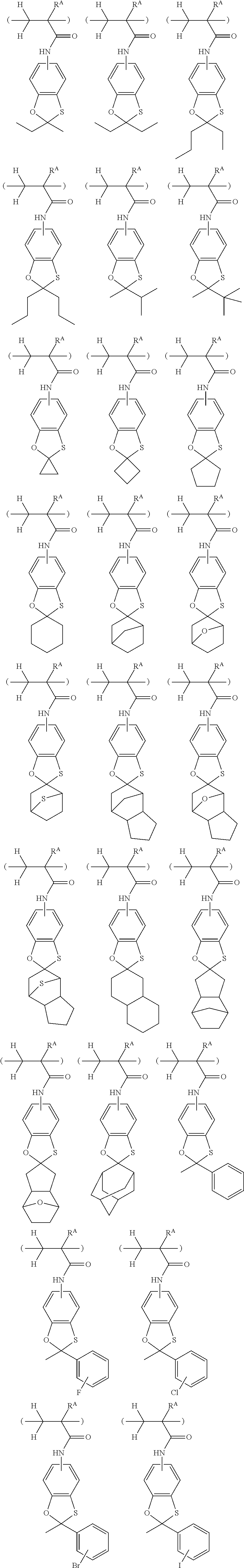

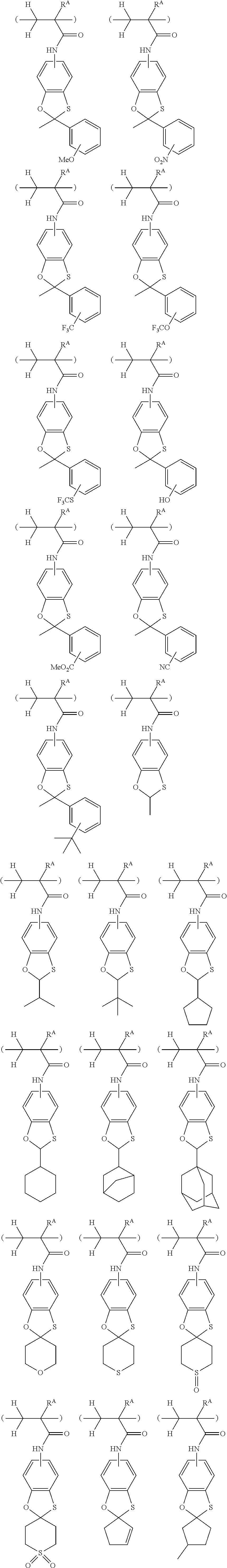

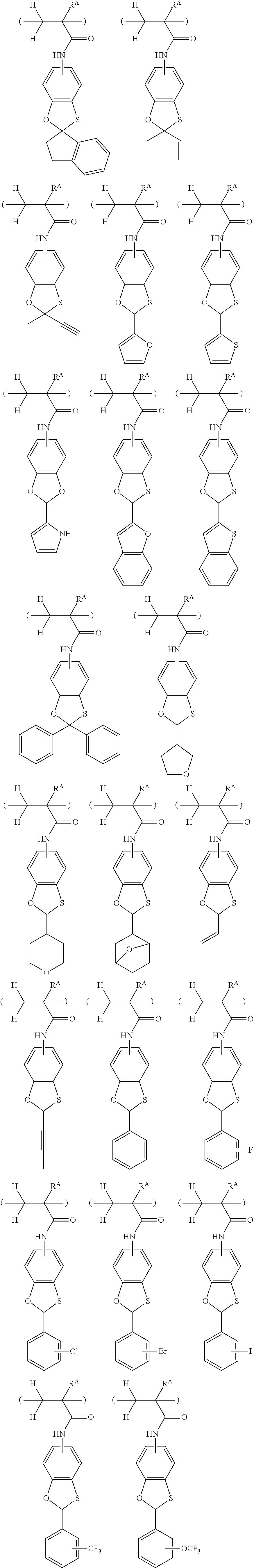

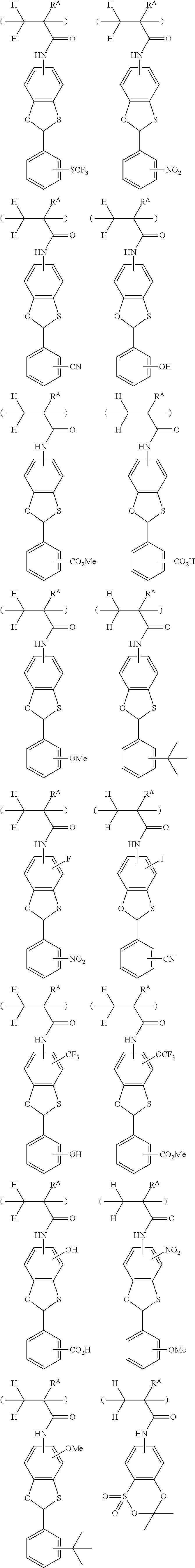

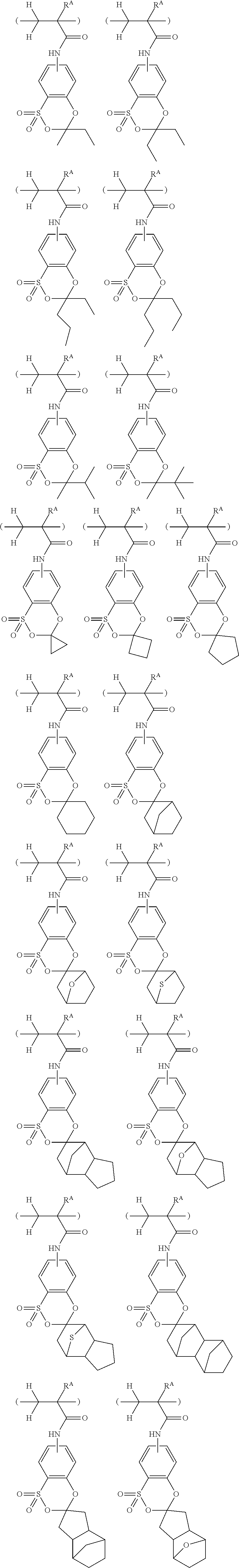

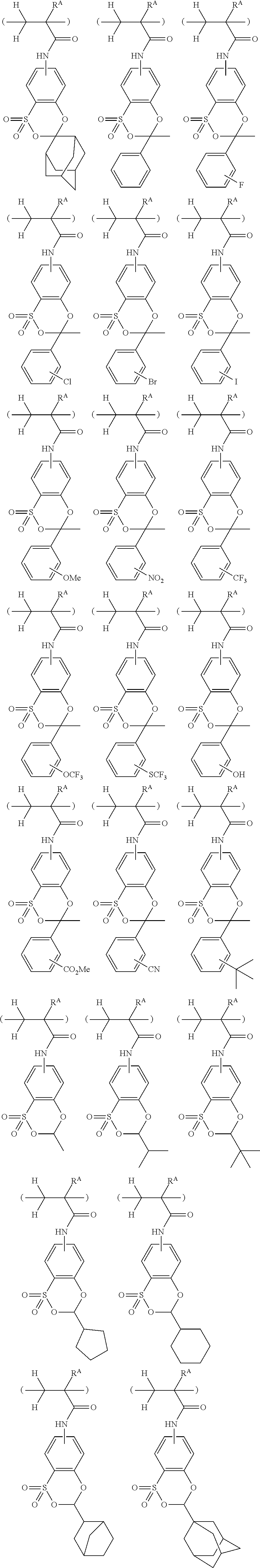

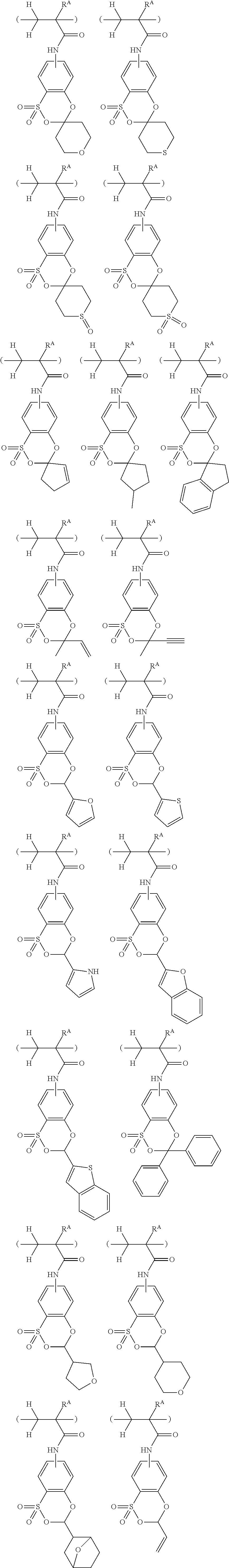

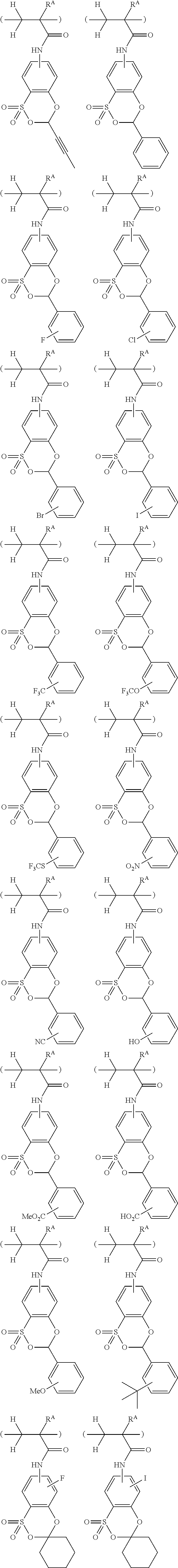

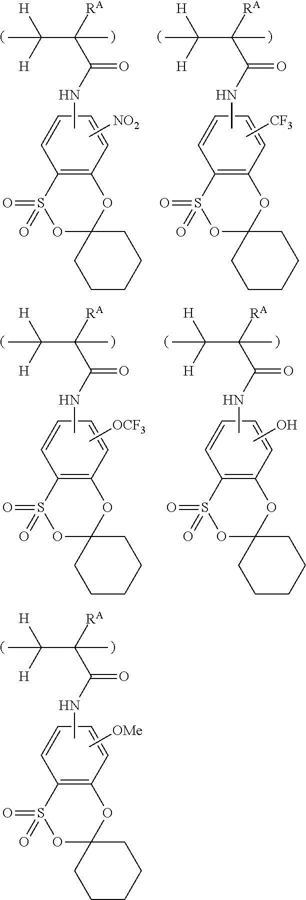

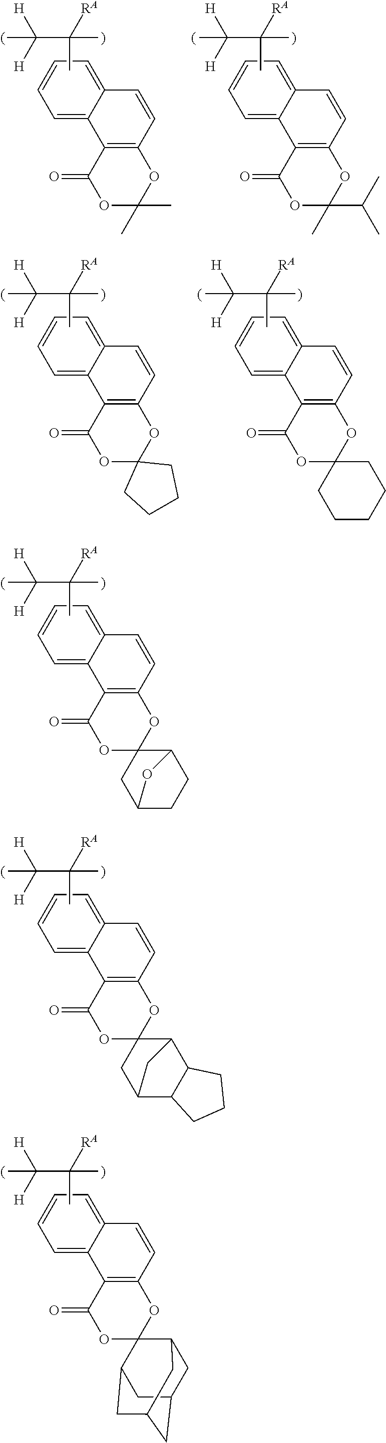

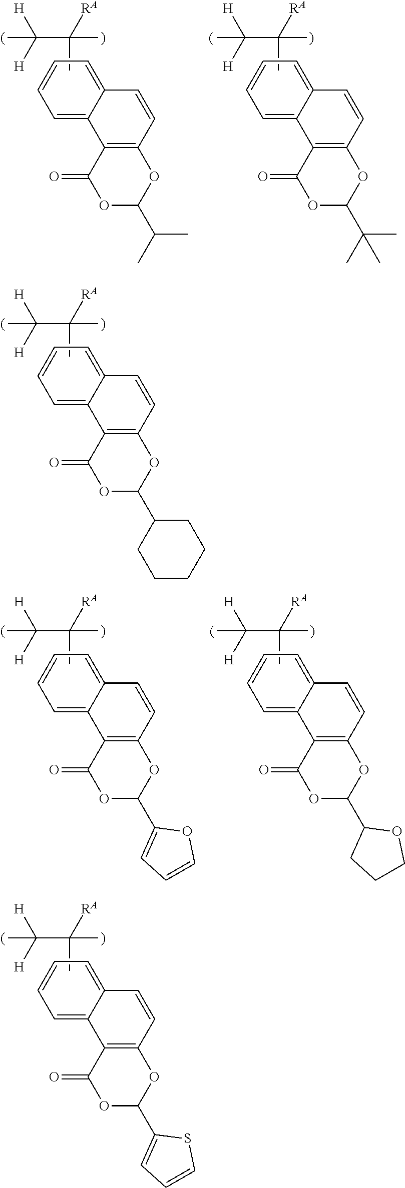

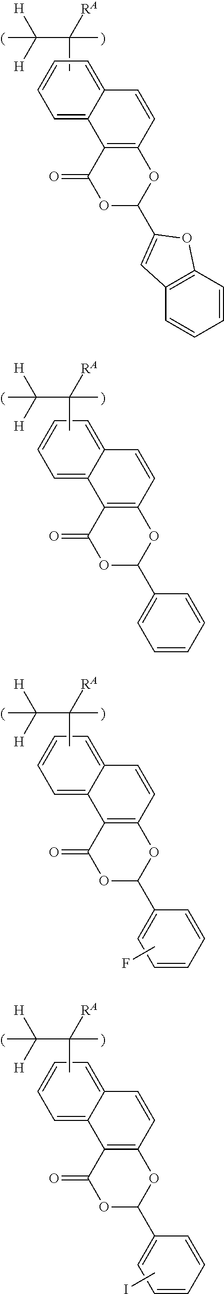

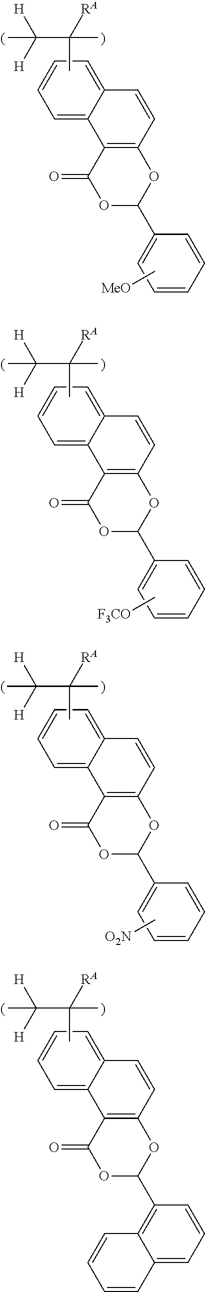

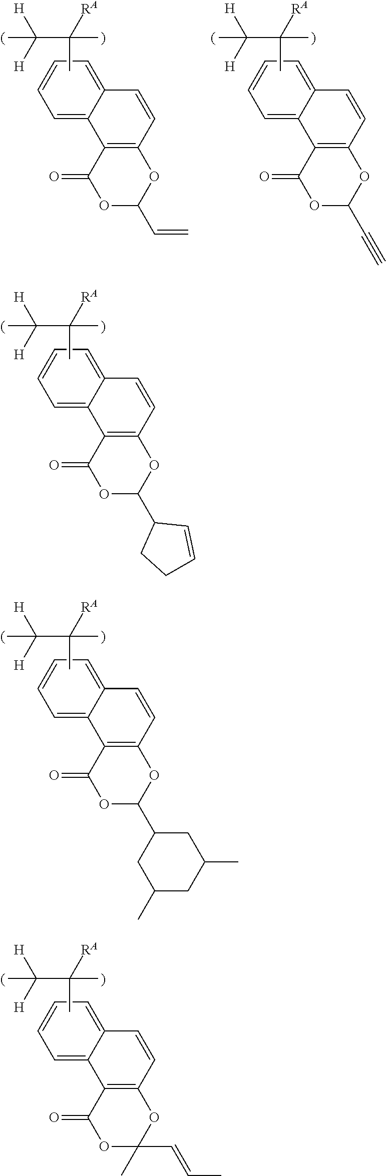

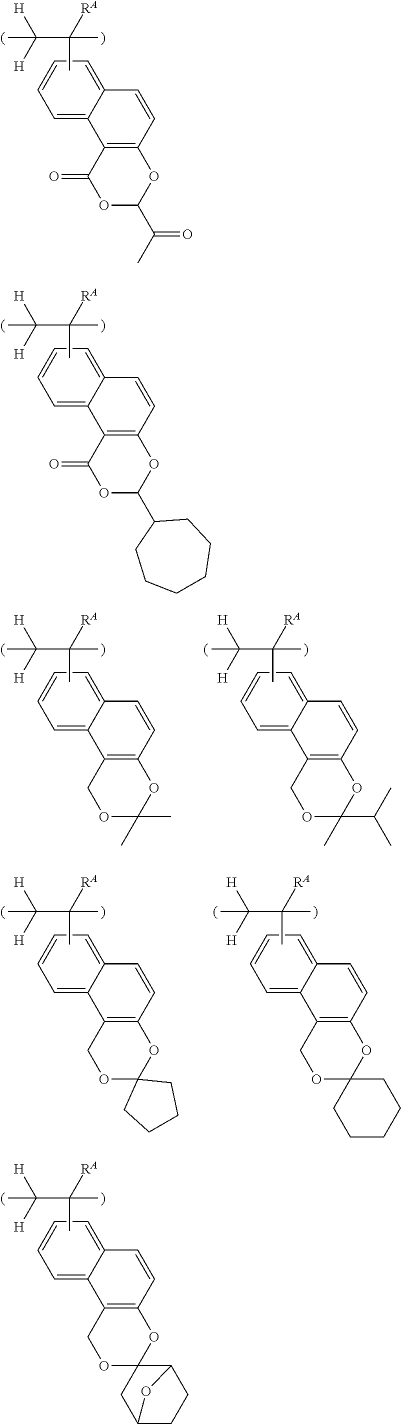

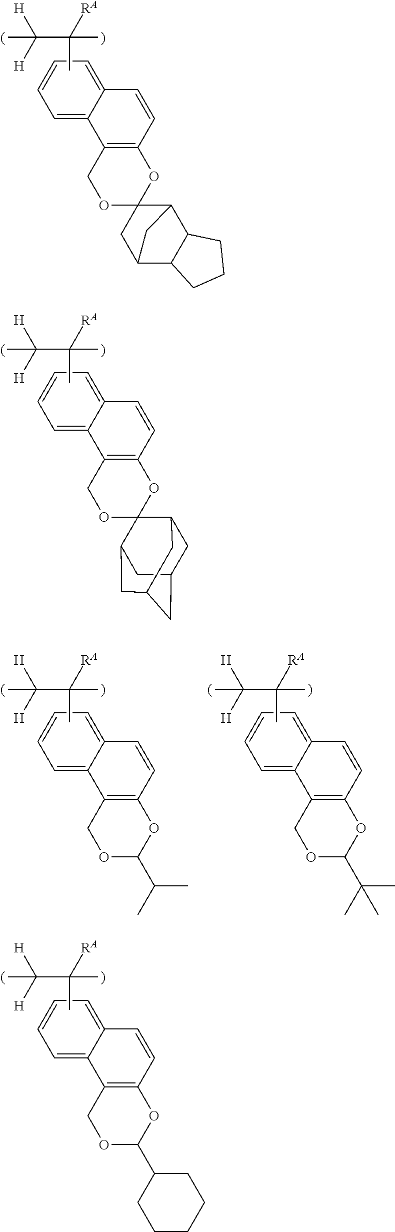

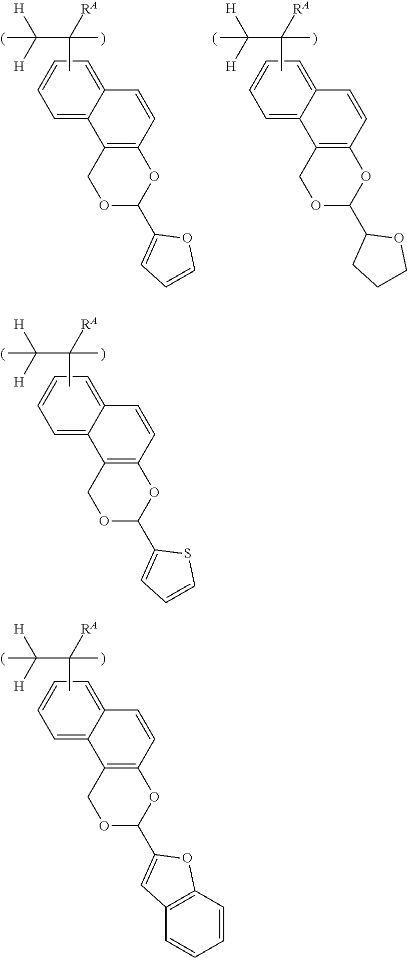

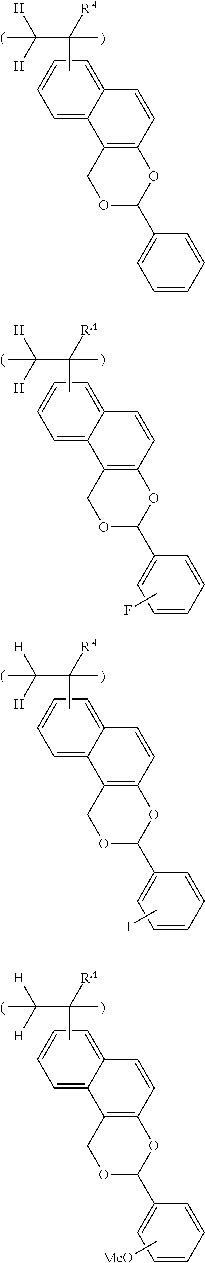

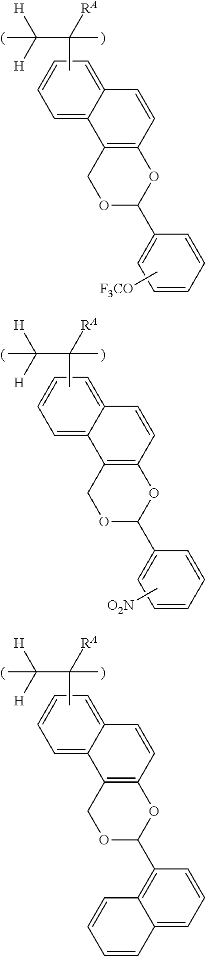

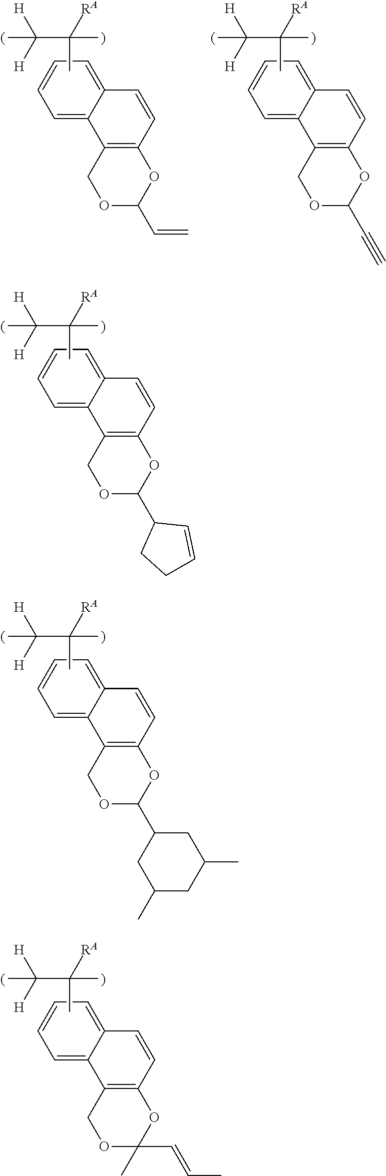

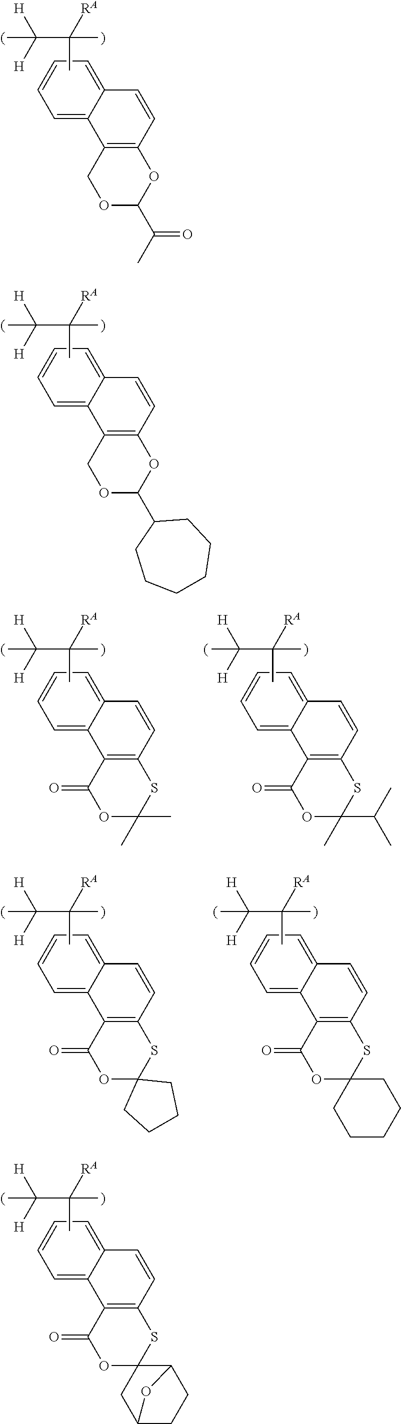

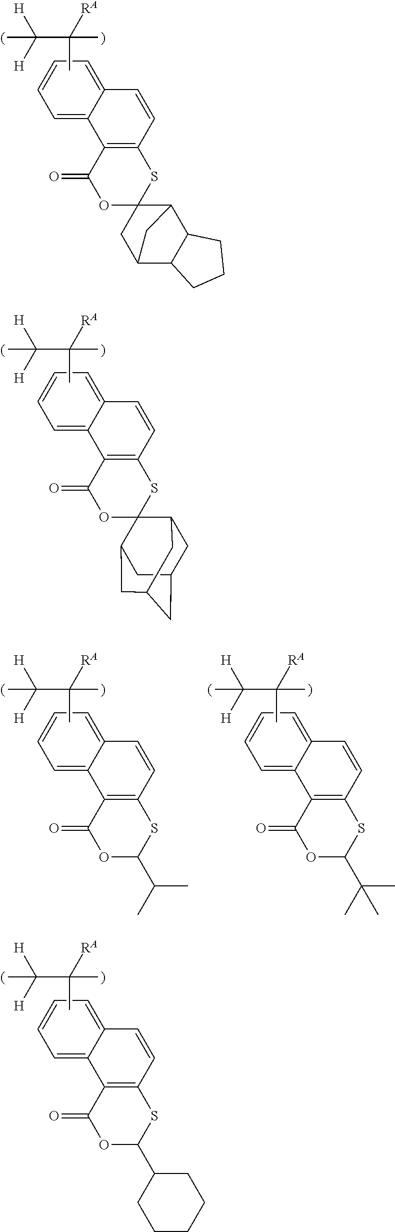

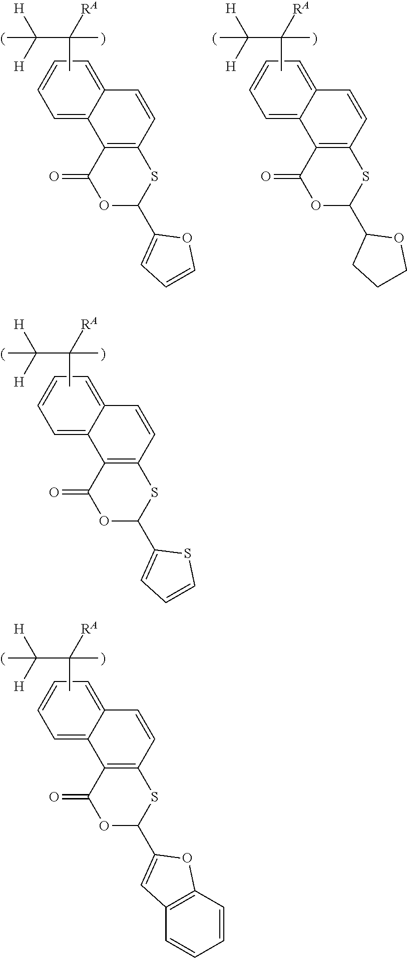

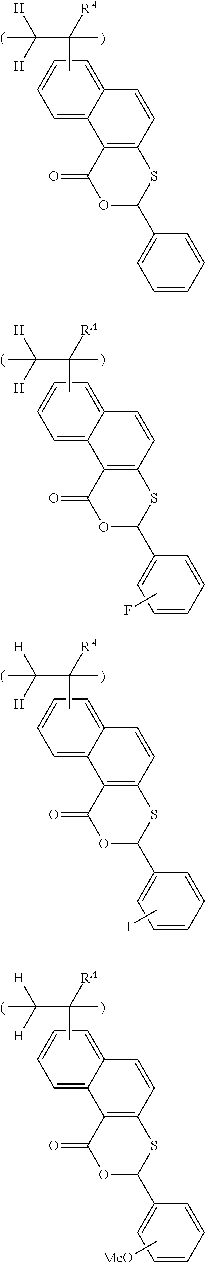

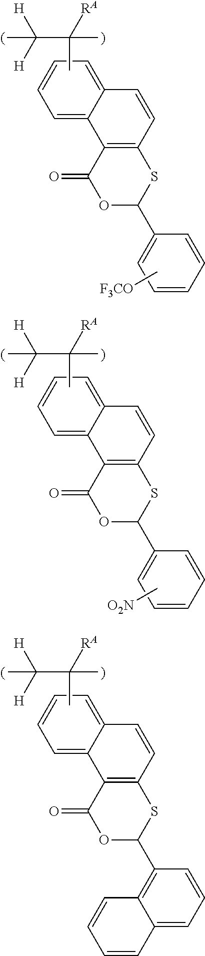

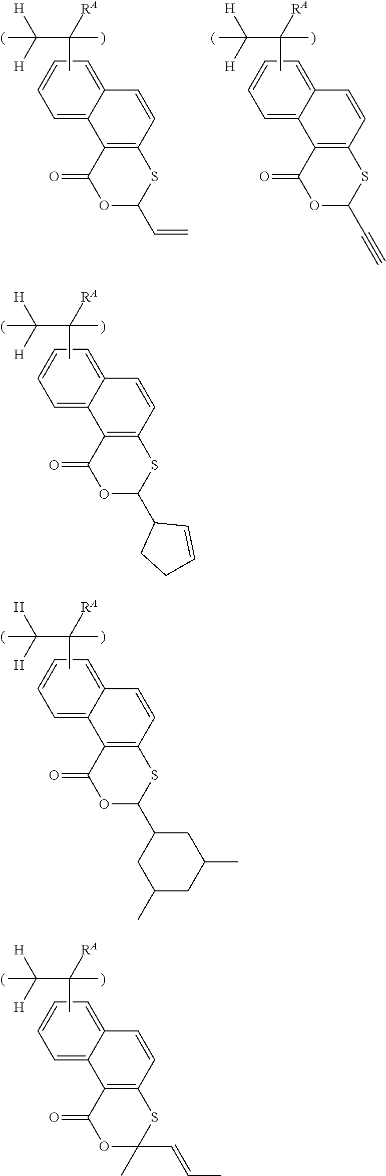

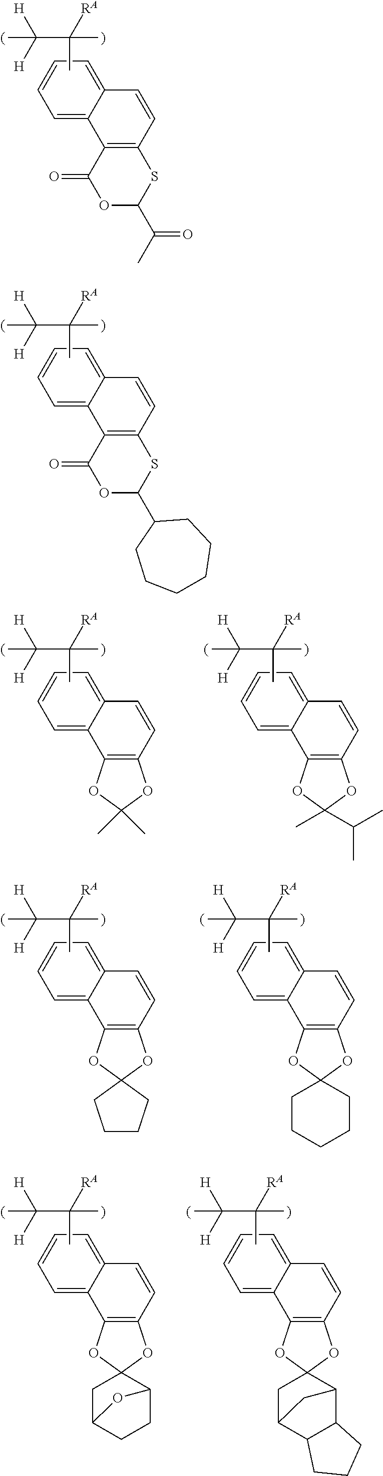

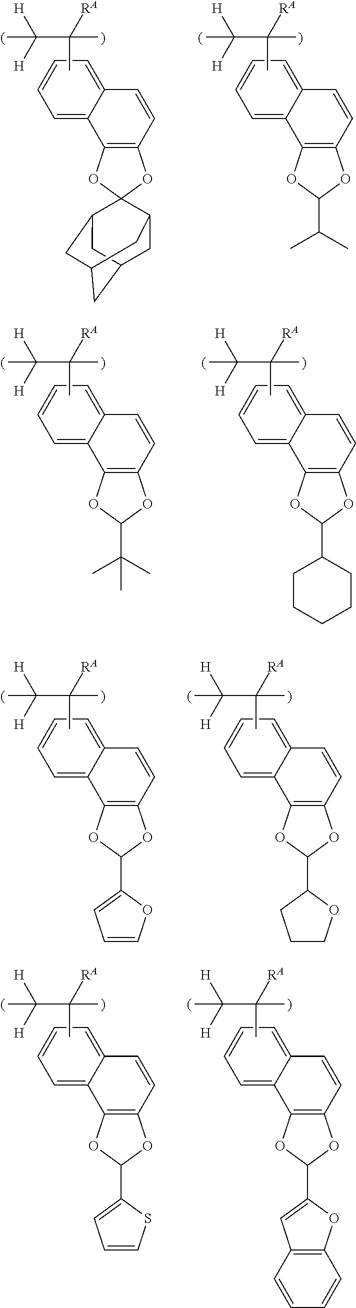

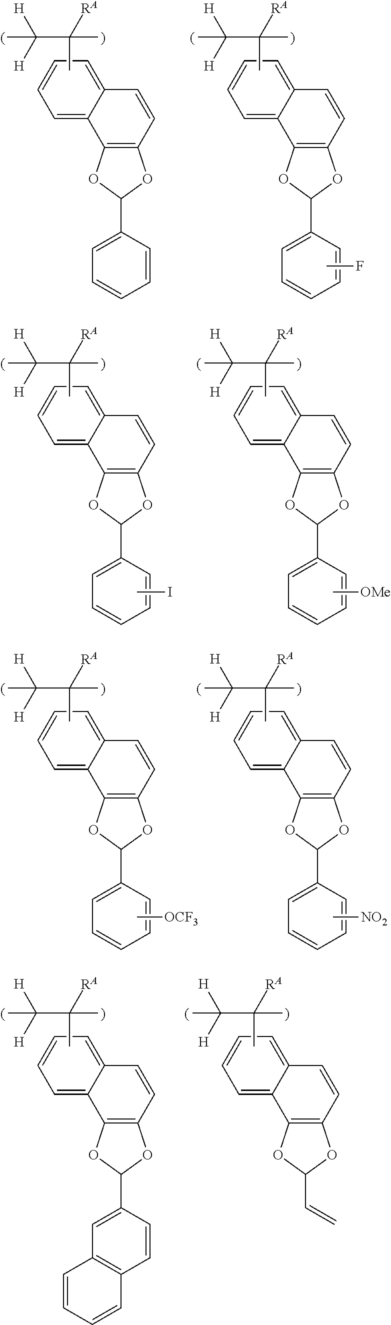

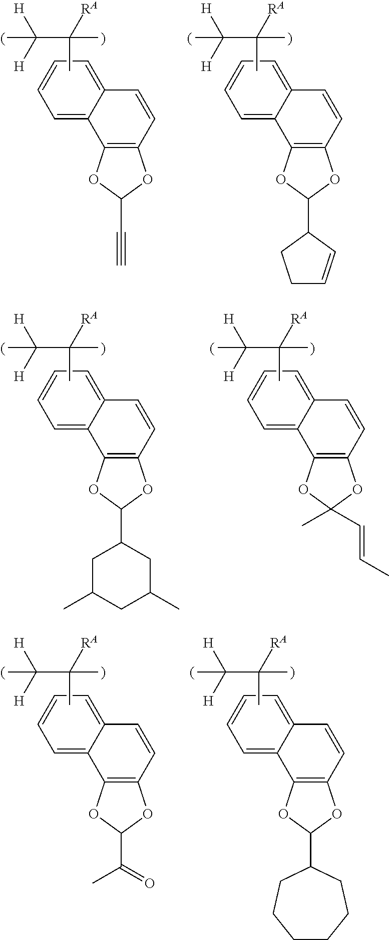

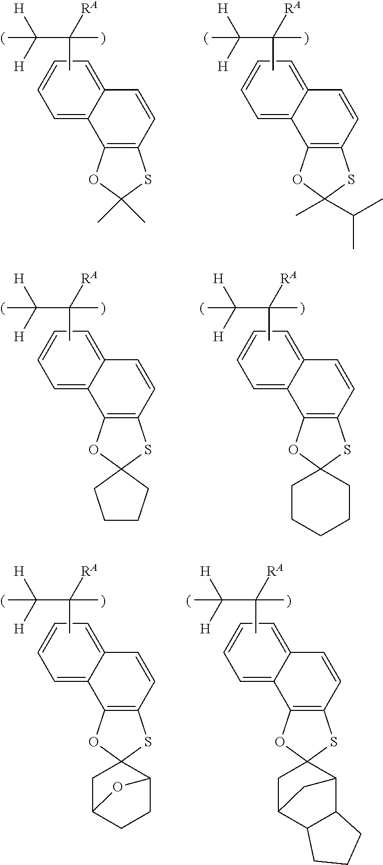

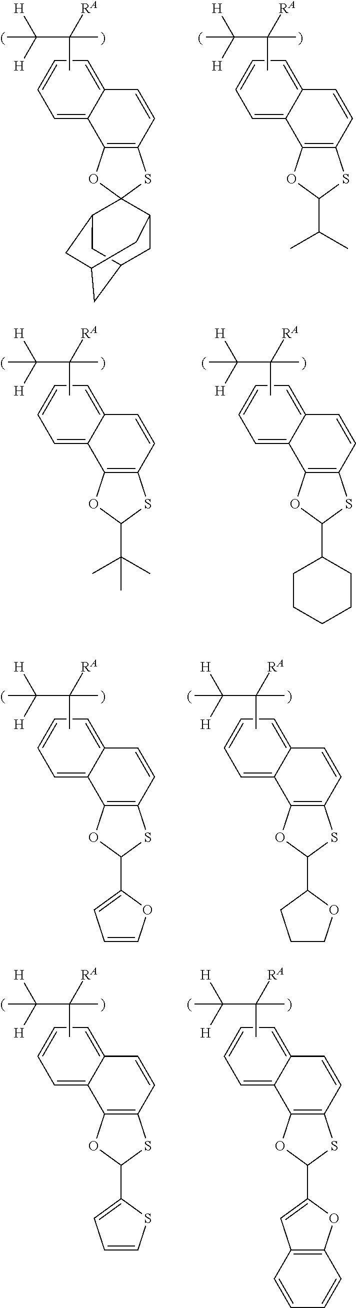

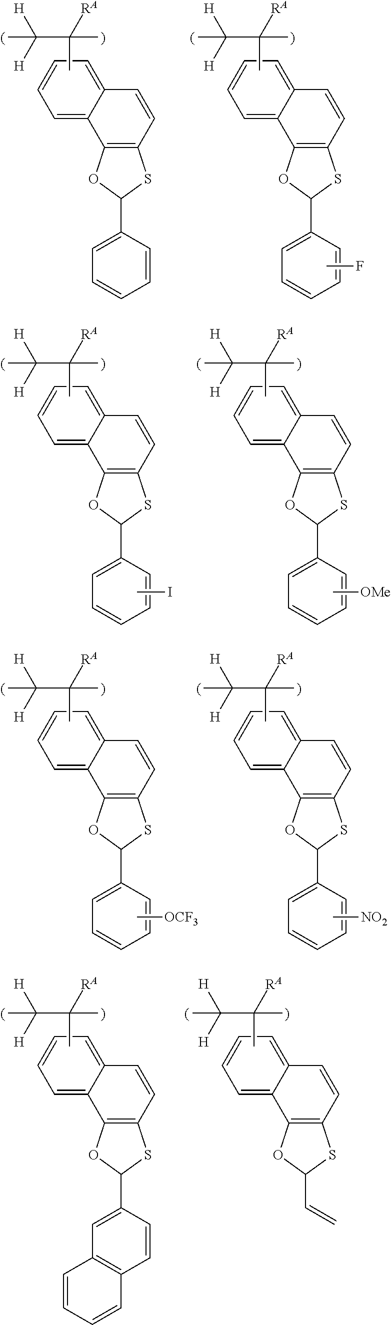

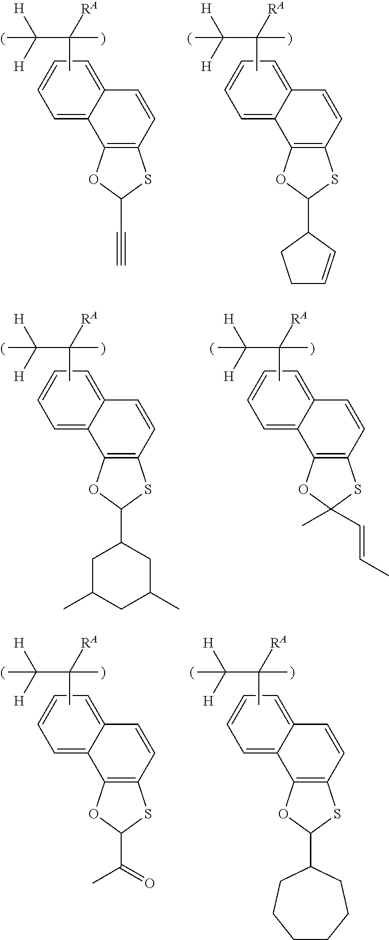

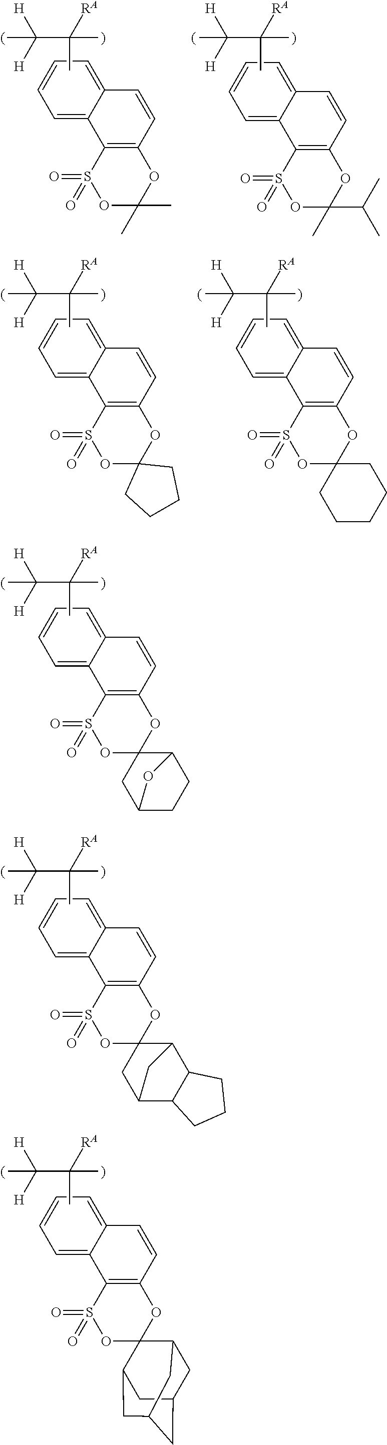

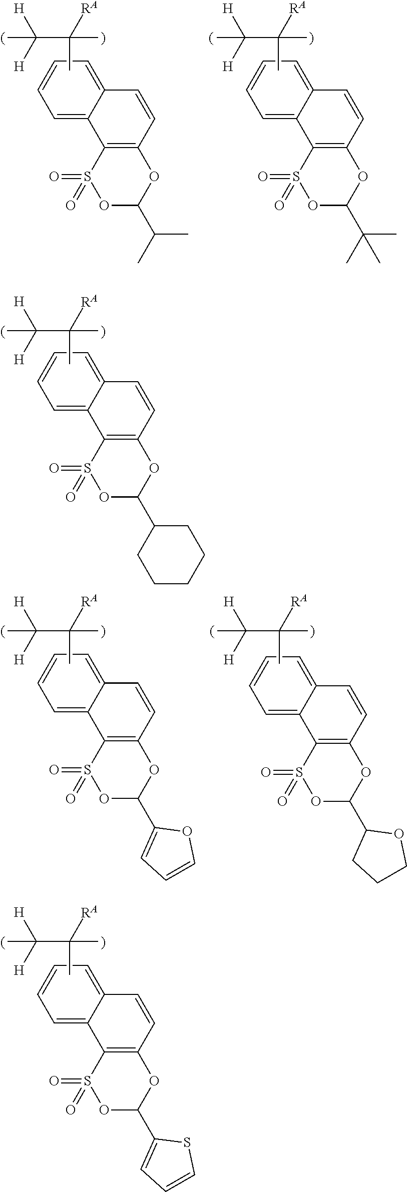

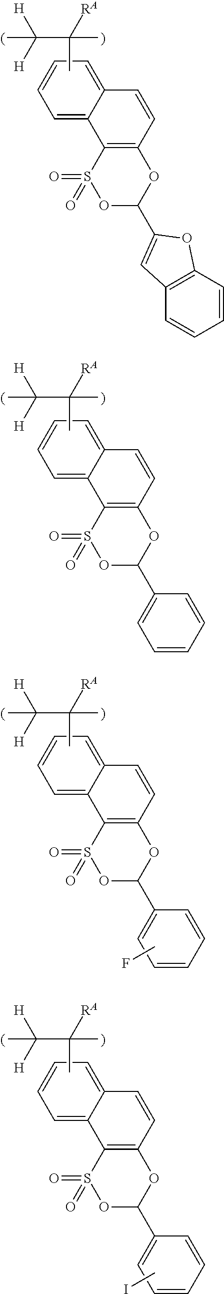

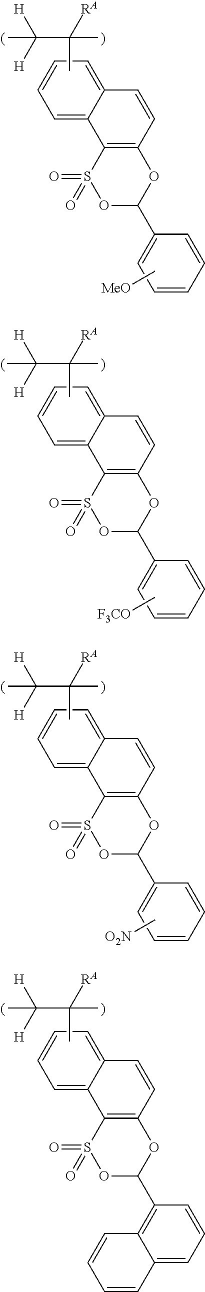

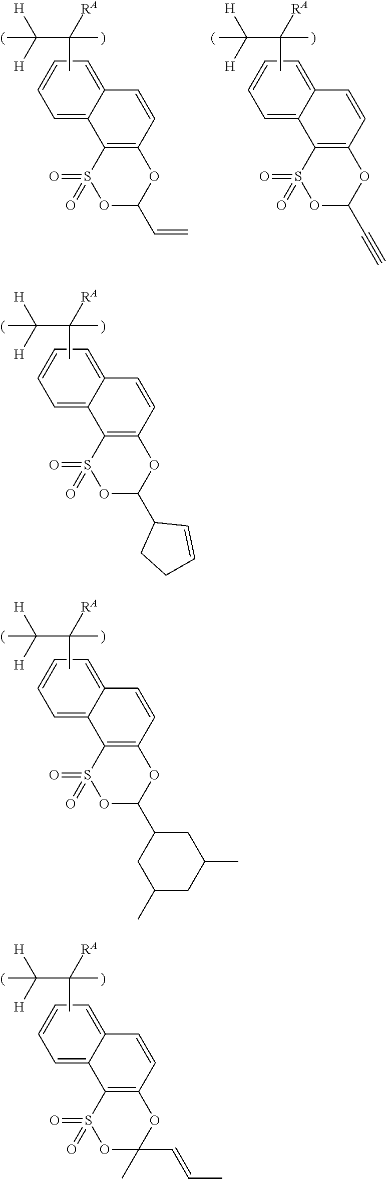

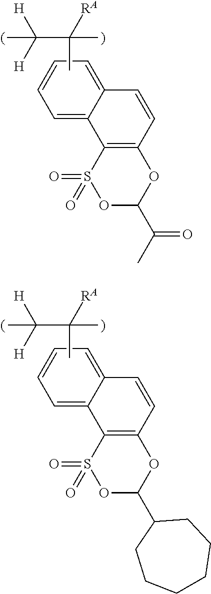

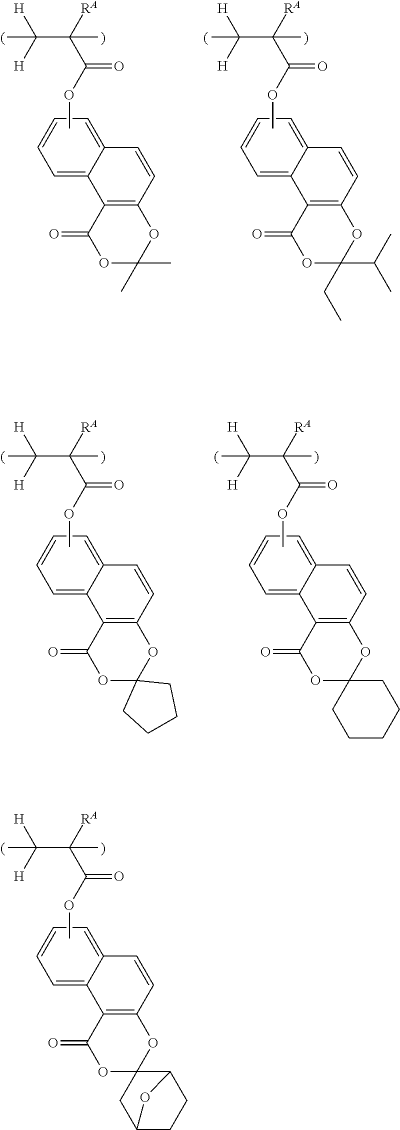

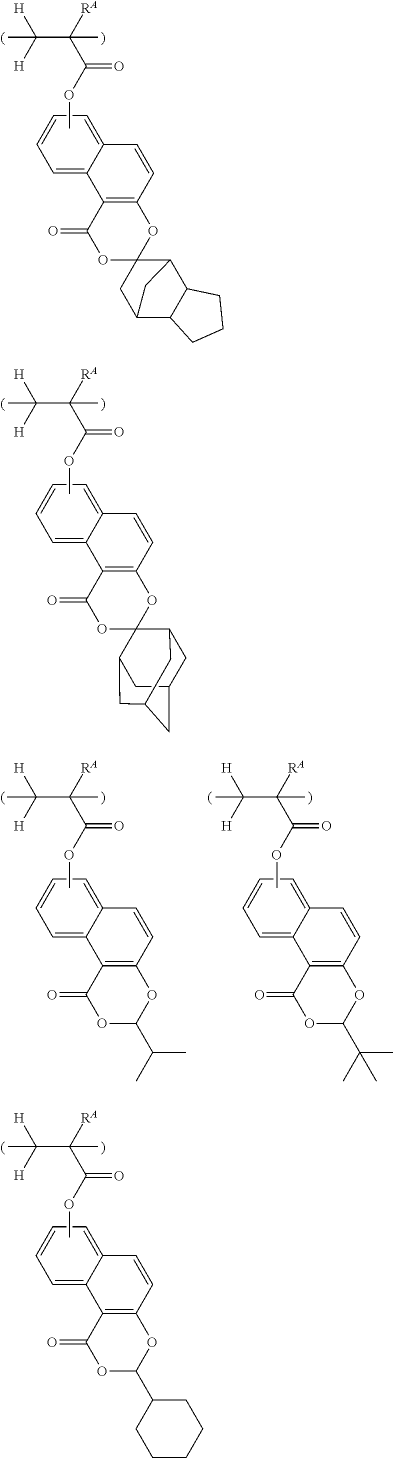

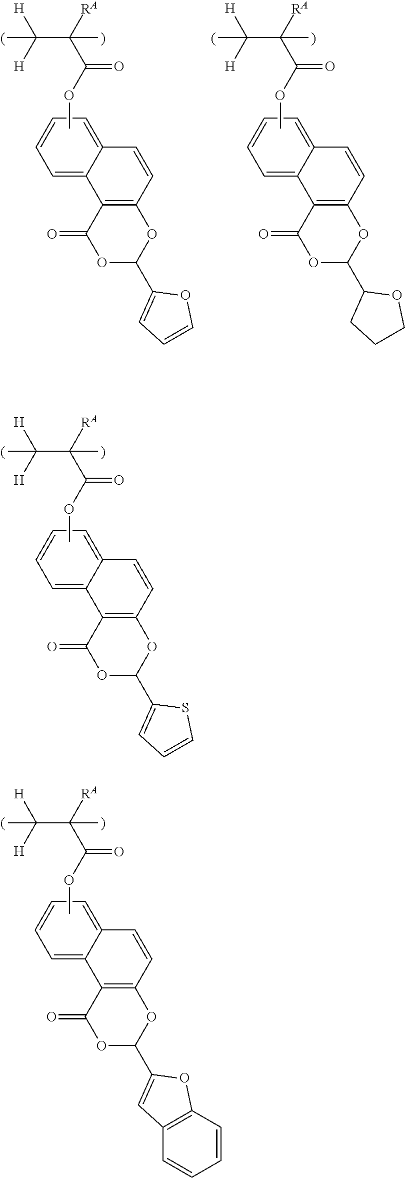

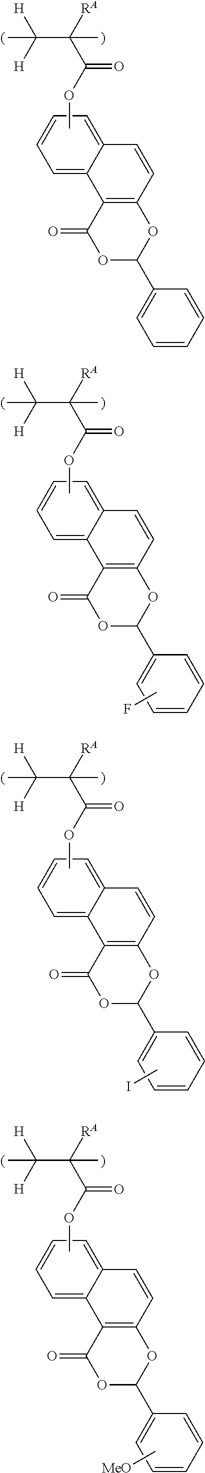

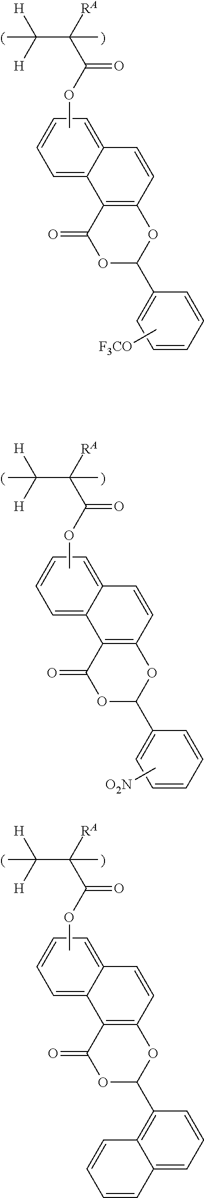

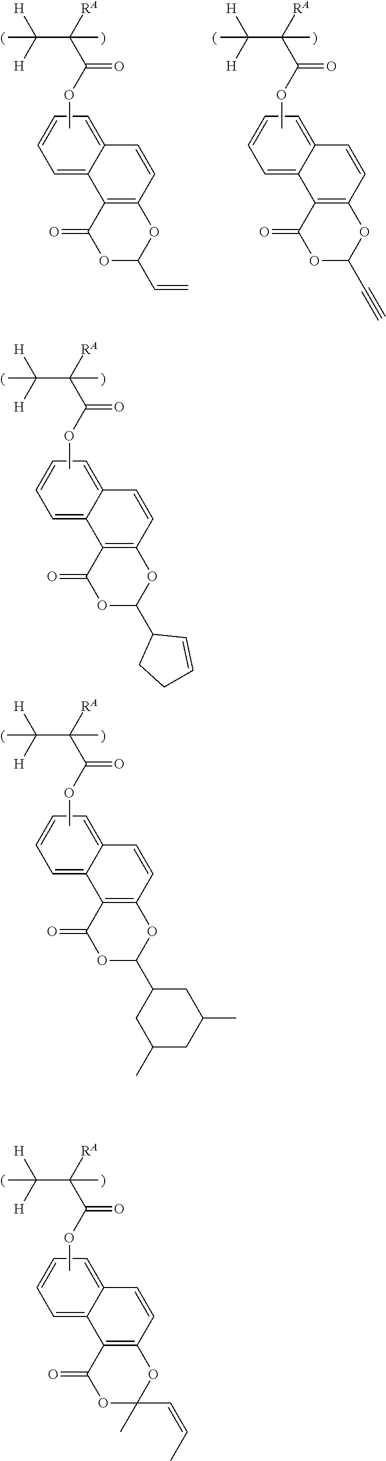

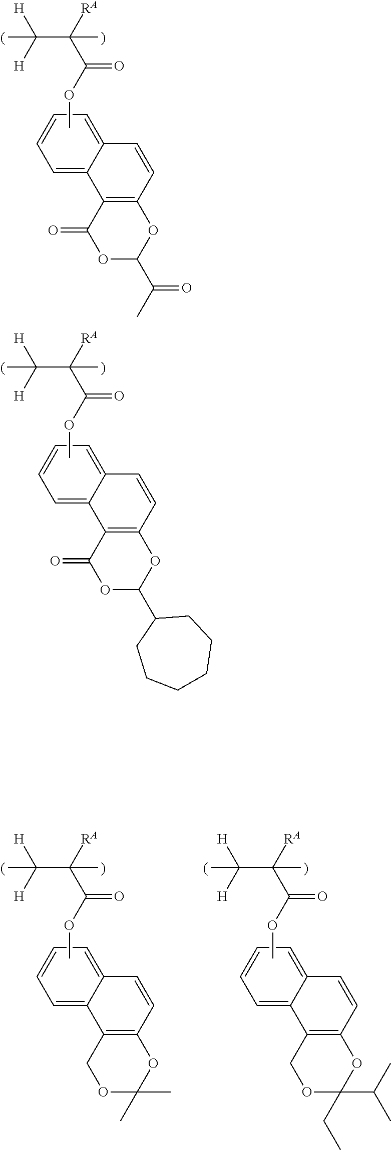

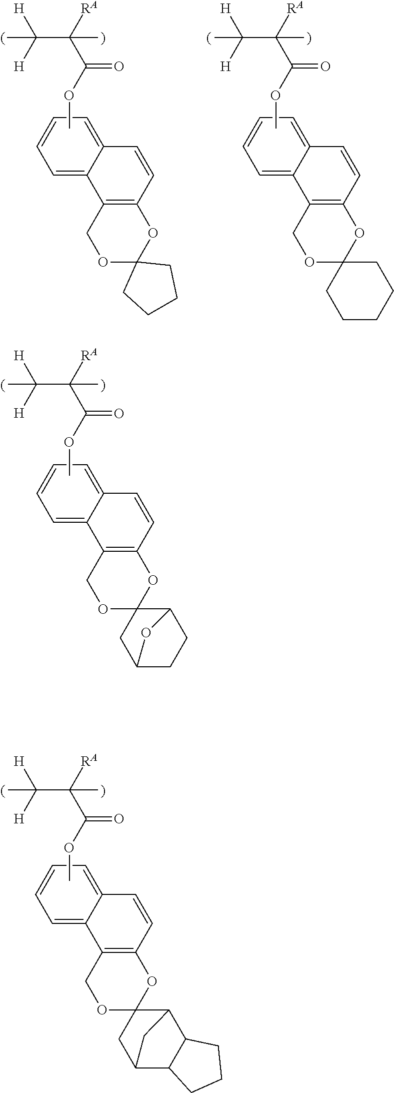

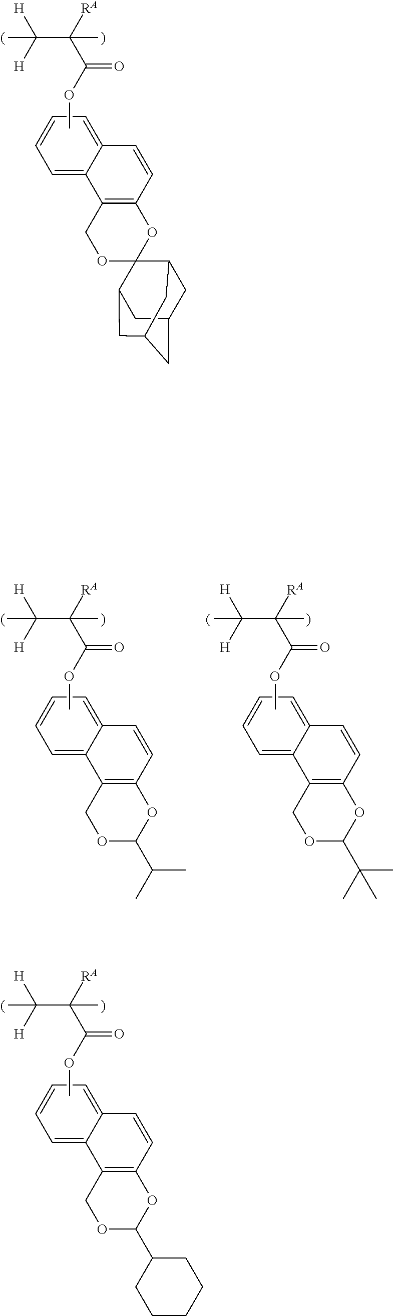

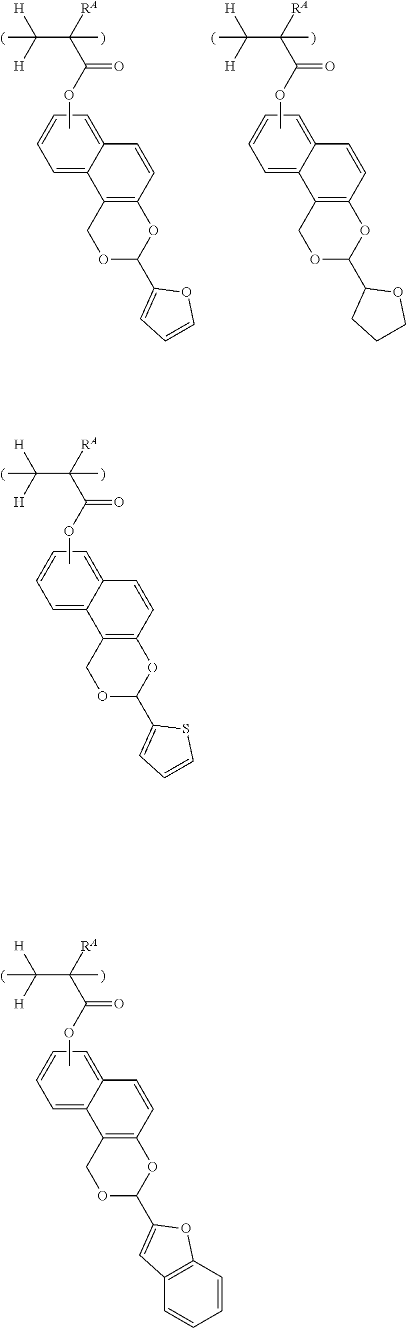

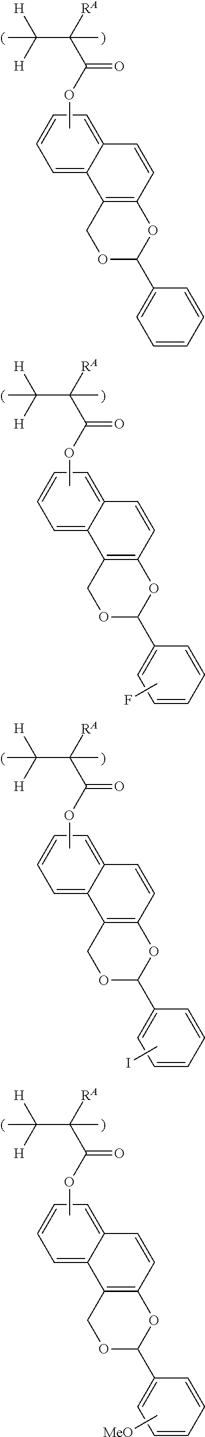

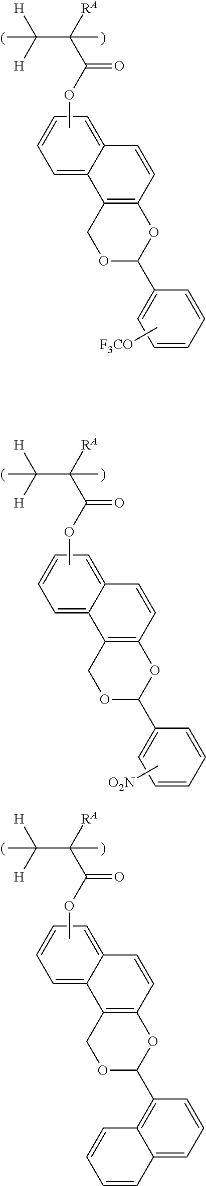

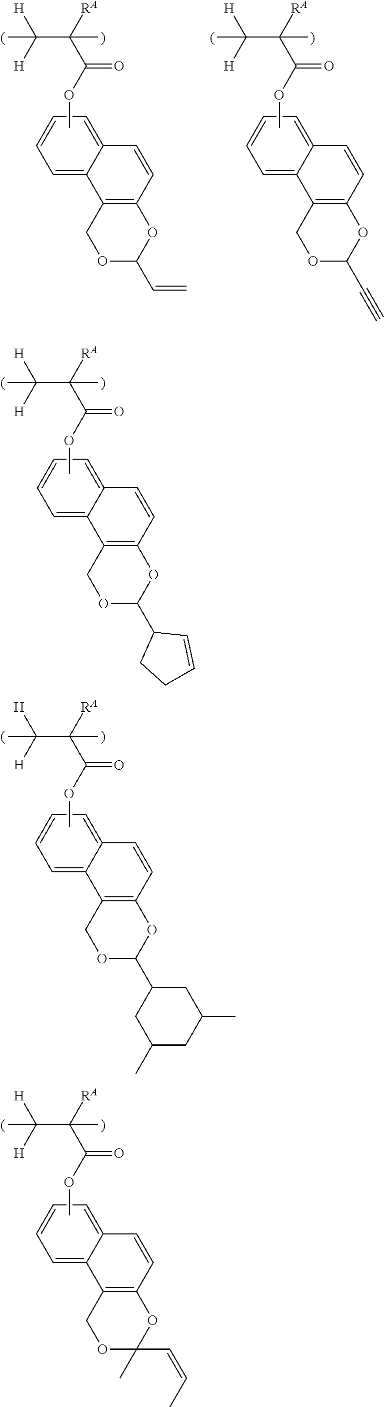

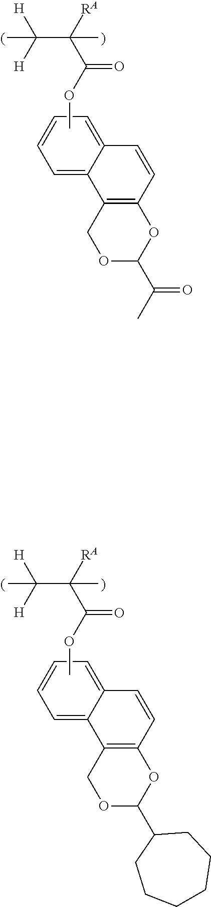

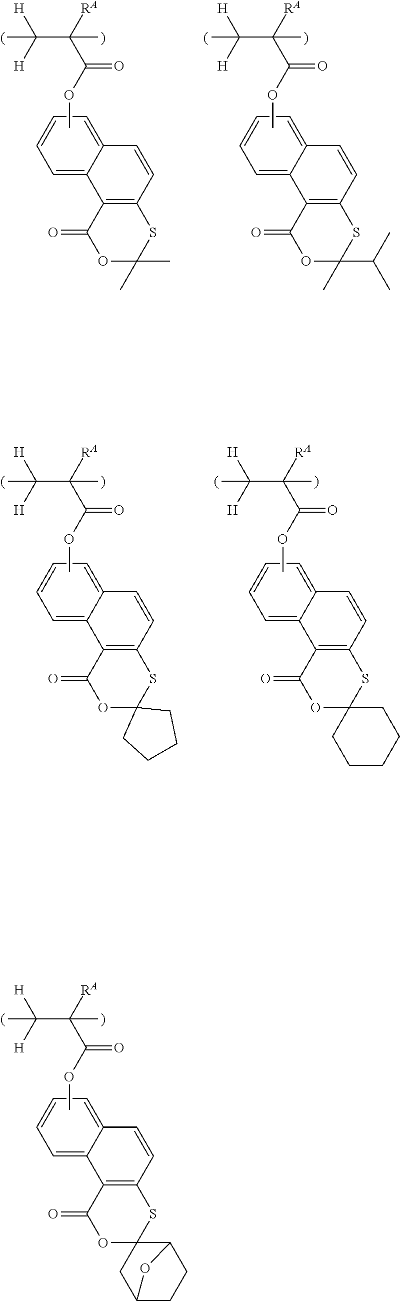

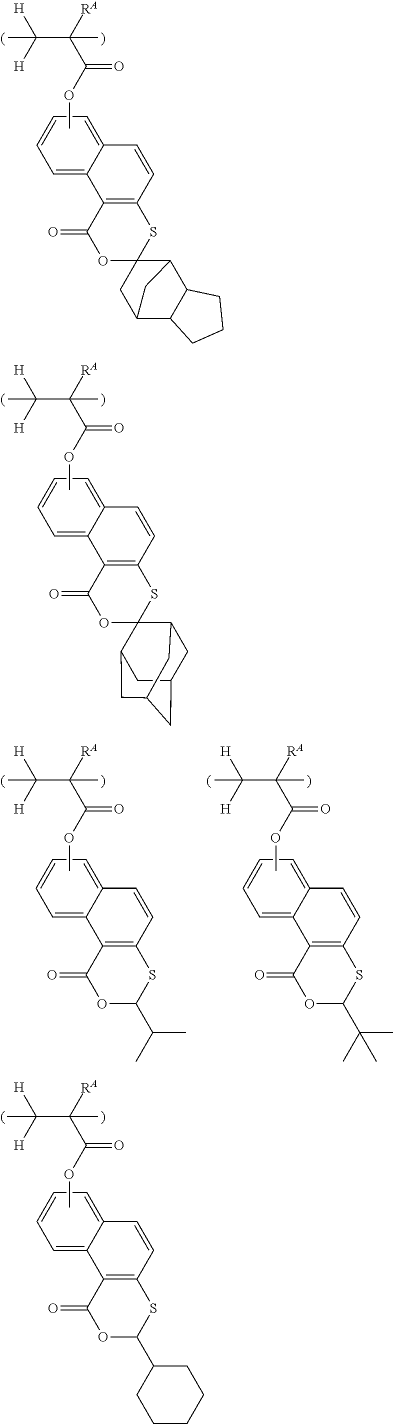

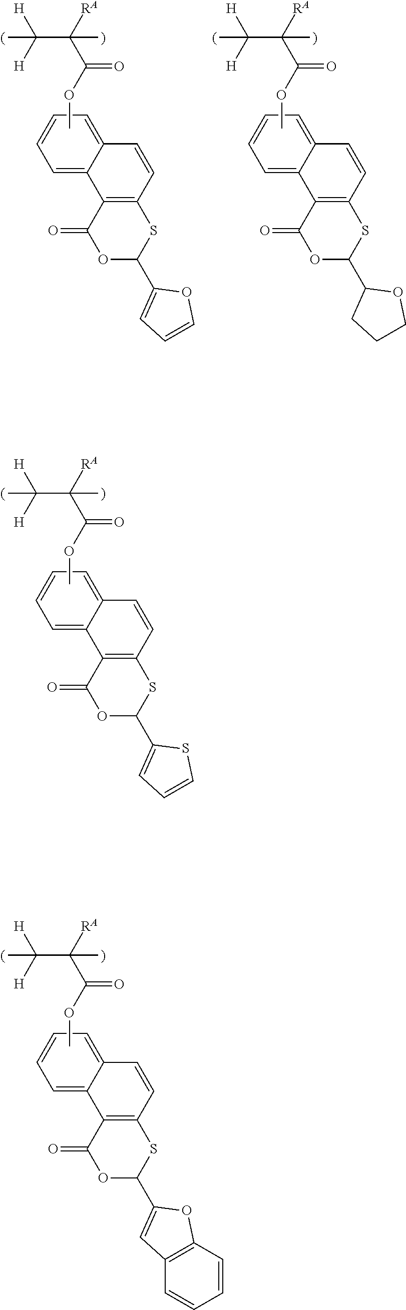

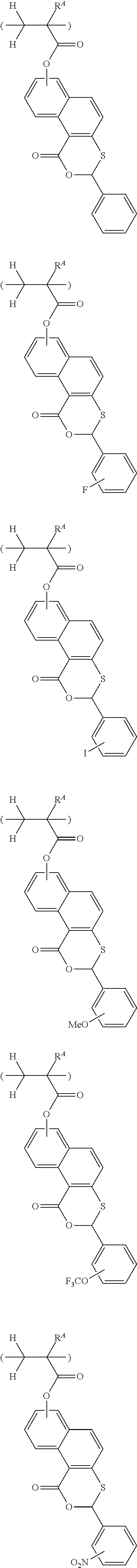

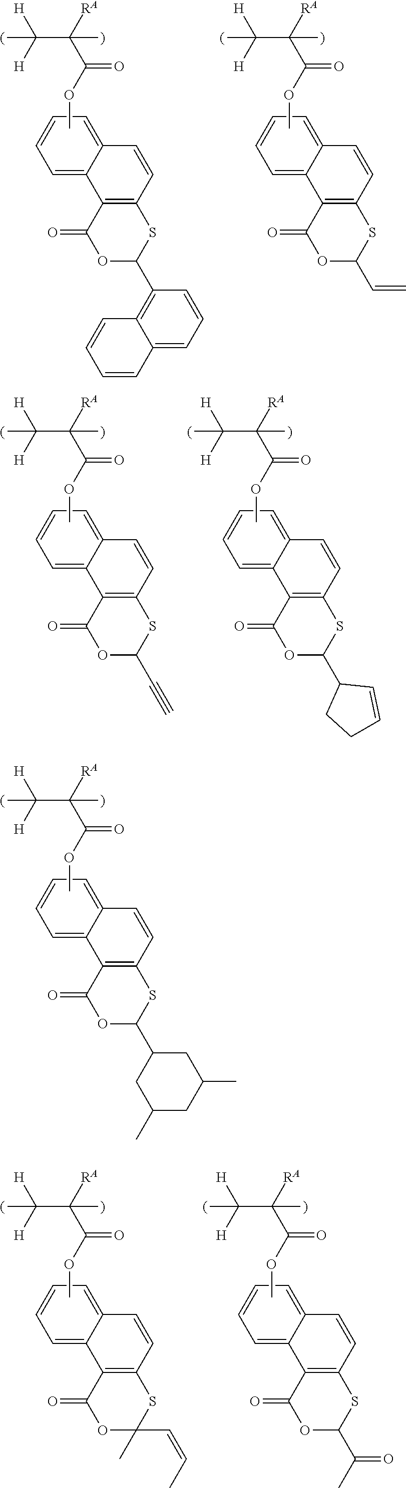

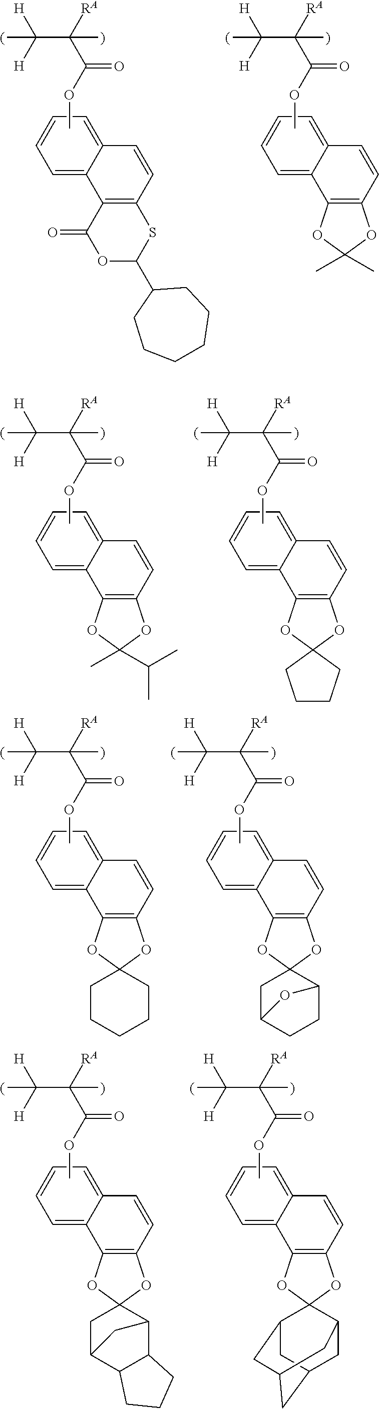

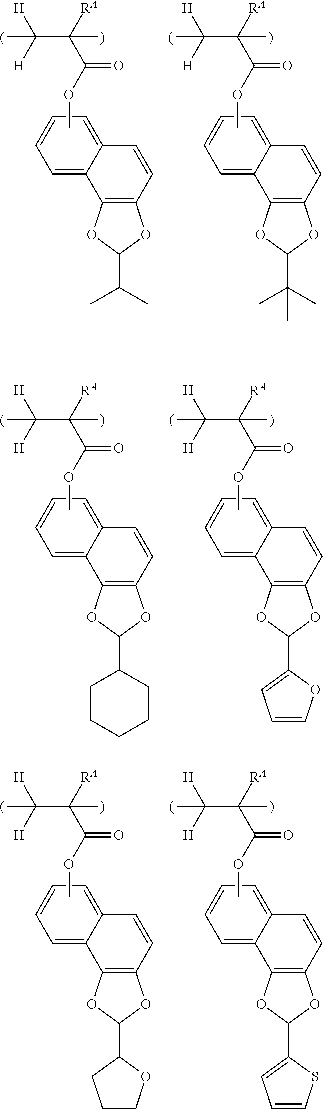

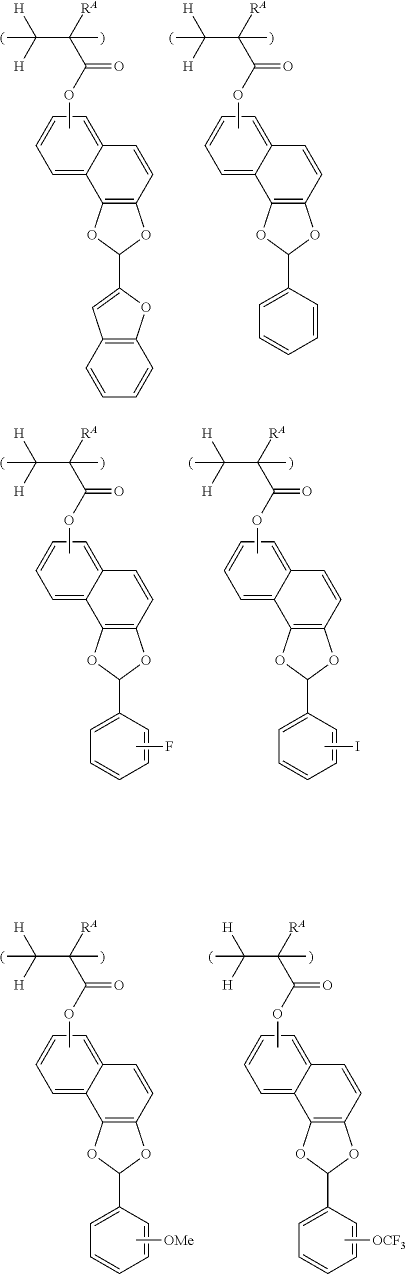

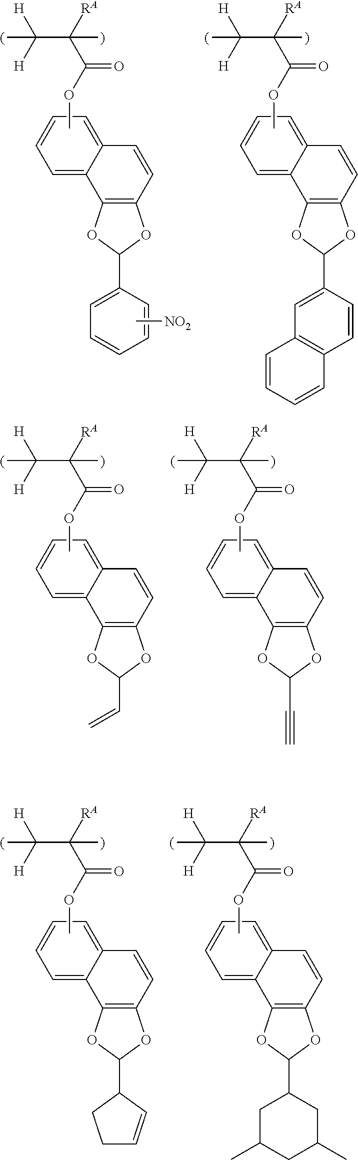

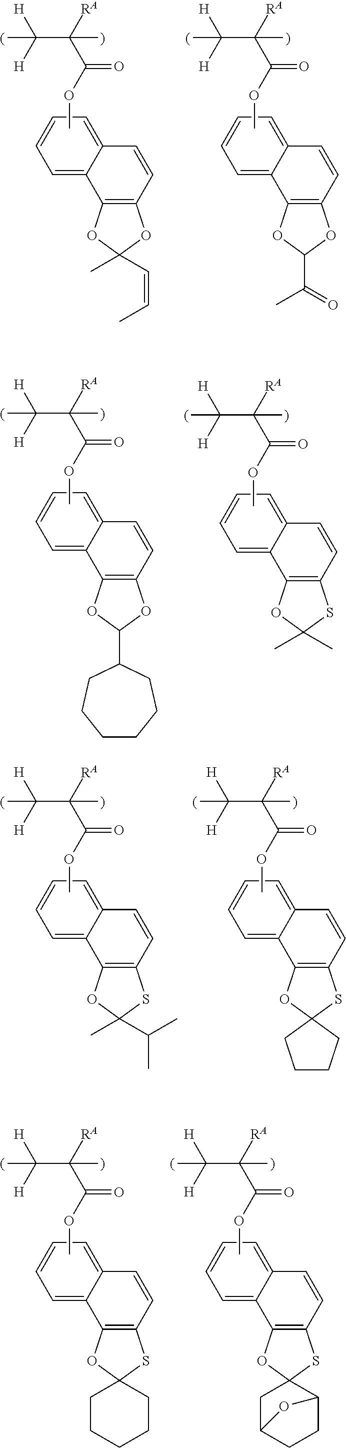

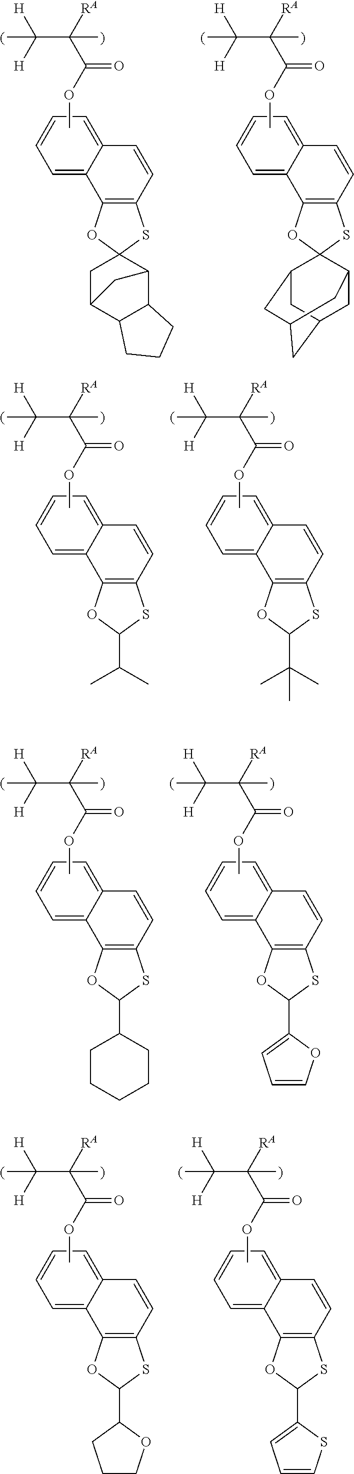

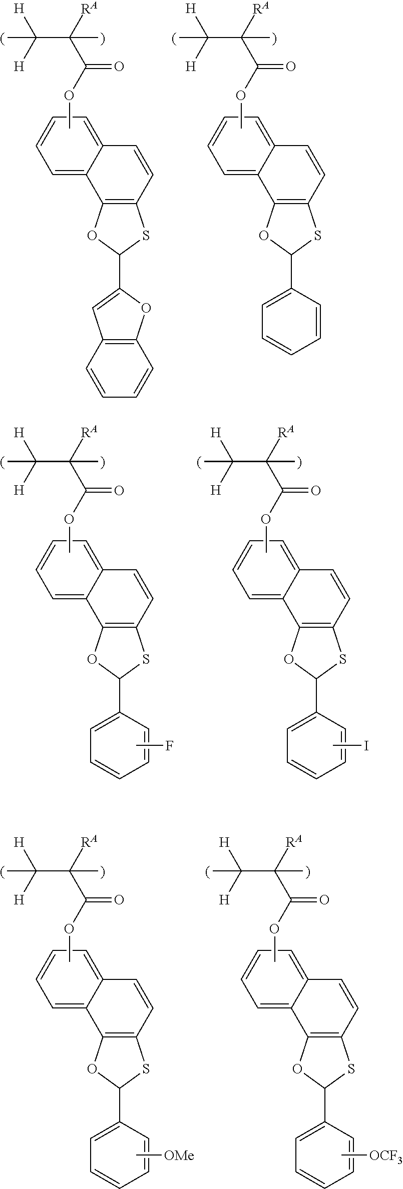

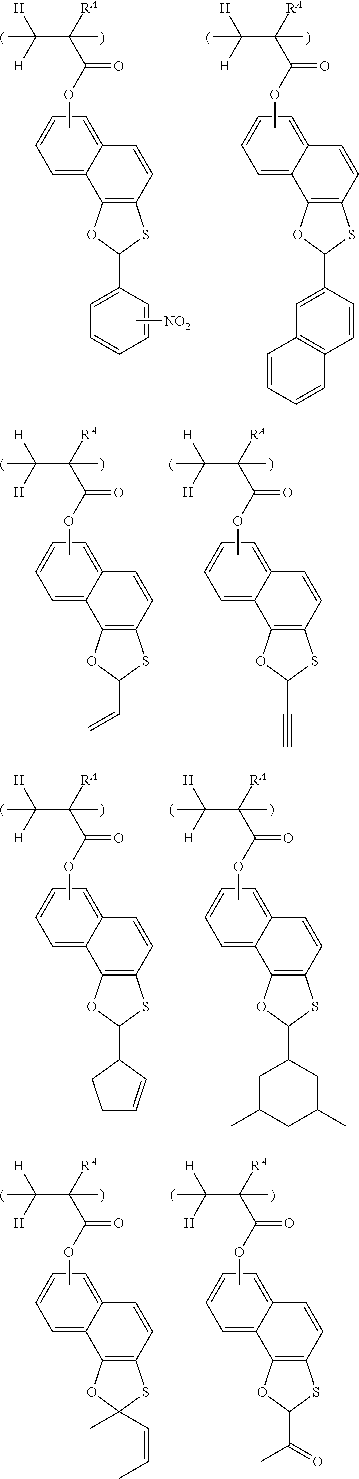

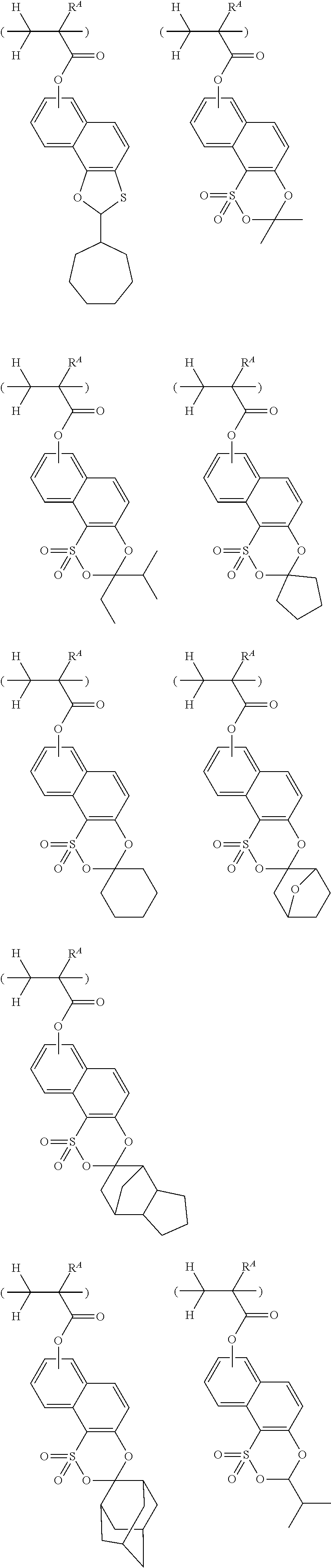

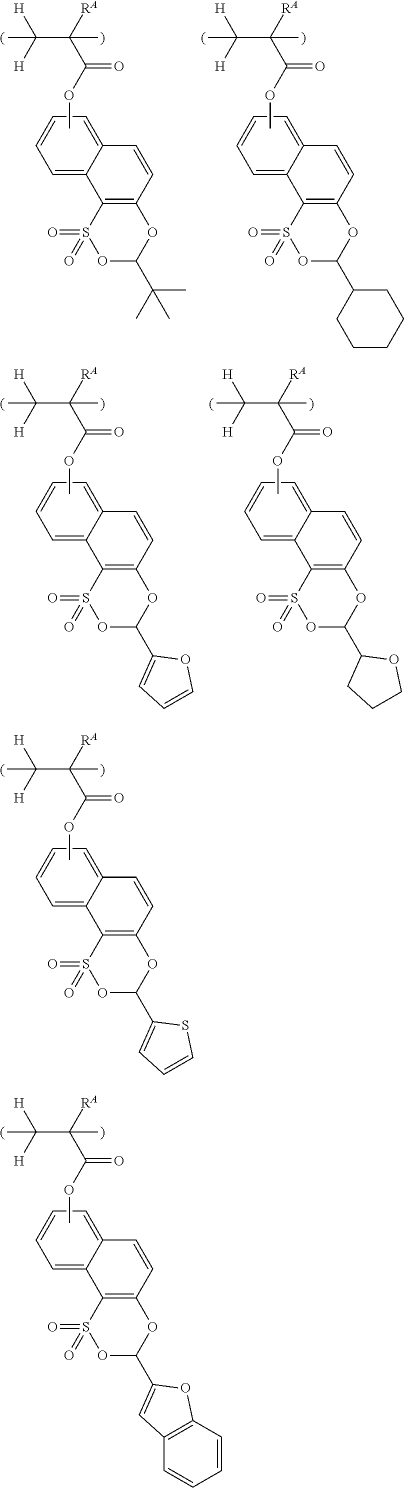

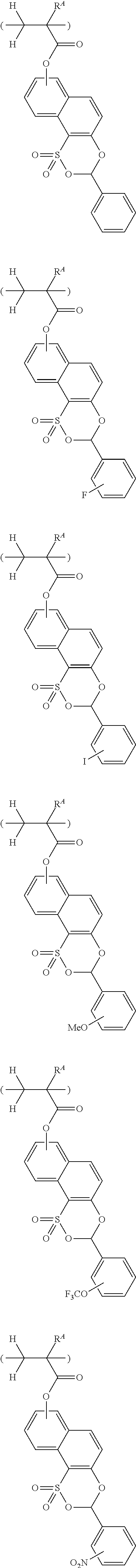

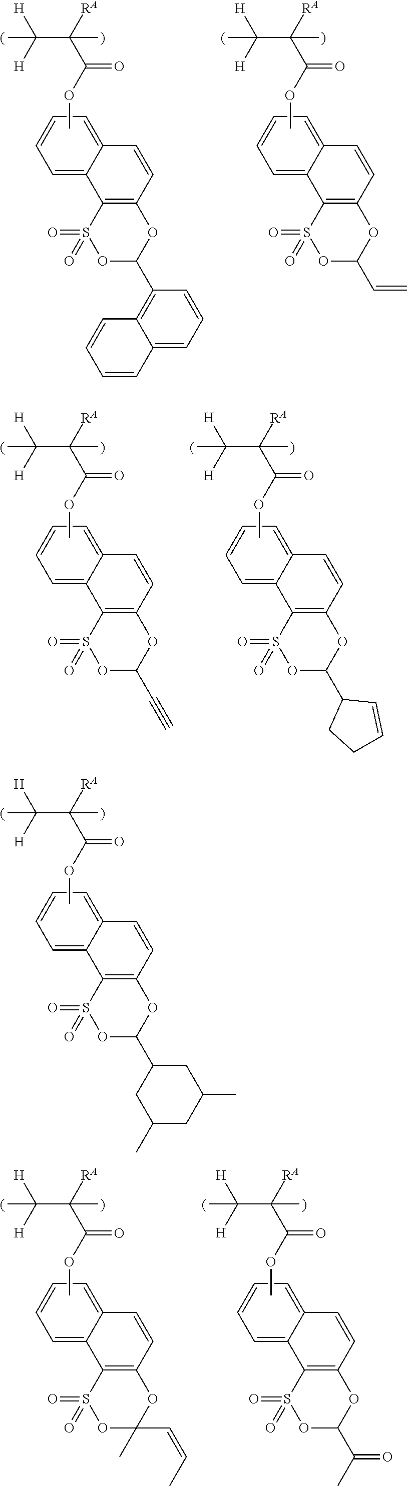

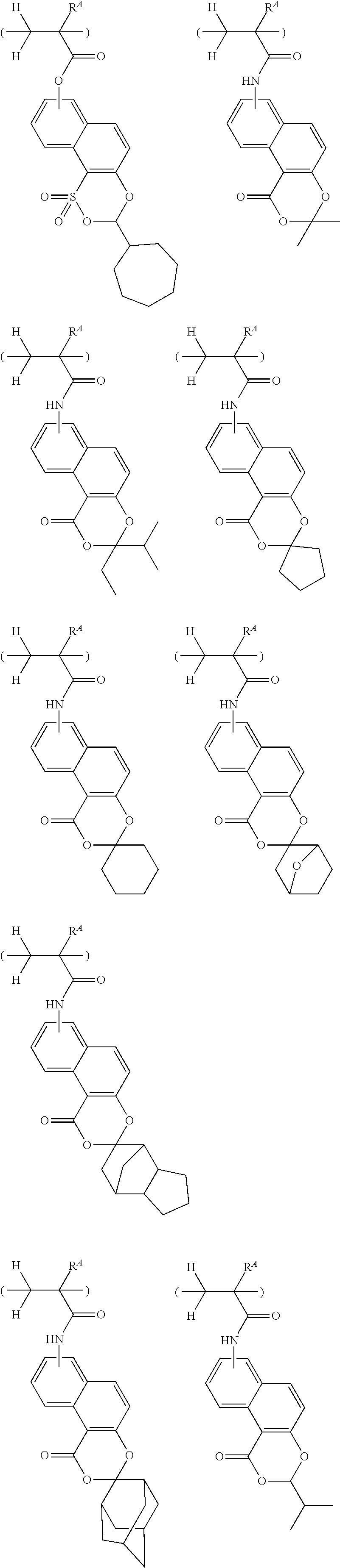

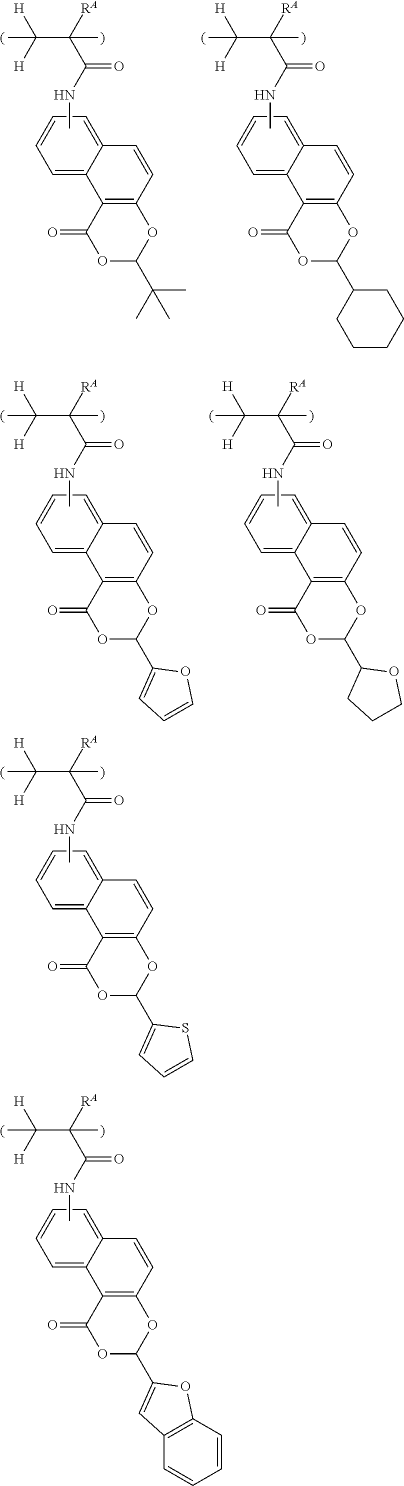

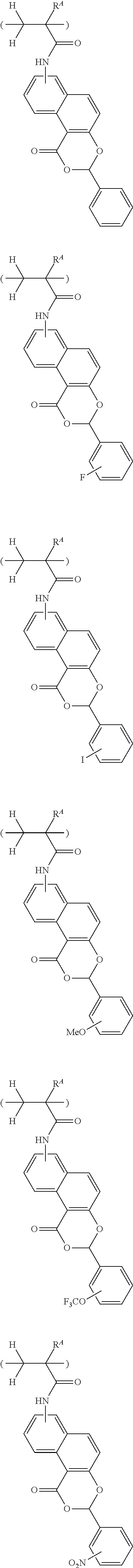

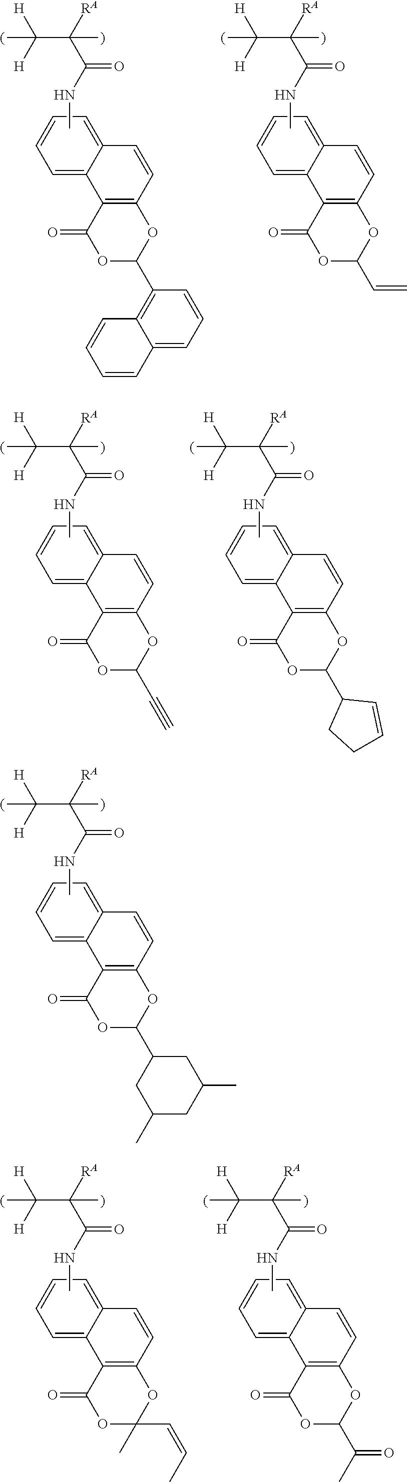

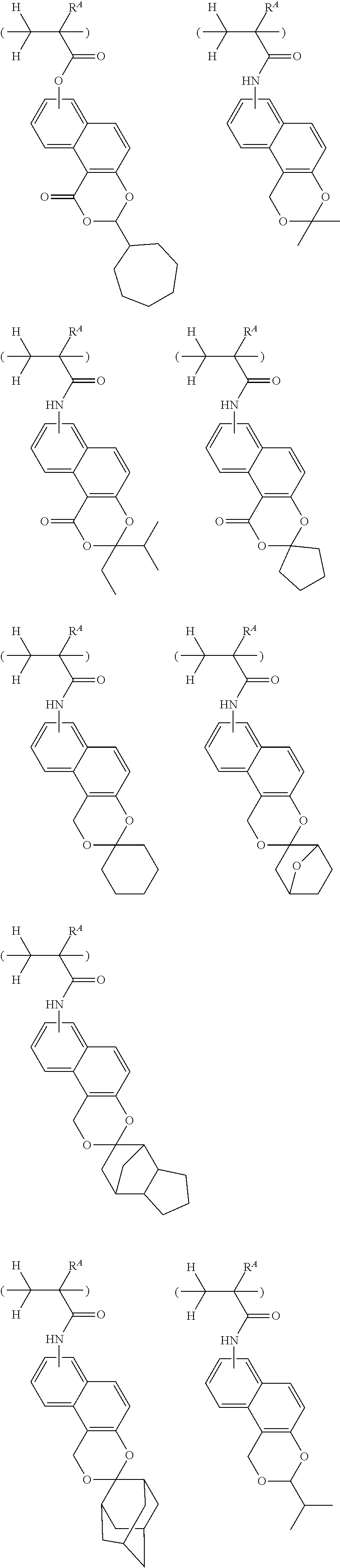

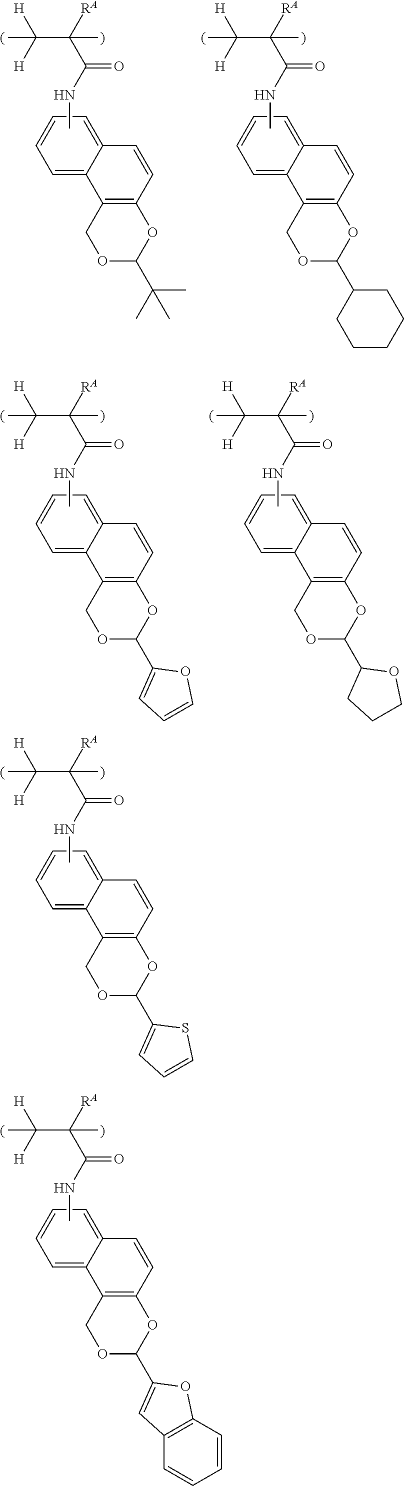

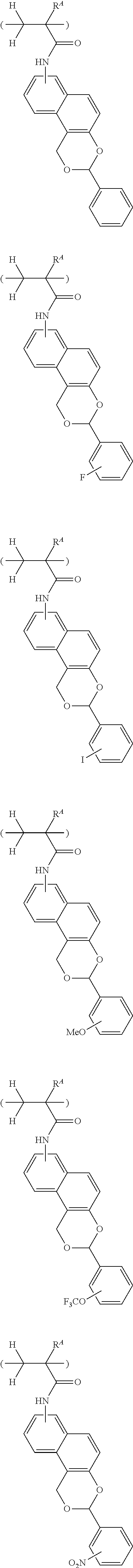

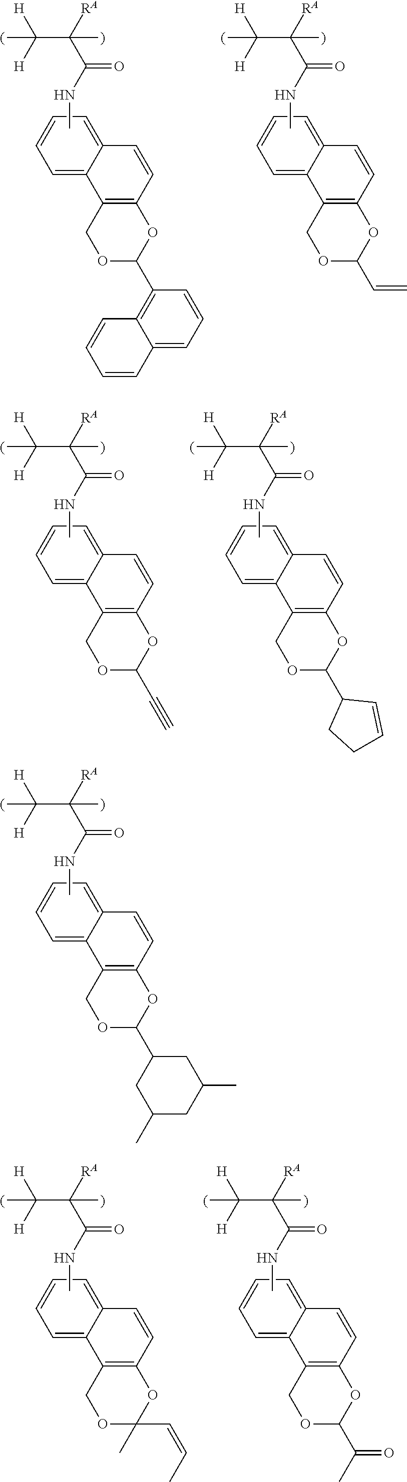

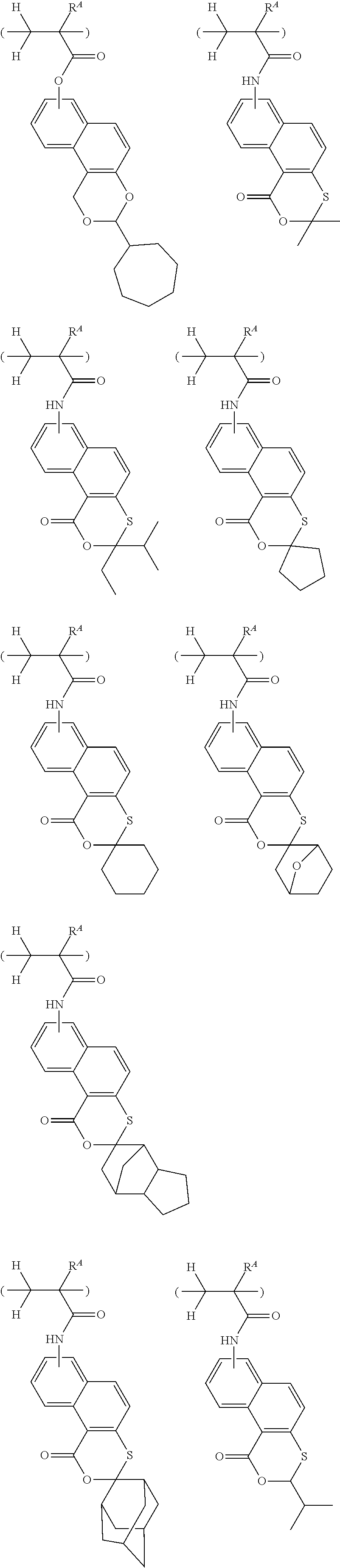

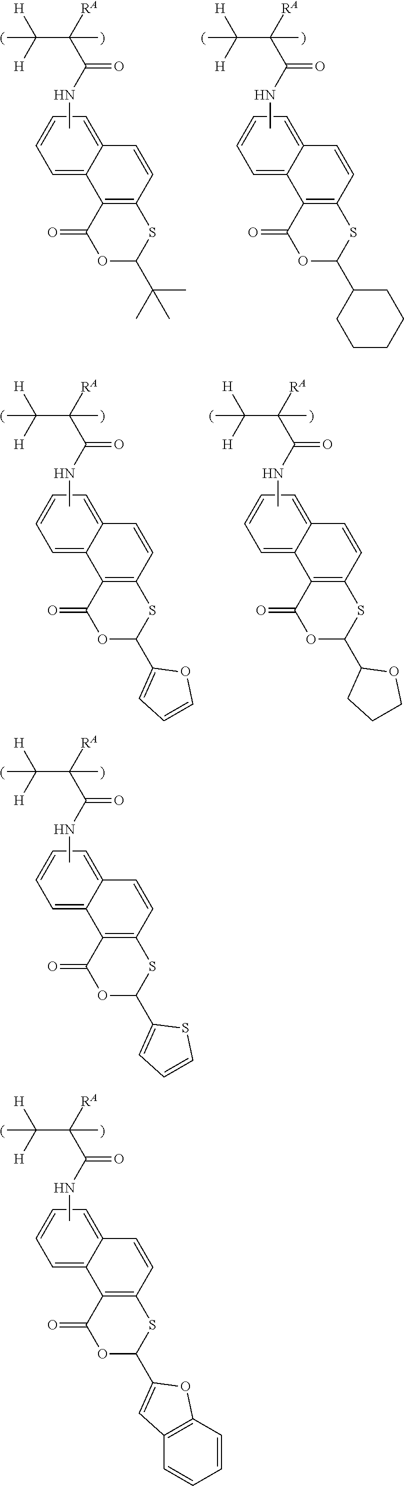

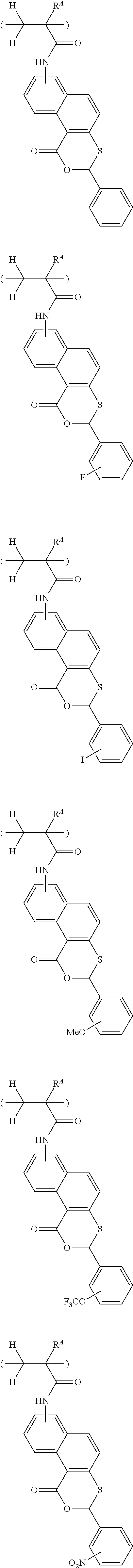

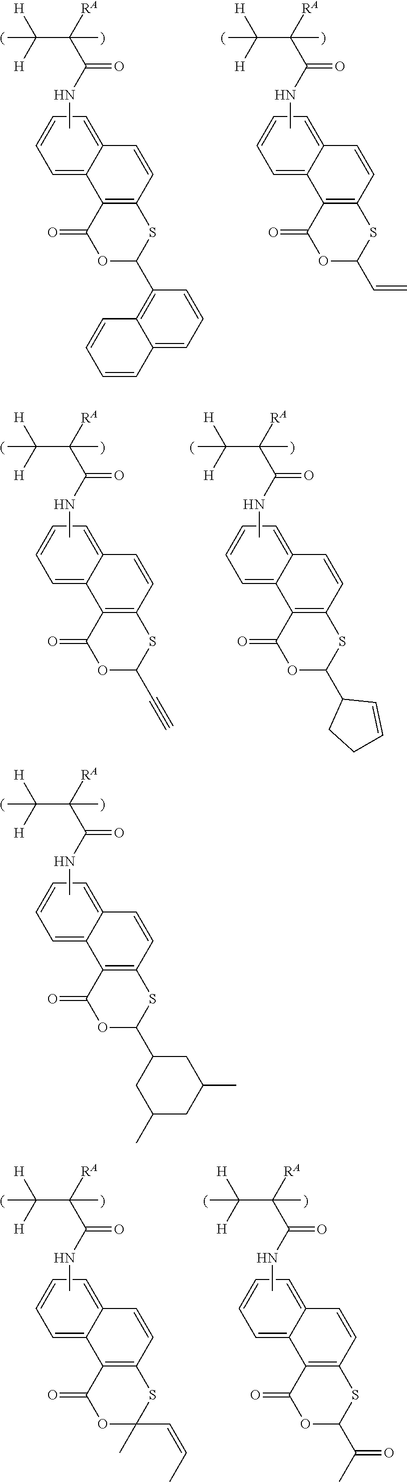

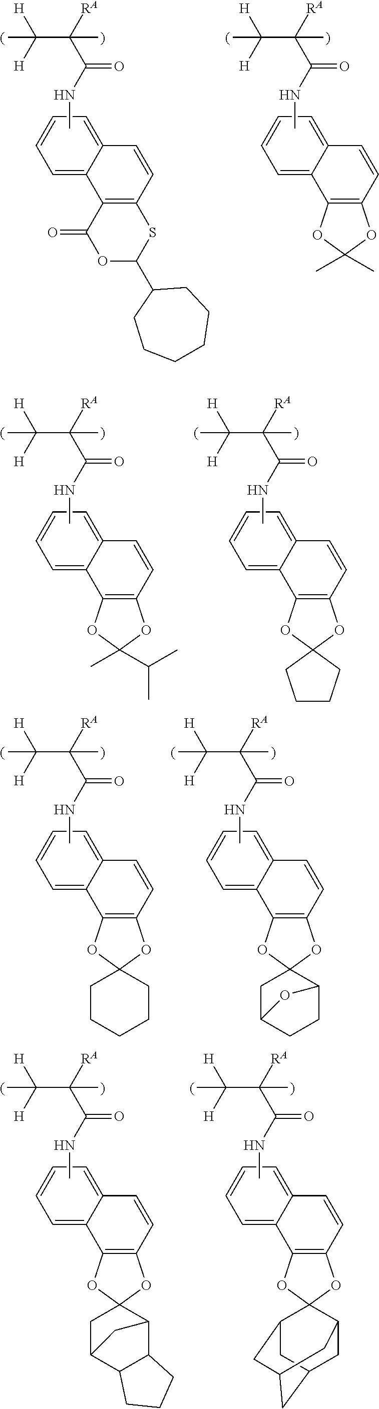

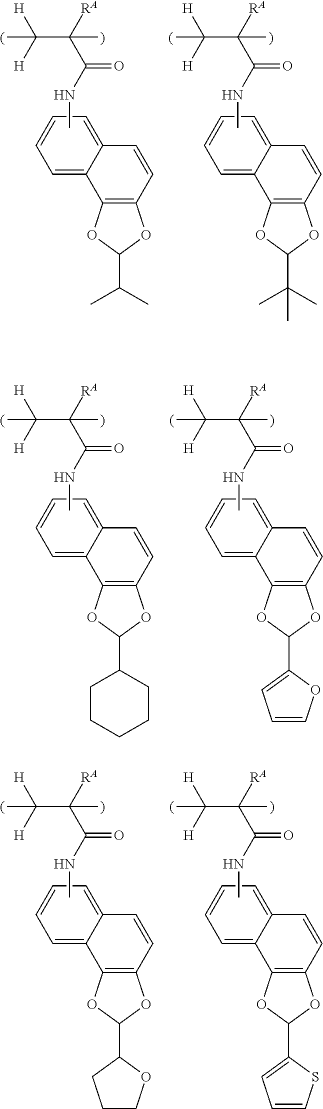

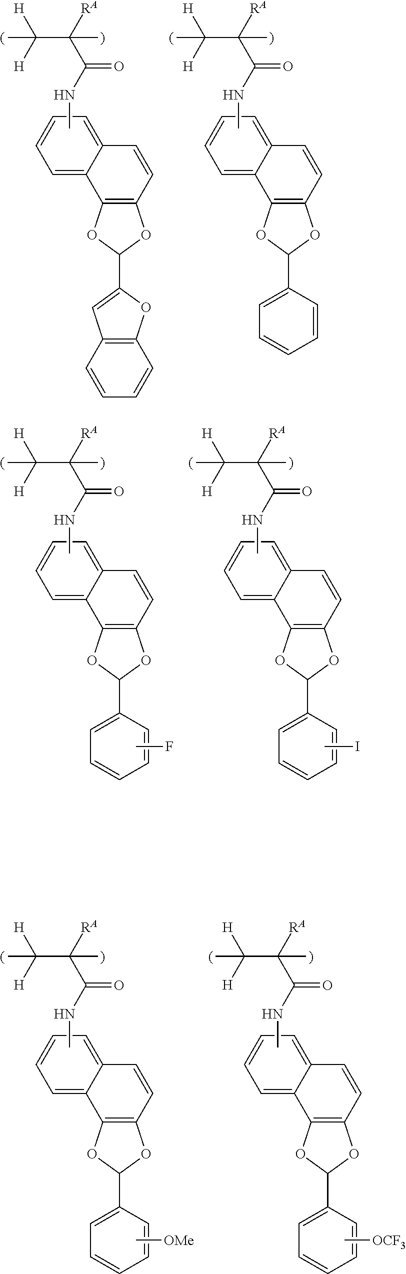

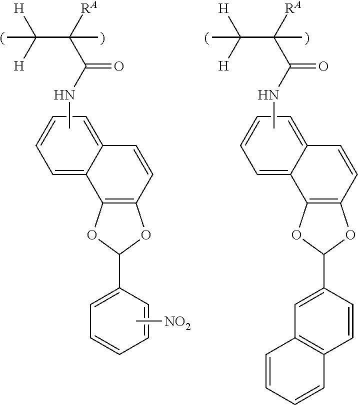

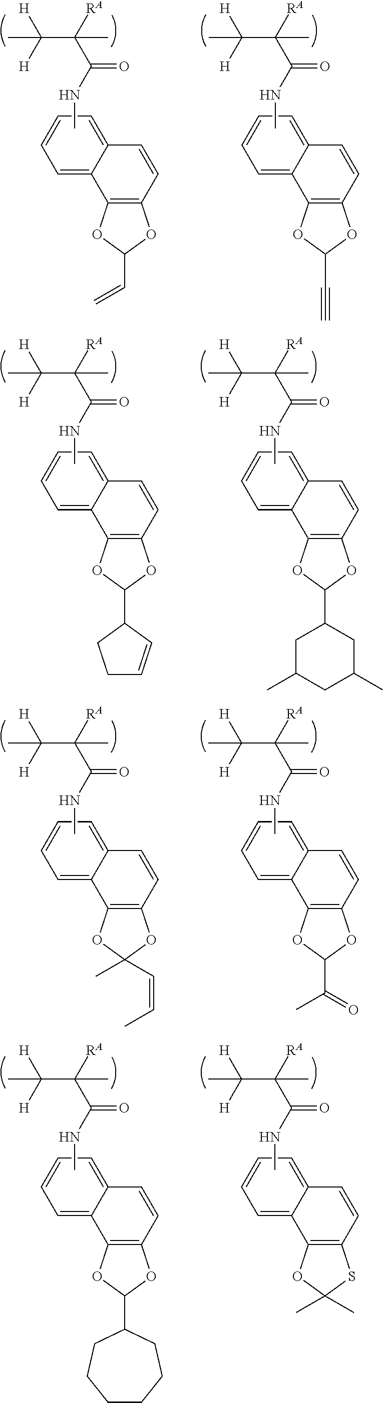

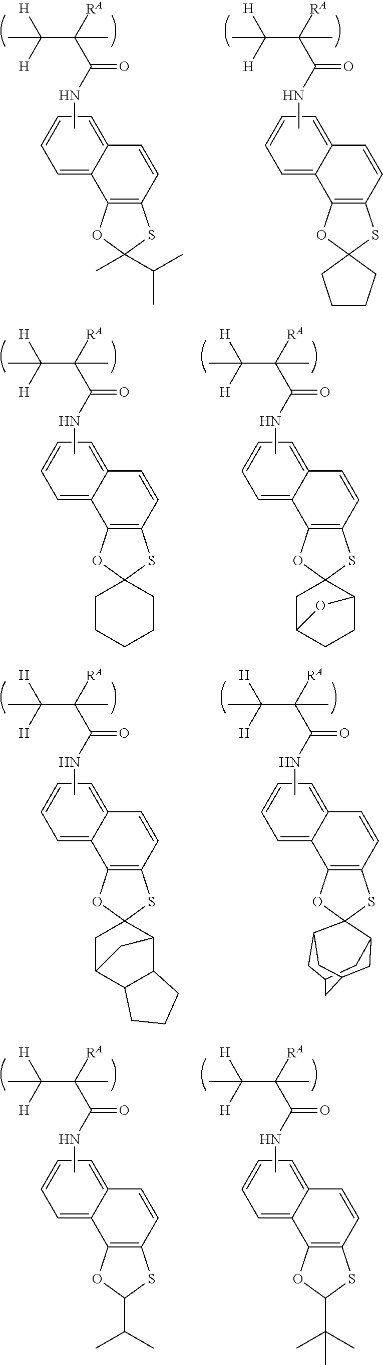

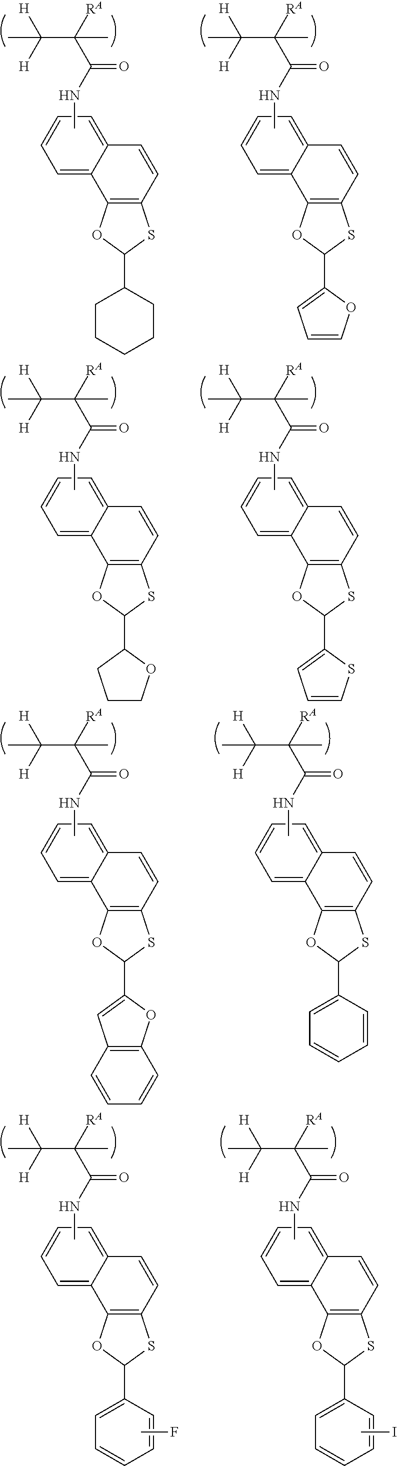

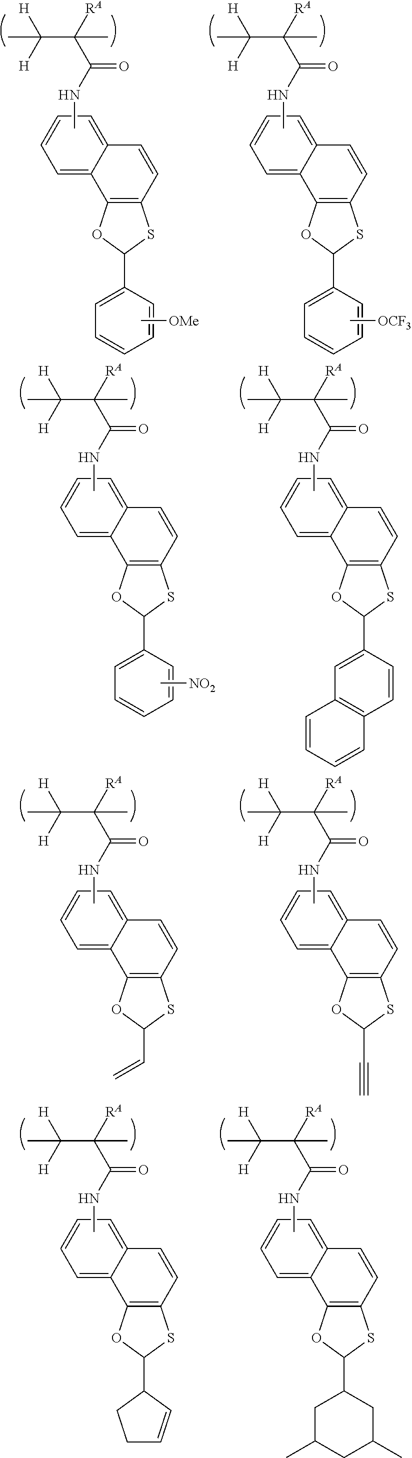

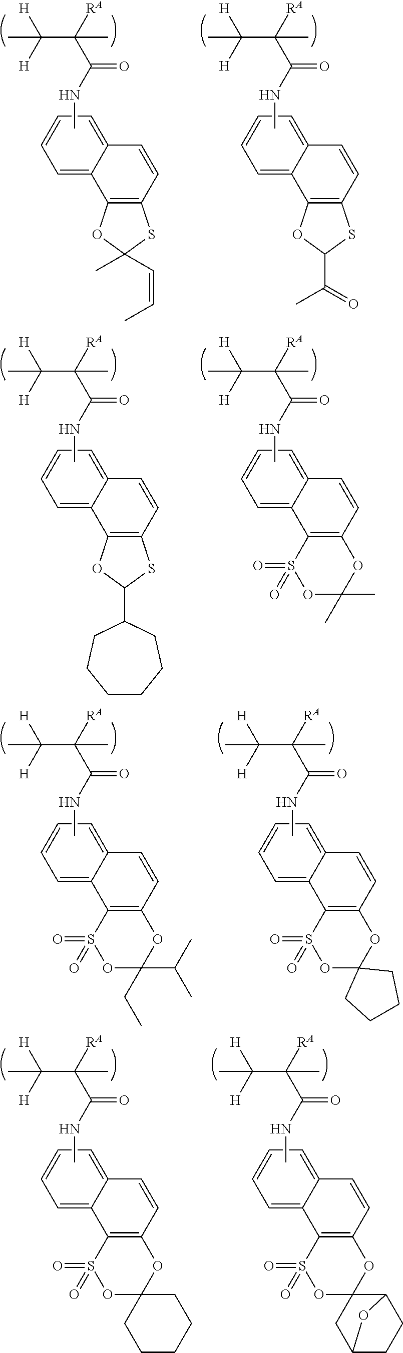

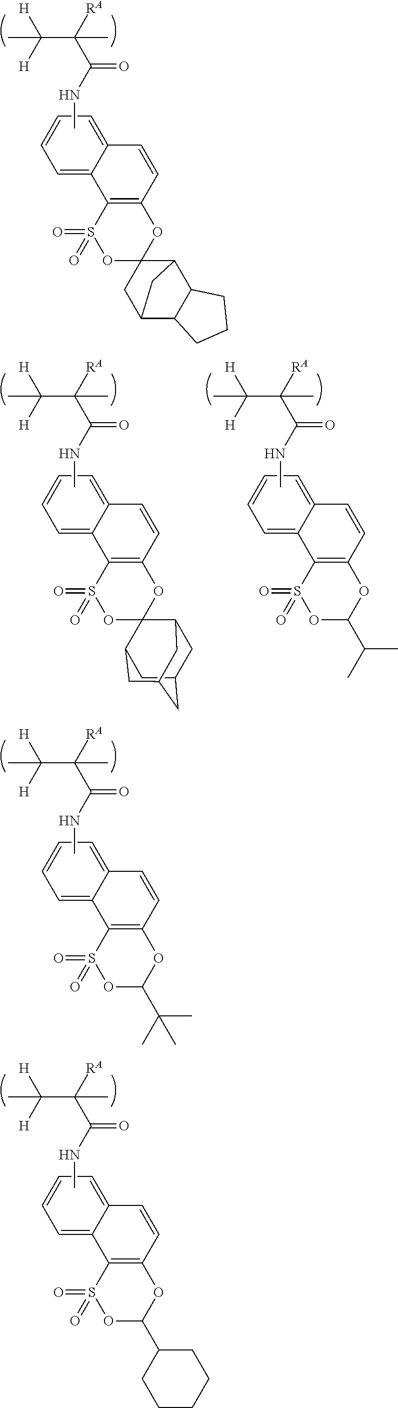

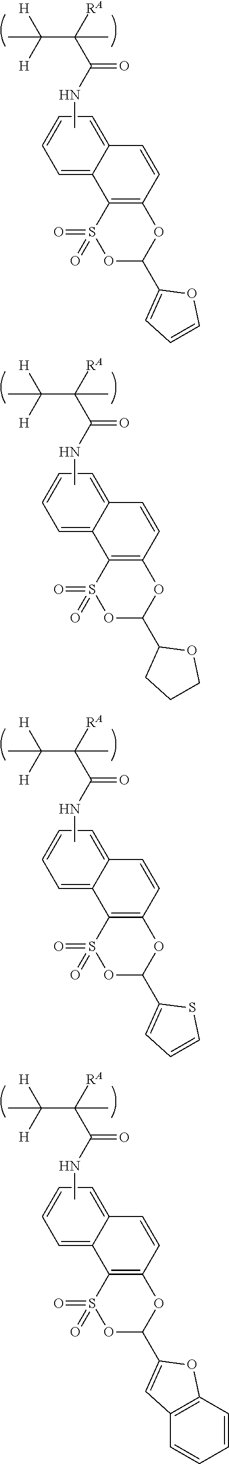

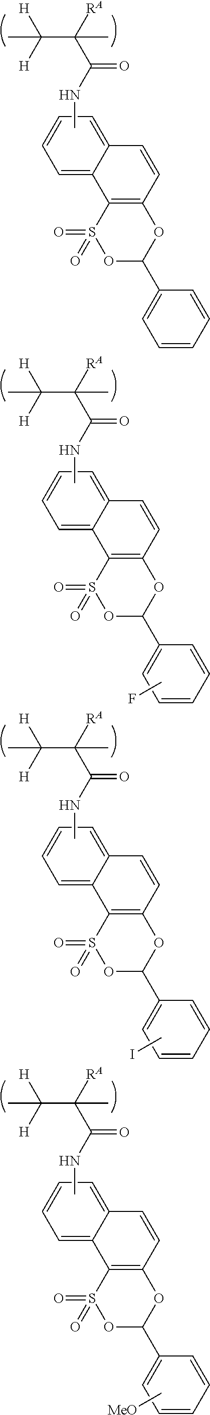

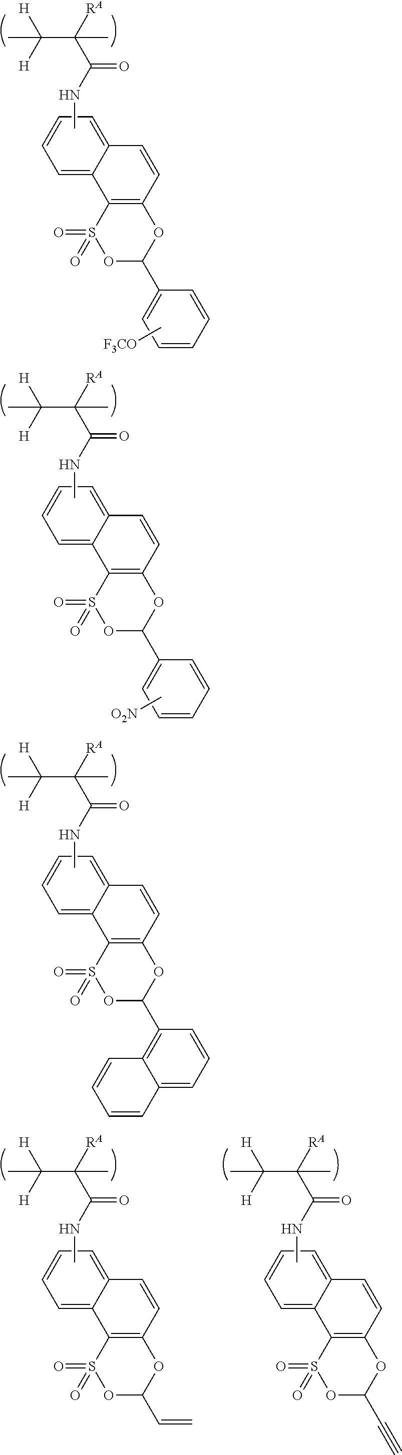

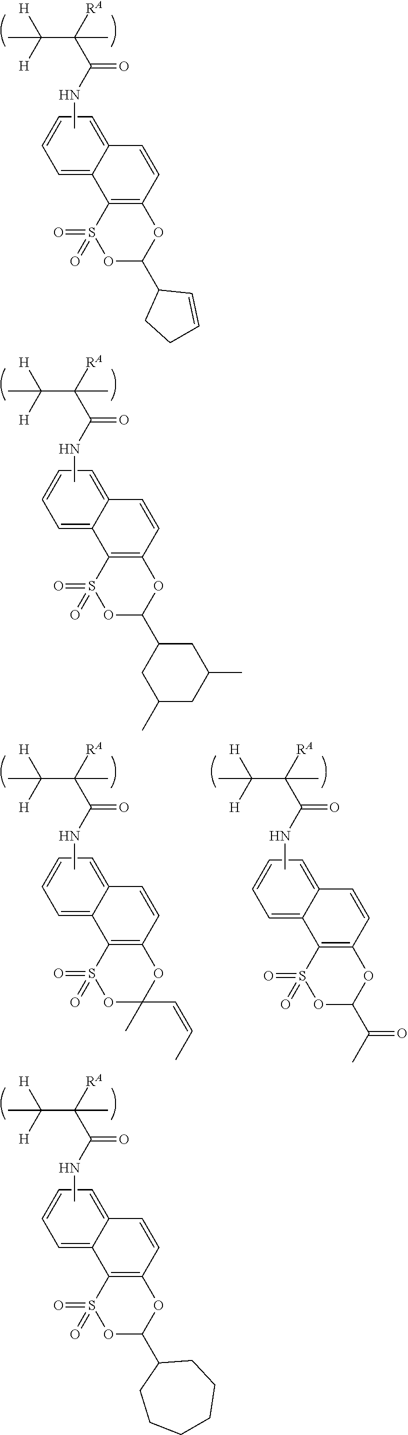

In a preferred embodiment, the polymer further comprises repeat units having the formula (b1), referred to as repeat units (b1), hereinafter.

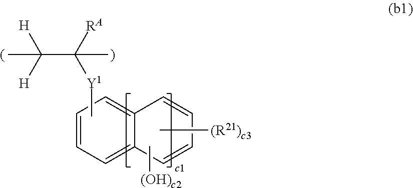

In formula (b1), R^{A} is hydrogen, fluorine, methyl or trifluoromethyl. Y¹ is a single bond, *—C(═O)—O—, or *—C(═O)—N(H)—, wherein * designates a point of attachment to the carbon atom in the backbone. R²¹ is halogen, carboxy, nitro, cyano, pentafluorosulfanyl, a C₁-C₂₀ hydrocarbyl group which may contain a heteroatom, C₁-C₂₀ hydrocarbyloxy group which may contain a heteroatom, C₂-C₂₀ hydrocarbylcarbonyl group which may contain a heteroatom, C₂-C₂₀ hydrocarbylcarbonyloxy group which may contain a heteroatom, or C₂-C₂₀ hydrocarbyloxycarbonyl group which may contain a heteroatom. When c3 is 2, 3 or 4, a plurality of R²¹ may be identical or different. The subscript c1 is 0, 1 or 2. The relevant structure is a benzene ring when c1=0, a naphthalene ring when c1=1, and an anthracene ring when c1=2. From the aspect of solvent solubility, the benzene ring corresponding to c1=0 is preferred. The subscript c2 is 1, 2, 3 or 4, and c3 is 0, 1, 2, 3 or 4, meeting 1≤c2+c3≤5.

Examples of the repeat unit (b1) are shown below, but not limited thereto. Herein R^{A} is as defined above.

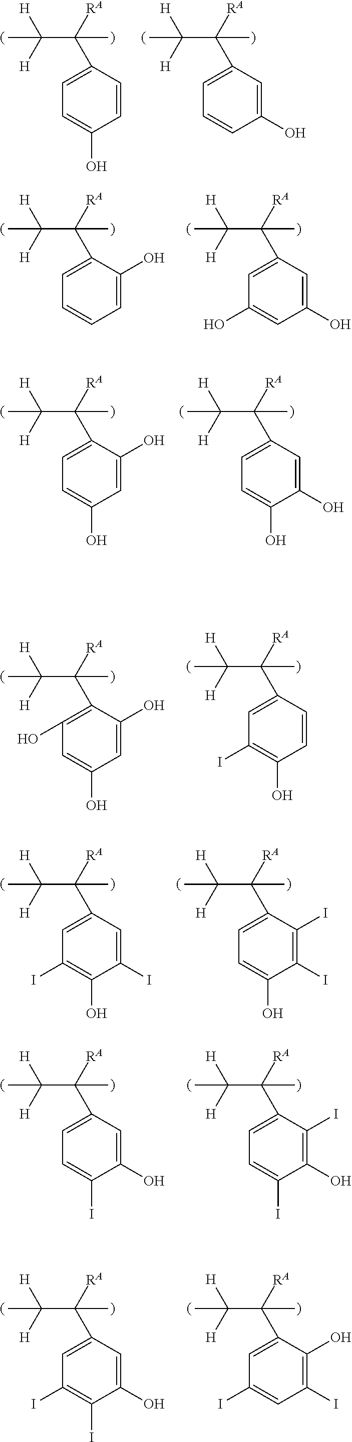

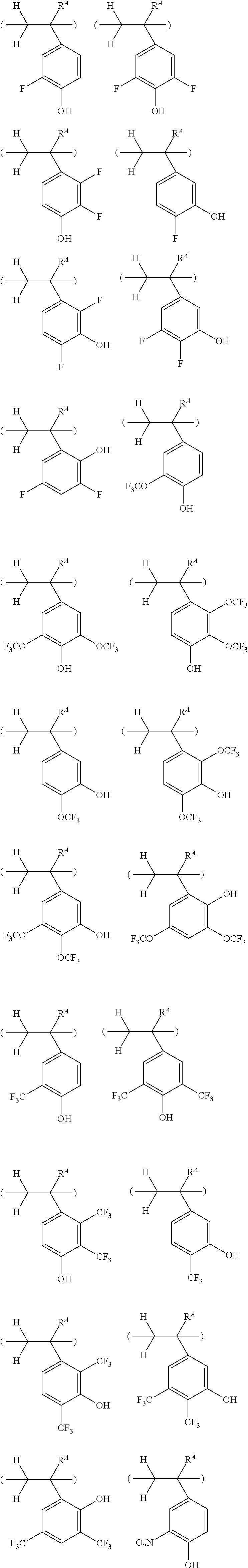

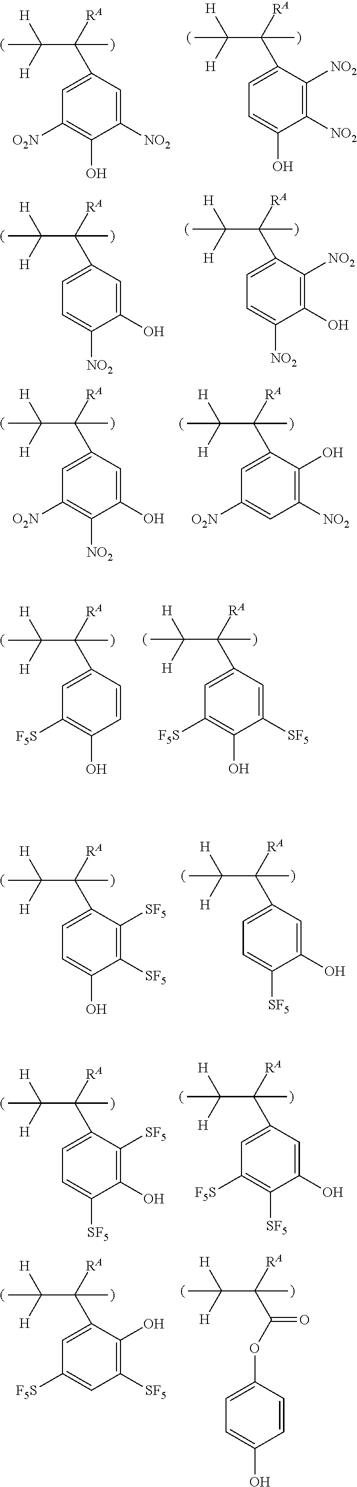

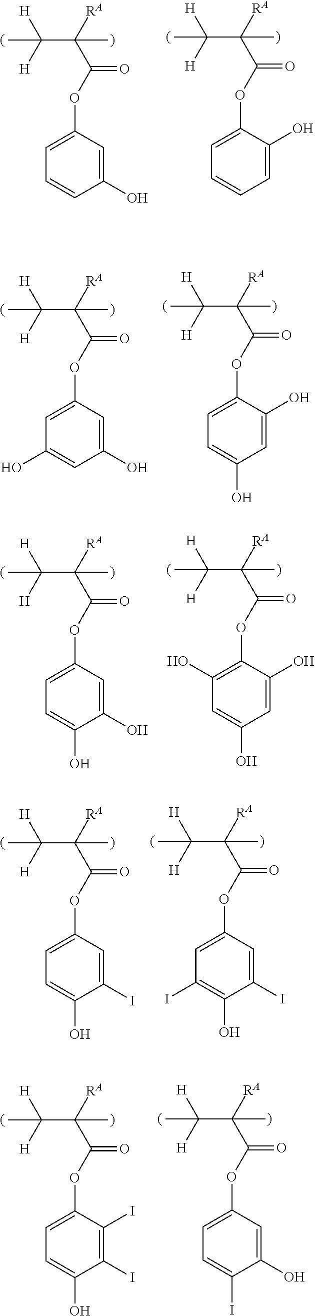

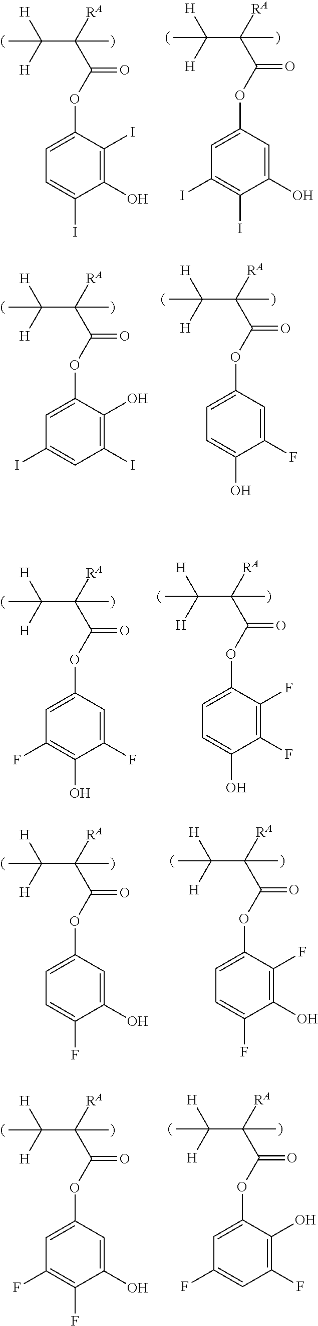

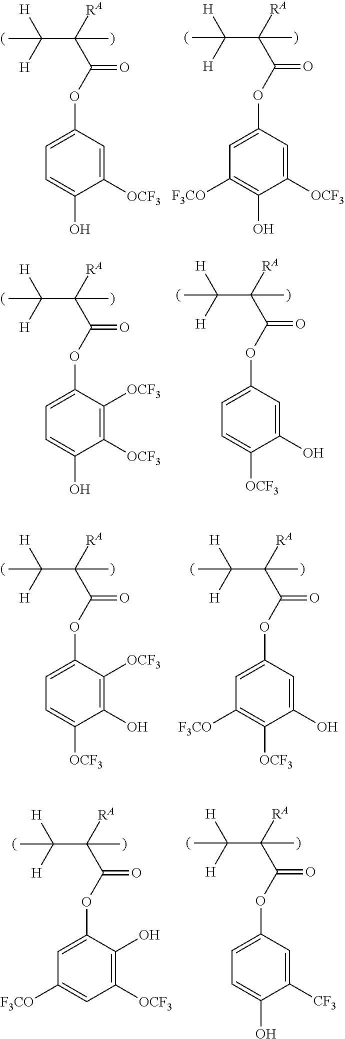

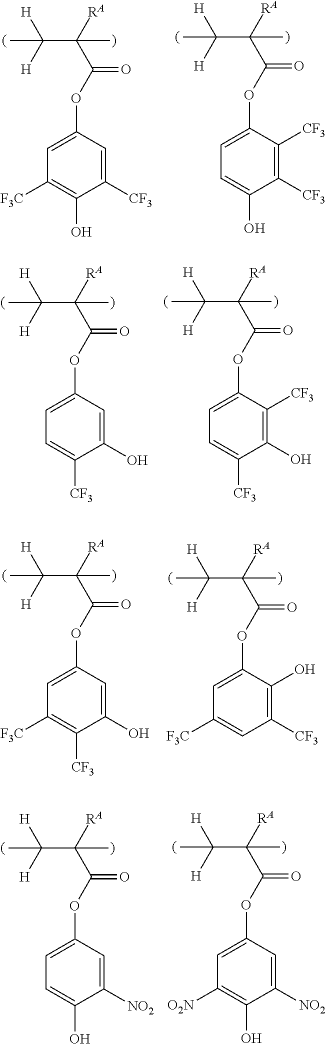

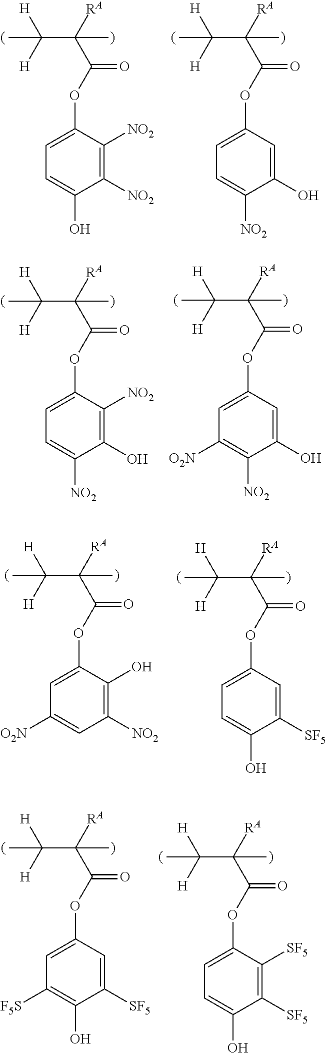

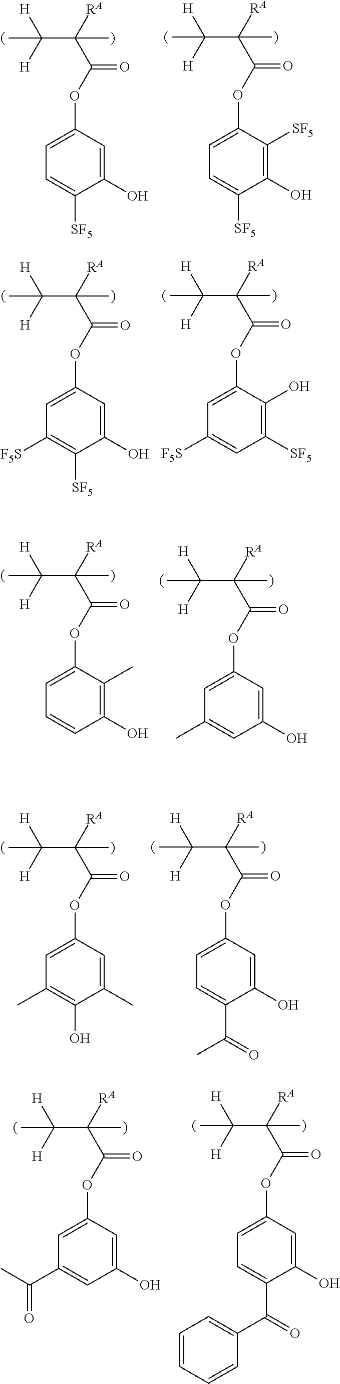

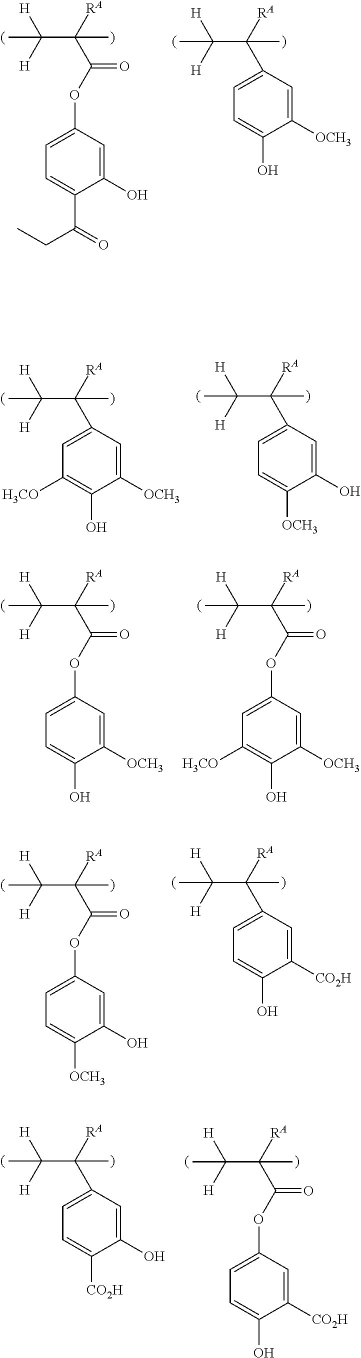

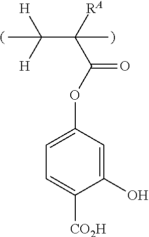

Other examples of repeat unit (b1) include those described in Patent Document 6, paragraphs [0180]-[0182], but are not limited thereto.

The polymer may further comprise repeat units having the formula (b2), referred to as repeat units (b2), hereinafter.

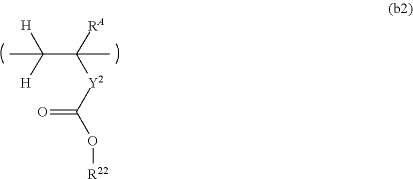

In formula (b2), R^{A} is hydrogen, fluorine, methyl or trifluoromethyl. Y² is a single bond, phenylene, naphthylene, *—C(═O)—O—Y²¹—, or *—C(═O)—N(H)—Y²¹—, wherein * designates a point of attachment to the carbon atom in the backbone. The phenylene and naphthylene groups may be substituted with hydroxy, nitro, cyano, a C₁-C₁₀ saturated hydrocarbyl moiety which may contain fluorine, C₁-C₁₀ saturated hydrocarbyloxy moiety which may contain fluorine, or halogen. Y²¹ is a C₁-C₁₀ saturated hydrocarbylene group, phenylene group or naphthylene group, the saturated hydrocarbylene group may contain hydroxy, ether bond, ester bond or lactone ring. R²² is hydrogen or a C₁-C₂₀ group containing at least one structure selected from hydroxy other than phenolic hydroxy, cyano, nitro, carbonyl, carboxy, ether bond, ester bond, sulfonate ester bond, carbonate bond, lactone ring, sultone ring, lactam ring, sultam ring, and carboxylic anhydride (—C(═O)—O—C(═O)—).

Examples of the repeat unit (b2) are shown below, but not limited thereto. Herein R^{A} is as defined above.

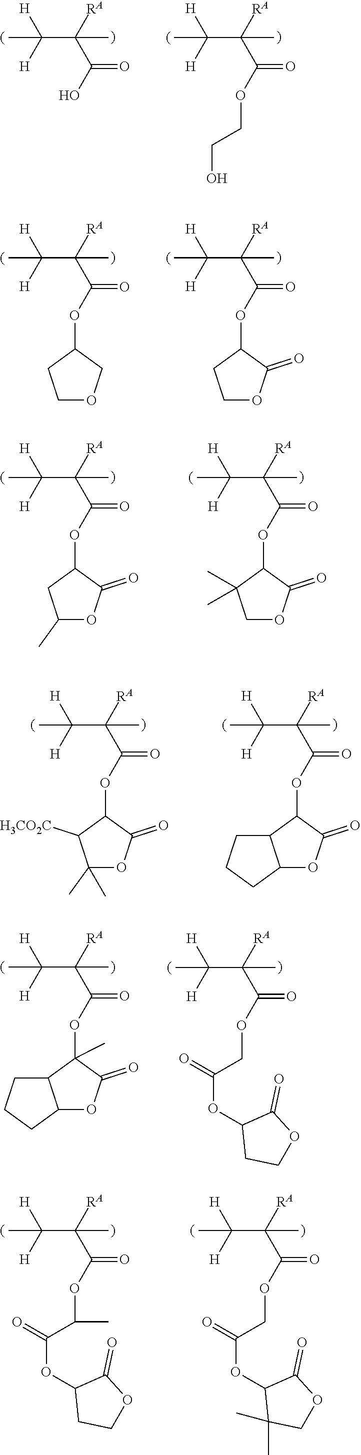

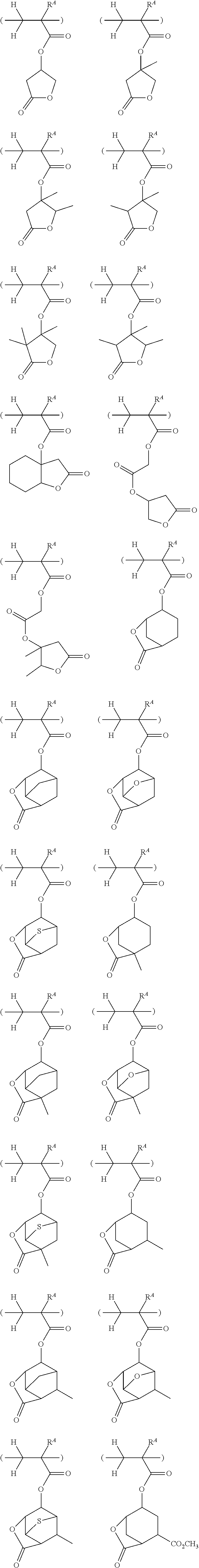

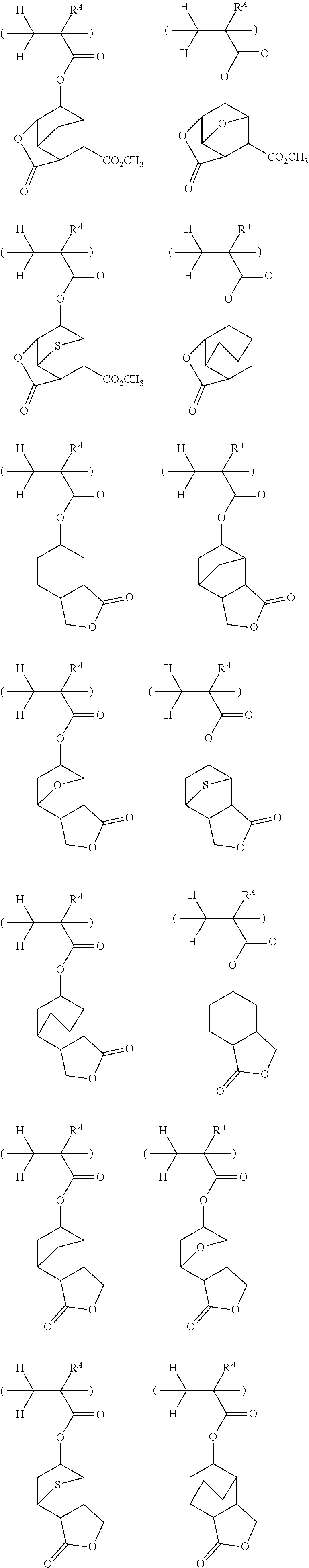

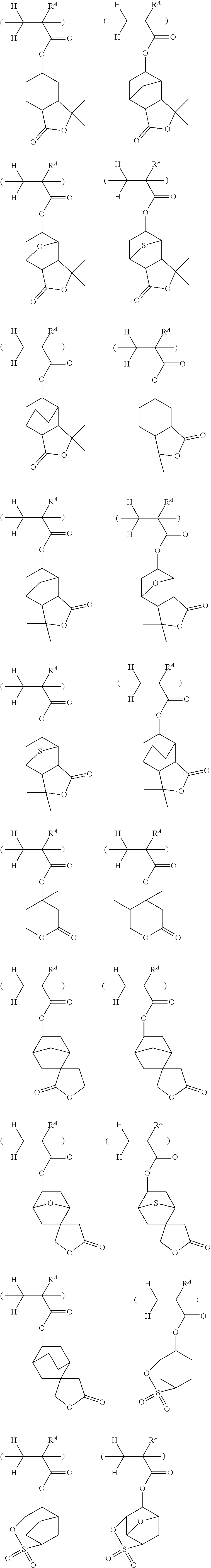

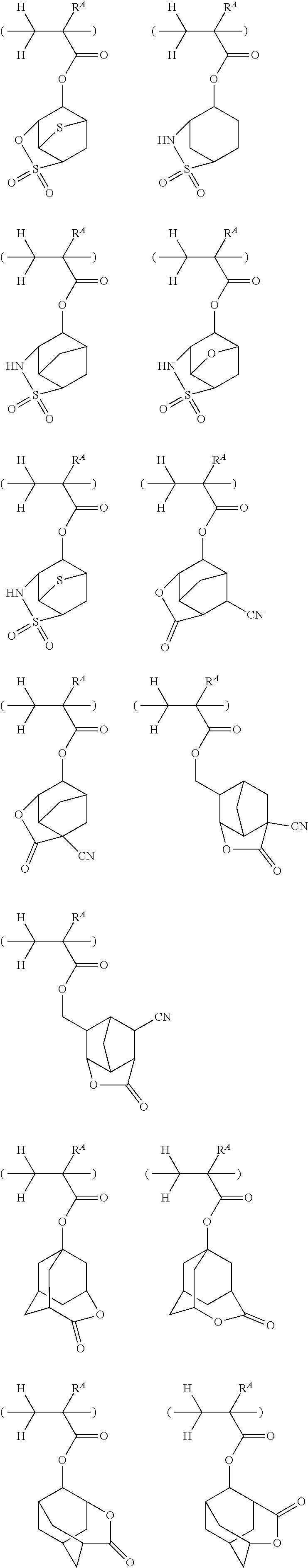

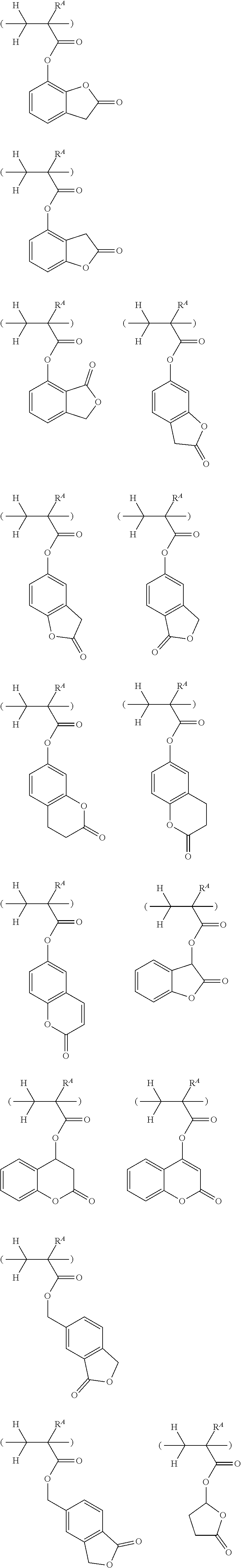

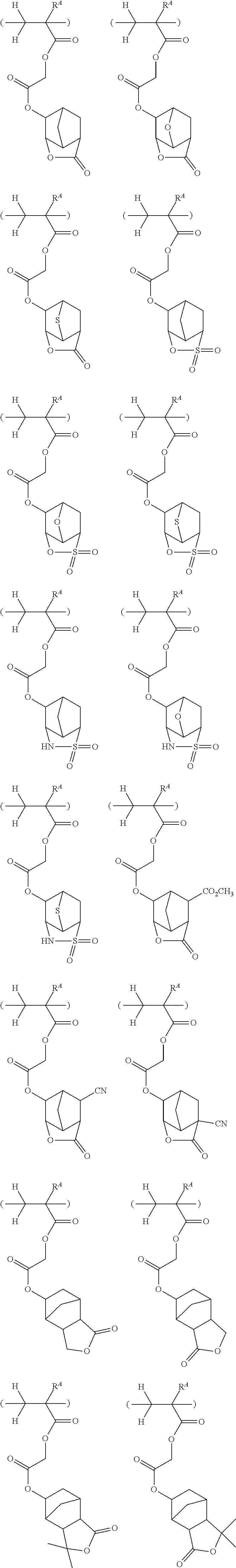

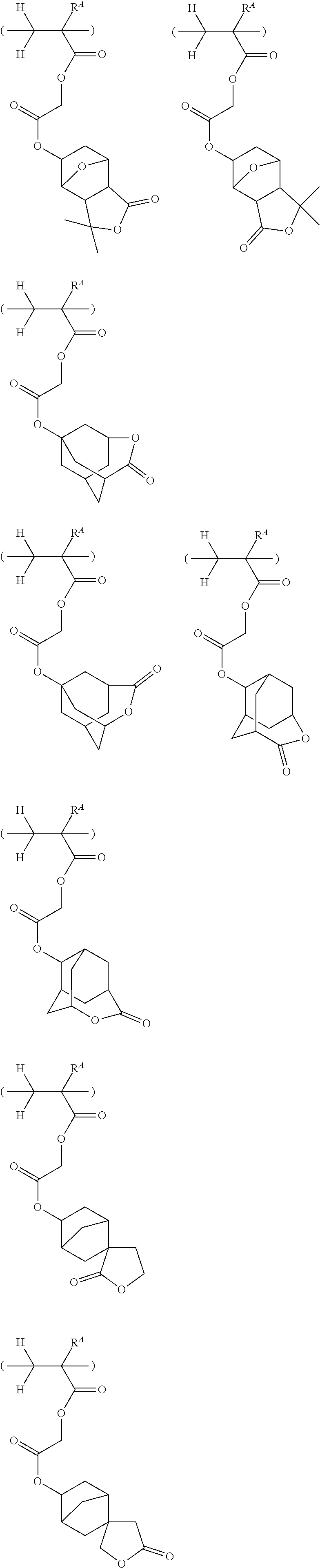

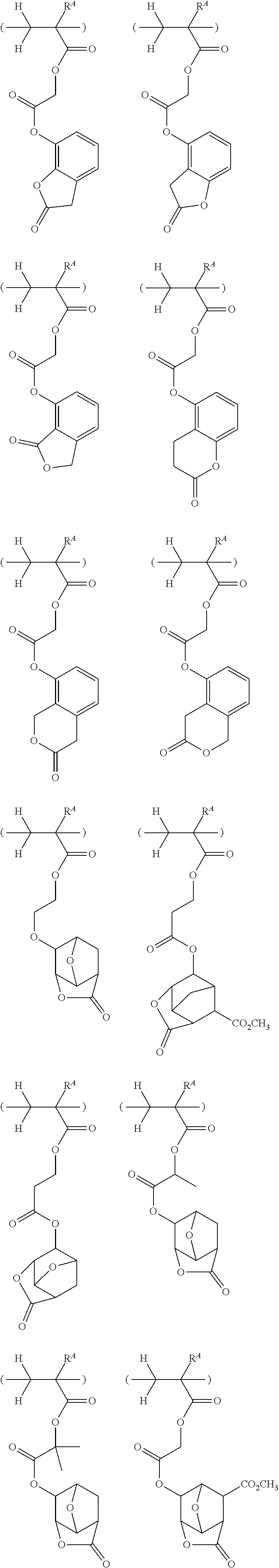

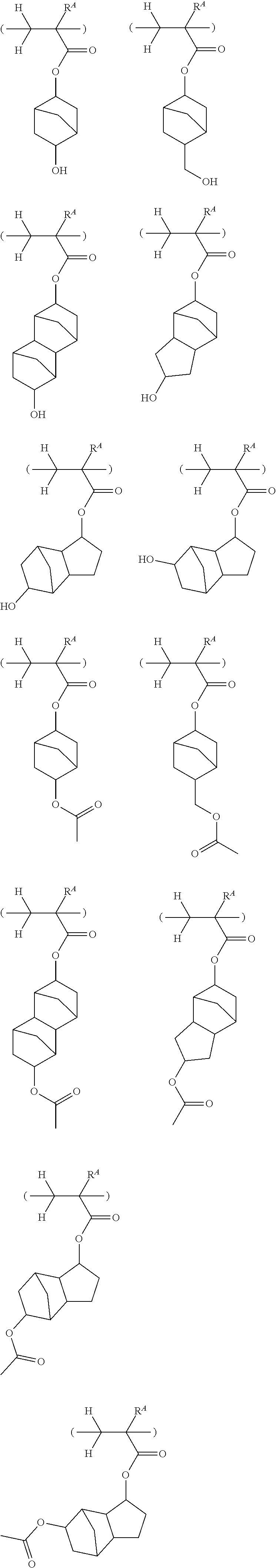

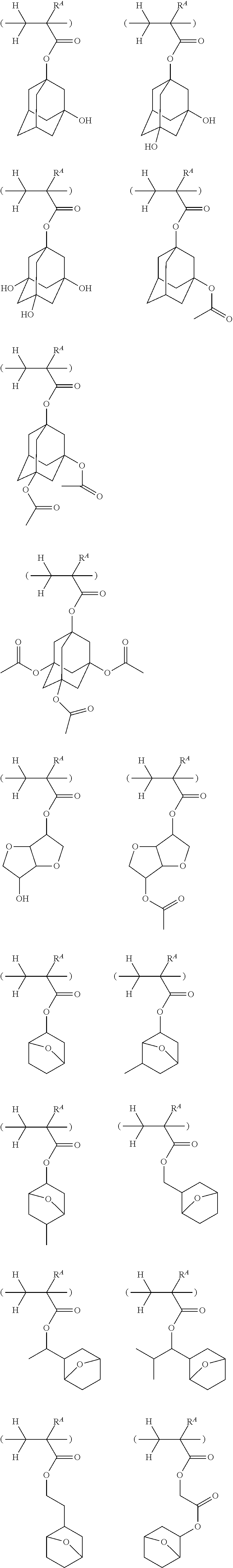

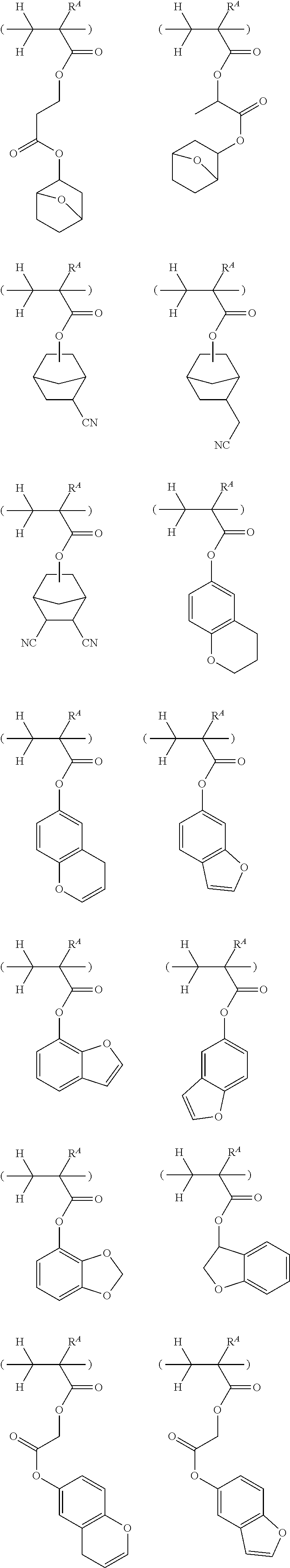

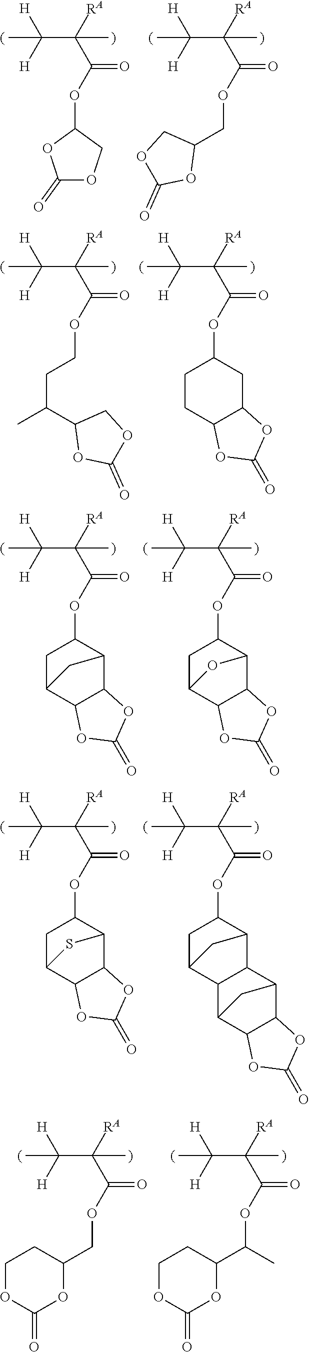

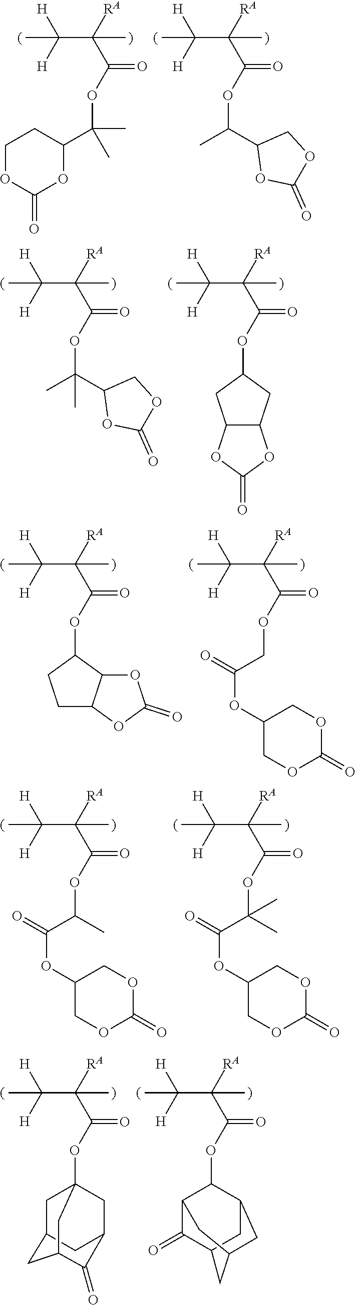

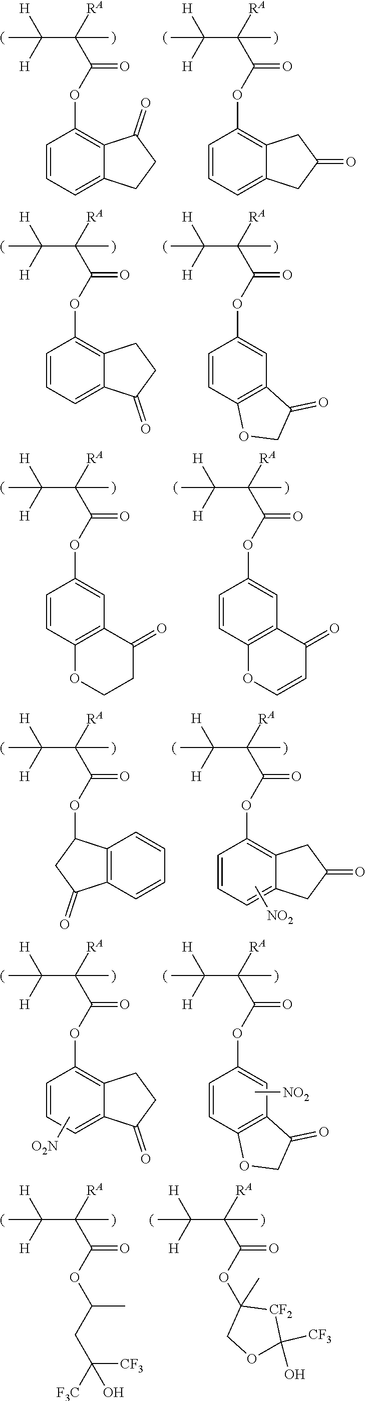

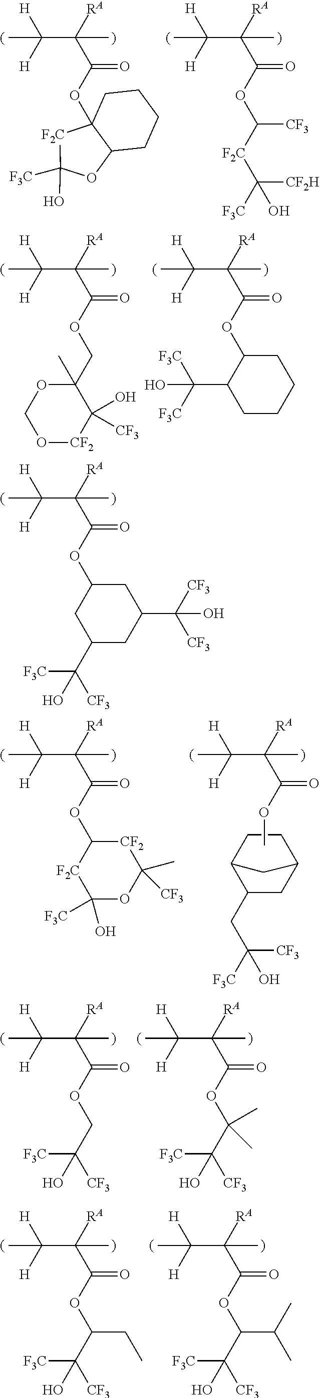

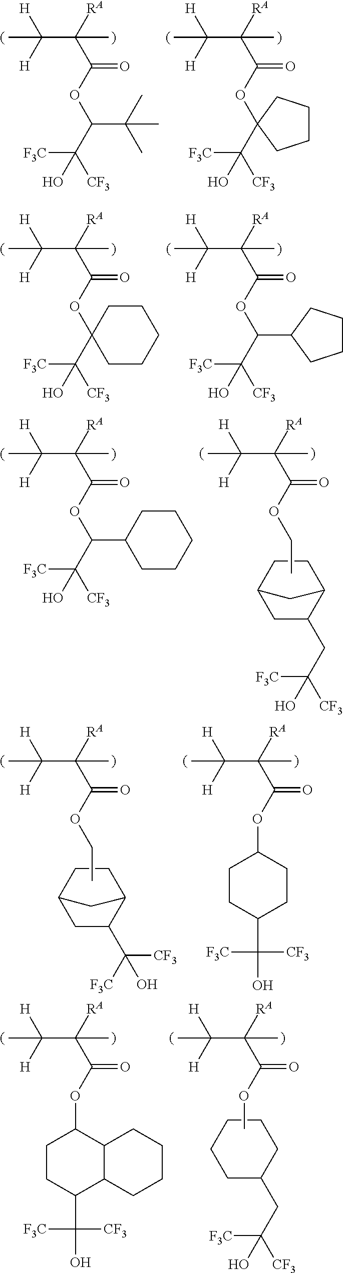

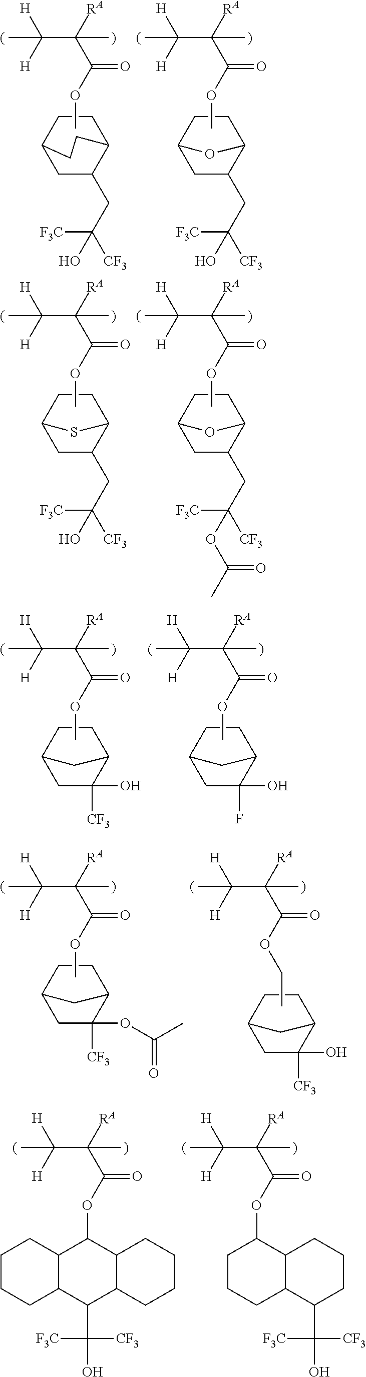

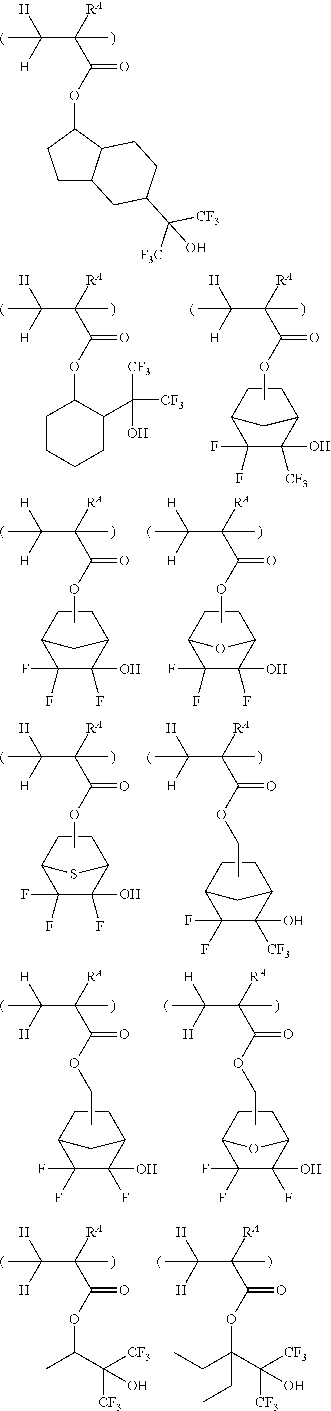

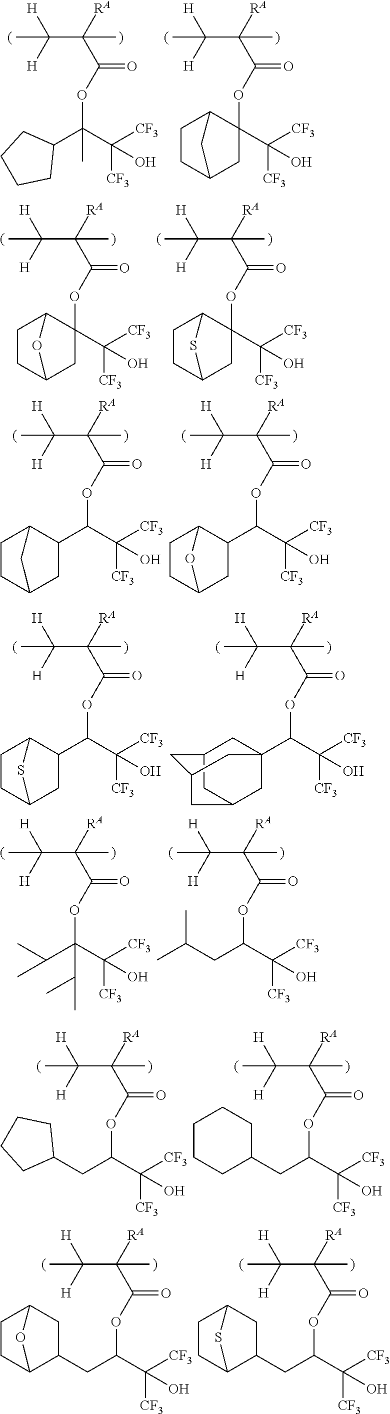

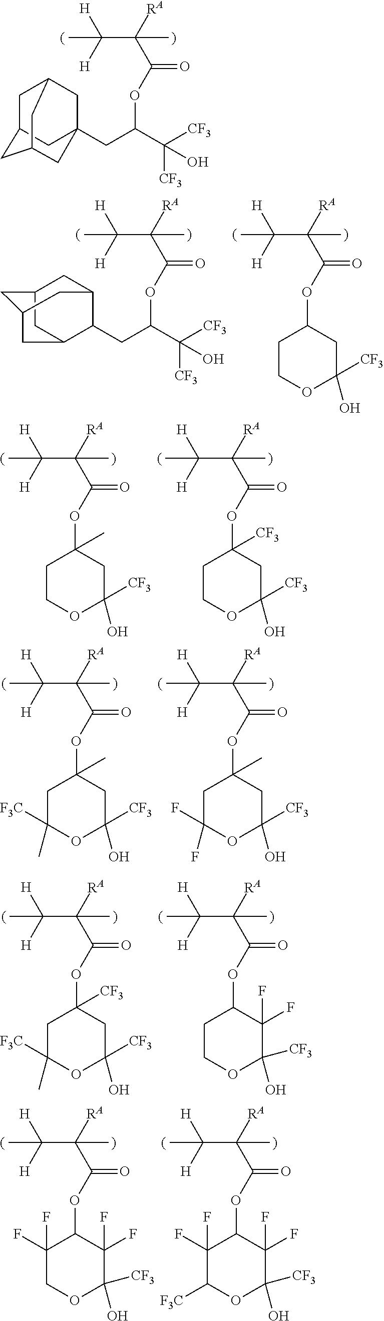

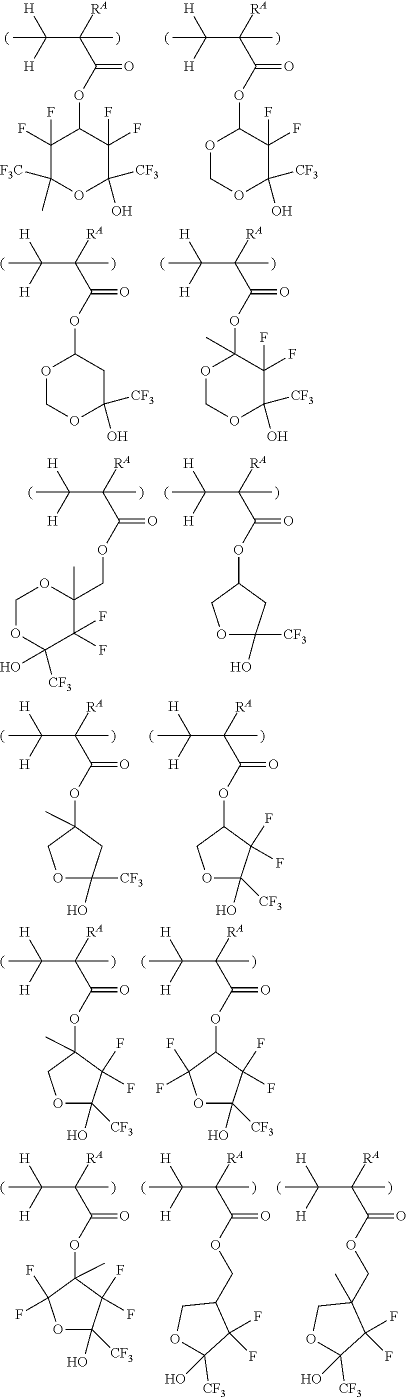

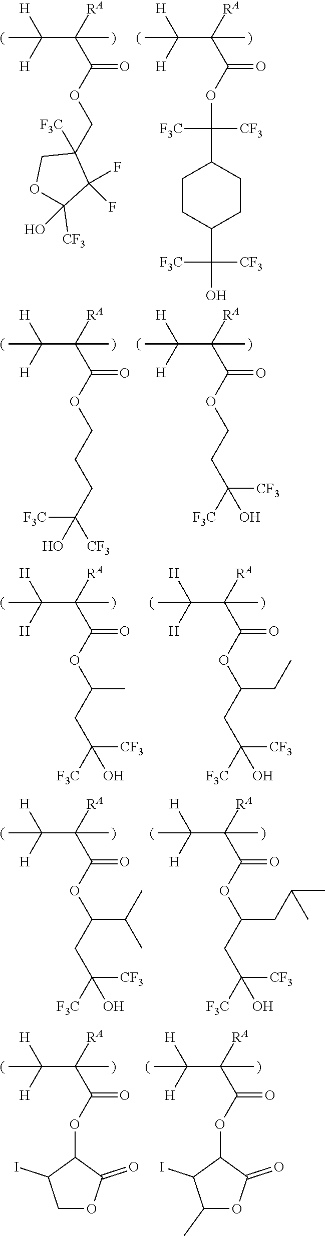

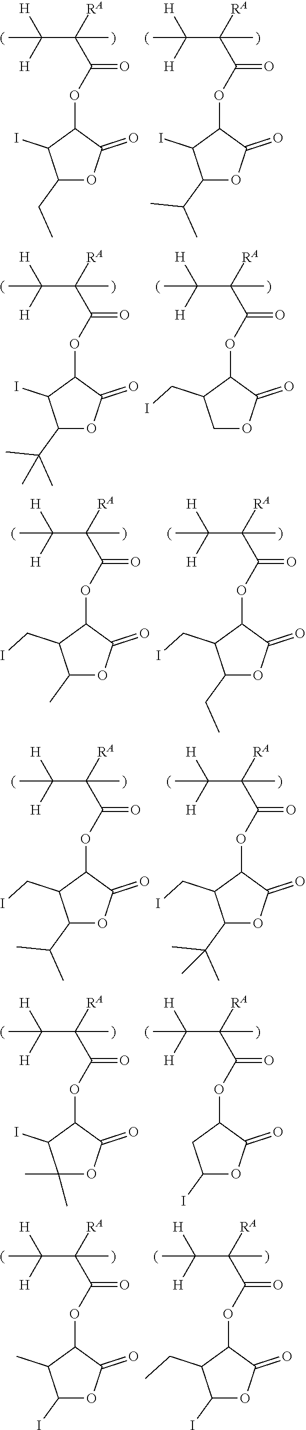

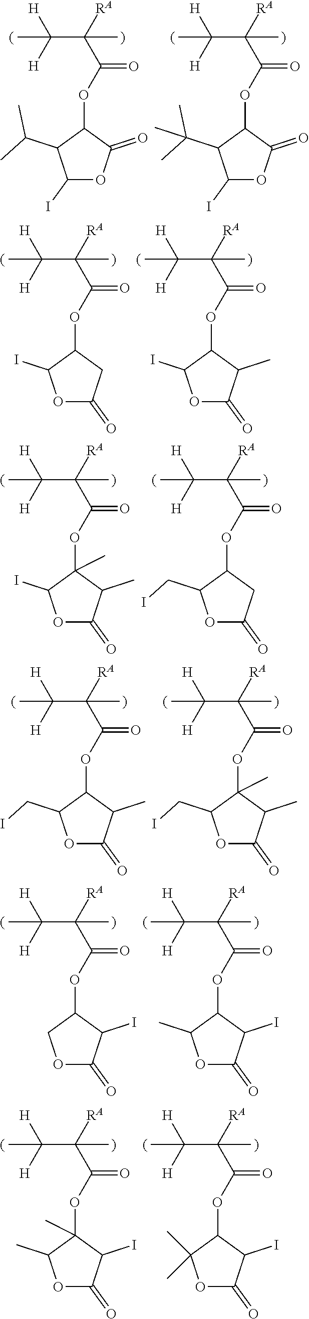

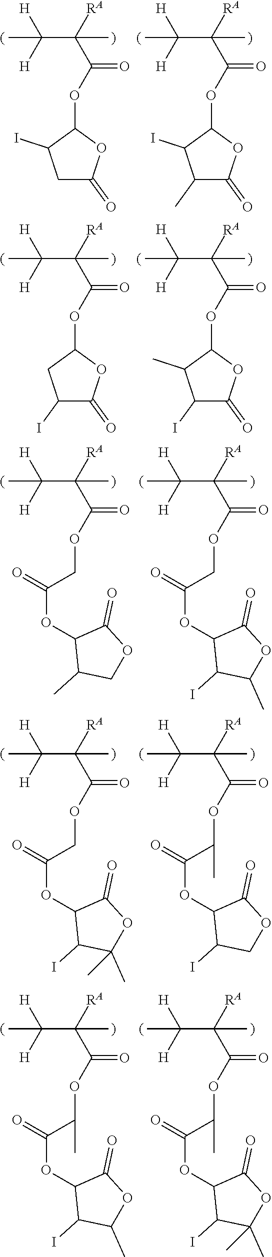

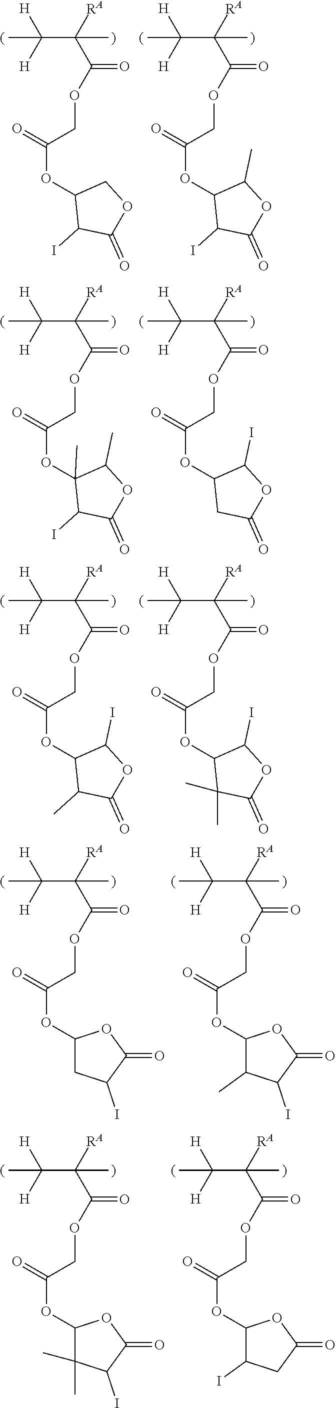

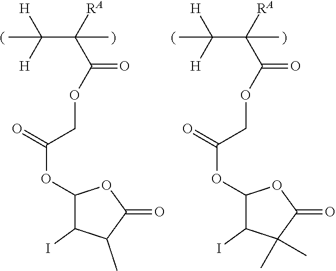

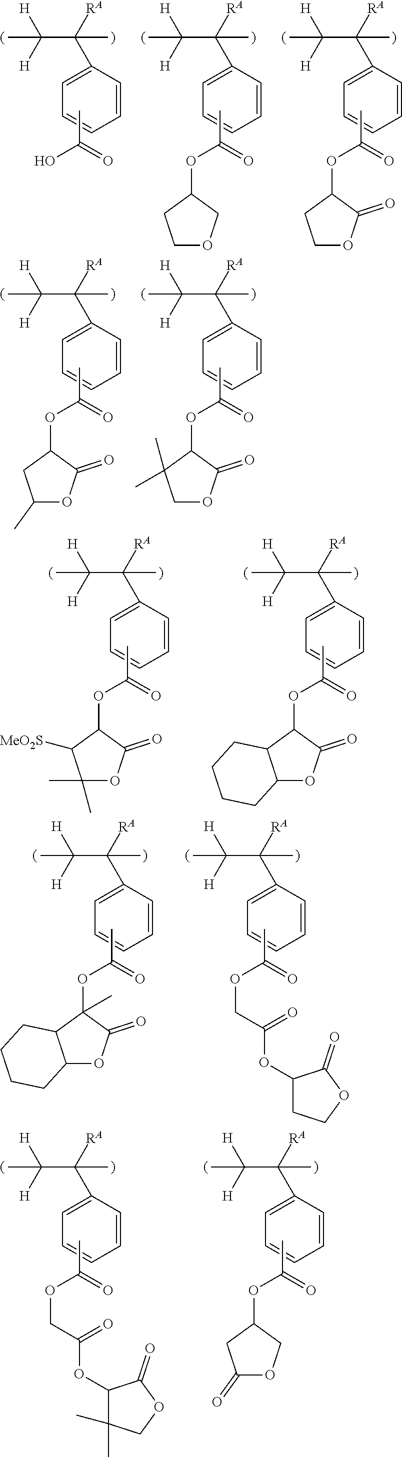

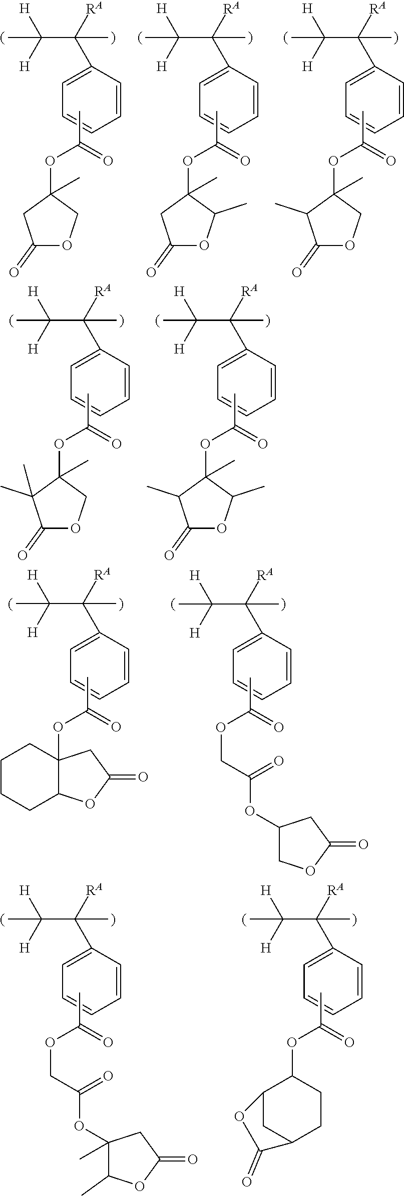

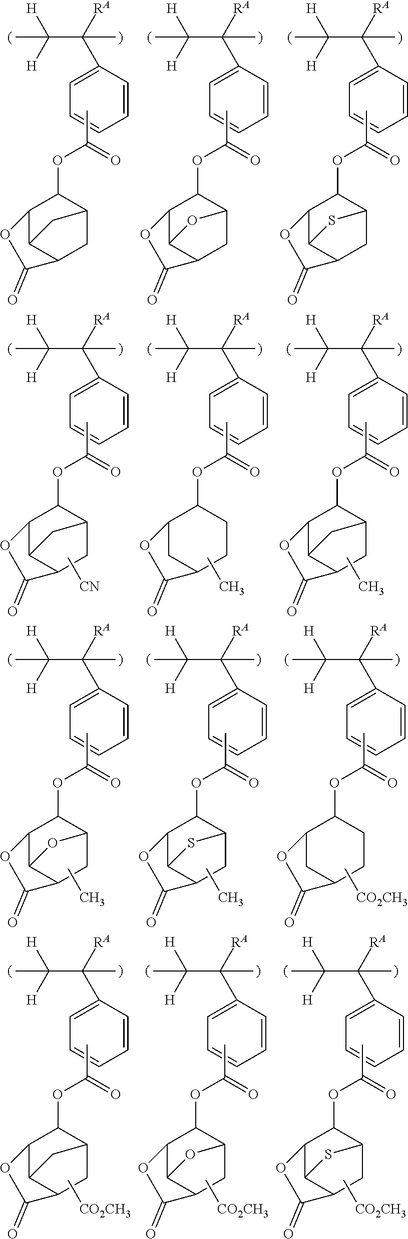

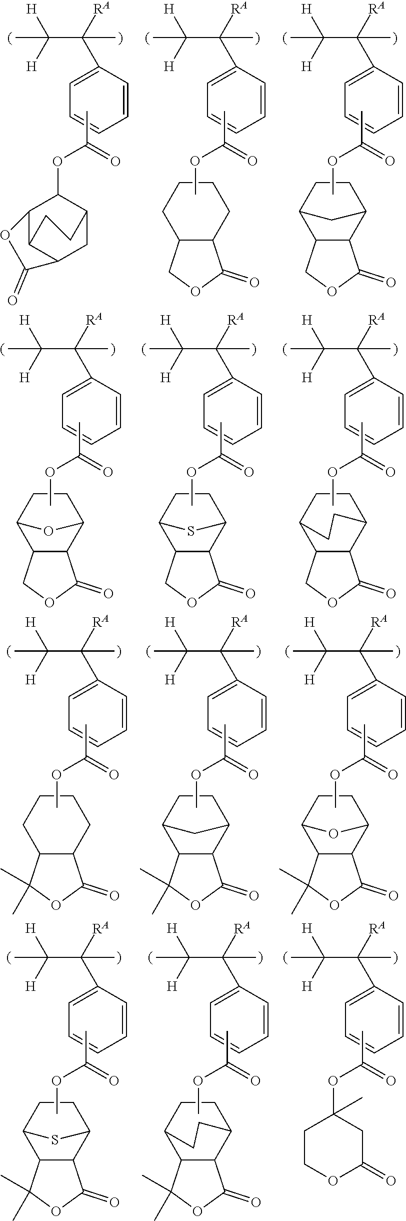

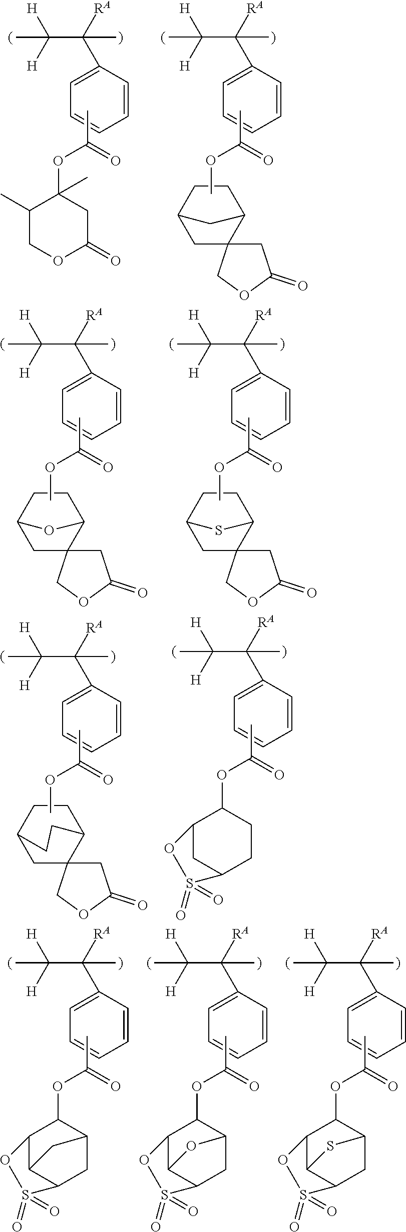

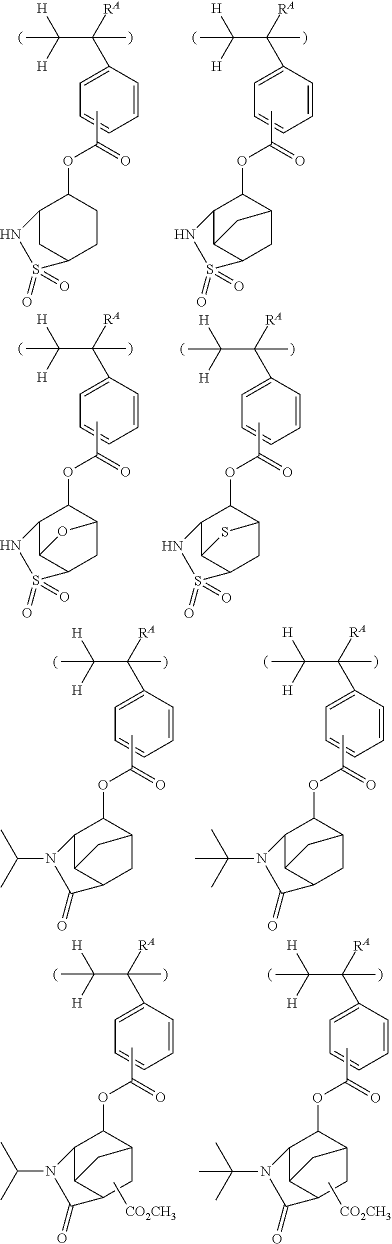

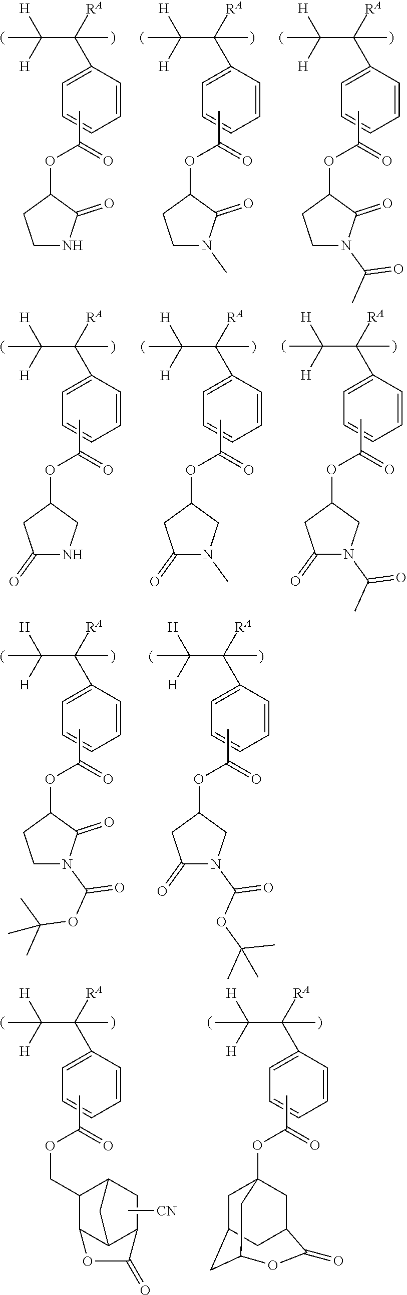

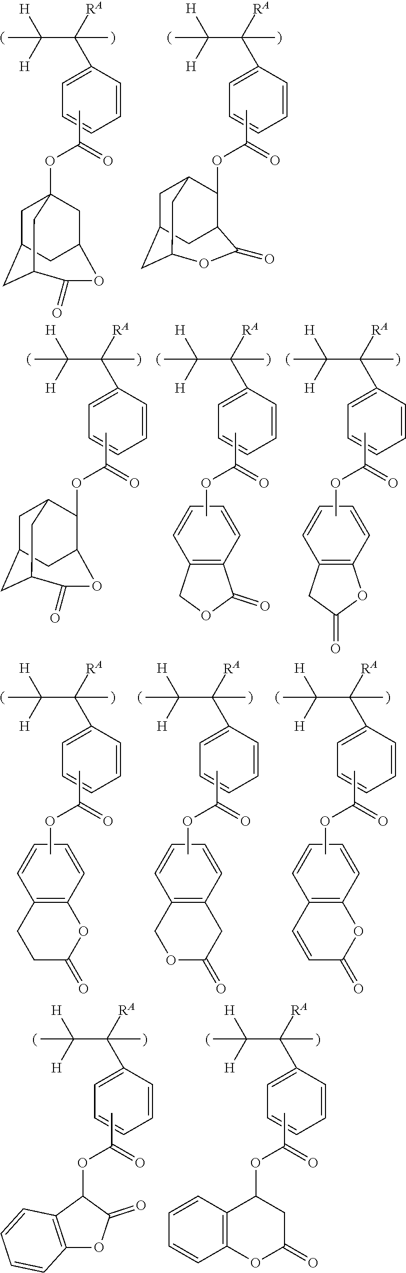

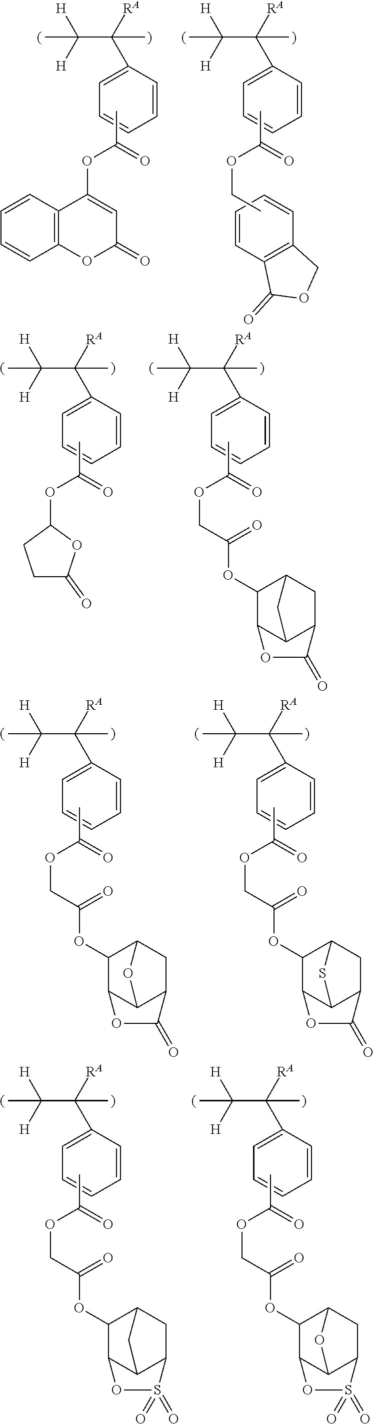

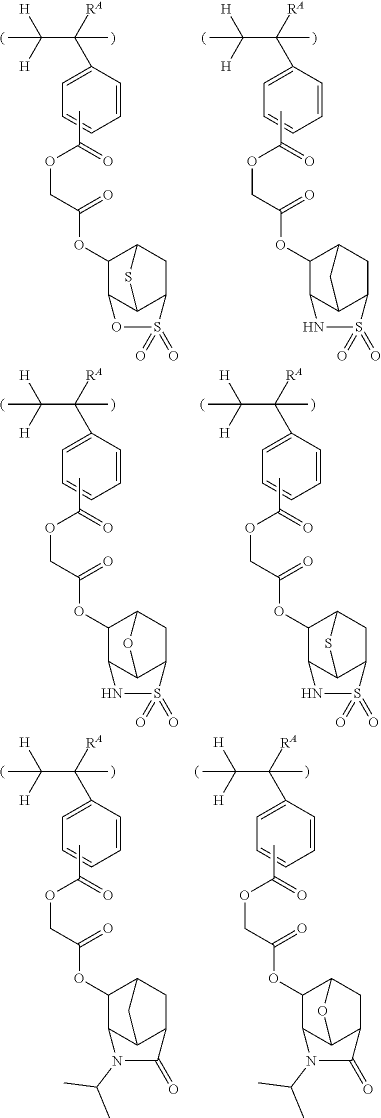

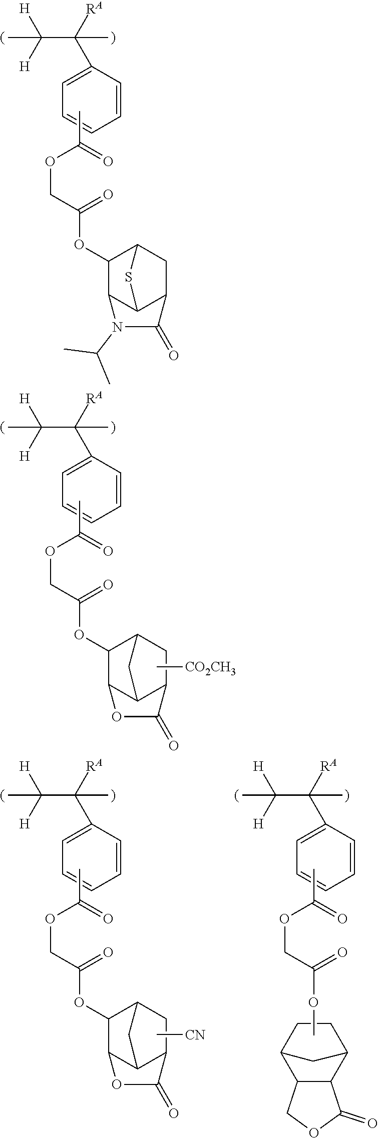

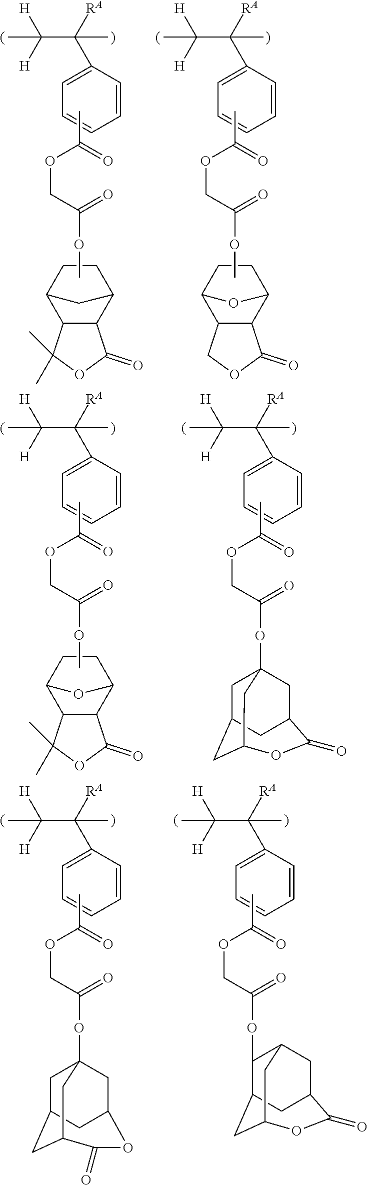

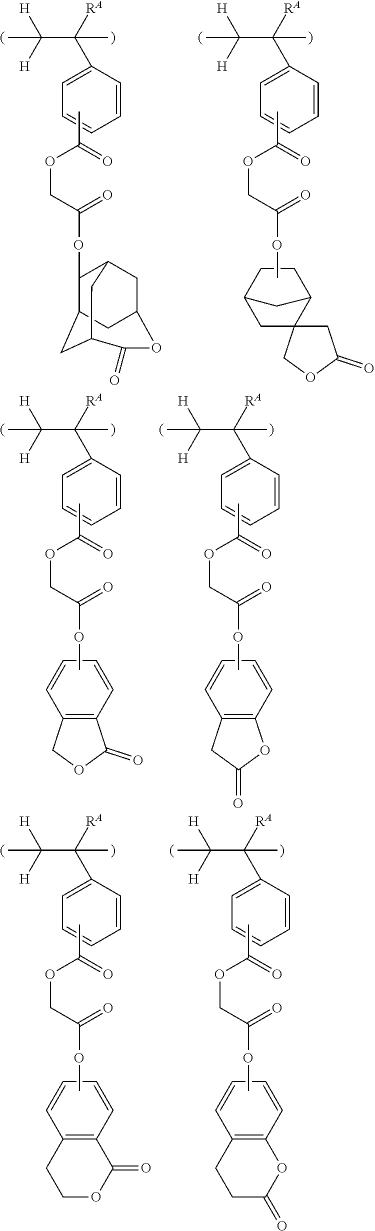

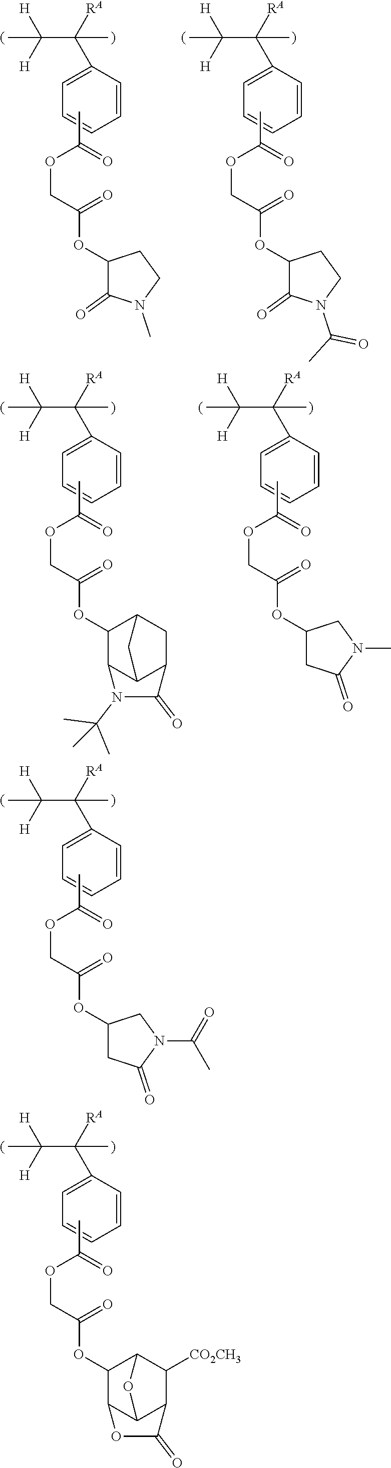

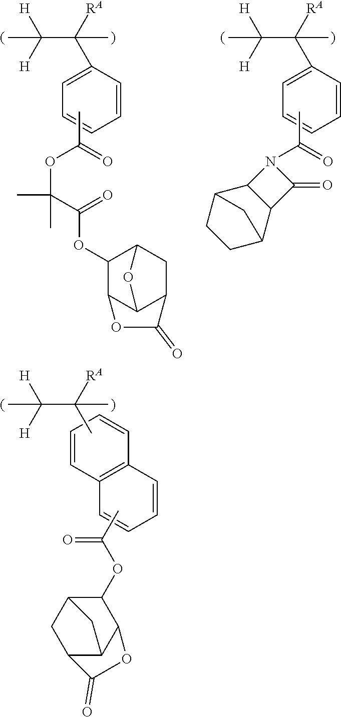

The polymer may further comprise repeat units of at least one type selected from repeat units having the formula (c1), repeat units having the formula (c2), repeat units having the formula (c3), repeat units having the formula (c4), and repeat units having the formula (c5), which are also referred to as repeat units (c1) to (c5).

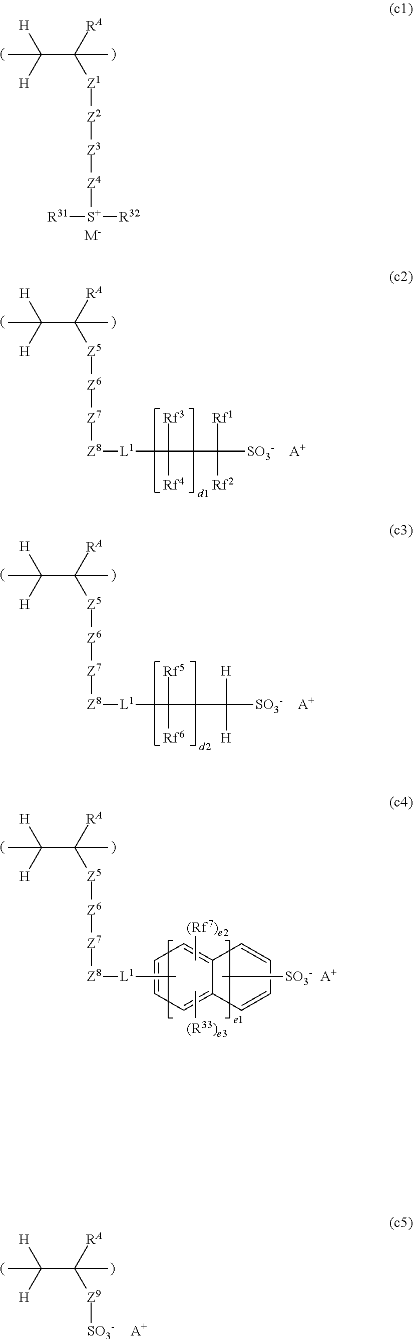

In formulae (c1) to (c5), R^{A} is each independently hydrogen, fluorine, methyl or trifluoromethyl.

Z¹ is a single bond or optionally substituted phenylene group. Z² is a single bond, **—C(═O)—O—Z²¹—, **—C(═O)—N(H)—Z²¹—, or **—O—Z²¹—. Z²¹ is a C₁-C₆ aliphatic hydrocarbylene group, phenylene group or a divalent group obtained by combining the foregoing, which may contain halogen, carbonyl moiety, ester bond, ether bond or hydroxy moiety. Z³ is a single bond, ether bond, ester bond, sulfonate ester bond, amide bond, sulfonamide bond, carbonate bond or carbamate bond. Z⁴ is a single bond or a C₁-C₆ aliphatic hydrocarbylene group, phenylene group or a divalent group obtained by combining the foregoing, which may contain halogen, carbonyl moiety, ester bond, ether bond or hydroxy moiety.

Z⁵ is each independently a single bond, optionally substituted phenylene group, optionally substituted naphthylene group, *—C(═O)—O—Z⁵¹— or *—C(═O)—N(R)—Z⁵—. Z⁵¹ is a C₁-C₁₀ aliphatic hydrocarbylene group, phenylene group or naphthylene group, the aliphatic hydrocarbylene group may contain halogen, hydroxy, ether bond, ester bond or lactone ring. R is hydrogen or a C₁-C₁₀ hydrocarbyl group which may contain a heteroatom.

Z⁶ is a single bond, ether bond, ester bond, sulfonate ester bond, amide bond, sulfonamide bond, carbonate bond or carbamate bond. Z⁷ is each independently a single bond, ***—Z⁷¹—C(═O)—O—, ***—C(═O)—N(R)—Z⁷¹— or ***—O—Z⁷¹—. Z⁷¹ is a C₁-C₂₀ hydrocarbylene group which may contain a heteroatom and R is as defined above. Z⁸ is each independently a single bond, ****—Z⁸¹—C(═O)—O—, ****—C(═O)—N(R)—Z⁸¹— or ****—O—Z⁸¹—. Z⁸¹ is a C₁-C₂₀ hydrocarbylene group which may contain a heteroatom and R is as defined above.

Z⁹ is a single bond, methylene, ethylene, phenylene, fluorinated phenylene, trifluoromethyl-substituted phenylene, *—C(═O)—O—Z⁹¹—, *—C(═O)—N(R)—Z⁹¹— or *—O—Z⁹¹—. Z⁹¹ is a C₁-C₆ aliphatic hydrocarbylene group, phenylene group, fluorinated phenylene group, or trifluoromethyl-substituted phenylene group, which may contain carbonyl, ester bond, ether bond or hydroxy and R is as defined above.

Herein, * designates a point of attachment to the carbon atom in the backbone, ** designates a point of attachment to Z¹, *** designates a point of attachment to Z⁶, **** designates a point of attachment to Z⁷.

The aliphatic hydrocarbylene group represented by Z²¹, Z⁵¹ and Z⁹¹ may be straight, branched or cyclic. Examples thereof include alkanediyl groups such as methanediyl, ethane-1,1-diyl, ethane-1,2-diyl, propane-1,1-diyl, propane-1,2-diyl, propane-1,3-diyl, propane-2,2-diyl, butane-1,1-diyl, butane-1,2-diyl, butane-1,3-diyl, butane-2,3-diyl, butane-1,4-diyl, 1,1-dimethylethane-1,2-diyl, pentane-1,5-diyl, 2-methylbutane-1,2-diyl, and hexane-1,6-diyl; cycloalkanediyl groups such as cyclopropanediyl, cyclobutanediyl, cyclopentanediyl and cyclohexanediyl, and combinations thereof.

The hydrocarbylene group which may contain a heteroatom, represented by Z⁷¹ and Z⁸¹, may be saturated or unsaturated and straight, branched or cyclic. Examples thereof are shown below, but not limited thereto.

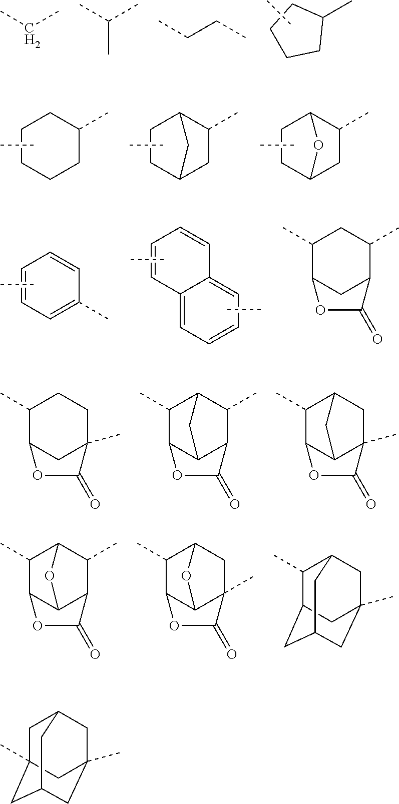

In formula (c1), R³¹ and R³² are each independently a C₁-C₂₀ hydrocarbyl group which may contain a heteroatom. The hydrocarbyl group may be saturated or unsaturated and straight, branched or cyclic. Examples thereof include C₁-C₂₀ alkyl groups such as methyl, ethyl, n-propyl, isopropyl, n-butyl, isobutyl, sec-butyl, and tert-butyl; C₃-C₂₀ cyclic saturated hydrocarbyl groups such as cyclopropyl, cyclopentyl, cyclohexyl, cyclopropylmethyl, 4-methylcyclohexyl, cyclohexylmethyl, norbornyl, and adamantyl; C₂-C₂₀ alkenyl groups such as vinyl, 1-propenyl, 2-propenyl, butenyl, and hexenyl; C₃-C₂₀ cyclic unsaturated hydrocarbyl groups such as cyclohexenyl; C₆-C₂₀ aryl groups such as phenyl, naphthyl and thienyl; C₇-C₂₀ aralkyl groups such as benzyl, 1-phenylethyl, and 2-phenylethyl, and combinations thereof. Of these, aryl groups are preferred. In the hydrocarbyl group, some or all hydrogen may be substituted by a moiety containing a heteroatom such as oxygen, sulfur, nitrogen or halogen, and some —CH₂— may be replaced by a moiety containing a heteroatom such as oxygen, sulfur or nitrogen, so that the group may contain a hydroxy, fluorine, chlorine, bromine, iodine, cyano, carbonyl, ether bond, ester bond, sulfonate ester bond, carbonate bond, lactone ring, sultone ring, carboxylic anhydride (—C(═O)—O—C(═O)—) or haloalkyl moiety.

R³¹ and R³² may bond together to form a ring with the sulfur atom to which they are attached. Examples of the ring are shown below.

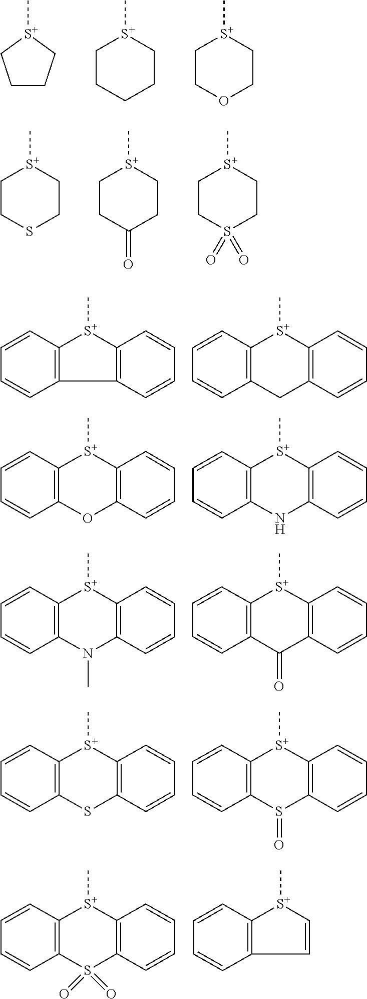

The broken line designates a point of attachment to Z⁴.

Examples of the cation in repeat unit (c1) are given below, but not limited thereto. Herein R^{A} is as defined above.

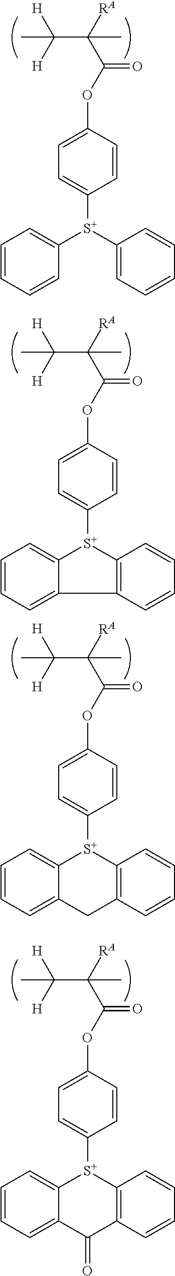

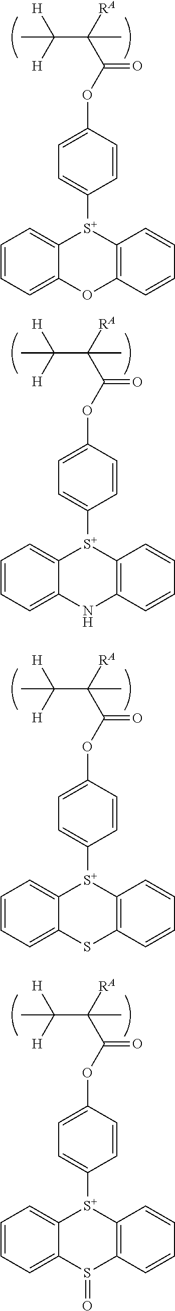

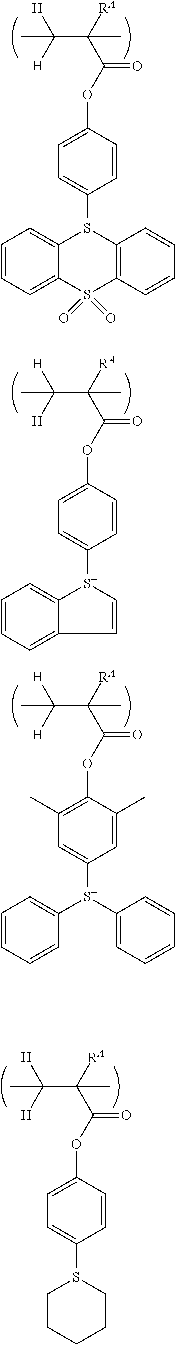

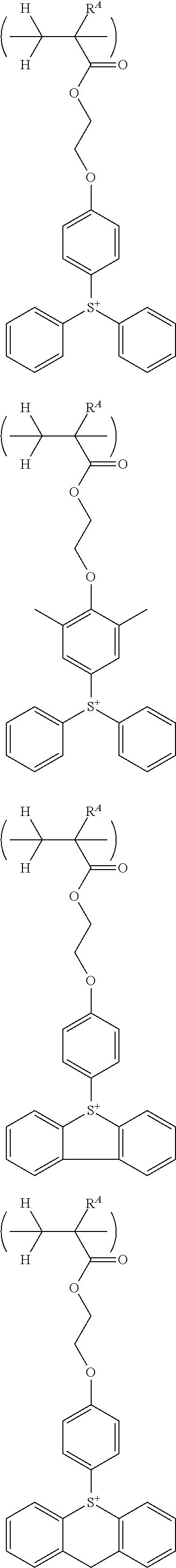

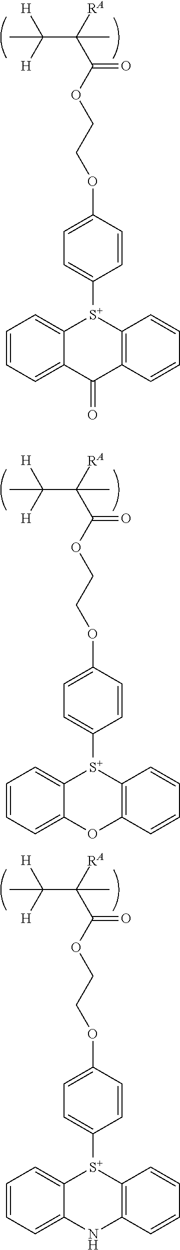

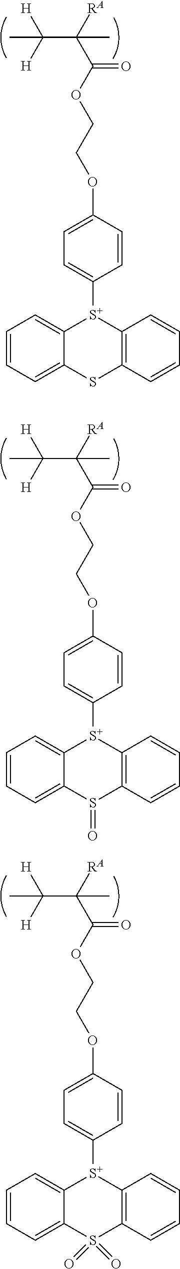

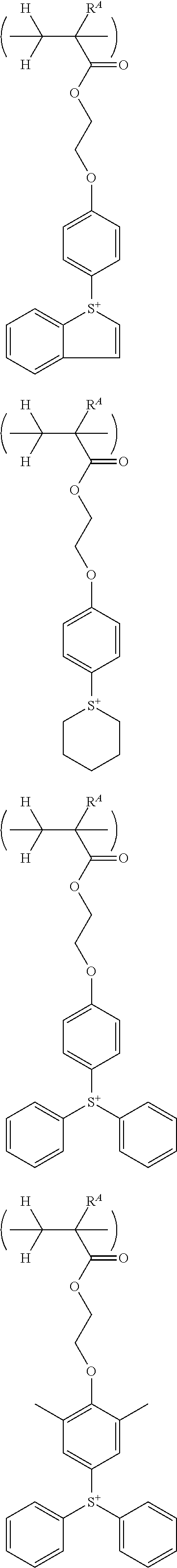

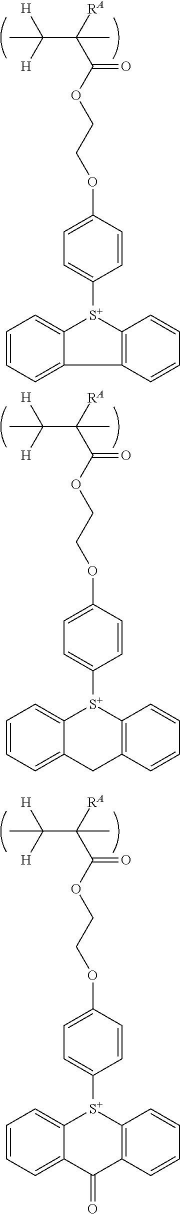

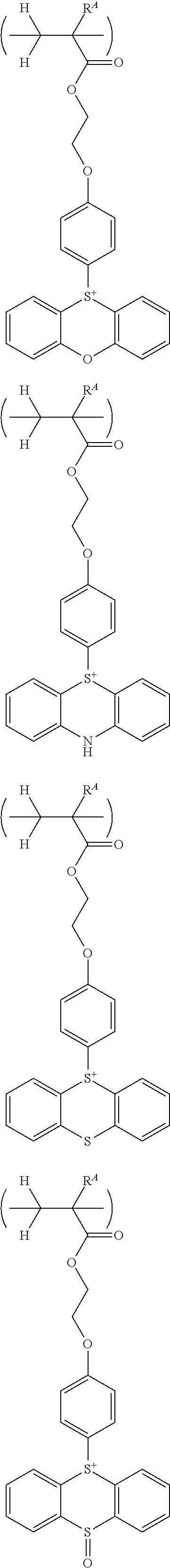

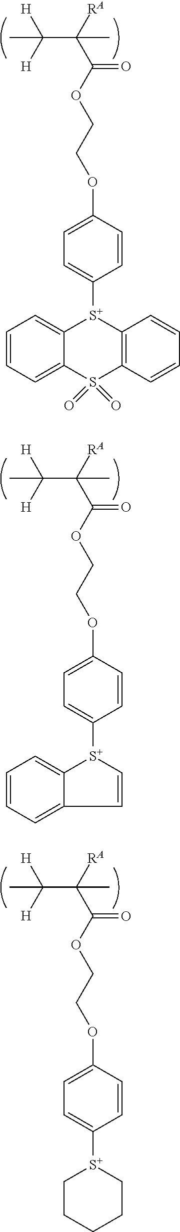

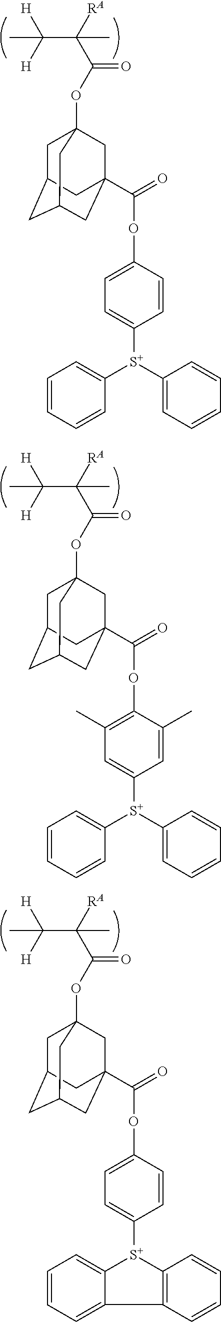

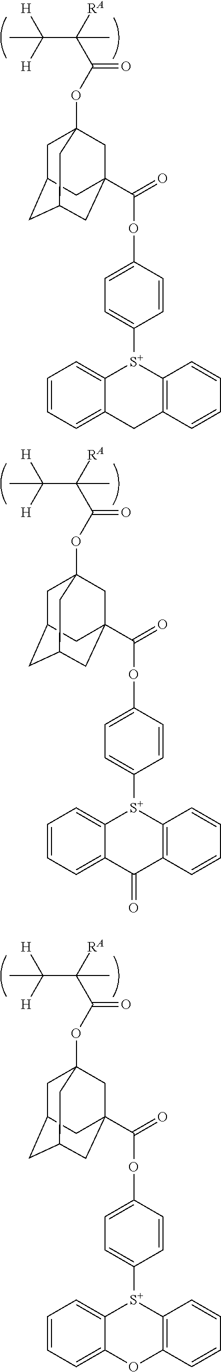

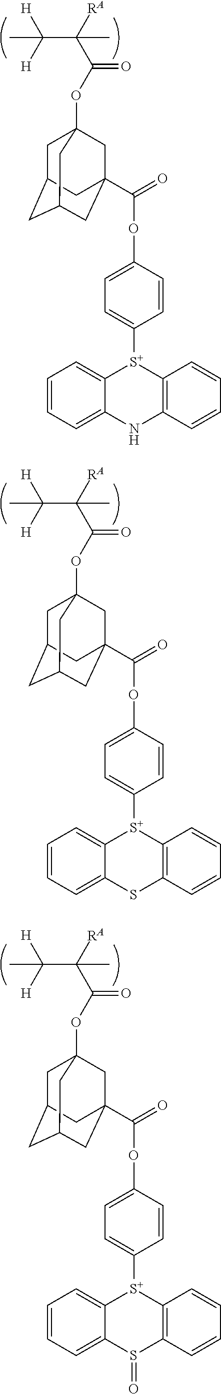

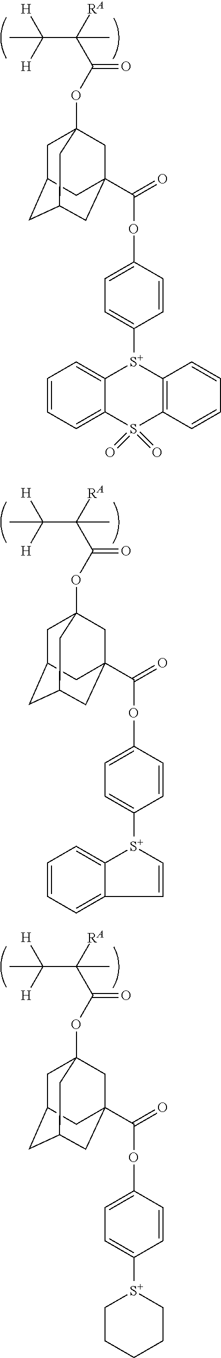

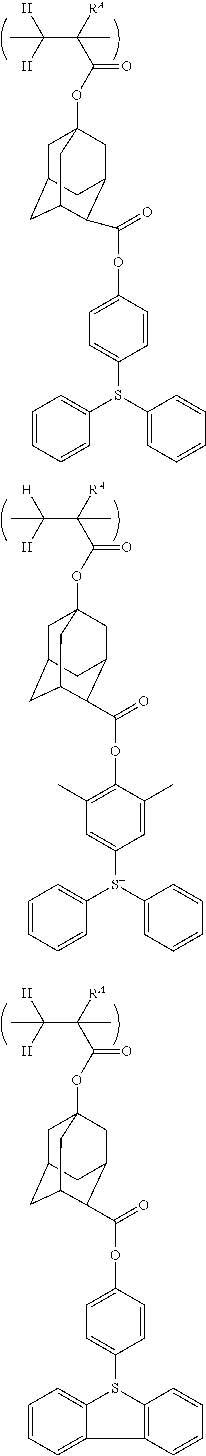

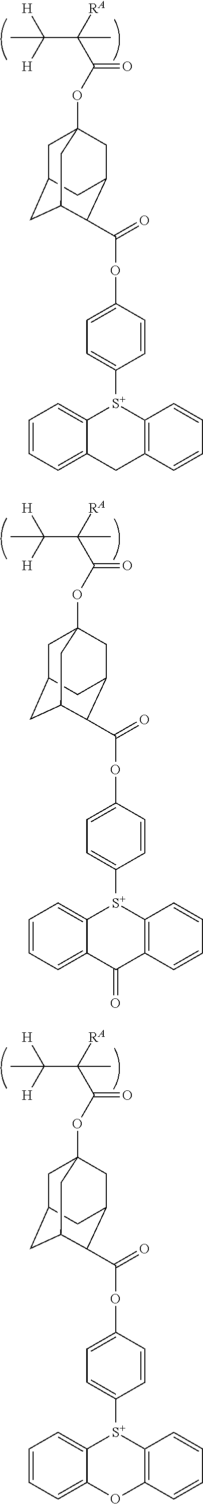

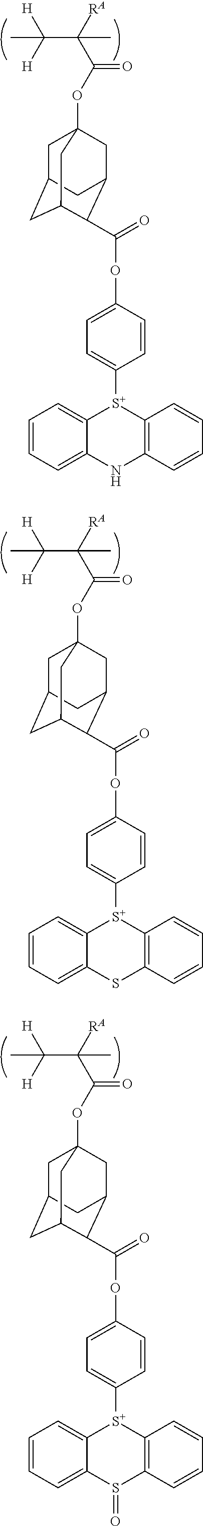

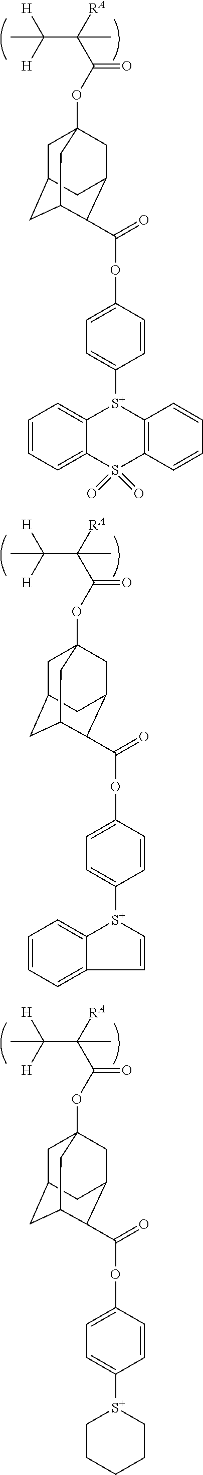

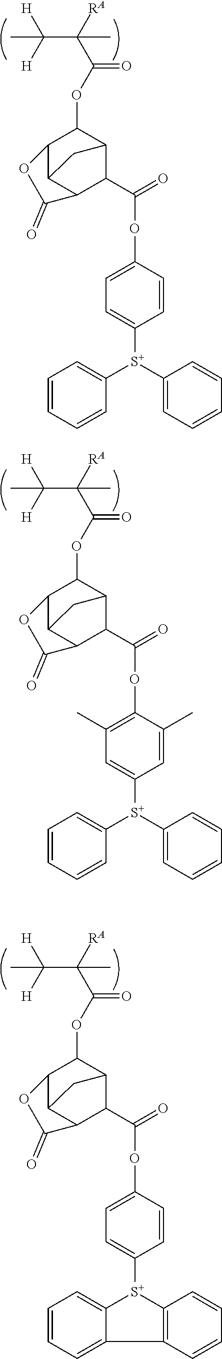

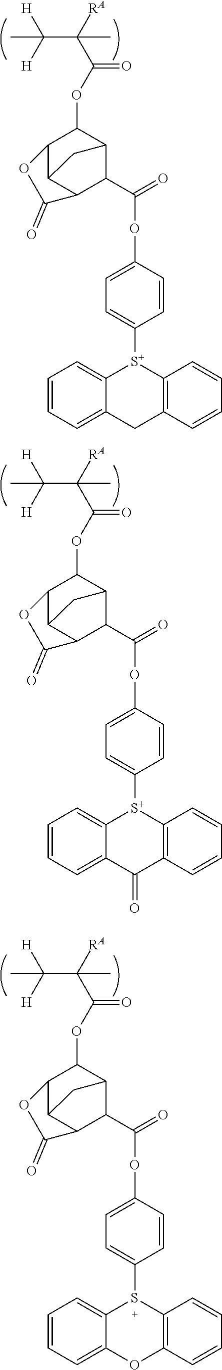

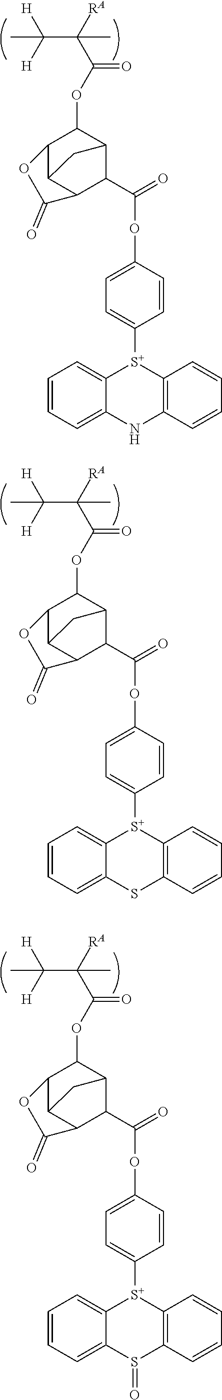

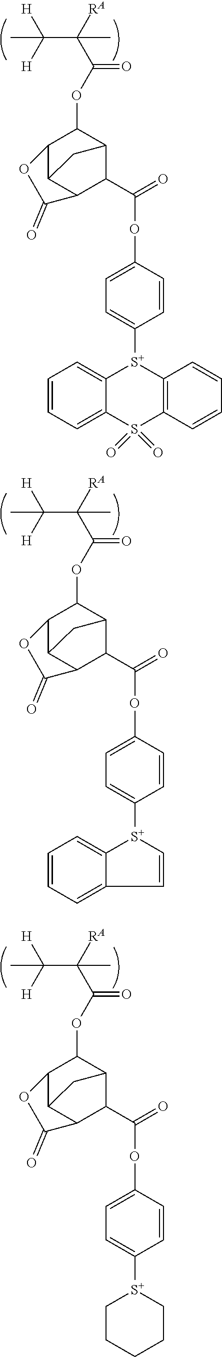

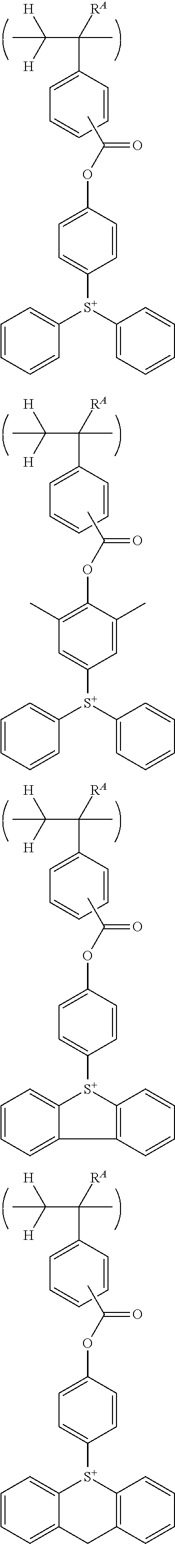

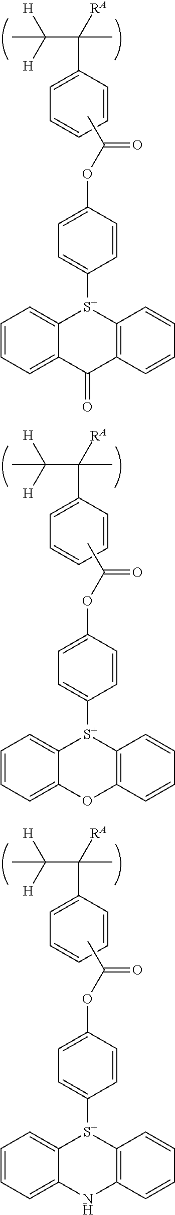

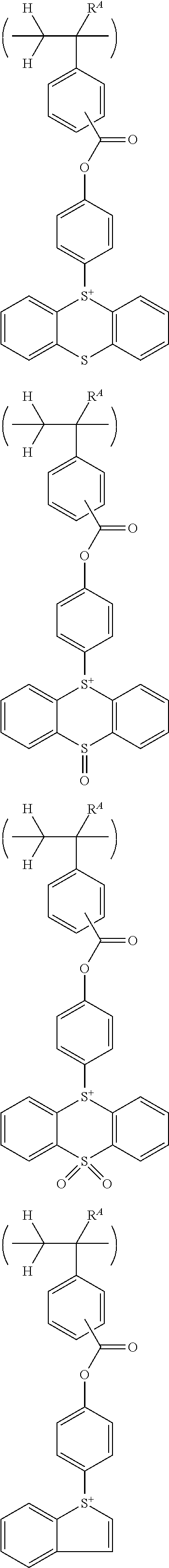

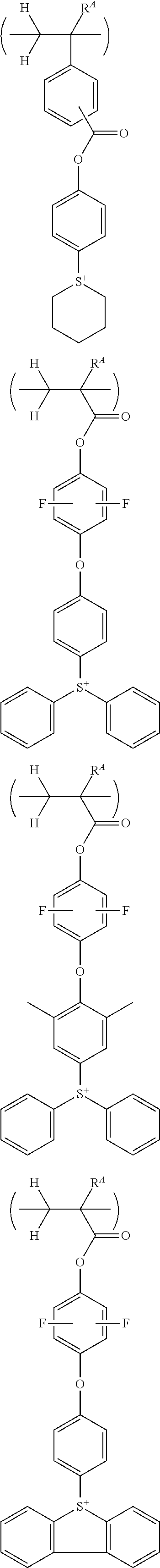

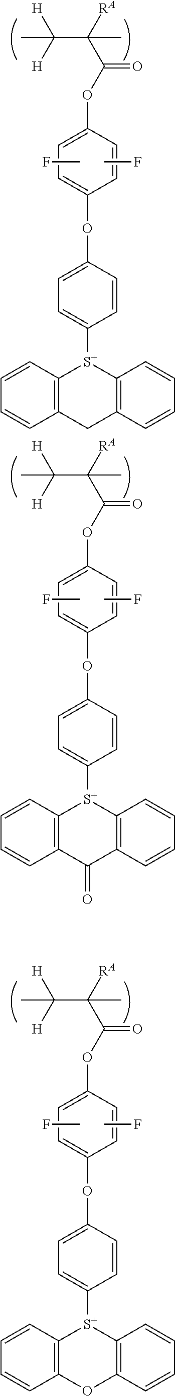

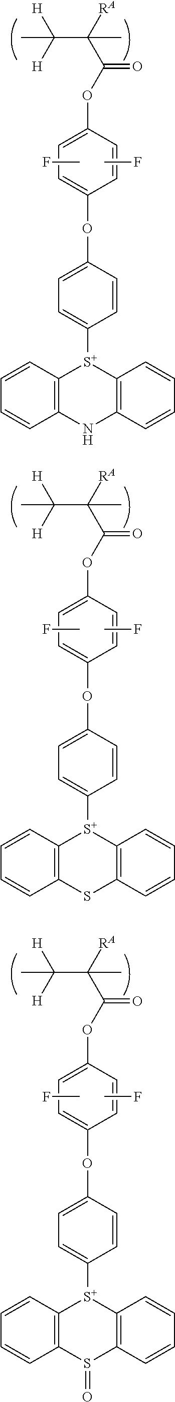

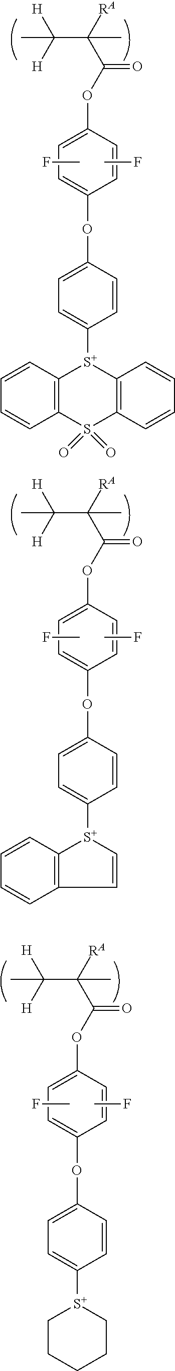

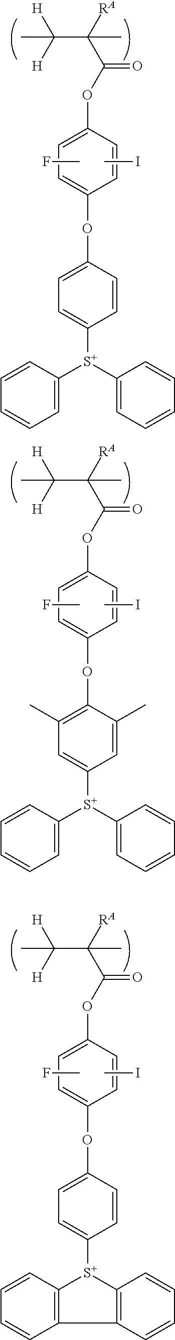

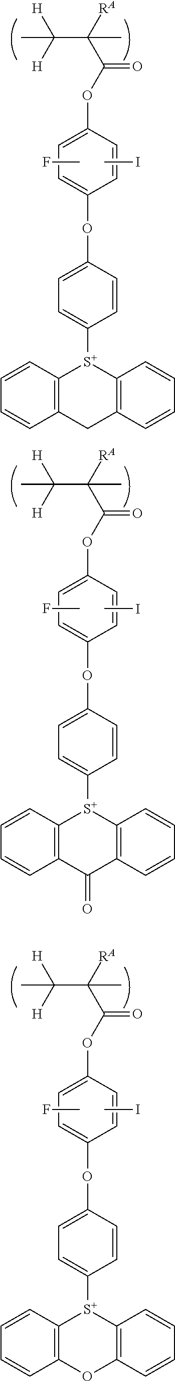

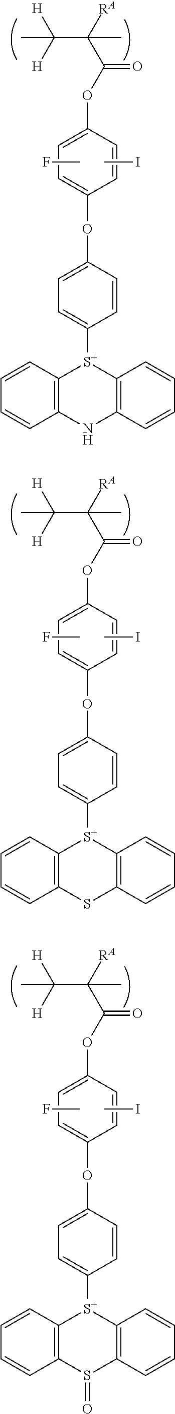

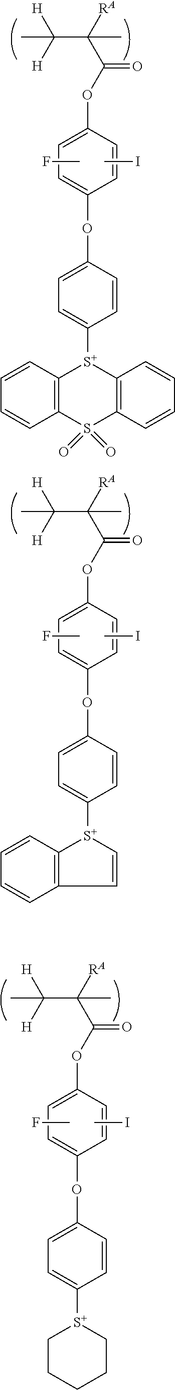

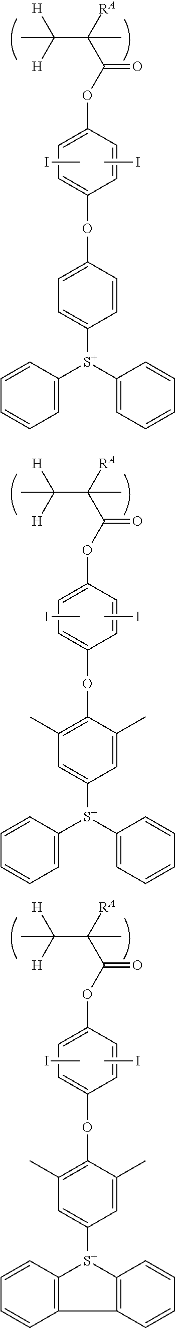

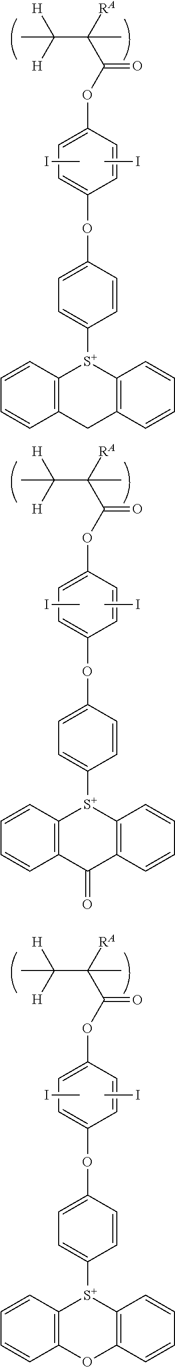

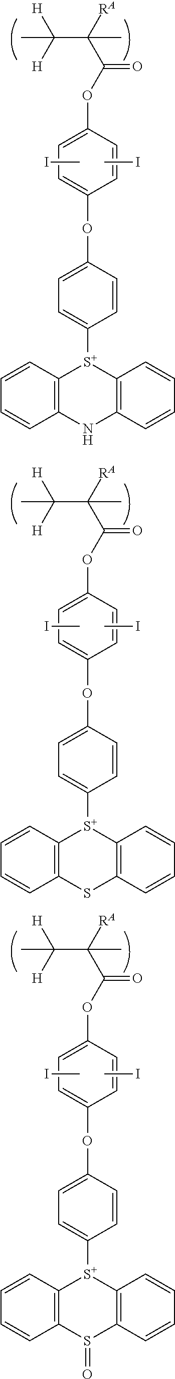

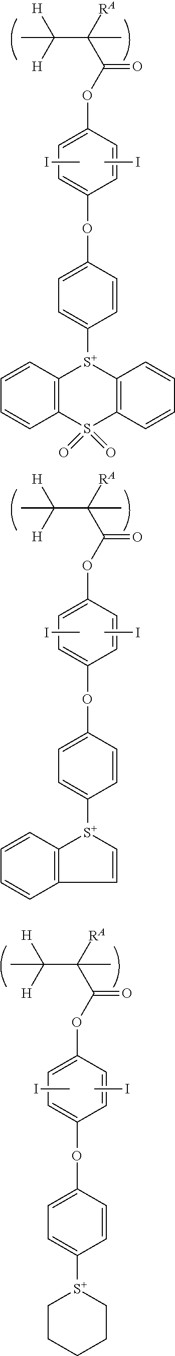

In formula (c1), M⁻ is a non-nucleophilic counter ion. Halide, sulfonate, imide and methide anions are preferred. Examples of the non-nucleophilic counter ion include halide ions such as chloride and bromide ions; sulfonate anions, specifically fluoroalkylsulfonate ions such as triflate, 1,1,1-trifluoroethanesulfonate, and nonafluorobutanesulfonate, arylsulfonate ions such as tosylate, benzenesulfonate, 4-fluorobenzenesulfonate, and 1,2,3,4,5-pentafluorobenzenesulfonate, alkylsulfonate ions such as mesylate and butanesulfonate; imide ions such as bis(trifluoromethylsulfonyl)imide, bis(perfluoroethylsulfonyl)imide and bis(perfluorobutylsulfonyl)imide; and methide ions such as tris(trifluoromethylsulfonyl)methide and tris(perfluoroethylsulfonyl)methide.

Anions having the following formulae (c1-1) to (c1-4) are also useful as the non-nucleophilic counter ion.

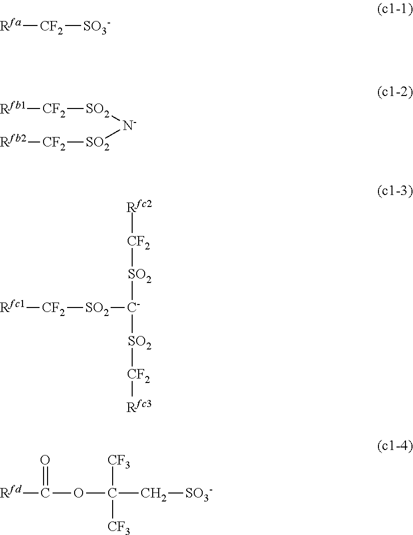

In formula (c1-1), R^{fa} is fluorine or a C₁-C₄₀ hydrocarbyl group which may contain a heteroatom. The hydrocarbyl group may be saturated or unsaturated and straight, branched or cyclic. Examples thereof are as will be exemplified below for the hydrocarbyl group R^{fa1} in formula (c1-1-1). In the hydrocarbyl group, some or all hydrogen may be substituted by a moiety containing a heteroatom such as oxygen, sulfur, nitrogen or halogen, and some —CH₂— may be replaced by a moiety containing a heteroatom such as oxygen, sulfur or nitrogen, so that the group may contain a hydroxy, fluorine, chlorine, bromine, iodine, cyano, nitro, carbonyl, ether bond, ester bond, sulfonate ester bond, carbonate bond, lactone ring, sultone ring, carboxylic anhydride (—C(═O)—O—C(═O)—) or haloalkyl moiety.

Of the anions of formula (c1-1), an anion having the formula (c1-1-1) is preferred.

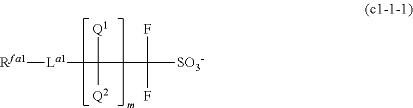

In formula (c1-1-1), Q¹ and Q² are each independently hydrogen, fluorine or a C₁-C₆ fluorinated saturated hydrocarbyl group. It is preferred for solvent solubility that at least one of Q¹ and Q² be trifluoromethyl. The subscript m is 0, 1, 2, 3 or 4, most preferably 1.

In formula (c1-1-1), R^{fa1} is a C₁-C₄₀ hydrocarbyl group which may contain a heteroatom. As the heteroatom, oxygen, nitrogen, sulfur and halogen atoms are preferred, with oxygen being most preferred. Of the hydrocarbyl groups, those groups of 6 to 30 carbon atoms are preferred from the aspect of achieving a high resolution in forming patterns of small feature size. The hydrocarbyl group may be saturated or unsaturated and straight, branched or cyclic. Examples thereof include C₁-C₄₀ alkyl groups such as methyl, ethyl, n-propyl, isopropyl, n-butyl, isobutyl, sec-butyl, tert-butyl, pentyl, neopentyl, hexyl, heptyl, 2-ethylhexyl, nonyl, undecyl, tridecyl, pentadecyl, heptadecyl, and icosyl; C₃-C₄₀ cyclic saturated hydrocarbyl groups such as cyclopentyl, cyclohexyl, 1-adamantyl, 2-adamantyl, 1-adamantylmethyl, norbornyl, norbornylmethyl, tricyclodecyl, tetracyclododecyl, tetracyclododecylmethyl, and dicyclohexylmethyl; C₂-C₄₀ unsaturated aliphatic hydrocarbyl groups such as 2-propenyl and 3-cyclohexenyl; C₆-C₄₀ aryl groups such as phenyl, 1-naphthyl, 2-naphthyl and 9-fluorenyl; C₇-C₄₀ aralkyl groups such as benzyl and diphenylmethyl; C₇-C₄₀ aromatic ring-containing polycyclic hydrocarbyl groups such as 9,10-ethano-9,10-dihydroanthryl and 6,13-ethano-6,13-dihydropentacenyl; C₁₇-C₄₀ steroid structure-containing hydrocarbyl groups, and combinations thereof.

In the foregoing hydrocarbyl groups, some or all hydrogen may be substituted by a moiety containing a heteroatom such as oxygen, sulfur, nitrogen or halogen, or some constituent —CH₂— may be replaced by a moiety containing a heteroatom such as oxygen, sulfur or nitrogen, so that the group may contain a hydroxy, fluorine, chlorine, bromine, iodine, cyano, nitro, carbonyl, ether bond, ester bond, sulfonate ester bond, carbonate bond, lactone ring, sultone ring, carboxylic anhydride (—C(═O)—O—C(═O)—) or haloalkyl moiety. Examples of the heteroatom-containing hydrocarbyl group include tetrahydrofuryl, methoxymethyl, ethoxymethyl, methylthiomethyl, acetamidomethyl, trifluoroethyl, (2-methoxyethoxy)methyl, acetoxymethyl, 2-carboxy-1-cyclohexyl, 2-oxopropyl, 4-oxo-1-adamantyl, and 3-oxocyclohexyl.

In formula (c1-1-1), L^{a1} is a single bond, ether bond, ester bond, sulfonate ester bond, carbonate bond or carbamate bond. From the aspect of synthesis, an ether bond or ester bond is preferred, with the ester bond being more preferred.

Examples of the anion having formula (c1-1) are shown below, but not limited thereto. Herein Q¹ is as defined above.

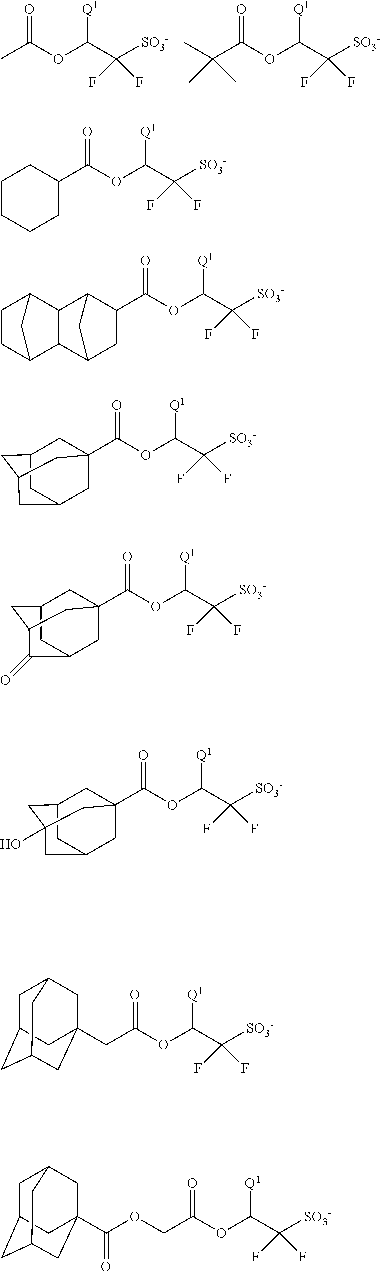

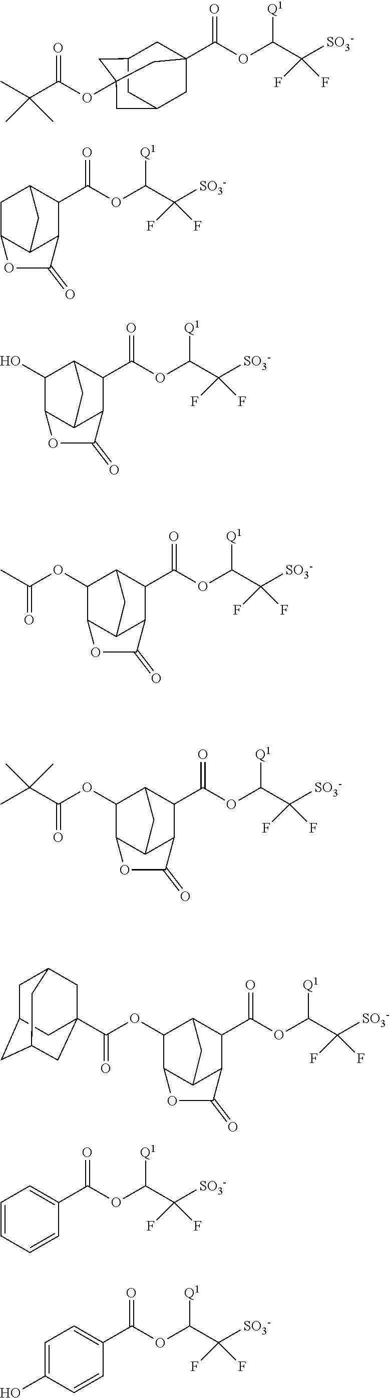

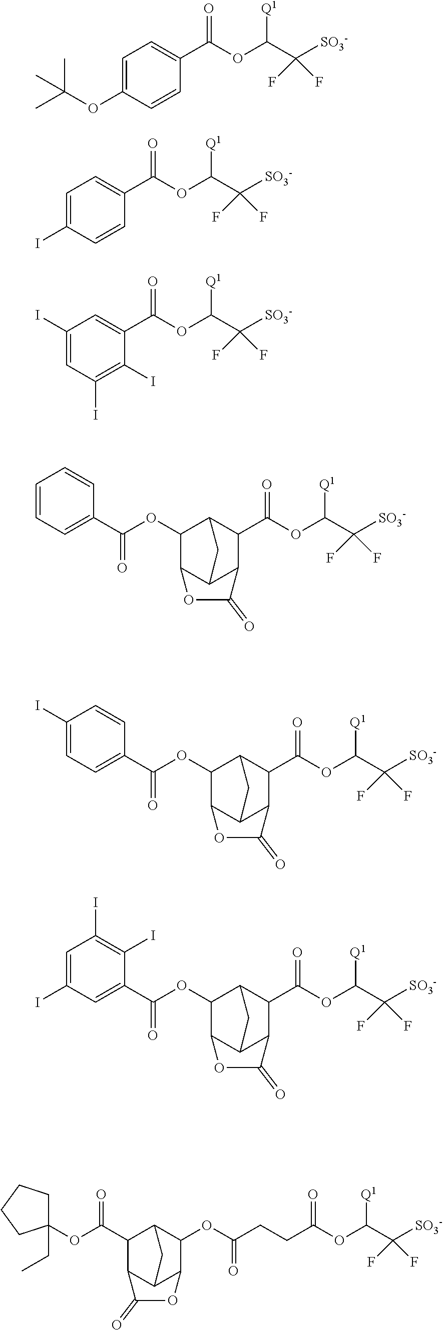

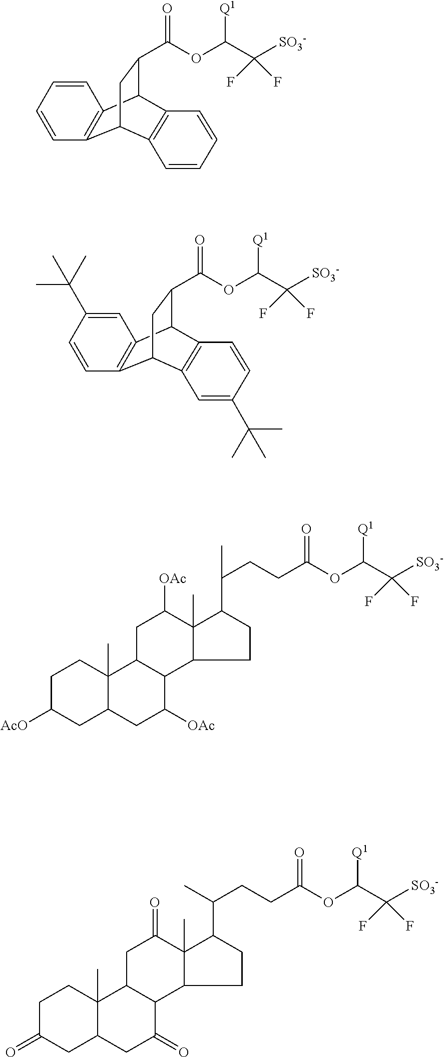

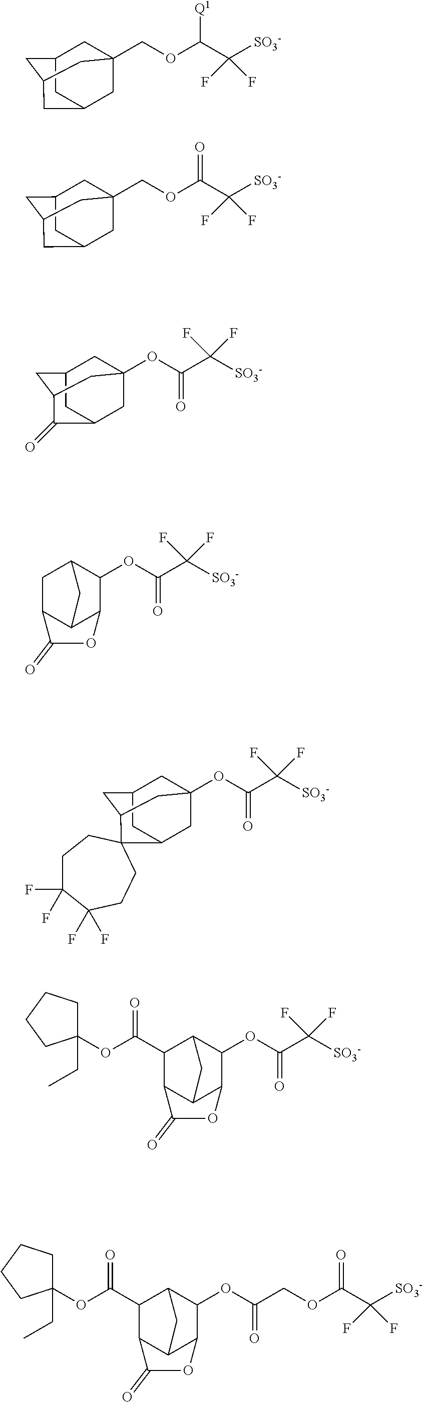

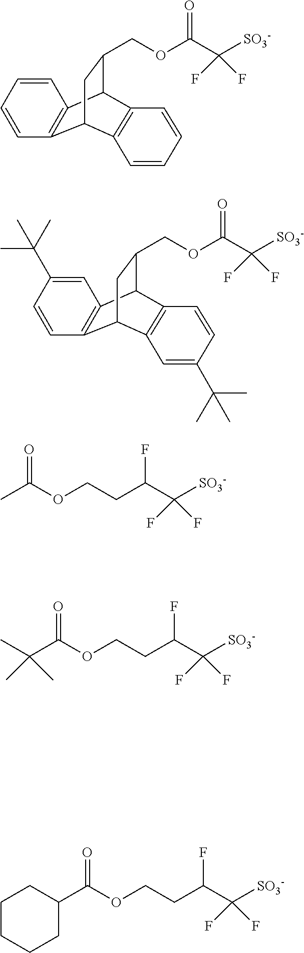

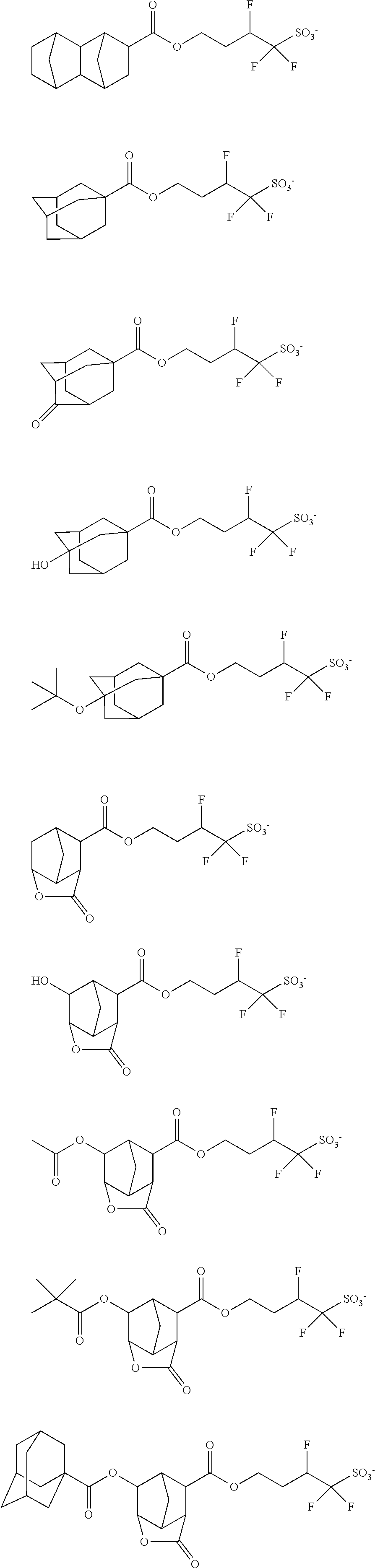

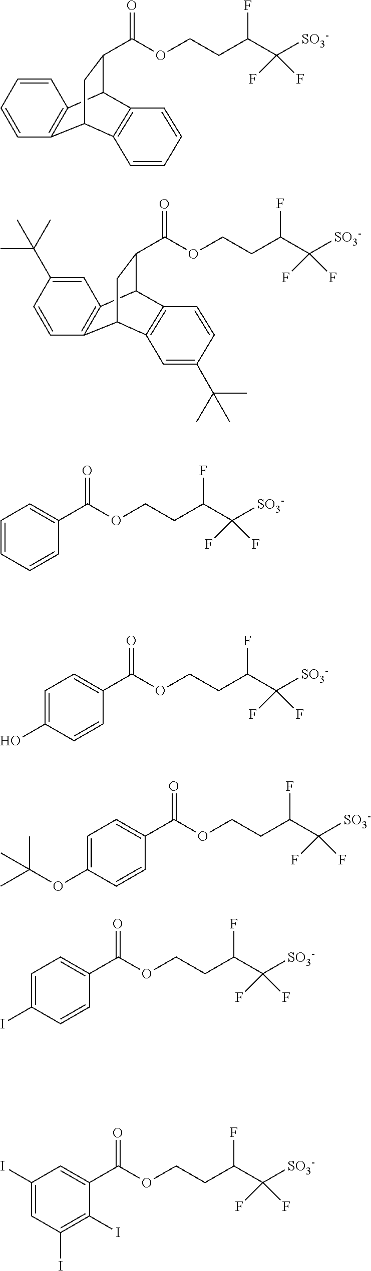

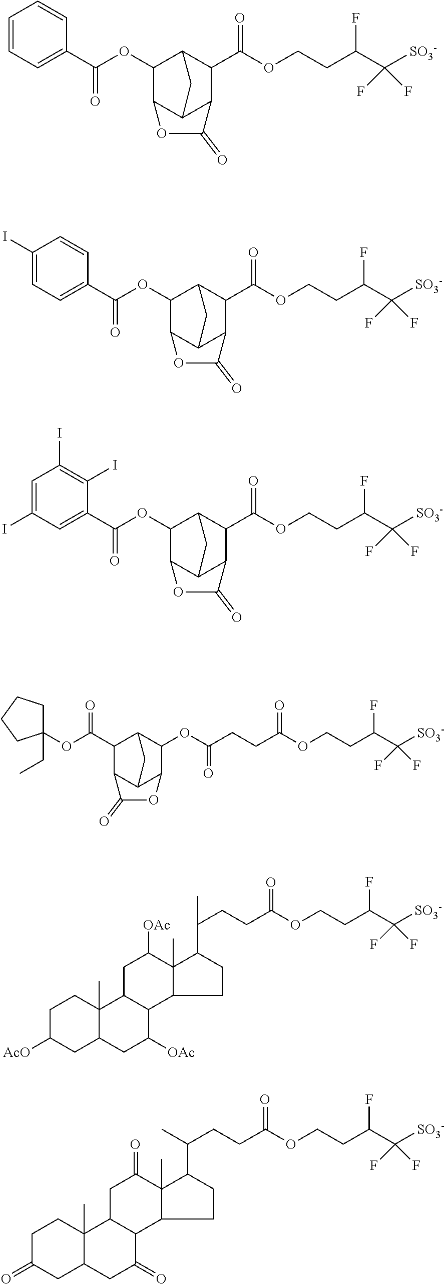

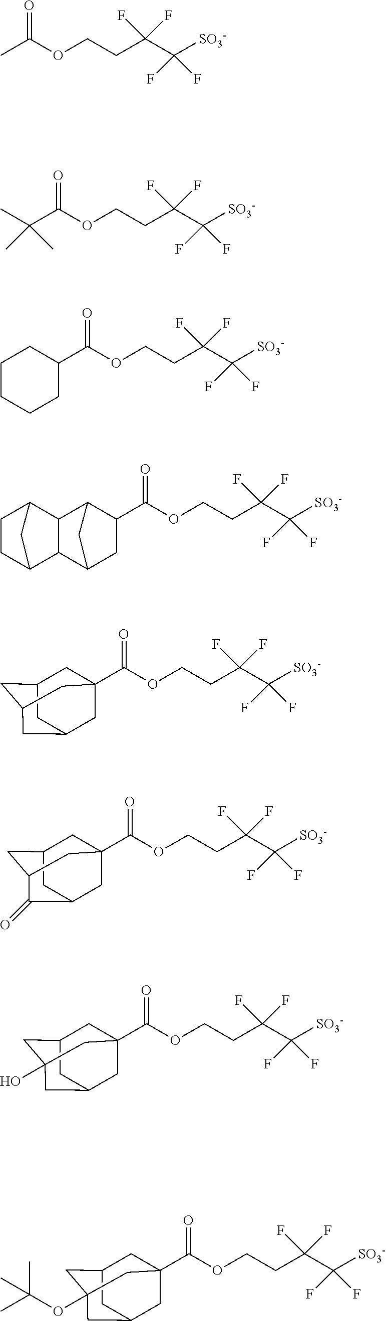

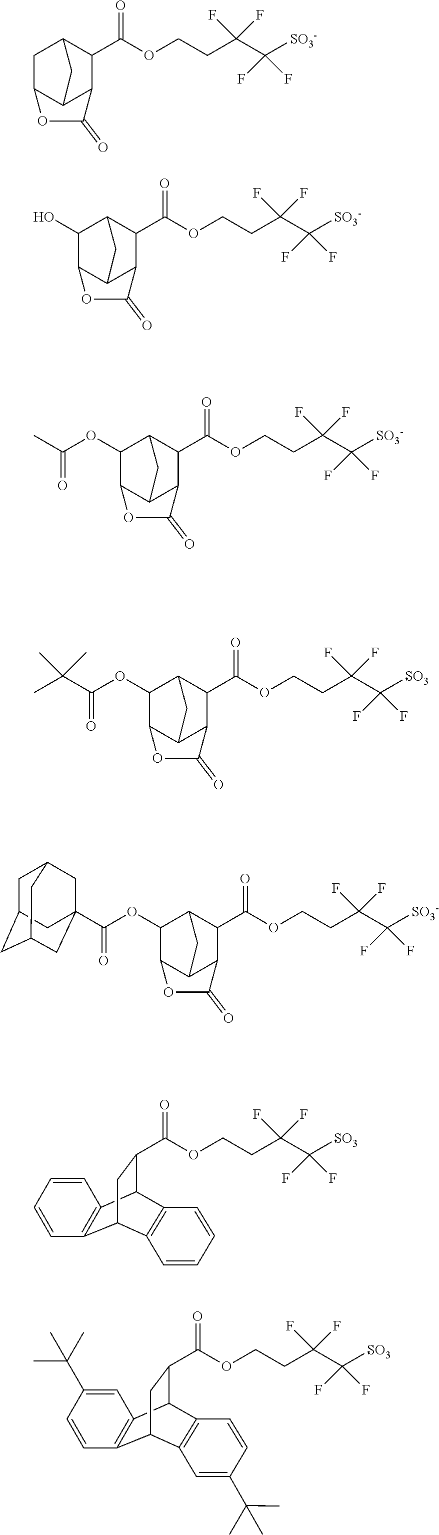

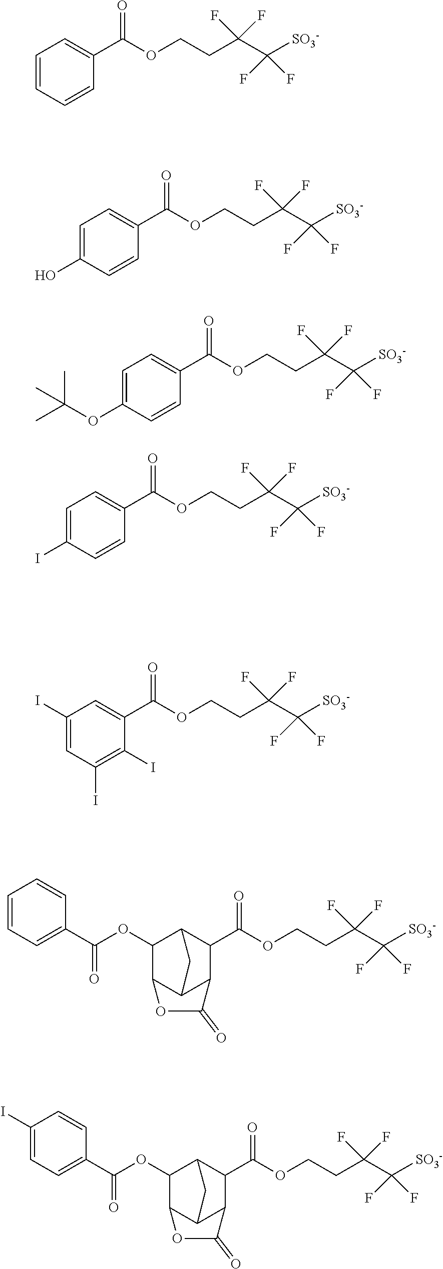

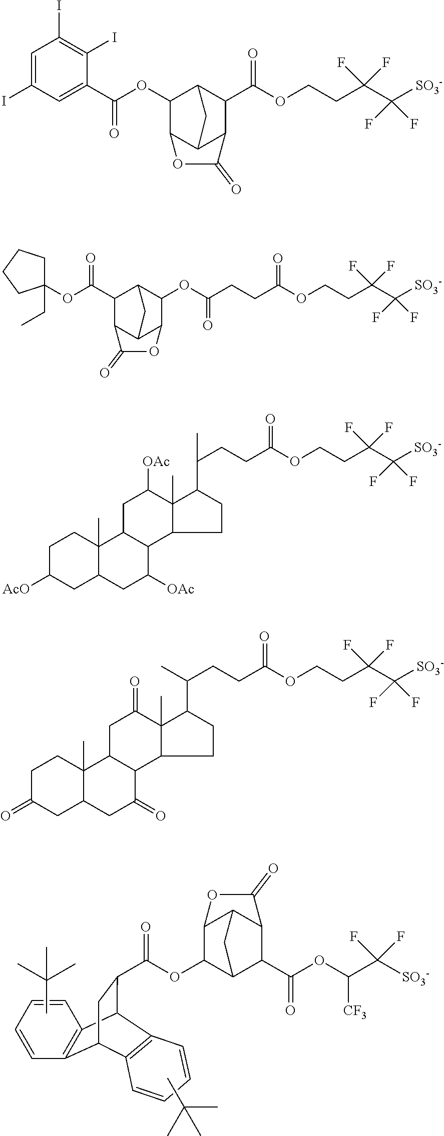

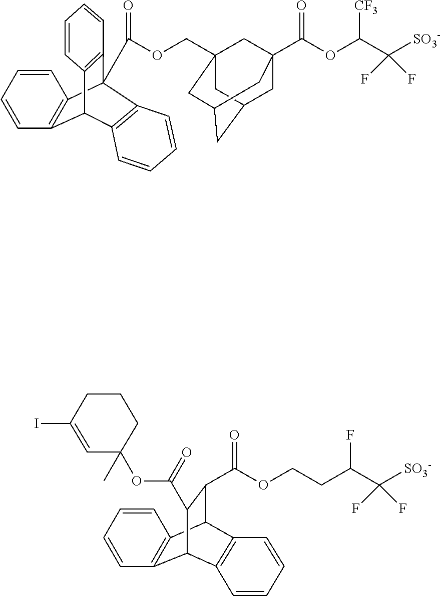

Other examples of the anion having formula (c1-1) include those described in JP-A 2025-023601, paragraphs [0042]-[0049], JP-A 2021-070692, paragraphs [0015]-[0017], JP 7091762, paragraphs [0145]-[0148], JP 7628783, paragraphs [0022]-[0023], and JP 7109178, paragraph [0224].

In formula (c1-2), R^{fb1} and R^{fb2} are each independently fluorine or a C₁-C₄₀ hydrocarbyl group which may contain a heteroatom. The hydrocarbyl group may be saturated or unsaturated and straight, branched or cyclic. Examples thereof are as exemplified above for the hydrocarbyl group R^{fa1} in formula (c1-1-1). Preferably R^{tb1} and R^{fb2} are fluorine or C₁-C₄ straight fluorinated alkyl groups. Also, R^{fb1} and R^{fb2} may bond together to form a ring with the linkage: —CF₂—SO₂—N—SO₂—CF₂— to which they are attached. It is preferred that a combination of R^{fb1} and R^{fb2} be a fluorinated ethylene or fluorinated propylene group.

In formula (c1-3), R^{fc1}, R^{fc2} and R^{fc3} are each independently fluorine or a C₁-C₄₀ hydrocarbyl group which may contain a heteroatom. The hydrocarbyl group may be saturated or unsaturated and straight, branched or cyclic. Examples thereof are as exemplified above for the hydrocarbyl group R^{fa1} in formula (c1-1-1). Preferably R^{fc1}, R^{fc2} and R^{fc3} are fluorine or C₁-C₄ straight fluorinated alkyl groups. Also, R^{fc1} and R^{fc2} may bond together to form a ring with the linkage: —CF₂—SO₂—C—SO₂—CF₂— to which they are attached. It is preferred that a combination of R^{fc1} and R^{fc2} be a fluorinated ethylene or fluorinated propylene group.

In formula (c1-4), R^{fd} is a C₁-C₄₀ hydrocarbyl group which may contain a heteroatom. The hydrocarbyl group may be saturated or unsaturated and straight, branched or cyclic. Examples thereof are as exemplified above for R^{fa1} in formula (c1-1-1). In the hydrocarbyl group, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy, fluorine, chlorine, bromine, iodine, cyano, nitro, carbonyl, ether bond, ester bond, sulfonate ester bond, carbonate bond, lactone ring, sultone ring, carboxylic anhydride (—C(═O)—O—C(═O)—) or haloalkyl moiety.

Examples of the anion having formula (c1-4) are shown below, but not limited thereto.

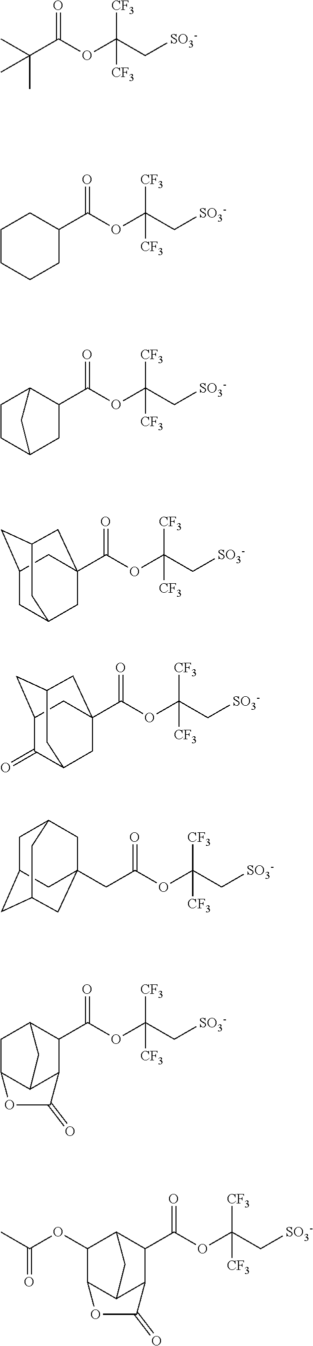

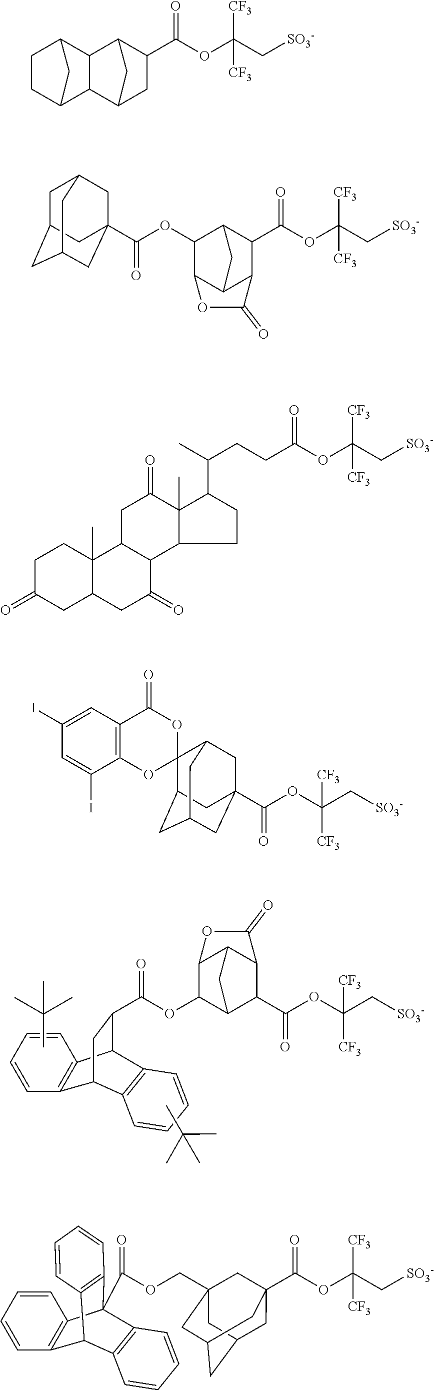

Other examples of the anion having formula (c1-4) include those described in JP-A 2025-023601, paragraphs [0050]-[0058].

Anions having an iodized or brominated aromatic ring are also useful as the non-nucleophilic counter ion. These anions have the formula (c1-5).

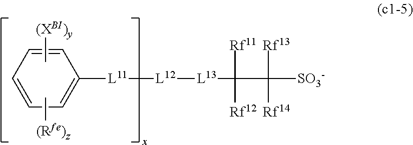

In formula (c1-5), x is 1, 2 or 3, y is 1, 2, 3, 4 or 5, z is 0, 1, 2 or 3, meeting 1≤y+z≤5. Preferably, y is 1, 2 or 3, more preferably 2 or 3, and z is 0, 1 or 2.

In formula (c1-5), X^{BI} is iodine or bromine. A plurality of X^{BI} may be identical or different when x and/or y is 2 or more.

In formula (c1-5), L¹¹ is a single bond, ether bond, ester bond, sulfonate ester bond, carbonate bond, carbamate bond, or a C₁-C₆ saturated hydrocarbylene group in which some —CH₂— may be replaced by an ether bond or ester bond. The saturated hydrocarbylene group may be straight, branched or cyclic.

In formula (c1-5), L¹² is a single bond or a C₁-C₂₀ divalent hydrocarbylene group which may contain a heteroatom when x=1, or a C₁-C₂₀ (x+1)-valent hydrocarbon group which may contain a heteroatom when x=2 or 3.

The C₁-C₂₀ hydrocarbylene group L¹² may be saturated or unsaturated and straight, branched or cyclic. Examples thereof include C₁-C₂₀ alkanediyl groups such as methanediyl, ethane-1,1-diyl, ethane-1,2-diyl, propane-1,3-diyl, butane-1,4-diyl, pentane-1,5-diyl, hexane-1,6-diyl, heptane-1,7-diyl, octane-1,8-diyl, nonane-1,9-diyl, decane-1,10-diyl, undecane-1,11-diyl, and dodecane-1,12-diyl; C₃-C₂₀ cyclic saturated hydrocarbylene groups such as cyclopentanediyl, cyclohexanediyl, norbornanediyl, adamantanediyl and tricyclo[5.2.1.0^{2,6}]decanediyl; C₂-C₂₀ unsaturated aliphatic hydrocarbylene groups such as vinylene and propene-1,3-diyl; and C₆-C₂₀ arylene groups such as phenylene, naphthylene, and anthracenediyl; C₇-C₂₀ aromatic ring-containing polycyclic hydrocarbylene groups such as 9,10-ethano-9,10-dihydroanthracenediyl and 6,13-ethano-6,13-dihydropentacene, and combinations thereof. The C₁-C₂₀ (x+1)-valent hydrocarbon group L¹² may be saturated or unsaturated and straight, branched or cyclic. Examples thereof include the aforementioned examples of the C₁-C₂₀ hydrocarbylene group from which one or two hydrogen atoms are eliminated.

In the hydrocarbylene and (x+1)-valent hydrocarbon groups, some or all of the hydrogen atoms may be substituted by a moiety containing a heteroatom such as oxygen, sulfur, nitrogen or halogen, and some —CH₂— may be replaced by a moiety containing a heteroatom such as oxygen, sulfur or nitrogen, so that the group may contain a hydroxy, cyano, fluorine, chlorine, bromine, iodine, carbonyl, ether bond, ester bond, sulfonate ester bond, carbonate bond, lactone ring, sultone ring, carboxylic anhydride (—C(═O)—O—C(═O)—) or haloalkyl moiety.

In formula (c1-5), L¹³ is a single bond, ether bond, ester bond, sulfonate ester bond, carbonate bond or carbamate bond.

In formula (c1-5), R^{fe} is hydroxy, carboxy, fluorine, chlorine, bromine, amino group, or a C₁-C₂₀ hydrocarbyl, C₁-C₂₀ hydrocarbyloxy, C₁-C₂₀ hydrocarbylthio, C₂-C₂₀ hydrocarbylcarbonyl, C₂-C₂₀ hydrocarbyloxycarbonyl, C₂-C₂₀ hydrocarbylcarbonyloxy, or C₁-C₂₀ hydrocarbylsulfonyloxy group, which may contain fluorine, chlorine, bromine, iodine, hydroxy, amino or ether bond, or —N(R^{feA})(R^{feB}), —N(R^{feC})—C(═O)—R^{feD} or —N(R^{feC})—C(═O)—O—R^{feD}. R^{feA} and R^{feB} are each independently hydrogen or a C₁-C₆ saturated hydrocarbyl group. R^{feC} is hydrogen, or a C₁-C₆ saturated hydrocarbyl group which may contain halogen, hydroxy, C₁-C₆ saturated hydrocarbyloxy, C₂-C₆ saturated hydrocarbylcarbonyl or C₂-C₆ saturated hydrocarbylcarbonyloxy moiety. R^{feD} is a aliphatic hydrocarbyl group, C₆-C₁₂ aryl group or C₇-C₁₅ aralkyl group, which may contain halogen, hydroxy, C₁-C₆ saturated hydrocarbyloxy, C₂-C₆ saturated hydrocarbylcarbonyl or C₂-C₆ saturated hydrocarbylcarbonyloxy moiety. The aliphatic hydrocarbyl group may be saturated or unsaturated and straight, branched or cyclic. The hydrocarbyl, hydrocarbyloxy, hydrocarbylcarbonyl, hydrocarbyloxycarbonyl, hydrocarbylcarbonyloxy, and hydrocarbylsulfonyloxy groups may be straight, branched or cyclic. A plurality of R^{fe} may be identical or different when x and/or z is 2 or more.

Of these, R^{fe} is preferably hydroxy, —N(R^{feC})—C(═O)—R^{feD}, —N(R^{feC})—C(═O)—O—R^{feD} fluorine, chlorine, bromine, methyl or methoxy.

In formula (c1-5), Rf¹¹ to Rf¹⁴ are each independently hydrogen, fluorine or trifluoromethyl, at least one of Rf¹¹ to Rf¹⁴ is fluorine or trifluoromethyl. Rf¹¹ and Rf¹², taken together, may form a carbonyl group. More preferably, both Rf¹³ and Rf¹⁴ are fluorine.

Examples of the anion having formula (c1-5) are shown below, but not limited thereto. X^{BI} is as defined above.

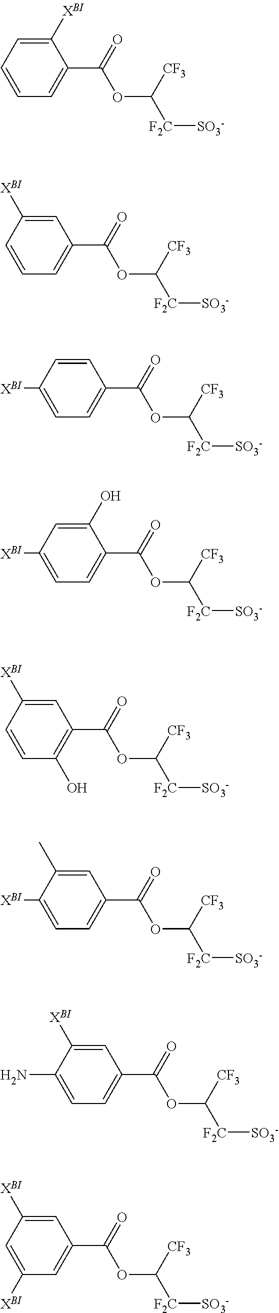

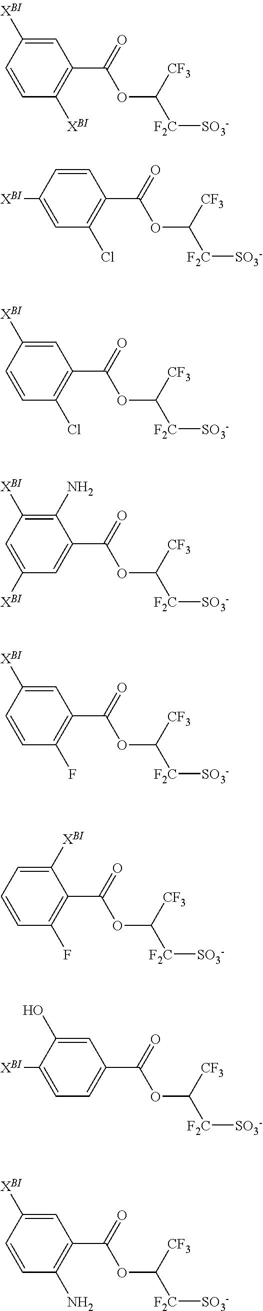

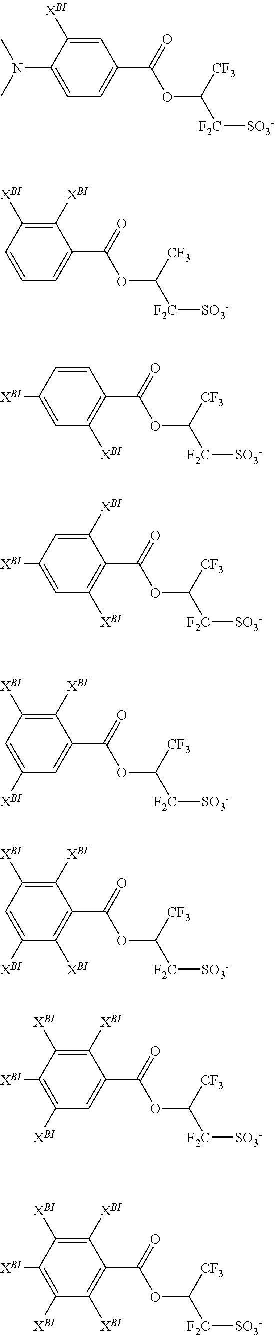

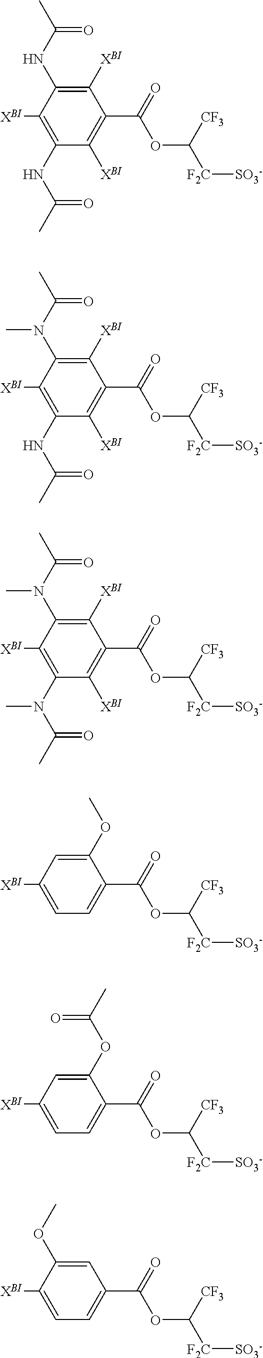

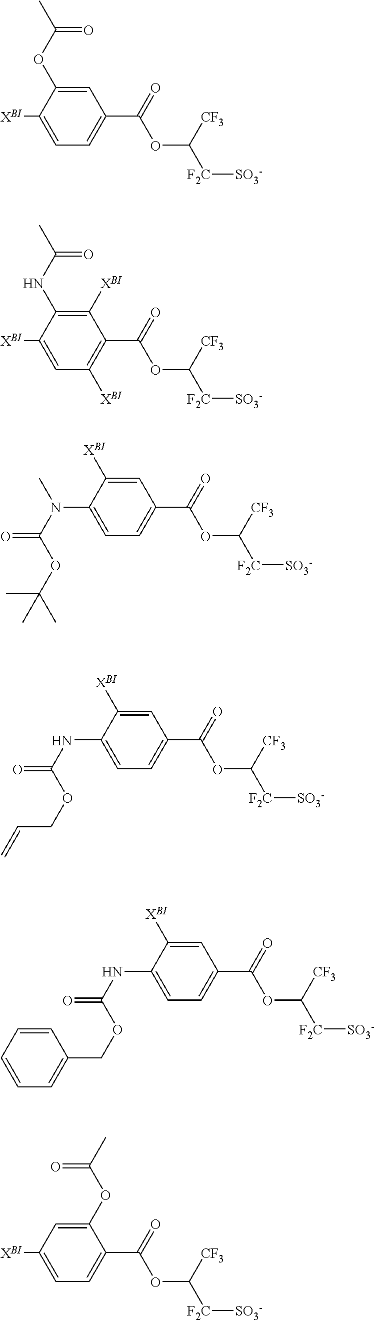

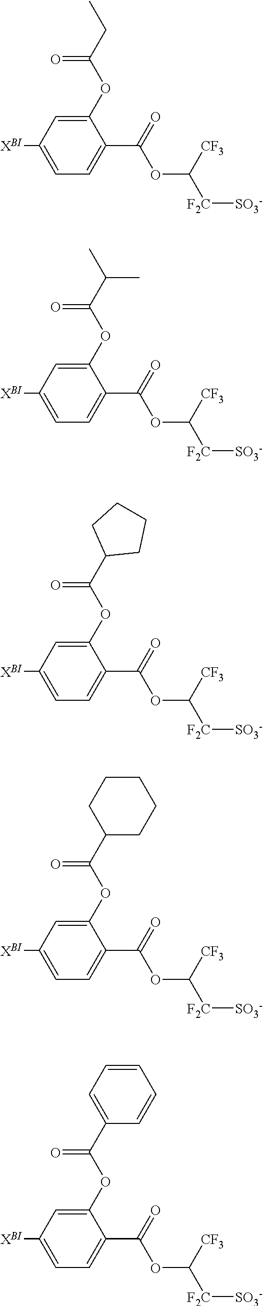

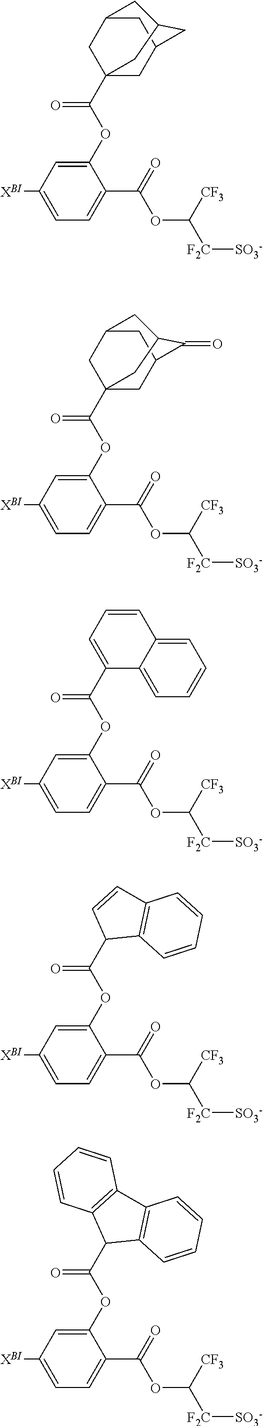

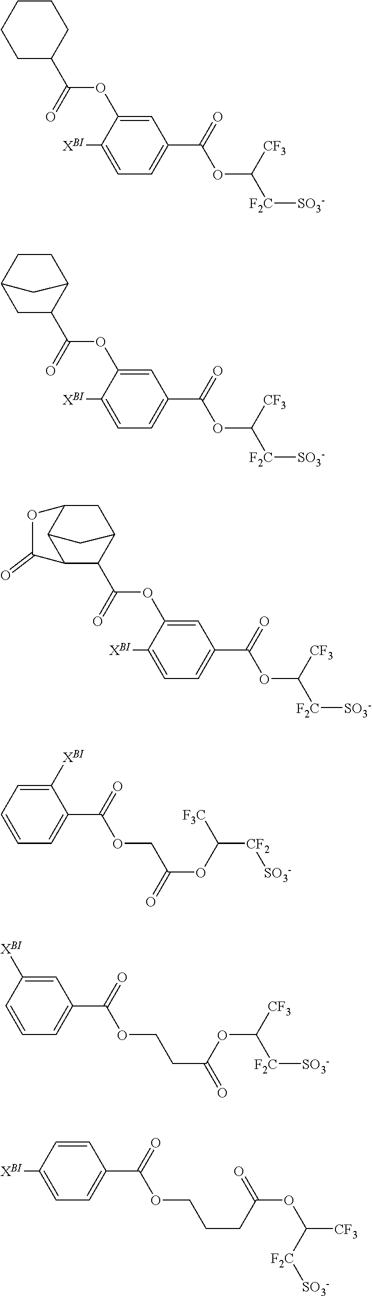

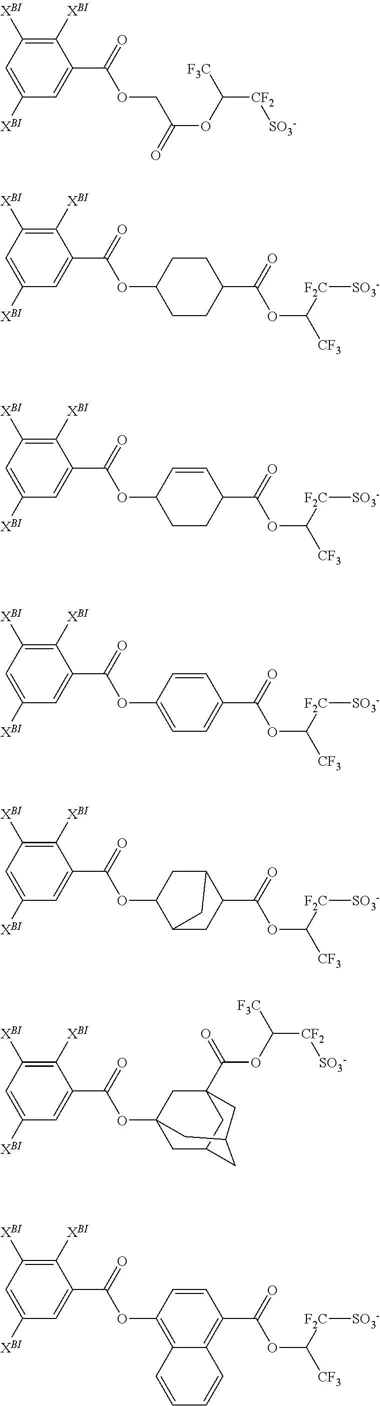

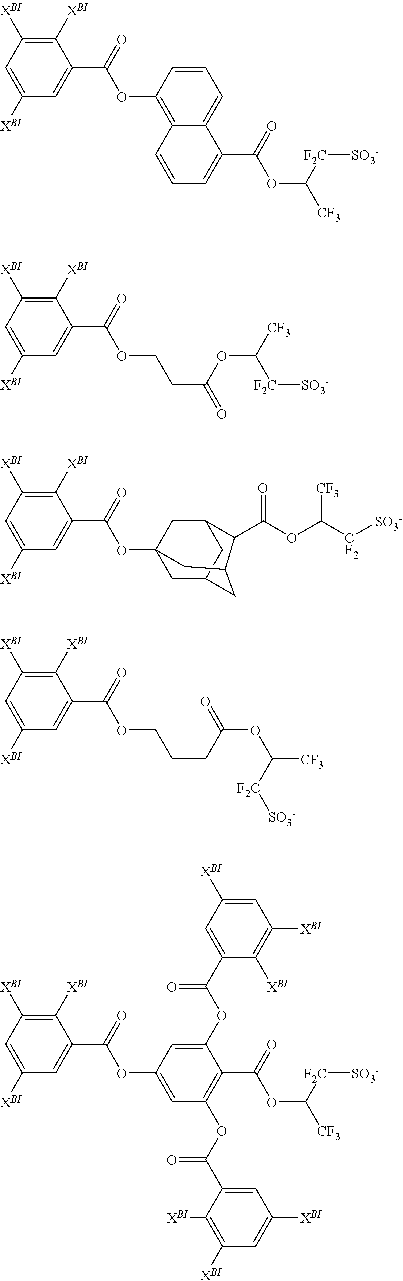

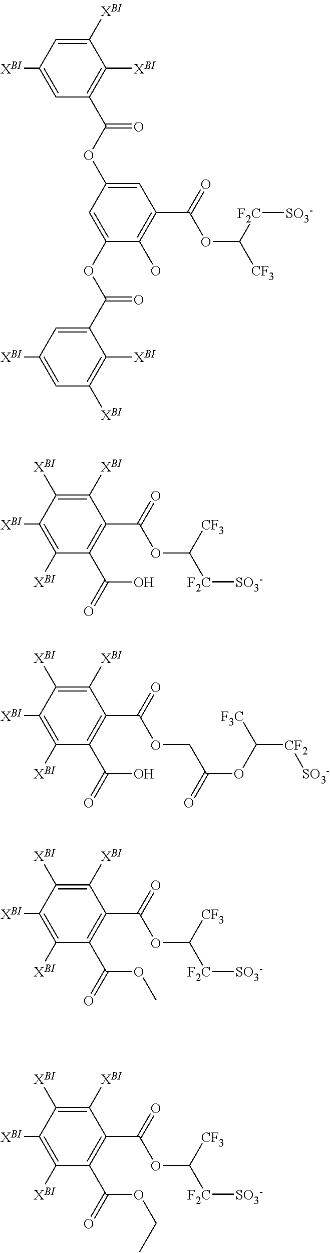

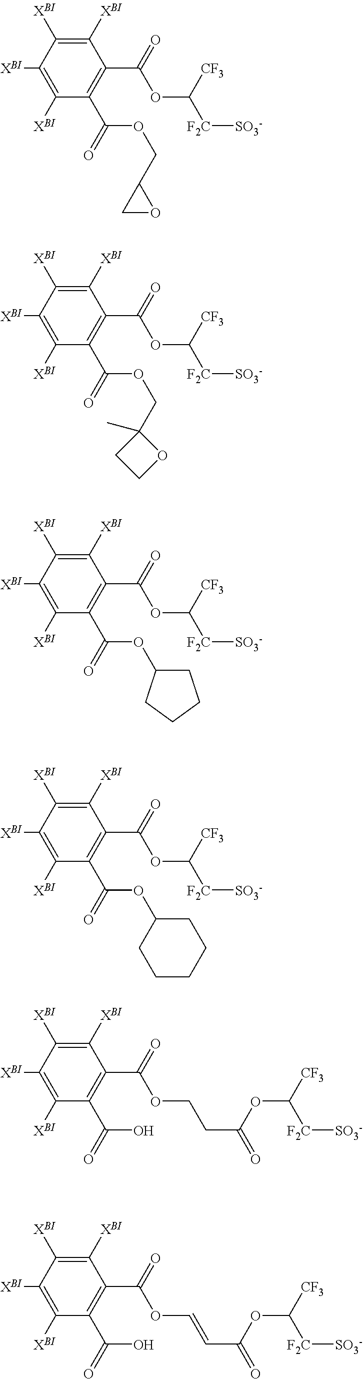

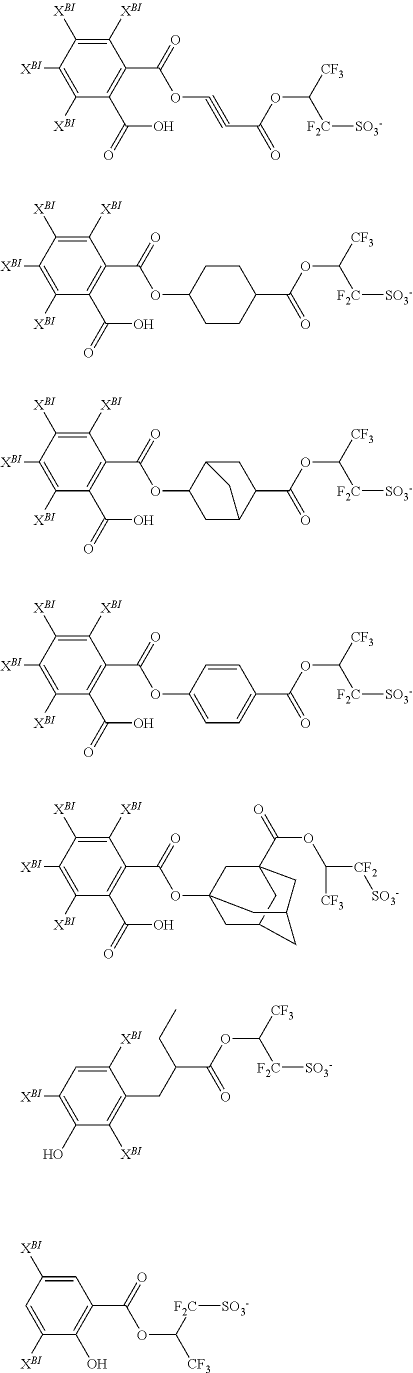

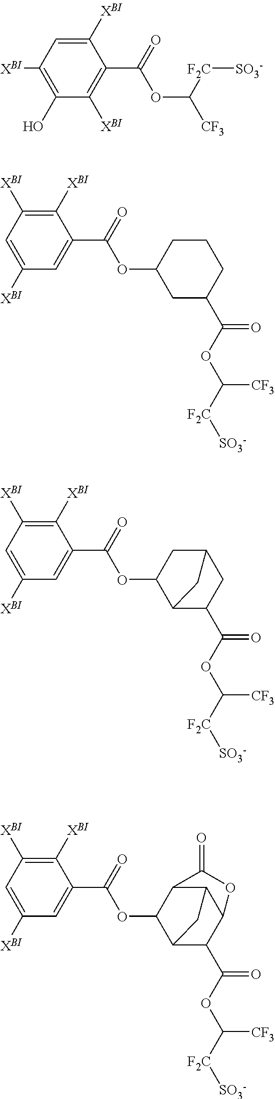

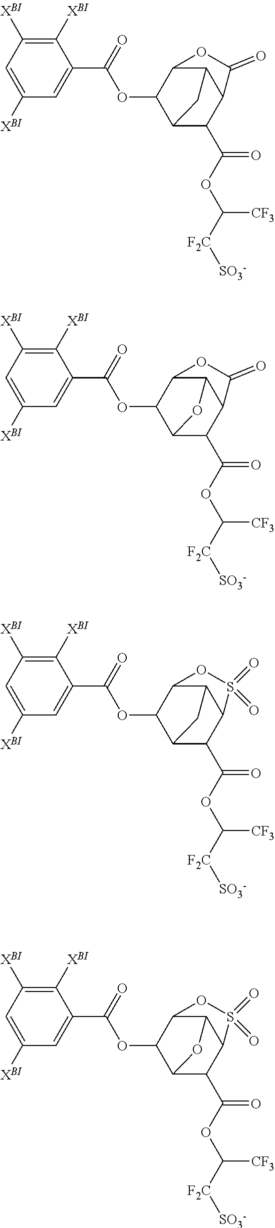

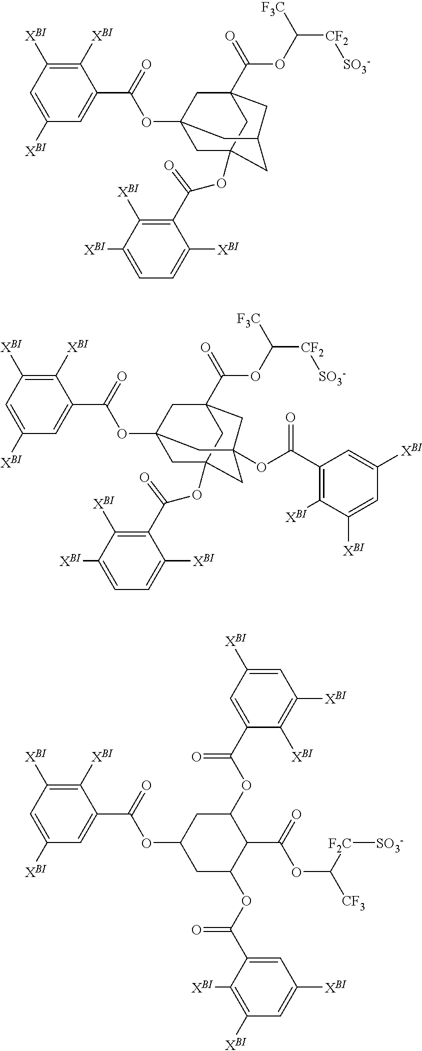

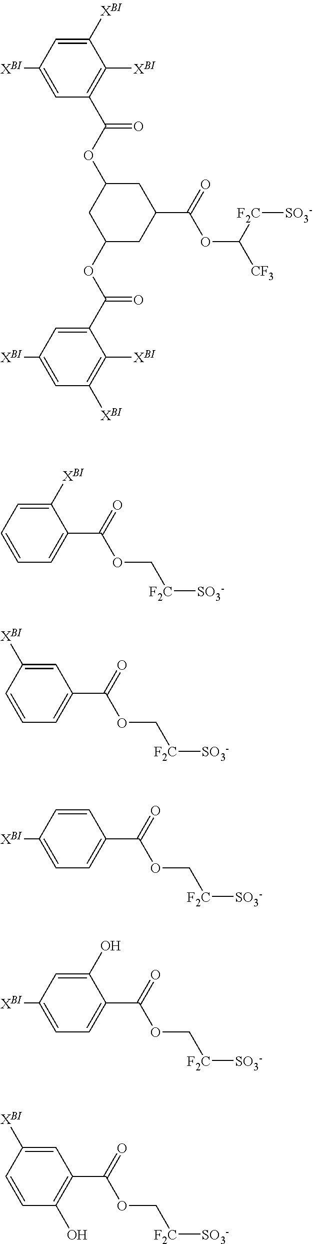

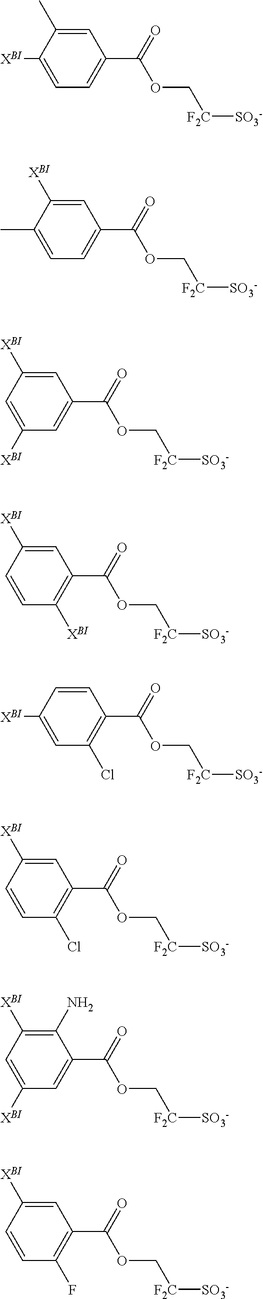

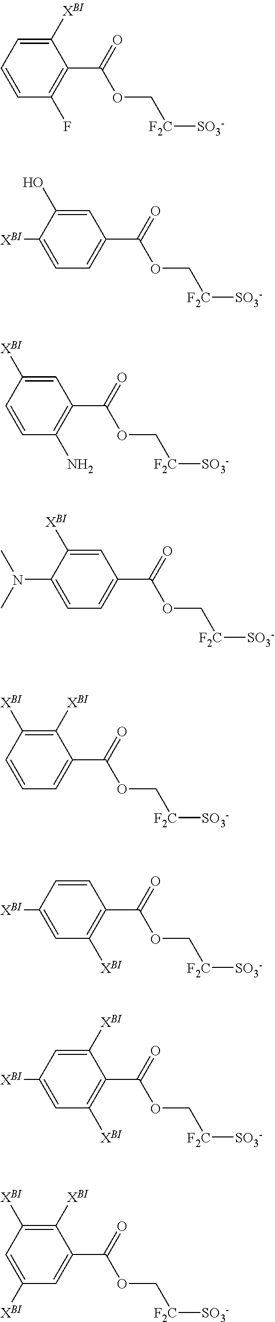

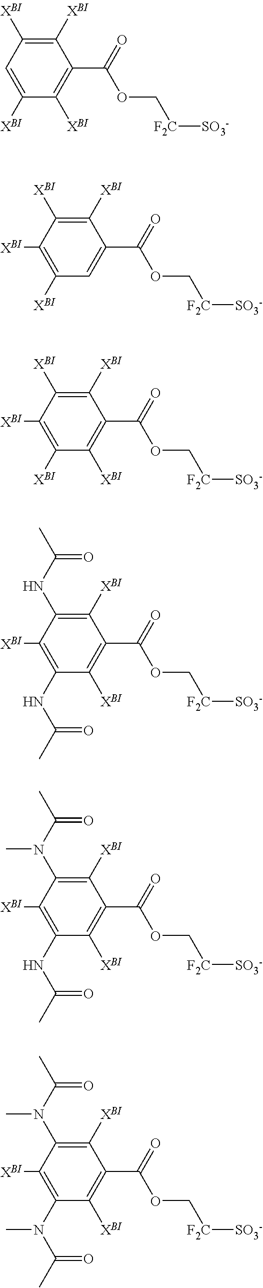

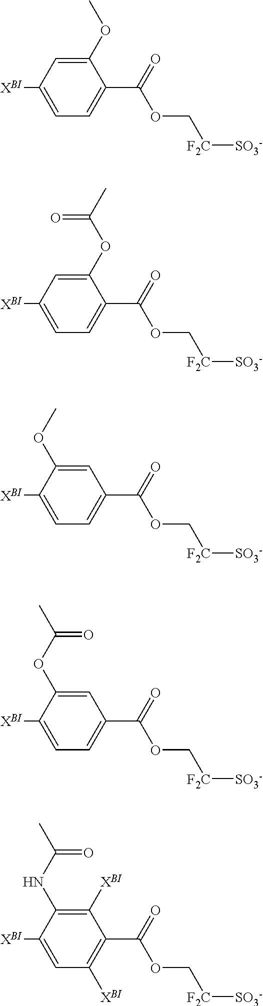

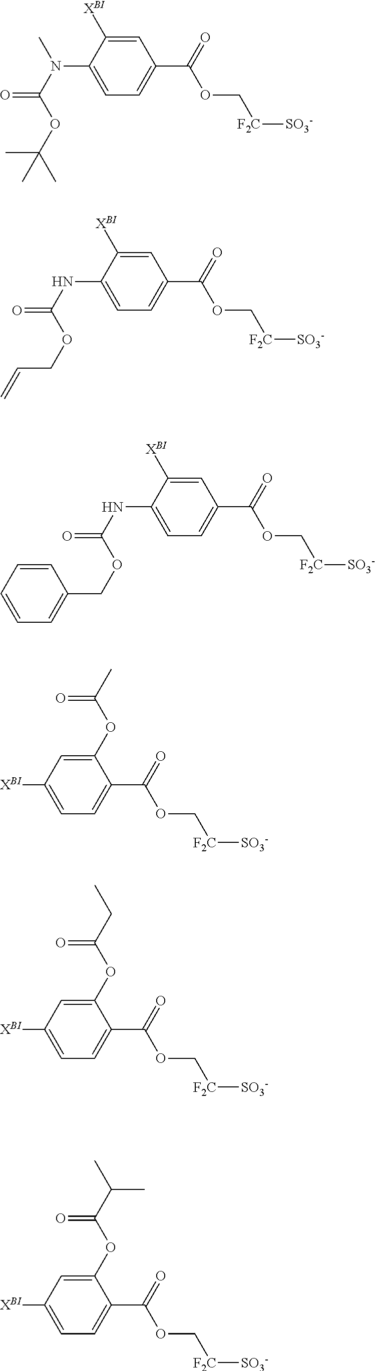

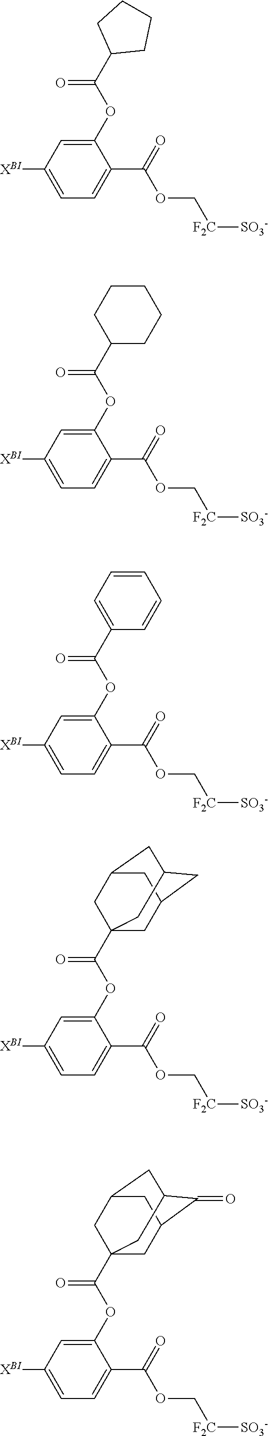

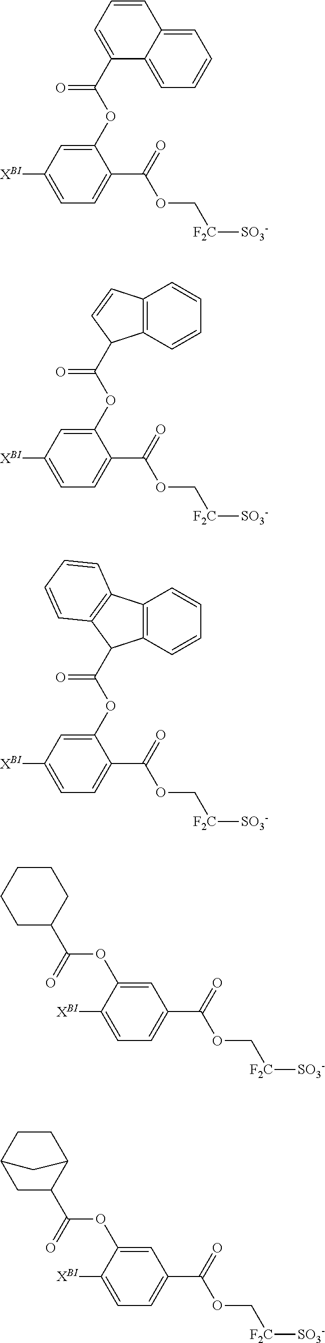

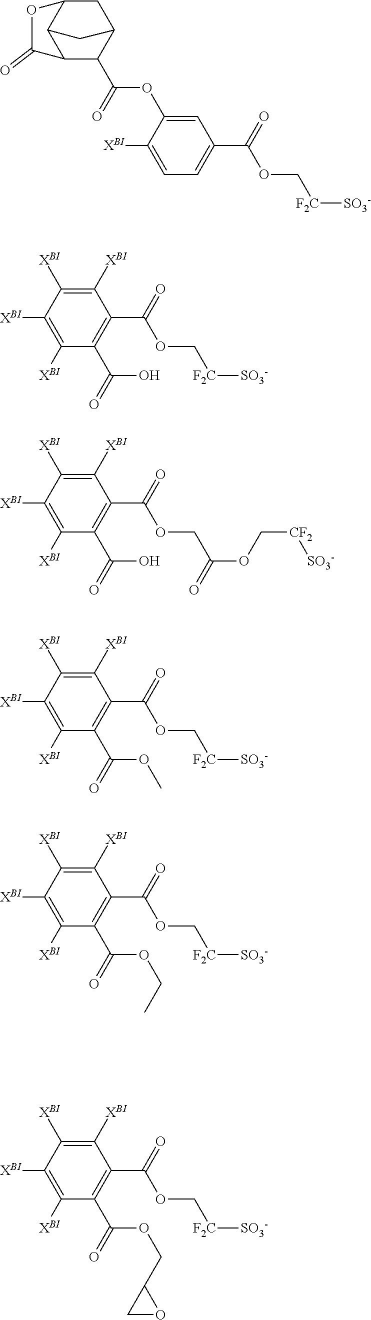

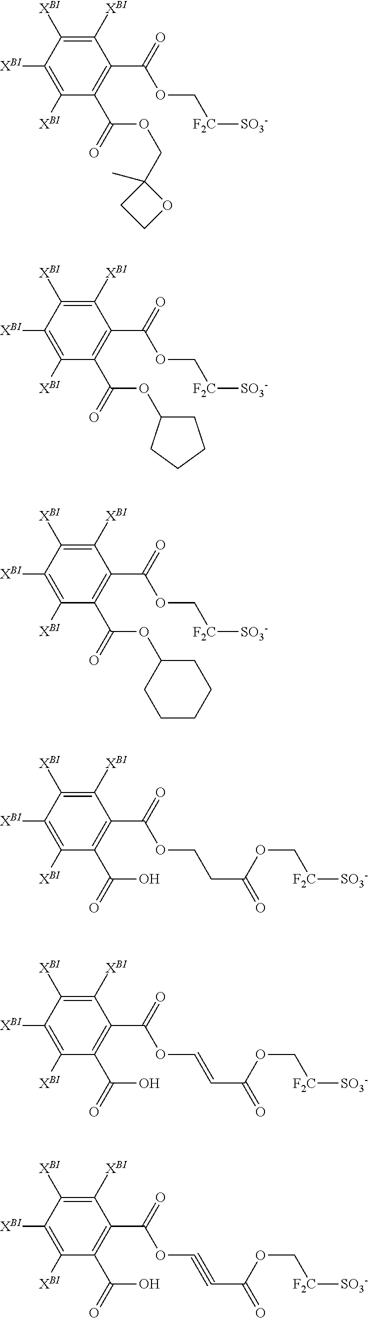

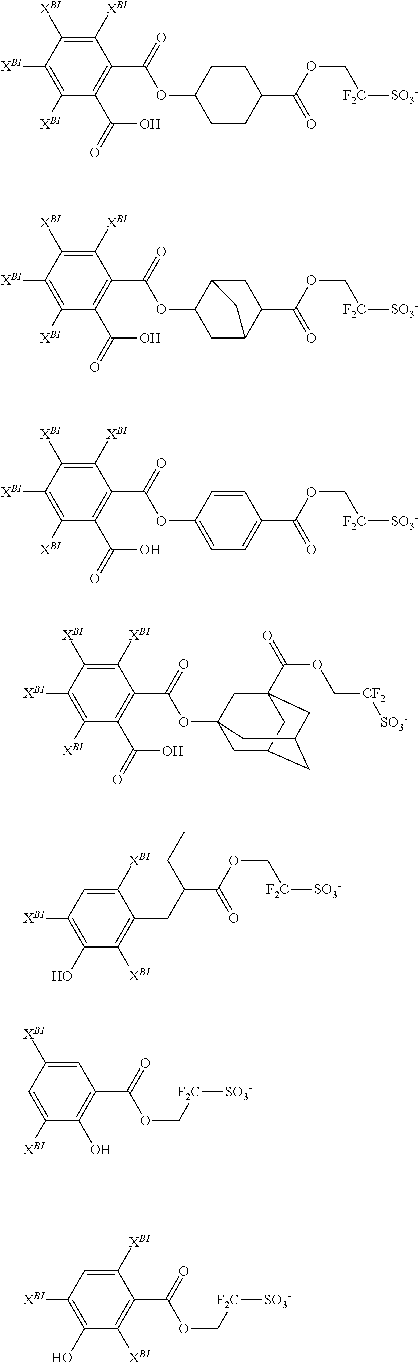

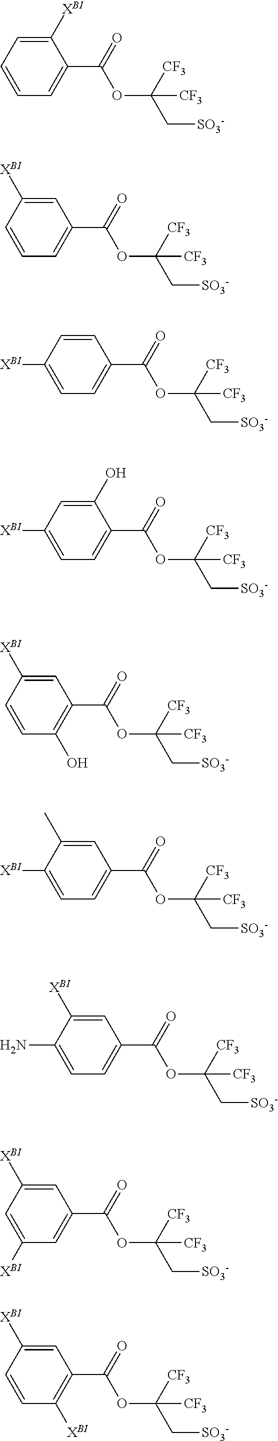

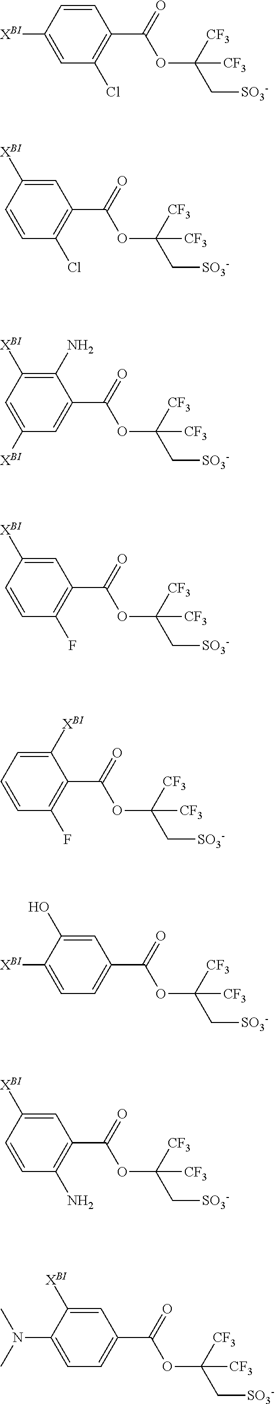

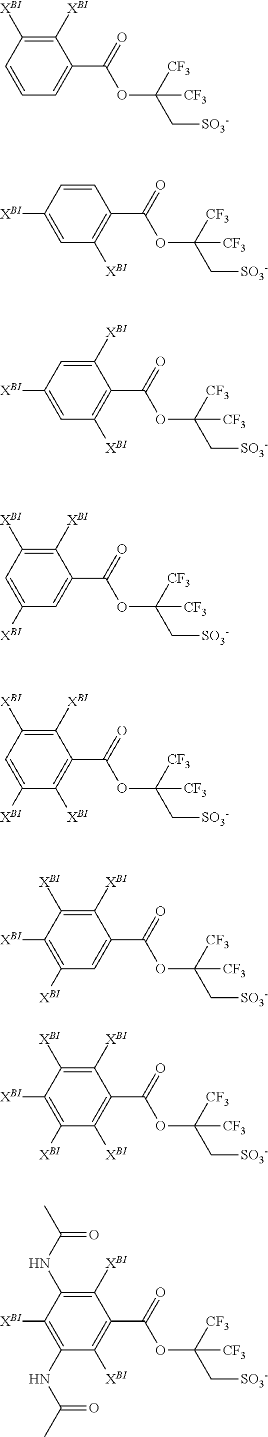

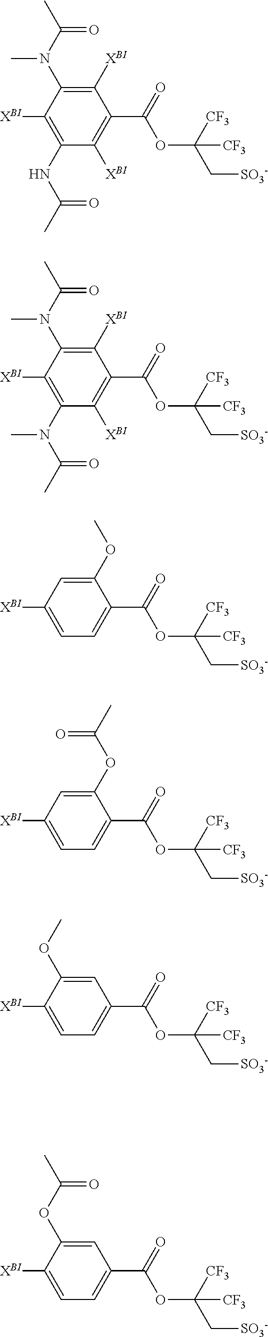

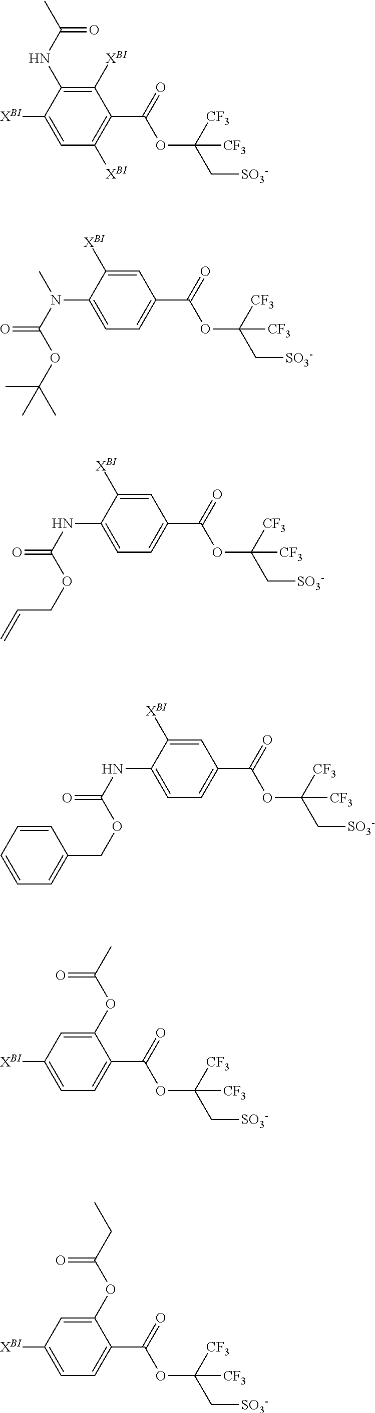

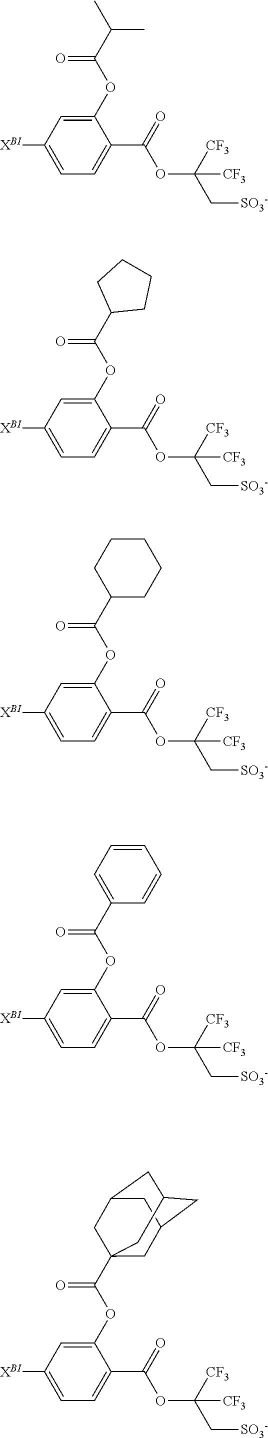

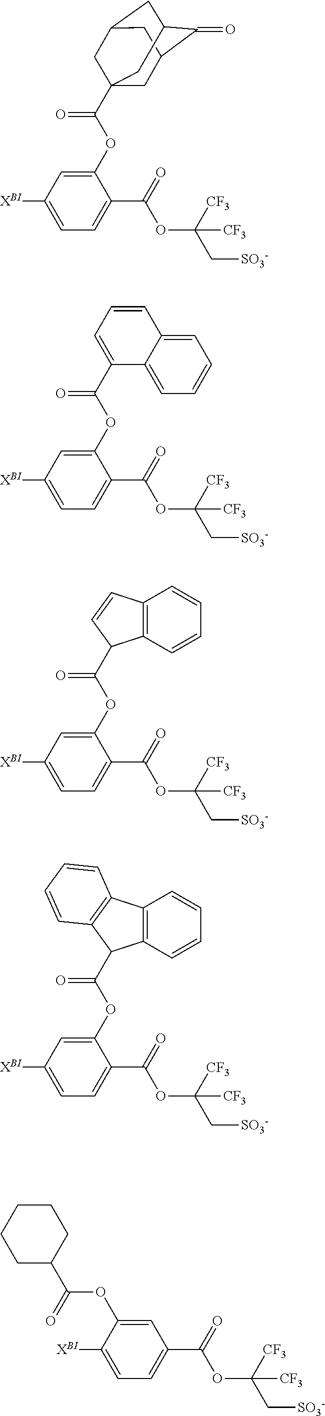

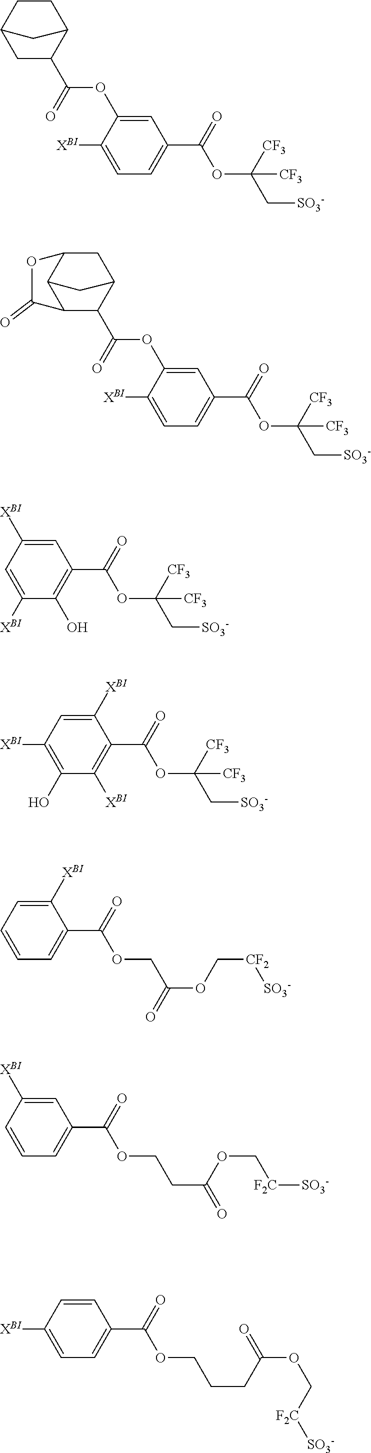

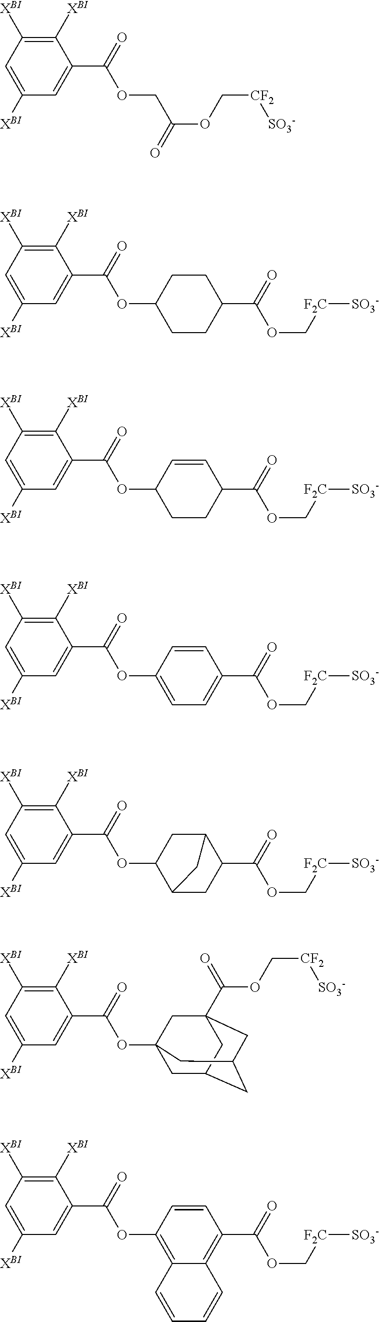

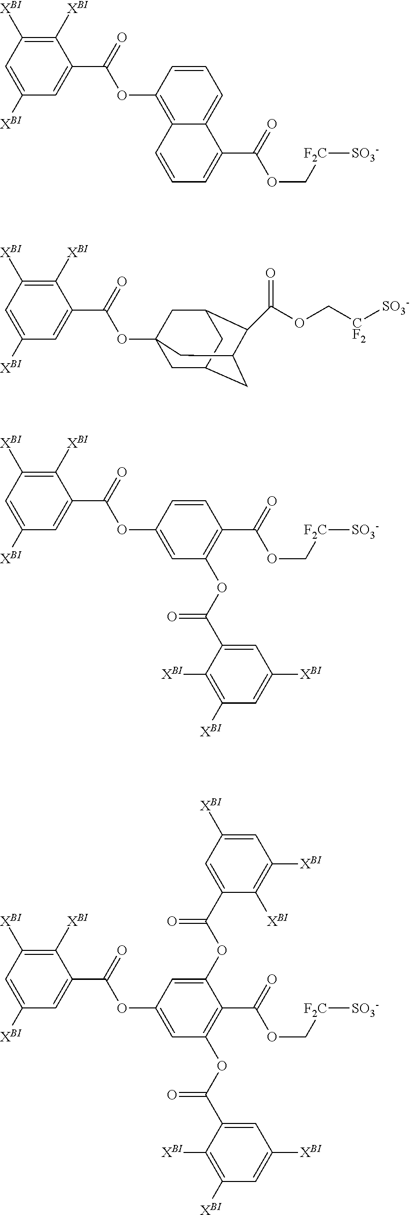

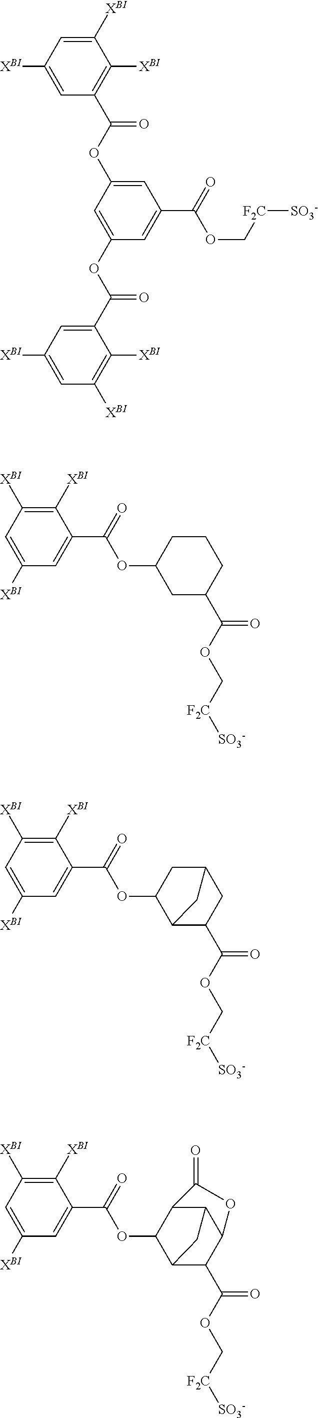

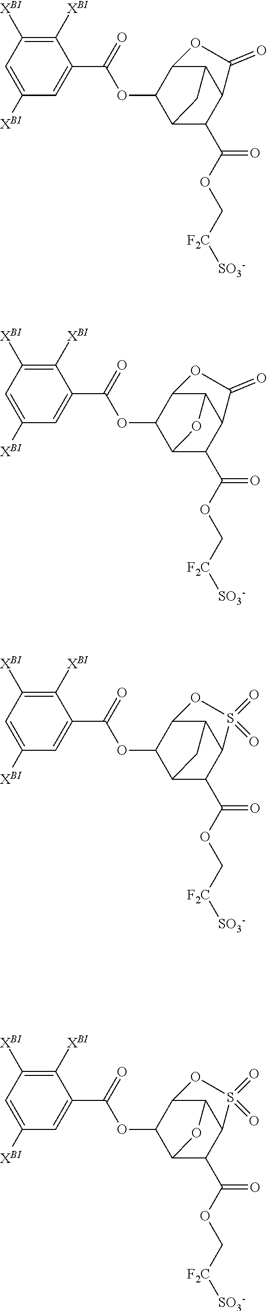

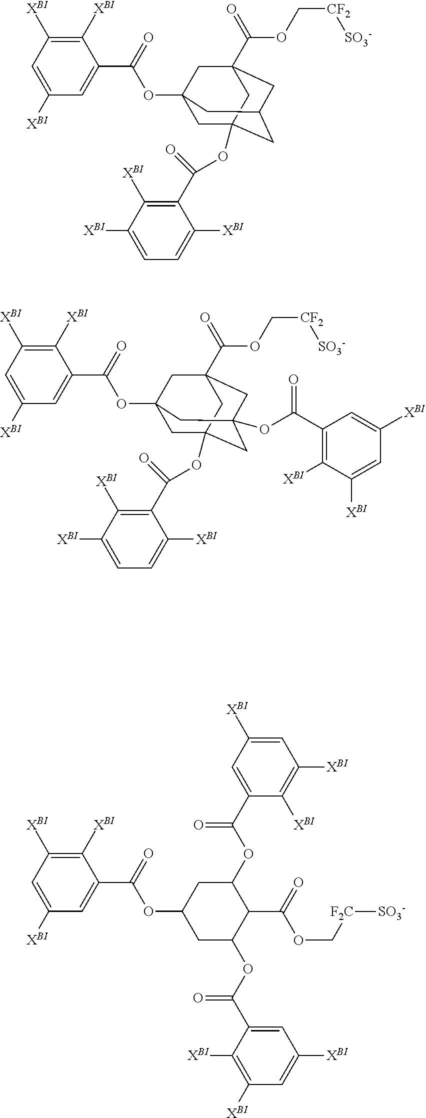

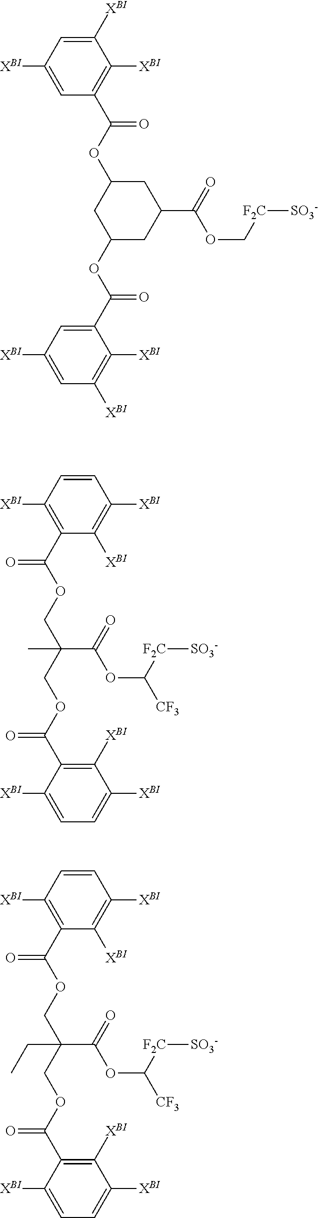

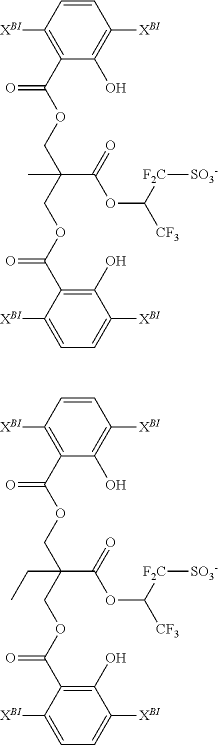

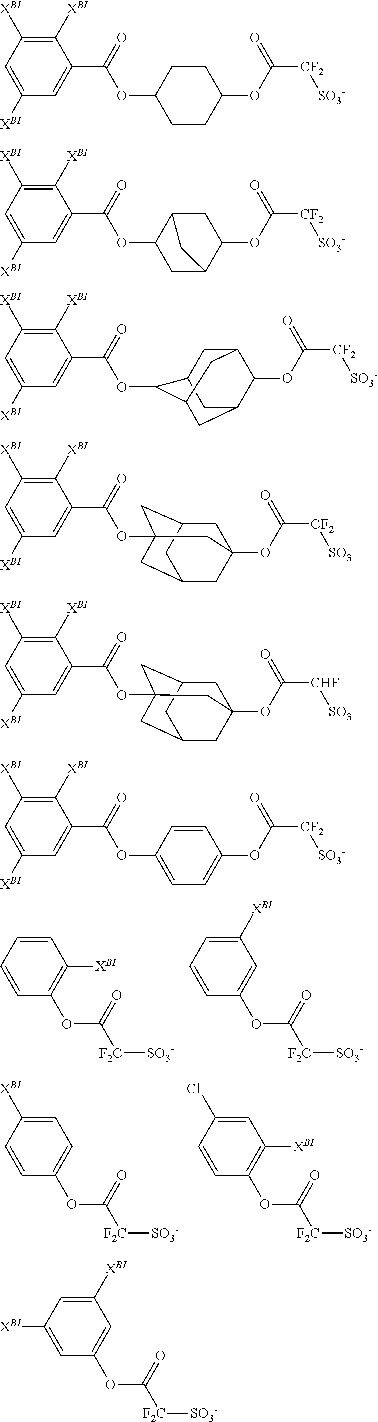

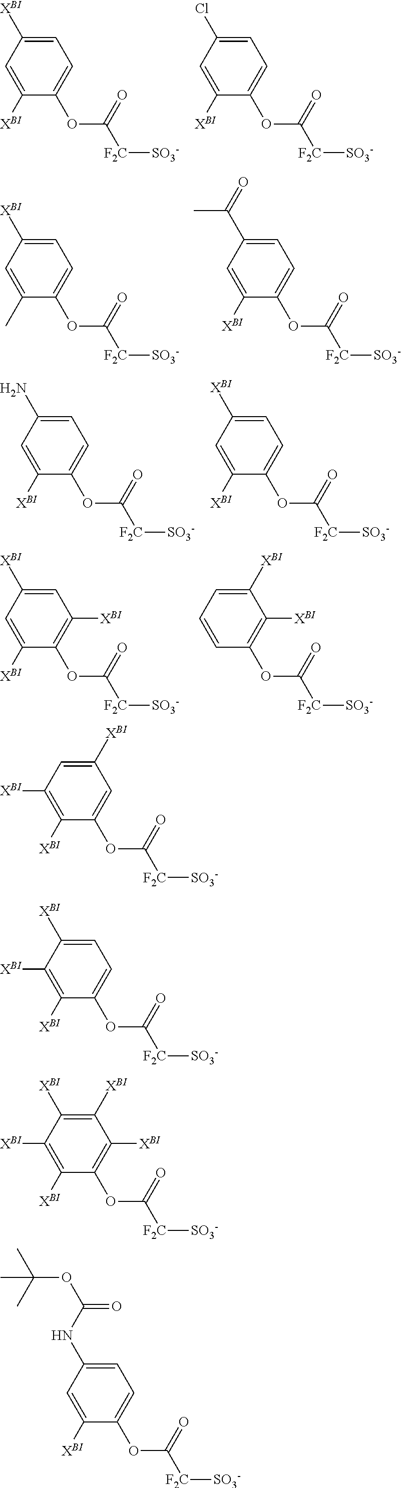

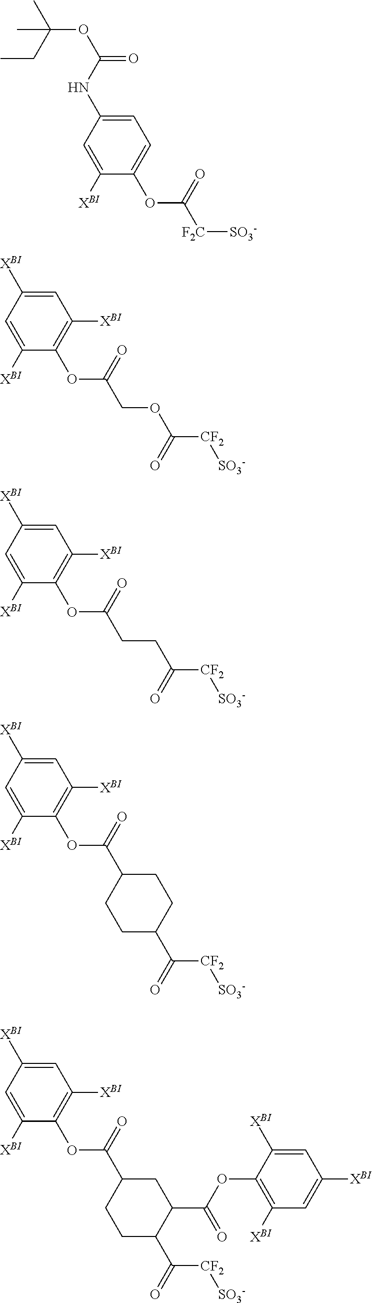

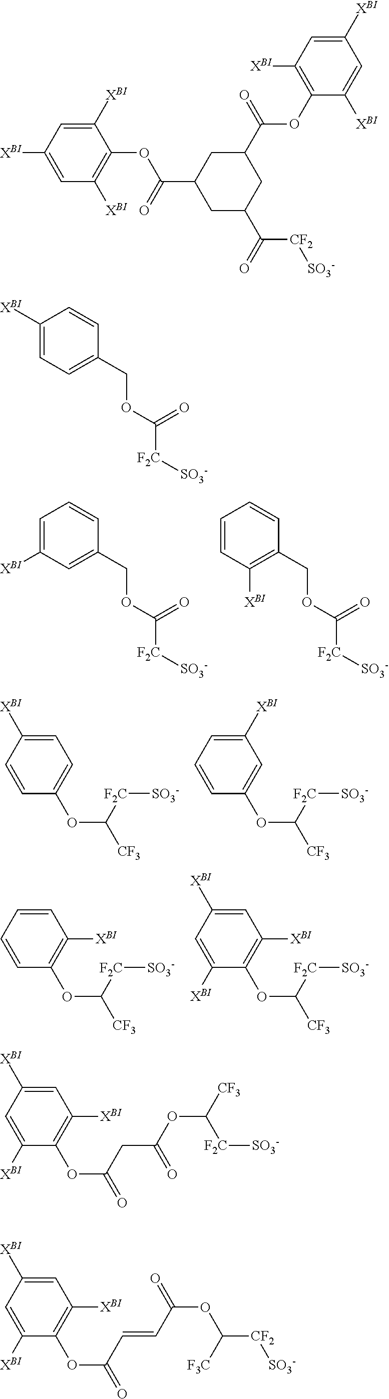

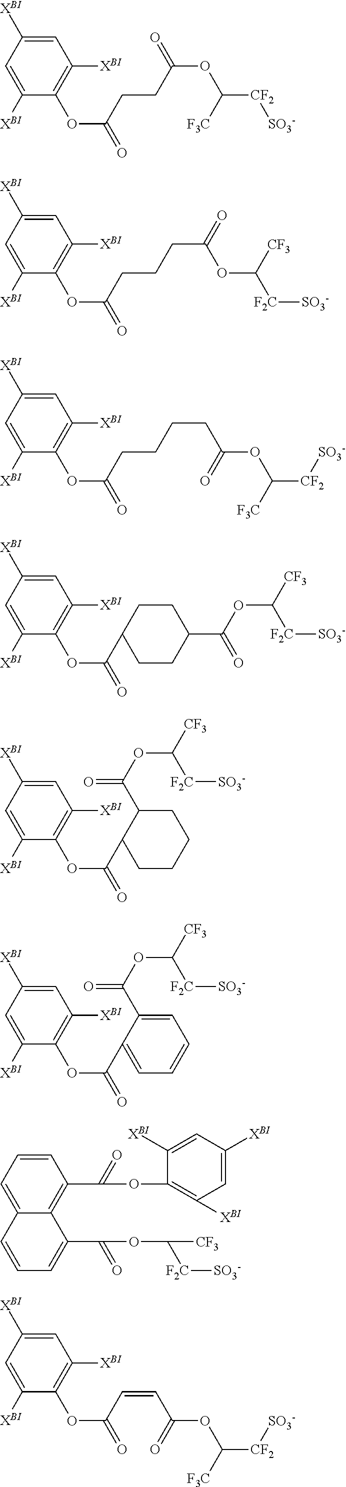

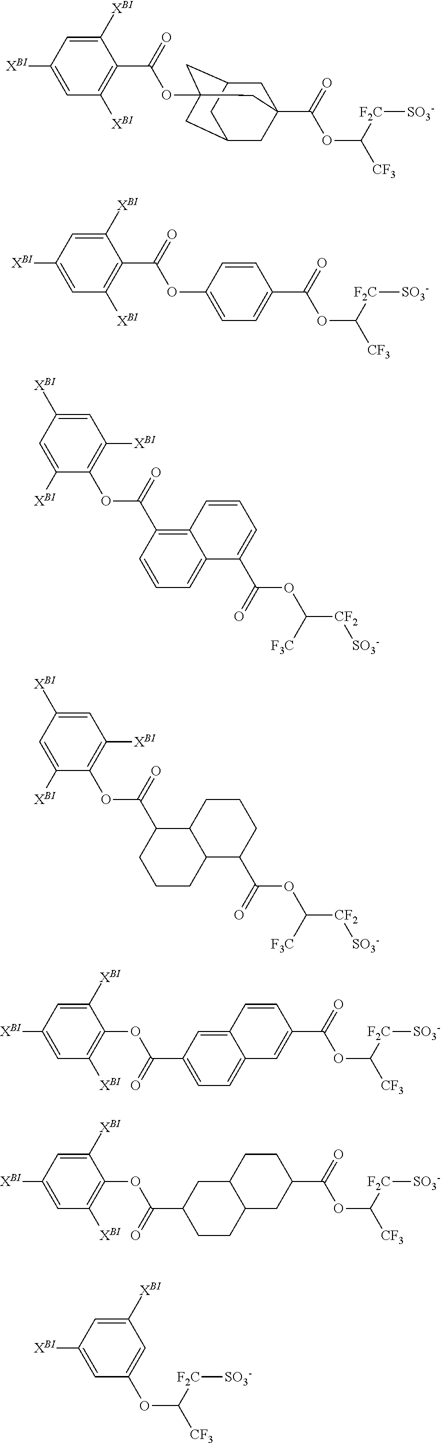

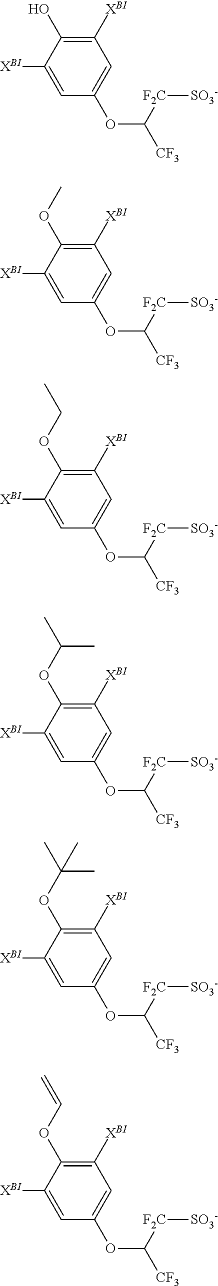

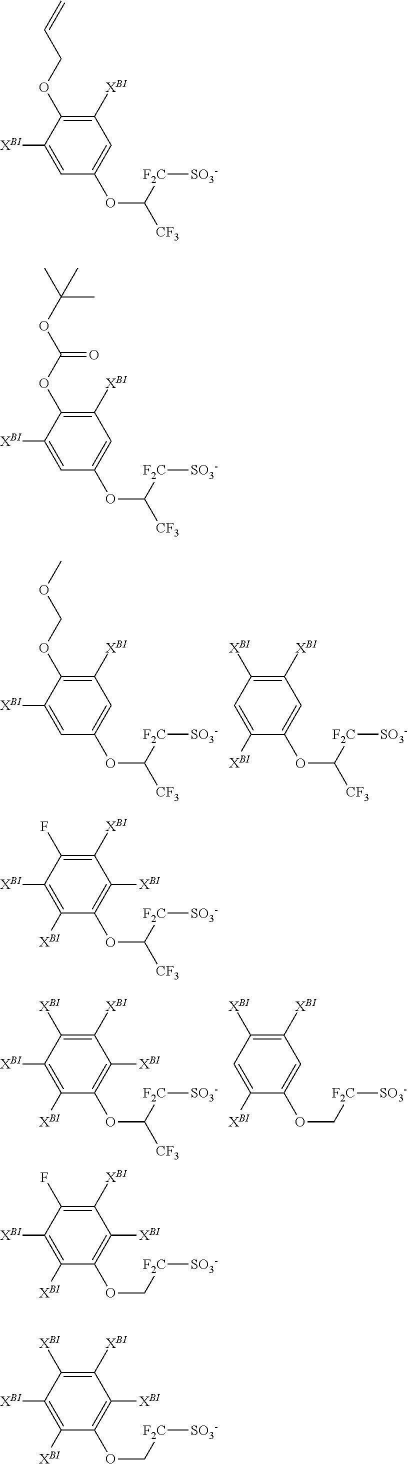

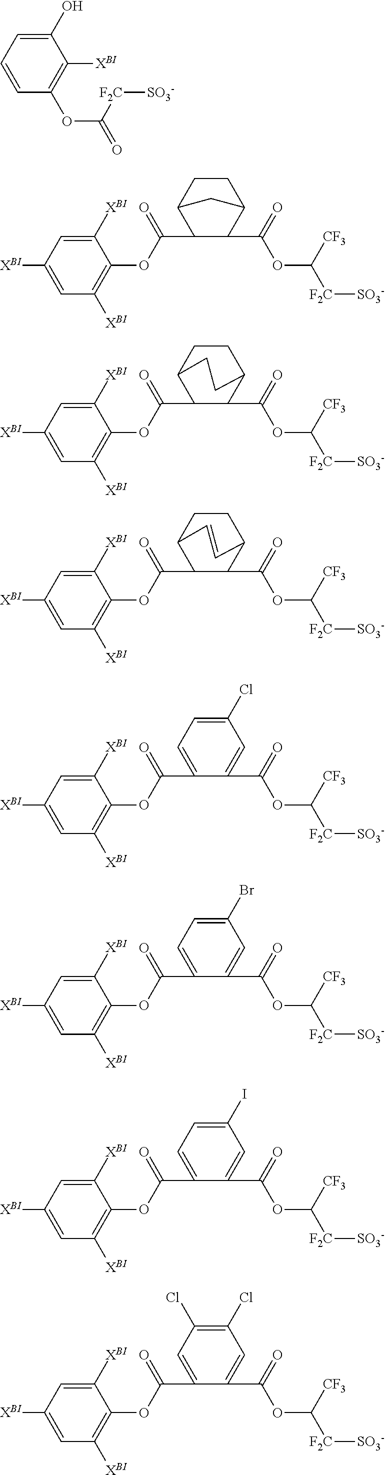

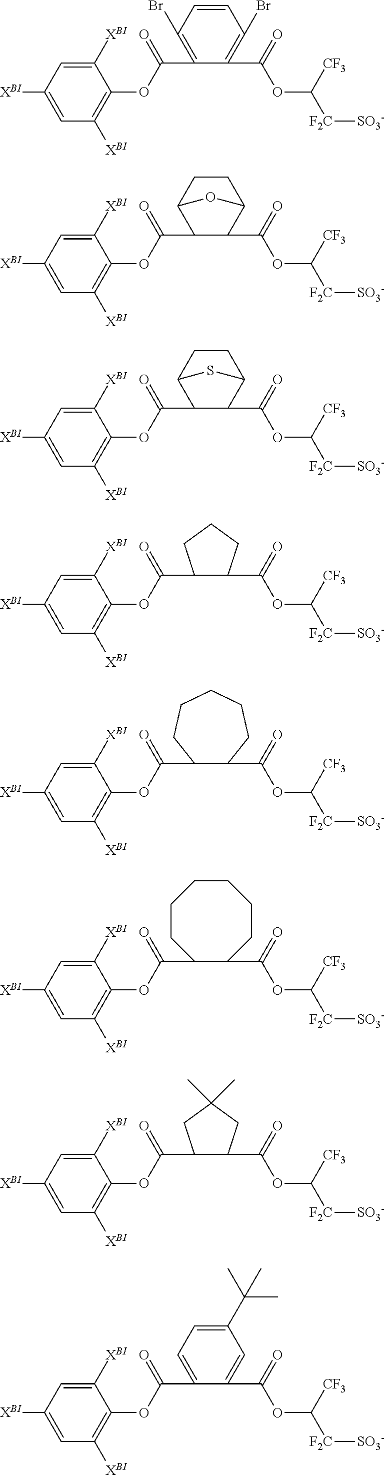

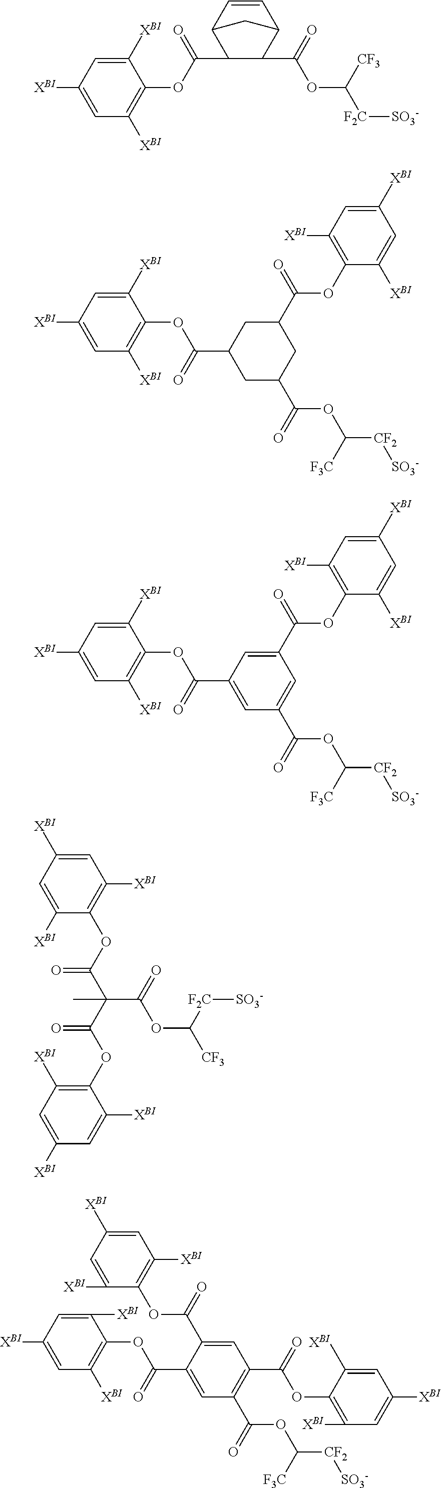

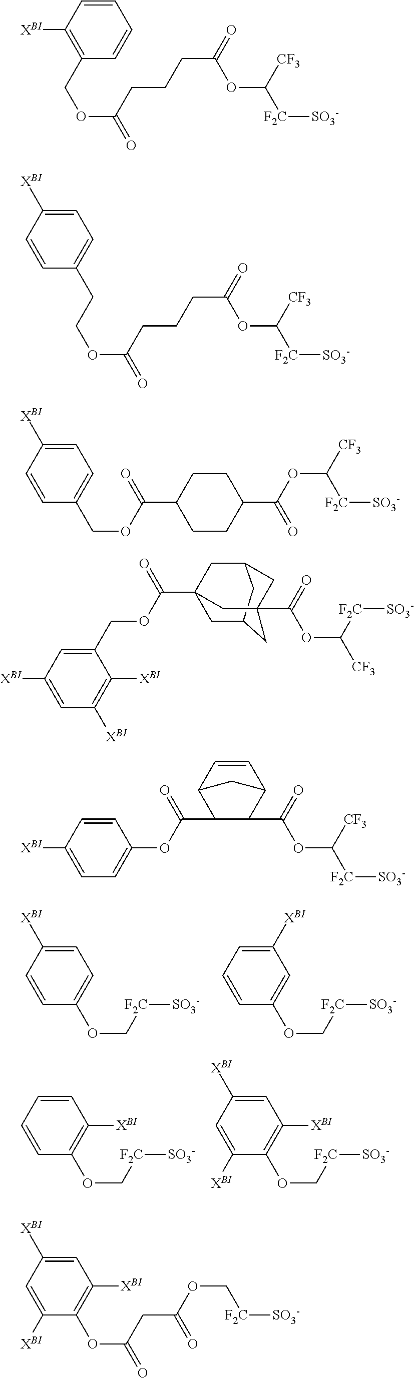

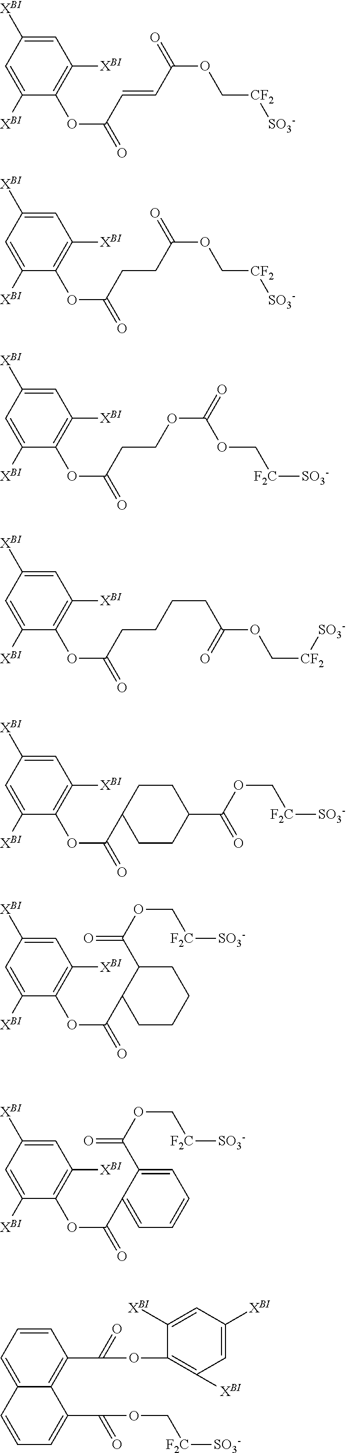

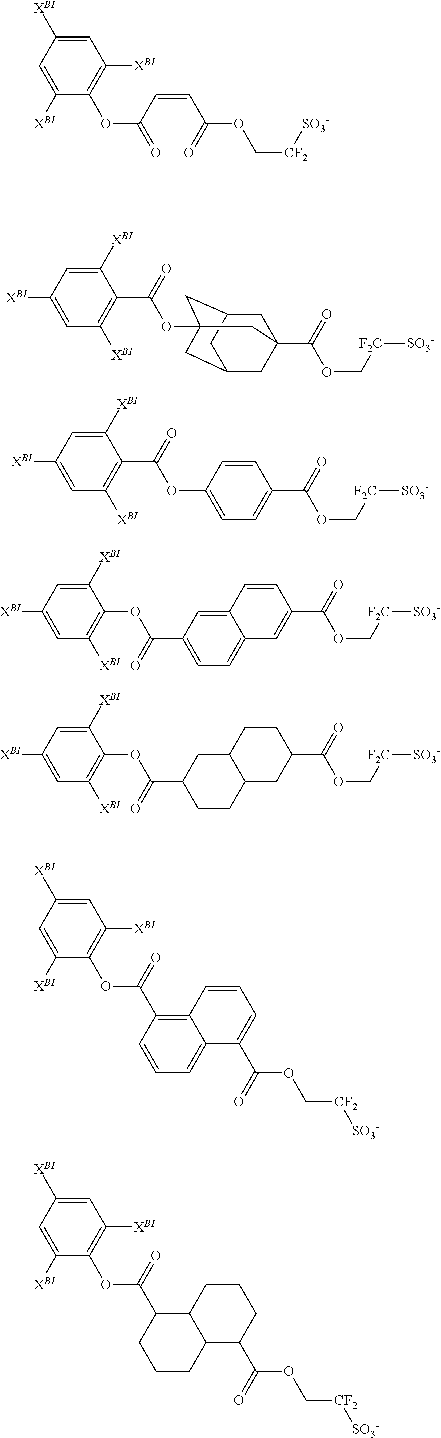

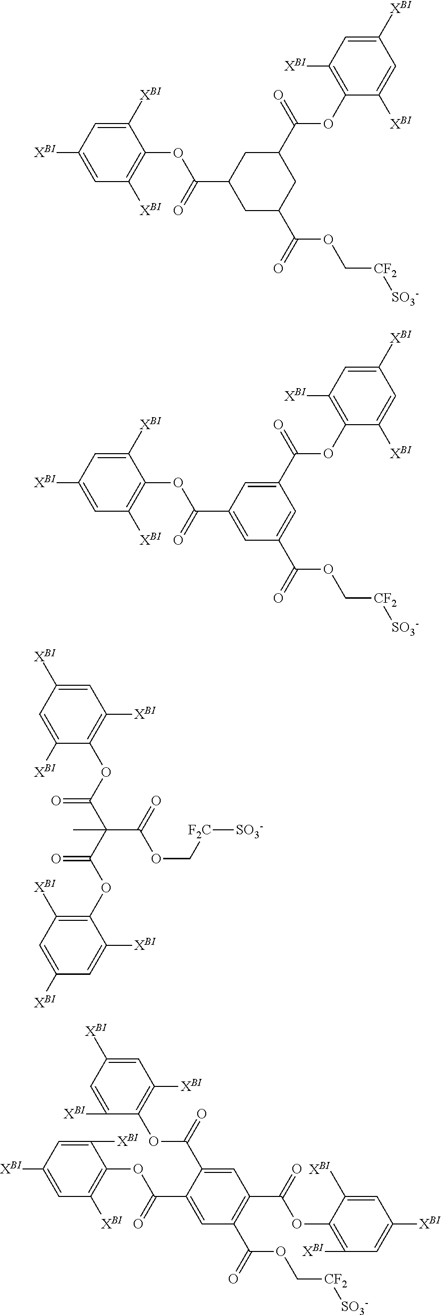

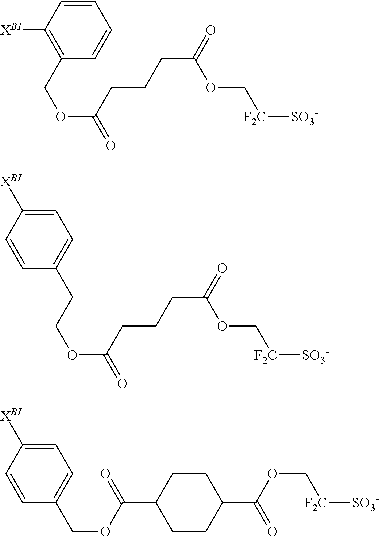

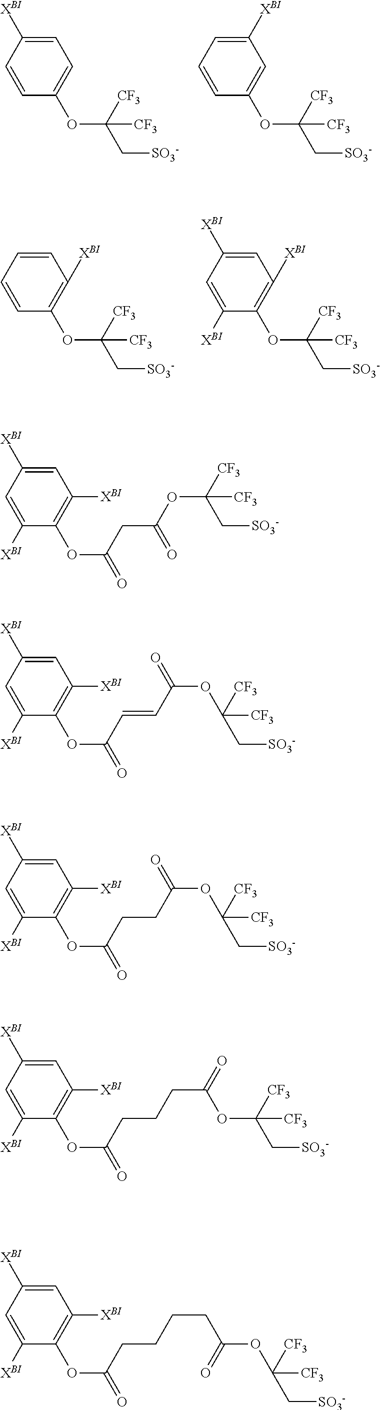

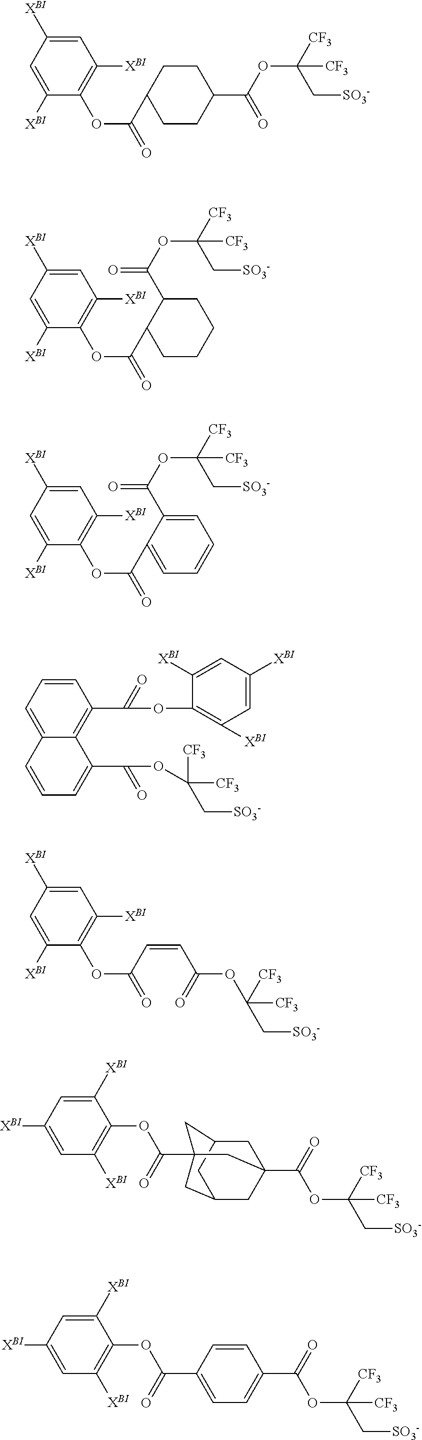

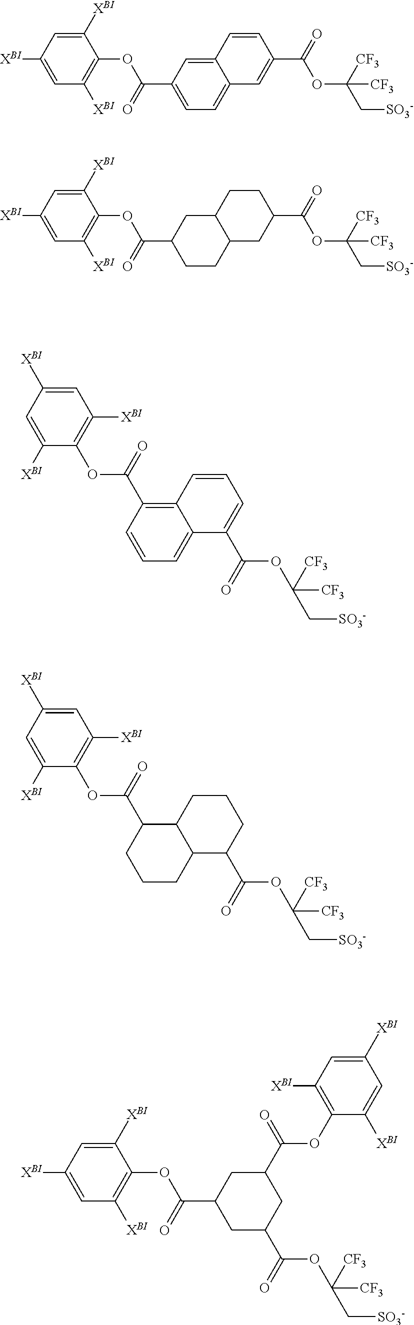

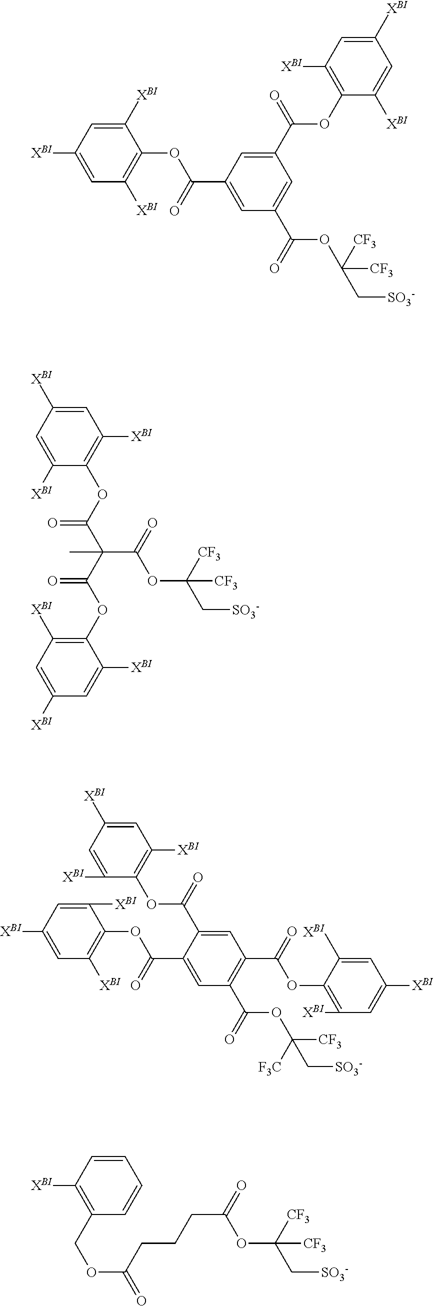

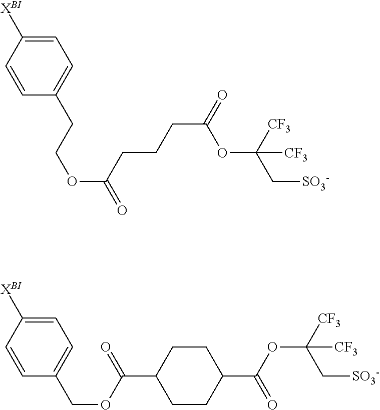

Other examples of the anion M⁻ include those described in the following patent documents.
WO 2023/157455, paragraphs [0076] and [0106]
WO 2024/024801, paragraph [0111]
WO 2024/043121, paragraphs [0253]-[0256]
WO 2024/057751, paragraphs [0044]-[0045]
WO 2024/122423, paragraphs [0205]-[0220]
JP-A 2023-123183, paragraphs [0170]-[0178]
JP-A 2024-062406, paragraphs [0026]-[0028]
JP-A 2024-062407, paragraphs [0022]-[0025]
JP-A 2024-062408, paragraphs [0026]-[0028]
JP-A 2024-068156, paragraphs [0028]-[0030]
JP-A 2024-068157, paragraphs [0026]-[0028]
JP-A 2024-068158, paragraphs [0028]-[0030]
JP-A 2024-068159, paragraphs [0028]-[0030]
JP-A 2024-072280, paragraphs [0031]-[0033]
JP-A 2024-072281, paragraphs [0023]-[0025]
JP-A 2024-077618, paragraphs [0026]-[0029]
JP-A 2024-077619, paragraphs [0020]-[0021]
JP-A 2024-080672, paragraphs [0140]-[0143]
JP-A 2024-083303, paragraphs [0023]-[0025]
JP-A 2024-083304, paragraphs [0028]-[0031]
JP-A 2024-099500, paragraphs [0030]-[0033]
JP-A 2024-099502, paragraphs [0028]-[0030]
JP-A 2024-101557, paragraphs [0030]-[0032]
JP-A 2024-102842, paragraphs [0025]-[0027]
JP-A 2024-102843, paragraphs [0033]-[0035]
JP-A 2024-127832, paragraphs [0021]-[0022]
JP-A 2024-144354, paragraphs [0169]-[0172]
JP-A 2024-144356, paragraphs [0178]-[0181]
JP-A 2024-160436, paragraphs [0040]-[0043]
JP-A 2025-000705, paragraphs [0030]-[0031]
JP 7247732, paragraphs [0157]-[0158]
JP 7446352, paragraphs [0227]-[0238]
JP 7466597, paragraphs [0253]-[0256]
JP 7466782, paragraphs [0309]-[0312]

Other examples of the non-nucleophilic counter ion include the fluorine-free aromatic sulfonate anions and alkanesulfonate anions described in JP 7398551, paragraphs [0186]-[0188], JP 7067271, paragraphs [0028]-[0029], JP 7032549, paragraphs [0220]-[0225], JP 6645464, paragraphs [0040]-[0045], JP 6248882, paragraphs [0027]-[0029], JP 6090585, paragraphs [0034]-[0037], JP-A 2024-104830, paragraphs [0037]-[0060], JP-A 2024-140135, paragraphs [0033]-[0093], JP-A 2023-177038, paragraphs [0039]-[0066], and JP-A 2006-276759, paragraphs [0100]-[0102], and the fluorine-containing aromatic sulfonate anions described in JP 6648726, paragraphs [0029]-[0034], JP-A 2024-077330, paragraphs [0264]-[0267], and JP-A 2025-000201, paragraphs [0040]-[0071].

Further useful non-nucleophilic counter ions include bissulfonic acid anions as described in JP-A 2015-206932, sulfonamide or sulfonimide anions having sulfonic acid side and different side as described in WO 2020/158366, and anions having a sulfonic acid side and a carboxylic acid side as described in JP-A 2015-024989.

In formulae (c2) and (c3), d1 and d2 are each independently 0, 1, 2 or 3, preferably 1.

In formula (c4), e1 is 0 or 1, e2 is 0, 1, 2, 3 or 4, and e3 is 0, 1, 2, 3 or 4, meeting 0≤e2+e3≤4 when e1=0, and 0≤e2+e3≤6 when e1=1.

In formulae (c2), (c3) and (c4), L¹ is a single bond, ether bond, ester bond, carbonyl, sulfonate ester bond, sulfonamide bond, carbonate bond or carbamate bond.

From the aspect of synthesis, an ether bond, ester bond or carbonyl is preferred, with the ester bond or carbonyl being more preferred.

In formula (c2), Rf¹ and R² are each independently fluorine or a C₁-C₆ fluorinated saturated hydrocarbyl group. It is preferred that both Rf¹ and Rf² be fluorine because the generated acid has a higher acid strength. Rf³ and Rf⁴ are each independently hydrogen, fluorine or a C₁-C₆ fluorinated saturated hydrocarbyl group. It is preferred for solvent solubility that at least one of Rf³ and Rf⁴ be trifluoromethyl.

In formula (c3), Rf⁵ and Rf⁶ are each independently hydrogen, fluorine or a C₁-C₆ fluorinated saturated hydrocarbyl group. It is excluded that all Rf⁵ and Rf⁶ are hydrogen at the same time. It is preferred for solvent solubility that at least one of Rf⁵ and Rf⁶ be trifluoromethyl.

In formula (c4), Rf⁷ is fluorine, a C₁-C₆ fluorinated alkyl group, C₁-C₆ fluorinated alkoxy group, or C₁-C₆ fluorinated alkylthio group. Rf⁷ is preferably fluorine, trifluoromethyl, difluoromethyl, trifluoromethoxy, difluoromethoxy, trifluoromethylthio or difluoromethylthio, more preferably fluorine, trifluoromethyl or trifluoromethoxy. When e2 is 2, 3 or 4, a plurality of Rf may be identical or different.

In formula (c4), R³³ is halogen exclusive of fluorine, or a C₁-C₂₀ hydrocarbyl group which may contain a heteroatom. The hydrocarbyl group may be saturated or unsaturated and straight, branched or cyclic. Examples thereof are as exemplified above for the hydrocarbyl groups R¹ and R² in formula (A), but not limited thereto. When e3 is 2, 3 or 4, a plurality of R³³ may be identical or different.

When e3 is 2, 3 or 4, a plurality of R³³ may bond together to form a ring with the carbon atoms to which they are attached. Examples of the ring include cyclopropane, cyclobutane, cyclopentane, cyclohexane, norbornane, and adamantane rings. In the ring, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the ring may contain a hydroxy moiety, fluorine, chlorine, bromine, iodine, cyano moiety, carbonyl moiety, ether bond, ester bond, sulfonate ester bond, carbonate bond, lactone ring, sultone ring, carboxylic anhydride (—C(═O)—O—C(═O)—) or haloalkyl moiety.

Examples of the anion in repeat unit (c2) are shown below, but not limited thereto. R^{A} is as defined above.

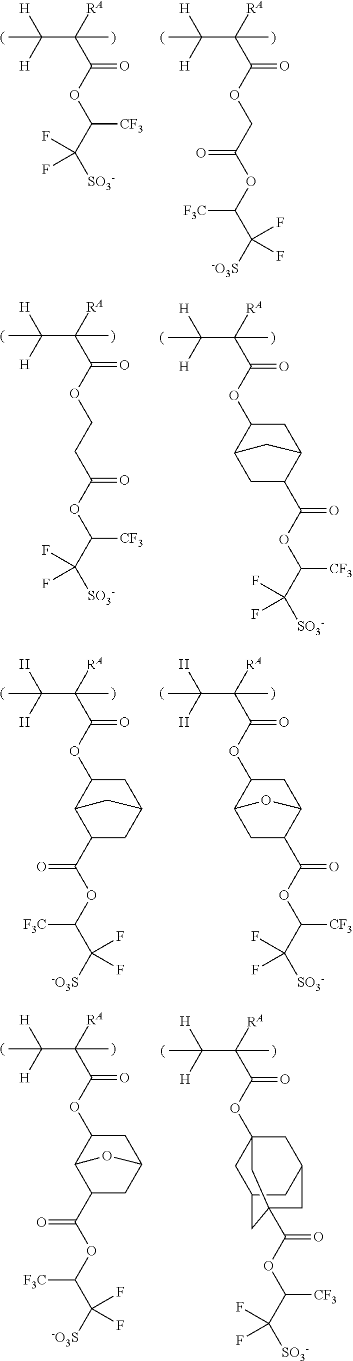

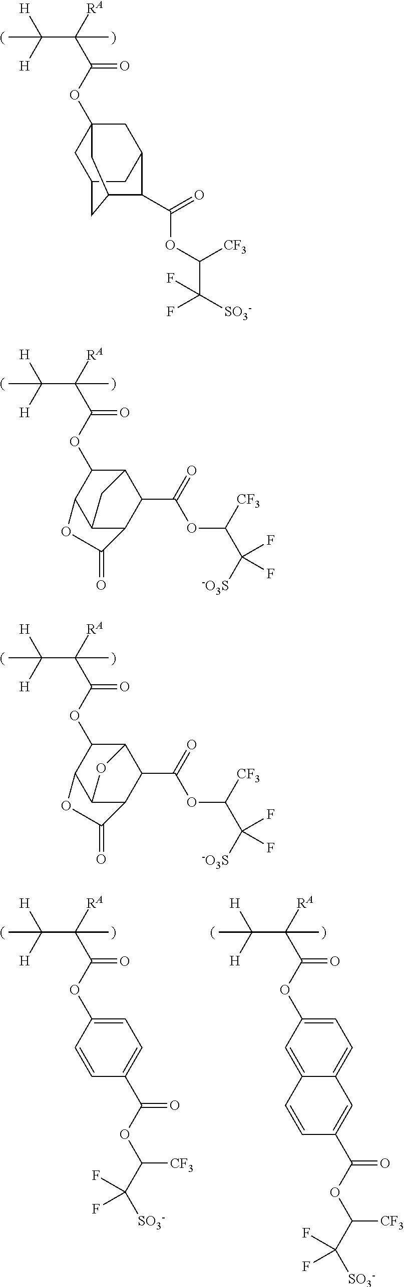

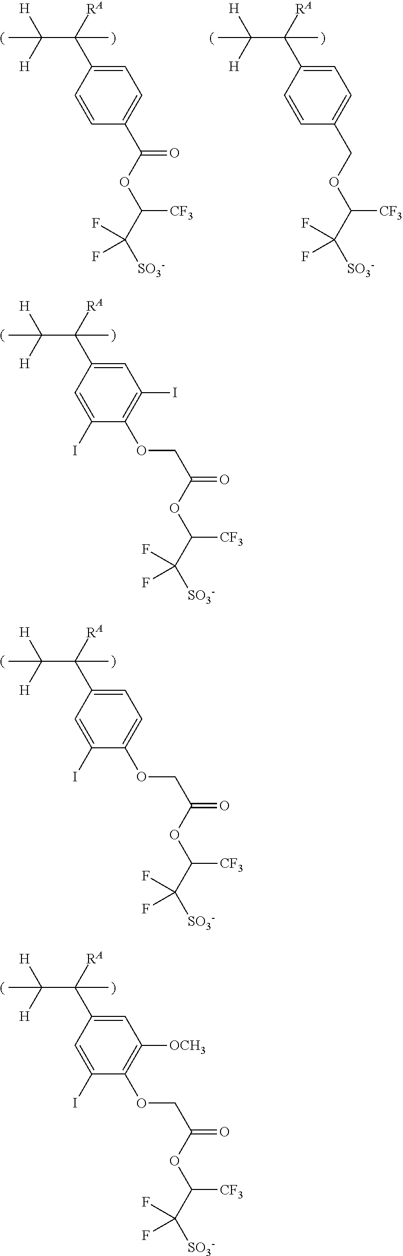

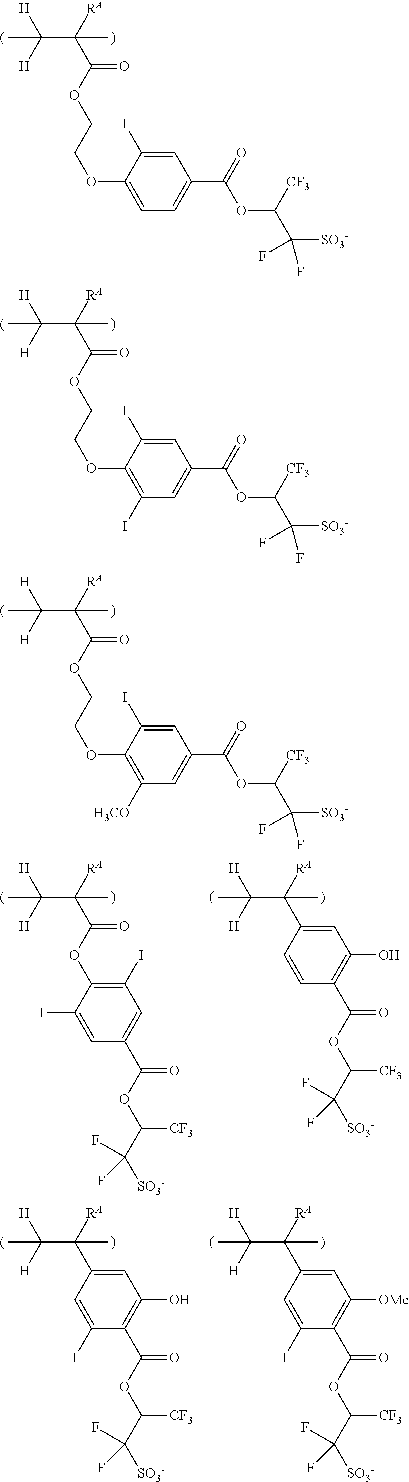

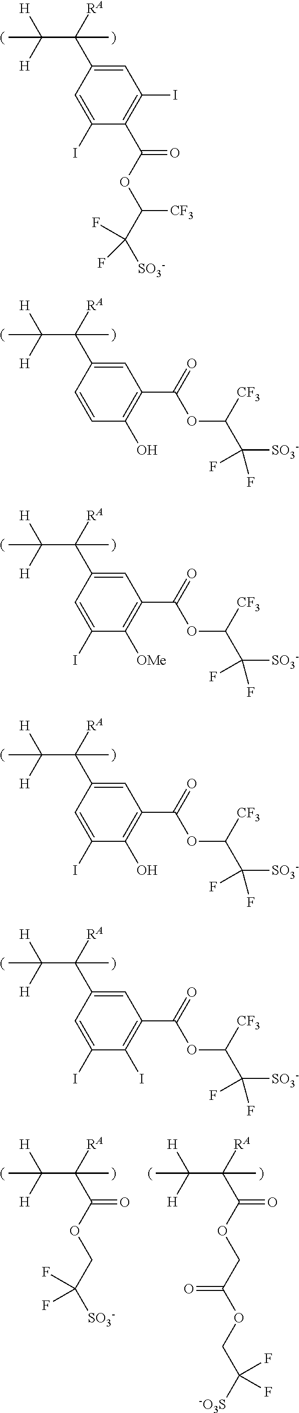

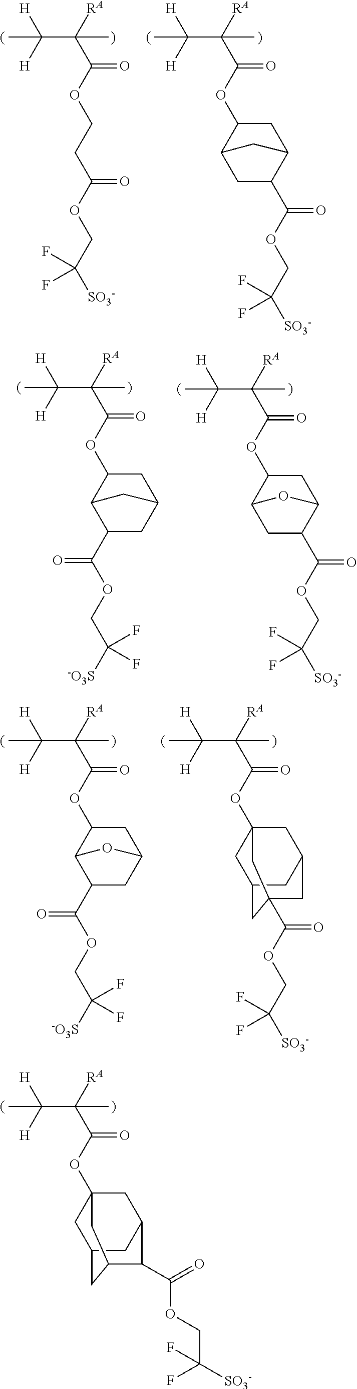

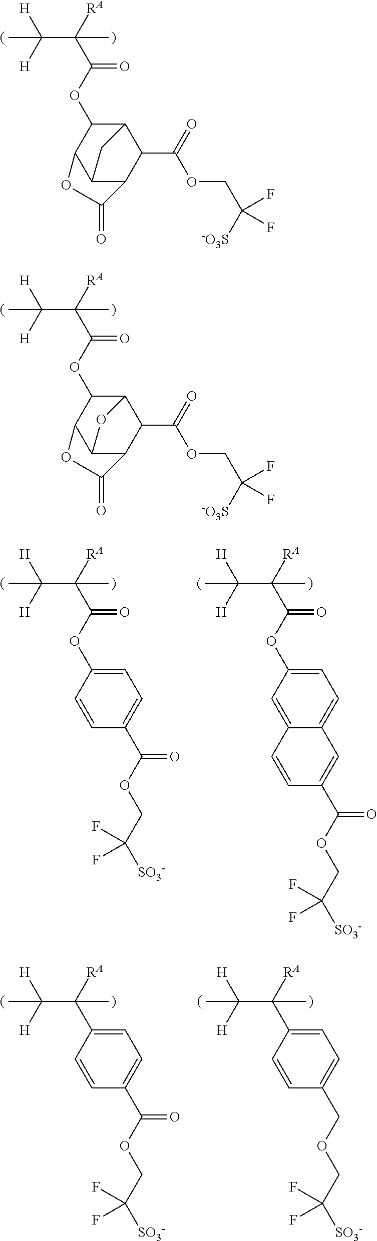

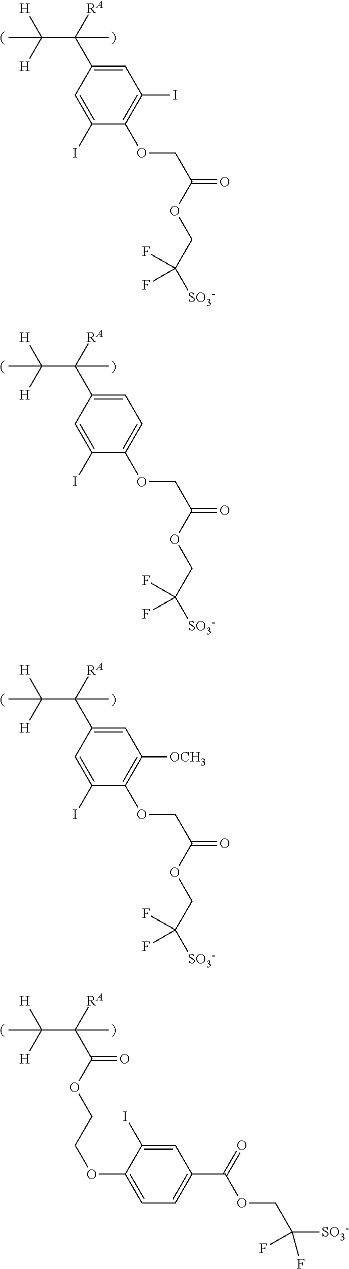

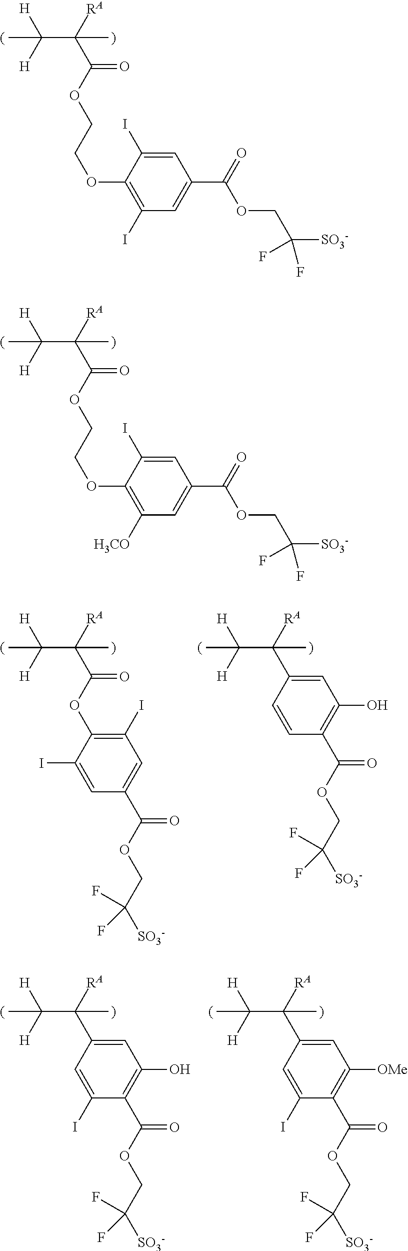

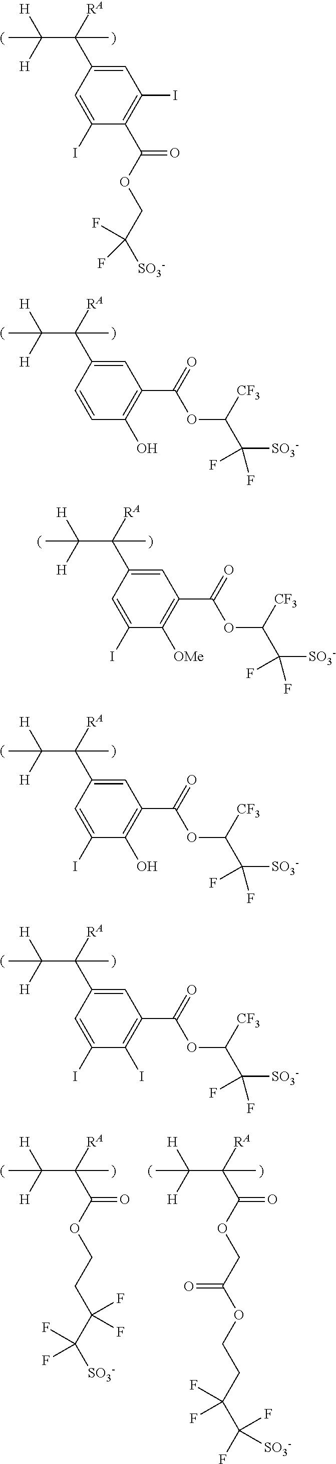

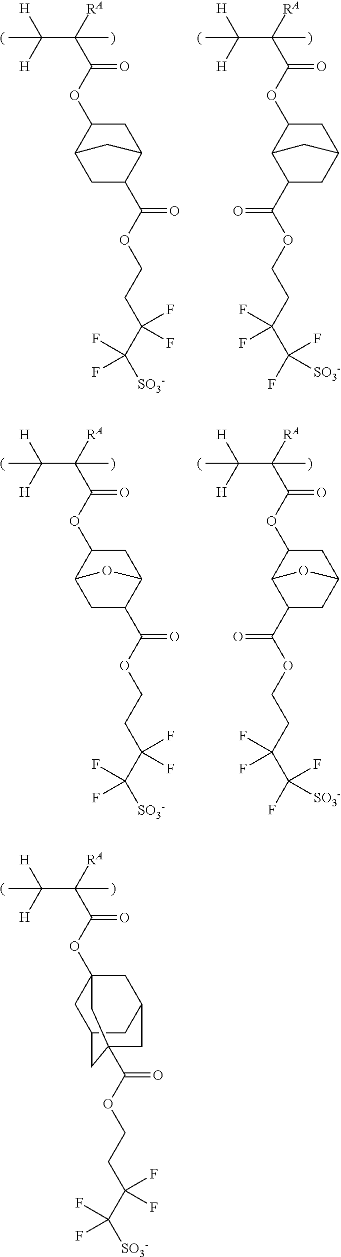

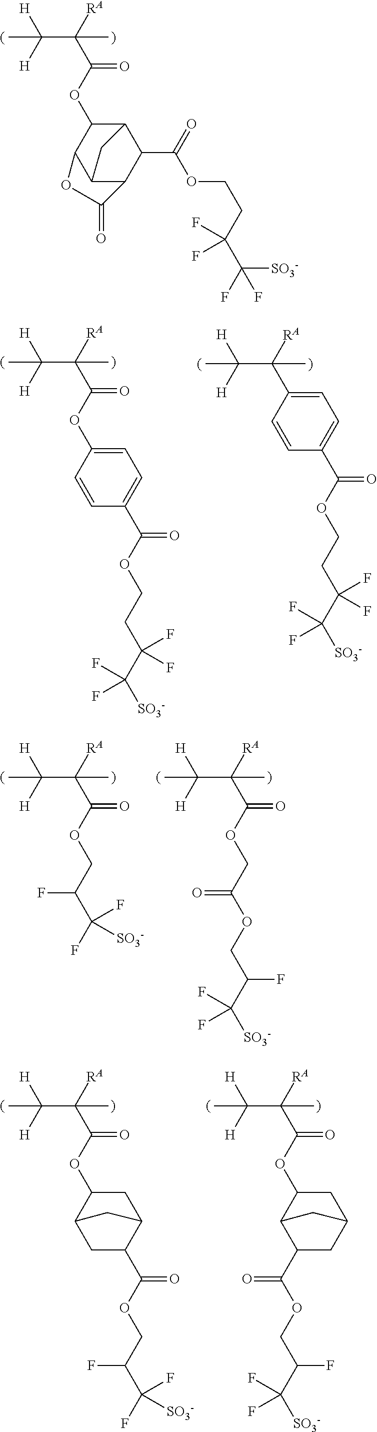

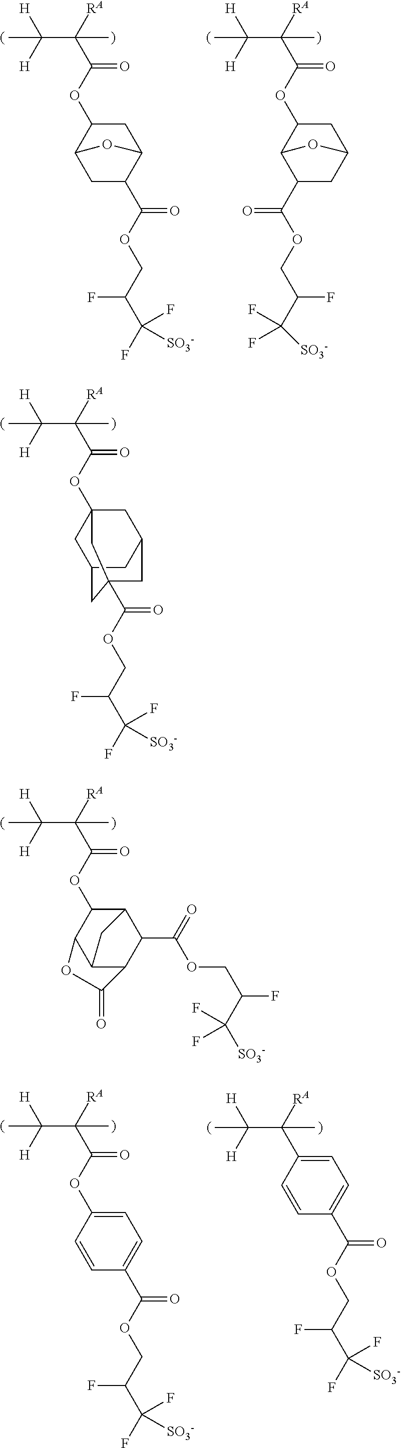

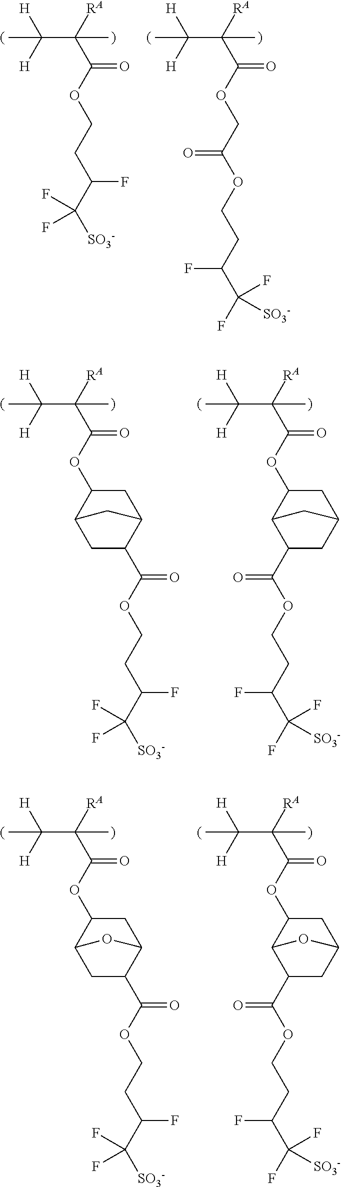

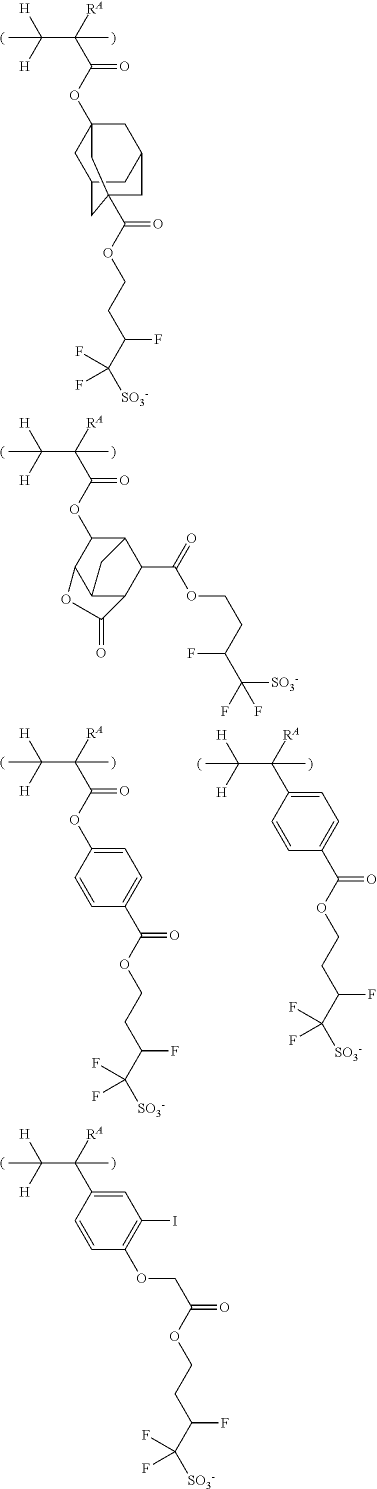

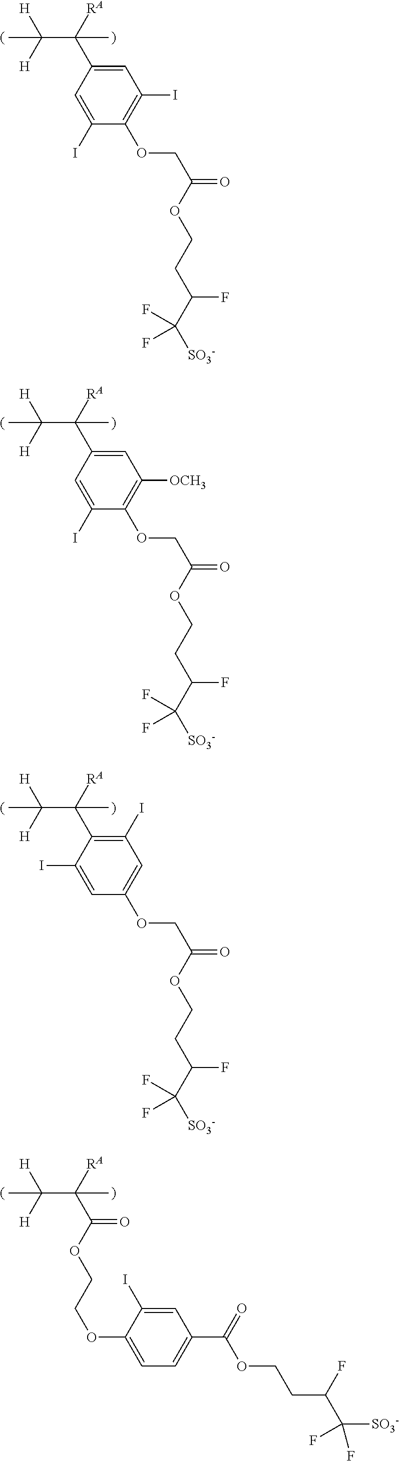

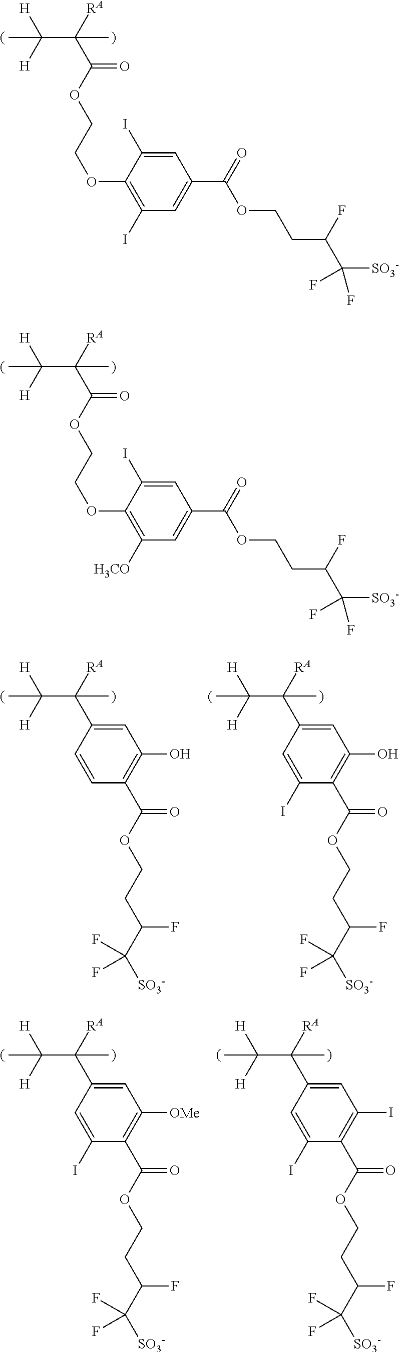

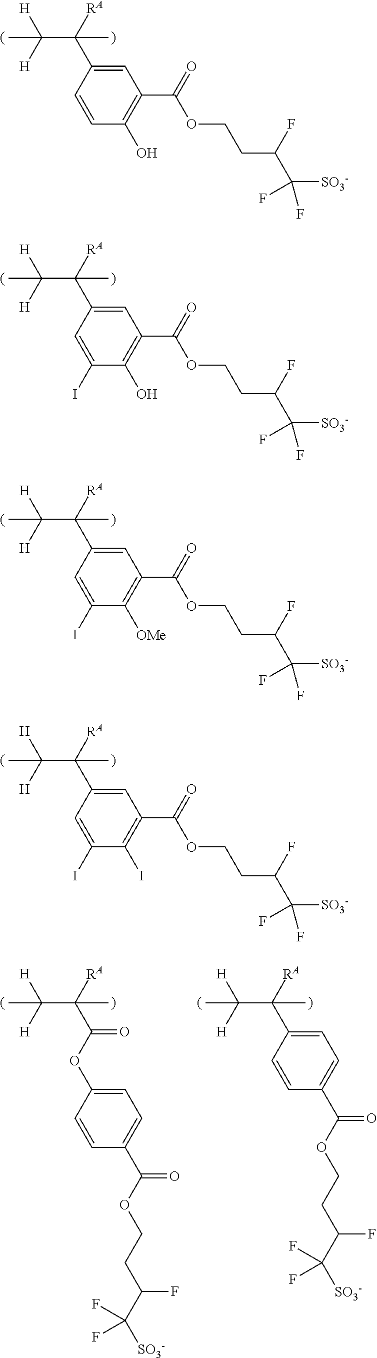

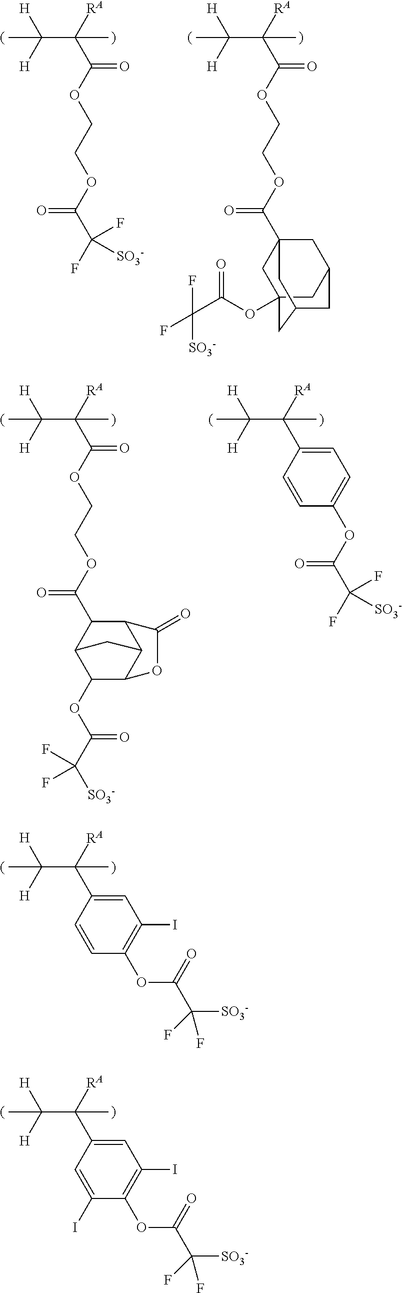

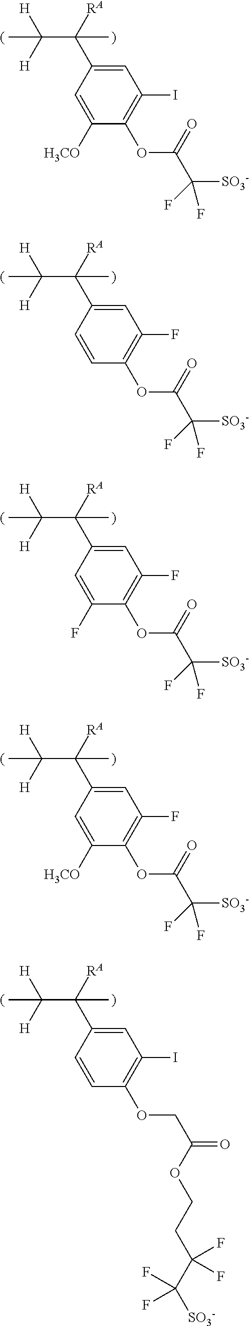

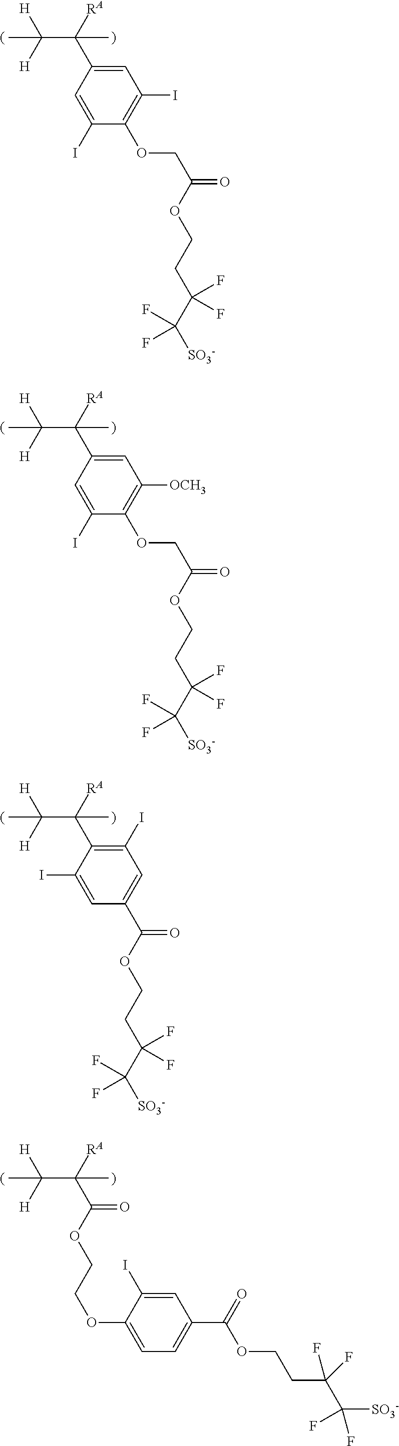

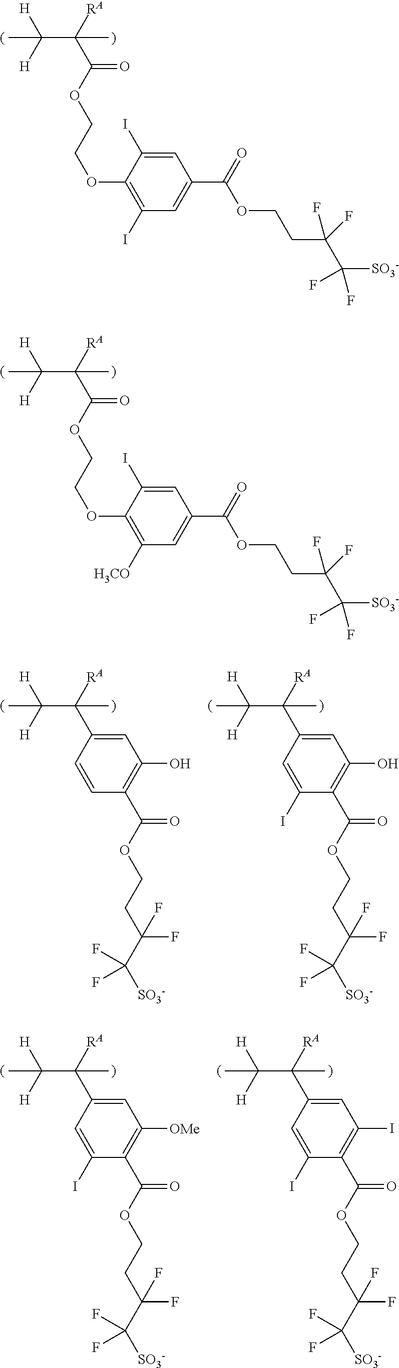

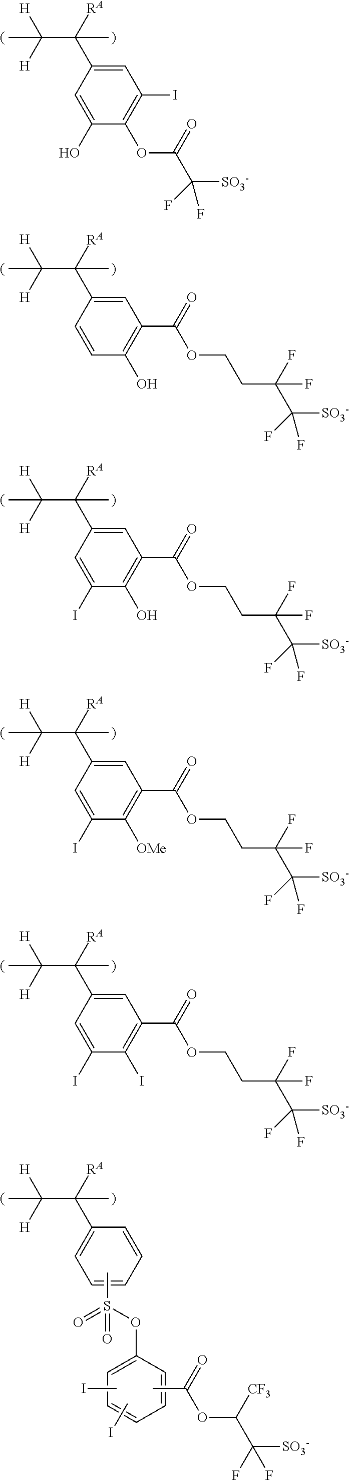

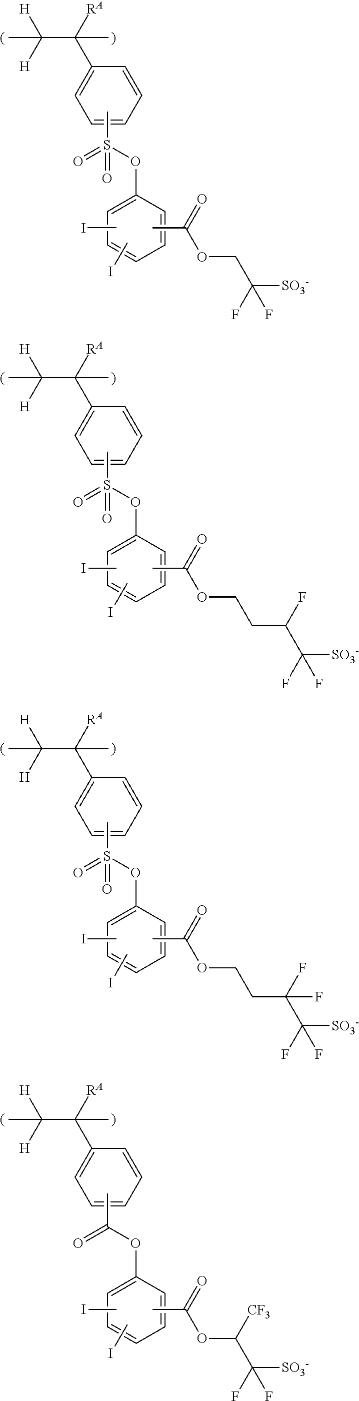

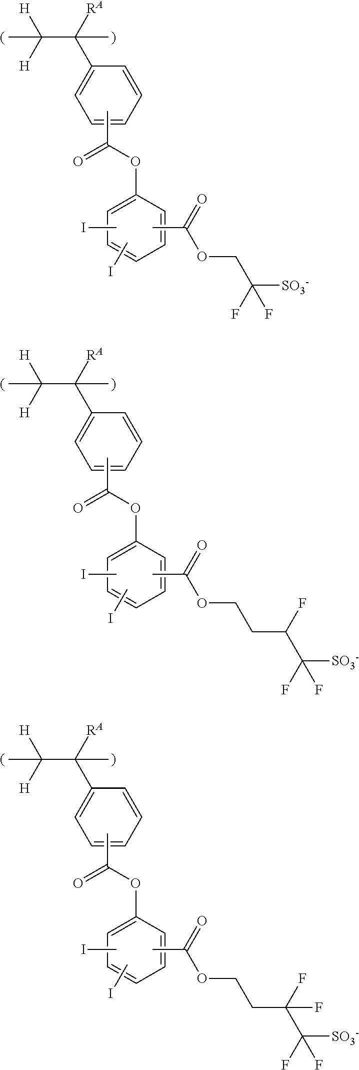

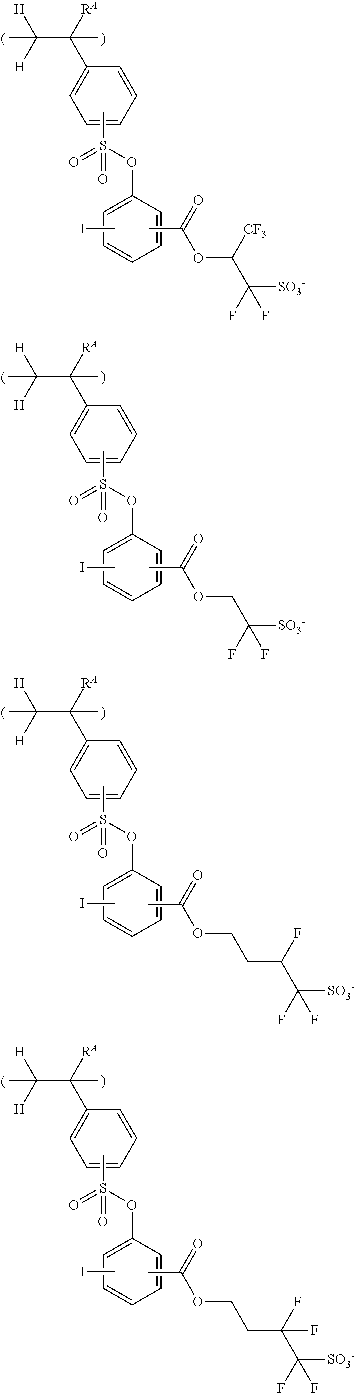

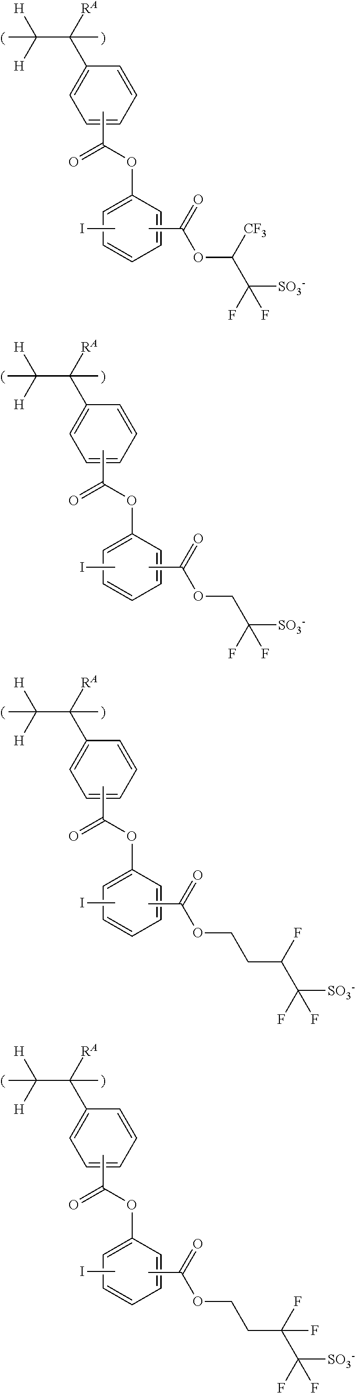

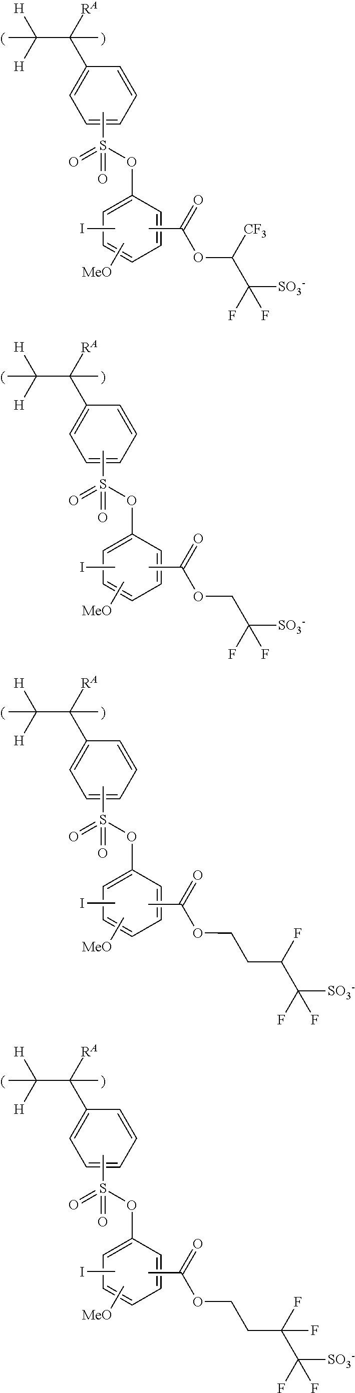

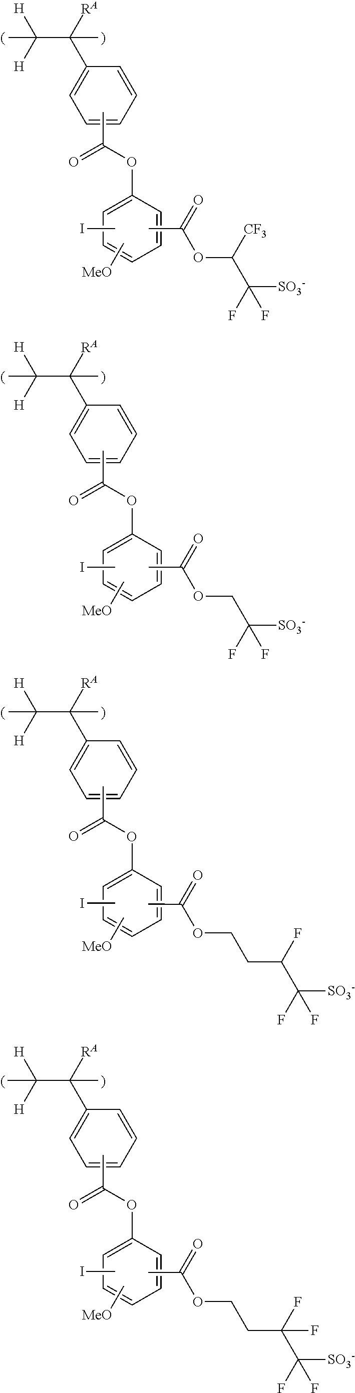

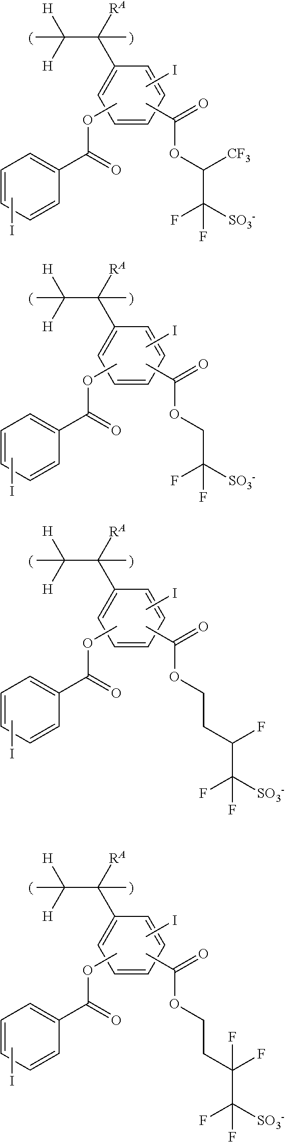

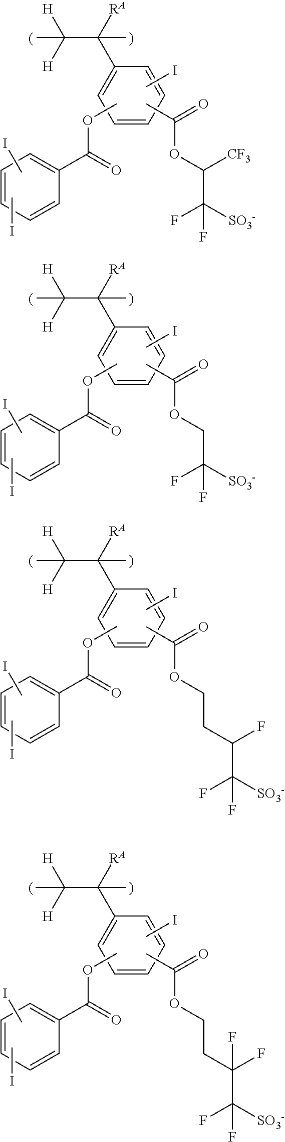

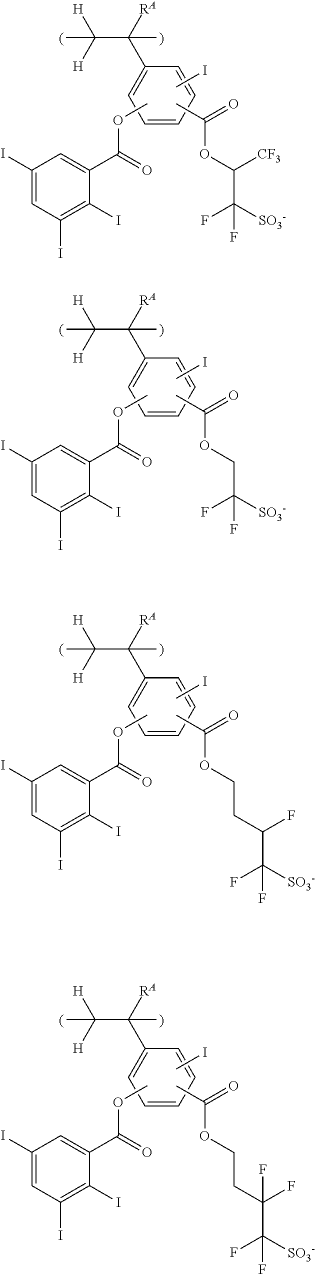

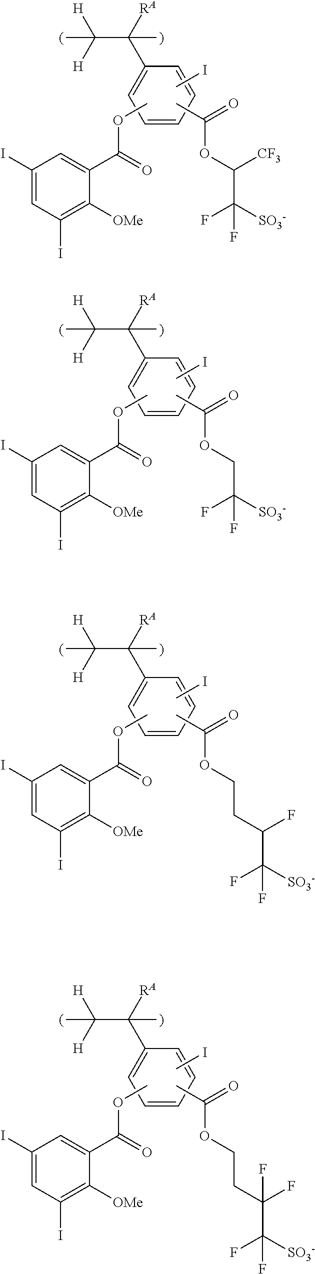

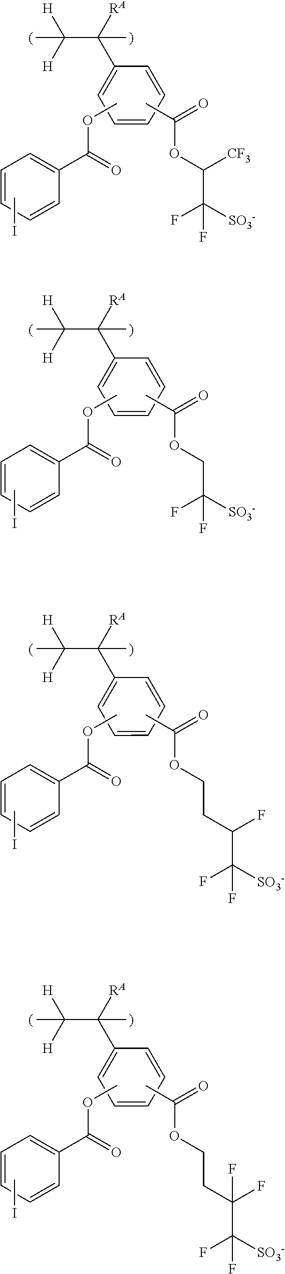

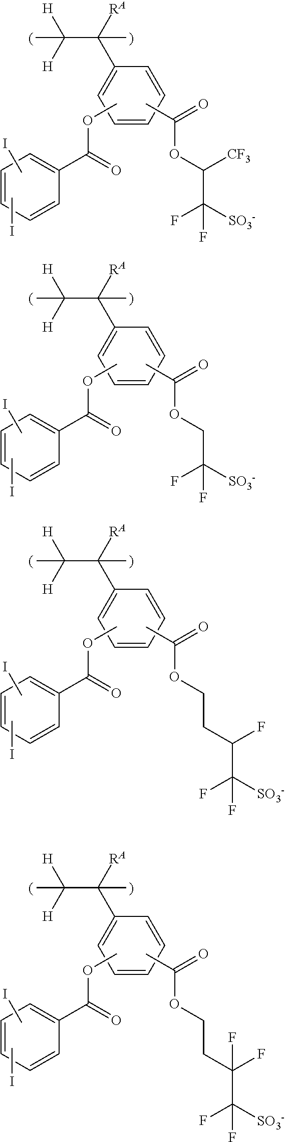

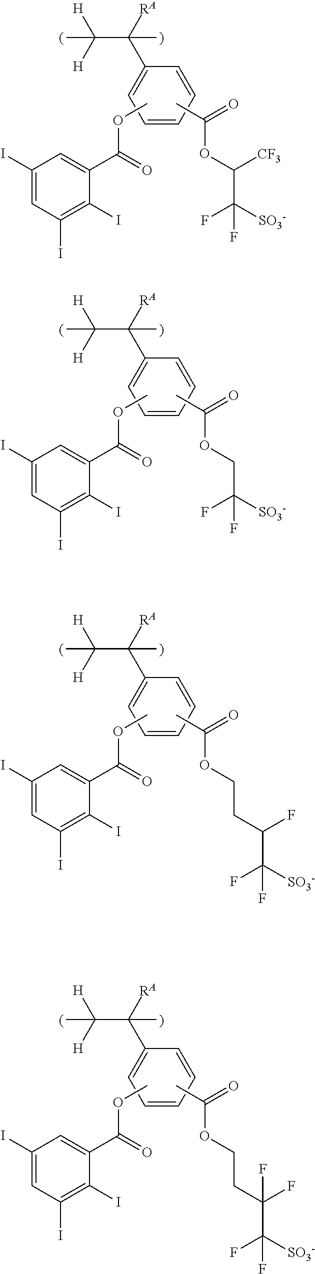

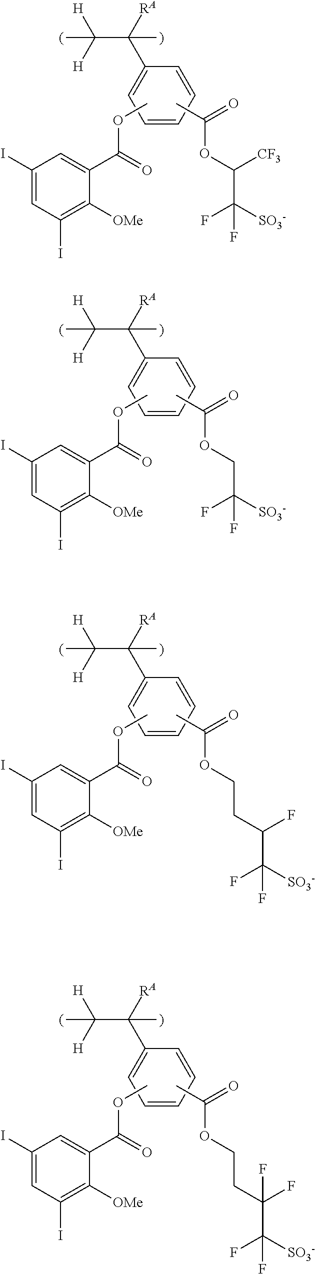

Other examples of repeat unit (c2) include those described in WO 2024/176672, paragraphs [0043]-[0044], WO 2024/176701, paragraphs [0067]-[0070], WO 2024/190386, paragraphs [0057]-[0058], JP-A 2024-103465, paragraphs [0020]-[0023], JP-A 2024-120703, paragraphs [0067]-[0070], JP 7520258, paragraphs [0075]-[0084], JP-A 2024-043941, paragraphs [0032]-[0047], JP-A 2025-0103053, paragraphs [0385]-[0390], and WO 2025/018169, paragraphs [0062]-[0064].

Examples of the anion in repeat unit (c3) are shown below, but not limited thereto. R^{A} is as defined above.

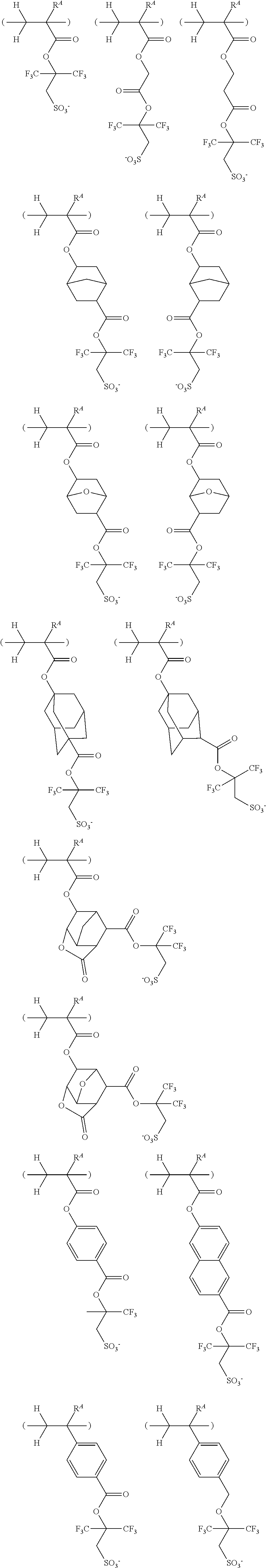

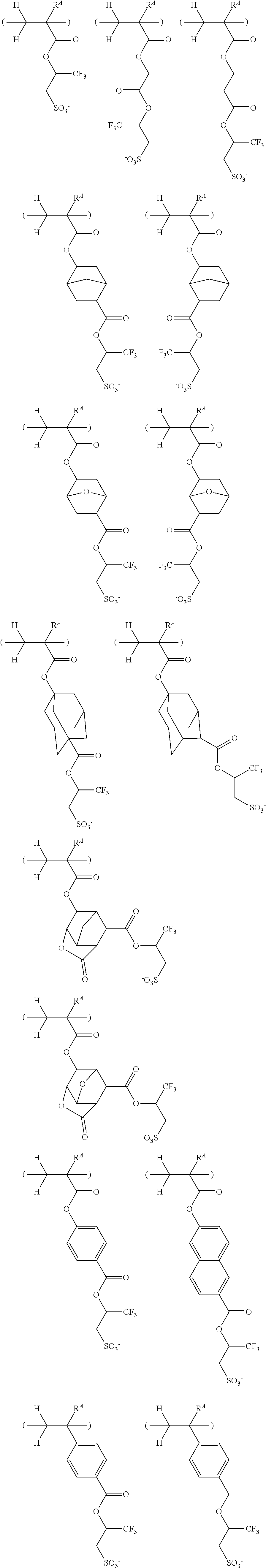

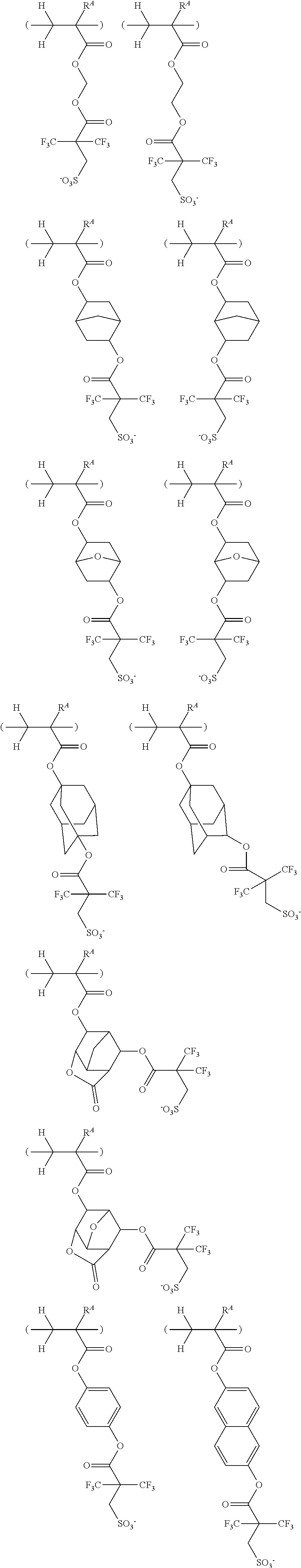

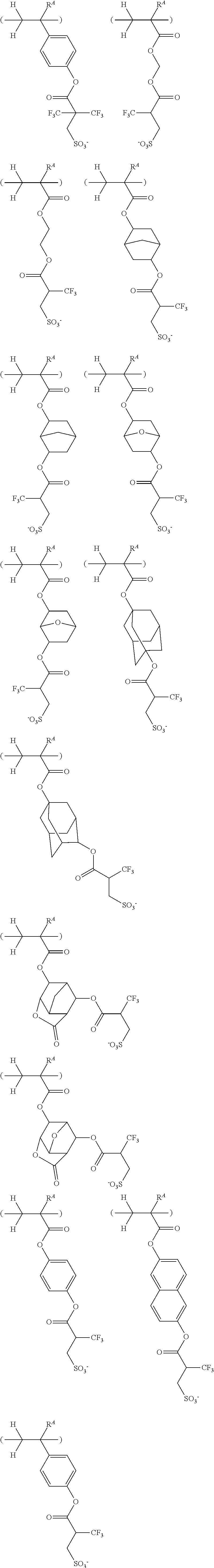

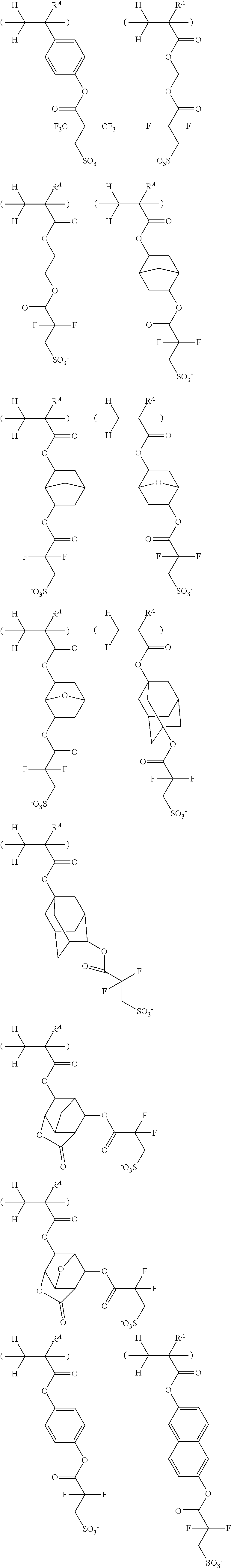

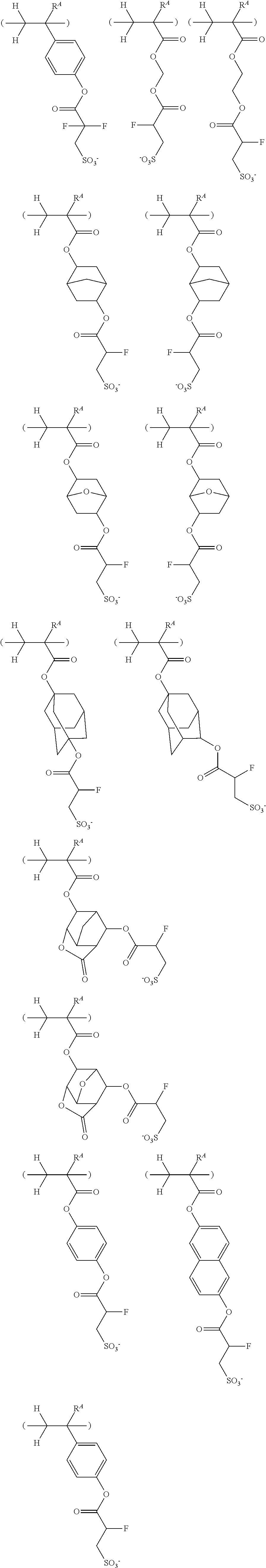

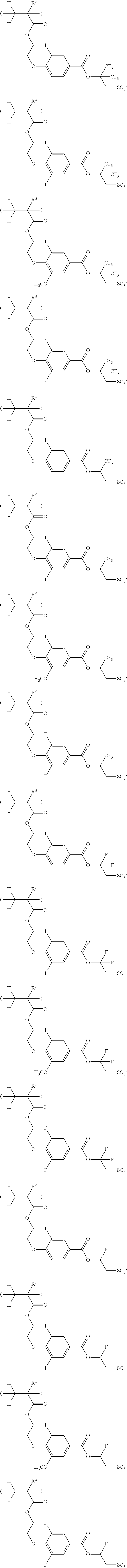

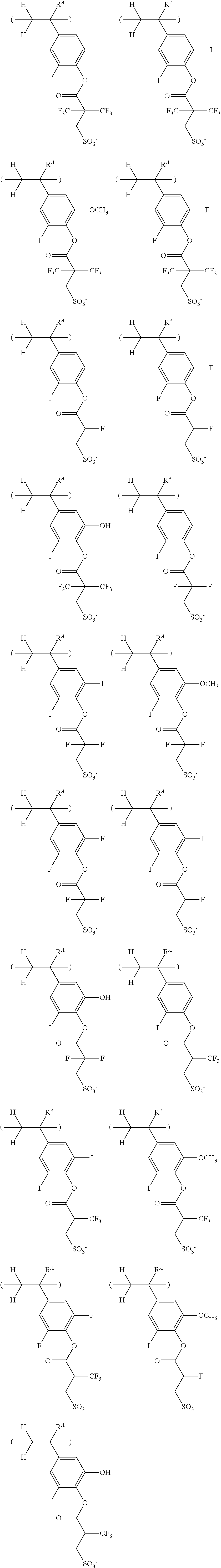

[chemical structure]

[chemical structure]

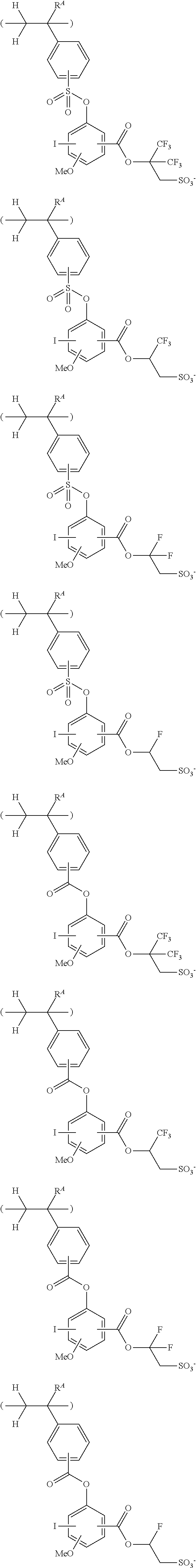

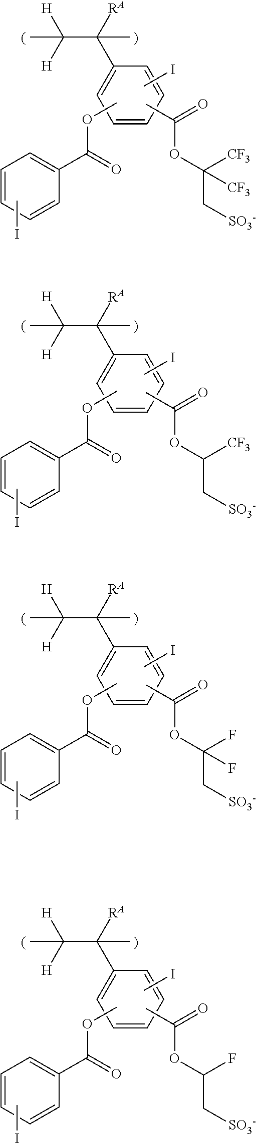

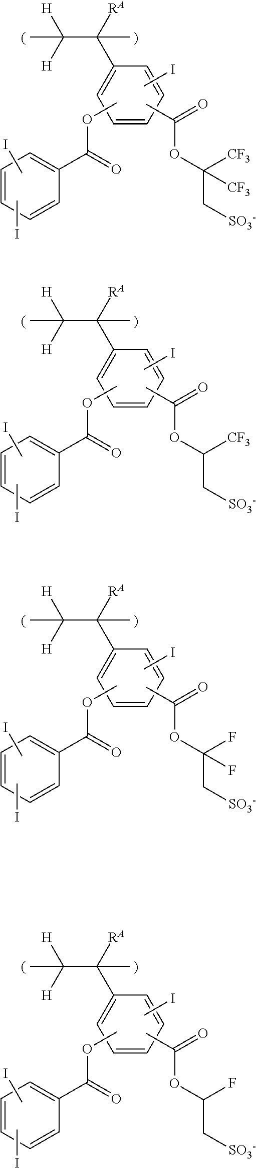

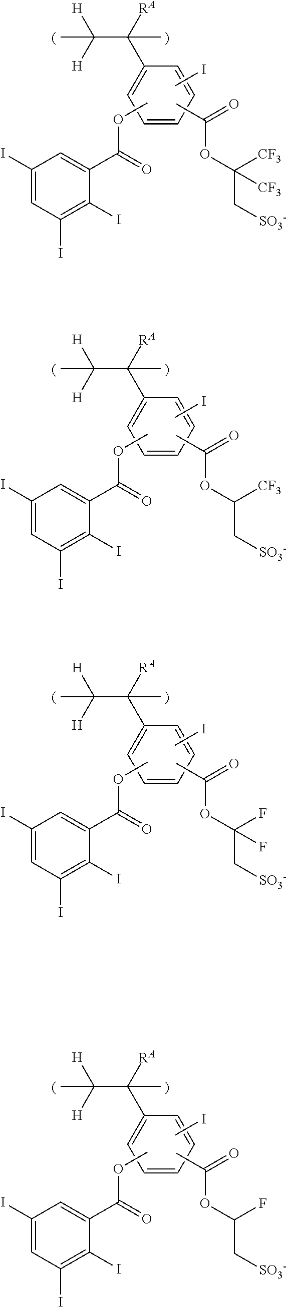

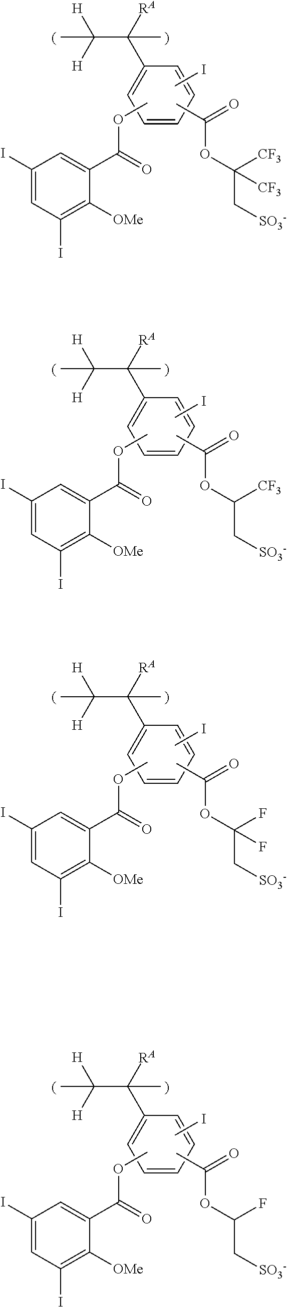

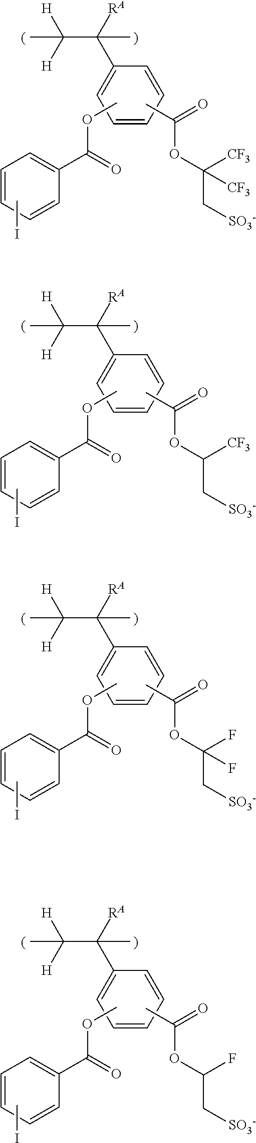

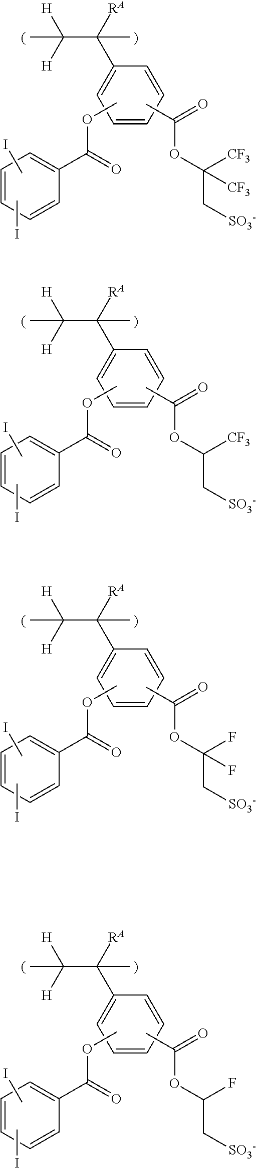

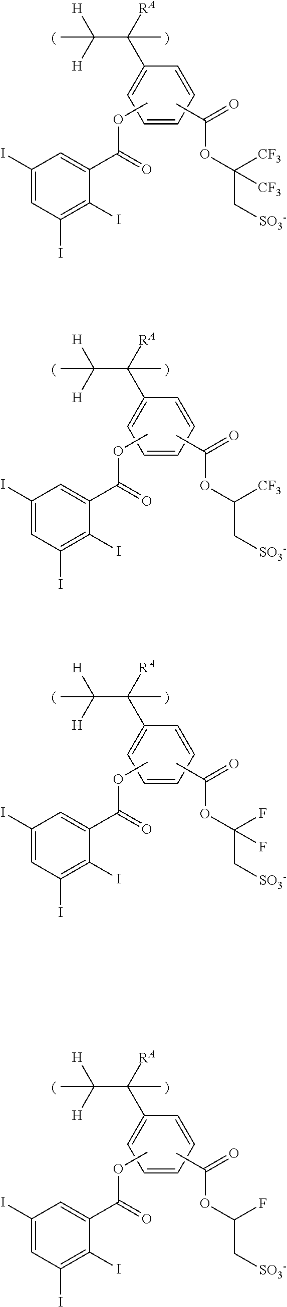

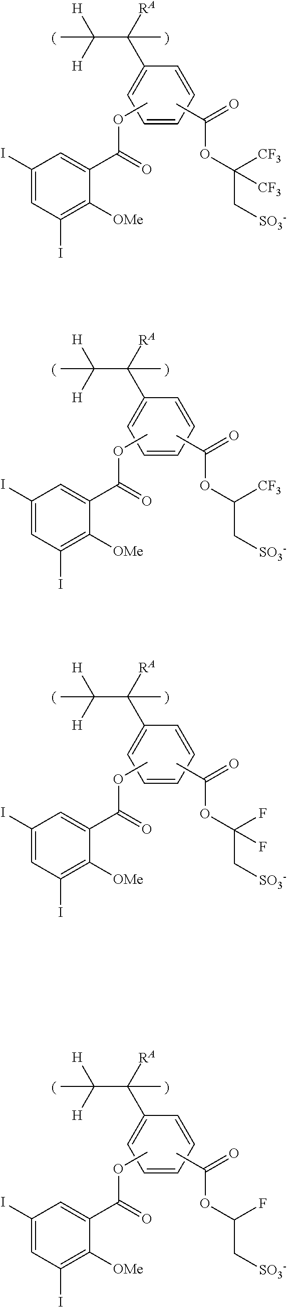

Examples of the anion in repeat unit (c4) are shown below, but not limited thereto. R^{A} is as defined above.

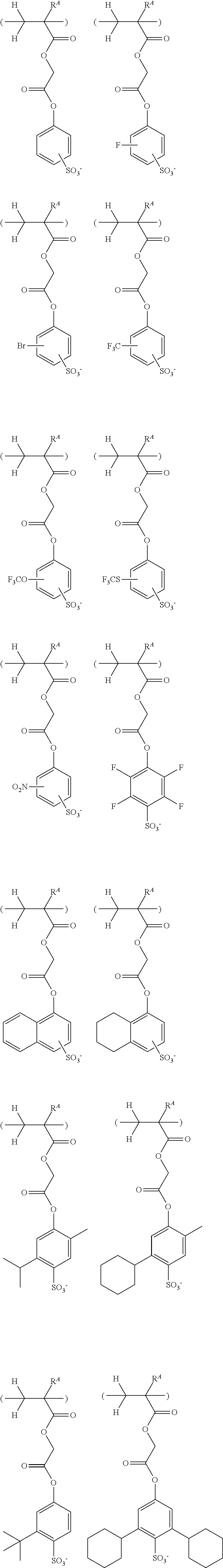

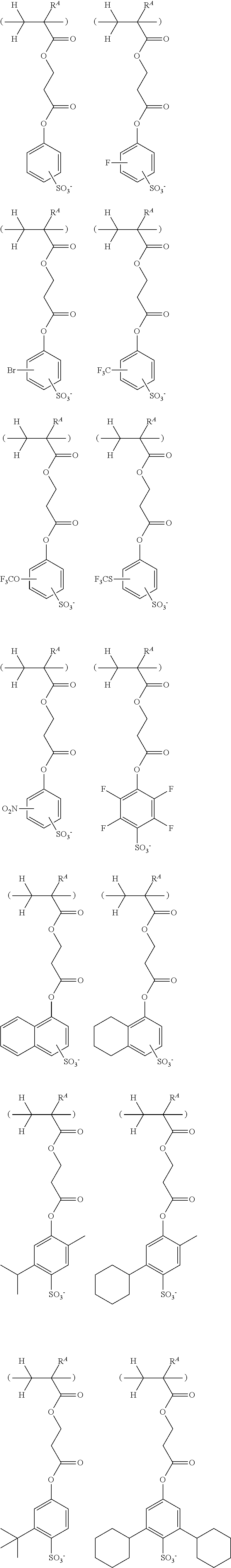

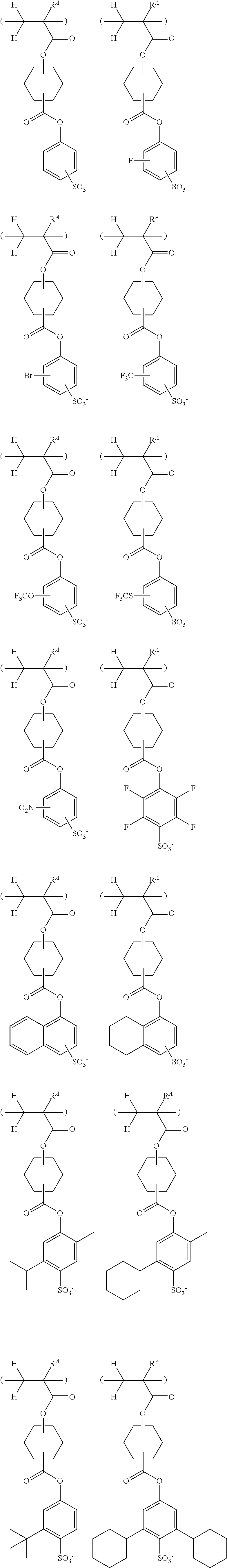

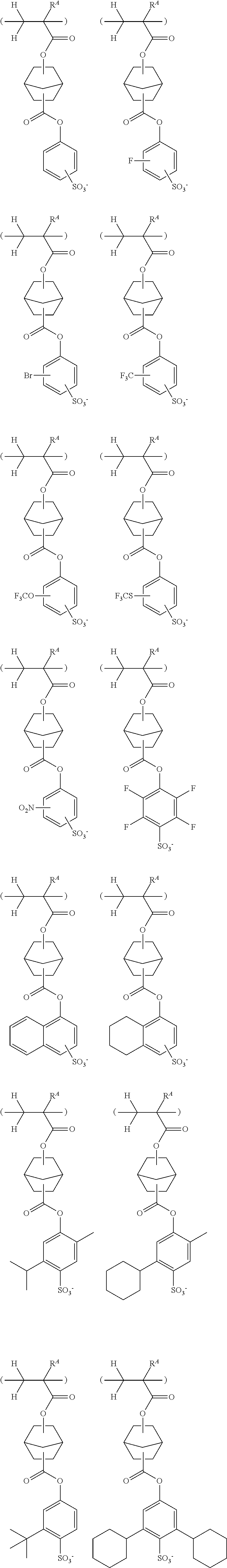

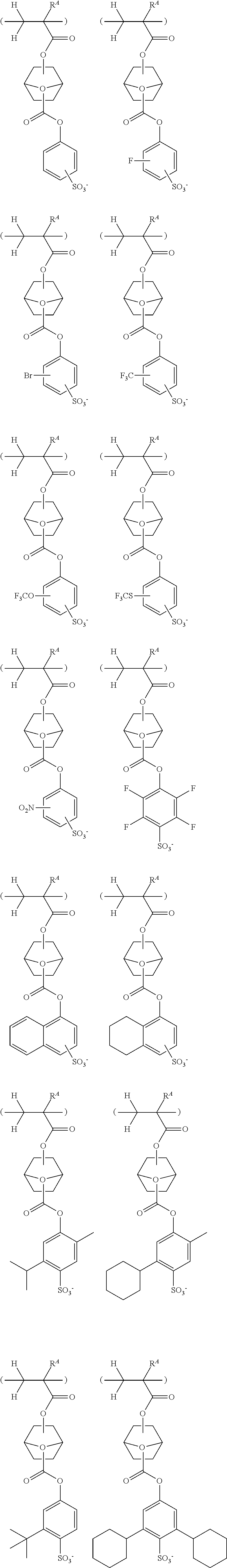

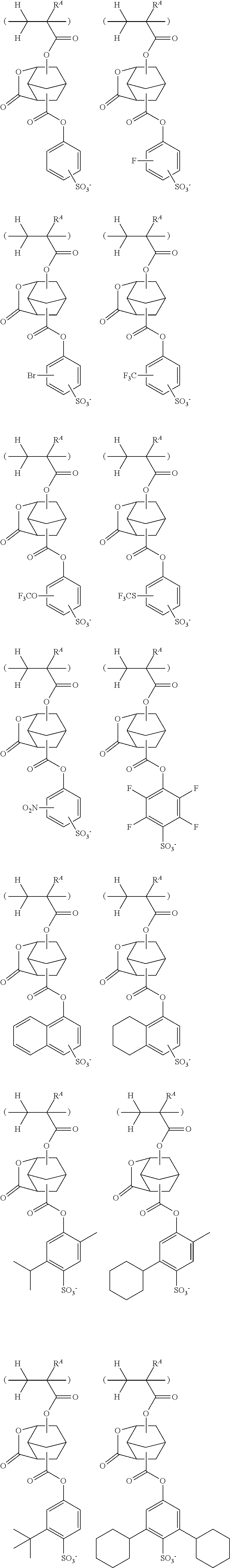

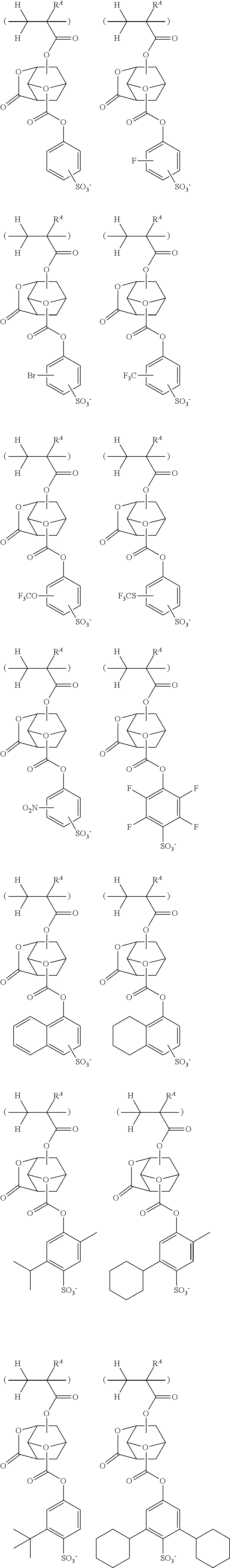

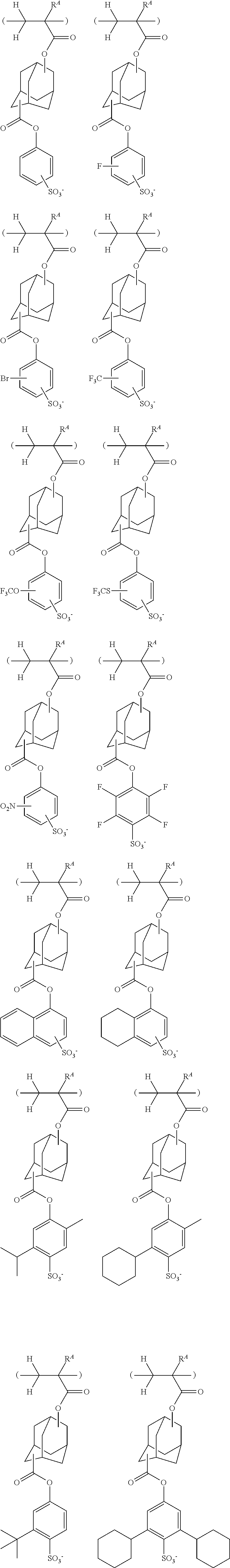

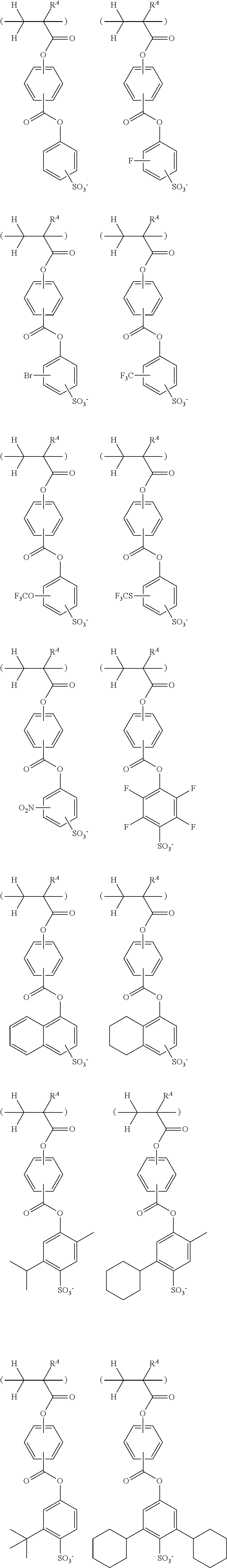

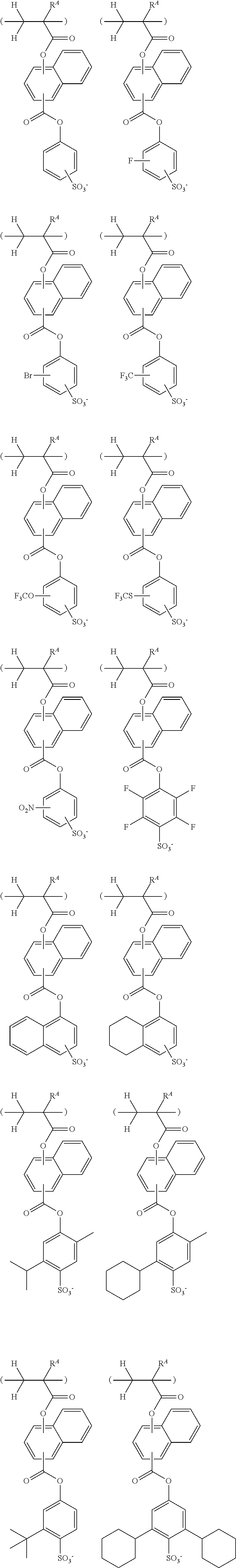

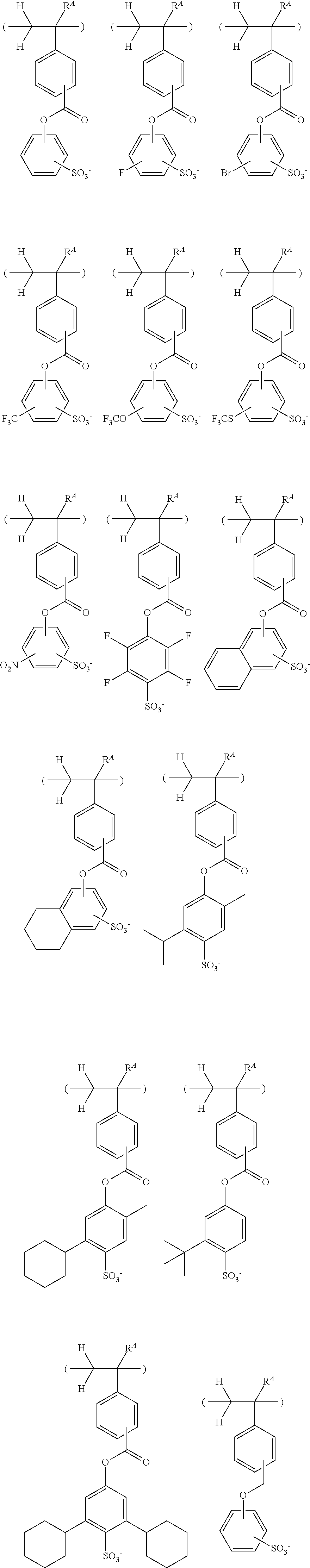

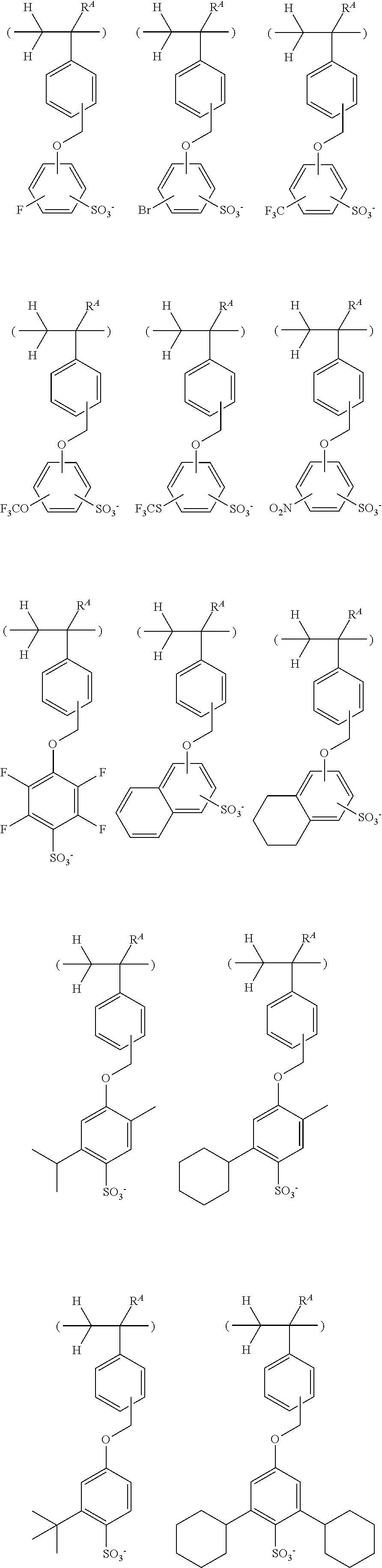

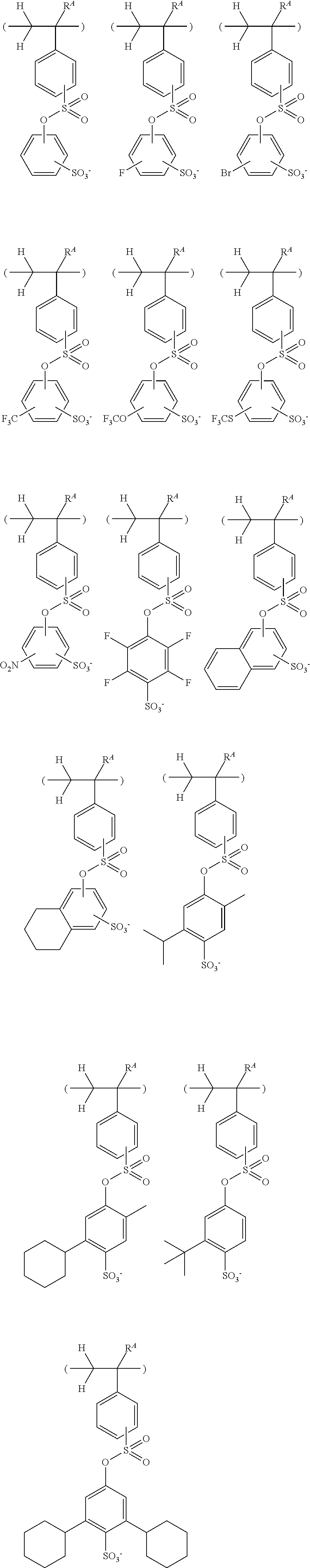

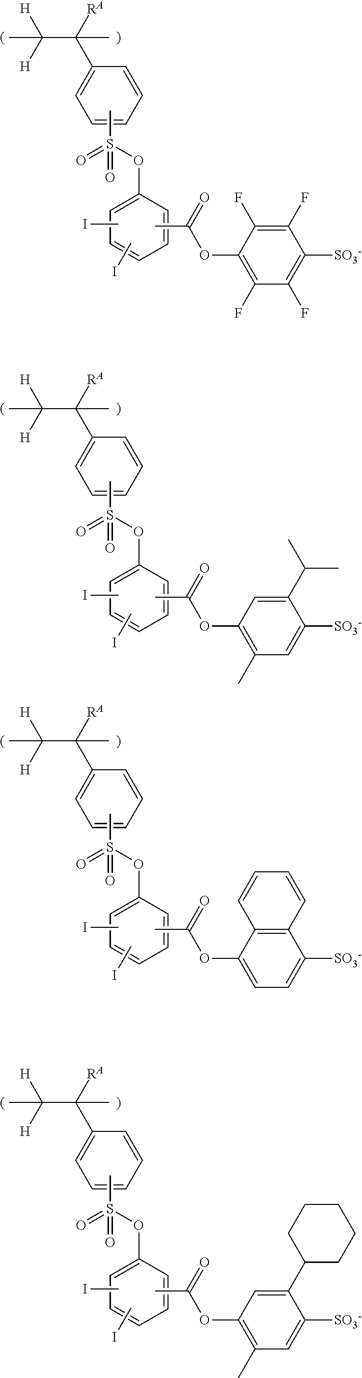

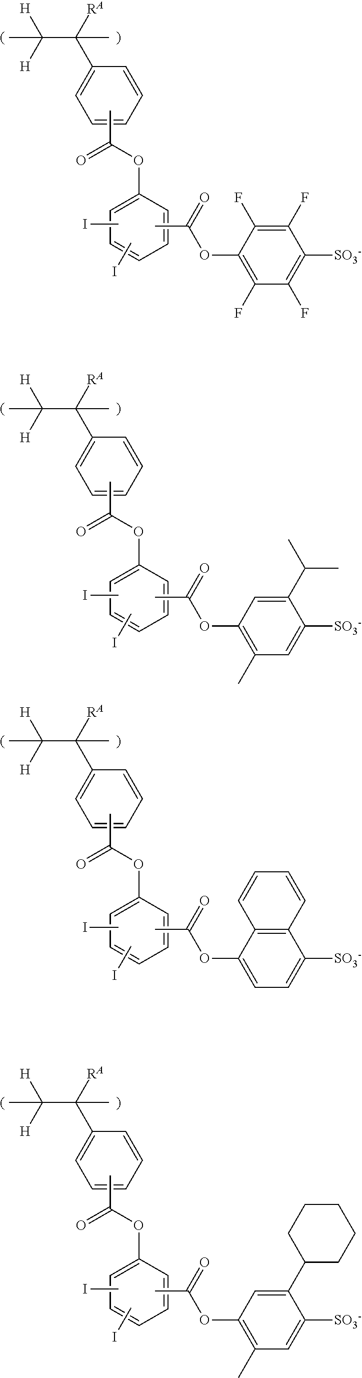

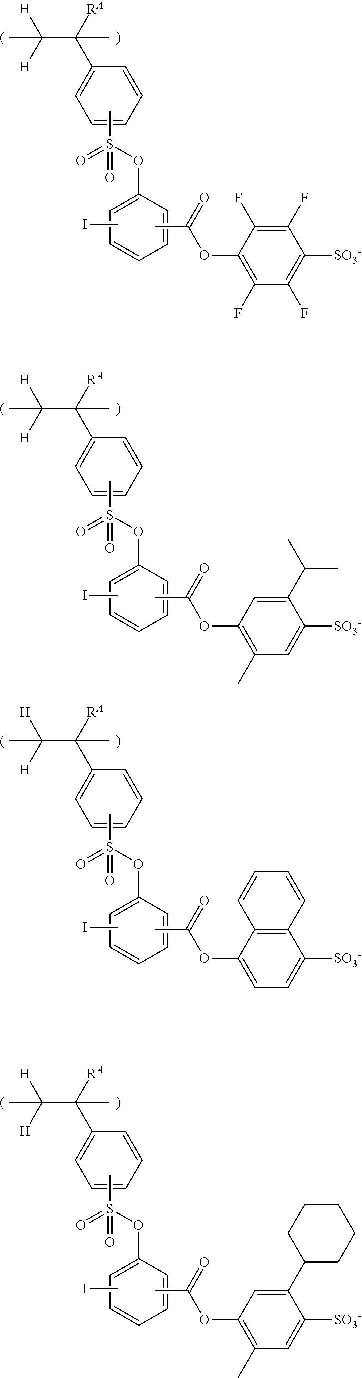

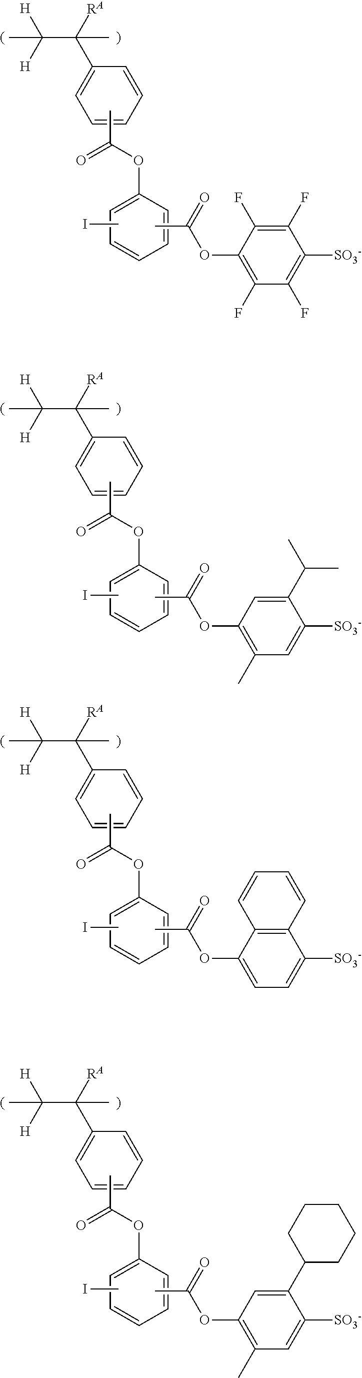

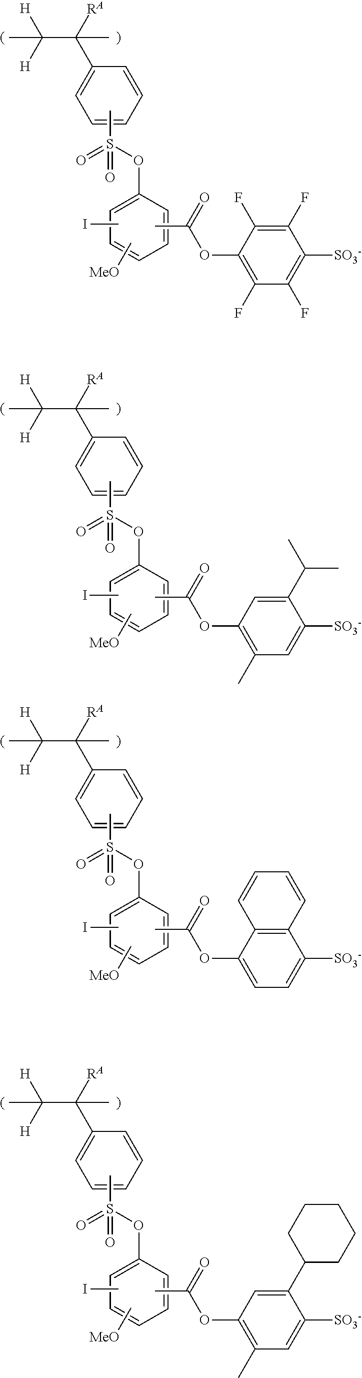

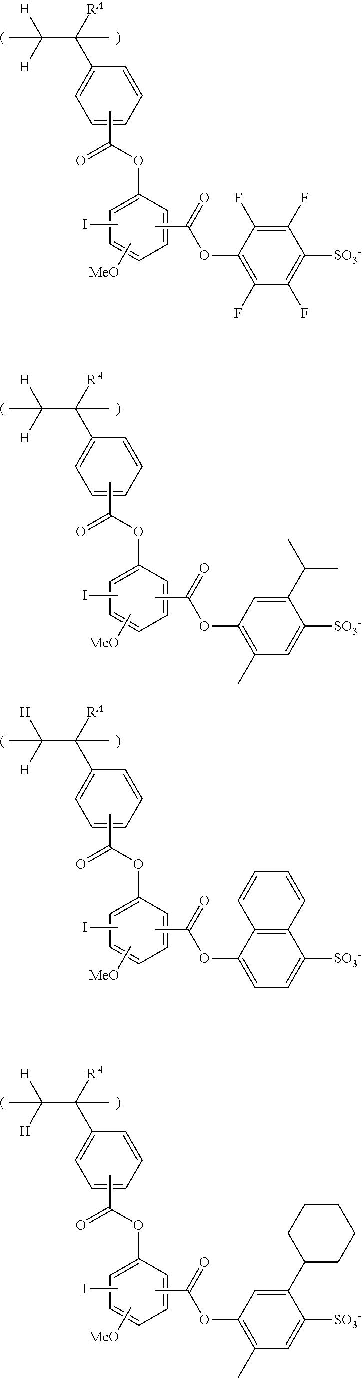

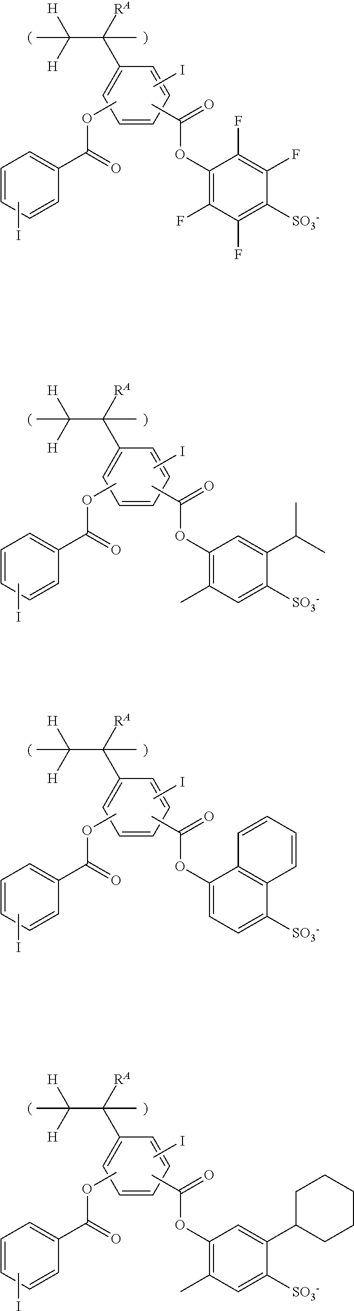

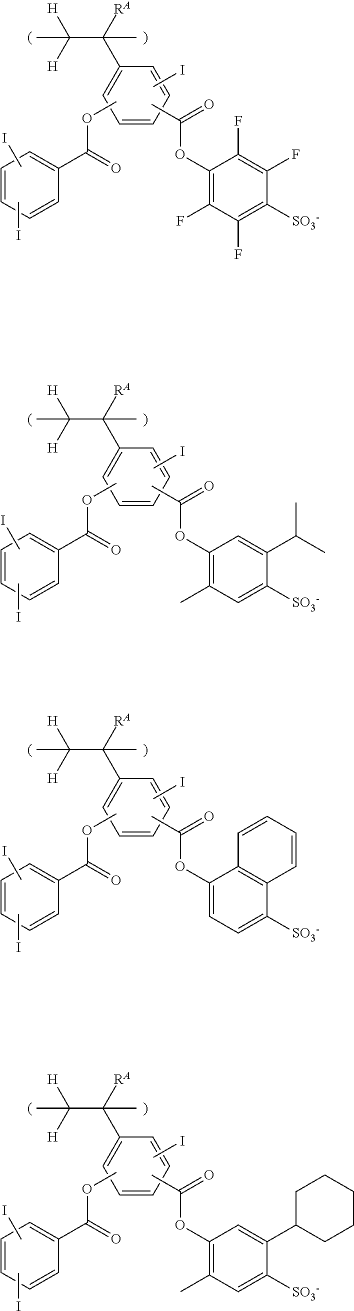

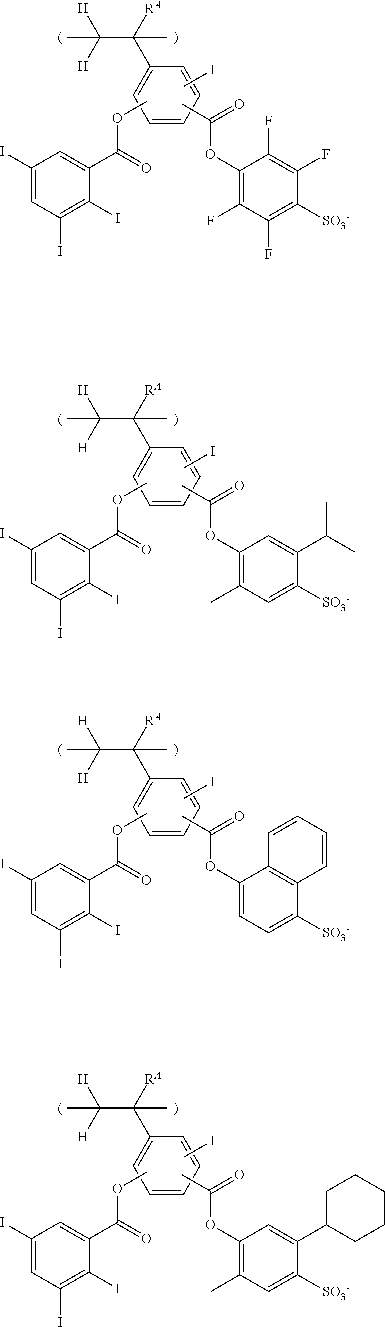

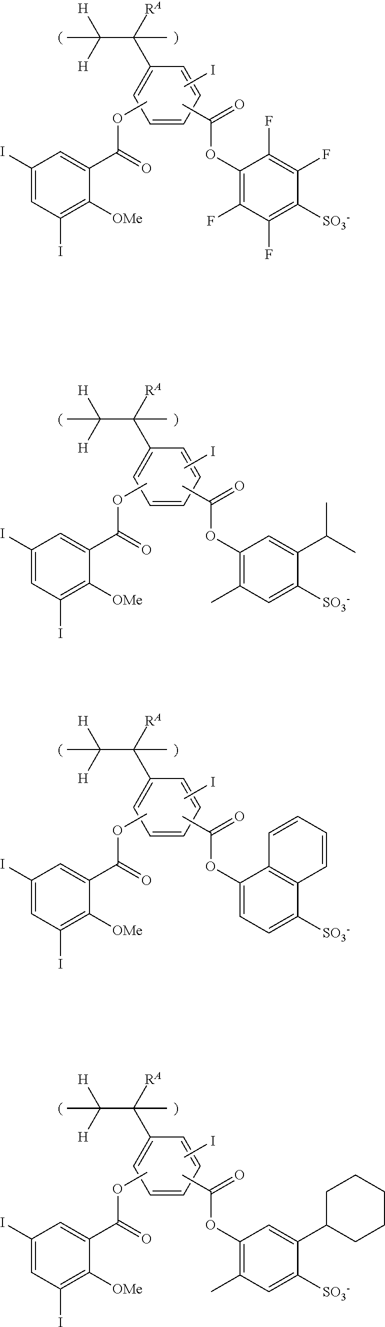

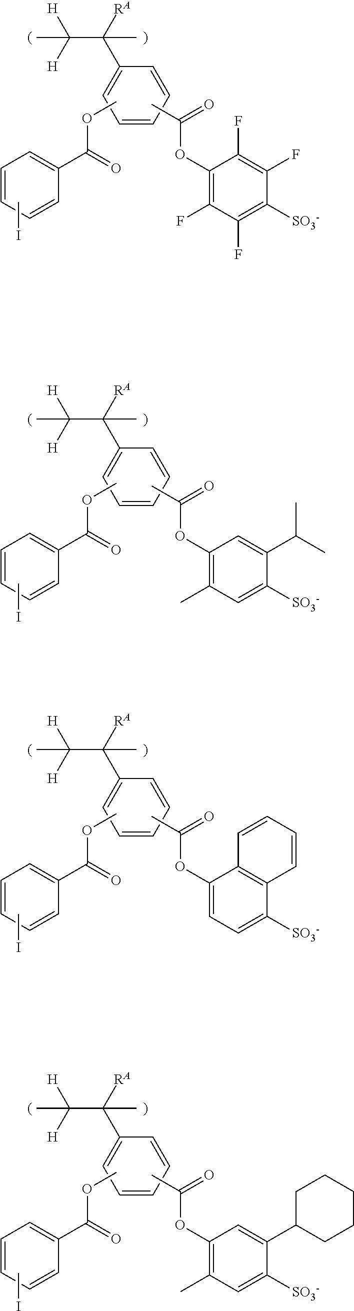

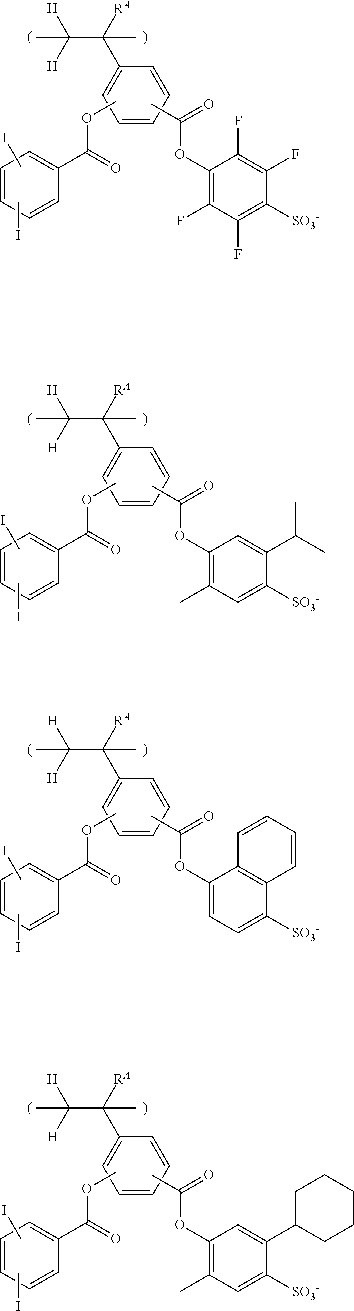

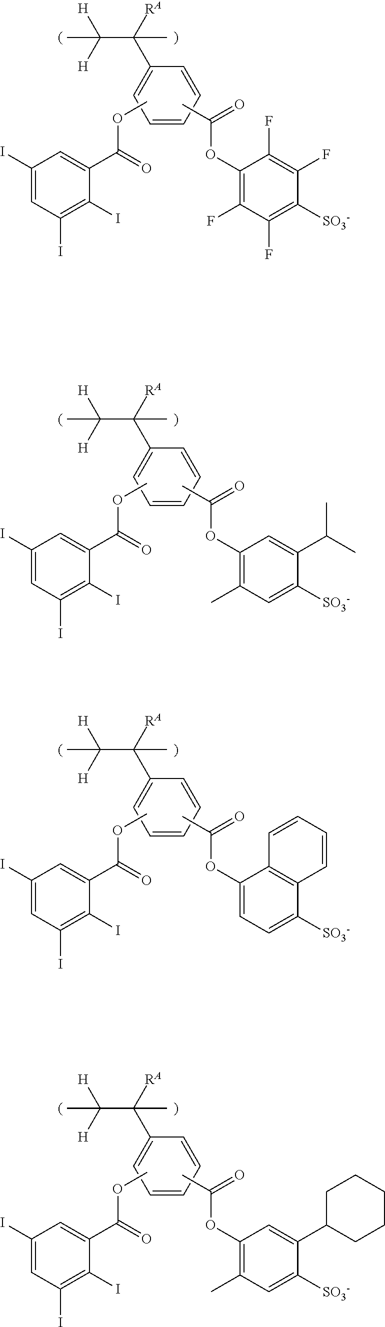

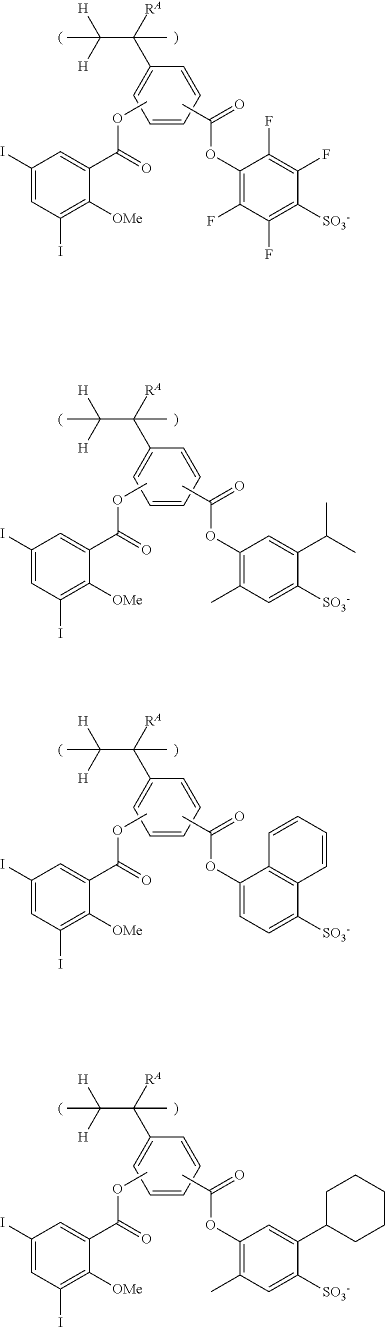

Other examples of the anion in repeat unit (c4) include those described in JP-A 2024-103464, paragraphs [0023]-[0026] and JP-A 2024-120702, paragraphs [0419]-[0420].

Examples of the anion in repeat unit (c5) are shown below, but not limited thereto. R^{A} is as defined above.

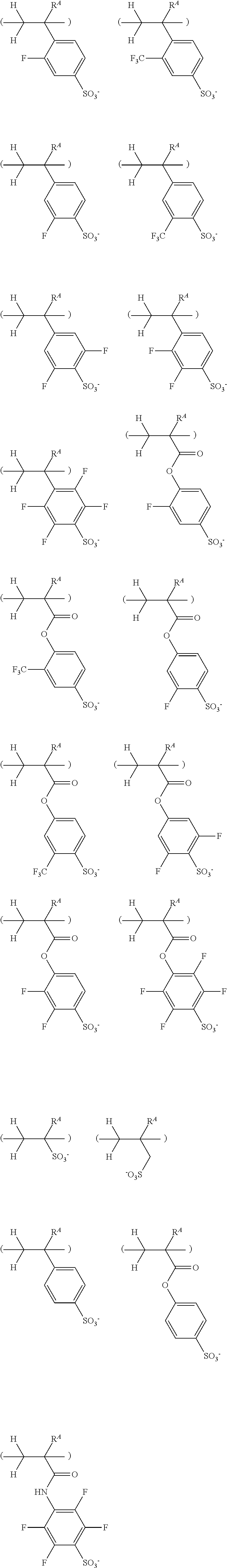

In formulae (c2) to (c5), A⁺ is an onium cation. Suitable onium cations include sulfonium, iodonium and ammonium cations, with the sulfonium and iodonium cations being preferred. Examples of the sulfonium cation include those described in JP-A 2024-003744, paragraphs [0102]-[0125], WO 2024/128017, paragraphs [0044]-[0049], and JP 7491173, paragraphs [0035]-[0046], but are not limited thereto.

A sulfonium cation having the formula (sulfo-1) is also preferred as the sulfonium cation.

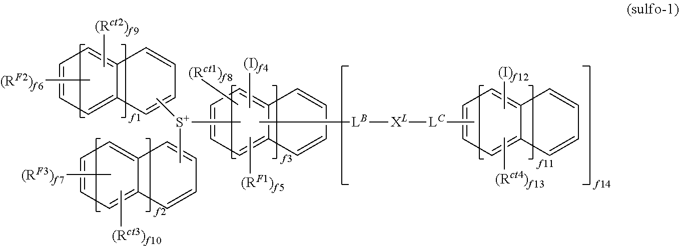

In formula (sulfo-1), f1 is 0 or 1. The relevant structure is a benzene ring when f1=0, and a naphthalene ring when f1=1. The benzene ring corresponding to f1=0 is preferred from the aspect of solvent solubility. The subscript f2 is 0 or 1. The relevant structure is a benzene ring when f2=0, and a naphthalene ring when f2=1. The benzene ring corresponding to f2=0 is preferred from the aspect of solvent solubility. The subscript f3 is 0 or 1. The relevant structure is a benzene ring when f3=0, and a naphthalene ring when f3=1. The benzene ring corresponding to f3=0 is preferred from the aspect of solvent solubility.

In formula (sulfo-1), f4 is 0, 1, 2, 3 or 4. As the number of iodine atoms in the cation structure increases, the compound becomes more absorptive to EUV, but so poor in solvent solubility that it may precipitate in a resist composition. For this reason, f4 is preferably 0, 1, 2 or 3, more preferably 0, 1 or 2.

In formula (sulfo-1), f5 is 0, 1, 2, 3 or 4. From the aspect of reactant availability, f5 is preferably 0, 1, 2 or 3, more preferably 0, 1 or 2. The subscript f6 is 0, 1, 2, 3, 4, 5 or 6. From the aspect of reactant availability, f6 is preferably 0, 1, 2 or 3, more preferably 0, 1 or 2. The subscript f7 is 0, 1, 2, 3, 4, 5 or 6. From the aspect of reactant availability, f7 is preferably 0, 1, 2 or 3, more preferably 0, 1 or 2.

In formula (sulfo-1), f8 is 0, 1 or 2. From the aspect of reactant availability, f8 is preferably 0 or 1. The subscript f9 is 0, 1 or 2. From the aspect of reactant availability, f9 is preferably 0 or 1. The subscript f10 is 0, 1 or 2. From the aspect of reactant availability, f10 is preferably 0 or 1.

In formula (sulfo-1), f11 is 0 or 1. The relevant structure is a benzene ring when f11=0, and a naphthalene ring when f11=1. The benzene ring corresponding to f11=0 is preferred from the aspect of solvent solubility.

In formula (sulfo-1), f12 is 0, 1, 2, 3 or 4. As the number of iodine atoms in the cation structure increases, the compound becomes more absorptive to EUV, but so poor in solvent solubility that it may precipitate in a resist composition. For this reason, f12 is preferably 0, 1, 2 or 3, more preferably 0, 1 or 2.

In formula (sulfo-1), f13 is 0, 1 or 2. From the aspect of reactant availability, f13 is preferably 0 or 1. The subscript f14 is 0, 1 or 2. From the aspect of synthesis, f14 is preferably 0 or 1.

The subscripts f1 to f14 are in the range: 0≤f6+f9≤4 when f1=0, 0≤f6+f9≤6 when f1=1; 0≤f7+f10≤4 when f2=0, 0≤f7+f10≤6 when f2=1; 1≤f4+f5+f8+f14≤4 when f3=0, 1≤f4+f5+f8+f14≤6 when f3=1; 0≤f12+f13≤4 when f11=0, 0≤f12+f13≤6 when f11=1; and f4+f12≥1.

In formula (sulfo-1), R^{F1} to R^{F3} are each independently fluorine, a C₁-C₆ fluorinated saturated hydrocarbyl group, C₁-C₆ fluorinated saturated hydrocarbyloxy group, or C₁-C₆ fluorinated saturated hydrocarbylthio group. Of these, trifluoromethyl, trifluoromethoxy, and trifluorothiomethoxy are preferred. A plurality of R^{F}1 may be identical or different when f5 is 2, 3 or 4, a plurality of R^{F2} may be identical or different when f6 is 2, 3, 4, 5 or 6, and a plurality of R^{F3} may be identical or different when f7 is 2, 3, 4, 5 or 6.

In formula (sulfo-1), R^{ct1} to R^{ct4} are each independently halogen exclusive of iodine and fluorine, nitro, cyano, a C₁-C₂₀ hydrocarbyl group which may contain a heteroatom, C₁-C₂₀ hydrocarbyloxy group which may contain a heteroatom, or C₁-C₂₀ hydrocarbylthio group which may contain a heteroatom. The hydrocarbyl group and hydrocarbyl moiety in the hydrocarbyloxy and hydrocarbylthio groups may be saturated or unsaturated and straight, branched or cyclic. Examples thereof are as exemplified above for the hydrocarbyl group R¹ and R² in formula (A). In the hydrocarbyl group and hydrocarbyl moiety in the hydrocarbyloxy and hydrocarbylthio groups, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy moiety, cyano moiety, fluorine, chlorine, bromine, iodine, carbonyl moiety, ether bond, ester bond, sulfonate ester bond, carbonate bond, lactone ring, sultone ring, carboxylic anhydride (—C(═O)—O—C(═O)—) or haloalkyl moiety.

When f8=2, two R^{ct1} may be identical or different and two R^{ct1} may bond together to form a ring with the carbon atoms to which they are attached. When f9=2, two R^{ct2} may be identical or different and two R^{ct2} may bond together to form a ring with the carbon atoms to which they are attached. When f10=2, two R^{ct3} may be identical or different and two R^{ct3} may bond together to form a ring with the carbon atoms to which they are attached. When f13=2, two R^{ct4} may be identical or different and two R^{ct4} may bond together to form a ring with the carbon atoms to which they are attached. Examples of the ring thus formed include cyclopropane, cyclobutane, cyclopentane, cyclohexane, norbornane, and adamantane rings. In the ring, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the ring may contain a hydroxy moiety, fluorine, chlorine, bromine, iodine, cyano moiety, carbonyl moiety, ether bond, ester bond, sulfonate ester bond, carbonate bond, lactone ring, sultone ring, carboxylic anhydride (—C(═O)—O—C(═O)—) or haloalkyl moiety.

The aromatic rings directly bonded to S⁺ in the sulfonium cation having formula (sulfo-1) may bond together to form a ring with S⁺. Exemplary structures of the ring are shown below.

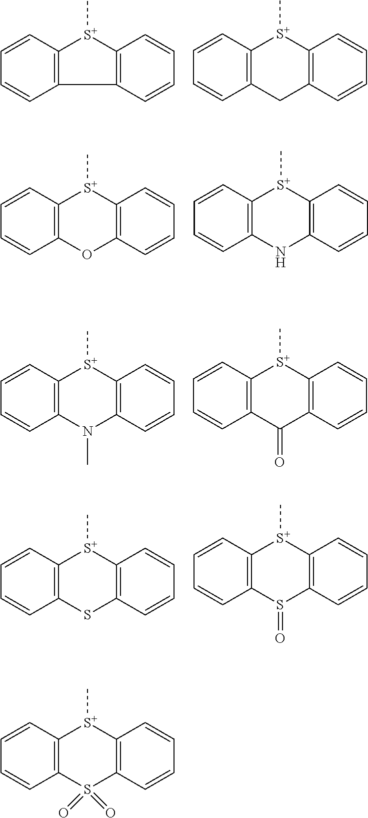

In formula (sulfo-1), L^{B} and L^{C} are each independently a single bond, ether bond, ester bond, sulfonate ester bond, amide bond, sulfonamide bond, carbonate bond or carbamate bond. L^{B} is preferably a single bond, ether bond, ester bond or sulfonate ester bond, more preferably an ester bond or sulfonate ester bond. L^{C} is preferably a single bond, ether bond or ester bond, more preferably a single bond.

In formula (sulfo-1), X^{L} is a single bond or a C₁-C₄₀ hydrocarbylene group which may contain a heteroatom. The C₁-C₄₀ hydrocarbylene group may be straight, branched or cyclic. Suitable hydrocarbylene groups include alkanediyl, cyclic saturated hydrocarbylene and arylene groups. Suitable heteroatoms include oxygen, nitrogen and sulfur atoms.

Examples of the optionally heteroatom-containing C₁-C₄₀ hydrocarbylene group X^{L} are shown below, but not limited thereto. Herein * each designates a point of attachment to L^{B} or L^{C}.

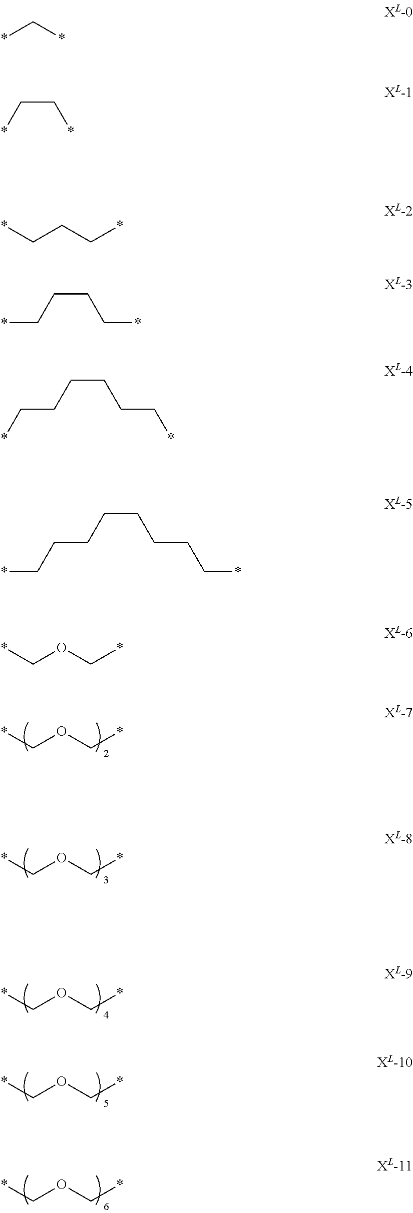

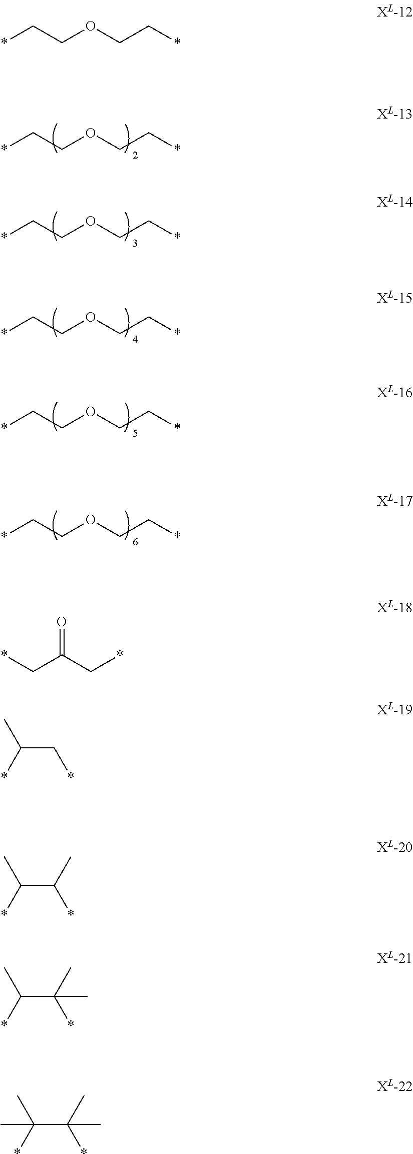

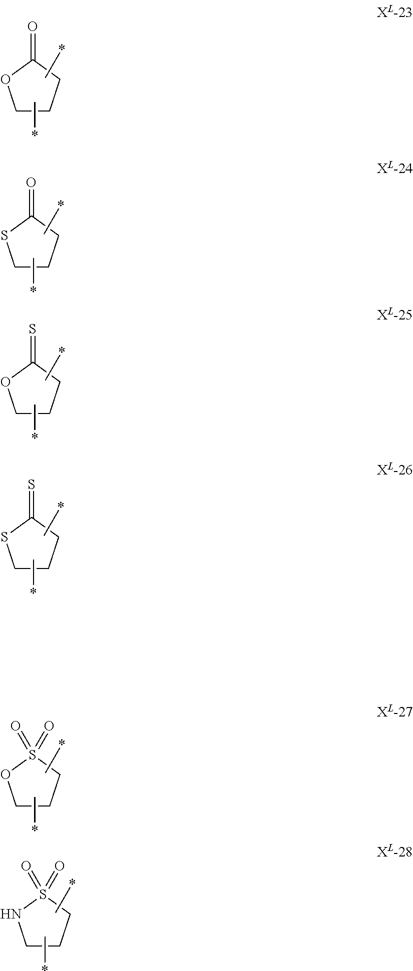

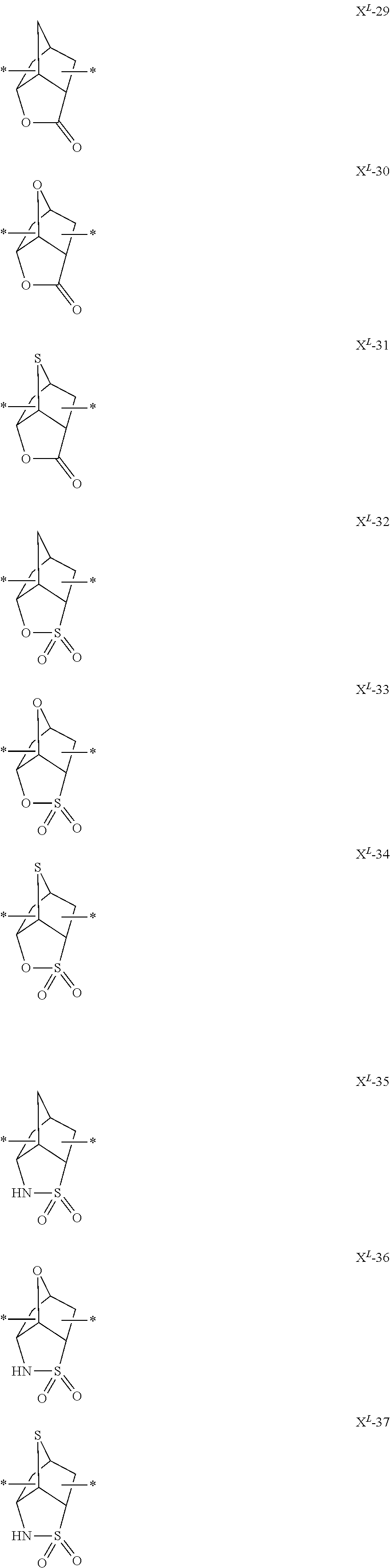

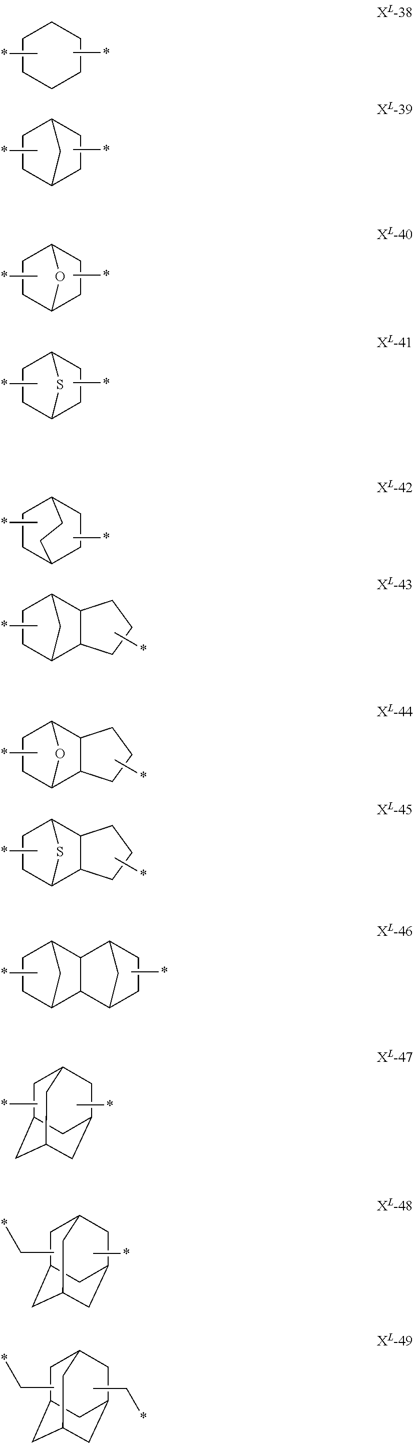

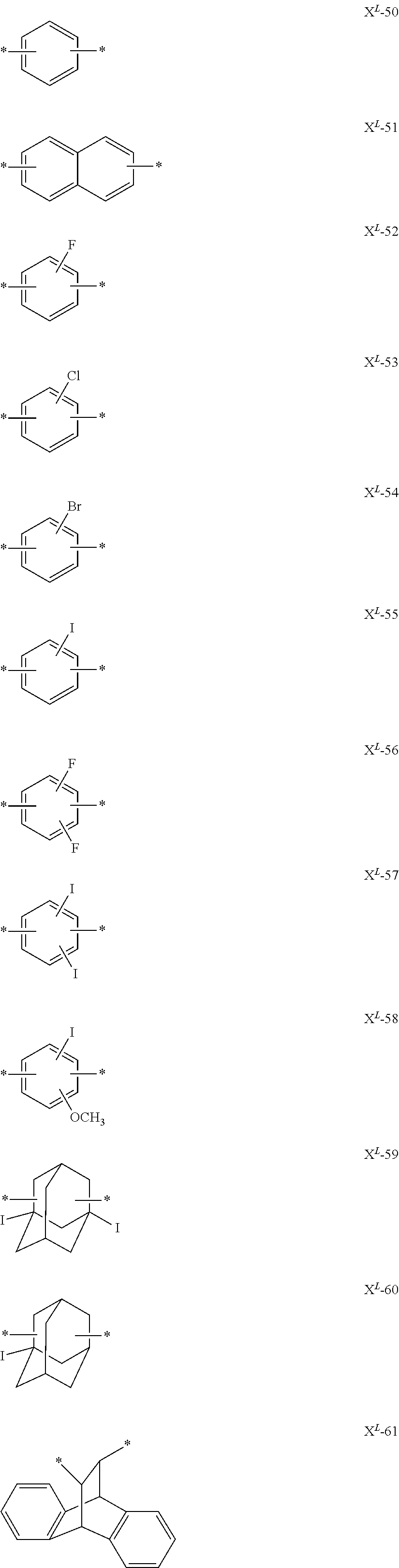

Of these, X^{L}-0 to X^{L}-22, X^{L}-29 to X^{L}-34, and X^{L}-47 to X^{L}-61 are preferred.

Of the sulfonium cations having formula (sulfo-1), those cations having the formula (sulfo-1-1):

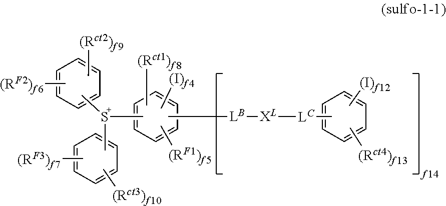

wherein f4 to f10, f12 to f14, R^{F1} to R^{F3}, R^{ct1} to R^{ct4}, L^{B}, L^{C}, and X^{L} are as defined above are preferred.

Of the sulfonium cations having formula (sulfo-1-1), those cations having the formula (sulfo-1-2):

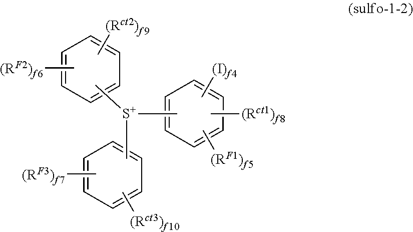

wherein f4 to f10, R^{F1} to R^{F3}, and R^{ct1} to R^{ct3} are as defined above are more preferred.

Examples of the sulfonium cation having formula (sulfo-1) are shown below, but not limited thereto.

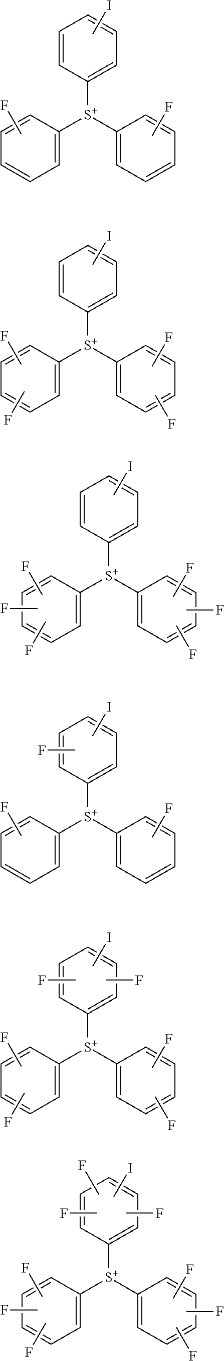

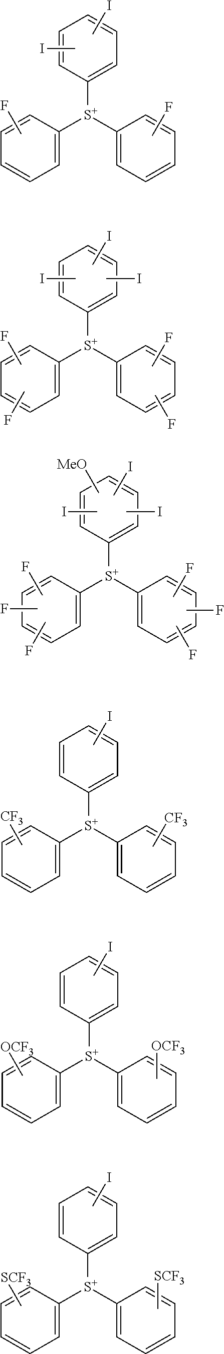

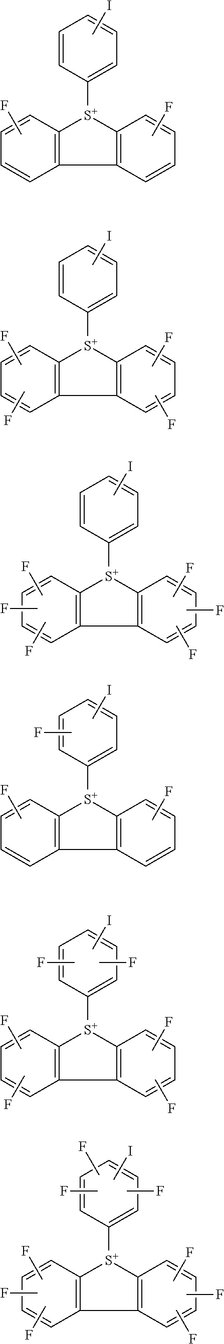

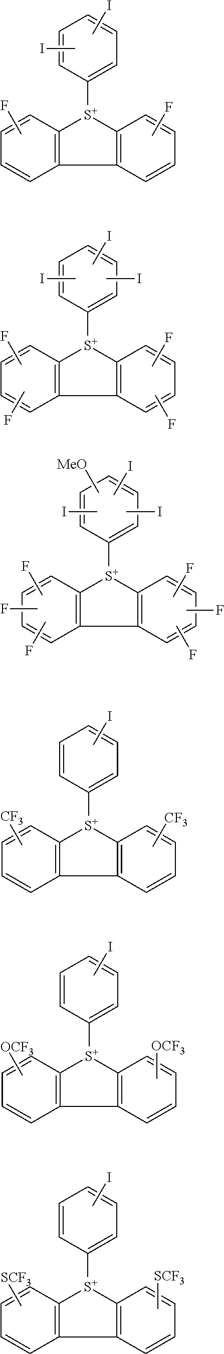

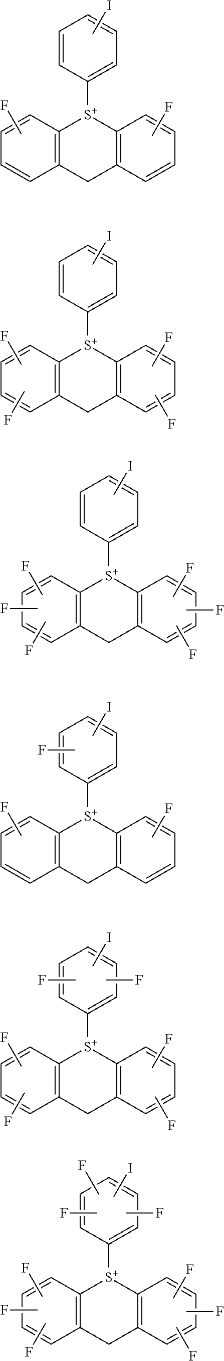

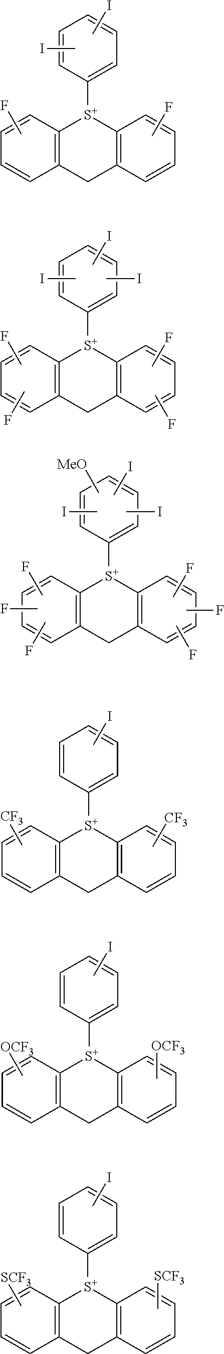

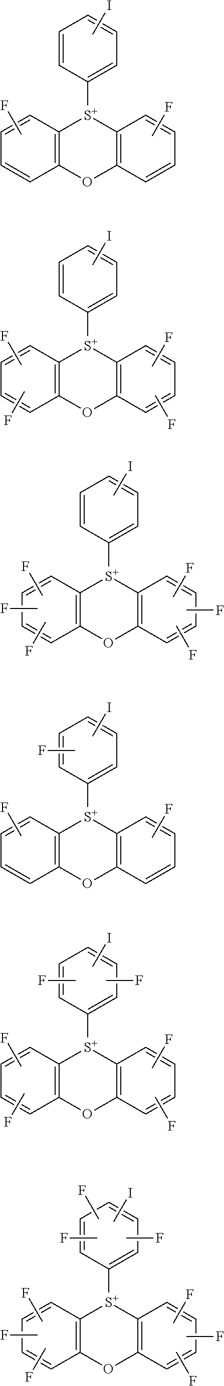

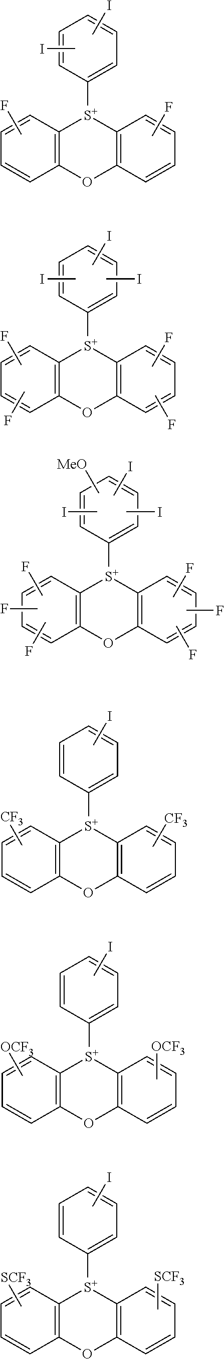

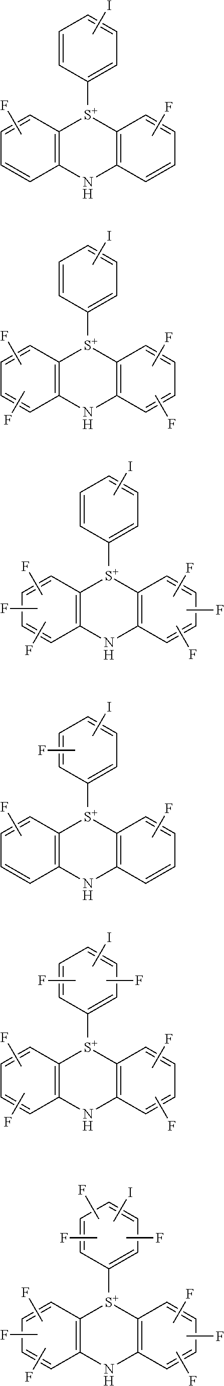

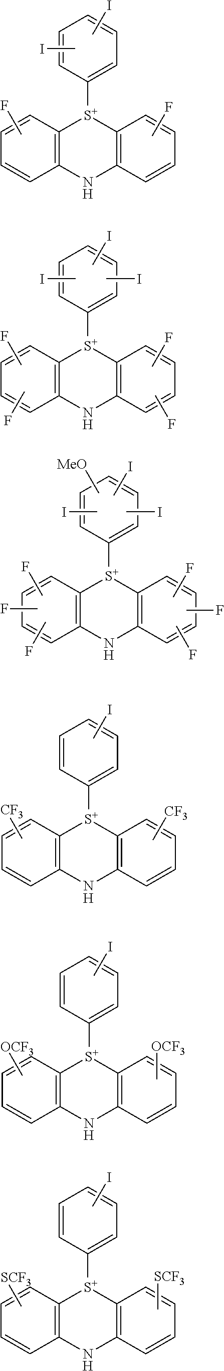

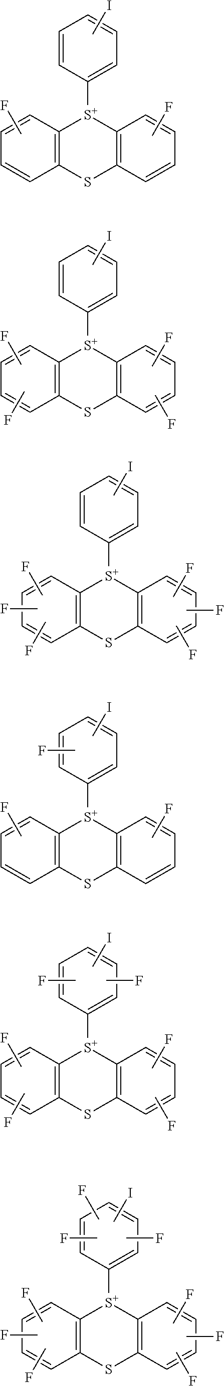

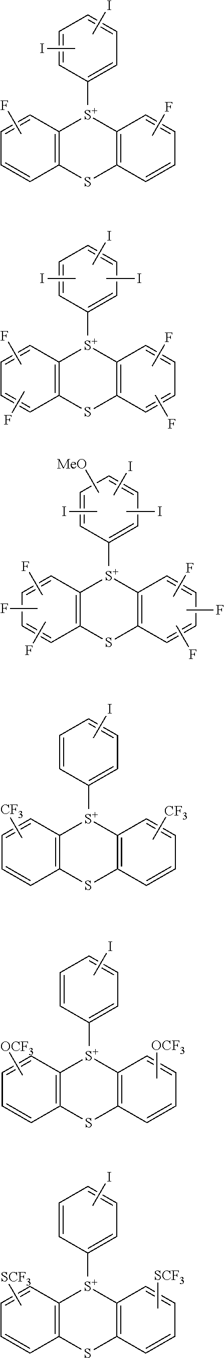

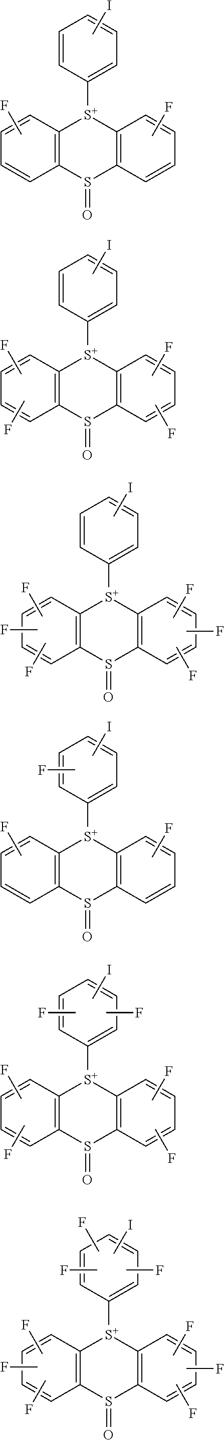

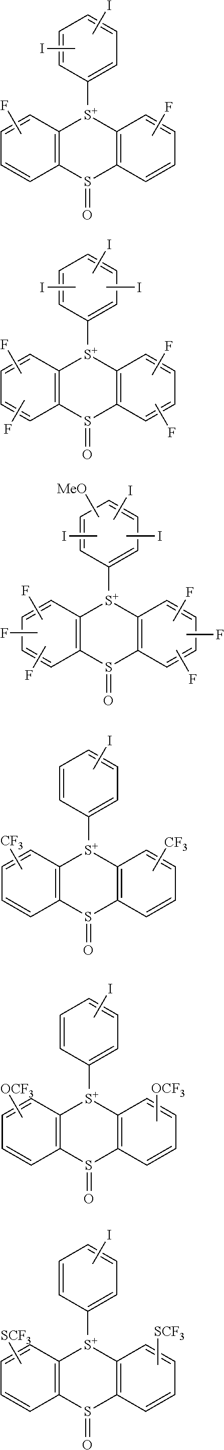

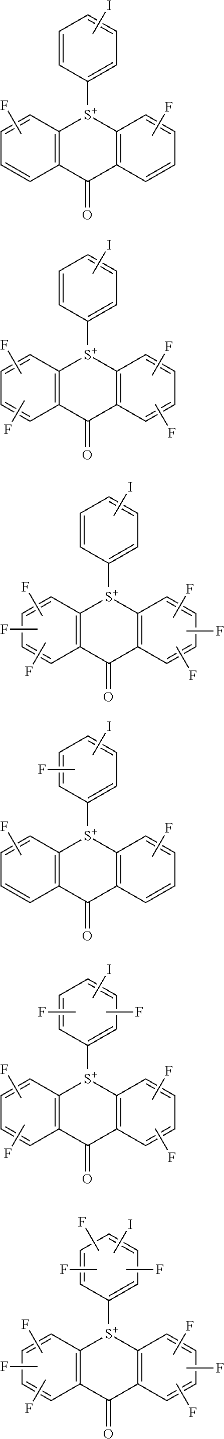

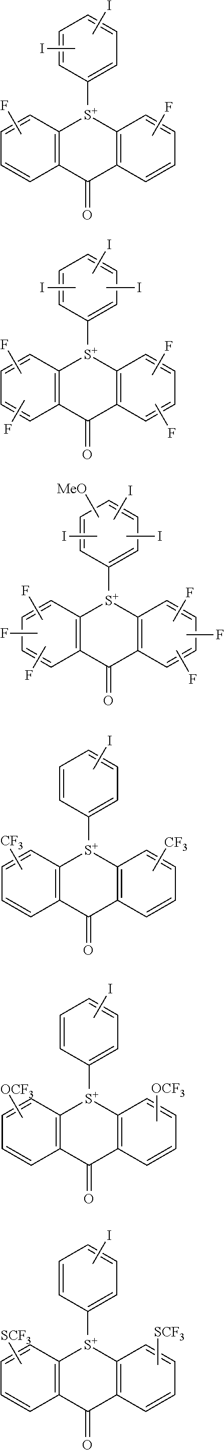

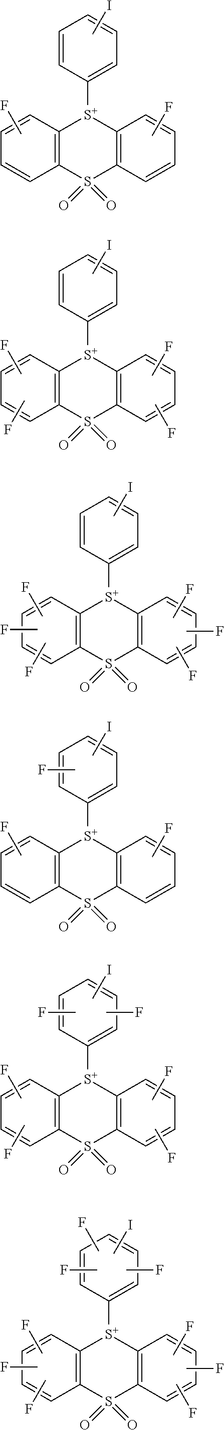

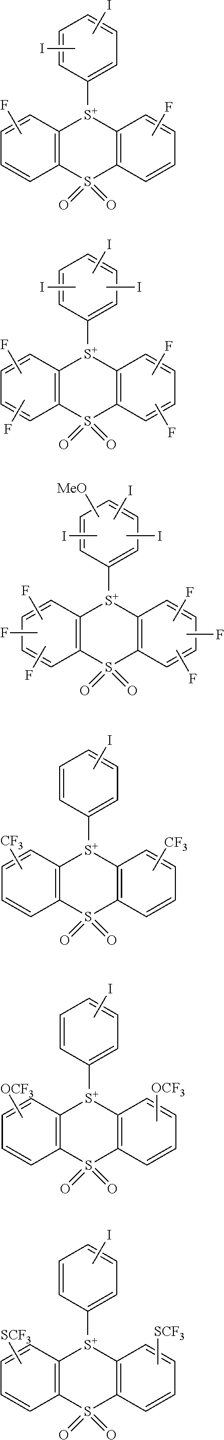

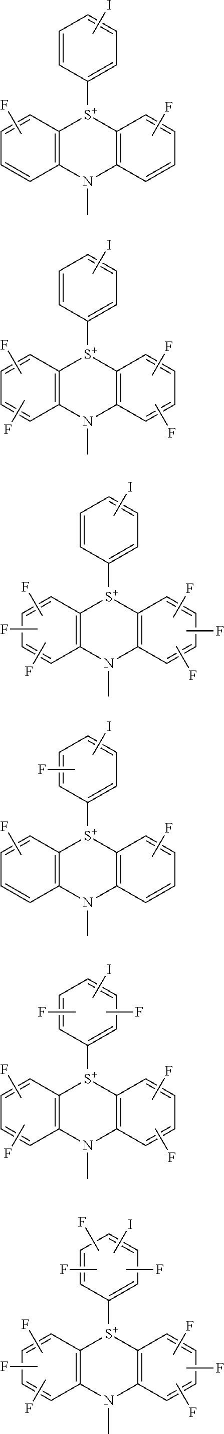

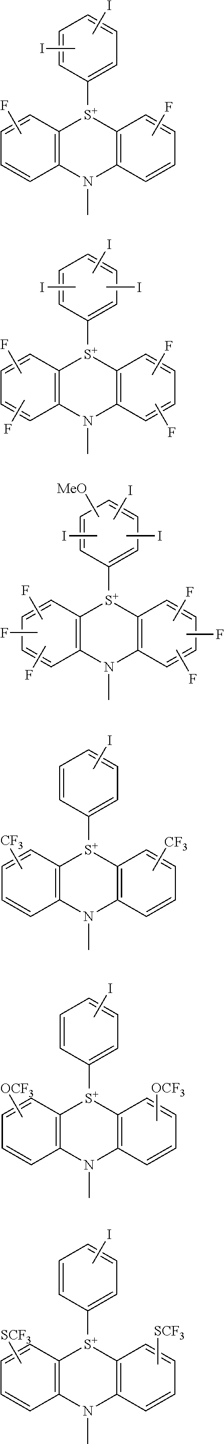

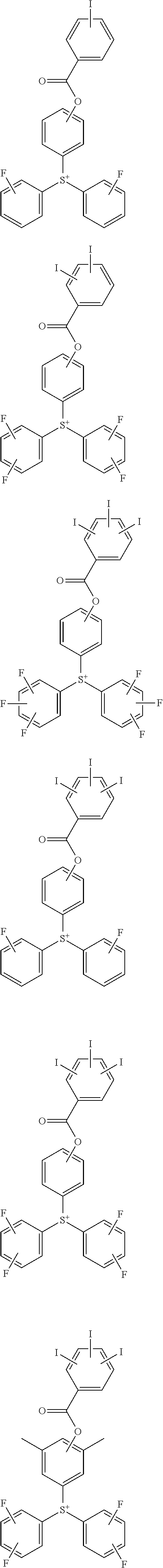

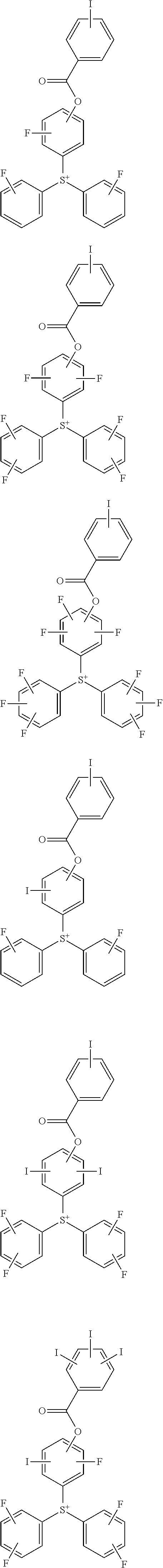

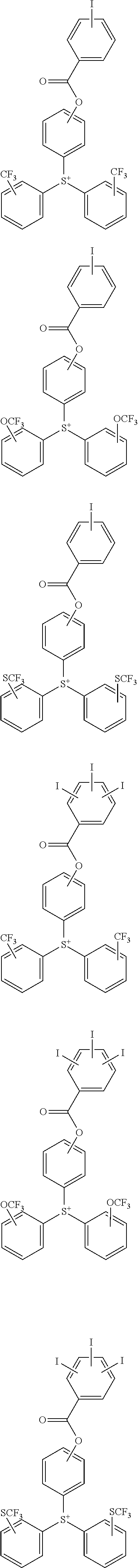

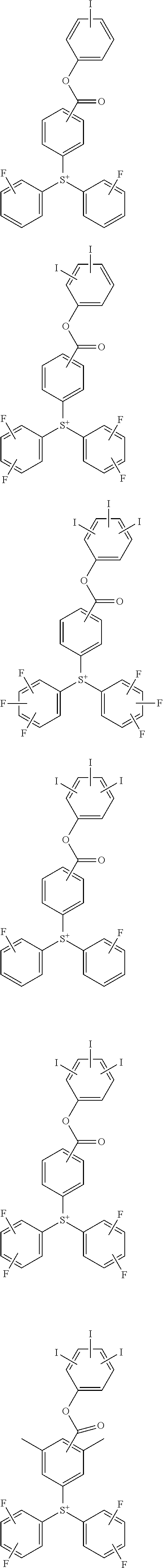

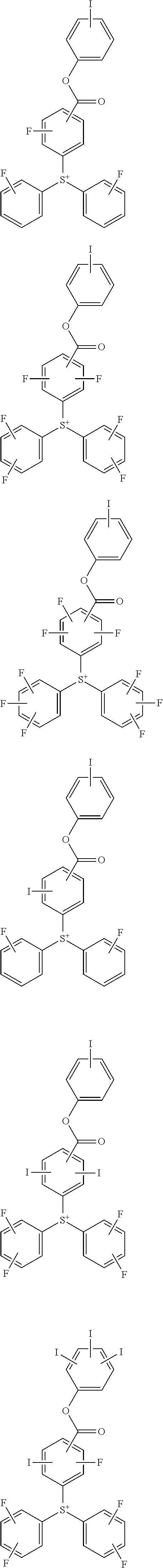

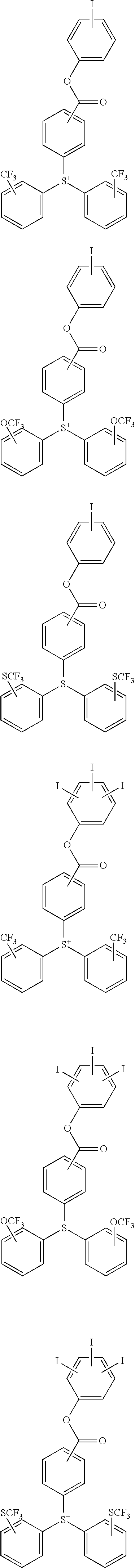

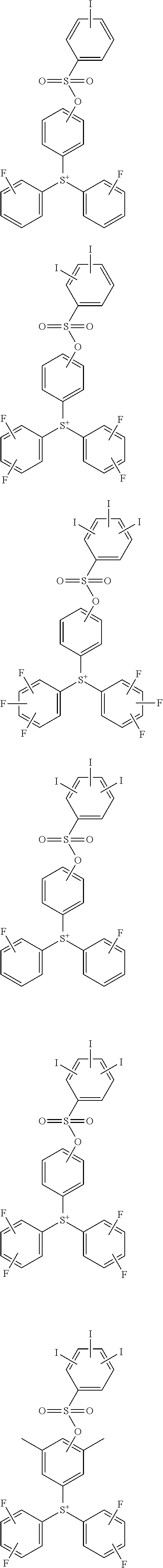

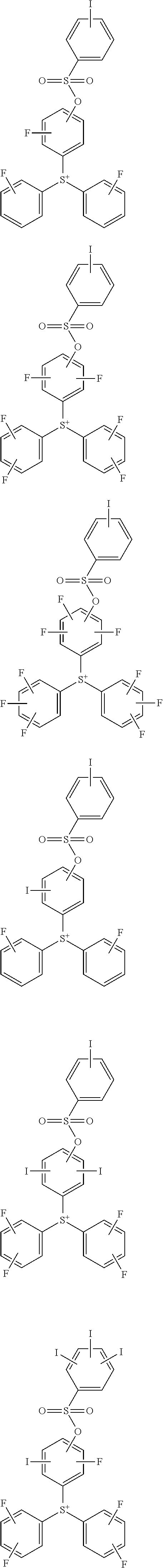

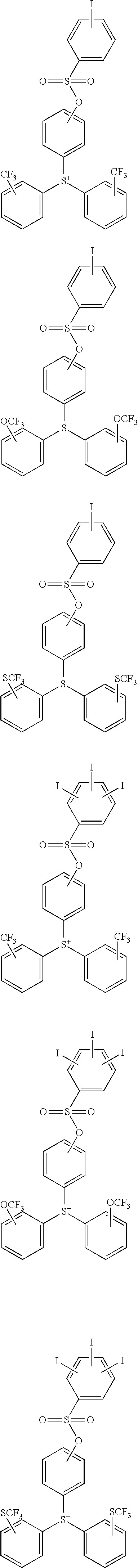

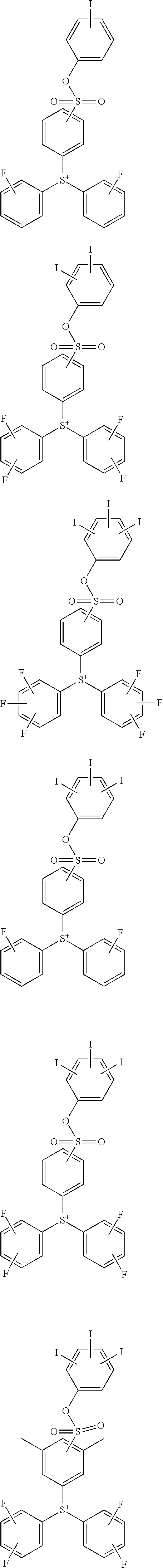

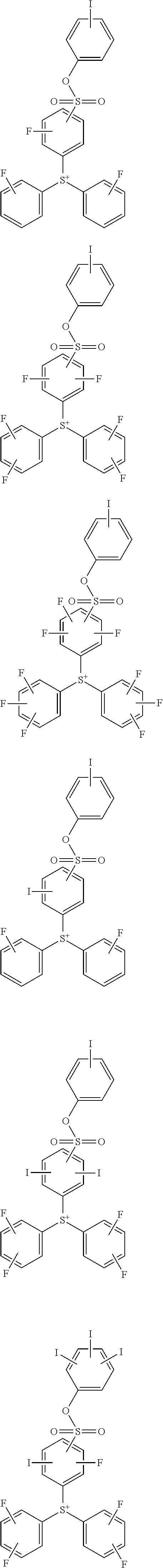

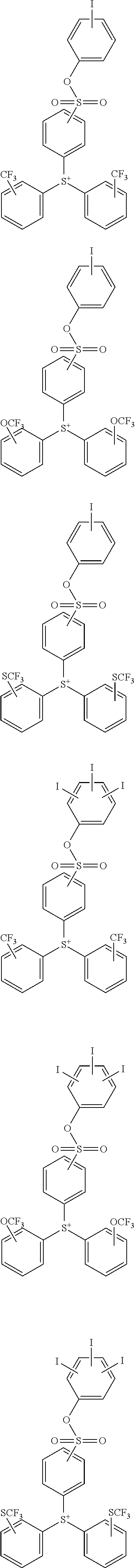

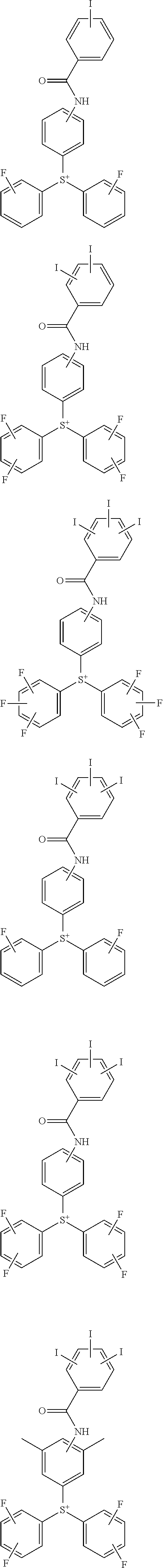

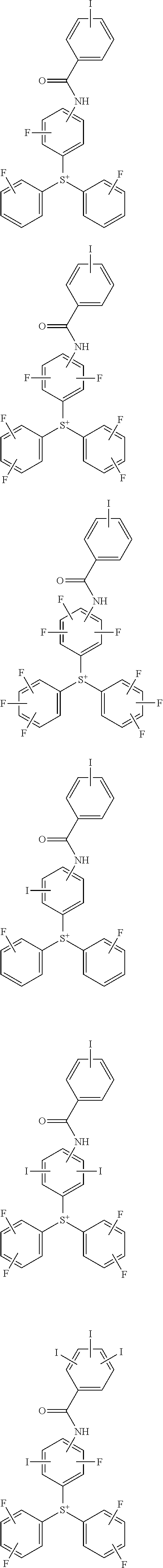

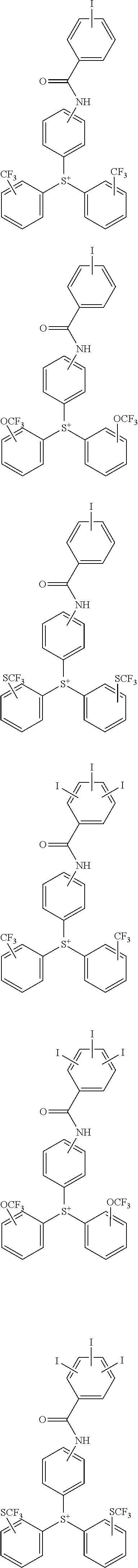

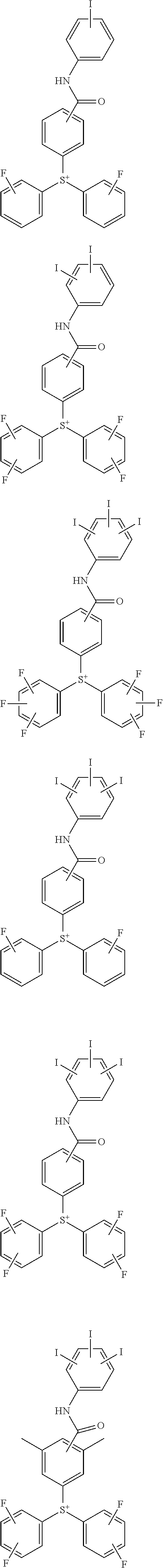

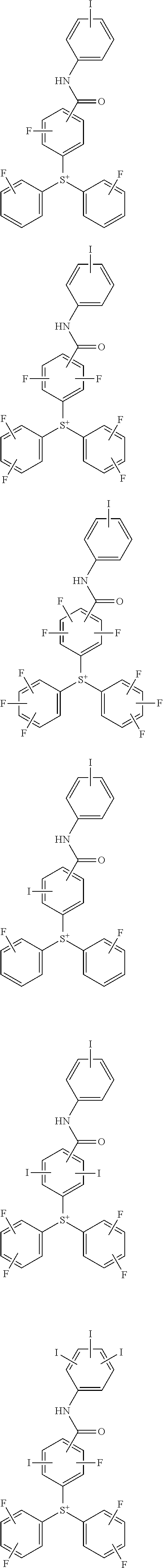

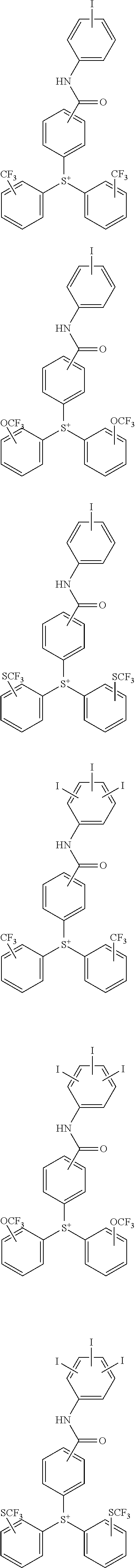

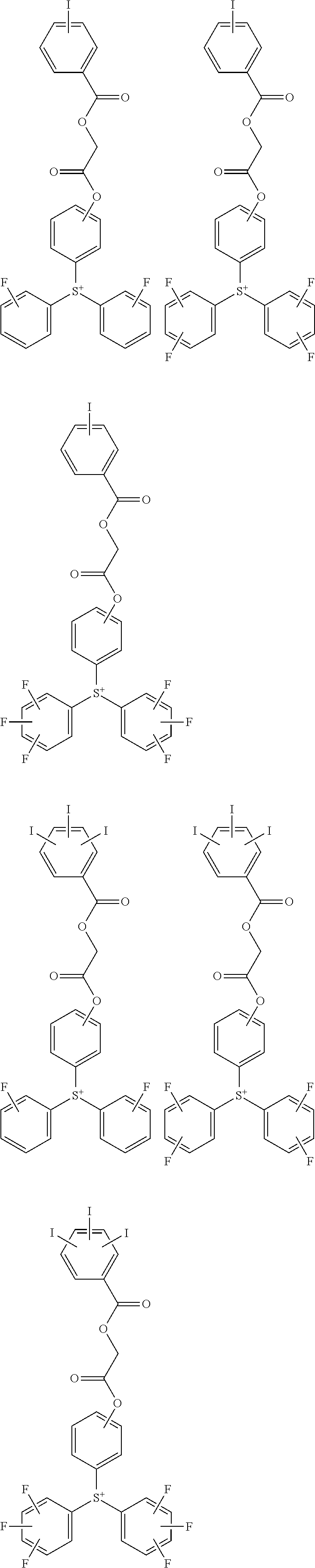

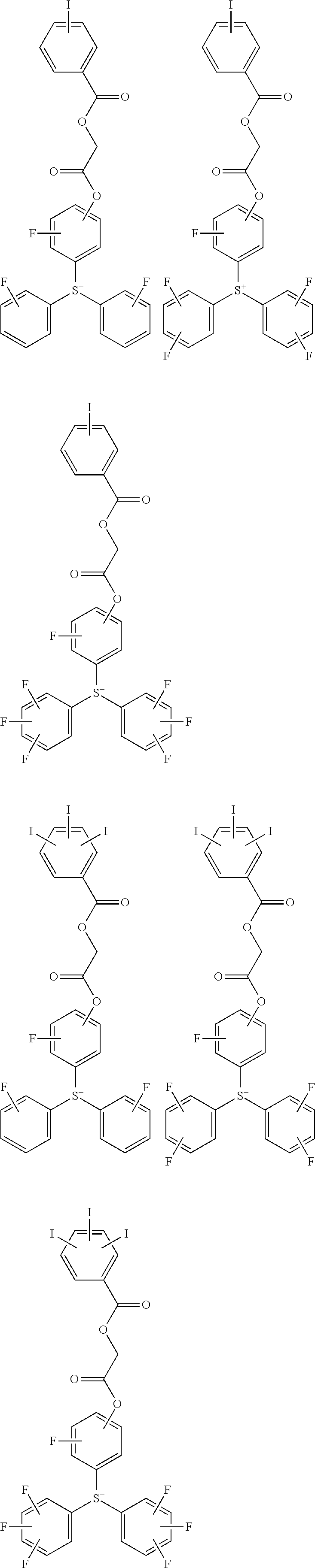

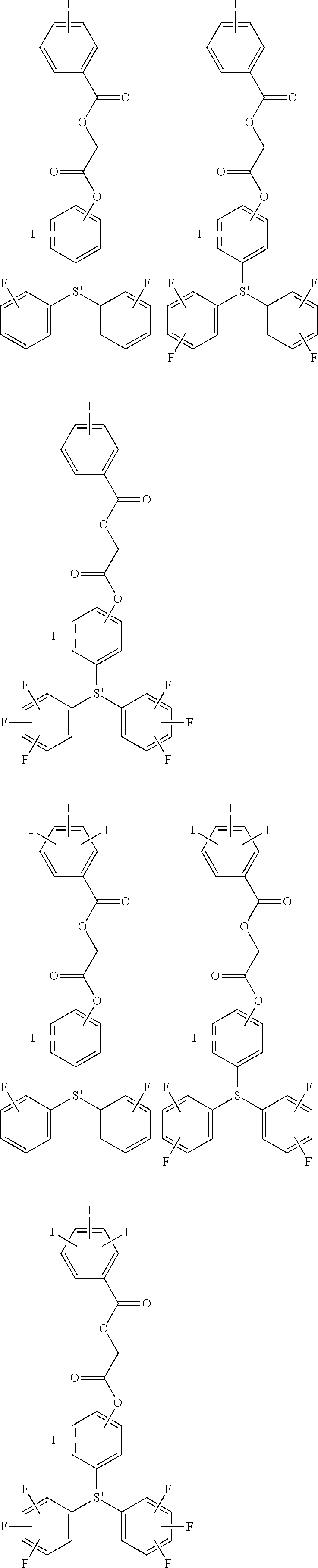

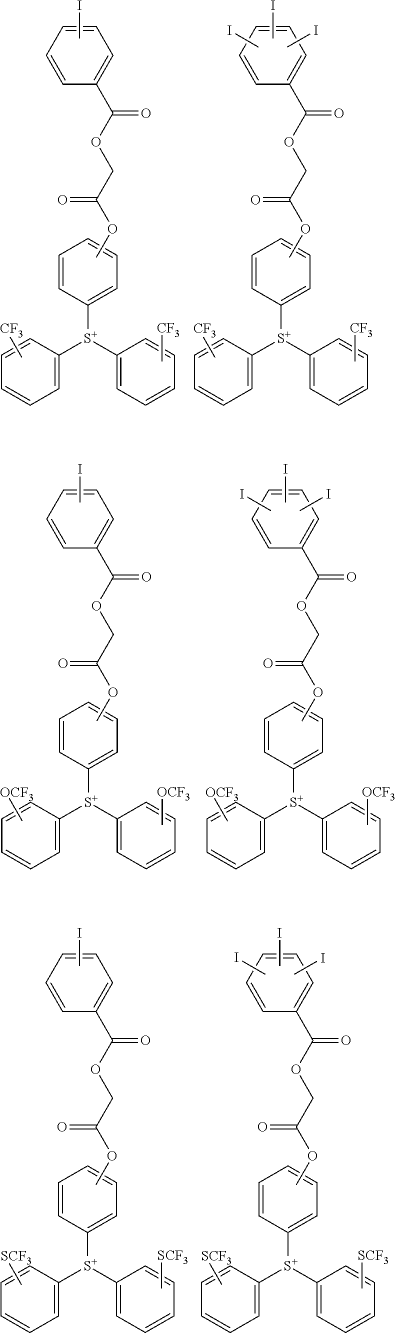

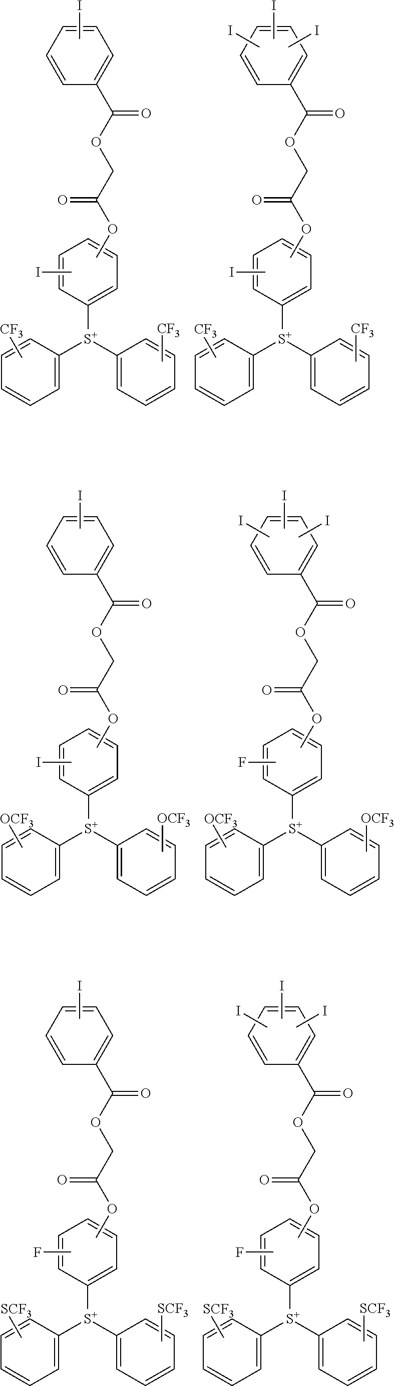

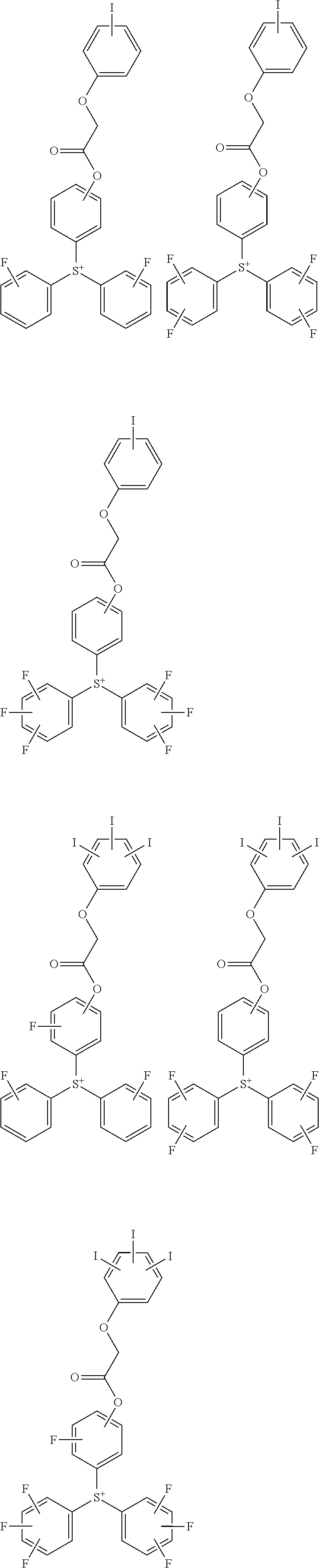

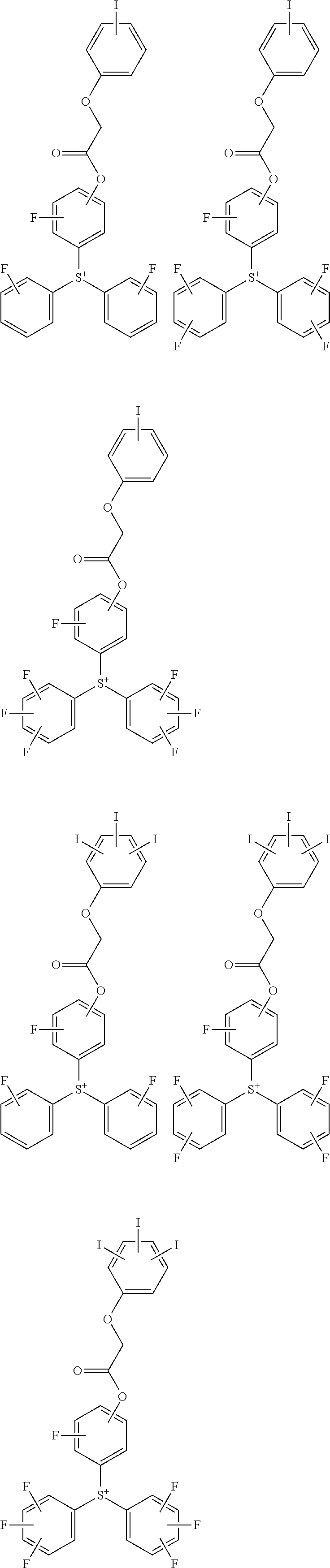

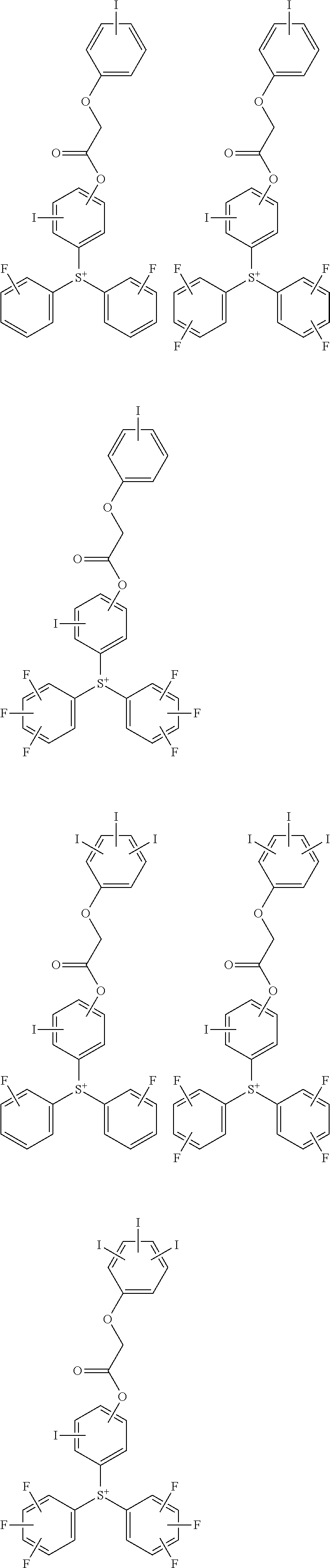

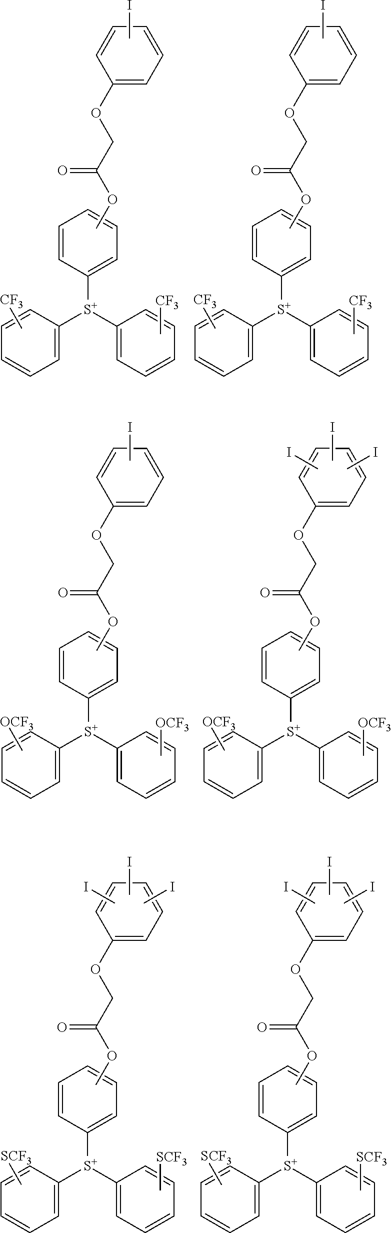

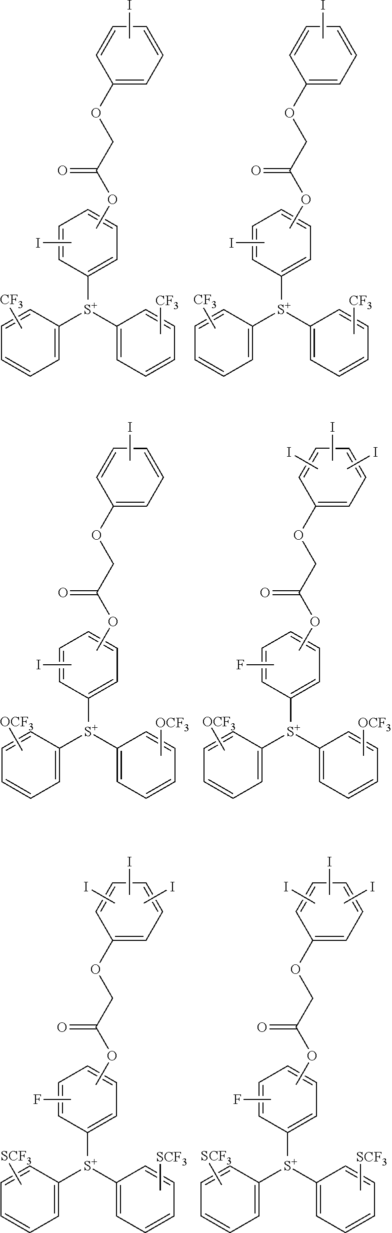

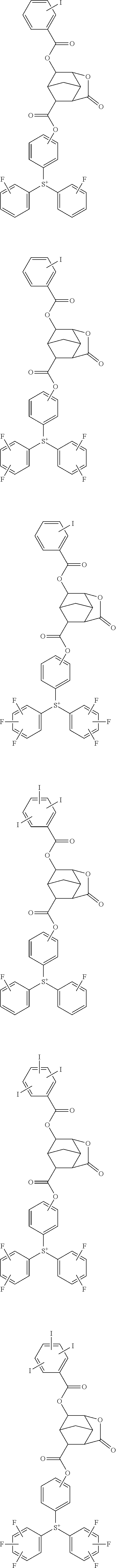

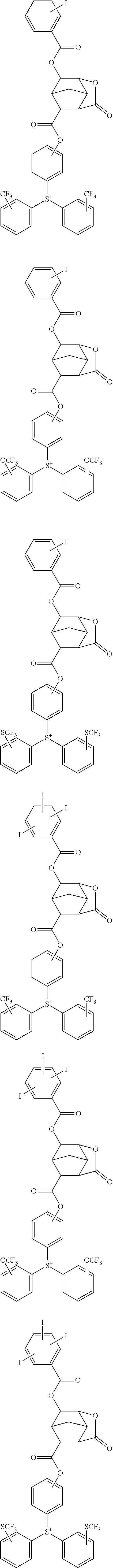

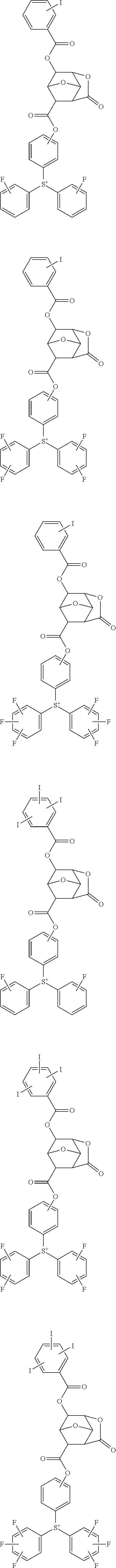

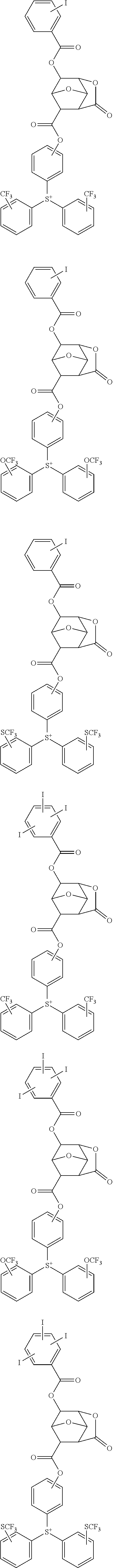

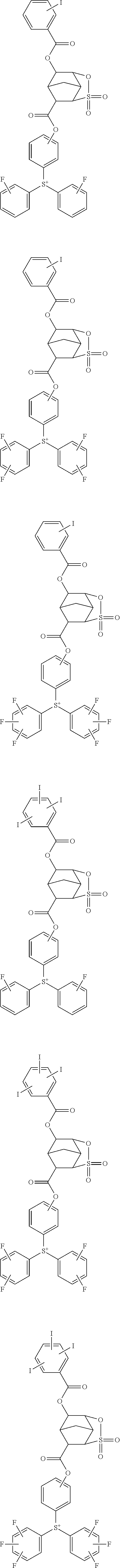

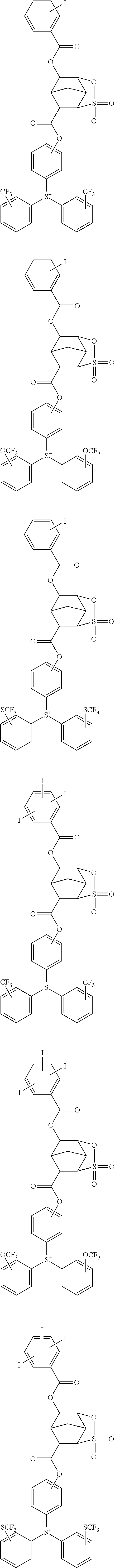

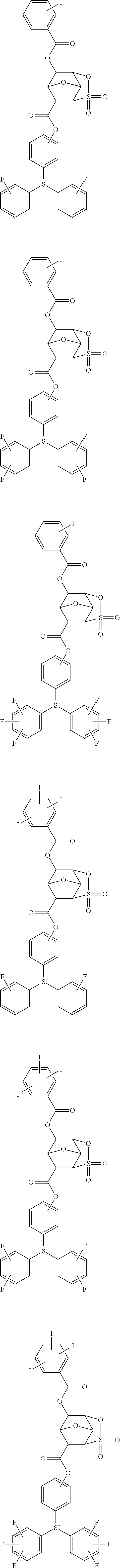

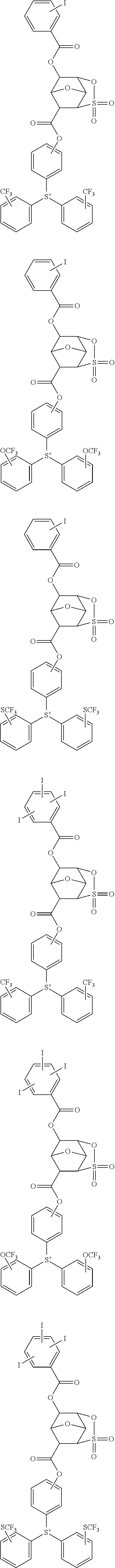

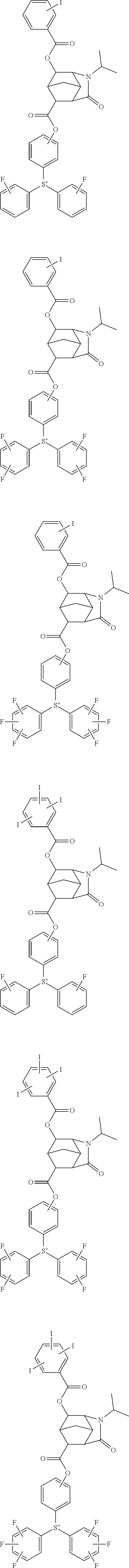

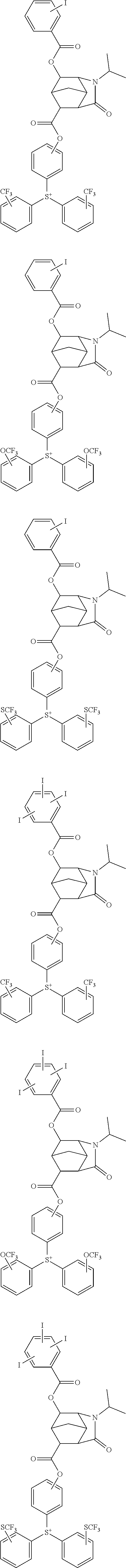

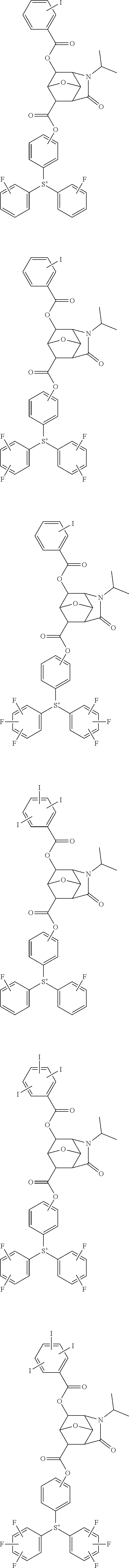

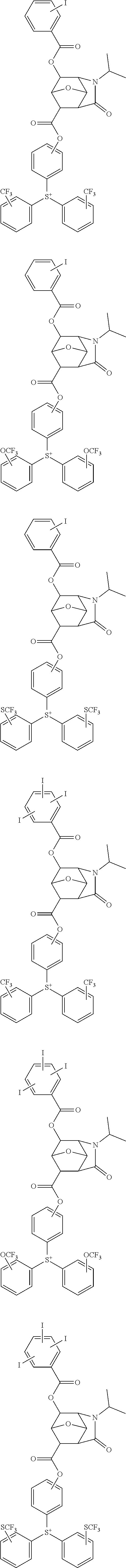

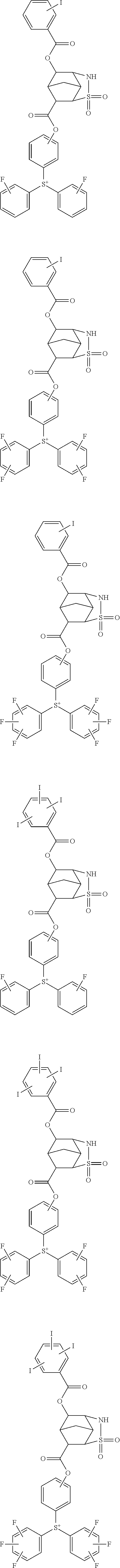

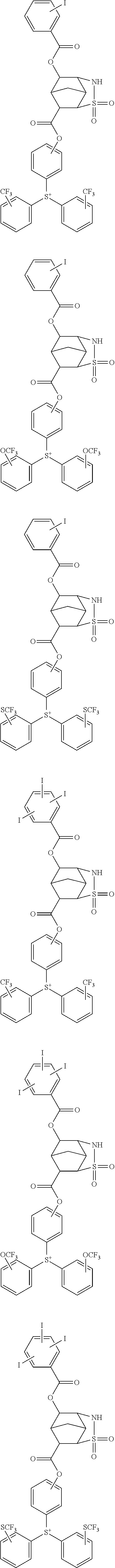

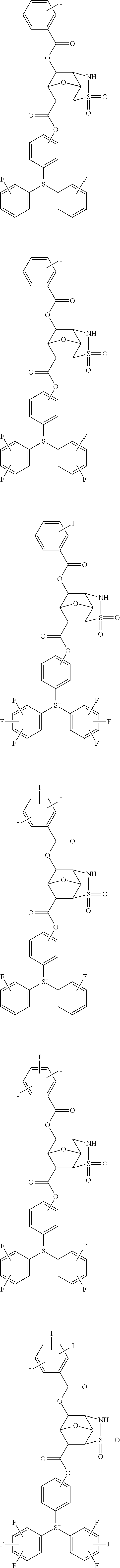

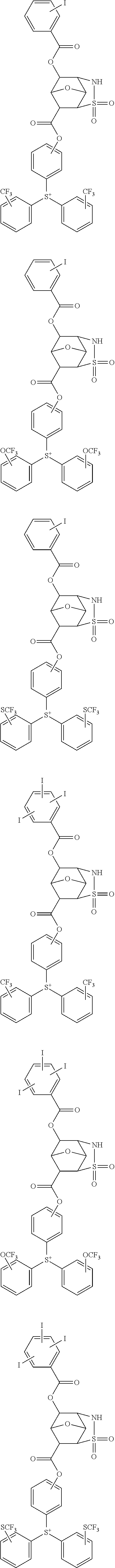

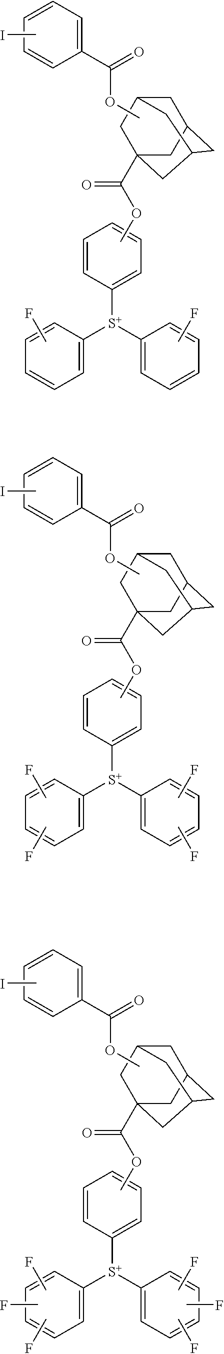

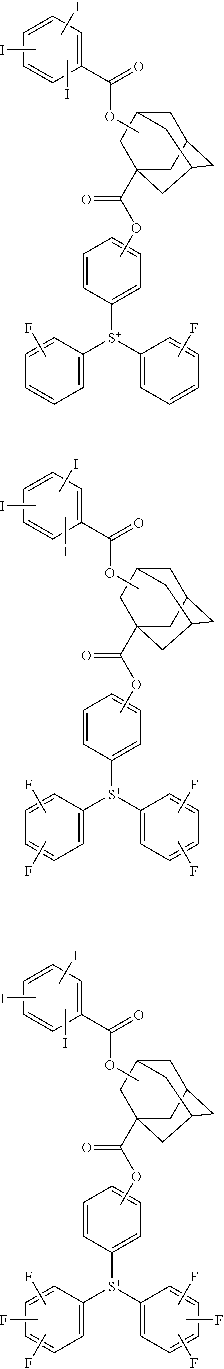

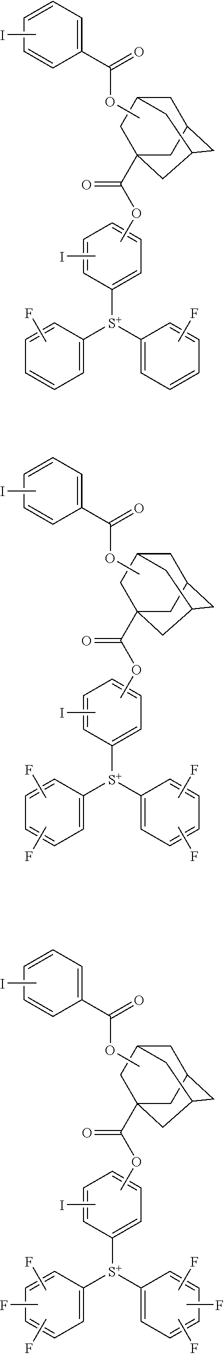

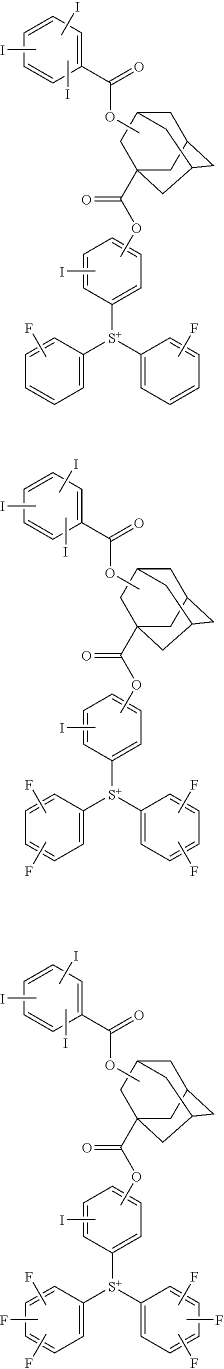

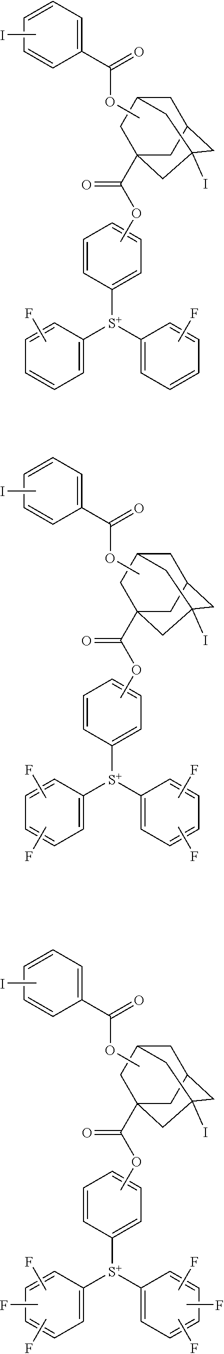

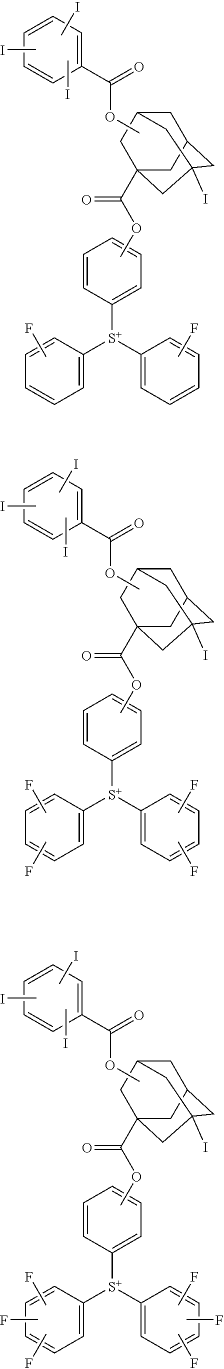

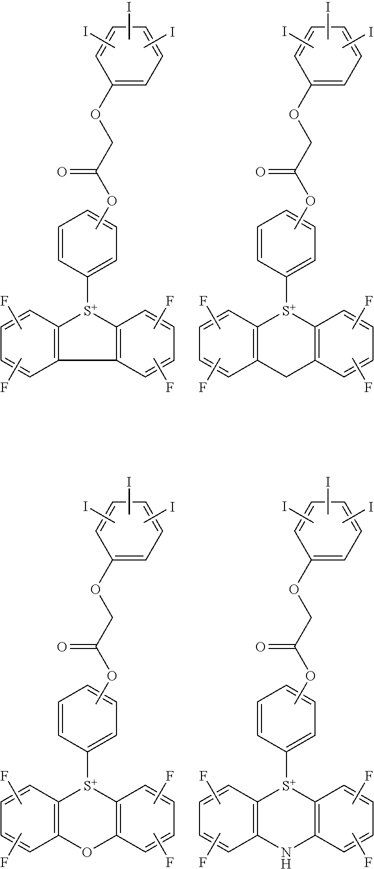

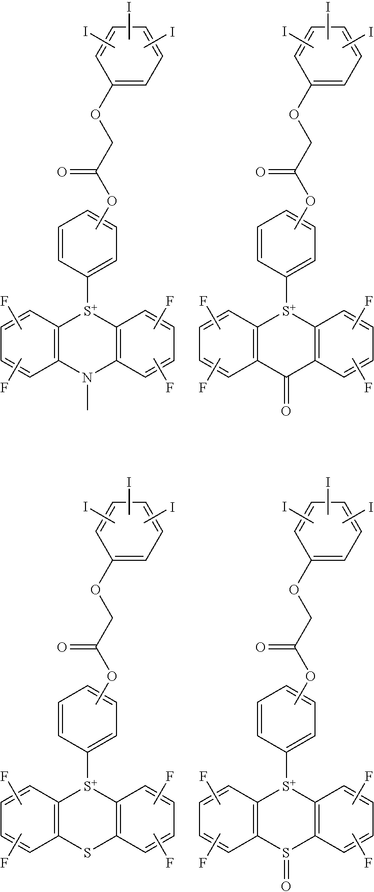

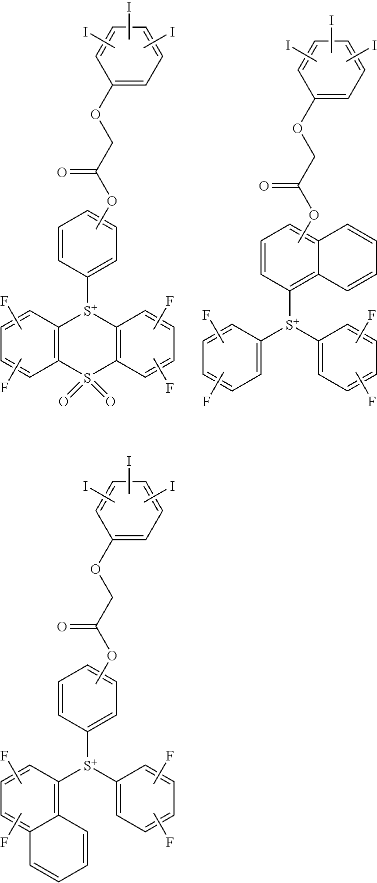

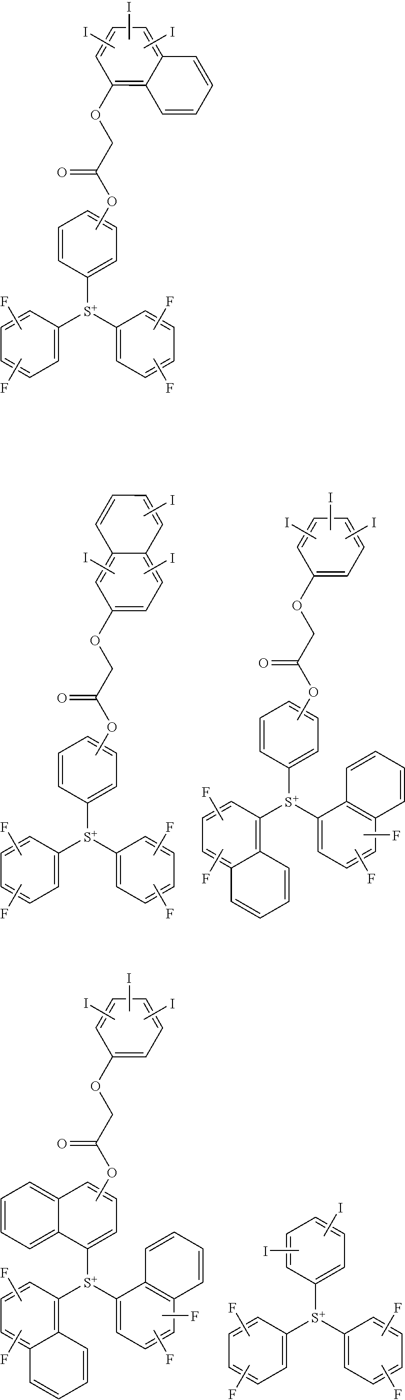

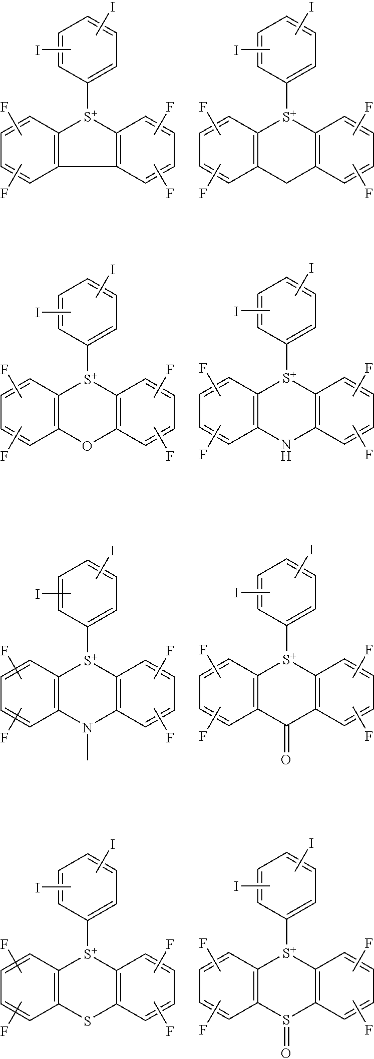

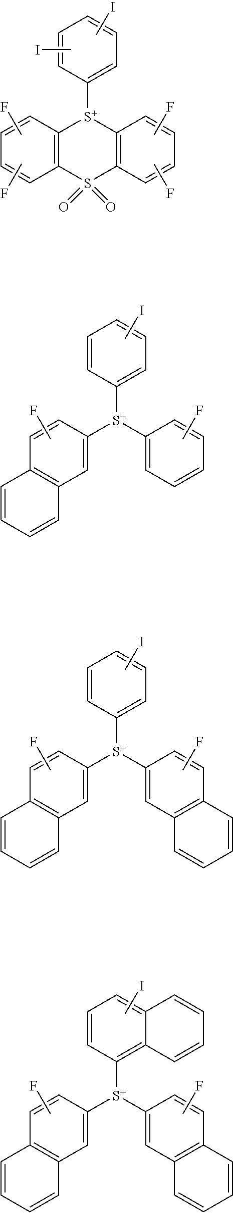

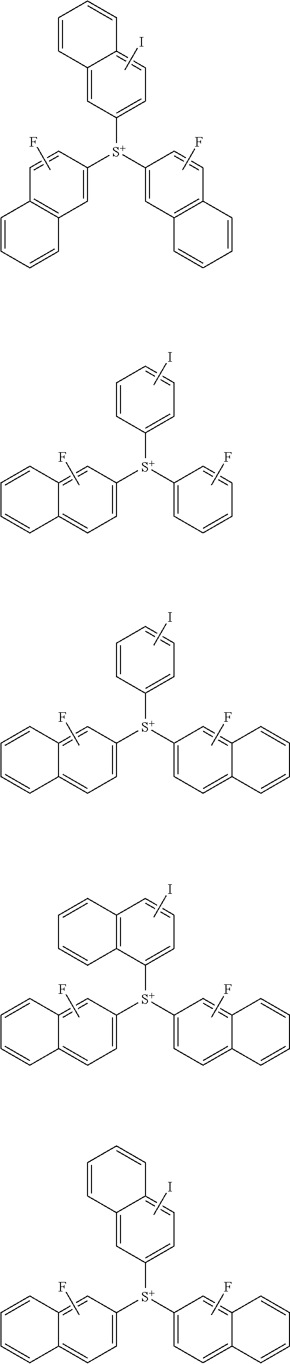

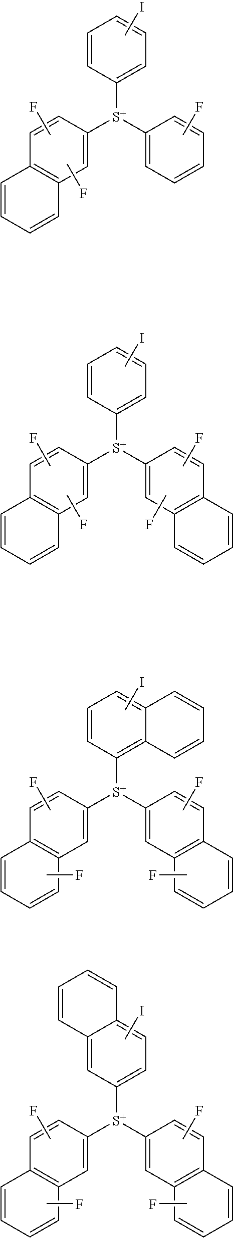

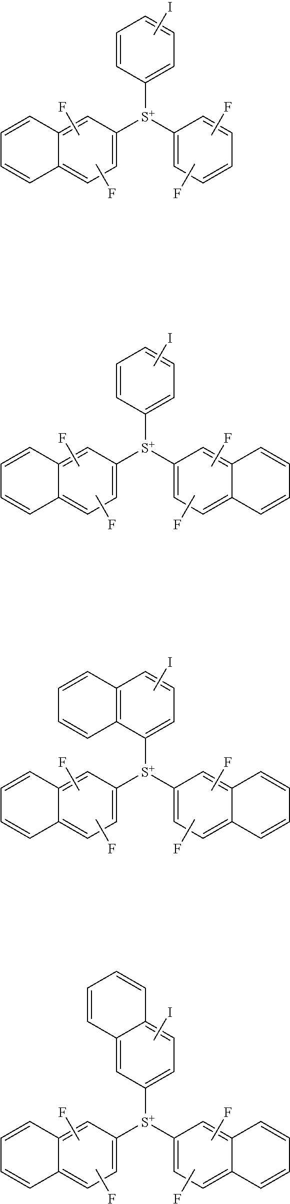

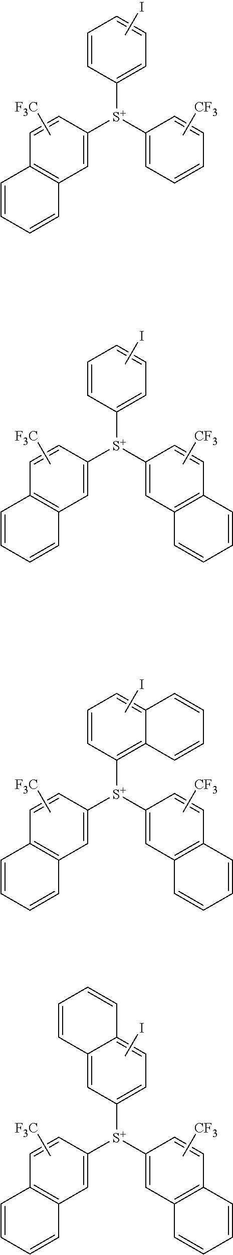

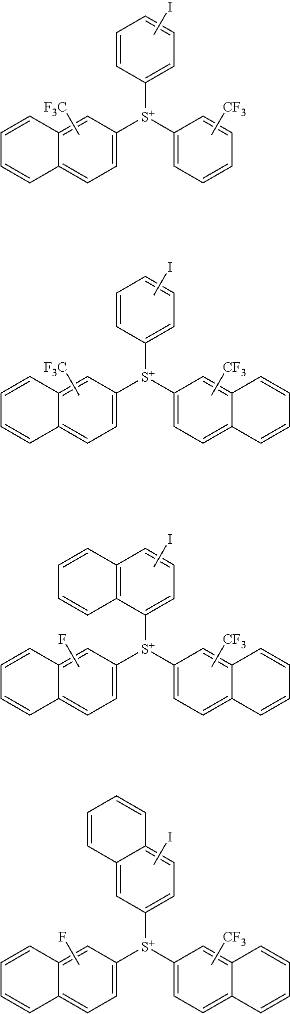

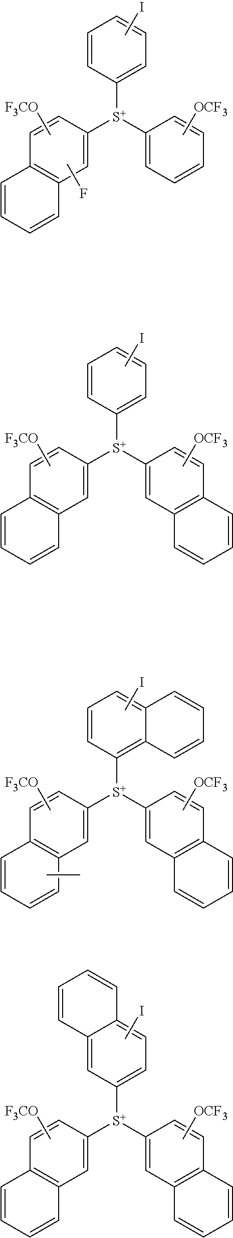

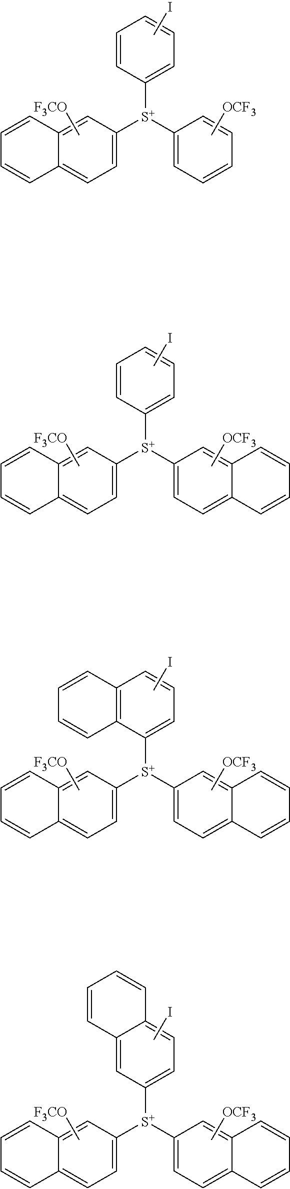

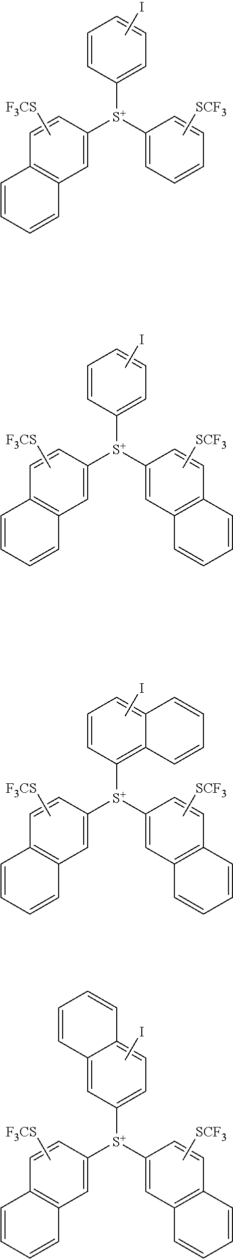

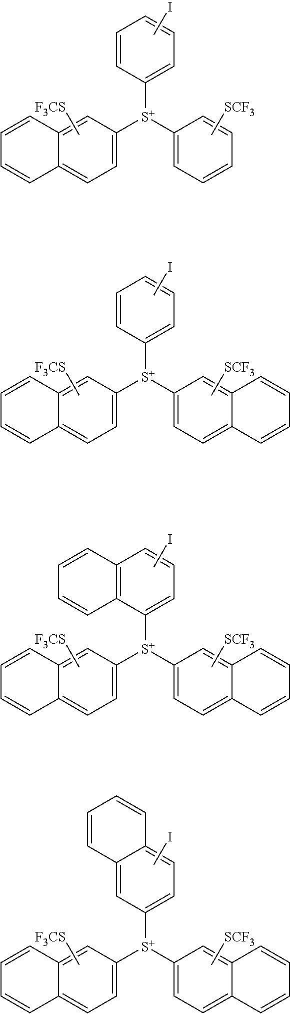

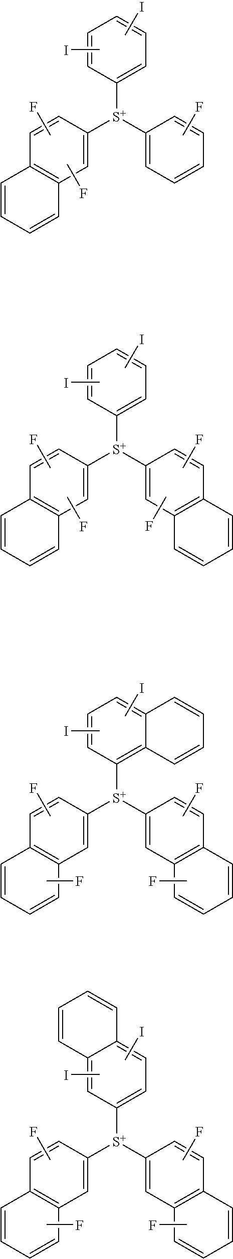

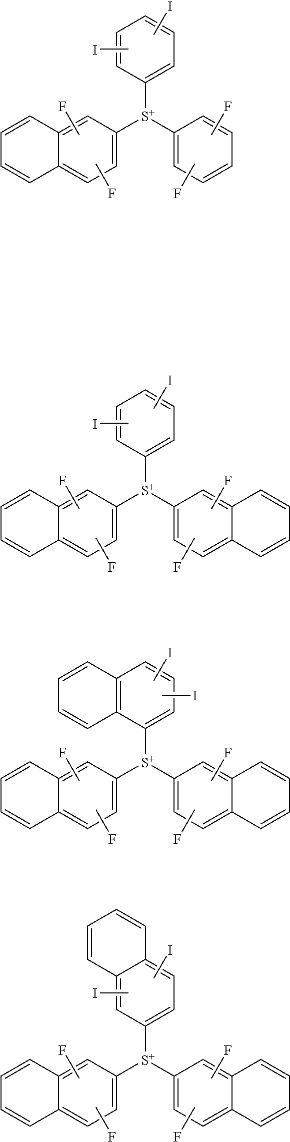

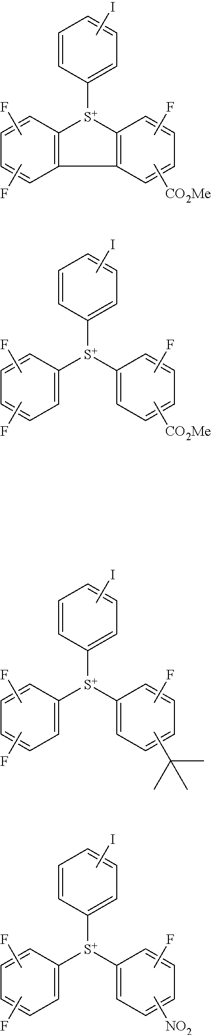

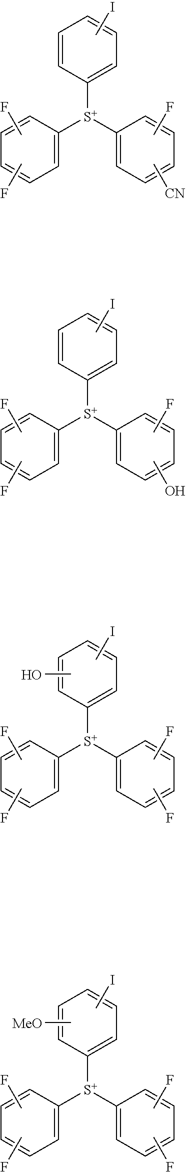

Examples of the iodonium cation include those described in JP-A 2024-000259, paragraph [0181], but are not limited thereto.

The ammonium cation typically has the formula (am-1).

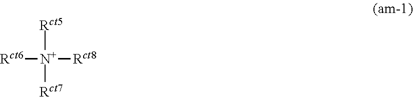

In formula (am-1), R^{ct5} to R^{ct8} are each independently a C₁-C₄₀ hydrocarbyl group which may contain a heteroatom. R^{ct5} and R^{ct6} may bond together to form a ring with the nitrogen atom to which they are attached. Examples of the hydrocarbyl group are as exemplified above for the hydrocarbyl group R¹ and R² in formula (A).

Examples of the ammonium cation having formula (am-1) are shown below, but not limited thereto.

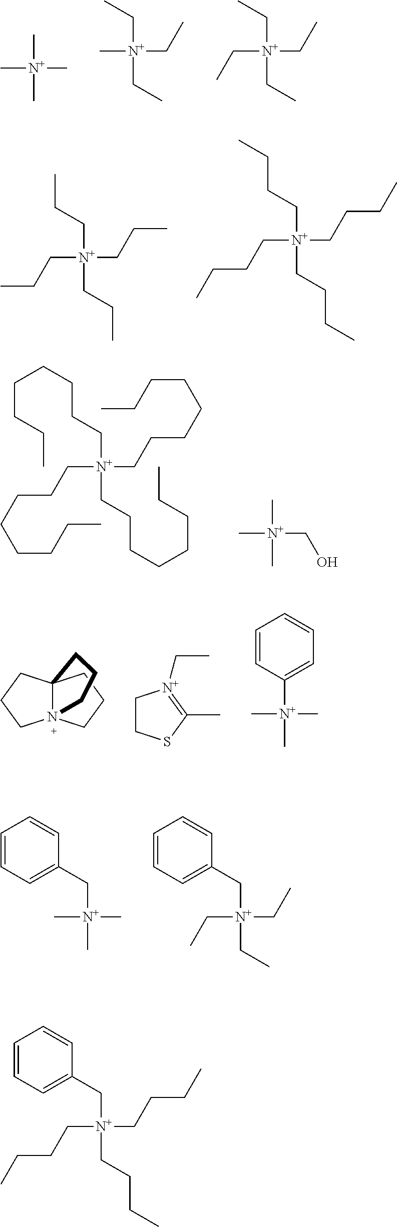

Examples of the repeat units (c1) to (c5) include arbitrary combinations of anions with cations, both as exemplified above.

Of the repeat units (c1) to (c5), repeat units (c2) to (c5) are preferred from the aspect of controlling acid diffusion, repeat units (c2), (c4) and (c5) are more preferred from the aspect of the acid strength of generated acid, and repeat units (c2) are most preferred from the aspect of solvent solubility.

The polymer may further comprise repeat units (d) of a structure having a hydroxy group protected with an acid labile group. The repeat unit (d) is not particularly limited as long as the unit includes one or more structures having a hydroxy group protected with a protective group such that the protective group is decomposed to generate the hydroxy group under the action of acid. Repeat units having the formula (d1) are preferred.

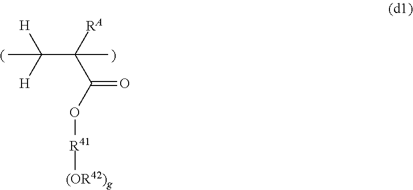

In formula (d1), R^{A} is hydrogen, fluorine, methyl or trifluoromethyl. R⁴¹ is a C₁-C₃₀ (g+1)-valent hydrocarbon group which may contain a heteroatom. R⁴² is an acid labile group, and g is 1, 2, 3 or 4.

In formula (d1), the acid labile group R⁴² is deprotected under the action of acid so that a hydroxy group is generated. Although the structure of R⁴² is not particularly limited, an acetal structure, ketal structure, hydrocarbyloxycarbonyl group and hydrocarbyloxymethyl group having the following formula (d2) are preferred, with the hydrocarbyloxymethyl group having formula (d2) being more preferred.

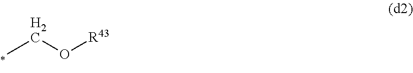

Herein R⁴³ is a C₁-C₁₅ hydrocarbyl group.

Illustrative examples of the acid labile group R⁴², the hydrocarbyloxymethyl group having formula (d2), and the repeat units (d) are as exemplified for the repeat units (d) in JP-A 2020-111564 (US 20200223796).

In addition to the foregoing units, the polymer may further comprise repeat units (e) derived from indene, benzofuran, benzothiophene, acenaphthylene, chromone, coumarin, norbornadiene and derivatives thereof. Examples of the monomer from which repeat units (e) are derived are shown below, but not limited thereto.

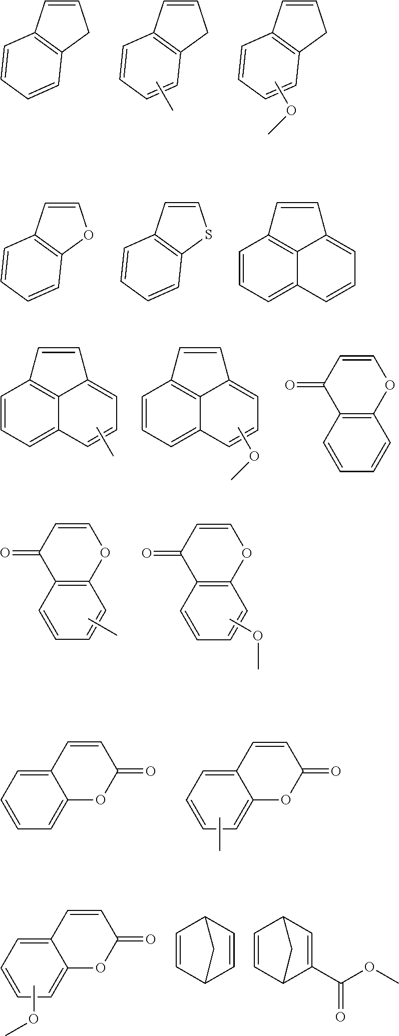

The polymer may further comprise repeat units (f) derived from indane, vinylpyridine or vinylcarbazole.

In the polymer, repeat units A, (a1), (a2), (a3), (b1), (b2), (c1) to (c5), (d), (e), and (f) are incorporated in a ratio of preferably 0<A≤0.8, 0≤a1≤0.5, 0≤a2≤0.5, 0≤a3≤0.5, 0≤b1≤0.6, 0≤b2≤0.6, 0≤c1≤0.4, 0≤c2≤0.4, 0≤c3≤0.4, 0≤c4≤0.4, 0≤c5≤0.4, 0≤d≤0.5, 0≤e≤0.3, and 0≤f≤0.3; more preferably 0<A≤0.7, 0≤a1≤0.4, 0≤a2≤0.4, 0≤a3≤0.4, 0≤b1≤0.5, 0≤b2≤0.5, 0≤c1≤0.3, 0≤c2≤0.3, 0≤c3≤0.3, 0≤c4≤0.3, 0≤c5≤0.3, 0≤d0.3, 0≤e≤0.3, and 0≤f≤0.3; with the proviso that A+a1+a2+a3+b1+b2+c1+c2+c3+c4+c5+d+e+f≤1.0.

The polymer should preferably have a weight average molecular weight (Mw) in the range of 1, 000 to 500, 000, and more preferably 3, 000 to 100, 000, as measured by GPC versus polystyrene standards using tetrahydrofuran (THF) or N,N-dimethylformamide (DMF) solvent. A Mw in the range ensures that the resist film has etch resistance and eliminates the risk of resolution decline by a failure to provide a difference in dissolution rate before and after exposure.

The influence of Mw/Mn becomes stronger as the pattern rule becomes finer. Therefore, the polymer should preferably have a narrow dispersity (Mw/Mn) of 1.0 to 2.0 in order to provide a resist composition suitable for micropatterning to a small feature size. A Mw/Mn in the range ensures that the contents of lower and higher molecular weight polymer fractions are low and eliminates a possibility that foreign matter is left on the pattern or the pattern profile is degraded.

The polymer may be synthesized, for example, by dissolving a monomer or monomers corresponding to the above-mentioned repeat units in an organic solvent, adding a radical polymerization initiator, and heating for polymerization.

Examples of the organic solvent which can be used for polymerization include toluene, benzene, THF, diethyl ether, dioxane, cyclohexane, cyclopentane, methyl ethyl ketone (MEK), propylene glycol monomethyl ether acetate (PGMEA), and γ-butyrolactone (GBL). Examples of the polymerization initiator used herein include 2,2′-azobisisobutyronitrile (AIBN), 2,2′-azobis(2,4-dimethylvaleronitrile), dimethyl 2,2-azobis(2-methylpropionate), 1,1′-azobis(1-acetoxy-1-phenylethane), benzoyl peroxide, and lauroyl peroxide. The initiator is preferably added in an amount of 0.01 to 25 mol % based on the total of monomers to be polymerized. The reaction temperature is preferably 50 to 150 °C, more preferably 60 to 100 °C. The reaction time is preferably 2 to 24 hours, more preferably 2 to 12 hours in view of production efficiency.

The polymerization initiator may be fed to the reactor either by adding the initiator to the monomer solution and feeding the solution to the reactor, or by dissolving the initiator in a solvent to form an initiator solution and feeding the initiator solution and the monomer solution independently to the reactor. Because of a possibility that in the standby duration, the initiator generates a radical which triggers polymerization reaction to form a ultra-high-molecular-weight polymer, it is preferred from the standpoint of quality control to prepare the monomer solution and the initiator solution separately and add them dropwise. The acid labile group that has been incorporated in the monomer may be kept as such, or polymerization may be followed by protection or partial protection. During the polymer synthesis, any known chain transfer agent such as dodecyl mercaptan or 2-mercaptoethanol may be added for molecular weight control purpose. The amount of chain transfer agent added is preferably 0.01 to 20 mol % based on the total of monomers.

When a hydroxy-containing monomer is copolymerized, the hydroxy group is substituted by an acetal group which is susceptible to deprotection with acid, typically ethoxyethoxy, prior to polymerization, and the polymerization is followed by deprotection with weak acid and water. Alternatively, the hydroxy group is substituted by an acetyl, formyl or pivaloyl group prior to polymerization, and the polymerization is followed by alkaline hydrolysis.

When hydroxystyrene or hydroxyvinylnaphthalene is copolymerized, one method is by dissolving hydroxystyrene or hydroxyvinylnaphthalene and other monomers in an organic solvent, adding a radical polymerization initiator thereto, and heating the solution for polymerization. In an alternative method, acetoxystyrene or acetoxyvinylnaphthalene is used instead, and after polymerization, the acetoxy group is deprotected by alkaline hydrolysis, for thereby converting the polymer product to polyhydroxystyrene or polyhydroxyvinylnaphthalene.

For alkaline hydrolysis, a base such as aqueous ammonia or triethylamine may be used. Preferably the reaction temperature is −20 °C to 100 °C, more preferably 0 °C to 60 °C, and the reaction time is 0.2 to 100 hours, more preferably 0.5 to 20 hours.

The amounts of monomers in the monomer solution may be determined appropriate so as to provide the preferred fractions of repeat units.

It is now described how to use the polymer obtained by the above preparation method. The reaction solution resulting from polymerization reaction may be used as the final product. Alternatively, the polymer may be recovered in powder form through a purifying step such as re-precipitation step of adding the polymerization solution to a poor solvent and letting the polymer precipitate as powder, after which the polymer powder is used as the final product. It is preferred from the standpoints of operation efficiency and consistent quality to handle a polymer solution which is obtained by dissolving the powder polymer resulting from the purifying step in a solvent, as the final product.

The solvents which can be used herein are described in JP-A 2008-111103, paragraphs [0144]-[0145](U.S. Pat. No. 7,537,880). Exemplary solvents include ketones such as cyclohexanone and methyl-2-n-pentyl ketone; alcohols such as 3-methoxybutanol, 3-methyl-3-methoxybutanol, 1-methoxy-2-propanol, and 1-ethoxy-2-propanol; keto-alcohols such as diacetone alcohol (DAA); ethers such as propylene glycol monomethyl ether (PGME), ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; lactones such as γ-butyrolactone (GBL); and high-boiling alcohols such as diethylene glycol, propylene glycol, glycerol, 1,4-butanediol, and 1,3-butanediol, which may be used alone or in admixture.

The polymer solution preferably has a polymer concentration of 0.01 to 30% by weight, more preferably 0.1 to 20% by weight.

Prior to use, the reaction solution or polymer solution is preferably filtered through a filter. Filtration is effective for consistent quality because foreign particles and gel which can cause defects are removed.

Suitable materials of which the filter is made include fluorocarbon, cellulose, nylon, polyester, and hydrocarbon base materials. Preferred for the filtration of a resist composition are filters made of fluorocarbons commonly known as Teflon®, hydrocarbons such as polyethylene and polypropylene, and nylon. While the pore size of the filter may be selected appropriate to comply with the desired cleanness, the filter preferably has a pore size of up to 100 nm, more preferably up to 20 nm. A single filter may be used or a plurality of filters may be used in combination. Although the filtering method may be single pass of the solution, preferably the filtering step is repeated by flowing the solution in a circulating manner. In the polymer preparation process, the filtering step may be carried out any times, in any order and in any stage. The reaction solution as polymerized or the polymer solution may be filtered, preferably both are filtered.

### [Chemically Amplified Resist Composition]

### (A) Base Polymer

The chemically amplified resist composition comprises a base polymer containing the polymer defined above as component (A).

The base polymer (A) may be a single polymer or a blend of two or more polymers which differ in compositional ratio, Mw and/or Mw/Mn. Component (A) may also be a blend of the polymer defined above and a hydrogenated product of ring-opening metathesis polymerization (ROMP) polymer. For the ROMP, reference is made to JP-A 2003-066612.

### (B) Organic Solvent

The resist composition may comprise an organic solvent as component (B). The organic solvent (B) is not particularly limited as long as the foregoing and other components are soluble therein. Suitable solvents include ketones such as cyclopentanone, cyclohexanone, and methyl-2-n-pentyl ketone; alcohols such as 3-methoxybutanol, 3-methyl-3-methoxybutanol, 1-methoxy-2-propanol, and 1-ethoxy-2-propanol; keto-alcohols such as diacetone alcohol (DAA); ethers such as propylene glycol monomethyl ether (PGME), ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monoethyl ether acetate, ethyl lactate (EL), ethyl pyruvate, butyl acetate, methyl 3-methoxypropionate, ethyl 3-ethoxypropionate, tert-butyl acetate, tert-butyl propionate, and propylene glycol mono-tert-butyl ether acetate; and lactones such as γ-butyrolactone (GBL), and mixtures thereof.

Of the foregoing organic solvents, it is recommended to use 1-ethoxy-2-propanol, PGMEA, cyclohexanone, GBL, ethyl lactate, DAA and mixtures thereof because the base polymer (A) is most soluble therein.

The organic solvent (B) is preferably added in an amount of 200 to 5, 000 parts by weight, and more preferably 400 to 3,500 parts by weight per 80 parts by weight of the base polymer (A). The organic solvent may be used alone or in admixture.

### (C) Quencher

The resist composition may further comprise (C) a quencher. As used herein, the “quencher” refers to a compound capable of trapping the strong acid generated by the PAG to prevent the acid from diffusing into the unexposed region of resist film, for forming the desired pattern. As used herein, the strong acid refers to an acid having a sufficient acidity to trigger the deprotection reaction of acid labile groups.

Preferred examples of the quencher include onium salts having the formulae (1) and (2).

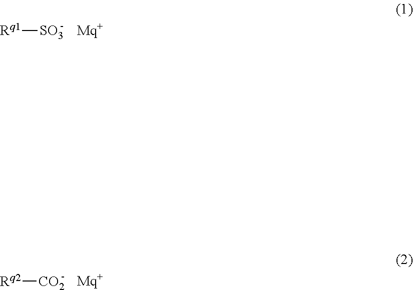

In formula (1), R^{q1} is hydrogen or a C₁-C₄₀ hydrocarbyl group which may contain a heteroatom, exclusive of the group wherein hydrogen bonded to the carbon atom at α-position relative to the sulfo group is substituted by fluorine or fluoroalkyl. In formula (2), R^{q2} is hydrogen or a C₁-C₄₀ hydrocarbyl group which may contain a heteroatom.

Examples of the C₁-C₄₀ hydrocarbyl group R^{q1} include C₁-C₄₀ alkyl groups such as methyl, ethyl, n-propyl, isopropyl, n-butyl, isobutyl, sec-butyl, tert-butyl, n-pentyl, tert-pentyl, n-hexyl, n-octyl, 2-ethylhexyl, n-nonyl, and n-decyl; C₃-C₄₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decyl, and adamantyl; C₆-C₄₀ aryl groups such as phenyl, naphthyl and anthracenyl. In the hydrocarbyl group, some or all hydrogen may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy moiety, fluorine, chlorine, bromine, iodine, cyano moiety, carbonyl moiety, ether bond, ester bond, sulfonic ester bond, carbonate bond, lactone ring, sultone ring, carboxylic anhydride (—C(═O)—O—C(═O)—), or haloalkyl moiety.

Examples of the hydrocarbyl group R^{q2} include those exemplified above for R^{q1} and fluorinated saturated hydrocarbyl groups, for example, fluorinated alkyl groups such as trifluoromethyl and trifluoroethyl, and fluorinated aryl groups such as pentafluorophenyl and 4-trifluoromethylphenyl.

Examples of the anion in the onium salt having formula (1) are shown below, but

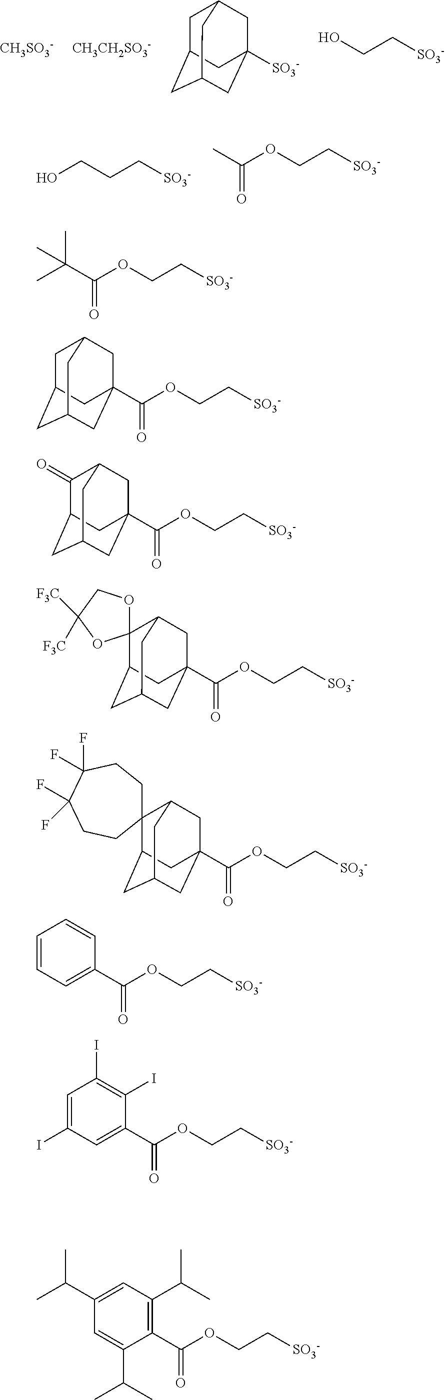

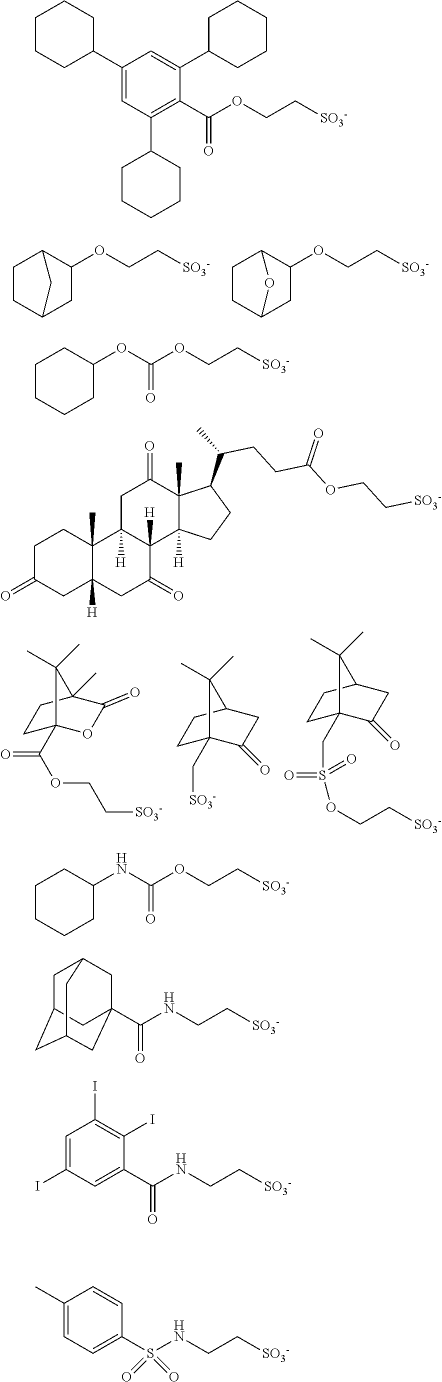

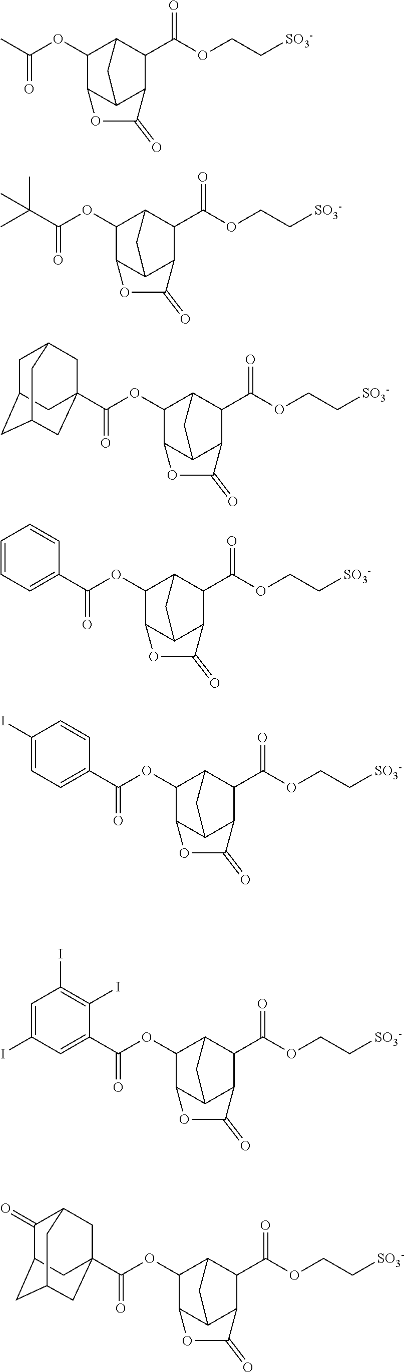

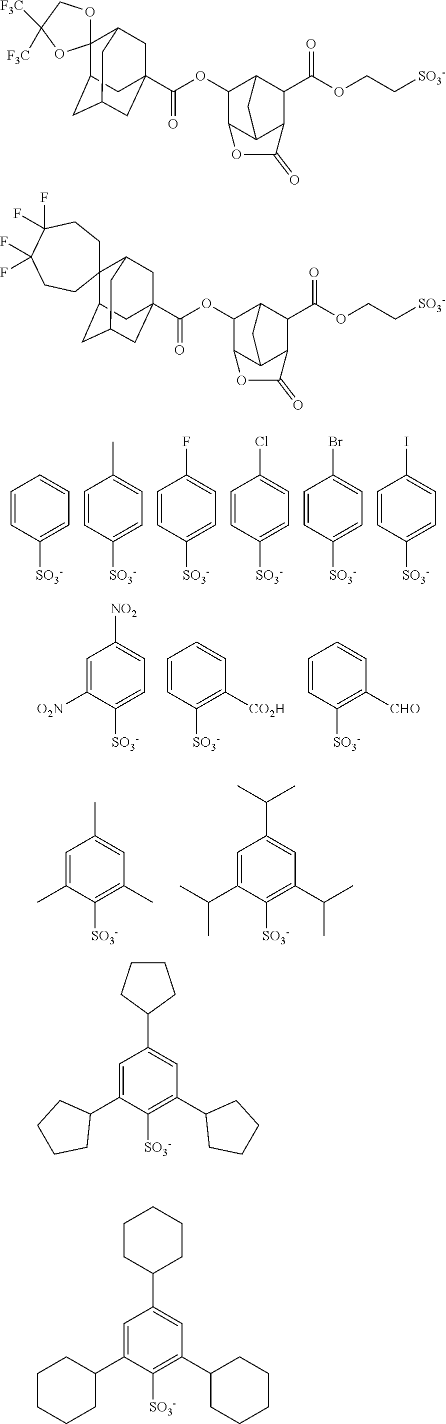

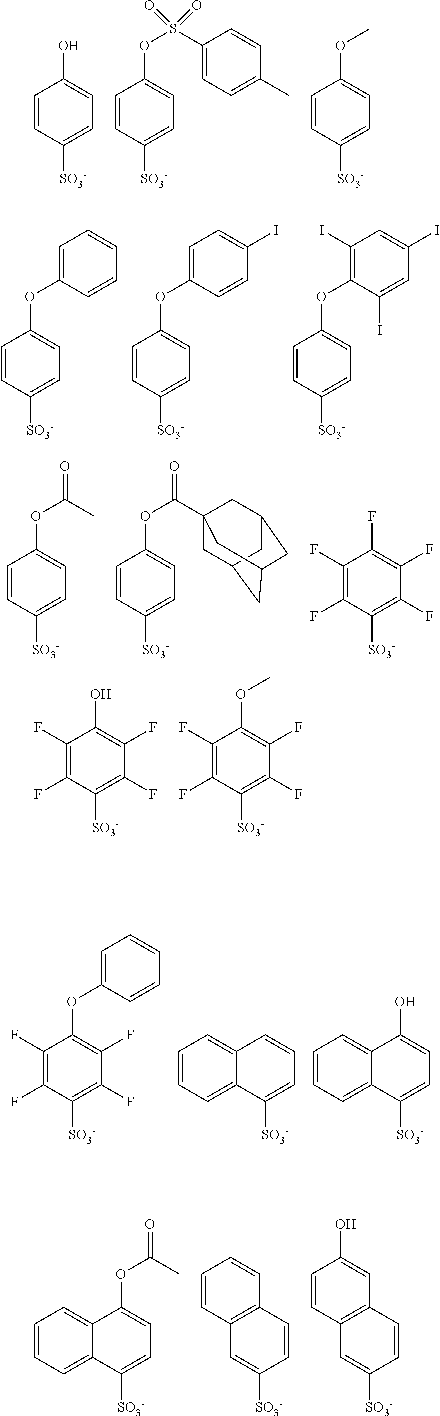

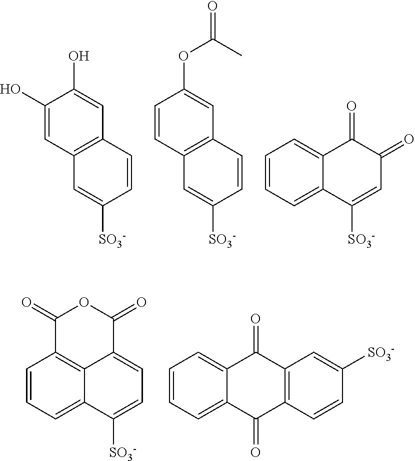

Other examples of the anion in the onium salt having formula (1) include those described in the following patent documents.
JP 6248882, paragraphs [0027]-[0029]
JP 6648726, paragraphs [0029]-[0034]
JP 7032549, paragraphs [0220]-[0225]
JP 7067271, paragraphs [0028]-[0029]
JP-A 2024-104830, paragraphs [0037]-[0060]
JP-A 2023-177038, paragraphs [0039]-[0066]
JP-A 2024-140135, paragraphs [0033]-[0093]
WO 2024/241820, paragraphs [0056]-[0059]

Examples of the anion in the onium salt having formula (2) are shown below, but not limited thereto.

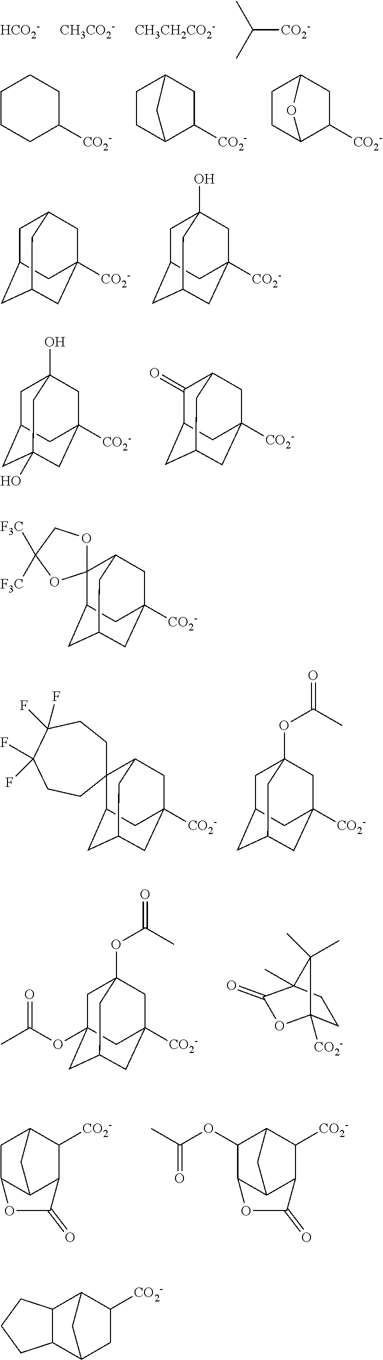

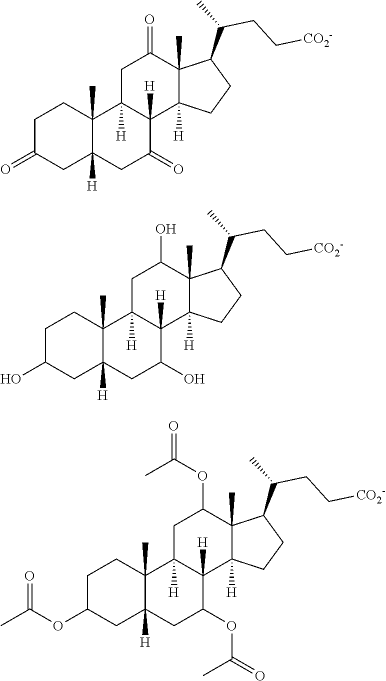

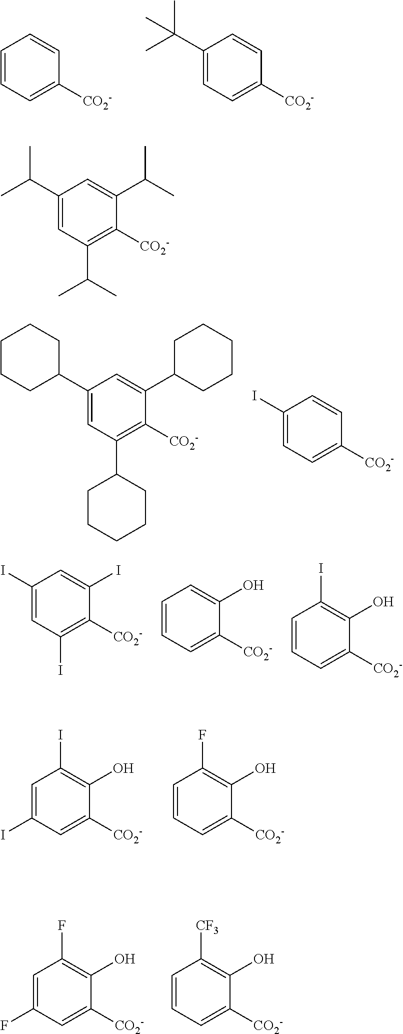

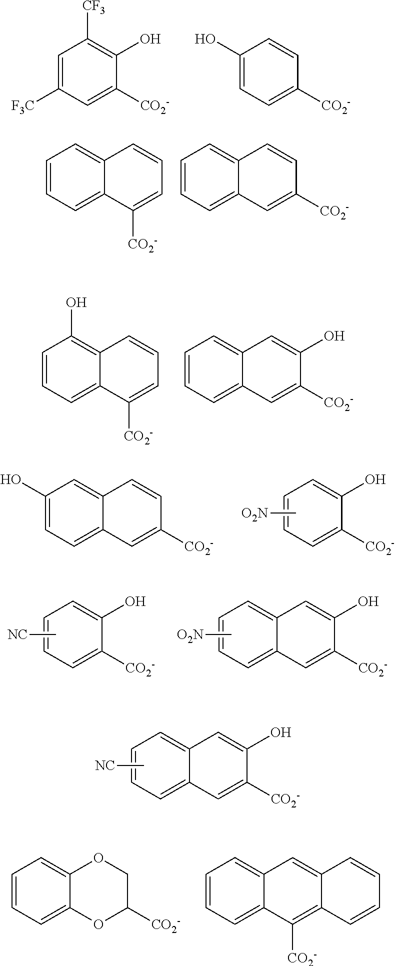

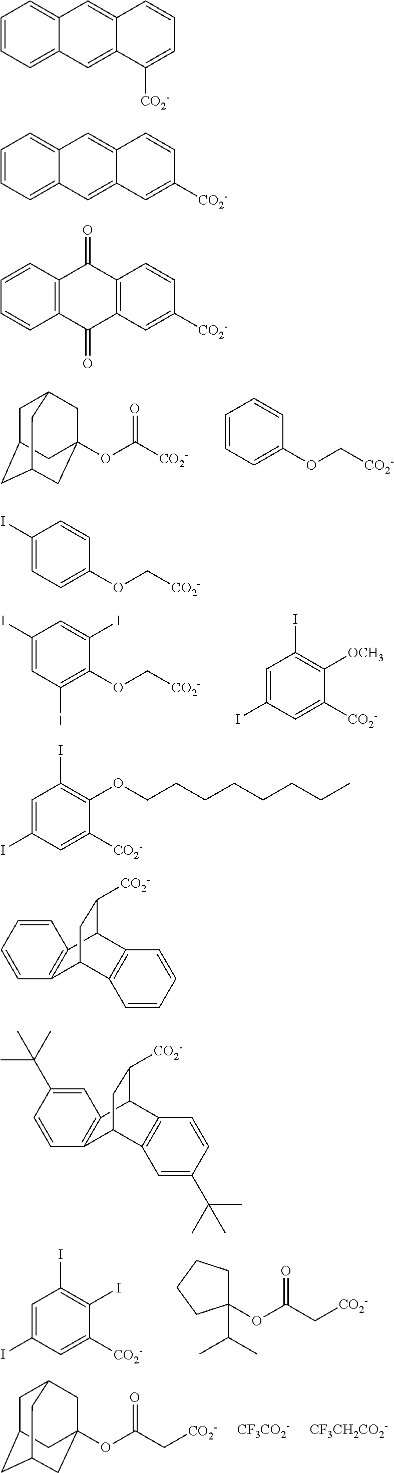

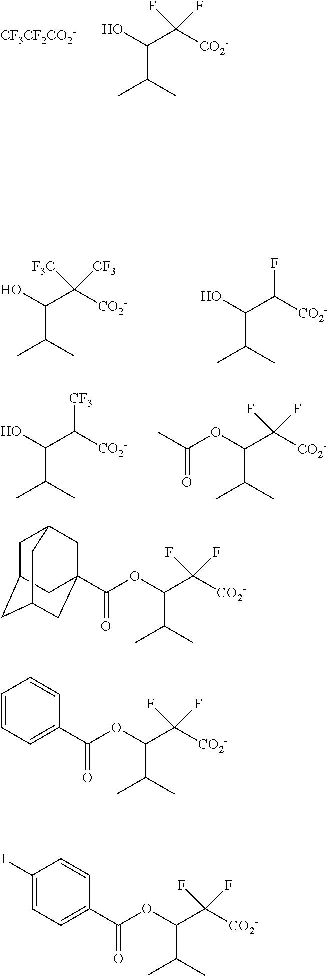

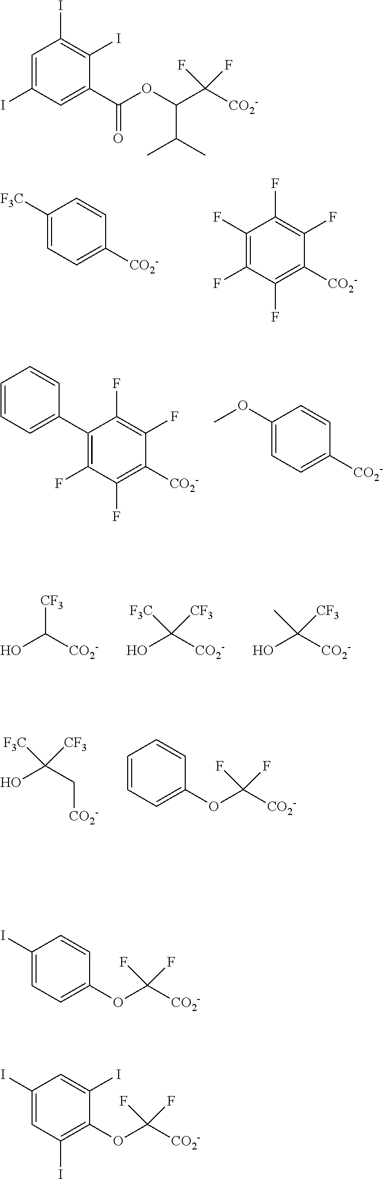

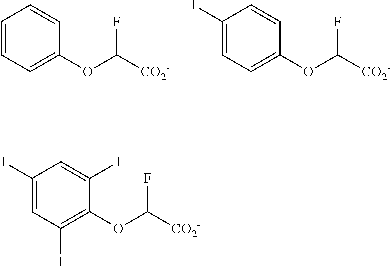

Other examples of the anion in the onium salt having formula (2) include those described in the following patent documents.
WO 2023/189502, paragraph [0097]
WO 2023/199907, paragraphs [0231]-[0233] and [0236]
WO 2023/223865, paragraphs [0240]-[0242]
WO 2024/122425, paragraphs [0203]-[0211]
WO 2024/166822, paragraphs [0282]-[0294]
JP-A 2022-077505, paragraphs [0013]-[0015]
JP-A 2022-091720, paragraphs [0022]-[0024]
JP-A 2022-141598, paragraphs [0026]-[0031]
JP-A 2023-018671, paragraphs [0017]-[0018]
JP-A 2023-062898, paragraph [0157]
JP-A 2023-108593, paragraph [0147]
JP-A 2024-040793, paragraphs [0181]-[0194]
JP-A 2024-067732, paragraph [0171]
JP-A 2024-074267, paragraphs [0029]-[0030]
JP-A 2024-074268, paragraph [0022]
JP-A 2024-079160, paragraphs [0233]-[0237]
JP-A 2024-083302, paragraphs [0025]-[0026]
JP-A 2024-083305, paragraphs [0030]-[0031]
JP-A 2024-084141, paragraphs [0032]-[0034]
JP-A 2024-099498, paragraphs [0030]-[0031]
JP-A 2024-099503, paragraphs [0032]-[0033]
JP-A 2024-101558, paragraphs [0032]-[0033]
JP-A 2024-102839, paragraphs [0027]-[0028]
JP-A 2024-102841, paragraphs [0035]-[0036]
JP-A 2024-113453, paragraphs [0256]-[0261]
JP-A 2024-131484, paragraph [0266]
JP-A 2025-010082, paragraphs [0022]-[0024]
JP-A 2025-027484, paragraph [0299]
JP 7611887, paragraphs [0190]-[0198]
JP 7614747, paragraphs [0285]-[0290]
JP 7621323, paragraphs [0201]-[0209]

In formulae (1) and (2), Mq⁺ is an onium cation. Suitable onium cations include sulfonium, iodonium and ammonium cations. Examples of the sulfonium cation include those exemplified above for the cation in the sulfonium salt having formula (1), those described in JP-A 2024-003744, paragraphs [0102]-[0125], WO 2024/128017, paragraphs [0044]-[0049], and JP 7491173, paragraphs [0035]-[0046], and those exemplified above for the sulfonium cation having formula (sulfo-1), but are not limited thereto. Examples of the iodonium cation include those described in JP-A 2024-000259, paragraph [0181], but are not limited thereto. Examples of the ammonium cation include those exemplified above for the ammonium cation having formula (am-1).

Examples of the onium salt having formula (1) or (2) include arbitrary combinations of anions with cations, both as exemplified above. These onium salts may be readily synthesized by ion exchange reaction according to any well-known organic chemistry technique. For the ion exchange reaction, reference may be made to JP-A 2007-145797, for example.

The onium salt having formula (1) or (2) functions as a quencher in the resist composition because the counter anion of the onium salt is a conjugated base of a weak acid. As used herein, the weak acid indicates an acidity insufficient to deprotect acid labile groups from an acid labile group-containing unit in the base polymer. The onium salt having formula (1) or (2) functions as a quencher when used in combination with an onium salt type PAG having a conjugated base of a strong acid (typically α-fluorinated sulfonic acid) as the counter anion. In a system using a mixture of an onium salt capable of generating a strong acid (e.g., α-fluorinated sulfonic acid) and an onium salt capable of generating a weak acid (e.g., non-fluorinated sulfonic acid or carboxylic acid), if the strong acid generated from the PAG upon exposure to high-energy radiation collides with the unreacted onium salt having a weak acid anion, then a salt exchange occurs whereby the weak acid is released and an onium salt having a strong acid anion is formed. In this course, the strong acid is exchanged into the weak acid having a low catalysis, incurring apparent deactivation of the acid for enabling to control acid diffusion.

Also useful as the quencher (C) are onium salts having a sulfonium cation and a phenoxide anion site in a common molecule as described in JP 6848776, onium salts having a sulfonium cation and a carboxylate anion site in a common molecule as described in JP 6583136 and JP-A 2020-200311, and onium salts having an iodonium cation and a carboxylate anion site in a common molecule as described in JP 6274755.

If a PAG capable of generating a strong acid is an onium salt, an exchange from the strong acid generated upon exposure to high-energy radiation to a weak acid as above can take place, but it rarely happens that the weak acid generated upon exposure to high-energy radiation collides with the unreacted onium salt capable of generating a strong acid to induce a salt exchange. This is because of a likelihood of an onium cation forming an ion pair with a stronger acid anion.

When the onium salt having formula (1) or (2) is used as the quencher (C), the amount of the onium salt used is preferably 0.1 to 20 parts by weight, more preferably 0.1 to 10 parts by weight per 80 parts by weight of the base polymer (A). As long as the amount of component (C) is in the range, a satisfactory resolution is available without a substantial lowering of sensitivity. The onium salt having formula (1) or (2) may be used alone or in admixture.

Nitrogen-containing compounds may also be used as the quencher (C). Suitable nitrogen-containing compounds include primary, secondary and tertiary amine compounds, specifically amine compounds having a hydroxy group, ether bond, ester bond, lactone ring, cyano group or sulfonic ester bond, as described in JP-A 2008-111103, paragraphs [0146]-[0164](U.S. Pat. No. 7,537,880), and primary or secondary amine compounds protected with a carbamate group, as described in JP 3790649. Also included are compounds structured such that an acid labile group is co-present with any one of lactone, sultone, lactam and sultam rings as described in JP 7615989.

A sulfonic acid sulfonium salt having a nitrogen-containing substituent may also be used as the nitrogen-containing compound. This compound functions as a quencher in the unexposed region, but as a so-called photo-degradable base in the exposed region because it loses the quencher function in the exposed region due to neutralization thereof with the acid generated by itself. Using a photo-degradable base, the contrast between exposed and unexposed regions can be further enhanced. With respect to the photo-degradable base, reference may be made to JP-A 2009-109595 and JP-A 2012-046501, for example.

When the nitrogen-containing compound is used as the quencher (C), the amount of the nitrogen-containing compound used is preferably 0.001 to 12 parts by weight, more preferably 0.01 to 8 parts by weight per 80 parts by weight of the base polymer (A). The nitrogen-containing compound may be used alone or in admixture.

### (D) Photoacid Generator

The chemically amplified resist composition may comprise (D) a photoacid generator. The PAG is not particularly limited as long as it is capable of generating a strong acid upon exposure to high-energy radiation.

The preferred PAG is a salt having the formula (3) or (4).

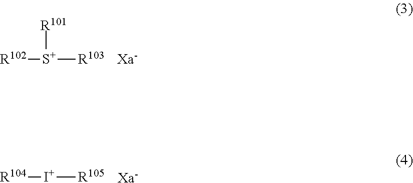

In formulae (3) and (4), R¹⁰¹ to R¹⁰⁵ are each independently halogen or a C₁-C₂₀ hydrocarbyl group which may contain a heteroatom. Any two of R¹⁰¹, R¹⁰² and R¹⁰³ may bond together to form a ring with the sulfur atom to which they are attached. Examples of the hydrocarbyl group are as exemplified above for the hydrocarbyl group R¹ and R² in formula (A).

Examples of the cation in the sulfonium salt having formula (3) include those described in JP-A 2024-003744, paragraphs [0102]-[0125], WO 2024/128017, paragraphs [0044]-[0049], and JP 7491173, paragraphs [0035]-[0046], and those exemplified as the sulfonium cation having formula (sulfo-1), but are not limited thereto. Examples of the cation in the iodonium salt having formula (4) include those described in JP-A 2024-000259, paragraph [0181], but are not limited thereto.

In formulae (3) and (4), Xa⁻ is an anion of strong acid. Preferred examples of the anion of strong acid include the anions having formulae (c1-1), (c1-4), and (c1-5). Fluorinated aromatic sulfonic acid anions as described in JP 6648726, paragraphs [0029]-[0034], JP-A 2024-077330, paragraphs [0264]-[0267], and JP-A 2025-000201, paragraphs [0040]-[0071] are also useful as the strong acid anion.

Compounds having the formula (5) are also preferred as the PAG (D).

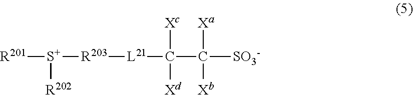

In formula (5), R²⁰¹ and R²⁰² are each independently a C₁-C₃₀ hydrocarbyl group which may contain a heteroatom. R²⁰³ is a C₁-C₃₀ hydrocarbylene group which may contain a heteroatom. Any two of R²⁰¹, R²⁰² and R²⁰³ may bond together to form a ring with the sulfur atom to which they are attached.

The C₁-C₃₀ hydrocarbyl group represented by R²⁰¹ and R²⁰² may be saturated or unsaturated and straight, branched or cyclic. Examples thereof include C₁-C₃₀ alkyl groups such as methyl, ethyl, n-propyl, isopropyl, n-butyl, isobutyl, sec-butyl, tert-butyl, n-pentyl, tert-pentyl, n-hexyl, n-octyl, 2-ethylhexyl, n-nonyl, and n-decyl; C₃-C₃₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, oxanorbornyl, tricyclo[5.2.1.0^{2,6}]decyl, and adamantyl; and C₆-C₃₀ aryl groups such as phenyl, methylphenyl, ethylphenyl, n-propylphenyl, isopropylphenyl, n-butylphenyl, isobutylphenyl, sec-butylphenyl, tert-butylphenyl, naphthyl, methylnaphthyl, ethylnaphthyl, n-propylnaphthyl, isopropylnaphthyl, n-butylnaphthyl, isobutylnaphthyl, sec-butylnaphthyl, tert-butylnaphthyl, and anthracenyl, and combinations thereof. In these hydrocarbyl groups, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy, cyano, fluorine, chlorine, bromine, iodine, carbonyl, ether bond, ester bond, sulfonate ester bond, carbonate bond, lactone ring, sultone ring, carboxylic anhydride (—C(═O)—O—C(═O)—) or haloalkyl moiety.

The C₁-C₃₀ hydrocarbylene group R²⁰³ may be saturated or unsaturated and straight, branched or cyclic. Examples thereof include C₁-C₃₀ alkanediyl groups such as methanediyl, ethane-1,1-diyl, ethane-1,2-diyl, propane-1,3-diyl, butane-1,4-diyl, pentane-1,5-diyl, hexane-1,6-diyl, heptane-1,7-diyl, octane-1,8-diyl, nonane-1,9-diyl, decane-1,10-diyl, undecane-1,11-diyl, dodecane-1,12-diyl, tridecane-1,13-diyl, tetradecane-1,14-diyl, pentadecane-1,15-diyl, hexadecane-1,16-diyl, and heptadecane-1,17-diyl; C₃-C₃₀ cyclic saturated hydrocarbylene groups such as cyclopentanediyl, cyclohexanediyl, norbornanediyl and adamantanediyl; and arylene groups such as phenylene, methylphenylene, ethylphenylene, n-propylphenylene, isopropylphenylene, n-butylphenylene, isobutylphenylene, sec-butylphenylene, tert-butylphenylene, naphthylene, methylnaphthylene, ethylnaphthylene, n-propylnaphthylene, isopropylnaphthylene, n-butylnaphthylene, isobutylnaphthylene, sec-butylnaphthylene, and tert-butylnaphthylene. In these hydrocarbylene groups, some or all of the hydrogen atoms may be substituted by a moiety containing a heteroatom such as oxygen, sulfur, nitrogen or halogen, or some constituent —CH2- may be replaced by a moiety containing a heteroatom such as oxygen, sulfur or nitrogen, so that the group may contain a hydroxy, cyano, fluorine, chlorine, bromine, iodine, carbonyl, ether bond, ester bond, sulfonate ester bond, carbonate bond, lactone ring, sultone ring, carboxylic anhydride (—C(═O)—O—C(═O)—) or haloalkyl moiety. Of the heteroatoms, oxygen is preferred.

In formula (5), L²¹ is a single bond, ether bond or a C₁-C₂₀ hydrocarbylene group which may contain a heteroatom. The hydrocarbylene group may be saturated or unsaturated and straight, branched or cyclic. Examples thereof are as exemplified above for the hydrocarbylene group R²⁰³.

In formula (5), X^{a}, X^{b}, X^{c} and X^{d} are each independently hydrogen, fluorine or trifluoromethyl, at least one of X^{a}, X^{b}, X° and X^{d} being fluorine or trifluoromethyl.

Of the PAGs having formula (5), those having formula (5′) are preferred.

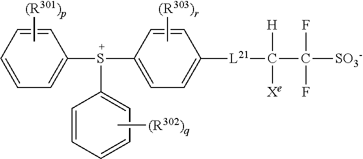

In formula (5′), L²¹ is as defined above. X^{e} is hydrogen or trifluoromethyl, preferably trifluoromethyl. R³⁰¹, R³⁰² and R³⁰³ are each independently hydrogen or a C₁-C₂₀ hydrocarbyl group which may contain a heteroatom. The hydrocarbyl group may be saturated or unsaturated and straight, branched or cyclic. Examples thereof are as exemplified above for R^{fa1} in formula (c1-1-1). The subscripts p and q are each independently 0, 1, 2, 3, 4 or 5, and r is 0, 1, 2, 3 or 4.

Examples of the PAG having formula (5) include those exemplified for the PAG having formula (2) in JP-A 2017-026980.

Of the foregoing PAGs, those having an anion of formula (c1-1-1), (c1-4) or (c1-5) are especially preferred because of reduced acid diffusion and high solubility in solvents. Also those having formula (5′) are especially preferred because of extremely reduced acid diffusion.

When used, the PAG (D) is preferably added in an amount of 0.1 to 40 parts, and more preferably 0.5 to 20 parts by weight per 80 parts by weight of the base polymer (A). As long as the amount of the PAG is in the range, good resolution is achievable and the risk of foreign particles being formed after development or during stripping of resist film is avoided. The PAG may be used alone or in admixture.

### (E) Surfactant

The resist composition may further include (E) a surfactant. Preferred are a surfactant which is insoluble or substantially insoluble in water and soluble in alkaline developer, and a surfactant which is insoluble or substantially insoluble in water and alkaline developer. For the surfactant, reference should be made to those compounds described in JP-A 2010-215608 and JP-A 2011-016746.

While many examples of the surfactant which is insoluble or substantially insoluble in water and alkaline developer are described in the patent documents cited herein, preferred examples are surfactants FC-4430 (3M), Olfine® E1004 (Nissin Chemical Co., Ltd.), Surflon® S-381, KH-20 and KH-30 (AGC Seimi Chemical Co., Ltd.). Partially fluorinated oxetane ring-opened polymers having the formula (surf-1) are also useful.

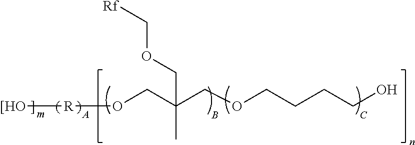

It is provided herein that R, Rf, A, B, C, m, and n are applied to only formula (surf-1), independent of their descriptions other than for the surfactant. R is a di- to tetra-valent C₂-C₅ aliphatic group. Exemplary divalent aliphatic groups include ethylene, 1,4-butylene, 1,2-propylene, 2,2-dimethyl-1,3-propylene and 1,5-pentylene. Exemplary tri- and tetra-valent groups are shown below.

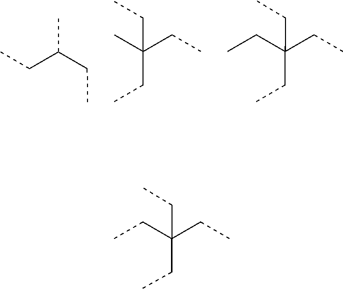

Herein the broken line denotes a valence bond. These formulae are partial structures derived from glycerol, trimethylol ethane, trimethylol propane, and pentaerythritol, respectively. Of these, 1,4-butylene and 2,2-dimethyl-1,3-propylene are preferably used.

Rf is trifluoromethyl or pentafluoroethyl, and preferably trifluoromethyl. The letter m is an integer of 0 to 3, n is an integer of 1 to 4, and the sum of m and n, which represents the valence of R, is an integer of 2 to 4. “A” is equal to 1, B is an integer of 2 to 25, and C is an integer of 0 to 10. Preferably, B is an integer of 4 to 20, and C is 0 or 1. Note that the formula (surf-1) does not prescribe the arrangement of respective constituent units while they may be arranged either blockwise or randomly. For the preparation of surfactants in the form of partially fluorinated oxetane ring-opened polymers, reference should be made to U.S. Pat. No. 5,650,483, for example.

The surfactant which is insoluble or substantially insoluble in water and soluble in alkaline developer is useful when ArF immersion lithography is applied to the resist composition in the absence of a resist protective film. In this embodiment, the surfactant has a propensity to segregate on the resist surface for achieving a function of minimizing water penetration or leaching. The surfactant is also effective for preventing water-soluble components from being leached out of the resist film for minimizing any damage to the exposure tool. The surfactant becomes solubilized during aqueous alkaline development following exposure and PEB, and thus forms few or no foreign particles which become defects. The preferred surfactant is a polymeric surfactant which is insoluble or substantially insoluble in water, but soluble in alkaline developer, also referred to as “hydrophobic resin” in this sense, and especially which is water repellent and enhances water sliding.

Suitable polymeric surfactants include those containing repeat units of at least one type selected from repeat units having the formula (6A), repeat units having the formula (6B), repeat units having the formula (6C), repeat units having the formula (6D), and repeat units having the formula (6E), which are also referred to as repeat units 6A, 6B, 6C, 6D, and 6E.

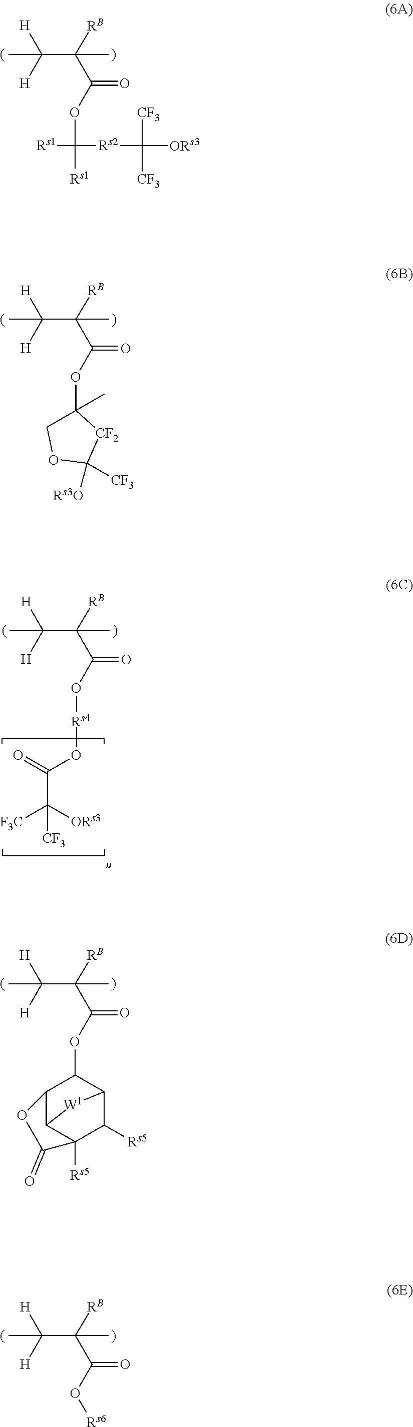

In formulae (6A) to (6E), R^{B} is hydrogen, fluorine, methyl or trifluoromethyl. W¹ is —CH₂—, —CH₂CH₂— or —O—, or two separate —H. R^{s1} is each independently hydrogen or a C₁-C₁₀ hydrocarbyl group. R^{s2} is a single bond or a C₁-C₅ straight or branched hydrocarbylene group. R^{s3} is each independently hydrogen, a C₁-C₁₅ hydrocarbyl or fluorinated hydrocarbyl group, or an acid labile group. When R^{s3} is a hydrocarbyl or fluorinated hydrocarbyl group, an ether bond or carbonyl moiety may intervene in a carbon-carbon bond. R^{s4} is a C₁-C₂₀ (u+1)-valent hydrocarbon or fluorinated hydrocarbon group, and u is 1, 2 or 3. R^{s5} is each independently hydrogen or a group: —C(═O)—O—R^{sa} wherein R^{sa} is a C₁-C₂₀ fluorinated hydrocarbyl group. R^{s6} is a C₁-C₁₅ hydrocarbyl or fluorinated hydrocarbyl group in which an ether bond or carbonyl moiety may intervene in a carbon-carbon bond.

The C₁-C₁₀ hydrocarbyl group represented by R^{s1} may be straight, branched or cyclic and is preferably saturated. Examples thereof include C₁-C₁₀ alkyl groups such as methyl, ethyl, n-propyl, isopropyl, n-butyl, isobutyl, sec-butyl, tert-butyl, n-pentyl, n-hexyl, n-heptyl, n-octyl, n-nonyl, n-decyl, and C₃-C₁₀ cyclic saturated hydrocarbyl groups such as cyclopropyl, cyclobutyl, cyclopentyl, cyclohexyl, adamantyl, and norbornyl. Inter alia, C₁-C₆ hydrocarbyl groups are preferred.

The hydrocarbylene group represented by R^{s2} may be straight, branched or cyclic and is preferably saturated. Examples thereof include methylene, ethylene, propylene, butylene and pentylene.

The hydrocarbyl group represented by R^{s3} or R^{s6} may be saturated or unsaturated and straight, branched or cyclic. Examples thereof include saturated hydrocarbyl groups, and aliphatic unsaturated hydrocarbyl groups such as alkenyl and alkynyl groups, with the saturated hydrocarbyl groups being preferred. Suitable saturated hydrocarbyl groups include those exemplified for the hydrocarbyl group represented by R^{s1} as well as undecyl, dodecyl, tridecyl, tetradecyl, and pentadecyl. Examples of the fluorinated hydrocarbyl group represented by R^{s3} or R^{s6} include the foregoing hydrocarbyl groups in which some or all carbon-bonded hydrogen atoms are substituted by fluorine atoms. In these groups, an ether bond or carbonyl moiety may intervene in a carbon-carbon bond as mentioned above.

Examples of the acid labile group represented by R^{s3} include groups of the above formulae (AL-3) to (AL-5), trialkylsilyl groups in which each alkyl moiety has 1 to 6 carbon atoms, and C₄-C₂₀ oxoalkyl groups.

The (u+1)-valent hydrocarbon or fluorinated hydrocarbon group represented by R^{s4} may be straight, branched or cyclic and examples thereof include the foregoing hydrocarbyl or fluorinated hydrocarbyl groups from which “u” number of hydrogen atoms are eliminated.

The fluorinated hydrocarbyl group represented by R^{sa} may be straight, branched or cyclic and is preferably saturated. Examples thereof include the foregoing hydrocarbyl groups in which some or all hydrogen atoms are substituted by fluorine atoms. Illustrative examples include trifluoromethyl, 2,2,2-trifluoroethyl, 3,3,3-trifluoro-1-propyl, 3,3,3-trifluoro-2-propyl, 2,2,3,3-tetrafluoropropyl, 1,1,1,3,3,3-hexafluoroisopropyl, 2,2,3,3,4,4,4-heptafluorobutyl, 2,2,3,3,4,4,5,5-octafluoropentyl, 2,2,3,3,4,4,5,5,6,6,7,7-dodecafluoroheptyl, 2-(perfluorobutyl)ethyl, 2-(perfluorohexyl)ethyl, 2-(perfluorooctyl)ethyl, and 2-(perfluorodecyl)ethyl.

Examples of the repeat units 6A to 6E are shown below, but not limited thereto. Herein R^{B} is as defined above.

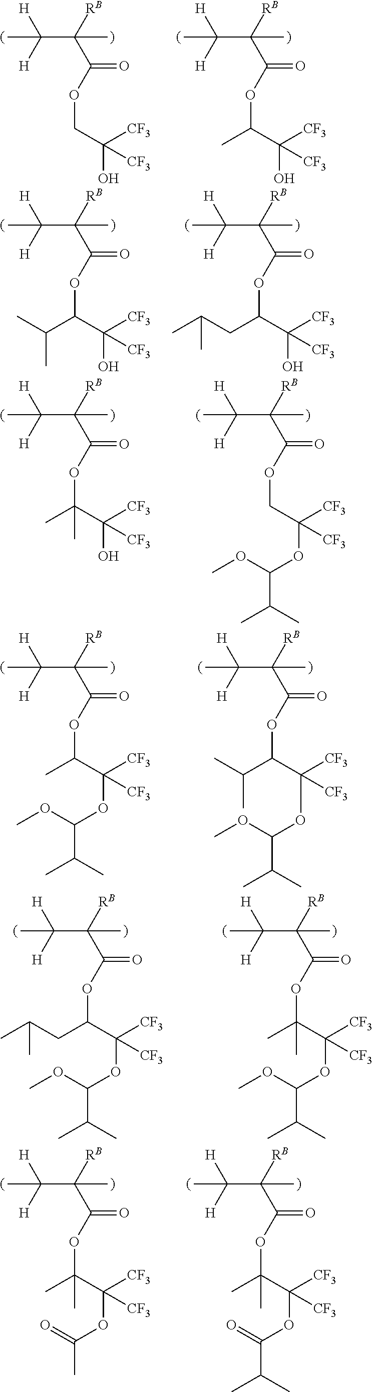

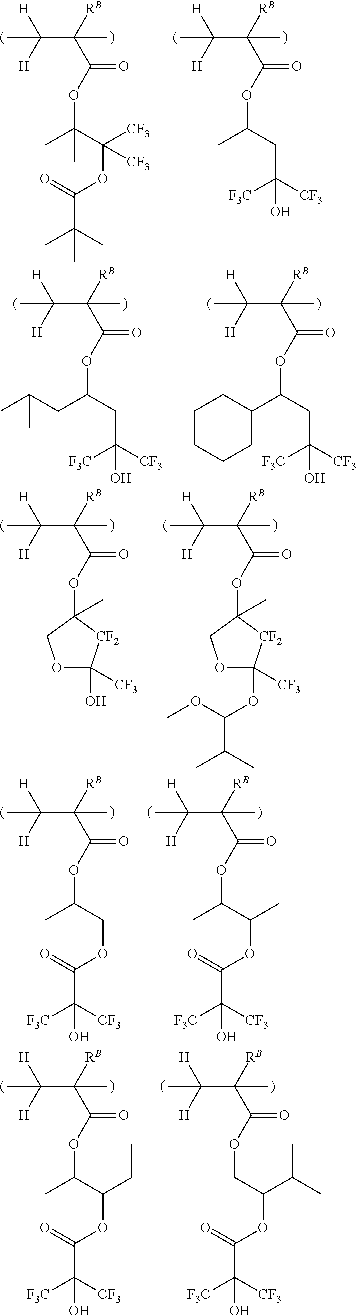

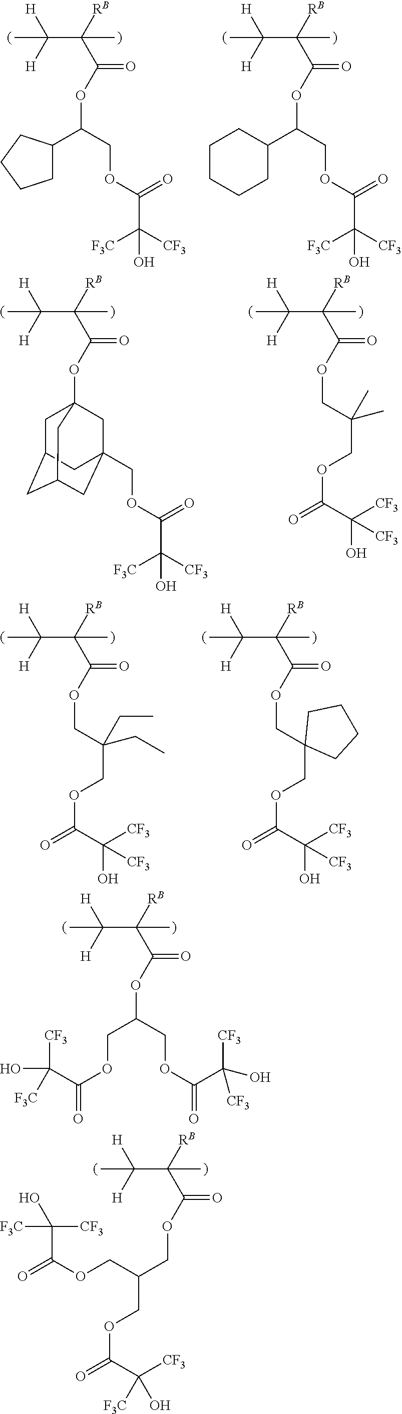

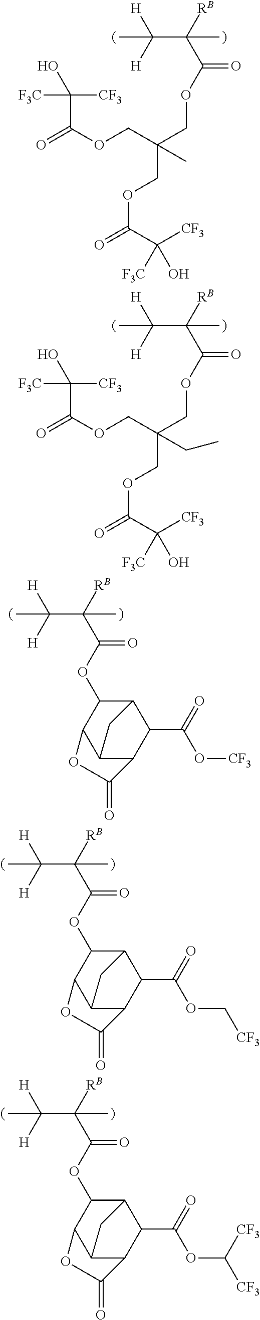

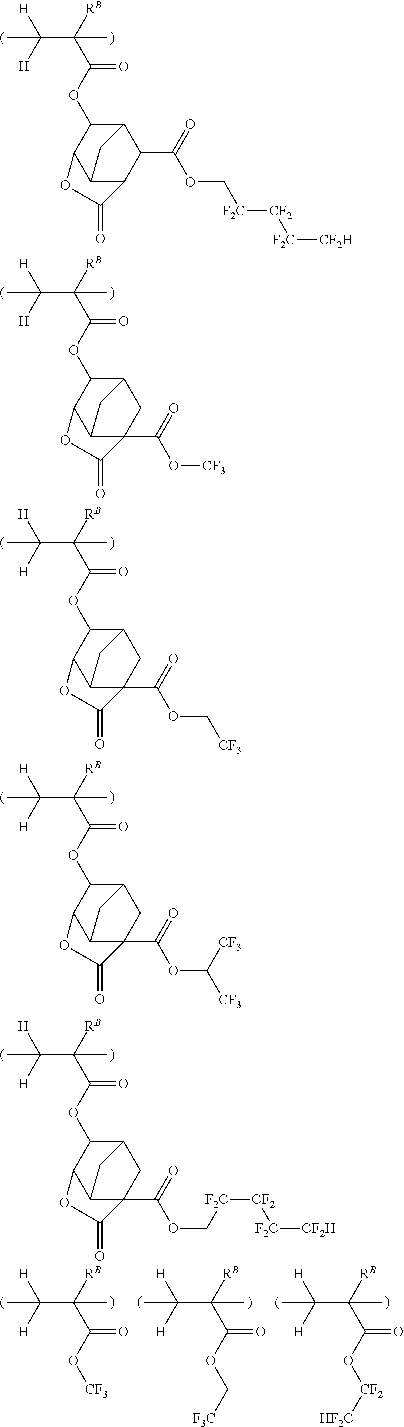

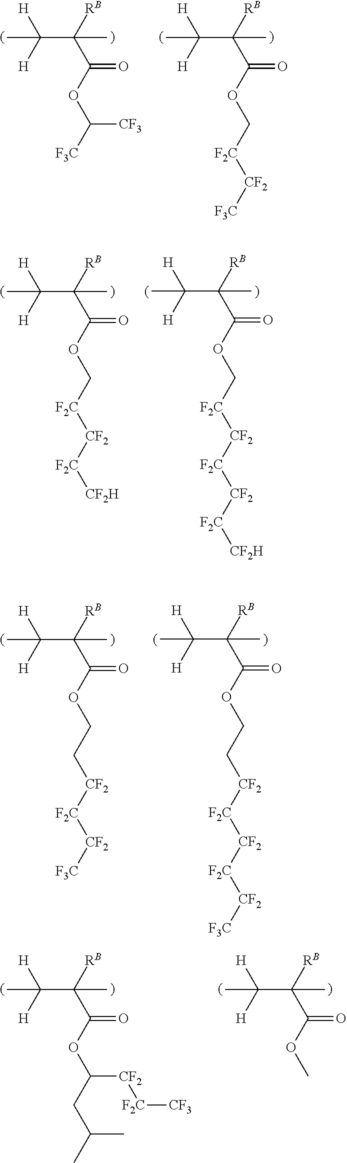

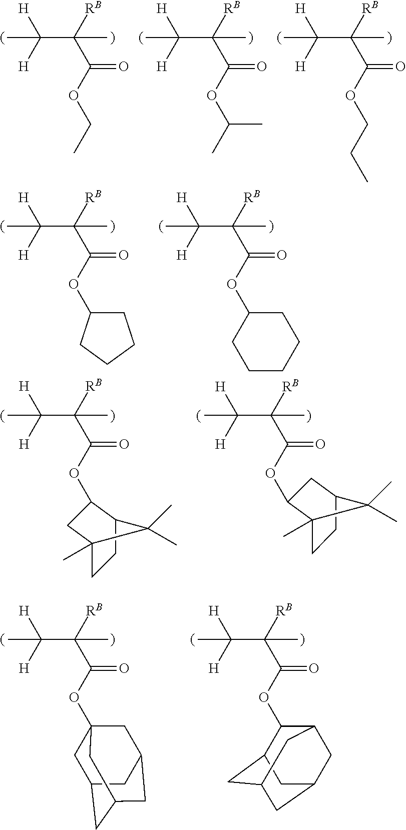

The polymeric surfactant may further contain repeat units other than the repeat units 6A to 6E. Typical other repeat units are those derived from methacrylic acid and α-trifluoromethylacrylic acid derivatives. In the polymeric surfactant, the content of the repeat units 6A to 6E is preferably at least 20 mol %, more preferably at least 60 mol %, most preferably 100 mol % of the overall repeat units.

The polymeric surfactant preferably has a Mw of 1, 000 to 500, 000, more preferably 3, 000 to 100, 000 and a Mw/Mn of 1.0 to 2.0, more preferably 1.0 to 1.6.

The polymeric surfactant may be synthesized by any desired method, for example, by dissolving an unsaturated bond-containing monomer or monomers providing repeat units 6A to 6E and optionally other repeat units in an organic solvent, adding a radical initiator, and heating for polymerization. Suitable organic solvents used herein include toluene, benzene, THF, diethyl ether, and dioxane. Examples of the polymerization initiator used herein include AIBN, 2,2′-azobis(2,4-dimethylvaleronitrile), dimethyl 2,2-azobis(2-methylpropionate), benzoyl peroxide, and lauroyl peroxide. Preferably the reaction temperature is 50 to 100 °C and the reaction time is 4 to 24 hours. The acid labile group that has been incorporated in the monomer may be kept as such, or the polymer may be protected or partially protected therewith at the end of polymerization.

During the synthesis of polymeric surfactant, any known chain transfer agent such as dodecyl mercaptan or 2-mercaptoethanol may be added for molecular weight control purpose. The amount of chain transfer agent added is preferably 0.01 to 10 mol % based on the total moles of monomers to be polymerized.

When the resist composition contains a surfactant (E), the amount thereof is preferably 0.1 to 50 parts by weight, and more preferably 0.5 to 10 parts by weight per 80 parts by weight of the base polymer (A). At least 0.1 part of the surfactant is effective in improving the receding contact angle with water of the resist film at its surface. Up to 50 parts of the surfactant is effective in forming a resist film having a low rate of dissolution in a developer and capable of maintaining the height of a small-size pattern formed therein. The surfactant (E) may be used alone or in admixture.

### (F) Other Components

The resist composition may further comprise (F) another component, for example, a compound which is decomposed with an acid to generate another acid (i.e., acid amplifier compound), an organic acid derivative, a fluorinated alcohol, and a compound having a Mw of up to 3, 000 which changes its solubility in developer under the action of an acid (i.e., dissolution inhibitor). Specifically, the acid amplifier compound is described in JP-A 2009-269953 and JP-A 2010-215608 and preferably used in an amount of 0 to 5 parts, more preferably 0 to 3 parts by weight per 80 parts by weight of the base polymer (A). An extra amount of the acid amplifier compound can make the acid diffusion control difficult and cause degradations to resolution and pattern profile. With respect to the remaining additives, reference should be made to JP-A 2009-269953 and JP-A 2010-215608.

### [Process]

A further embodiment of the invention is a process of forming a pattern from the resist composition defined above by lithography. The preferred process includes the steps of applying the resist composition onto a substrate to form a resist film thereon, exposing the resist film to high-energy radiation, and developing the exposed resist film in a developer. Any desired steps may be added to the process if necessary.

The substrate used herein may be a substrate for integrated circuitry fabrication, e.g., Si, SiO₂, SiN, SiON, TiN, WSi, BPSG, SOG, organic antireflective film, etc. or a substrate for mask circuitry fabrication, e.g., Cr, CrO, CrON, MoSi₂, SiO₂, etc.

The resist composition is applied onto a substrate by a suitable coating technique such as spin coating. The coating is prebaked on a hot plate preferably at a temperature of 60 to 150 °C for 1 to 10 minutes, more preferably at 80 to 140 °C for 1 to 5 minutes. The resulting resist film preferably has a thickness of 0.05 to 2 μm.

Then the resist film is exposed to a pattern of high-energy radiation, typically KrF or ArF excimer laser, EUV of wavelength 3 to 15 nm or EB. On use of KrF excimer laser, ArF excimer laser or EUV, the resist film is exposed through a mask having a desired pattern, preferably in a dose of 1 to 200 mJ/cm², more preferably 10 to 100 mJ/cm². On use of EB, a pattern may be written directly or through a mask having the desired pattern, preferably in a dose of 1 to 300 μC/cm², more preferably 10 to 200 μC/cm².

The exposure may be performed by conventional lithography whereas the immersion lithography of holding a liquid having a refractive index of at least 1.0 between the resist film and the projection lens may be employed if desired. The liquid is typically water, and in this case, a protective film which is insoluble in water may be formed on the resist film.

While the water-insoluble protective film serves to prevent any components from being leached out of the resist film and to improve water sliding on the film surface, it is generally divided into two types. The first type is an organic solvent-strippable protective film which must be stripped, prior to alkaline development, with an organic solvent in which the resist film is not dissolvable. The second type is an alkali-soluble protective film which is soluble in an alkaline developer so that it can be removed simultaneously with the removal of solubilized regions of the resist film. The protective film of the second type is preferably of a material comprising a polymer having a 1,1,1,3,3,3-hexafluoro-2-propanol residue (which is insoluble in water and soluble in an alkaline developer) as a base in an alcohol solvent of at least 4 carbon atoms, an ether solvent of 8 to 12 carbon atoms or a mixture thereof. Alternatively, the aforementioned surfactant which is insoluble in water and soluble in an alkaline developer may be dissolved in an alcohol solvent of at least 4 carbon atoms, an ether solvent of 8 to 12 carbon atoms or a mixture thereof to form a material from which the protective film of the second type is formed.

After the exposure, the resist film may be baked (PEB), for example, on a hotplate preferably at 60 to 150 °C for 1 to 5 minutes, more preferably at 80 to 140 °C for 1 to 3 minutes.

The resist film is then developed with a developer in the form of an aqueous base solution, for example, 0.1 to 5 wt %, preferably 2 to 3 wt % aqueous solution of tetramethylammonium hydroxide (TMAH) for 0.1 to 3 minutes, preferably 0.5 to 2 minutes by conventional techniques such as dip, puddle and spray techniques. In this way, the exposed region of the resist film is dissolved away, and a desired resist pattern is formed on the substrate.

Any desired step may be added to the pattern forming process. For example, after the resist film is formed, a step of rinsing with pure water may be introduced to extract the acid generator or the like from the film surface or wash away particles. After exposure, a step of rinsing may be introduced to remove any water remaining on the film after exposure.

Also, a double patterning process may be used for pattern formation. The double patterning process includes a trench process of processing an underlay to a 1:3 trench pattern by a first step of exposure and etching, shifting the position, and forming a 1:3 trench pattern by a second step of exposure, for forming a 1:1 pattern; and a line process of processing a first underlay to a 1:3 isolated left pattern by a first step of exposure and etching, shifting the position, processing a second underlay formed below the first underlay by a second step of exposure through the 1:3 isolated left pattern, for forming a half-pitch 1:1 pattern.

In the pattern forming process, negative tone development may also be used. That is, an organic solvent may be used instead of the aqueous alkaline solution as the developer for developing and dissolving away the unexposed region of the resist film.

The organic solvent used as the developer is preferably selected from 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, isopentyl acetate, butenyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, ethyl phenylacetate, benzyl formate, phenylethyl formate, methyl 3-phenylpropionate, benzyl propionate, and 2-phenylethyl acetate. These organic solvents may be used alone or in admixture of two or more.

### EXAMPLES

Synthesis Examples, Examples and Comparative Examples are given below by way of illustration and not by way of limitation. The abbreviation “pbw” is parts by weight. Analysis is made by time-of-flight mass spectrometry using an analyzer MALDI TOF-MS S3000 by JEOL Ltd.

### [1] Synthesis of Monomers

### Example 1-1

### Synthesis of Monomer A-1

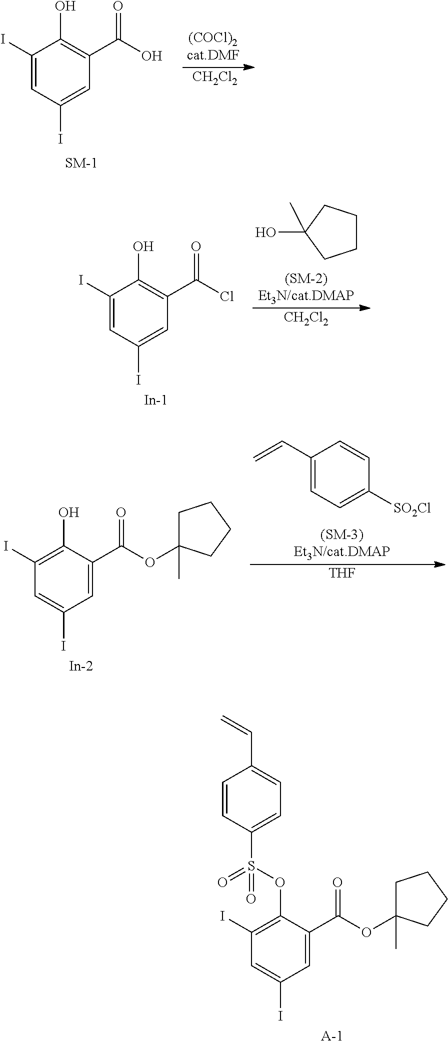

### (1) Synthesis of Intermediate In-1

Under nitrogen atmosphere, 389.9 g of reactant SM-1 and 0.7 g of DMF were suspended in 1,600 g of methylene chloride. The suspension was heated at a temperature of 35 °C, after which 152.3 g of oxalyl chloride was added dropwise. At the end of addition, the suspension was aged at the temperature of 35 °C for 4 hours. After aging, the reaction solution was cooled and concentrated to a 30 wt % methylene chloride solution. Intermediate In-1 was used in the subsequent step without further purification.

### (2) Synthesis of Intermediate In-2

Under nitrogen atmosphere, 110.2 g of reactant SM-2, 131.5 g of triethylamine, and 12.2 g of N,N-dimethylaminopyridine were dissolved in 500 g of methylene chloride. The solution was cooled in an ice bath. Thereafter, the 30 wt % methylene chloride solution of Intermediate In-1 was added dropwise to this solution while keeping the internal temperature below 30 °C. At the end of addition, the internal temperature was raised to 35 °C, at which the solution was aged for 8 hours. The reaction solution was cooled in an ice bath and 300 mL of water was added to quench the reaction. This was followed by standard aqueous workup, solvent distillation, and purification by silica gel column chromatography, obtaining Intermediate In-2 as oily matter (amount 358.8 g, yield 76%).

### (3) Synthesis of Monomer A-1

Under nitrogen atmosphere, 94.4 g of Intermediate In-2, 24.3 g of triethylamine and 2.4 g of N,N-dimethylaminopyridine were dissolved in 200 g of TIF. The solution was cooled in an ice bath. Reactant SM-3 was added dropwise to the solution while keeping the internal temperature below 20 °C. At the end of addition, the internal temperature was raised to 25 °C, at which the solution was aged for 8 hours. The reaction solution was cooled in an ice bath and 100 mL of saturated sodium bicarbonate water was added to quench the reaction. This was followed by standard aqueous workup, solvent distillation, and purification by silica gel column chromatography, obtaining Monomer A-1 as oily matter (amount 118.7 g, yield 93%).

The result of mass analysis of Monomer A-1 is shown below.
MASS: 638.9 [M+H]⁺

### Examples 1-2 to 1-11

### Synthesis of Monomers A-2 to A-11

Monomers A-2 to A-11 shown below were similarly synthesized using the corresponding reactants and organic synthesis reaction.

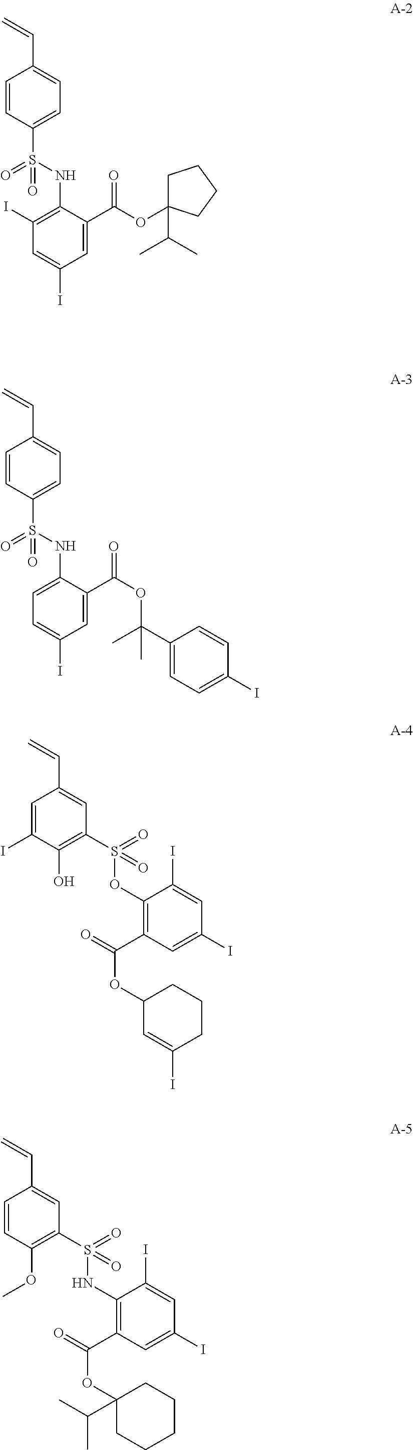 [SMILES: C=Cc1ccc(S(=O)(=O)Nc2c(I)cc(I)cc2C(=O)OC2(C(C)C)CCCC2)cc1 ; C=Cc1ccc(S(=O)(=O)Nc2ccc(I)cc2C(=O)OC(C)(C)c2ccc(I)cc2)cc1 ; C=Cc1cc(I)c(O)c(S(=O)(=O)Oc2c(I)cc(I)cc2C(=O)OC2C=C(I)CCC2)c1 ; C=Cc1ccc(OC)c(S(=O)(=O)Nc2c(I)cc(I)cc2C(=O)OC2(C(C)C)CCCCC2)c1]

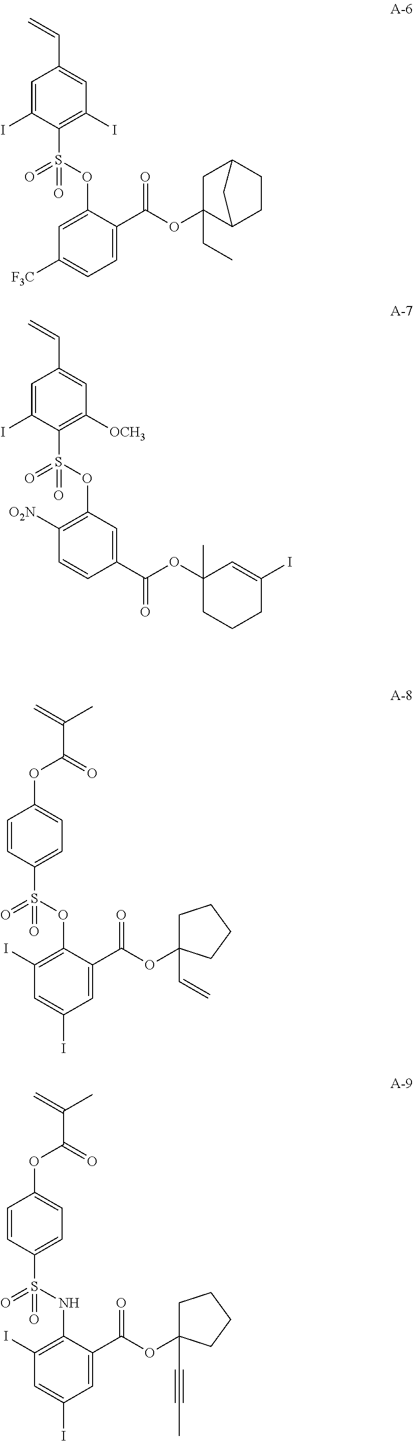

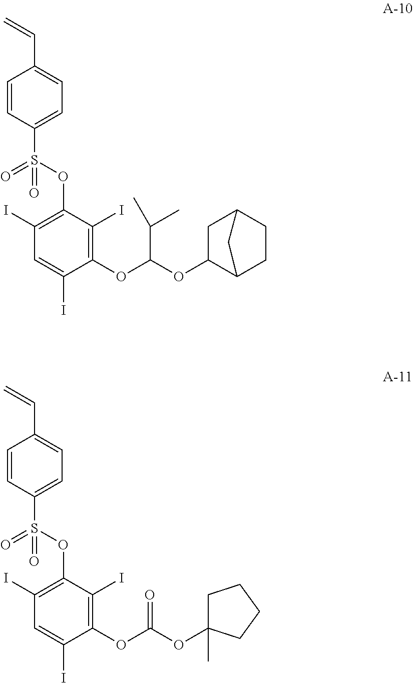 [SMILES: C=Cc1ccc(S(=O)(=O)Oc2c(I)cc(I)c(OC(OC3CC4CCC3C4)C(C)C)c2I)cc1 ; C=Cc1ccc(S(=O)(=O)Oc2c(I)cc(I)c(OC(=O)OC3(C)CCCC3)c2I)cc1]

### [2] Synthesis of Base Polymers

A variety of monomers were used in the synthesis of base polymers. The monomers other than Monomers A-1 to A-11 are shown below.

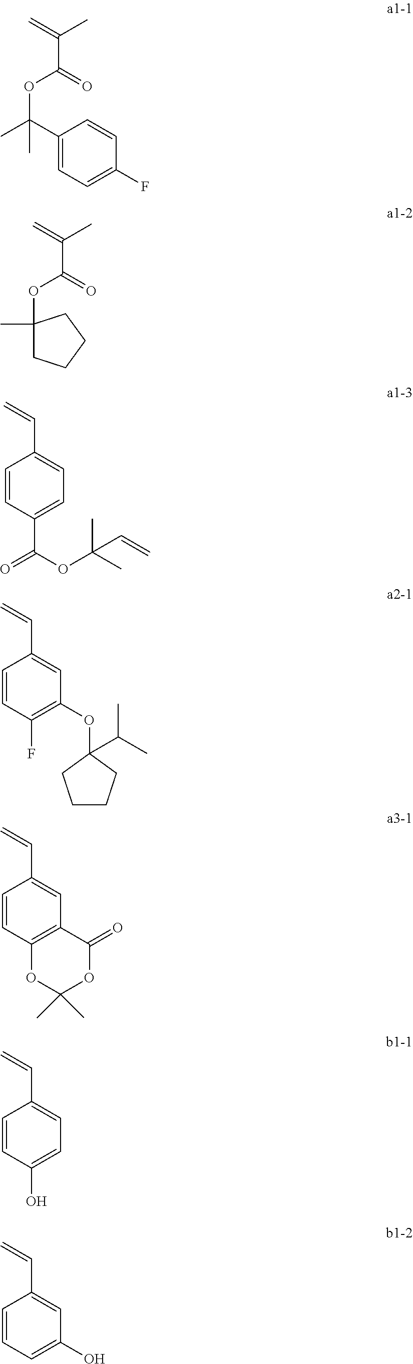

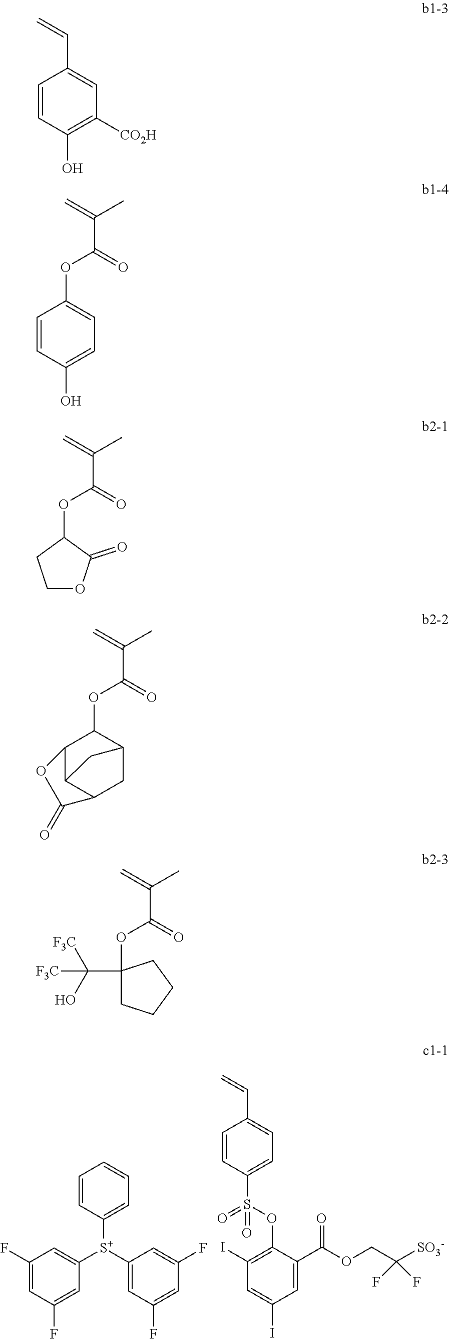

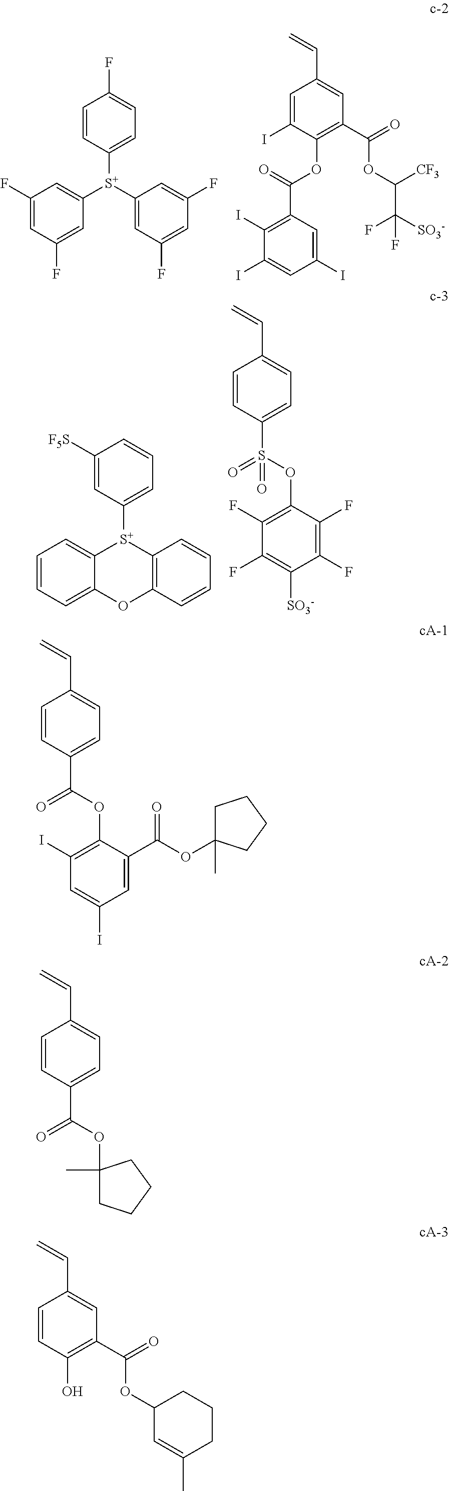

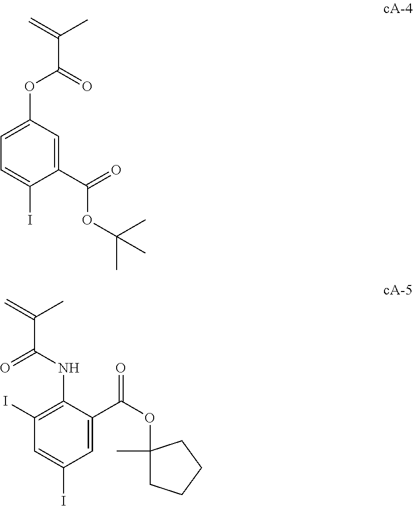

### Example 2-1

### Synthesis of Polymer P-1

A flask under nitrogen atmosphere was charged with 85.5 g of Monomer A-1, 14.7 g of Monomer Pre-b2-1, 2.57 g of dimethyl 2,2′-azobis(2-methylpropionate) (trade name V601, FUJIFILM Wako Pure Chemical Corp.), and 139 g of methyl ethyl ketone (MEK) solvent to form a monomer/initiator solution. Another flask under nitrogen atmosphere was charged with 46 g of MEK, which was heated at 80 °C with stirring. The monomer/initiator solution was added dropwise to the flask over 4 hours. At the end of dropwise addition, the solution was continuously stirred for 2 hours while the temperature of 80 °C was maintained during polymerization. The solution was cooled at room temperature, after which it was added dropwise to 2, 000 g of hexane with vigorous stirring. The precipitated polymer was collected by filtration and washed twice with 600 g of hexane, obtaining Polymer Pre-P-1 as crude powder. The crude powder was dissolved in 200 g of THF, after which 3.2 g of ethanolamine was added to the solution, which was aged at 50 °C for 2 hours. The solution was cooled, after which it was added dropwise to 2, 000 g of hexane with vigorous stirring. The precipitated polymer was collected by filtration, washed twice with 600 g of hexane, and vacuum dried at 50 °C for 20 hours, obtaining Polymer P-1 as white powder (amount 98.1 g, yield 98%). Polymer P-1 had a Mw of 6,800 and a Mw/Mn of 1.53. It is noted that Mw is determined by GPC versus polystyrene standards using DMF solvent.

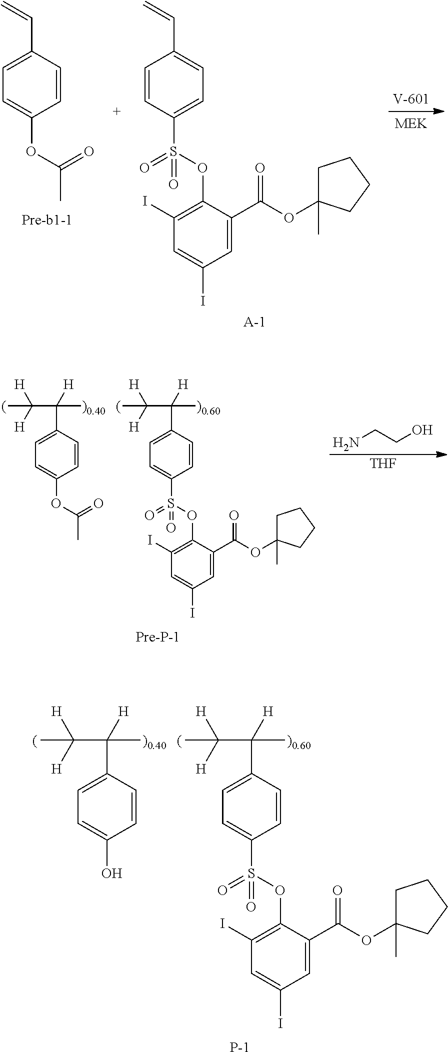

### Example 2-2

### Synthesis of Polymer P-46

A flask under nitrogen atmosphere was charged with 61.8 g of Monomer A-1, 8.1 g of Monomer b1-2, 30.1 g of Monomer c-1, 2.23 g of V601, and 139 g of MEK to form a monomer/initiator solution. Another flask under nitrogen atmosphere was charged with 46 g of MEK, which was heated at 80 °C with stirring. The monomer/initiator solution was added dropwise to the flask over 4 hours. At the end of dropwise addition, the solution was continuously stirred for 2 hours while the temperature of 80 °C was maintained during polymerization. The solution was cooled at room temperature, after which it was added dropwise to 2, 000 g of hexane with vigorous stirring. The precipitated polymer was collected by filtration, washed twice with 600 g of hexane, and vacuum dried at 50 °C for 20 hours, obtaining Polymer P-46 as white powder (amount 97.3 g, yield 97%). Polymer P-46 had a Mw of 9,700 and a Mw/Mn of 1.54. It is noted that Mw is determined by GPC versus polystyrene standards using DMF solvent.

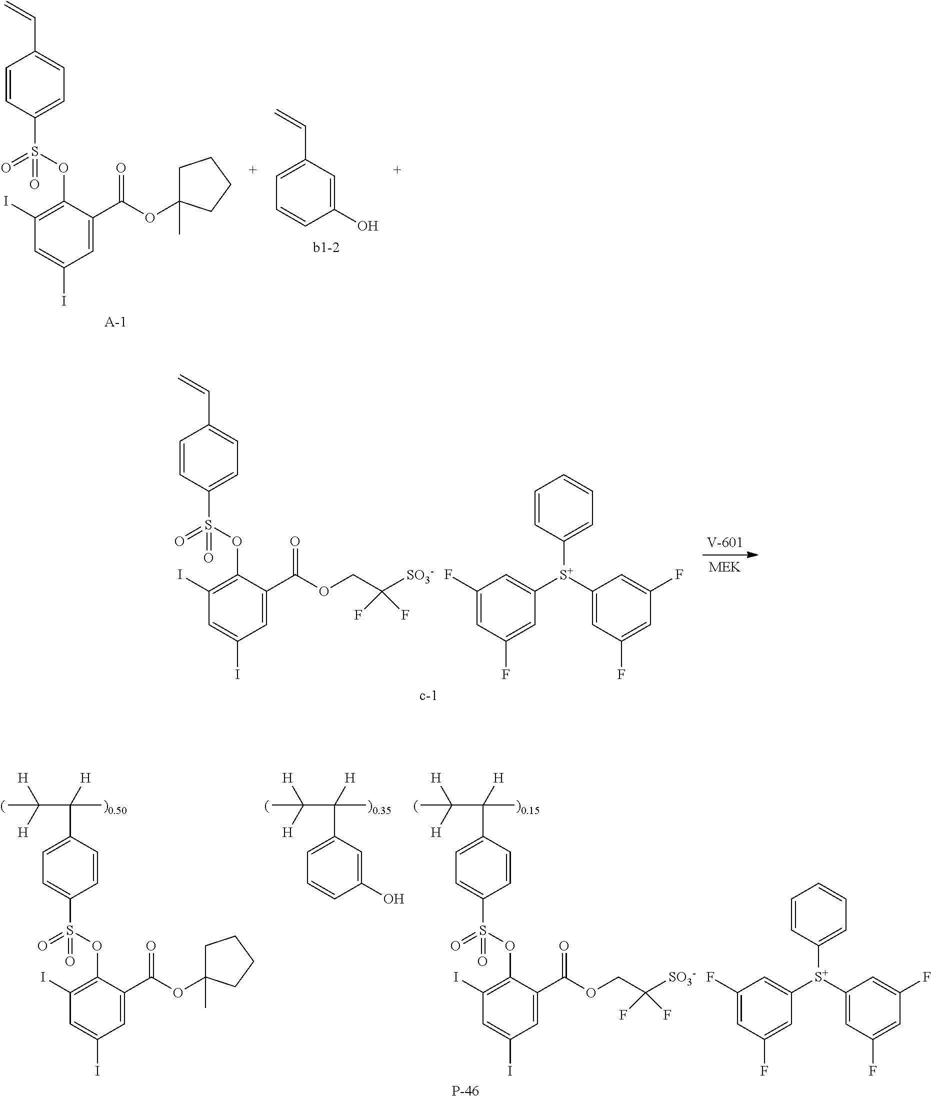

### Examples 2-3 to 2-80 and Comparative Examples 1-1 to 1-70

### Synthesis of Polymers P-2 to P-45 and P-47 to P-80 and Comparative Polymers CP-1 to CP-70

The base polymers shown in Tables 1 to 4 were synthesized by the same procedure as in Example 2-1, Example 2-2, and well-known procedures except that the type and amount of monomers were changed.

TABLE 1

| | | | | Incorpo- | | Incorpo- | | Incorpo- | | Incorpo- | | Incorpo- | | |
|---|---|---|---|---|---|---|---|---|---|---|---|---|---|---|
| | | | | ration | | ration | | ration | | ration | | ration | | |
| | | | | ratio | | ratio | | ratio | | ratio | | ratio | | |
| | | Polymer | Unit 1 | (mol %) | Unit 2 | (mol %) | Unit 3 | (mol %) | Unit 4 | (mol %) | Unit 5 | (mol %) | Mw | Mw/Mn |
| Example | 2-1 | P-1 | A-1 | 60 | b1-1 | 40 | — | — | — | — | — | — | 6,800 | 1.52 |
| | 2-2 | P-2 | A-2 | 60 | b1-1 | 40 | — | — | — | — | — | — | 6,700 | 1.51 |
| | 2-3 | P-3 | A-3 | 60 | b1-1 | 40 | — | — | — | — | — | — | 6,600 | 1.50 |
| | 2-4 | P-4 | A-4 | 60 | b1-1 | 40 | — | — | — | — | — | — | 6,900 | 1.51 |
| | 2-5 | P-5 | A-5 | 60 | b1-1 | 40 | — | — | — | — | — | — | 6,600 | 1.51 |
| | 2-6 | P-6 | A-6 | 60 | b1-1 | 40 | — | — | — | — | — | — | 6,900 | 1.52 |
| | 2-7 | P-7 | A-7 | 60 | b1-1 | 40 | — | — | — | — | — | — | 6,800 | 1.54 |
| | 2-8 | P-8 | A-8 | 60 | b1-1 | 40 | — | — | — | — | — | — | 6,700 | 1.54 |
| | 2-9 | P-9 | A-9 | 60 | b1-1 | 40 | — | — | — | — | — | — | 6,500 | 1.56 |
| | 2-10 | P-10 | A-10 | 60 | b1-1 | 40 | — | — | — | — | — | — | 6,900 | 1.53 |
| | 2-11 | P-11 | A-11 | 60 | b1-1 | 40 | — | — | — | — | — | — | 6,800 | 1.52 |
| | 2-12 | P-12 | A-1 | 50 | b1-2 | 50 | — | — | — | — | — | — | 6,600 | 1.54 |
| | 2-13 | P-13 | A-2 | 50 | b1-2 | 50 | — | — | — | — | — | — | 6,800 | 1.52 |
| | 2-14 | P-14 | A-3 | 50 | b1-2 | 50 | — | — | — | — | — | — | 6,800 | 1.51 |
| | 2-15 | P-15 | A-4 | 50 | b1-2 | 50 | — | — | — | — | — | — | 6,700 | 1.50 |
| | 2-16 | P-16 | A-5 | 50 | b1-2 | 50 | — | — | — | — | — | — | 6,900 | 1.53 |
| | 2-17 | P-17 | A-6 | 50 | b1-2 | 50 | — | — | — | — | — | — | 6,600 | 1.51 |
| | 2-18 | P-18 | A-7 | 50 | b1-2 | 50 | — | — | — | — | — | — | 6,800 | 1.51 |
| | 2-19 | P-19 | A-8 | 50 | b1-2 | 50 | — | — | — | — | — | — | 6,700 | 1.54 |
| | 2-20 | P-20 | A-9 | 50 | b1-2 | 50 | — | — | — | — | — | — | 6,700 | 1.53 |
| | 2-21 | P-21 | A-10 | 50 | b1-2 | 50 | — | — | — | — | — | — | 6,800 | 1.54 |
| | 2-22 | P-22 | A-11 | 50 | b1-2 | 50 | — | — | — | — | — | — | 6,900 | 1.52 |
| | 2-23 | P-23 | A-1 | 50 | b1-1 | 35 | b2-1 | 15 | — | — | — | — | 6,800 | 1.54 |
| | 2-24 | P-24 | A-1 | 50 | b1-1 | 35 | b2-2 | 15 | — | — | — | — | 6,800 | 1.55 |
| | 2-25 | P-25 | A-2 | 50 | b1-1 | 35 | b2-1 | 15 | — | — | — | — | 6,700 | 1.52 |
| | 2-26 | P-26 | A-3 | 50 | b1-1 | 35 | b2-2 | 15 | — | — | — | — | 6,600 | 1.51 |
| | 2-27 | P-27 | A-1 | 45 | b1-1 | 35 | b2-1 | 15 | b2-3 | 5 | — | — | 6,500 | 1.52 |
| | 2-28 | P-28 | A-1 | 30 | a1-1 | 20 | b1-1 | 50 | — | — | — | — | 6,800 | 1.53 |
| | 2-29 | P-29 | A-1 | 40 | a1-1 | 15 | b1-2 | 45 | — | — | — | — | 6,700 | 1.53 |
| | 2-30 | P-30 | A-1 | 40 | a1-1 | 10 | b1-3 | 35 | b2-2 | 15 | — | — | 6,800 | 1.54 |
| | 2-31 | P-31 | A-1 | 35 | a1-1 | 15 | b1-4 | 40 | b2-1 | 10 | — | — | 6,700 | 1.52 |
| | 2-32 | P-32 | A-1 | 35 | a1-2 | 15 | b1-1 | 50 | — | — | — | — | 6,900 | 1.51 |
| | 2-33 | P-33 | A-1 | 35 | a1-3 | 15 | b1-1 | 50 | — | — | — | — | 6,600 | 1.50 |
| | 2-34 | P-34 | A-1 | 35 | a2-1 | 15 | b1-1 | 50 | — | — | — | — | 6,500 | 1.51 |
| | 2-35 | P-35 | A-1 | 40 | a3-1 | 10 | b1-1 | 50 | — | — | — | — | 6,700 | 1.51 |
| | 2-36 | P-36 | A-2 | 45 | b1-1 | 35 | b1-1 | 15 | b2-3 | 5 | — | — | 6,600 | 1.56 |
| | 2-37 | P-37 | A-3 | 30 | a1-1 | 20 | b1-1 | 50 | — | — | — | — | 6,700 | 1.54 |
| | 2-38 | P-38 | A-4 | 40 | a1-1 | 15 | b1-2 | 45 | — | — | — | — | 6,900 | 1.53 |
| | 2-39 | P-39 | A-5 | 40 | a1-1 | 10 | b1-3 | 35 | b2-2 | 15 | — | — | 6,800 | 1.54 |
| | 2-40 | P-40 | A-6 | 35 | a1-1 | 15 | b1-4 | 40 | b2-1 | 10 | — | — | 6,800 | 1.55 |

TABLE 2

| | | | | Incorpo- | | Incorpo- | | Incorpo- | | Incorpo- | | Incorpo- | | |
|---|---|---|---|---|---|---|---|---|---|---|---|---|---|---|
| | | | | ration | | ration | | ration | | ration | | ration | | |
| | | | | ratio | | ratio | | ratio | | ratio | | ratio | | |
| | | Polymer | Unit 1 | (mol %) | Unit 2 | (mol %) | Unit 3 | (mol %) | Unit 4 | (mol %) | Unit 5 | (mol %) | Mw | Mw/Mn |
| Example | 2-41 | P-41 | A-7 | 35 | a1-2 | 15 | b1-2 | 50 | — | — | — | — | 6,700 | 1.54 |
| | 2-42 | P-42 | A-8 | 35 | a1-3 | 15 | b1-4 | 50 | — | — | — | — | 6,600 | 1.54 |
| | 2-43 | P-43 | A-9 | 35 | a2-1 | 15 | b2-2 | 50 | — | — | — | — | 6,500 | 1.52 |
| | 2-44 | P-44 | A-10 | 40 | a2-1 | 15 | b2-2 | 45 | — | — | — | — | 6,700 | 1.53 |
| | 2-45 | P-45 | A-1 | 35 | a1-2 | 15 | b1-1 | 40 | b2-2 | 10 | — | — | 6,800 | 1.53 |
| | 2-46 | P-46 | A-1 | 50 | b1-2 | 35 | c-1 | 15 | — | — | — | — | 9,700 | 1.54 |
| | 2-47 | P-47 | A-1 | 50 | b1-2 | 35 | c-2 | 15 | — | — | — | — | 9,600 | 1.52 |
| | 2-48 | P-48 | A-1 | 50 | b1-2 | 35 | c-3 | 15 | — | — | — | — | 9,800 | 1.51 |
| | 2-49 | P-49 | A-1 | 50 | b1-1 | 35 | c-1 | 15 | — | — | — | — | 9,900 | 1.50 |
| | 2-50 | P-50 | A-1 | 50 | b1-1 | 35 | c-2 | 15 | — | — | — | — | 9,700 | 1.51 |
| | 2-51 | P-51 | A-1 | 50 | b1-1 | 35 | c-3 | 15 | — | — | — | — | 9,600 | 1.51 |
| | 2-52 | P-52 | A-1 | 50 | b1-2 | 35 | c-1 | 15 | — | — | — | — | 9,400 | 1.52 |
| | 2-53 | P-53 | A-2 | 50 | b1-2 | 35 | c-1 | 15 | — | — | — | — | 9,800 | 1.51 |
| | 2-54 | P-54 | A-3 | 50 | b1-2 | 35 | c-1 | 15 | — | — | — | — | 9,700 | 1.50 |
| | 2-55 | P-55 | A-4 | 50 | b1-2 | 35 | c-1 | 15 | — | — | — | — | 9,800 | 1.51 |
| | 2-56 | P-56 | A-5 | 50 | b1-2 | 35 | c-1 | 15 | — | — | — | — | 9,400 | 1.51 |
| | 2-57 | P-57 | A-6 | 50 | b1-2 | 35 | c-1 | 15 | — | — | — | — | 9,600 | 1.52 |
| | 2-58 | P-58 | A-7 | 50 | b1-2 | 35 | c-1 | 15 | — | — | — | — | 9,700 | 1.54 |
| | 2-59 | P-59 | A-8 | 50 | b1-2 | 35 | c-1 | 15 | — | — | — | — | 9,600 | 1.53 |
| | 2-60 | P-60 | A-9 | 50 | b1-2 | 35 | c-1 | 15 | — | — | — | — | 9,600 | 1.54 |
| | 2-61 | P-61 | A-10 | 50 | b1-2 | 35 | c-1 | 15 | — | — | — | — | 9,600 | 1.52 |
| | 2-62 | P-62 | A-11 | 50 | b1-2 | 35 | c-1 | 15 | — | — | — | — | 9,400 | 1.54 |
| | 2-63 | P-63 | A-1 | 45 | b1-1 | 30 | b2-1 | 10 | c-1 | 15 | — | — | 9,500 | 1.54 |
| | 2-64 | P-64 | A-1 | 45 | b1-1 | 30 | b2-2 | 10 | c-1 | 15 | — | — | 9,600 | 1.52 |
| | 2-65 | P-65 | A-1 | 45 | b1-2 | 35 | b2-1 | 5 | c-1 | 15 | — | — | 9,400 | 1.53 |
| | 2-66 | P-66 | A-1 | 45 | b1-2 | 35 | b2-2 | 5 | c-1 | 15 | — | — | 9,600 | 1.51 |
| | 2-67 | P-67 | A-1 | 45 | b1-2 | 35 | b2-3 | 5 | c-1 | 15 | — | — | 9,400 | 1.51 |
| | 2-68 | P-68 | A-1 | 45 | b1-2 | 35 | b2-3 | 5 | c-2 | 15 | — | — | 9,600 | 1.52 |
| | 2-69 | P-69 | A-1 | 45 | b1-2 | 35 | b2-3 | 5 | c-3 | 15 | — | — | 9,500 | 1.54 |
| | 2-70 | P-70 | A-1 | 40 | a1-1 | 15 | b1-2 | 30 | c-1 | 15 | — | — | 9,800 | 1.53 |
| | 2-71 | P-71 | A-1 | 40 | a1-2 | 15 | b1-2 | 30 | c-1 | 15 | — | — | 9,600 | 1.54 |
| | 2-72 | P-72 | A-1 | 40 | a1-3 | 15 | b1-2 | 30 | c-1 | 15 | — | — | 9,600 | 1.52 |
| | 2-73 | P-73 | A-1 | 35 | a2-1 | 20 | b1-2 | 30 | c-1 | 15 | — | — | 9,400 | 1.54 |
| | 2-74 | P-74 | A-1 | 40 | a3-1 | 15 | b1-2 | 30 | c-1 | 15 | — | — | 9,800 | 1.53 |
| | 2-75 | P-75 | A-2 | 40 | a1-1 | 15 | b1-2 | 30 | c-2 | 15 | — | — | 9,800 | 1.54 |
| | 2-76 | P-76 | A-3 | 40 | a1-1 | 15 | b1-2 | 30 | c-3 | 15 | — | — | 9,600 | 1.52 |
| | 2-77 | P-77 | A-4 | 35 | a1-1 | 15 | b1-2 | 35 | b2-1 | 10 | c-1 | 5 | 9,500 | 1.54 |
| | 2-78 | P-78 | A-5 | 35 | a1-1 | 15 | b1-2 | 35 | b2-2 | 10 | c-2 | 5 | 9,800 | 1.52 |
| | 2-79 | P-79 | A-6 | 35 | a1-1 | 15 | b1-2 | 40 | b2-2 | 5 | c-3 | 5 | 9,400 | 1.54 |
| | 2-80 | P-80 | A-1 | 35 | a1-1 | 15 | b1-2 | 40 | b2-2 | 5 | c-1 | 5 | 9,600 | 1.52 |

TABLE 3

| | | | | Incorpo- | | Incorpo- | | Incorpo- | | Incorpo- | | Incorpo- | | |
|---|---|---|---|---|---|---|---|---|---|---|---|---|---|---|
| | | | | ration | | ration | | ration | | ration | | ration | | |
| | | | | ratio | | ratio | | ratio | | ratio | | ratio | | |
| | | Polymer | Unit 1 | (mol %) | Unit 2 | (mol %) | Unit 3 | (mol %) | Unit 4 | (mol %) | Unit 5 | (mol %) | Mw | Mw/Mn |
| Comparative | 1-1 | CP-1 | cA-1 | 60 | b1-1 | 40 | — | — | — | — | — | — | 6,600 | 1.52 |
| Example | 1-2 | CP-2 | cA-2 | 60 | b1-1 | 40 | — | — | — | — | — | — | 6,900 | 1.51 |
| | 1-3 | CP-3 | cA-3 | 60 | b1-1 | 40 | — | — | — | — | — | — | 6,600 | 1.50 |
| | 1-4 | CP-4 | cA-4 | 60 | b1-1 | 40 | — | — | — | — | — | — | 6,900 | 1.51 |
| | 1-5 | CP-5 | cA-5 | 60 | b1-1 | 40 | — | — | — | — | — | — | 6,800 | 1.51 |
| | 1-6 | CP-6 | a1-1 | 60 | b1-1 | 40 | — | — | — | — | — | — | 6,600 | 1.52 |
| | 1-7 | CP-7 | a1-2 | 60 | b1-1 | 40 | — | — | — | — | — | — | 6,900 | 1.54 |
| | 1-8 | CP-8 | a1-3 | 60 | b1-1 | 40 | — | — | — | — | — | — | 6,800 | 1.54 |
| | 1-9 | CP-9 | a2-1 | 60 | b1-1 | 40 | — | — | — | — | — | — | 6,700 | 1.55 |
| | 1-10 | CP-10 | a3-1 | 60 | b1-1 | 40 | — | — | — | — | — | — | 6,500 | 1.53 |
| | 1-11 | CP-11 | cA-1 | 50 | b1-2 | 50 | — | — | — | — | — | — | 6,900 | 1.52 |
| | 1-12 | CP-12 | cA-2 | 50 | b1-2 | 50 | — | — | — | — | — | — | 6,800 | 1.52 |
| | 1-13 | CP-13 | cA-3 | 50 | b1-2 | 50 | — | — | — | — | — | — | 6,800 | 1.54 |
| | 1-14 | CP-14 | cA-4 | 50 | b1-2 | 50 | — | — | — | — | — | — | 6,600 | 1.54 |
| | 1-15 | CP-15 | cA-5 | 50 | b1-2 | 50 | — | — | — | — | — | — | 6,900 | 1.55 |
| | 1-16 | CP-16 | a1-1 | 60 | b1-2 | 50 | — | — | — | — | — | — | 6,800 | 1.52 |
| | 1-17 | CP-17 | a1-2 | 60 | b1-2 | 50 | — | — | — | — | — | — | 6,700 | 1.54 |
| | 1-18 | CP-18 | a1-3 | 60 | b1-2 | 50 | — | — | — | — | — | — | 6,800 | 1.54 |
| | 1-19 | CP-19 | a2-1 | 60 | b1-2 | 50 | — | — | — | — | — | — | 6,600 | 1.55 |
| | 1-20 | CP-20 | a3-1 | 60 | b1-2 | 50 | — | — | — | — | — | — | 6,900 | 1.52 |
| | 1-21 | CP-21 | cA-1 | 50 | b1-1 | 35 | b2-1 | 15 | — | — | — | — | 6,800 | 1.52 |
| | 1-22 | CP-22 | cA-1 | 50 | b1-1 | 35 | b2-2 | 15 | — | — | — | — | 6,700 | 1.54 |
| | 1-23 | CP-23 | cA-2 | 50 | b1-1 | 35 | b2-1 | 15 | — | — | — | — | 6,700 | 1.55 |
| | 1-24 | CP-24 | cA-3 | 50 | b1-1 | 35 | b2-2 | 15 | — | — | — | — | 6,600 | 1.52 |
| | 1-25 | CP-25 | cA-1 | 45 | b1-1 | 35 | b2-1 | 15 | b2-3 | 5 | — | — | 6,500 | 1.54 |
| | 1-26 | CP-26 | cA-1 | 30 | a1-1 | 20 | b1-1 | 50 | — | — | — | — | 6,800 | 1.54 |
| | 1-27 | CP-27 | cA-1 | 40 | a1-1 | 15 | b1-2 | 45 | — | — | — | — | 6,700 | 1.55 |
| | 1-28 | CP-28 | cA-1 | 40 | a1-1 | 10 | b1-3 | 35 | b2-2 | 15 | — | — | 6,800 | 1.54 |
| | 1-29 | CP-29 | cA-1 | 35 | a1-1 | 15 | b1-4 | 40 | b2-1 | 10 | — | — | 6,700 | 1.52 |
| | 1-30 | CP-30 | cA-1 | 35 | a1-2 | 15 | b1-1 | 50 | — | — | — | — | 6,800 | 1.54 |
| | 1-31 | CP-31 | cA-1 | 35 | a1-3 | 15 | b1-1 | 50 | — | — | — | — | 6,600 | 1.55 |
| | 1-32 | CP-32 | cA-1 | 35 | a2-1 | 15 | b1-1 | 50 | — | — | — | — | 6,900 | 1.52 |
| | 1-33 | CP-33 | cA-1 | 40 | a3-1 | 10 | b1-1 | 50 | — | — | — | — | 6,800 | 1.54 |
| | 1-34 | CP-34 | cA-2 | 45 | b1-1 | 35 | b1-1 | 15 | b2-3 | 5 | — | — | 6,700 | 1.54 |
| | 1-35 | CP-35 | cA-3 | 30 | a1-1 | 20 | b1-1 | 50 | — | — | — | — | 6,700 | 1.55 |

TABLE 4

| | | | | Incorpo- | | Incorpo- | | Incorpo- | | Incorpo- | | Incorpo- | | |
|---|---|---|---|---|---|---|---|---|---|---|---|---|---|---|
| | | | | ration | | ration | | ration | | ration | | ration | | |
| | | | | ratio | | ratio | | ratio | | ratio | | ratio | | |
| | | Polymer | Unit 1 | (mol %) | Unit 2 | (mol %) | Unit 3 | (mol %) | Unit 4 | (mol %) | Unit 5 | (mol %) | Mw | Mw/Mn |
| Comparative | 1-36 | CP-36 | cA-4 | 40 | a1-1 | 15 | b1-2 | 45 | — | — | — | — | 6,800 | 1.53 |
| Example | 1-37 | CP-37 | cA-5 | 40 | a1-1 | 10 | b1-3 | 35 | b2-2 | 15 | — | — | 6,600 | 1.54 |
| | 1-38 | CP-38 | cA-2 | 35 | a1-1 | 15 | b1-4 | 40 | b2-1 | 10 | — | — | 6,900 | 1.55 |
| | 1-39 | CP-39 | cA-3 | 35 | a1-2 | 15 | b1-2 | 50 | — | — | — | — | 6,800 | 1.52 |
| | 1-40 | CP-40 | cA-4 | 35 | a1-3 | 15 | b1-4 | 50 | — | — | — | — | 6,700 | 1.54 |
| | 1-41 | CP-41 | cA-5 | 35 | a2-1 | 15 | b2-2 | 50 | — | — | — | — | 6,500 | 1.54 |
| | 1-42 | CP-42 | cA-1 | 50 | b1-2 | 35 | c-1 | 15 | — | — | — | — | 9,700 | 1.52 |
| | 1-43 | CP-43 | cA-1 | 50 | b1-2 | 35 | c-2 | 15 | — | — | — | — | 9,400 | 1.54 |
| | 1-44 | CP-44 | cA-1 | 50 | b1-2 | 35 | c-3 | 15 | — | — | — | — | 9,800 | 1.55 |
| | 1-45 | CP-45 | cA-1 | 50 | b1-1 | 35 | c-1 | 15 | — | — | — | — | 9,700 | 1.52 |
| | 1-46 | CP-46 | cA-1 | 50 | b1-1 | 35 | c-2 | 15 | — | — | — | — | 9,800 | 1.54 |
| | 1-47 | CP-47 | cA-1 | 50 | b1-1 | 35 | c-3 | 15 | — | — | — | — | 9,600 | 1.54 |
| | 1-48 | CP-48 | cA-2 | 50 | b1-2 | 35 | c-1 | 15 | — | — | — | — | 9,400 | 1.54 |
| | 1-49 | CP-49 | cA-3 | 50 | b1-2 | 35 | c-1 | 15 | — | — | — | — | 9,600 | 1.55 |
| | 1-50 | CP-50 | cA-4 | 50 | b1-2 | 35 | c-1 | 15 | — | — | — | — | 9,500 | 1.51 |
| | 1-51 | CP-51 | cA-5 | 50 | b1-2 | 35 | c-1 | 15 | — | — | — | — | 9,800 | 1.52 |
| | 1-52 | CP-52 | cA-1 | 45 | b1-1 | 30 | b2-1 | 10 | c-1 | 15 | — | — | 9,700 | 1.54 |
| | 1-53 | CP-53 | cA-1 | 45 | b1-1 | 30 | b2-2 | 10 | c-1 | 15 | — | — | 9,400 | 1.55 |
| | 1-54 | CP-54 | cA-1 | 45 | b1-2 | 35 | b2-1 | 5 | c-1 | 15 | — | — | 9,800 | 1.52 |
| | 1-55 | CP-55 | cA-1 | 45 | b1-2 | 35 | b2-2 | 5 | c-1 | 15 | — | — | 9,700 | 1.54 |
| | 1-56 | CP-56 | cA-1 | 45 | b1-2 | 35 | b2-3 | 5 | c-1 | 15 | — | — | 9,800 | 1.54 |
| | 1-57 | CP-57 | cA-1 | 45 | b1-2 | 35 | b2-3 | 5 | c-2 | 15 | — | — | 9,600 | 1.52 |
| | 1-58 | CP-58 | cA-1 | 45 | b1-2 | 35 | b2-3 | 5 | c-3 | 15 | — | — | 9,400 | 1.52 |
| | 1-59 | CP-59 | cA-1 | 40 | a1-1 | 15 | b1-2 | 30 | c-1 | 15 | — | — | 9,400 | 1.54 |
| | 1-60 | CP-60 | cA-1 | 40 | a1-2 | 15 | b1-2 | 30 | c-1 | 15 | — | — | 9,600 | 1.53 |
| | 1-61 | CP-61 | cA-1 | 40 | a1-3 | 15 | b1-2 | 30 | c-1 | 15 | — | — | 9,700 | 1.52 |
| | 1-62 | CP-62 | cA-1 | 35 | a2-1 | 20 | b1-2 | 30 | c-1 | 15 | — | — | 9,400 | 1.54 |
| | 1-63 | CP-63 | cA-1 | 40 | a3-1 | 15 | b1-2 | 30 | c-1 | 15 | — | — | 9,800 | 1.54 |
| | 1-64 | CP-64 | cA-2 | 40 | a1-1 | 15 | b1-2 | 30 | c-2 | 15 | — | — | 9,700 | 1.52 |
| | 1-65 | CP-65 | cA-3 | 40 | a1-1 | 15 | b1-2 | 30 | c-3 | 15 | — | — | 9,800 | 1.54 |
| | 1-66 | CP-66 | cA-4 | 35 | a1-1 | 15 | b1-2 | 35 | b2-1 | 10 | c-1 | 5 | 9,600 | 1.55 |
| | 1-67 | CP-67 | cA-5 | 35 | a1-1 | 15 | b1-2 | 35 | b2-2 | 10 | c-2 | 5 | 9,400 | 1.52 |
| | 1-68 | CP-68 | cA-1 | 35 | a1-1 | 15 | b1-2 | 40 | b2-2 | 5 | c-3 | 5 | 9,800 | 1.54 |
| | 1-69 | CP-69 | cA-1 | 35 | a1-1 | 15 | b1-2 | 40 | b2-2 | 5 | c-1 | 5 | 9,600 | 1.54 |
| | 1-70 | CP-70 | cA-2 | 35 | a1-1 | 15 | b1-2 | 40 | b2-2 | 5 | c-1 | 5 | 9,600 | 1.52 |

### [3] Preparation of Chemically Amplified Resist Compositions

### Examples 3-1 to 3-80 and Comparative Examples 2-1 to 2-70

A chemically amplified resist composition (R-1 to R-80, CR-1 to CR-70) in solution form was prepared by dissolving a base polymer (P-1 to P-80), comparative base polymer (CP-1 to CP-70), photoacid generator (PAG-X to PAG-Z), and quencher (Q-1 to Q-4) in an organic solvent in accordance with the recipe shown in Tables 5 to 8, and filtering the solution through a Teflon® filter with a pore size of 0.2 μm. The organic solvent contained 0.01% by weight of surfactant A.

TABLE 5

| | | | Base | Photoacid | | | | |
|---|---|---|---|---|---|---|---|---|
| | | Resist | polymer | generator | Quencher | Solvent 1 | Solvent 2 | Solvent 3 |
| | | composition | (pbw) | (pbw) | (pbw) | (pbw) | (pbw) | (pbw) |
| Example | 3-1 | R-1 | P-1 (80) | PAG-X (20) | Q-1 (7.8) | PGMEA (2250) | EL (2800) | DAA (550) |
| | 3-2 | R-2 | P-2 (80) | PAG-X (20) | Q-1 (7.6) | PGMEA (2250) | EL (2800) | DAA (550) |
| | 3-3 | R-3 | P-3 (80) | PAG-X (20) | Q-1 (7.8) | PGMEA (2250) | EL (2800) | DAA (550) |
| | 3-4 | R-4 | P-4 (80) | PAG-X (20) | Q-1 (7.8) | PGMEA (2250) | EL (2800) | DAA (550) |
| | 3-5 | R-5 | P-5 (80) | PAG-X (20) | Q-1 (7.8) | PGMEA (2250) | EL (2800) | DAA (550) |
| | 3-6 | R-6 | P-6 (80) | PAG-X (20) | Q-1 (7.4) | PGMEA (2250) | EL (2800) | DAA (550) |
| | 3-7 | R-7 | P-7 (80) | PAG-X (20) | Q-1 (7.8) | PGMEA (2250) | EL (2800) | DAA (550) |
| | 3-8 | R-8 | P-8 (80) | PAG-X (20) | Q-1 (7.8) | PGMEA (2250) | EL (2800) | DAA (550) |
| | 3-9 | R-9 | P-9 (80) | PAG-X (20) | Q-1 (7.8) | PGMEA (2250) | EL (2800) | DAA (550) |
| | 3-10 | R-10 | P-10 (80) | PAG-X (20) | Q-1 (7.8) | PGMEA (2250) | EL (2800) | DAA (550) |
| | 3-11 | R-11 | P-11 (80) | PAG-X (20) | Q-1 (7.8) | PGMEA (2250) | EL (2800) | DAA (550) |
| | 3-12 | R-12 | P-12 (80) | PAG-X (20) | Q-1 (7.6) | PGMEA (2250) | EL (2800) | DAA (550) |
| | 3-13 | R-13 | P-13 (80) | PAG-X (20) | Q-1 (7.8) | PGMEA (2250) | EL (2800) | DAA (550) |
| | 3-14 | R-14 | P-14 (80) | PAG-X (20) | Q-1 (7.8) | PGMEA (2250) | EL (2800) | DAA (550) |
| | 3-15 | R-15 | P-15 (80) | PAG-X (20) | Q-1 (7.8) | PGMEA (2250) | EL (2800) | DAA (550) |
| | 3-16 | R-16 | P-16 (80) | PAG-X (20) | Q-1 (7.6) | PGMEA (2250) | EL (2800) | DAA (550) |
| | 3-17 | R-17 | P-17 (80) | PAG-X (20) | Q-1 (7.8) | PGMEA (2250) | EL (2800) | DAA (550) |
| | 3-18 | R-18 | P-18 (80) | PAG-X (20) | Q-1 (7.6) | PGMEA (2250) | EL (2800) | DAA (550) |
| | 3-19 | R-19 | P-19 (80) | PAG-X (20) | Q-1 (7.8) | PGMEA (2250) | EL (2800) | DAA (550) |
| | 3-20 | R-20 | P-20 (80) | PAG-X (20) | Q-1 (7.8) | PGMEA (2250) | EL (2800) | DAA (550) |
| | 3-21 | R-21 | P-21 (80) | PAG-X (20) | Q-1 (7.4) | PGMEA (2250) | EL (2800) | DAA (550) |
| | 3-22 | R-22 | P-22 (80) | PAG-X (20) | Q-1 (7.6) | PGMEA (2250) | EL (2800) | DAA (550) |
| | 3-23 | R-23 | P-23 (80) | PAG-Y (20) | Q-2 (7.8) | PGMEA (2250) | EL (2800) | DAA (550) |
| | 3-24 | R-24 | P-24 (80) | PAG-Y (20) | Q-3 (7.8) | PGMEA (2250) | EL (2800) | DAA (550) |
| | 3-25 | R-25 | P-25 (80) | PAG-X (20) | Q-1 (7.8) | PGMEA (2250) | EL (2800) | DAA (550) |
| | 3-26 | R-26 | P-26 (80) | PAG-X (20) | Q-3 (7.8) | PGMEA (2250) | EL (2800) | DAA (550) |
| | 3-27 | R-27 | P-27 (80) | PAG-X (20) | Q-2 (4.8) | PGMEA (2250) | EL (2800) | DAA (550) |
| | | | | | Q-4 (3.0) | | | |
| | 3-28 | R-28 | P-28 (80) | PAG-X (20) | Q-1 (7.8) | PGMEA (2250) | EL (2800) | DAA (550) |
| | 3-29 | R-29 | P-29 (80) | PAG-X (20) | Q-3 (7.8) | PGMEA (2250) | EL (2800) | DAA (550) |
| | 3-30 | R-30 | P-30 (80) | PAG-X (20) | Q-1 (7.8) | PGMEA (2250) | EL (2800) | DAA (550) |
| | 3-31 | R-31 | P-31 (80) | PAG-Y (20) | Q-2 (7.8) | PGMEA (2250) | EL (2800) | DAA (550) |
| | 3-32 | R-32 | P-32 (80) | PAG-X (20) | Q-2 (7.8) | PGMEA (2250) | EL (2800) | DAA (550) |
| | 3-33 | R-33 | P-33 (80) | PAG-X (20) | Q-1 (4.8) | PGMEA (2250) | EL (2800) | DAA (550) |
| | | | | | Q-4 (3.0) | | | |
| | 3-34 | R-34 | P-34 (80) | PAG-Y (20) | Q-2 (7.8) | PGMEA (2250) | EL (2800) | DAA (550) |
| | 3-35 | R-35 | P-35 (80) | PAG-Y (20) | Q-3 (7.8) | PGMEA (2250) | EL (2800) | DAA (550) |
| | 3-36 | R-36 | P-36 (80) | PAG-X (20) | Q-1 (7.8) | PGMEA (2250) | EL (2800) | DAA (550) |
| | 3-37 | R-37 | P-37 (80) | PAG-Y (20) | Q-2 (7.8) | PGMEA (2250) | EL (2800) | DAA (550) |
| | 3-38 | R-38 | P-38 (80) | PAG-X (20) | Q-3 (7.6) | PGMEA (2250) | EL (2800) | DAA (550) |
| | 3-39 | R-39 | P-39 (80) | PAG-Z (24) | Q-1 (7.4) | PGMEA (2250) | EL (2800) | DAA (550) |
| | 3-40 | R-40 | P-40 (80) | PAG-X (20) | Q-3 (7.6) | PGMEA (2250) | EL (2800) | DAA (550) |

TABLE 6

| | | | Base | Photoacid | | | | |
|---|---|---|---|---|---|---|---|---|
| | | Resist | polymer | generator | Quencher | Solvent 1 | Solvent 2 | Solvent 3 |
| | | composition | (pbw) | (pbw) | (pbw) | (pbw) | (pbw) | (pbw) |
| Example | 3-41 | R-41 | P-41 (80) | PAG-X (20) | Q-2 (7.8) | PGMEA (2250) | EL (2800) | DAA (550) |
| | 3-42 | R-42 | P-42 (80) | PAG-Y (20) | Q-1 (7.8) | PGMEA (2250) | EL (2800) | DAA (550) |
| | 3-43 | R-43 | P-43 (80) | PAG-X (12) | Q-2 (7.8) | PGMEA (2250) | EL (2800) | DAA (550) |
| | | | | PAG-Z (8) | | | | |
| | 3-44 | R-44 | P-44 (80) | PAG-Y (20) | Q-1 (4.8) | PGMEA (2250) | EL (2800) | DAA (550) |
| | | | | | Q-4 (3.0) | | | |
| | 3-45 | R-45 | P-45 (80) | PAG-Y (12) | Q-1 (7.8) | PGMEA (2250) | EL (2800) | DAA (550) |
| | | | | PAG-Z (8) | | | | |
| | 3-46 | R-46 | P-46 (80) | — | Q-1 (7.8) | PGMEA (2250) | EL (2800) | DAA (550) |
| | 3-47 | R-47 | P-47 (80) | — | Q-3 (7.8) | PGMEA (2250) | EL (2800) | DAA (550) |
| | 3-48 | R-48 | P-48 (80) | — | Q-1 (7.8) | PGMEA (2250) | EL (2800) | DAA (550) |
| | 3-49 | R-49 | P-49 (80) | — | Q-3 (7.8) | PGMEA (2250) | EL (2800) | DAA (550) |
| | 3-50 | R-50 | P-50 (80) | — | Q-1 (7.4) | PGMEA (2250) | EL (2800) | DAA (550) |
| | 3-51 | R-51 | P-51 (80) | — | Q-2 (7.6) | PGMEA (2250) | EL (2800) | DAA (550) |
| | 3-52 | R-52 | P-52 (80) | — | Q-1 (7.8) | PGMEA (2250) | EL (2800) | DAA (550) |
| | 3-53 | R-53 | P-53 (80) | — | Q-3 (7.8) | PGMEA (2250) | EL (2800) | DAA (550) |
| | 3-54 | R-54 | P-54 (80) | — | Q-2 (4.8) | PGMEA (2250) | EL (2800) | DAA (550) |
| | | | | | Q-4 (3.0) | | | |
| | 3-55 | R-55 | P-55 (80) | — | Q-1 (7.8) | PGMEA (2250) | EL (2800) | DAA (550) |
| | 3-56 | R-56 | P-56 (80) | — | Q-2 (7.8) | PGMEA (2250) | EL (2800) | DAA (550) |
| | 3-57 | R-57 | P-57 (80) | — | Q-1 (7.8) | PGMEA (2250) | EL (2800) | DAA (550) |
| | 3-58 | R-58 | P-58 (80) | — | Q-3 (7.4) | PGMEA (2250) | EL (2800) | DAA (550) |
| | 3-59 | R-59 | P-59 (80) | — | Q-1 (7.8) | PGMEA (2250) | EL (2800) | DAA (550) |
| | 3-60 | R-60 | P-60 (80) | — | Q-1 (7.6) | PGMEA (2250) | EL (2800) | DAA (550) |
| | 3-61 | R-61 | P-61 (80) | — | Q-3 (7.8) | PGMEA (2250) | EL (2800) | DAA (550) |
| | 3-62 | R-62 | P-62 (80) | — | Q-2 (7.8) | PGMEA (2250) | EL (2800) | DAA (550) |
| | 3-63 | R-63 | P-63 (80) | — | Q-1 (7.8) | PGMEA (2250) | EL (2800) | DAA (550) |
| | 3-64 | R-64 | P-64 (80) | — | Q-2 (7.8) | PGMEA (2250) | EL (2800) | DAA (550) |
| | 3-65 | R-65 | P-65 (80) | — | Q-1 (7.8) | PGMEA (2250) | EL (2800) | DAA (550) |
| | 3-66 | R-66 | P-66 (80) | — | Q-3 (4.8) | PGMEA (2250) | EL (2800) | DAA (550) |
| | | | | | Q-4 (3.0) | | | |
| | 3-67 | R-67 | P-67 (80) | — | Q-3 (7.8) | PGMEA (2250) | EL (2800) | DAA (550) |
| | 3-68 | R-68 | P-68 (80) | — | Q-1 (7.8) | PGMEA (2250) | EL (2800) | DAA (550) |
| | 3-69 | R-69 | P-69 (80) | — | Q-2 (7.8) | PGMEA (2250) | EL (2800) | DAA (550) |
| | 3-70 | R-70 | P-70 (80) | — | Q-1 (7.6) | PGMEA (2250) | EL (2800) | DAA (550) |
| | 3-71 | R-71 | P-71 (80) | — | Q-2 (7.8) | PGMEA (2250) | EL (2800) | DAA (550) |
| | 3-72 | R-72 | P-72 (80) | — | Q-3 (7.8) | PGMEA (2250) | EL (2800) | DAA (550) |
| | 3-73 | R-73 | P-73 (80) | — | Q-1 (7.8) | PGMEA (2250) | EL (2800) | DAA (550) |
| | 3-74 | R-74 | P-74 (80) | — | Q-2 (7.6) | PGMEA (2250) | EL (2800) | DAA (550) |
| | 3-75 | R-75 | P-75 (80) | — | Q-1 (7.8) | PGMEA (2250) | EL (2800) | DAA (550) |
| | 3-76 | R-76 | P-76 (80) | — | Q-2 (7.6) | PGMEA (2250) | EL (2800) | DAA (550) |
| | 3-77 | R-77 | P-77 (80) | PAG-X (8) | Q-1 (7.8) | PGMEA (2250) | EL (2800) | DAA (550) |
| | 3-78 | R-78 | P-78 (80) | PAG-Y (8) | Q-2 (7.8) | PGMEA (2250) | EL (2800) | DAA (550) |
| | 3-79 | R-79 | P-79 (80) | PAG-X (6) | Q-3 (7.6) | PGMEA (2250) | EL (2800) | DAA (550) |
| | | | | PAG-Z (2) | | | | |
| | 3-80 | R-80 | P-80 (80) | PAG-Y (6) | Q-1 (7.8) | PGMEA (2250) | EL (2800) | DAA (550) |
| | | | | PAG-Z (2) | | | | |

TABLE 7

| | | | Base | Photoacid | | | | |
|---|---|---|---|---|---|---|---|---|
| | | Resist | polymer | generator | Quencher | Solvent 1 | Solvent 2 | Solvent 3 |
| | | composition | (pbw) | (pbw) | (pbw) | (pbw) | (pbw) | (pbw) |
| Comparative | 2-1 | CR-1 | CP-1 (80) | PAG-X (20) | Q-1 (7.8) | PGMEA (2250) | EL (2800) | DAA (550) |
| Example | 2-2 | CR-2 | CP-2 (80) | PAG-X (20) | Q-1 (7.6) | PGMEA (2250) | EL (2800) | DAA (550) |
| | 2-3 | CR-3 | CP-3 (80) | PAG-X (20) | Q-1 (7.8) | PGMEA (2250) | EL (2800) | DAA (550) |
| | 2-4 | CR-4 | CP-4 (80) | PAG-X (20) | Q-1 (7.8) | PGMEA (2250) | EL (2800) | DAA (550) |
| | 2-5 | CR-5 | CP-5 (80) | PAG-X (20) | Q-1 (7.8) | PGMEA (2250) | EL (2800) | DAA (550) |
| | 2-6 | CR-6 | CP-6 (80) | PAG-X (20) | Q-1 (7.4) | PGMEA (2250) | EL (2800) | DAA (550) |
| | 2-7 | CR-7 | CP-7 (80) | PAG-X (20) | Q-1 (7.8) | PGMEA (2250) | EL (2800) | DAA (550) |
| | 2-8 | CR-8 | CP-8 (80) | PAG-X (20) | Q-1 (7.8) | PGMEA (2250) | EL (2800) | DAA (550) |
| | 2-9 | CR-9 | CP-9 (80) | PAG-X (20) | Q-1 (7.8) | PGMEA (2250) | EL (2800) | DAA (550) |
| | 2-10 | CR-10 | CP-10 (80) | PAG-X (20) | Q-1 (7.8) | PGMEA (2250) | EL (2800) | DAA (550) |
| | 2-11 | CR-11 | CP-11 (80) | PAG-X (20) | Q-1 (7.8) | PGMEA (2250) | EL (2800) | DAA (550) |
| | 2-12 | CR-12 | CP-12 (80) | PAG-X (20) | Q-1 (7.6) | PGMEA (2250) | EL (2800) | DAA (550) |
| | 2-13 | CR-13 | CP-13 (80) | PAG-X (20) | Q-1 (7.8) | PGMEA (2250) | EL (2800) | DAA (550) |
| | 2-14 | CR-14 | CP-14 (80) | PAG-X (20) | Q-1 (7.8) | PGMEA (2250) | EL (2800) | DAA (550) |
| | 2-15 | CR-15 | CP-15 (80) | PAG-X (20) | Q-1 (7.8) | PGMEA (2250) | EL (2800) | DAA (550) |
| | 2-16 | CR-16 | CP-16 (80) | PAG-X (20) | Q-1 (7.6) | PGMEA (2250) | EL (2800) | DAA (550) |
| | 2-17 | CR-17 | CP-17 (80) | PAG-X (20) | Q-1 (7.8) | PGMEA (2250) | EL (2800) | DAA (550) |
| | 2-18 | CR-18 | CP-18 (80) | PAG-X (20) | Q-1 (7.6) | PGMEA (2250) | EL (2800) | DAA (550) |
| | 2-19 | CR-19 | CP-19 (80) | PAG-X (20) | Q-1 (7.8) | PGMEA (2250) | EL (2800) | DAA (550) |
| | 2-20 | CR-20 | CP-20 (80) | PAG-X (20) | Q-1 (7.8) | PGMEA (2250) | EL (2800) | DAA (550) |
| | 2-21 | CR-21 | CP-21 (80) | PAG-Y (20) | Q-2 (7.8) | PGMEA (2250) | EL (2800) | DAA (550) |
| | 2-22 | CR-22 | CP-22 (80) | PAG-Y (20) | Q-3 (7.8) | PGMEA (2250) | EL (2800) | DAA (550) |
| | 2-23 | CR-23 | CP-23 (80) | PAG-X (20) | Q-1 (7.8) | PGMEA (2250) | EL (2800) | DAA (550) |
| | 2-24 | CR-24 | CP-24 (80) | PAG-X (20) | Q-3 (7.8) | PGMEA (2250) | EL (2800) | DAA (550) |
| | 2-25 | CR-25 | CP-25 (80) | PAG-X (20) | Q-2 (4.8) | PGMEA (2250) | EL (2800) | DAA (550) |
| | | | | | Q-4 (3.0) | | | |
| | 2-26 | CR-26 | CP-26 (80) | PAG-X (20) | Q-1 (7.8) | PGMEA (2250) | EL (2800) | DAA (550) |
| | 2-27 | CR-27 | CP-27 (80) | PAG-X (20) | Q-3 (7.8) | PGMEA (2250) | EL (2800) | DAA (550) |
| | 2-28 | CR-28 | CP-28 (80) | PAG-X (20) | Q-1 (7.8) | PGMEA (2250) | EL (2800) | DAA (550) |
| | 2-29 | CR-29 | CP-29 (80) | PAG-Y (20) | Q-2 (7.8) | PGMEA (2250) | EL (2800) | DAA (550) |
| | 2-30 | CR-30 | CP-30 (80) | PAG-X (20) | Q-2 (7.8) | PGMEA (2250) | EL (2800) | DAA (550) |
| | 2-31 | CR-31 | CP-31 (80) | PAG-X (20) | Q-1 (4.8) | PGMEA (2250) | EL (2800) | DAA (550) |
| | | | | | Q-4 (3.0) | | | |
| | 2-32 | CR-32 | CP-32 (80) | PAG-Y (20) | Q-2 (7.8) | PGMEA (2250) | EL (2800) | DAA (550) |
| | 2-33 | CR-33 | CP-33 (80) | PAG-Y (20) | Q-3 (7.8) | PGMEA (2250) | EL (2800) | DAA (550) |
| | 2-34 | CR-34 | CP-34 (80) | PAG-X (20) | Q-1 (7.8) | PGMEA (2250) | EL (2800) | DAA (550) |
| | 2-35 | CR-35 | CP-35 (80) | PAG-Y (20) | Q-2 (7.8) | PGMEA (2250) | EL (2800) | DAA (550) |

TABLE 8

| | | | Base | Photoacid | | | | |
|---|---|---|---|---|---|---|---|---|
| | | Resist | polymer | generator | Quencher | Solvent 1 | Solvent 2 | Solvent 3 |
| | | composition | (pbw) | (pbw) | (pbw) | (pbw) | (pbw) | (pbw) |
| Comparative | 2-36 | CR-36 | CP-36 (80) | PAG-X (20) | Q-3 (7.6) | PGMEA (2250) | EL (2800) | DAA (550) |
| Example | 2-37 | CR-37 | CP-37 (80) | PAG-Z (24) | Q-1 (7.4) | PGMEA (2250) | EL (2800) | DAA (550) |
| | 2-38 | CR-38 | CP-38 (80) | PAG-X (20) | Q-3 (7.6) | PGMEA (2250) | EL (2800) | DAA (550) |
| | 2-39 | CR-39 | CP-39 (80) | PAG-X (20) | Q-2 (7.8) | PGMEA (2250) | EL (2800) | DAA (550) |
| | 2-40 | CR-40 | CP-40 (80) | PAG-Y (20) | Q-1 (7.8) | PGMEA (2250) | EL (2800) | DAA (550) |
| | 2-41 | CR-41 | CP-41 (80) | PAG-X (12) | Q-2 (7.8) | PGMEA (2250) | EL (2800) | DAA (550) |
| | | | | PAG-Z (8) | | | | |
| | 2-42 | CR-42 | CP-42 (80) | — | Q-1 (7.8) | PGMEA (2250) | EL (2800) | DAA (550) |
| | 2-43 | CR-43 | CP-43 (80) | — | Q-3 (7.8) | PGMEA (2250) | EL (2800) | DAA (550) |
| | 2-44 | CR-44 | CP-44 (80) | — | Q-1 (7.8) | PGMEA (2250) | EL (2800) | DAA (550) |
| | 2-45 | CR-45 | CP-45 (80) | — | Q-3 (7.8) | PGMEA (2250) | EL (2800) | DAA (550) |
| | 2-46 | CR-46 | CP-46 (80) | — | Q-1 (7.4) | PGMEA (2250) | EL (2800) | DAA (550) |
| | 2-47 | CR-47 | CP-47 (80) | — | Q-2 (7.6) | PGMEA (2250) | EL (2800) | DAA (550) |
| | 2-48 | CR-48 | CP-48 (80) | — | Q-1 (7.8) | PGMEA (2250) | EL (2800) | DAA (550) |
| | 2-49 | CR-49 | CP-49 (80) | — | Q-3 (7.8) | PGMEA (2250) | EL (2800) | DAA (550) |
| | 2-50 | CR-50 | CP-50 (80) | — | Q-2 (4.8) | PGMEA (2250) | EL (2800) | DAA (550) |
| | | | | | Q-4 (3.0) | | | |
| | 2-51 | CR-51 | CP-51 (80) | — | Q-1 (7.8) | PGMEA (2250) | EL (2800) | DAA (550) |
| | 2-52 | CR-52 | CP-52 (80) | — | Q-1 (7.8) | PGMEA (2250) | EL (2800) | DAA (550) |
| | 2-53 | CR-53 | CP-53 (80) | — | Q-2 (7.8) | PGMEA (2250) | EL (2800) | DAA (550) |
| | 2-54 | CR-54 | CP-54 (80) | — | Q-1 (7.8) | PGMEA (2250) | EL (2800) | DAA (550) |
| | 2-55 | CR-55 | CP-55 (80) | — | Q-3 (4.8) | PGMEA (2250) | EL (2800) | DAA (550) |
| | | | | | Q-4 (3.0) | | | |
| | 2-56 | CR-56 | CP-56 (80) | — | Q-3 (7.8) | PGMEA (2250) | EL (2800) | DAA (550) |
| | 2-57 | CR-57 | CP-57 (80) | — | Q-1 (7.8) | PGMEA (2250) | EL (2800) | DAA (550) |
| | 2-58 | CR-58 | CP-58 (80) | — | Q-2 (7.8) | PGMEA (2250) | EL (2800) | DAA (550) |
| | 2-59 | CR-59 | CP-59 (80) | — | Q-1 (7.6) | PGMEA (2250) | EL (2800) | DAA (550) |
| | 2-60 | CR-60 | CP-60 (80) | — | Q-2 (7.8) | PGMEA (2250) | EL (2800) | DAA (550) |
| | 2-61 | CR-61 | CP-61 (80) | — | Q-3 (7.8) | PGMEA (2250) | EL (2800) | DAA (550) |
| | 2-62 | CR-62 | CP-62 (80) | — | Q-1 (7.8) | PGMEA (2250) | EL (2800) | DAA (550) |
| | 2-63 | CR-63 | CP-63 (80) | — | Q-2 (7.6) | PGMEA (2250) | EL (2800) | DAA (550) |
| | 2-64 | CR-64 | CP-64 (80) | — | Q-1 (7.8) | PGMEA (2250) | EL (2800) | DAA (550) |
| | 2-65 | CR-65 | CP-65 (80) | — | Q-2 (7.6) | PGMEA (2250) | EL (2800) | DAA (550) |
| | 2-66 | CR-66 | CP-66 (80) | PAG-X (8) | Q-1 (7.8) | PGMEA (2250) | EL (2800) | DAA (550) |
| | 2-67 | CR-67 | CP-67 (80) | PAG-Y (8) | Q-2 (7.8) | PGMEA (2250) | EL (2800) | DAA (550) |
| | 2-68 | CR-68 | CP-68 (80) | PAG-X (6) | Q-3 (7.6) | PGMEA (2250) | EL (2800) | DAA (550) |
| | | | | PAG-Z (2) | | | | |
| | 2-69 | CR-69 | CP-69 (80) | PAG-Y (6) | Q-1 (7.8) | PGMEA (2250) | EL (2800) | DAA (550) |
| | | | | PAG-Z (2) | | | | |
| | 2-70 | CR-70 | CP-70 (80) | PAG-X (6) | Q-1 (7.8) | PGMEA (2250) | EL (2800) | DAA (550) |
| | | | | PAG-Z (2) | | | | |

The components in Tables 5 to 8 are identified below.

### Organic Solvent:

PGMEA (propylene glycol monomethyl ether acetate)
EL (ethyl lactate)
DAA (diacetone alcohol)

### Photoacid Generators: PAG-X, PAG-Y and PAG-Z

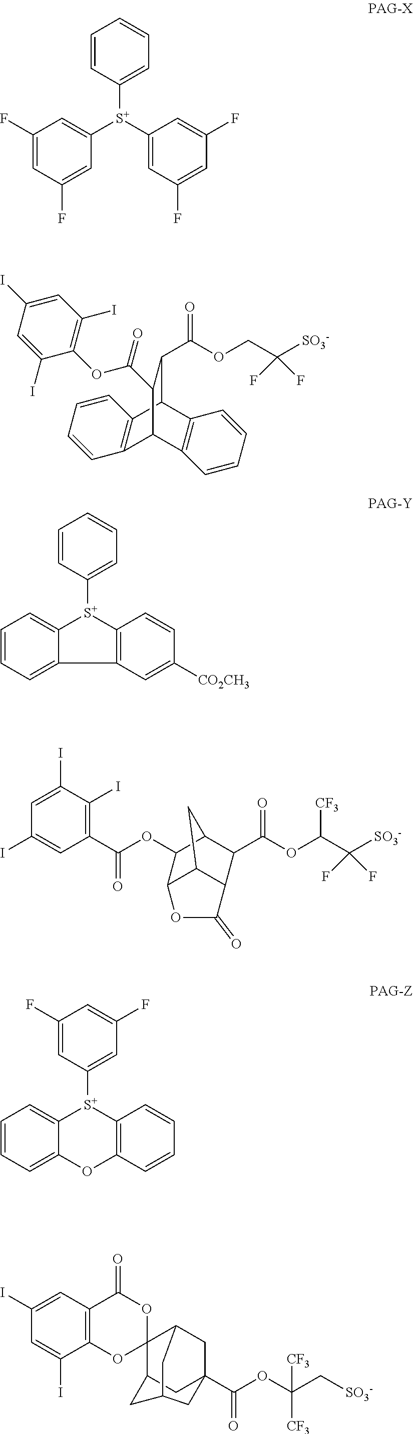

### Quenchers: Q-1 to Q-4

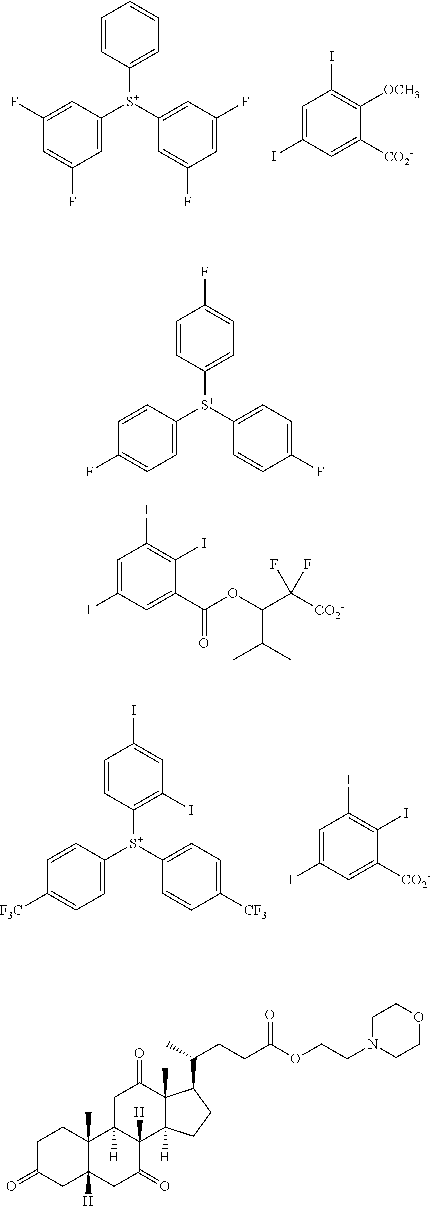

### Surfactant A:

3-methyl-3-(2,2,2-trifluoroethoxymethyl)oxetane/tetrahydrofuran/
2,2-dimethyl-1,3-propanediol copolymer of the formula below (Omnova Solutions, Inc.)

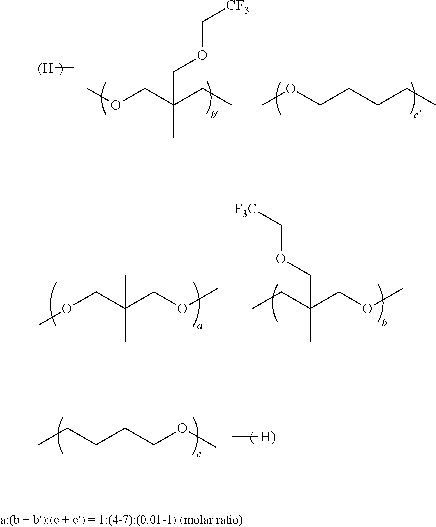

### [4] EUV Lithography Test 1

### Examples 4-1 to 4-80 and Comparative Examples 3-1 to 3-70

Each of the chemically amplified resist compositions (R-1 to R-80, CR-1 to CR-70) was spin coated on a silicon substrate having a 20-nm coating of silicon-containing spin-on hard mask SHB-A940 (Shin-Etsu Chemical Co., Ltd., silicon content 43 wt %) and prebaked on a hotplate at 100 °C for 60 seconds to form a resist film of 50 nm thick. Using an EUV scanner NXE3300 (ASML, NA 0.33, σ 0.9/0.6, dipole illumination), the resist film was exposed to EUV through a mask bearing a line and space (LS) pattern having a size of 18 nm and a pitch of 36 nm (on-wafer size) while varying the dose and focus (dose pitch : 1 mJ/cm², focus pitch: 0.020 μm). The resist film was baked (PEB) at the temperature shown in Tables 9 to 12 for 60 seconds and puddle developed in a 2.38 wt % TMAH aqueous solution for 30 seconds, rinsed with a rinse fluid containing surfactant, and spin dried to form a positive pattern.

The LS pattern as developed was observed under CD-SEM (CG6300, Hitachi High-Technologies Corp.) whereupon sensitivity, EL, LWR, DOF and collapse limit were evaluated by the following methods. The results are shown in Tables 9 to 12.

### [Evaluation of Sensitivity]

The optimum dose Eop (mJ/cm²) which provided a LS pattern with a line width of 18 nm and a pitch of 36 nm was determined as an index of sensitivity. A smaller value indicates a higher sensitivity.

### [Evaluation of EL]

The exposure dose which provided a LS pattern with a space width of 18 nm+10% (i.e., 16.2 to 19.8 nm) was determined. EL (%) is calculated from the exposure doses according to the following equation:

EL (%)=(|E₁−E₂/Eop)×100
wherein E₁ is an optimum exposure dose which provides a LS pattern with a line width of 16.2 nm and a pitch of 36 nm, E₂ is an optimum exposure dose which provides a LS pattern with a line width of 19.8 nm and a pitch of 36 nm, and Eop is an optimum exposure dose which provides a LS pattern with a line width of 18 nm and a pitch of 36 nm. A greater value indicates better performance.

### [Evaluation of LWR]

For the LS pattern formed by exposure at the optimum dose Eop, the line width was measured at 10 longitudinally spaced apart points, from which a 3-fold value (3σ) of the standard deviation (σ) was determined and reported as LWR. A smaller value of 3σ indicates a pattern having small roughness and uniform line width.

### [Evaluation of DOF]

As an index of DOF, a range of focus which provided a LS pattern with a size of 18 nm±10% (i.e., 16.2 to 19.8 nm) was determined. A greater value indicates a wider DOF.

### [Evaluation of Collapse Limit of Line Pattern]

For the LS pattern formed by exposure at the dose corresponding to the optimum focus, the line width was measured at 10 longitudinally spaced apart points. The minimum line size above which lines could be resolved without collapse was determined and reported as collapse limit. A smaller value indicates better collapse limit.

TABLE 9

| | | Resist | PEB temp. | Eop | EL | LWR | DOF | Collapse limit |
|---|---|---|---|---|---|---|---|---|
| | | composition | (°C) | (mJ/cm²) | (%) | (nm) | (nm) | (nm) |
| Example | 4-1 | R-1 | 100 | 32 | 19 | 2.2 | 120 | 10.6 |
| | 4-2 | R-2 | 90 | 31 | 18 | 2.1 | 110 | 10.7 |
| | 4-3 | R-3 | 100 | 32 | 19 | 2.3 | 110 | 10.9 |
| | 4-4 | R-4 | 90 | 33 | 17 | 2.2 | 110 | 10.8 |
| | 4-5 | R-5 | 95 | 31 | 17 | 2.2 | 120 | 11.1 |
| | 4-6 | R-6 | 100 | 32 | 18 | 2.4 | 100 | 10.5 |
| | 4-7 | R-7 | 100 | 31 | 19 | 2.1 | 120 | 10.6 |
| | 4-8 | R-8 | 90 | 31 | 18 | 2.2 | 110 | 10.7 |
| | 4-9 | R-9 | 100 | 32 | 19 | 2.5 | 120 | 10.9 |
| | 4-10 | R-10 | 90 | 32 | 18 | 2.2 | 110 | 10.8 |
| | 4-11 | R-11 | 95 | 33 | 19 | 2.3 | 120 | 11.1 |
| | 4-12 | R-12 | 100 | 31 | 17 | 2.1 | 120 | 10.5 |
| | 4-13 | R-13 | 100 | 32 | 17 | 2.1 | 110 | 10.8 |
| | 4-14 | R-14 | 90 | 32 | 18 | 2.3 | 120 | 11.3 |
| | 4-15 | R-15 | 95 | 31 | 17 | 2.2 | 110 | 10.9 |
| | 4-16 | R-16 | 100 | 32 | 18 | 2.3 | 100 | 10.6 |
| | 4-17 | R-17 | 100 | 31 | 18 | 2.2 | 110 | 10.9 |
| | 4-18 | R-18 | 90 | 33 | 16 | 2.4 | 110 | 10.6 |
| | 4-19 | R-19 | 100 | 34 | 17 | 2.4 | 120 | 11.1 |
| | 4-20 | R-20 | 95 | 31 | 18 | 2.1 | 120 | 10.5 |
| | 4-21 | R-21 | 100 | 32 | 19 | 2.6 | 120 | 10.8 |
| | 4-22 | R-22 | 95 | 32 | 18 | 2.1 | 110 | 11.2 |
| | 4-23 | R-23 | 100 | 31 | 19 | 2.3 | 100 | 10.9 |
| | 4-24 | R-24 | 100 | 33 | 18 | 2.2 | 120 | 10.6 |
| | 4-25 | R-25 | 95 | 32 | 19 | 2.2 | 100 | 10.8 |
| | 4-26 | R-26 | 95 | 33 | 18 | 2.4 | 110 | 10.6 |
| | 4-27 | R-27 | 90 | 31 | 19 | 2.4 | 110 | 11.1 |
| | 4-28 | R-28 | 100 | 32 | 19 | 2.2 | 100 | 10.8 |
| | 4-29 | R-29 | 95 | 31 | 18 | 2.1 | 120 | 10.9 |
| | 4-30 | R-30 | 95 | 31 | 19 | 2.3 | 110 | 11.2 |
| | 4-31 | R-31 | 100 | 32 | 17 | 2.2 | 120 | 10.8 |
| | 4-32 | R-32 | 90 | 32 | 17 | 2.2 | 110 | 11.3 |
| | 4-33 | R-33 | 100 | 33 | 19 | 2.4 | 120 | 11.2 |
| | 4-34 | R-34 | 90 | 31 | 18 | 2.3 | 110 | 10.6 |
| | 4-35 | R-35 | 100 | 32 | 19 | 2.1 | 120 | 10.8 |
| | 4-36 | R-36 | 95 | 31 | 17 | 2.4 | 120 | 10.6 |
| | 4-37 | R-37 | 95 | 31 | 17 | 2.1 | 110 | 11.1 |
| | 4-38 | R-38 | 100 | 32 | 18 | 2.3 | 120 | 10.8 |
| | 4-39 | R-39 | 95 | 31 | 19 | 2.2 | 110 | 10.9 |
| | 4-40 | R-40 | 100 | 31 | 17 | 2.3 | 100 | 11.2 |

TABLE 10

| | | Resist | PEB temp. | Eop | EL | LWR | DOF | Collapse limit |
|---|---|---|---|---|---|---|---|---|
| | | composition | (°C) | (mJ/cm²) | (%) | (nm) | (nm) | (nm) |
| Example | 4-41 | R-41 | 95 | 32 | 18 | 2.2 | 120 | 10.8 |
| | 4-42 | R-42 | 95 | 31 | 18 | 2.4 | 110 | 10.6 |
| | 4-43 | R-43 | 100 | 32 | 16 | 2.3 | 120 | 11.1 |
| | 4-44 | R-44 | 100 | 32 | 17 | 2.1 | 110 | 10.6 |
| | 4-45 | R-45 | 90 | 33 | 18 | 2.1 | 120 | 10.8 |
| | 4-46 | R-46 | 100 | 31 | 17 | 2.3 | 120 | 10.6 |
| | 4-47 | R-47 | 95 | 32 | 17 | 2.2 | 110 | 11.1 |
| | 4-48 | R-48 | 95 | 31 | 17 | 2.2 | 120 | 10.8 |
| | 4-49 | R-49 | 100 | 31 | 18 | 2.4 | 110 | 10.9 |
| | 4-50 | R-50 | 95 | 32 | 18 | 2.4 | 100 | 11.2 |
| | 4-51 | R-51 | 95 | 32 | 16 | 2.4 | 110 | 10.8 |
| | 4-52 | R-52 | 100 | 31 | 17 | 2.1 | 110 | 11.1 |
| | 4-53 | R-53 | 100 | 31 | 18 | 2.3 | 120 | 10.8 |
| | 4-54 | R-54 | 95 | 32 | 19 | 2.2 | 120 | 10.6 |
| | 4-55 | R-55 | 95 | 33 | 18 | 2.2 | 120 | 11.2 |
| | 4-56 | R-56 | 90 | 31 | 19 | 2.2 | 110 | 10.9 |
| | 4-57 | R-57 | 100 | 32 | 17 | 2.4 | 100 | 10.6 |
| | 4-58 | R-58 | 95 | 31 | 17 | 2.3 | 120 | 10.8 |
| | 4-59 | R-59 | 95 | 31 | 18 | 2.4 | 100 | 10.6 |
| | 4-60 | R-60 | 100 | 32 | 19 | 2.4 | 120 | 11.1 |
| | 4-61 | R-61 | 95 | 31 | 18 | 2.1 | 110 | 10.8 |
| | 4-62 | R-62 | 95 | 32 | 17 | 2.3 | 120 | 10.9 |
| | 4-63 | R-63 | 100 | 33 | 18 | 2.2 | 110 | 10.6 |
| | 4-64 | R-64 | 100 | 31 | 19 | 2.4 | 120 | 10.8 |
| | 4-65 | R-65 | 90 | 32 | 17 | 2.4 | 120 | 10.6 |
| | 4-66 | R-66 | 100 | 31 | 17 | 2.2 | 110 | 11.1 |
| | 4-67 | R-67 | 90 | 31 | 18 | 2.3 | 120 | 10.8 |
| | 4-68 | R-68 | 100 | 32 | 18 | 2.1 | 110 | 10.9 |
| | 4-69 | R-69 | 95 | 32 | 16 | 2.1 | 100 | 11.2 |
| | 4-70 | R-70 | 95 | 33 | 17 | 2.3 | 110 | 10.8 |
| | 4-71 | R-71 | 100 | 31 | 18 | 2.2 | 110 | 10.9 |
| | 4-72 | R-72 | 95 | 32 | 19 | 2.3 | 120 | 11.2 |
| | 4-73 | R-73 | 95 | 31 | 17 | 2.2 | 120 | 10.9 |
| | 4-74 | R-74 | 90 | 31 | 16 | 2.4 | 120 | 10.6 |
| | 4-75 | R-75 | 100 | 32 | 18 | 2.4 | 120 | 10.8 |
| | 4-76 | R-76 | 95 | 31 | 19 | 2.1 | 110 | 10.6 |
| | 4-77 | R-77 | 95 | 31 | 17 | 2.3 | 120 | 11.1 |
| | 4-78 | R-78 | 95 | 32 | 19 | 2.2 | 110 | 10.8 |
| | 4-79 | R-79 | 95 | 32 | 18 | 2.4 | 120 | 10.9 |
| | 4-80 | R-80 | 95 | 31 | 17 | 2.2 | 120 | 10.9 |

TABLE 11

| | | Resist | PEB temp. | Eop | EL | LWR | DOF | Collapse limit |
|---|---|---|---|---|---|---|---|---|
| | | composition | (°C) | (mJ/cm²) | (%) | (nm) | (nm) | (nm) |
| Comparative | 3-1 | CR-1 | 100 | 34 | 16 | 2.6 | 90 | 12.1 |
| Example | 3-2 | CR-2 | 95 | 37 | 13 | 2.9 | 80 | 12.5 |
| | 3-3 | CR-3 | 100 | 36 | 14 | 2.7 | 90 | 12.3 |
| | 3-4 | CR-4 | 95 | 37 | 13 | 2.8 | 80 | 12.5 |
| | 3-5 | CR-5 | 100 | 38 | 14 | 2.9 | 90 | 13.2 |
| | 3-6 | CR-6 | 100 | 36 | 15 | 2.7 | 70 | 12.2 |
| | 3-7 | CR-7 | 95 | 38 | 12 | 2.8 | 80 | 12.4 |
| | 3-8 | CR-8 | 100 | 39 | 13 | 2.9 | 90 | 12.5 |
| | 3-9 | CR-9 | 95 | 38 | 14 | 2.7 | 60 | 12.5 |
| | 3-10 | CR-10 | 100 | 37 | 13 | 2.8 | 90 | 13.2 |
| | 3-11 | CR-11 | 100 | 34 | 17 | 2.6 | 80 | 11.9 |
| | 3-12 | CR-12 | 100 | 36 | 14 | 2.7 | 90 | 12.3 |
| | 3-13 | CR-13 | 95 | 37 | 17 | 2.8 | 70 | 12.5 |
| | 3-14 | CR-14 | 100 | 37 | 13 | 2.9 | 80 | 13.2 |
| | 3-15 | CR-15 | 95 | 38 | 14 | 2.7 | 90 | 12.2 |
| | 3-16 | CR-16 | 100 | 36 | 13 | 2.9 | 70 | 12.4 |
| | 3-17 | CR-17 | 100 | 37 | 15 | 2.7 | 90 | 12.5 |
| | 3-18 | CR-18 | 100 | 36 | 14 | 2.8 | 70 | 13.1 |
| | 3-19 | CR-19 | 95 | 37 | 14 | 2.9 | 90 | 12.9 |
| | 3-20 | CR-20 | 95 | 38 | 14 | 2.7 | 80 | 12.5 |
| | 3-21 | CR-21 | 90 | 34 | 16 | 2.7 | 90 | 12.5 |
| | 3-22 | CR-22 | 100 | 33 | 17 | 2.6 | 90 | 12.6 |
| | 3-23 | CR-23 | 95 | 39 | 14 | 2.9 | 80 | 12.8 |
| | 3-24 | CR-24 | 95 | 38 | 13 | 2.7 | 90 | 12.5 |
| | 3-25 | CR-25 | 95 | 34 | 17 | 2.5 | 80 | 12.4 |
| | 3-26 | CR-26 | 95 | 34 | 18 | 2.6 | 90 | 12.7 |
| | 3-27 | CR-27 | 90 | 33 | 17 | 2.5 | 80 | 12.4 |
| | 3-28 | CR-28 | 100 | 34 | 16 | 2.6 | 90 | 12.5 |
| | 3-29 | CR-29 | 95 | 35 | 17 | 2.6 | 70 | 13.2 |
| | 3-30 | CR-30 | 95 | 34 | 16 | 2.7 | 80 | 13.1 |
| | 3-31 | CR-31 | 95 | 33 | 16 | 2.6 | 90 | 12.7 |
| | 3-32 | CR-32 | 95 | 34 | 17 | 2.6 | 80 | 12.5 |
| | 3-33 | CR-33 | 95 | 34 | 15 | 2.5 | 90 | 12.4 |
| | 3-34 | CR-34 | 90 | 37 | 13 | 2.9 | 70 | 13.2 |
| | 3-35 | CR-35 | 100 | 36 | 12 | 2.7 | 90 | 12.9 |

TABLE 12

| | | Resist | PEB temp. | Eop | EL | LWR | DOF | Collapse limit |
|---|---|---|---|---|---|---|---|---|
| | | composition | (°C) | (mJ/cm²) | (%) | (nm) | (nm) | (nm) |
| Comparative | 3-36 | CR-36 | 95 | 36 | 13 | 2.8 | 90 | 12.6 |
| Example | 3-37 | CR-37 | 95 | 37 | 13 | 3.1 | 70 | 12.3 |
| | 3-38 | CR-38 | 100 | 36 | 14 | 2.9 | 80 | 12.4 |
| | 3-39 | CR-39 | 95 | 35 | 13 | 3 | 90 | 11.9 |
| | 3-40 | CR-40 | 100 | 37 | 14 | 2.9 | 60 | 12.9 |
| | 3-41 | CR-41 | 95 | 36 | 13 | 2.7 | 90 | 13.2 |
| | 3-42 | CR-42 | 95 | 34 | 16 | 2.6 | 80 | 12.2 |
| | 3-43 | CR-43 | 95 | 33 | 17 | 2.7 | 90 | 12.4 |
| | 3-44 | CR-44 | 90 | 34 | 16 | 2.5 | 90 | 12.6 |
| | 3-45 | CR-45 | 100 | 35 | 17 | 2.7 | 80 | 12.3 |
| | 3-46 | CR-46 | 95 | 34 | 17 | 2.6 | 90 | 12.2 |
| | 3-47 | CR-47 | 95 | 33 | 17 | 2.7 | 80 | 12.6 |
| | 3-48 | CR-48 | 95 | 36 | 13 | 2.9 | 50 | 13.2 |
| | 3-49 | CR-49 | 100 | 35 | 14 | 3 | 60 | 12.9 |
| | 3-50 | CR-50 | 95 | 37 | 13 | 3.2 | 70 | 13.2 |
| | 3-51 | CR-51 | 95 | 36 | 14 | 3.1 | 70 | 13.4 |
| | 3-52 | CR-52 | 95 | 34 | 17 | 2.6 | 80 | 12.5 |
| | 3-53 | CR-53 | 95 | 33 | 16 | 2.7 | 90 | 12.3 |
| | 3-54 | CR-54 | 95 | 34 | 17 | 2.6 | 90 | 12.6 |
| | 3-55 | CR-55 | 90 | 35 | 16 | 2.7 | 80 | 12.7 |
| | 3-56 | CR-56 | 100 | 34 | 16 | 2.6 | 90 | 12.1 |
| | 3-57 | CR-57 | 95 | 35 | 17 | 2.6 | 80 | 12.4 |
| | 3-58 | CR-58 | 95 | 35 | 16 | 2.5 | 80 | 11.9 |
| | 3-59 | CR-59 | 95 | 34 | 16 | 2.7 | 80 | 12.3 |
| | 3-60 | CR-60 | 100 | 34 | 17 | 2.6 | 90 | 12.5 |
| | 3-61 | CR-61 | 95 | 34 | 16 | 2.7 | 80 | 12.3 |
| | 3-62 | CR-62 | 95 | 35 | 17 | 2.6 | 80 | 12.5 |
| | 3-63 | CR-63 | 95 | 34 | 17 | 2.6 | 90 | 12.8 |
| | 3-64 | CR-64 | 90 | 37 | 12 | 2.7 | 60 | 13.2 |
| | 3-65 | CR-65 | 100 | 37 | 13 | 2.9 | 70 | 13.1 |
| | 3-66 | CR-66 | 95 | 36 | 14 | 2.9 | 60 | 13.2 |
| | 3-67 | CR-67 | 95 | 37 | 14 | 3.2 | 70 | 12.9 |
| | 3-68 | CR-68 | 100 | 38 | 17 | 2.7 | 90 | 12.8 |
| | 3-69 | CR-69 | 95 | 36 | 16 | 2.7 | 80 | 12.3 |
| | 3-70 | CR-70 | 100 | 38 | 13 | 2.9 | 70 | 12.8 |

It is demonstrated in Tables 9 to 12 that chemically amplified resist compositions comprising polymers within the scope of the invention exhibit a high sensitivity and improved values of EL, LWR and DOF. Small values of collapse limit attest that in forming a small-size pattern, the pattern is resistant to collapse. The resist compositions are useful in the EUV lithography process.

### [5] EUV Lithography Test 2

### Examples 5-1 to 5-80 and Comparative Examples 4-1 to 4-70

Each of the chemically amplified resist compositions (R-1 to R-80, CR-1 to CR-70) was spin coated on a silicon substrate having a 20-nm coating of silicon-containing spin-on hard mask SHB-A940 (Shin-Etsu Chemical Co., Ltd., silicon content 43 wt %) and prebaked on a hotplate at 105 °C for 60 seconds to form a resist film of 50 nm thick. Using an EUV scanner NXE3400 (ASML, NA 0.33, σ 0.9/0.6, quadrupole illumination), the resist film was exposed to EUV through a mask bearing a hole pattern having a pitch of 46 nm+20% bias (on-wafer size). The resist film was baked (PEB) on a hotplate at the temperature shown in Tables 13 to 16 for 60 seconds and developed in a 2.38 wt % TMAH aqueous solution for 30 seconds to form a hole pattern having a size of 23 nm.

The pattern as developed was observed under CD-SEM (CG6300, Hitachi High-Technologies Corp.). The dose (mJ/cm²) at which a pattern with a hole size of 23 nm was printed was determined as an index of sensitivity. The size of 50 holes was measured, from which a 3-fold value (3σ) of the standard deviation (σ) was determined as a dimensional variation or CDU. The results are shown in Tables 13 to 16.

TABLE 13

| | | | | Optimum | |
|---|---|---|---|---|---|
| | | | PEB | exposure | |
| | | Resist | temp. | dose | CDU |
| | | composition | (°C) | (mJ/cm²) | (nm) |
| Example | 5-1 | R-1 | 95 | 22 | 2.2 |
| | 5-2 | R-2 | 90 | 23 | 2.3 |
| | 5-3 | R-3 | 90 | 24 | 2.1 |
| | 5-4 | R-4 | 90 | 23 | 2.3 |
| | 5-5 | R-5 | 90 | 22 | 2.3 |
| | 5-6 | R-6 | 90 | 22 | 2.3 |
| | 5-7 | R-7 | 90 | 23 | 2.3 |
| | 5-8 | R-8 | 90 | 24 | 2.4 |
| | 5-9 | R-9 | 95 | 22 | 2.1 |
| | 5-10 | R-10 | 90 | 25 | 2.2 |
| | 5-11 | R-11 | 90 | 22 | 2.4 |
| | 5-12 | R-12 | 95 | 23 | 2.3 |
| | 5-13 | R-13 | 90 | 24 | 2.3 |
| | 5-14 | R-14 | 90 | 23 | 2.1 |
| | 5-15 | R-15 | 90 | 22 | 2.3 |
| | 5-16 | R-16 | 90 | 23 | 2.3 |
| | 5-17 | R-17 | 90 | 23 | 2.3 |
| | 5-18 | R-18 | 85 | 24 | 2.4 |
| | 5-19 | R-19 | 90 | 23 | 2.3 |
| | 5-20 | R-20 | 95 | 22 | 2.1 |
| | 5-21 | R-21 | 95 | 23 | 2.3 |
| | 5-22 | R-22 | 90 | 23 | 2.3 |
| | 5-23 | R-23 | 90 | 24 | 2.3 |
| | 5-24 | R-24 | 90 | 23 | 2.2 |
| | 5-25 | R-25 | 90 | 22 | 2.4 |
| | 5-26 | R-26 | 90 | 23 | 2.1 |
| | 5-27 | R-27 | 90 | 24 | 2.2 |
| | 5-28 | R-28 | 90 | 23 | 2.3 |
| | 5-29 | R-29 | 95 | 23 | 2.3 |
| | 5-30 | R-30 | 90 | 23 | 2.1 |
| | 5-31 | R-31 | 90 | 24 | 2.3 |
| | 5-32 | R-32 | 90 | 24 | 2.2 |
| | 5-33 | R-33 | 90 | 23 | 2.4 |
| | 5-34 | R-34 | 90 | 22 | 2.3 |
| | 5-35 | R-35 | 90 | 22 | 2.4 |
| | 5-36 | R-36 | 90 | 23 | 2.2 |
| | 5-37 | R-37 | 90 | 23 | 2.3 |
| | 5-38 | R-38 | 90 | 24 | 2.2 |
| | 5-39 | R-39 | 90 | 23 | 2.4 |
| | 5-40 | R-40 | 90 | 23 | 2.3 |

TABLE 14

| | | | | Optimum | |
|---|---|---|---|---|---|
| | | | PEB | exposure | |
| | | Resist | temp. | dose | CDU |
| | | composition | (°C) | (mJ/cm²) | (nm) |
| Example | 5-41 | R-41 | 90 | 24 | 2.2 |
| | 5-42 | R-42 | 85 | 22 | 2.4 |
| | 5-43 | R-43 | 90 | 23 | 2.1 |
| | 5-44 | R-44 | 95 | 24 | 2.3 |
| | 5-45 | R-45 | 95 | 22 | 2.2 |
| | 5-46 | R-46 | 90 | 22 | 2.3 |
| | 5-47 | R-47 | 90 | 23 | 2.3 |
| | 5-48 | R-48 | 90 | 24 | 2.1 |
| | 5-49 | R-49 | 90 | 23 | 2.3 |
| | 5-50 | R-50 | 90 | 23 | 2.2 |
| | 5-51 | R-51 | 90 | 24 | 2.4 |
| | 5-52 | R-52 | 90 | 23 | 2.3 |
| | 5-53 | R-53 | 95 | 24 | 2.4 |
| | 5-54 | R-54 | 90 | 23 | 2.2 |
| | 5-55 | R-55 | 90 | 24 | 2.3 |
| | 5-56 | R-56 | 90 | 23 | 2.3 |
| | 5-57 | R-57 | 90 | 23 | 2.1 |
| | 5-58 | R-58 | 90 | 24 | 2.3 |
| | 5-59 | R-59 | 90 | 24 | 2.3 |
| | 5-60 | R-60 | 90 | 23 | 2.1 |
| | 5-61 | R-61 | 90 | 22 | 2.3 |
| | 5-62 | R-62 | 90 | 23 | 2.4 |
| | 5-63 | R-63 | 85 | 23 | 2.2 |
| | 5-64 | R-64 | 90 | 24 | 2.3 |
| | 5-65 | R-65 | 95 | 23 | 2.3 |
| | 5-66 | R-66 | 95 | 22 | 2.1 |
| | 5-67 | R-67 | 90 | 23 | 2.3 |
| | 5-68 | R-68 | 90 | 24 | 2.2 |
| | 5-69 | R-69 | 90 | 23 | 2.3 |
| | 5-70 | R-70 | 90 | 23 | 2.3 |
| | 5-71 | R-71 | 90 | 23 | 2.1 |
| | 5-72 | R-72 | 85 | 24 | 2.3 |
| | 5-73 | R-73 | 90 | 24 | 2.3 |
| | 5-74 | R-74 | 95 | 24 | 2.2 |
| | 5-75 | R-75 | 95 | 23 | 2.3 |
| | 5-76 | R-76 | 90 | 22 | 2.1 |
| | 5-77 | R-77 | 90 | 22 | 2.3 |
| | 5-78 | R-78 | 90 | 23 | 2.4 |
| | 5-79 | R-79 | 90 | 22 | 2.2 |
| | 5-80 | R-80 | 90 | 22 | 2.3 |

TABLE 15

| | | | | Optimum | |
|---|---|---|---|---|---|
| | | | PEB | exposure | |
| | | Resist | temp. | dose | CDU |
| | | composition | (°C) | (mJ/cm²) | (nm) |
| Comparative | 4-1 | CR-1 | 90 | 25 | 2.4 |
| Example | 4-2 | CR-2 | 90 | 27 | 2.9 |
| | 4-3 | CR-3 | 90 | 28 | 2.8 |
| | 4-4 | CR-4 | 90 | 29 | 2.9 |
| | 4-5 | CR-5 | 90 | 28 | 2.7 |
| | 4-6 | CR-6 | 95 | 27 | 2.9 |
| | 4-7 | CR-7 | 90 | 26 | 3 |
| | 4-8 | CR-8 | 90 | 27 | 2.9 |
| | 4-9 | CR-9 | 95 | 26 | 3.1 |
| | 4-10 | CR-10 | 90 | 27 | 2.9 |
| | 4-11 | CR-11 | 90 | 25 | 2.5 |
| | 4-12 | CR-12 | 95 | 26 | 2.9 |
| | 4-13 | CR-13 | 90 | 27 | 2.8 |
| | 4-14 | CR-14 | 90 | 27 | 2.9 |
| | 4-15 | CR-15 | 90 | 28 | 2.7 |
| | 4-16 | CR-16 | 90 | 29 | 2.9 |
| | 4-17 | CR-17 | 90 | 28 | 3 |
| | 4-18 | CR-18 | 95 | 27 | 2.8 |
| | 4-19 | CR-19 | 90 | 26 | 3.1 |
| | 4-20 | CR-20 | 90 | 27 | 2.9 |
| | 4-21 | CR-21 | 95 | 25 | 2.6 |
| | 4-22 | CR-22 | 90 | 26 | 2.5 |
| | 4-23 | CR-23 | 90 | 27 | 3 |
| | 4-24 | CR-24 | 90 | 28 | 2.9 |
| | 4-25 | CR-25 | 95 | 26 | 2.5 |
| | 4-26 | CR-26 | 90 | 25 | 2.6 |
| | 4-27 | CR-27 | 90 | 26 | 2.5 |
| | 4-28 | CR-28 | 90 | 26 | 2.5 |
| | 4-29 | CR-29 | 90 | 25 | 2.5 |
| | 4-30 | CR-30 | 90 | 26 | 2.6 |
| | 4-31 | CR-31 | 90 | 26 | 2.5 |
| | 4-32 | CR-32 | 90 | 25 | 2.5 |
| | 4-33 | CR-33 | 90 | 26 | 2.6 |
| | 4-34 | CR-34 | 90 | 29 | 2.9 |
| | 4-35 | CR-35 | 90 | 30 | 2.8 |

TABLE 16

| | | | | Optimum | |
|---|---|---|---|---|---|
| | | | PEB | exposure | |
| | | Resist | temp. | dose | CDU |
| | | composition | (°C) | (mJ/cm²) | (nm) |
| Comparative | 4-36 | CR-36 | 90 | 29 | 3 |
| Example | 4-37 | CR-37 | 90 | 28 | 3.2 |
| | 4-38 | CR-38 | 90 | 27 | 2.8 |
| | 4-39 | CR-39 | 90 | 27 | 2.9 |
| | 4-40 | CR-40 | 90 | 28 | 2.7 |
| | 4-41 | CR-41 | 90 | 29 | 2.6 |
| | 4-42 | CR-42 | 85 | 25 | 2.5 |
| | 4-43 | CR-43 | 90 | 26 | 2.6 |
| | 4-44 | CR-44 | 90 | 26 | 2.6 |
| | 4-45 | CR-45 | 90 | 27 | 2.7 |
| | 4-46 | CR-46 | 95 | 26 | 2.5 |
| | 4-47 | CR-47 | 90 | 26 | 2.6 |
| | 4-48 | CR-48 | 90 | 28 | 2.9 |
| | 4-49 | CR-49 | 90 | 29 | 2.8 |
| | 4-50 | CR-50 | 90 | 30 | 2.9 |
| | 4-51 | CR-51 | 90 | 27 | 2.7 |
| | 4-52 | CR-52 | 90 | 25 | 2.5 |
| | 4-53 | CR-53 | 95 | 26 | 2.6 |
| | 4-54 | CR-54 | 90 | 28 | 2.6 |
| | 4-55 | CR-55 | 90 | 26 | 2.5 |
| | 4-56 | CR-56 | 90 | 26 | 2.6 |
| | 4-57 | CR-57 | 90 | 26 | 2.5 |
| | 4-58 | CR-58 | 95 | 26 | 2.7 |
| | 4-59 | CR-59 | 90 | 25 | 2.6 |
| | 4-60 | CR-60 | 90 | 26 | 2.5 |
| | 4-61 | CR-61 | 90 | 26 | 2.6 |
| | 4-62 | CR-62 | 90 | 25 | 2.6 |
| | 4-63 | CR-63 | 90 | 26 | 2.7 |
| | 4-64 | CR-64 | 90 | 29 | 2.9 |
| | 4-65 | CR-65 | 90 | 27 | 3 |
| | 4-66 | CR-66 | 90 | 29 | 2.7 |
| | 4-67 | CR-67 | 90 | 27 | 2.8 |
| | 4-68 | CR-68 | 95 | 26 | 2.5 |
| | 4-69 | CR-69 | 90 | 26 | 2.6 |
| | 4-70 | CR-70 | 90 | 29 | 2.9 |

It is demonstrated in Tables 13 to 16 that chemically amplified resist compositions within the scope of the invention exhibit a high sensitivity and satisfactory CDU.

### [6] Alkali Decomposition Test

### Examples 6-1 to 6-5 and Comparative Example 5-1

A solution was prepared by dissolving 2 g of each of monomers A-1 to A-5 and cA-1 in 10 g of THF and adding 1.0 equivalent relative to the monomer of ethanolamine. The solution was stirred while keeping an internal temperature of 40 °C. A sample was taken from each solution after the lapse of stirring time of 2 hours and 8 hours. A rate of decomposition was computed from the data of ¹H-NMR analysis, with the results shown in Table 17.

TABLE 17

| | | | Decomposition | Decomposition |
|---|---|---|---|---|
| | | | rate after | rate after |
| | | Monomer | 2 hr, % | 8 hr, % |
| Example | 6-1 | A-1 | <1 | 1 |
| | 6-2 | A-2 | <1 | 2 |
| | 6-3 | A-3 | <1 | 1 |
| | 6-4 | A-4 | <1 | 1 |
| | 6-5 | A-5 | <1 | 2 |
| Comparative | 5-1 | cA-1 | 34 | 97 |
| Example | | | | |

It is evident from Table 17 that the monomers within the scope of the invention are resistant to decomposition under alkaline conditions.

Japanese Patent Application No. 2025-072883 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A monomer having the formula (A): 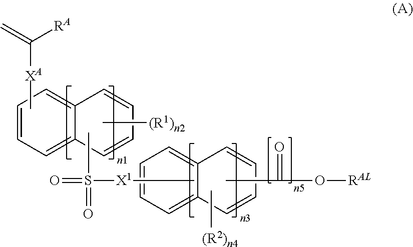
wherein n1 is 0 or 1, n2 is 0, 1,2,3 or 4, n3 is 0 or 1, n4 is 0, 1,2,3 or 4, n5 is 0 or 1,
R^{A} is hydrogen, fluorine, methyl or trifluoromethyl,
X^{A} is a single bond, —C(═O)—O—* or —C(═O)—N(H)—* wherein * designates a point of attachment to a carbon atom on the aromatic ring,
R¹ is halogen, nitro, cyano, hydroxy, carboxy, pentafluorosulfanyl, a C₁-C₂₀ hydrocarbyl group which may contain a heteroatom, C₁-C₂₀ hydrocarbyloxy group which may contain a heteroatom, C₁-C₂₀ hydrocarbylthio group which may contain a heteroatom; when n2 is 2, 3 or 4, a plurality of R¹ may be identical or different and two R¹ may bond together to form a ring with the carbon atoms to which they are attached,
R² is halogen, nitro, cyano, hydroxy, carboxy, pentafluorosulfanyl, a C₁-C₂₀ hydrocarbyl group which may contain a heteroatom, C₁-C₂₀ hydrocarbyloxy group which may contain a heteroatom, C₁-C₂₀ hydrocarbylthio group which may contain a heteroatom; when n4 is 2, 3 or 4, a plurality of R² may be identical or different and two R² may bond together to form a ring with the carbon atoms to which they are attached,
X¹ is —O— or —N(H)—, and
R^{AL} is an acid labile group.

2. The monomer of claim 1, having the formula (A1): 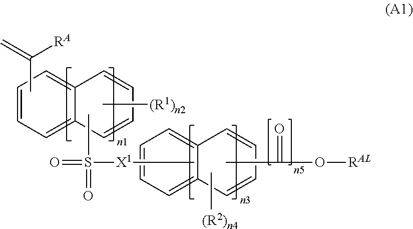
wherein n1 to n5, R^{A}, X¹, R¹, R² and R^{AL} are as defined above.

3. The monomer of claim 2, having the formula (A2): 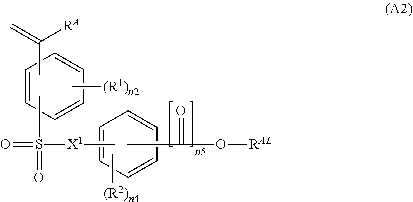
wherein n2, n4, n5, R^{A}, X¹, R¹, R² and R^{AL} are as defined above.

4. The monomer of claim 1 wherein R^{AL} is a group having the formula (AL-1) or (AL-2): 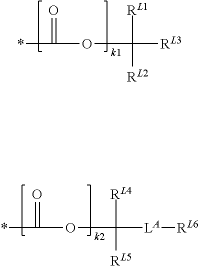
wherein k1 is 0 or 1, k2 is 0 or 1,
R^{L1} and R^{L2} are each independently a C₁-C₁₂ hydrocarbyl group, R^{L3} is hydrogen or a C₁-C₁₂ hydrocarbyl group, some —CH₂— in the hydrocarbyl group represented by R^{L1}, R^{L2} and R^{L3} may be replaced by —O— or —S—, and when the hydrocarbyl group contains an aromatic ring, some or all of the hydrogen atoms on the aromatic ring may be substituted by halogen, cyano, nitro, optionally halogenated C₁-C₄ alkyl moiety or optionally halogenated C₁-C₄ alkoxy moiety, R^{L1} and R^{L2} may bond together to form a ring with the carbon atom to which they are attached, some —CH₂— in the ring may be replaced by —O— or —S—, with the proviso that when R^{L3} is hydrogen, R^{L1} and R^{L2} bond together to form a multiple bond-containing alicyclic group with the carbon atom to which they are attached,
R^{L4} and R^{L5} are each independently hydrogen or a C₁-C₁₀ hydrocarbyl group, R^{L6} is a C₁-C₂₀ hydrocarbyl group, some —CH₂— in the hydrocarbyl group may be replaced by —O— or —S—, R^{L5} and R^{L6} may bond together to form a C₃-C₂₀ heterocyclic group with the carbon atom and L^{A} to which they are attached, some —CH₂— in the heterocyclic group may be replaced by —O— or —S—,
L^{A} is —O— or —S—, and
* designates a point of attachment to adjoining —O—.

5. A polymer comprising repeat units derived from the monomer of claim 1.

6. The polymer of claim 5, further comprising repeat units of at least one type selected from repeat units having the formula (a1), repeat units having the formula (a2), and repeat units having the formula (a3): 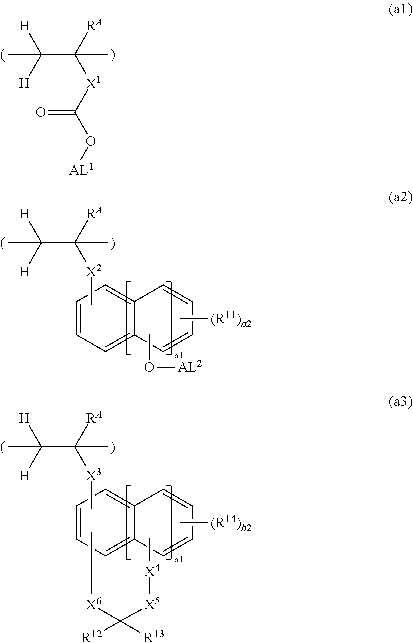
wherein a1 is 0 or 1, a2 is 0, 1, 2, 3 or 4,
b1 is 0 or 1, b2 is 0, 1, 2 or 3 when b1=0, b2 is 0, 1, 2, 3, 4 or 5 when b1=1,
R^{A} is each independently hydrogen, fluorine, methyl or trifluoromethyl,
X¹ is a single bond, phenylene, naphthylene, or *—C(═O)—O—X¹¹—, the phenylene or naphthylene group may be substituted with hydroxy, nitro, cyano, optionally fluorinated C₁-C₁₀ saturated hydrocarbyl moiety, optionally fluorinated C₁-C₁₀ saturated hydrocarbyloxy moiety, or halogen, X¹¹ is a C₁-C₁₀ saturated hydrocarbylene group, phenylene group or naphthylene group, the saturated hydrocarbylene group may contain hydroxy, ether bond, ester bond or lactone ring,
X² is a single bond, *—C(═O)—O— or *—C(═O)—N(H)—,
X³ is a single bond, *—C(═O)—O— or *—C(═O)—N(H)—,
* designates a point of attachment to the carbon atom in the backbone,
X⁴ is a single bond, a C₁-C₄ aliphatic hydrocarbylene group, carbonyl, sulfonyl, or a group obtained by combining the foregoing,
X⁵ and X⁶ are each independently oxygen or sulfur, X⁴ and X⁶ are attached to adjoining carbon atoms on the aromatic ring,
R¹¹ is halogen, cyano, hydroxy, nitro, pentafluorosulfanyl, a C₁-C₂₀ hydrocarbyl group which may contain a heteroatom, C₁-C₂₀ hydrocarbyloxy group which may contain a heteroatom, C₂-C₂₀ hydrocarbylcarbonyl group which may contain a heteroatom, C₂-C₂₀ hydrocarbylcarbonyloxy group which may contain a heteroatom, or C₂-C₂₀ hydrocarbyloxycarbonyl group which may contain a heteroatom; when a2 is 2, 3 or 4, a plurality of R¹¹ may be identical or different,
R¹² and R¹³ are each independently hydrogen or a C₁-C₂₀ hydrocarbyl group which may contain a heteroatom, R¹² and R¹³ may bond together to form a ring with the carbon atom to which they are attached,
R¹⁴ is halogen, hydroxy, cyano, nitro, pentafluorosulfanyl, a C₁-C₂₀ hydrocarbyl group which may contain a heteroatom, C₁-C₂₀ hydrocarbyloxy group which may contain a heteroatom, C₂-C₂₀ hydrocarbyloxycarbonyl group which may contain a heteroatom, C₂-C₂₀ hydrocarbylthio group which may contain a heteroatom, or —N(R^{14A})(R^{14B}), wherein R^{14A} and R^{14B} are each independently hydrogen or a C₁-C₆ hydrocarbyl group; when b2 is 2 or more, a plurality of R¹⁴ may be identical or different and a plurality of R¹⁴ may bond together to form a ring with carbon atoms on the aromatic ring to which they are attached,
AL¹ and AL² are each independently an acid labile group.

7. The polymer of claim 5, further comprising repeat units having the formula (b1): 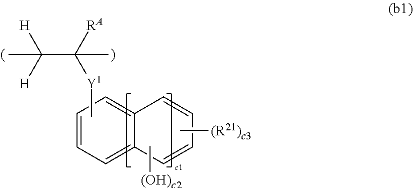
wherein R^{A} is each independently hydrogen, fluorine, methyl or trifluoromethyl,
Y¹ is a single bond, *—C(═O)—O— or *—C(═O)—N(H)—, wherein * designates a point of attachment to the carbon atom in the backbone,
R²¹ is halogen, carboxy, nitro, cyano, pentafluorosulfanyl, a C₁-C₂₀ hydrocarbyl group which may contain a heteroatom, C₁-C₂₀ hydrocarbyloxy group which may contain a heteroatom, C₂-C₂₀ hydrocarbylcarbonyl group which may contain a heteroatom, C₂-C₂₀ hydrocarbylcarbonyloxy group which may contain a heteroatom, C₂-C₂₀ hydrocarbyloxycarbonyl group which may contain a heteroatom; when c3 is 2, 3 or 4, a plurality of R²¹ may be identical or different,
c1 is 0 or 1, c2 is 1, 2, 3 or 4, c3 is 0, 1, 2, 3 or 4, meeting 1≤c2+c3≤5.

8. The polymer of claim 5, further comprising repeat units having the formula (b2): 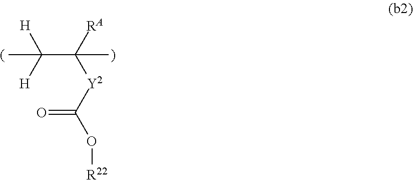
wherein R^{A} is each independently hydrogen, fluorine, methyl or trifluoromethyl,
Y² is a single bond, phenylene, naphthylene, *—C(═O)—O—Y²¹— or *—C(═O)—NH—Y²¹— the phenylene or naphthylene group may be substituted with hydroxy, nitro, cyano, optionally fluorinated C₁-C₁₀ saturated hydrocarbyl moiety, optionally fluorinated C₁-C₁₀ saturated hydrocarbyloxy moiety, or halogen, * designates a point of attachment to the carbon atom in the backbone, Y²¹ is a C₁-C₁₀ saturated hydrocarbylene group, phenylene group or naphthylene group, the saturated hydrocarbylene group may contain hydroxy, ether bond, ester bond or lactone ring,
R²² is hydrogen, or a C₁-C₂₀ group containing at least one structure selected from hydroxy other than phenolic hydroxy, cyano, nitro, carbonyl, carboxy, ether bond, ester bond, sulfonate ester bond, carbonate bond, lactone ring, sultone ring, lactam ring, sultam ring, and carboxylic anhydride (—C(═O)—O—C(═O)—).

9. The polymer of claim 5, further comprising repeat units of at least one type selected from repeat units having the formula (c1), repeat units having the formula (c2), repeat units having the formula (c3), repeat units having the formula (c4), and repeat units having the formula (c5): 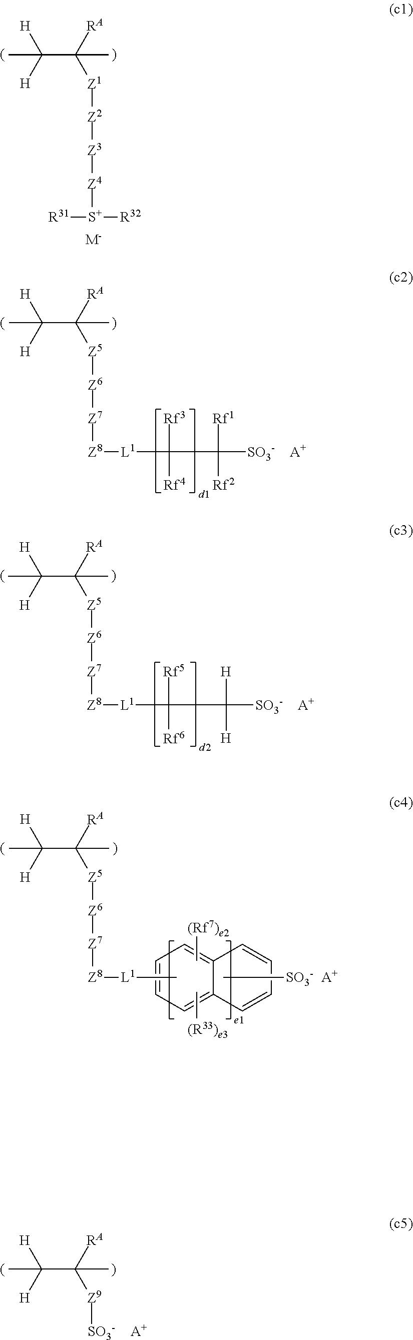
wherein d1 and d2 are each independently 0, 1, 2 or 3,
e1 is 0 or 1, e2 is 0, 1, 2, 3 or 4, e3 is 0, 1, 2, 3 or 4, meeting 0≤e2+e3≤4 when e1=0, and 0≤e2+e3≤6 when e1=1,
R^{A} is each independently hydrogen, fluorine, methyl or trifluoromethyl,
Z¹ is a single bond or optionally substituted phenylene group,
Z² is a single bond, **—C(═O)—O—Z²¹—, **—C(═O)—N(H)—Z²¹—, or **—O—Z²¹—, Z²¹ is a C₁-C₆ aliphatic hydrocarbylene group, phenylene group or a divalent group obtained by combining the foregoing, which may contain halogen, carbonyl moiety, ester bond, ether bond or hydroxy moiety,
Z³ is a single bond, ether bond, ester bond, sulfonate ester bond, amide bond, sulfonamide bond, carbonate bond or carbamate bond,
Z⁴ is a single bond or a C₁-C₆ aliphatic hydrocarbylene group, phenylene group or a divalent group obtained by combining the foregoing, which may contain halogen, carbonyl moiety, ester bond, ether bond or hydroxy moiety,
Z⁵ is each independently a single bond, optionally substituted phenylene group, naphthylene group or *—C(═O)—O—Z⁵¹—, Z⁵¹ is a C₁-C₁₀ aliphatic hydrocarbylene group, phenylene group or naphthylene group, the aliphatic hydrocarbylene group may contain halogen, hydroxy, ether bond, ester bond or lactone ring,
Z⁶ is a single bond, ether bond, ester bond, sulfonate ester bond, amide bond, sulfonamide bond, carbonate bond or carbamate bond,
Z⁷ is each independently a single bond, ***—Z⁷¹—C(═O)—O—, ***—C(═O)—N(H)—Z⁷¹— or ***—O—Z⁷¹—, Z⁷¹ is a C₁-C₂₀ hydrocarbylene group which may contain a heteroatom,
Z⁸ is each independently a single bond, ****—Z⁸¹—C(═O)—O—, ****—C(═O)—N(H)—Z⁸¹— or ****—O—Z⁸¹—, Z⁸¹ is a C₁-C₂₀ hydrocarbylene group which may contain a heteroatom,
Z⁹ is a single bond, methylene, ethylene, phenylene, fluorinated phenylene, trifluoromethyl-substituted phenylene, *—C(═O)—O—Z⁹¹—, *—C(═O)—N(H)—Z⁹¹— or *—O—Z⁹¹—, Z⁹¹ is a C₁-C₆ aliphatic hydrocarbylene group, phenylene group, fluorinated phenylene group, or trifluoromethyl-substituted phenylene group, which may contain carbonyl, ester bond, ether bond or hydroxy,
* designates a point of attachment to the carbon atom in the backbone, ** designates a point of attachment to Z¹, *** designates a point of attachment to Z⁶, **** designates a point of attachment to Z⁷,
L¹ is a single bond, ether bond, ester bond, carbonyl group, sulfonate ester bond, sulfonamide bond, carbonate bond or carbamate bond,
Rf¹ and Rf² are each independently fluorine or a C₁-C₆ fluorinated saturated hydrocarbyl group,
Rf³ and Rf⁴ are each independently hydrogen, fluorine or a C₁-C₆ fluorinated saturated hydrocarbyl group,
Rf⁵ and Rf⁶ are each independently hydrogen, fluorine or a C₁-C₆ fluorinated saturated hydrocarbyl group, excluding that all Rf⁵ and Rf⁶ are hydrogen at the same time,
Rf⁷ is fluorine, a C₁-C₆ fluorinated alkyl group, C₁-C₆ fluorinated alkoxy group, C₁-C₆ fluorinated alkylthio group, or pentafluorosulfanyl group,
R³¹ and R³² are each independently a C₁-C₂₀ hydrocarbyl group which may contain a heteroatom, R³¹ and R³² may bond together to form a ring with the sulfur atom to which they are attached,
R³³ is halogen exclusive of fluorine, or a C₁-C₂₀ hydrocarbyl group which may contain a heteroatom; when e3 is 2, 3 or 4, a plurality of R⁴³ may be identical or different and a plurality of R⁴³ may bond together to form a ring with the carbon atoms to which they are attached,
M⁻ is a non-nucleophilic counter ion, and
A⁺ is an onium cation.

10. A chemically amplified resist composition comprising a base polymer containing the polymer of claim 5, and an organic solvent.

11. The resist composition of claim 10, further comprising a quencher.

12. The resist composition of claim 10, further comprising a photoacid generator other than a polymer-bound photoacid generator.

13. The resist composition of claim 10, further comprising a surfactant.

14. A pattern forming process comprising the steps of applying the chemically amplified resist composition of claim 10 onto a substrate to form a resist film thereon, exposing the resist film to high-energy radiation, and developing the exposed resist film in a developer.

15. The process of claim 14 wherein the high-energy radiation is KrF excimer laser, ArF excimer laser, EB or EUV of wavelength 3 to 15 nm.
